(19) United States
(12) Patent Application Publication
(10) Pub. No.: US 2025/0011356 A1
(43) Pub. Date: Jan. 9, 2025

(54) ORGANIC ELECTROLUMINESCENT MATERIAL AND DEVICE

(71) Applicant: BEIJING SUMMER SPROUT TECHNOLOGY CO., LTD., Beijing (CN)

(72) Inventors: Zhen Wang, Beijing (CN); Zheng Wang, Beijing (CN); Hongbo Li, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/758,485

(22) Filed: Jun. 28, 2024

(30) Foreign Application Priority Data
Jun. 29, 2023 (CN) 202310784339.4

(51) Int. Cl. C07F 15/00; C07B 59/00; C09K 11/02; C09K 11/06; H10K 50/12; H10K 85/30; H10K 85/60

(52) U.S. Cl. CPC C07F 15/0033; C07B 59/004; C09K 11/02; C09K 11/06; H10K 50/12; H10K 85/342; H10K 85/622; H10K 85/654; H10K 85/6572; H10K 85/6574; H10K 85/6576; C07B 2200/05

(57) ABSTRACT

Provided are an organic electroluminescent material and a device comprising the same. The organic electroluminescent material is a metal complex comprising a ligand Lₐ having a structure of Formula 1. Applied to an electroluminescent device, these new metal complexes can reduce a full width at half maximum and capacitance of the device. The organic electroluminescent device can improve the response time and refresh rate of an OLED display device at a low grayscale and can maintain excellent device performance, thereby contributing to improving the overall performance of the device. The metal complex has a great advantage and a broad prospect in industrial application. Further provided are an organic electroluminescent device comprising the metal complex and a composition comprising the metal complex.

### CROSS-REFERENCE TO RELATED APPLICATION(S)

This application claims priority to Chinese Patent Application No. 202310784339.4 filed on Jun. 29, 2023, the disclosure of which is incorporated herein by reference in its entirety.

### TECHNICAL FIELD

The present disclosure relates to compounds for organic electronic devices such as organic light-emitting devices. More particularly, the present disclosure relates to a metal complex comprising a ligand Lₐ having a structure of Formula 1, an organic electroluminescent device comprising the metal complex and a compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

From an electronic perspective, a display principle of the OLED is briefly described as follows: under the action of an applied electric field greater than a certain threshold, holes and electrons are injected into an organic film light-emitting layer sandwiched between an anode and a cathode in a form of current from the anode and the cathode, respectively. The holes and the electrons are combined to form excitons, and radiative recombination occurs to cause light emission. Since the organic light-emitting film has very apparent capacitance characteristics, a capacitance of the organic light-emitting film layer is a key factor that affects the response time and refresh rate of an OLED display device at a low grayscale.

CN111655705A has disclosed a metal complex having the following structure:

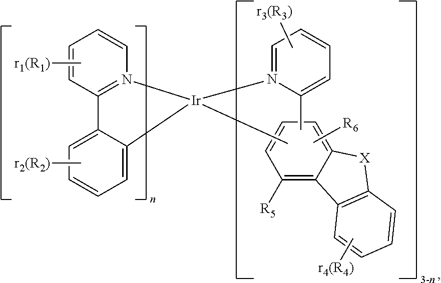

where R₅ is selected from groups such as halogen, a nitrile group, a nitro group, . . . and substituted or unsubstituted alkyl having 3 to 30 carbon atoms, R₄ is selected from many groups such as hydrogen, deuterium, halogen, and CN111655705A has further disclosed the following specific structures:

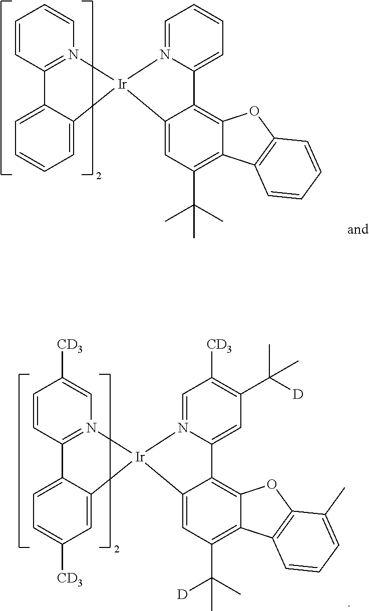

The application does not disclose or teach a metal complex where R₅ is a substituent “whose total number of carbon atoms is greater than or equal to 2” and R₄ at a particular position is aryl or heteroaryl and an effect of the metal complex on device performance.

US20210403496A1 has disclosed a phosphorescent metal complex having the following structure:

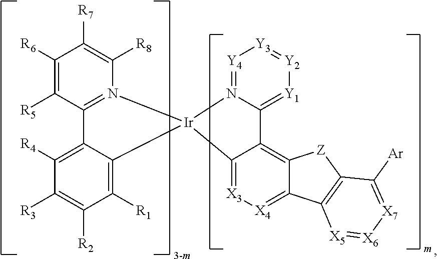

where Ar is selected from substituted or unsubstituted aryl having 6 to 30 carbon atoms, substituted or unsubstituted heteroaryl having 3 to 30 carbon atoms and combinations thereof, X₄ is selected from CRₓ or N, Rₓ is selected from many groups such as hydrogen, deuterium and halogen, and US20210403496A1 has further disclosed the following specific structures:

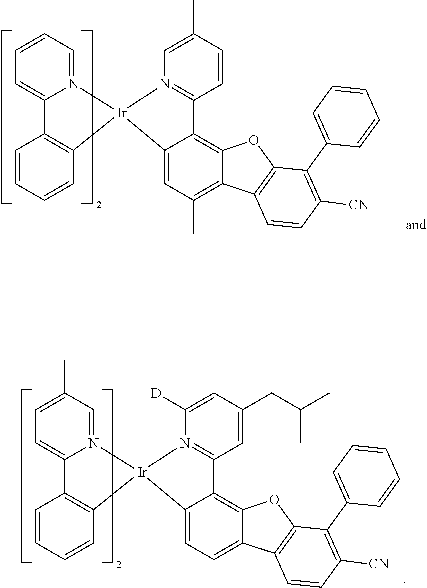

The application does not disclose or teach a metal complex where X₄ is selected from CRₓ and Rₓ is a substituent “whose total number of carbon atoms is greater than or equal to 2” and an effect of the metal complex on device performance.

### SUMMARY

The present disclosure aims to provide a series of metal complexes each comprising a ligand Lₐ having a structure of Formula 1 to solve at least part of the above-mentioned problems. Applied to an electroluminescent device, these new metal complexes can significantly reduce a full width at half maximum and capacitance of the device, thereby contributing to improving the overall performance of the device.

According to an embodiment of the present disclosure, disclosed is a metal complex comprising a metal M and a ligand Lₐ coordinated to the metal M, wherein Lₐ has a structure represented by Formula 1:

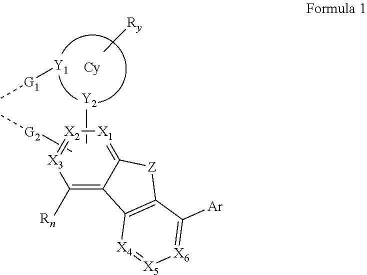

wherein,
Cy is selected from an aromatic ring having 6 to 24 ring atoms which comprises Y₁ and Y₂, a heteroaromatic ring having 5 to 24 ring atoms which comprises Y₁ and Y₂ or a combination thereof;
G₁ and G₂ are, at each occurrence identically or differently, selected from a single bond, O or S;
X₁ to X₃ are, at each occurrence identically or differently, selected from C, CRₓ or N, and one of X₁ to X₃ is selected from C and joined to Y₂;
when G₂ is selected from a single bond, and X₁, X₂ or X₃ is selected from N, X₁, X₂ or X₃ is joined to the metal by forming a metal-nitrogen bond through G₂; or when G₂ is selected from a single bond, O or S, and X₁, X₂ or X₃ is selected from C, X₁, X₂ or X₃ is joined to the metal through G₂;
X₄ to X₆ are, at each occurrence identically or differently, selected from CRₓ or N;
Y₁ and Y₂ are, at each occurrence identically or differently, selected from C or N;
Z is selected from the group consisting of O, S, Se, NR′, CR′R′, SiR′R′ and GeR′R′; when two R′ are present at the same time, the two R′ are identical or different;
R_{y} represents mono-substitution, multiple substitutions or non-substitution; when a plurality of R_{y} are present, the plurality of R_{y} are identical or different;
Ar is selected from substituted or unsubstituted aryl having 6 to 30 carbon atoms or substituted or unsubstituted heteroaryl having 3 to 30 carbon atoms;
Rₙ has a structure represented by Formula 2:

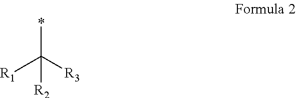

wherein the number of carbon atoms in Rₙ is greater than or equal to 2;
“*” represents a position where Formula 2 is joined to Formula 1;
Rₓ, R_{y}, R′, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
adjacent substituents R_{y} and R′ can be optionally joined to form a ring; and
adjacent substituents R₁, R₂ and R₃ can be optionally joined to form a ring.

According to another embodiment of the present disclosure, further disclosed is an organic electroluminescent device comprising an anode, a cathode and an organic layer disposed between the anode and the cathode, wherein at least one layer of the organic layer comprises the metal complex in the preceding embodiment.

According to another embodiment of the present disclosure, further disclosed is a compound composition comprising the metal complex in the preceding embodiment.

The present disclosure aims to provide the series of metal complexes each comprising the ligand Lₐ having the structure of Formula 1 to solve at least part of the above-mentioned problems. Applied to the electroluminescent device, these new metal complexes can reduce the full width at half maximum and capacitance of the device. The organic electroluminescent device can improve the response time and refresh rate of an OLED display device at a low grayscale and can maintain excellent device performance, thereby contributing to improving the overall performance of the device. The metal complex has a great advantage and a broad prospect in industrial application.

### BRIEF DESCRIPTION OF DRAWINGS

FIG. 1 is a schematic diagram of an organic light-emitting apparatus that may comprise a metal complex and a compound composition comprising the metal complex disclosed herein.

FIG. 2 is a schematic diagram of another organic light-emitting apparatus that may comprise a metal complex and a compound composition comprising the metal complex disclosed herein.

### DETAILED DESCRIPTION

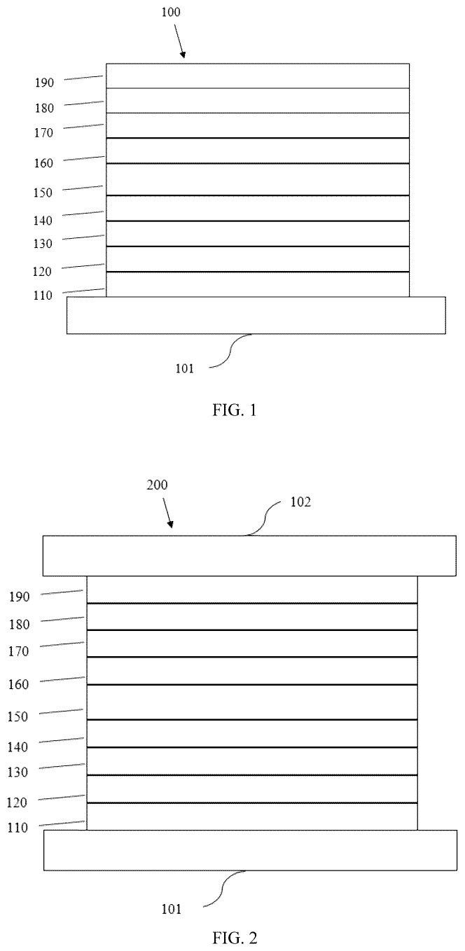

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

As used herein, “emissive area” means the area of an organic electroluminescent device in the direction perpendicular to the emissive surface where the anode is in direct contact with the organic layer and at the same time the organic layer is in direct contact with the cathode. Herein, the emissive area in Device Examples and Device Comparative Examples is 0.04 cm².

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldimethylgermanyl, phenyldiethylgermanyl, diphenylethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

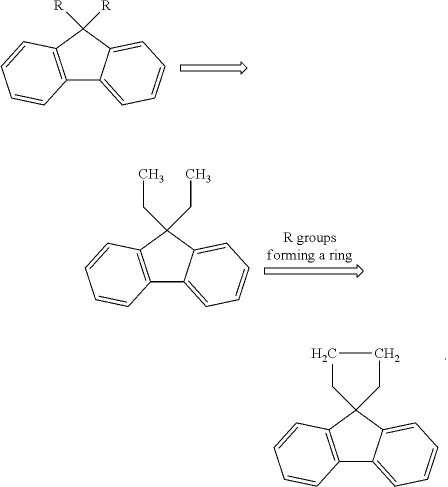

The expression that adjacent substituents can be optionally joined to form a ring is also intended to mean that two substituents bonded to carbon atoms which are directly bonded to each other are joined to each other via a chemical bond to form a ring, which can be exemplified by the following formula:

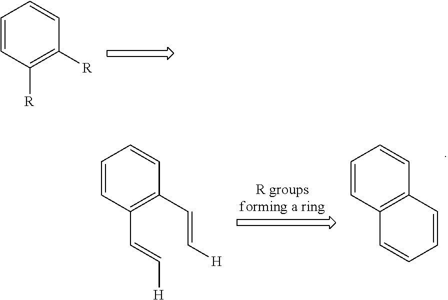

The expression that adjacent substituents can be optionally joined to form a ring is also intended to mean that two substituents bonded to a further distant carbon atom are joined to each other via a chemical bond to form a ring, which can be exemplified by the following formula:

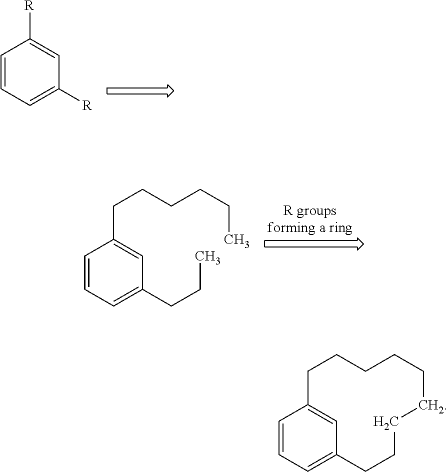

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

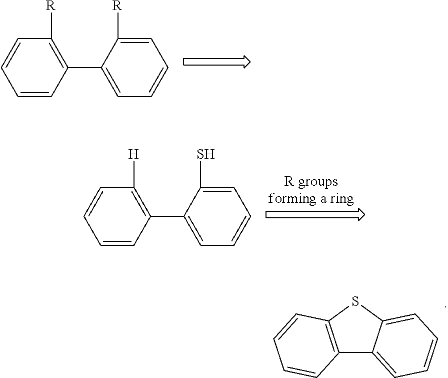

According to an embodiment of the present disclosure, disclosed is a metal complex comprising a metal M and a ligand Lₐ coordinated to the metal M, wherein Lₐ has a structure represented by Formula 1:

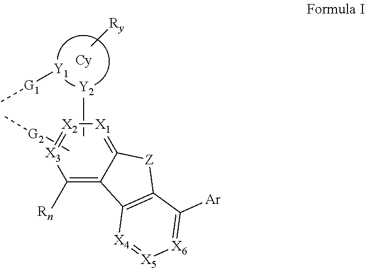

wherein,
Cy is selected from an aromatic ring having 6 to 24 ring atoms which comprises Y₁ and Y₂, a heteroaromatic ring having 5 to 24 ring atoms which comprises Y₁ and Y₂ or a combination thereof;
G₁ and G₂ are, at each occurrence identically or differently, selected from a single bond, O or S;
X₁ to X₃ are, at each occurrence identically or differently, selected from C, CRₓ or N, and one of X₁ to X₃ is selected from C and joined to Y₂;
when G₂ is selected from a single bond, and X₁, X₂ or X₃ is selected from N, X₁, X₂ or X₃ is joined to the metal by forming a metal-nitrogen bond through G₂; or when G₂ is selected from a single bond, O or S, and X₁, X₂ or X₃ is selected from C, X₁, X₂ or X₃ is joined to the metal through G₂;
X₄ to X₆ are, at each occurrence identically or differently, selected from CRₓ or N;
Y₁ and Y₂ are, at each occurrence identically or differently, selected from C or N; when Y₁ is selected from N, G₁ is selected from a single bond, and Y₁ is directly joined to the metal M; or when Y₁ is selected from C, G₁ is selected from a single bond, O or S, Y₁ is joined to the metal M through G₁;
Z is selected from the group consisting of O, S, Se, NR′, CR′R′, SiR′R′ and GeR′R′; when two R′ are present at the same time, the two R′ are identical or different;
R_{y} represents mono-substitution, multiple substitutions or non-substitution; when a plurality of R_{y} are present, the plurality of R_{y} are identical or different;
Ar is selected from substituted or unsubstituted aryl having 6 to 30 carbon atoms or substituted or unsubstituted heteroaryl having 3 to 30 carbon atoms;
Rₙ has a structure represented by Formula 2:

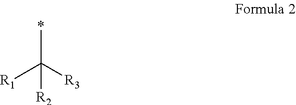

wherein the number of carbon atoms in Rₙ is greater than or equal to 2;
“*” represents a position where Formula 2 is joined to Formula 1;
Rₓ, R_{y}, R′, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
adjacent substituents Rₓ and R′ can be optionally joined to form a ring; and
adjacent substituents R₁, R₂ and R₃ can be optionally joined to form a ring.

In the present disclosure, when G₁ is selected from a single bond, it indicates that Y₁ is directly joined to the metal M, and when G₂ is selected from a single bond, it indicates that X₁, X₂ or X₃ is directly joined to the metal M.

In the present disclosure, the expression that “adjacent substituents R_{y} can be optionally joined to form a ring” is intended to mean that any one or more groups of the group consisting of adjacent substituents R_{y} can be optionally joined to form a ring. Obviously, it is also possible that none of these substituents are joined to form a ring.

In the present disclosure, the expression that “adjacent substituents R_{y} and R′ can be optionally joined to form a ring” is intended to mean that any one or more of groups of adjacent substituents, such as two substituents R_{y}, two substituents R′, and substituents R_{y} and R′, can be joined to form a ring. Obviously, it is also possible that none of these substituents are joined to form a ring.

In the present disclosure, the expression that “adjacent substituents R₁, R₂ and R₃ can be optionally joined to form a ring” is intended to mean that any one or more of groups of adjacent substituents, such as substituents R₁ and R₂, substituents R₁ and R₃, and substituents R₃ and R₂, can be joined to form a ring. Obviously, it is also possible that none of these substituents are joined to form a ring.

According to an embodiment of the present disclosure, Cy is, at each occurrence identically or differently, selected from any structure of the group consisting of the following:

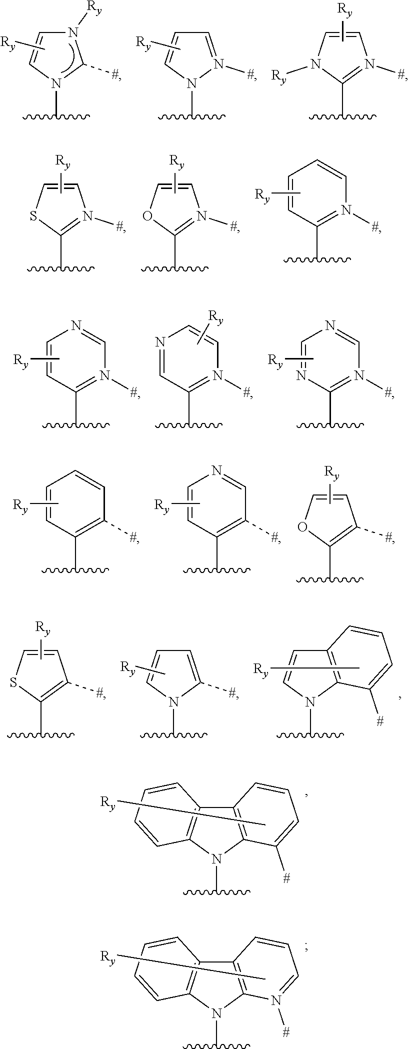

wherein,
R_{y} represents, at each occurrence identically or differently, mono-substitution, multiple substitutions or non-substitution; when a plurality of R_{y} are present in any structure, the plurality of R_{y} are identical or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring; and
“#” represents a position where Cy is joined to the metal M, and “ [symbol] ” represents a position where Cy is joined to X₁, X₂ or X₃.

According to an embodiment of the present disclosure, the metal complex has a general formula of M(Lₐ)ₘ(L_{b})ₙ(L_{c})_{q};
M is selected from a metal with a relative atomic mass greater than 40; preferably, the metal M is, at each occurrence identically or differently, selected from the group consisting of Cu, Ag, Au, Ru, Rh, Pd, Os, Ir and Pt;
Lₐ, L_{b} and L_{c} are a first ligand, a second ligand and a third ligand coordinated to the metal M, respectively, and L_{c} is the same as or different from Lₐ or L_{b}, wherein Lₐ, L_{b} and L_{c} can be optionally joined to form a multidentate ligand;
m is selected from 1, 2 or 3, n is selected from 0, 1 or 2, q is selected from 0, 1 or 2, and m+n+q is equal to an oxidation state of the metal M; when m is greater than or equal to 2, a plurality of Lₐ are identical or different; when n is equal to 2, two L_{b} are identical or different; when q is equal to 2, two L_{c} are identical or different;
L_{b} and L_{c} are, at each occurrence identically or differently, selected from a structure represented by any one of the group consisting of:

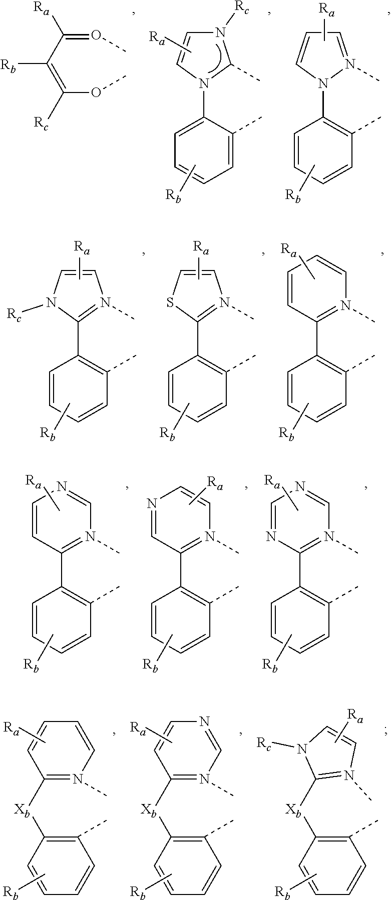

wherein,
X_{b} is, at each occurrence identically or differently, selected from the group consisting of: O, S, Se, NR_{N1} and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is also possible that none of these substituents are joined to form a ring. For example, adjacent substituents Rₐ and R_{b} in

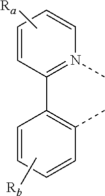

can be optionally joined to form a ring. When Rₐ is optionally joined to form a ring,

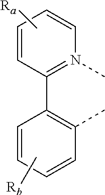

may form a structure of

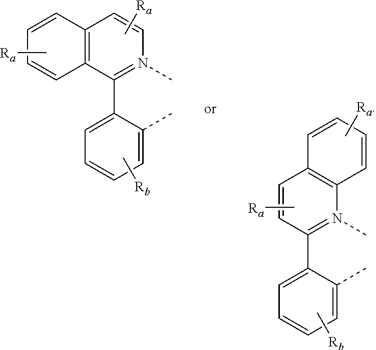

According to an embodiment of the present disclosure, G₁ and G₂ are, at each occurrence identically or differently, selected from a single bond or O.

According to an embodiment of the present disclosure, G₁ and G₂ each are a single bond.

According to an embodiment of the present disclosure, the metal complex has a general formula structure of Ir(Lₐ)ₘ(L_{b})₃₋ₘ, and the structure is represented by Formula 3:

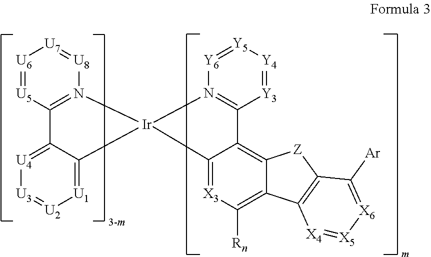

wherein,
m is selected from 1, 2 or 3; when m is selected from 1, two L_{b} are identical or different;
when m is selected from 2 or 3, a plurality of Lₐ are identical or different;
Z is selected from the group consisting of O, S, Se, NR′, CR′R′, SiR′R′ and GeR′R′; when two R′ are present at the same time, the two R′ are identical or different;
U₁ to U₈ are, at each occurrence identically or differently, selected from CRᵤ or N;
X₃ to X₆ are, at each occurrence identically or differently, selected from CRₓ or N;
Y₃ to Y₆ are, at each occurrence identically or differently, selected from CR_{y} or N;
Ar is selected from substituted or unsubstituted aryl having 6 to 30 carbon atoms or substituted or unsubstituted heteroaryl having 3 to 30 carbon atoms;
Rₙ has a structure represented by Formula 2:

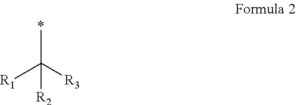

wherein the number of carbon atoms in Rₙ is greater than or equal to 2;
“*” represents a position where Formula 2 is joined to Formula 3;
R′, Rᵤ, Rₓ, R_{y}, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
adjacent substituents R_{y} and R′ can be optionally joined to form a ring;
adjacent substituents Rᵤ can be optionally joined to form a ring; and
adjacent substituents R₁, R₂ and R₃ can be optionally joined to form a ring.

In the present disclosure, the expression that “adjacent substituents Rᵤ can be optionally joined to form a ring” is intended to mean that any one or more groups of the group consisting of adjacent substituents Rᵤ can be optionally joined to form a ring. Obviously, it is also possible that none of these substituents are joined to form a ring.

According to an embodiment of the present disclosure, m is selected from 1 or 2.

According to an embodiment of the present disclosure, m is selected from 1.

According to an embodiment of the present disclosure, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, a cyano group and combinations thereof, and the total number of carbon atoms in R₁, R₂ and R₃ is greater than or equal to 1.

According to an embodiment of the present disclosure, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, a cyano group and combinations thereof, and at least one of R₁, R₂ and R₃ is selected from substituted or unsubstituted alkyl having 1 to 20 carbon atoms, substituted or unsubstituted cycloalkyl having 3 to 20 ring carbon atoms and combinations thereof.

According to an embodiment of the present disclosure, R₁, R₂ and R₃ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof, and the total number of carbon atoms in R₁, R₂ and R₃ is greater than or equal to 1.

According to an embodiment of the present disclosure, R₁, R₂ and R₃ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof, and at least one of R₁, R₂ and R₃ is selected from substituted or unsubstituted alkyl having 1 to 6 carbon atoms, substituted or unsubstituted cycloalkyl having 3 to 6 ring carbon atoms and combinations thereof.

According to an embodiment of the present disclosure, R₁, R₂ and R₃ are, at each occurrence identically or differently, selected from hydrogen, deuterium, substituted or unsubstituted alkyl having 1 to 6 carbon atoms and combinations thereof, and at least one of R₁, R₂ and R₃ is selected from substituted or unsubstituted alkyl having 1 to 6 carbon atoms.

According to an embodiment of the present disclosure, R₁, R₂ and R₃ are, at each occurrence identically or differently, selected from hydrogen, deuterium, substituted or unsubstituted alkyl having 1 to 6 carbon atoms, and R₁, R₂ and R₃ are not joined to form a ring, or two of R₁, R₂ and R₃ are joined to form a ring. For example, two of R₁, R₂ and R₃ are joined to form substituted or unsubstituted cycloalkyl.

According to an embodiment of the present disclosure, at least one of R₁, R₂ and R₃ is selected from hydrogen or deuterium.

According to an embodiment of the present disclosure, one of R₁, R₂ and R₃ is selected from hydrogen or deuterium.

According to an embodiment of the present disclosure, two of R₁, R₂ and R₃ are selected from hydrogen or deuterium.

According to an embodiment of the present disclosure, Rₙ is, at each occurrence identically or differently, selected from the group consisting of:

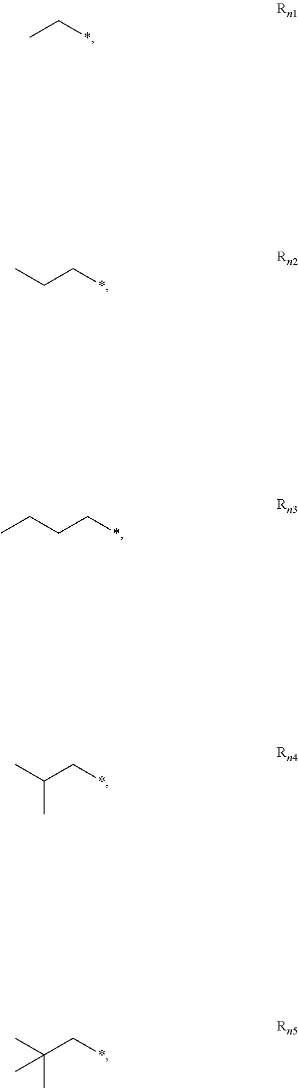

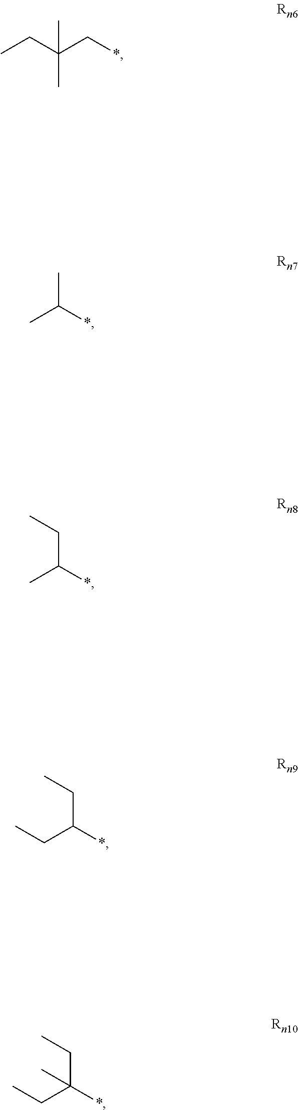

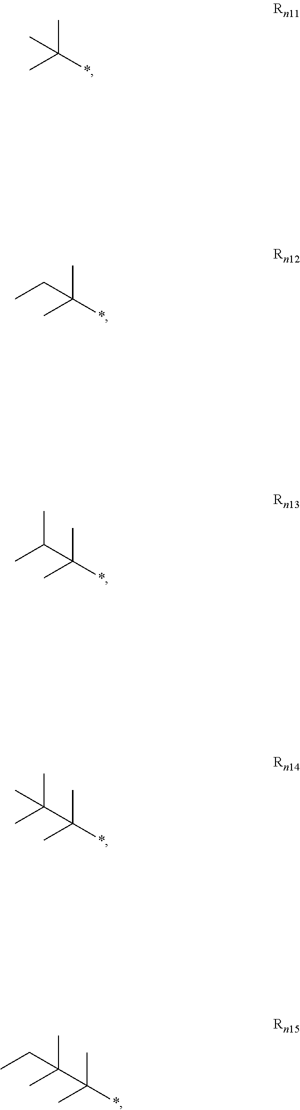

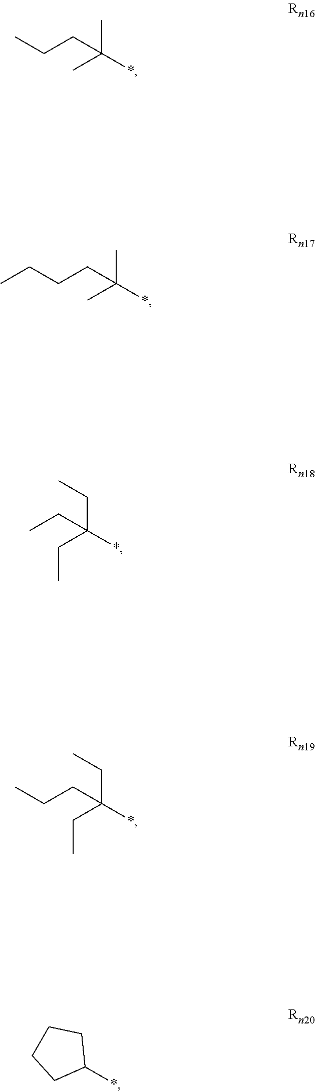

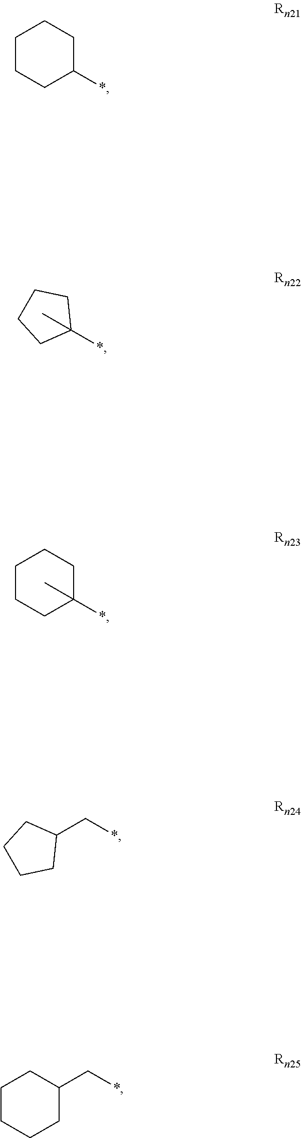

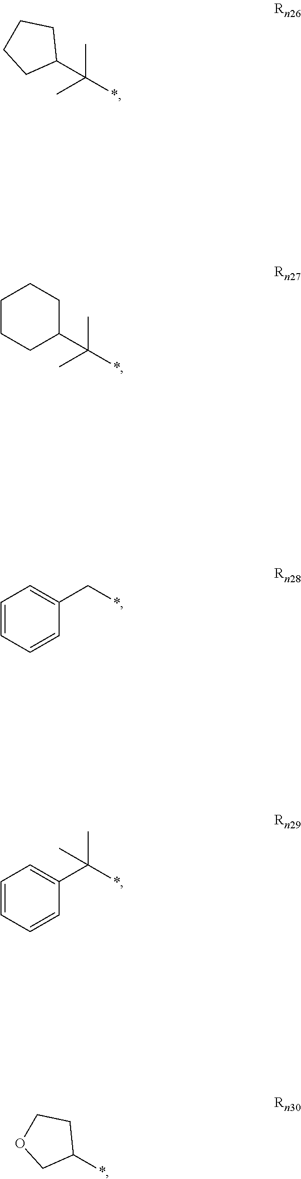

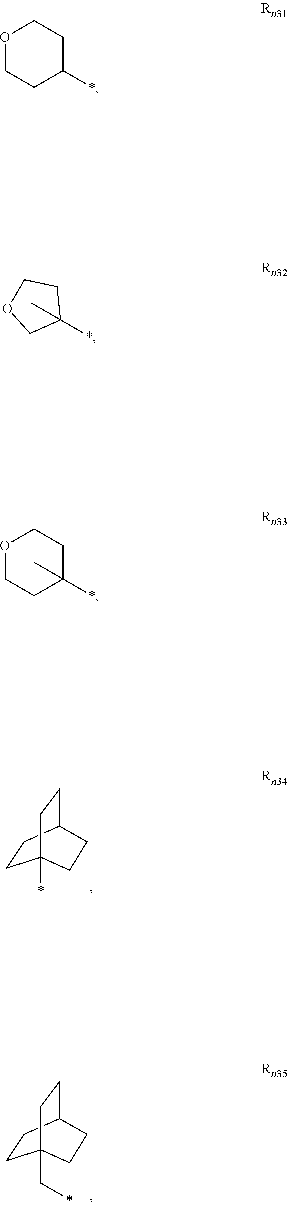

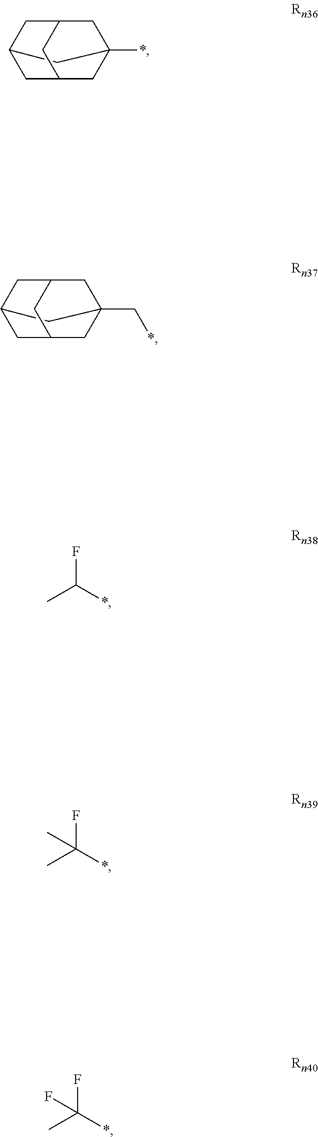

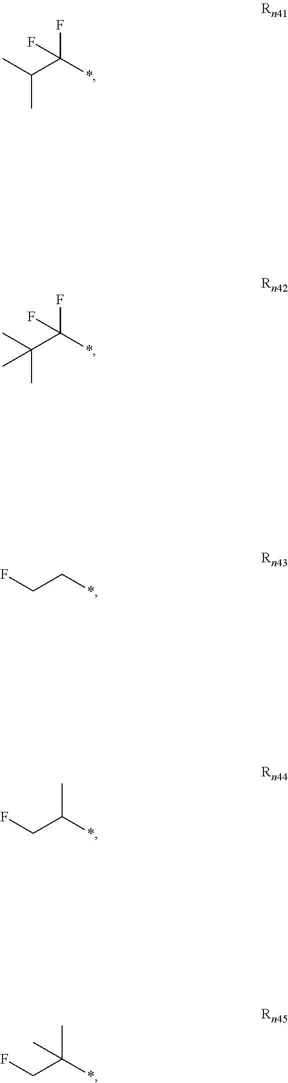

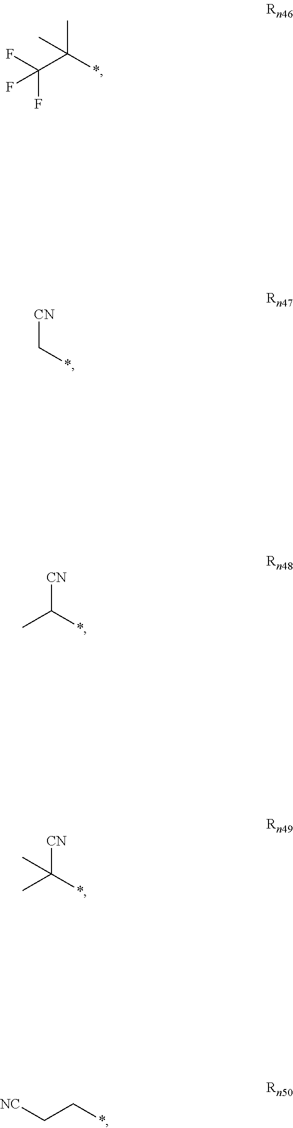

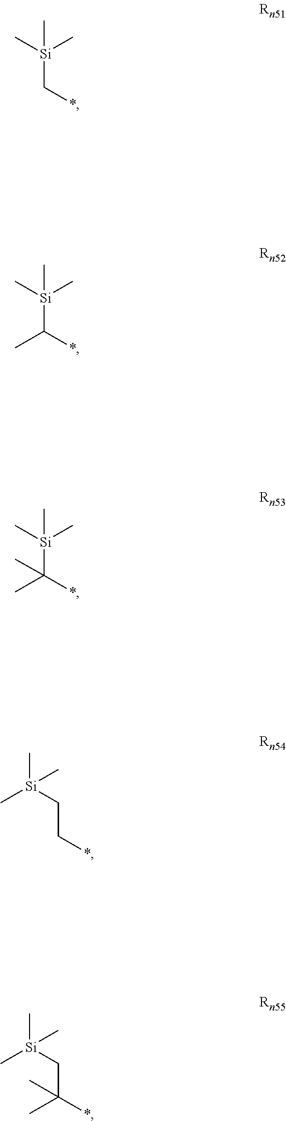

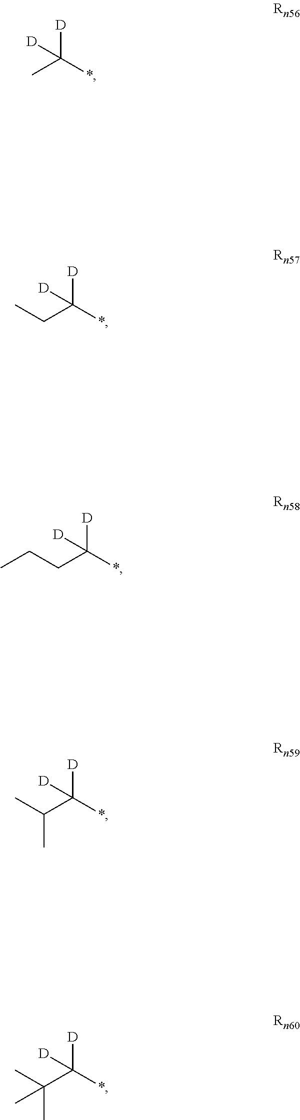

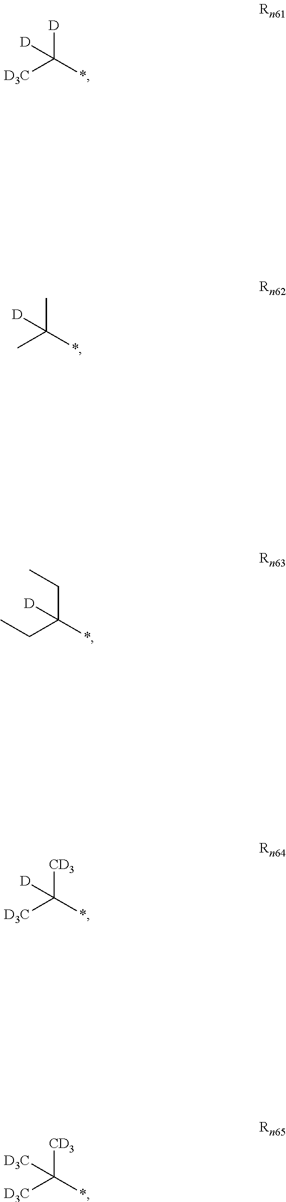

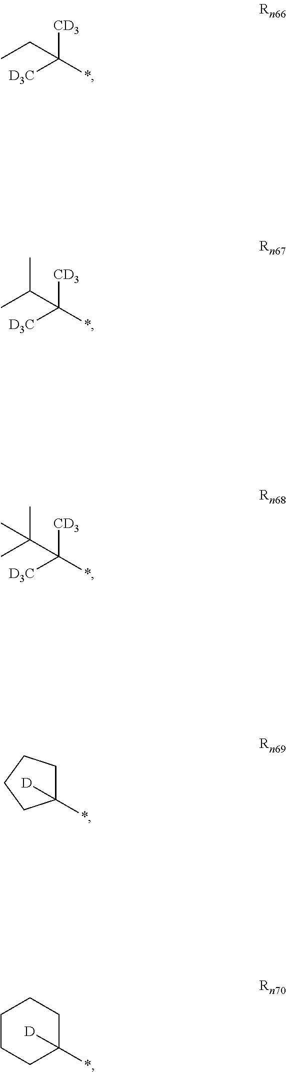

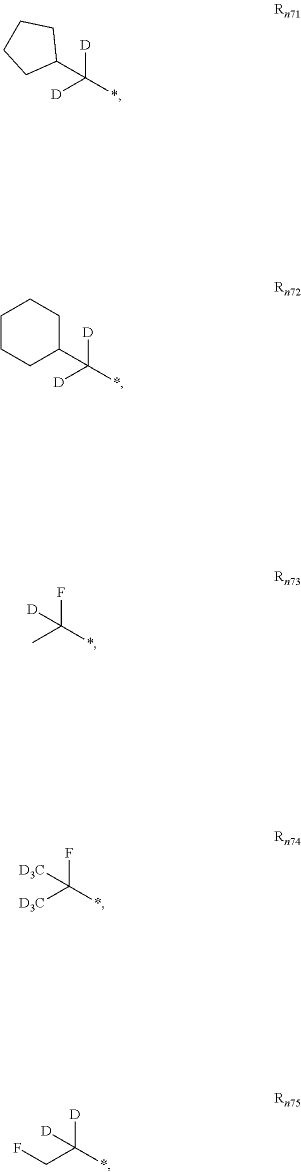

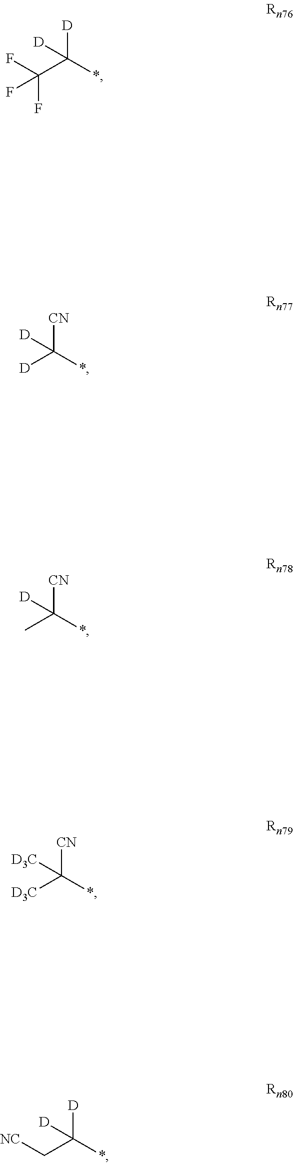

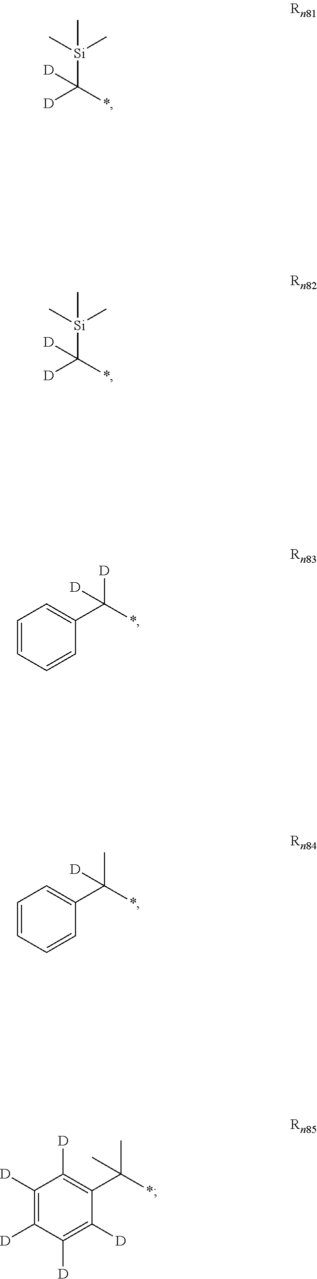

wherein optionally, hydrogen in the above Rₙ can be partially or fully substituted with deuterium.

According to an embodiment of the present disclosure, X₃ to X₆ are, at each occurrence identically or differently, selected from CRₓ.

According to an embodiment of the present disclosure, X₃ to X₆ are, at each occurrence identically or differently, selected from CRₓ or N, and at least one of X₃ to X₆ is N. For example, one of X₃ to X₆ is selected from N, or two of X₃ to X₆ are selected from N.

According to an embodiment of the present disclosure, Y₃ to Y₆ are, at each occurrence identically or differently, selected from CR_{y}.

According to an embodiment of the present disclosure, Y₃ to Y₆ are, at each occurrence identically or differently, selected from CR_{y} or N, and at least one of Y₃ to Y₆ is N. For example, one of Y₃ to Y₆ is selected from N, or two of Y₃ to Y₆ are selected from N.

According to an embodiment of the present disclosure, U₁ to U₈ are, at each occurrence identically or differently, selected from CRᵤ.

According to an embodiment of the present disclosure, U₁ to U₈ are, at each occurrence identically or differently, selected from CRᵤ or N, and at least one of U₁ to U₈ is N. For example, one of U₁ to U₈ is selected from N, or two of U₁ to U₈ are selected from N, or one of U₁ to U₄ is selected from N, or one of U₅ to U₈ is selected from N.

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group and combinations thereof.

According to an embodiment of the present disclosure, Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group and combinations thereof.

According to an embodiment of the present disclosure, Rₓ is, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof.

According to an embodiment of the present disclosure, R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group and combinations thereof.

According to an embodiment of the present disclosure, R_{y} is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group and combinations thereof.

According to an embodiment of the present disclosure, R_{y} is, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof.

According to an embodiment of the present disclosure, Rᵤ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group and combinations thereof.

According to an embodiment of the present disclosure, Rᵤ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group and combinations thereof.

According to an embodiment of the present disclosure, Rᵤ is, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof.

According to an embodiment of the present disclosure, at least one of X₃ to X₆ is selected from CRₓ, the Rₓ is a cyano group or fluorine, and all the carbon atoms in the substituent Rₙ are selected from a primary carbon, a secondary carbon or a tertiary carbon.

According to an embodiment of the present disclosure, at least one of X₄ to X₆ is selected from CR_{y}, the Rₓ is a cyano group or fluorine, and all the carbon atoms in the substituent Rₙ are selected from a primary carbon, a secondary carbon or a tertiary carbon.

According to an embodiment of the present disclosure, X₆ is CRₓ, the Rₓ is a cyano group or fluorine, and all the carbon atoms in the substituent Rₙ are selected from a primary carbon, a secondary carbon or a tertiary carbon.

According to an embodiment of the present disclosure, X₃ to X₆ are, at each occurrence identically or differently, selected from CRₓ, the Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms and combinations thereof, and at least one of all the carbon atoms in the substituent Rₙ is a quaternary carbon.

According to an embodiment of the present disclosure, X₄ to X₆ are, at each occurrence identically or differently, selected from CRₓ, the Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms and combinations thereof, and at least one of all the carbon atoms in the substituent Rₙ is a quaternary carbon.

According to an embodiment of the present disclosure, X₆ is CRₓ, the Rₓ is, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof, and at least one of all the carbon atoms in the substituent Rₙ is a quaternary carbon.

According to an embodiment of the present disclosure, at least one of Y₃ to Y₆ is selected from CR_{y}, wherein the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one of Y₃ to Y₆ is selected from CR_{y}, wherein the R_{y} is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof.

According to an embodiment of the present disclosure, at least one of Y₃ to Y₆ is selected from CR_{y}, wherein the R_{y} is selected from the group consisting of: deuterium, fluorine, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, trimethylsilyl, trimethylgermanyl and combinations thereof.

According to an embodiment of the present disclosure, at least one or at least two of U₁ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms or a combination thereof, and the total number of carbon atoms in all of the Rᵤ is at least 4.

According to an embodiment of the present disclosure, at least one or at least two of U₁ to U₄ are selected from CRᵤ, the Rᵤ is selected from substituted or unsubstituted alkyl having 1 to 20 carbon atoms, substituted or unsubstituted cycloalkyl having 3 to 20 ring carbon atoms or a combination thereof, and the total number of carbon atoms in all of the Rᵤ is at least 4.

According to an embodiment of the present disclosure, at least one or at least two of U₅ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms or a combination thereof, and the total number of carbon atoms in all of the Rᵤ is at least 4.

According to an embodiment of the present disclosure, Ar is, at each occurrence identically or differently, selected from the group consisting of Ar1 to Ar147, wherein the specific structures of Ar1 to Ar147 are referred to claim 15.

According to an embodiment of the present disclosure, hydrogen in Ar1 to Ar114, Ar116 to Ar126, Ar129, Ar131 to Ar136, Ar142, Ar143, Ar146 and Ar147 can be partially or fully substituted with deuterium.

According to an embodiment of the present disclosure, Lₐ is, at each occurrence identically or differently, selected from the group consisting of Lₐ₁ to Lₐ₆₉₅₄, wherein the specific structures of Lₐ₁ to Lₐ₆₉₅₄ are referred to claim 16.

According to an embodiment of the present disclosure, hydrogen in Lₐ₁ to Lₐ₆₉₅₄ can be partially or fully substituted with deuterium.

According to an embodiment of the present disclosure, L_{b} is, at each occurrence identically or differently, selected from the group consisting of L_{b1} to L_{b158}, wherein the specific structures of L_{b1} to L_{b158} are referred to claim 17.

According to an embodiment of the present disclosure, hydrogen in L_{b1} to L_{b18}, L_{b20} to L_{b26} and L_{b31} to L_{b158} can be partially or fully substituted with deuterium.

According to an embodiment of the present disclosure, the metal complex has a structure of Ir(Lₐ)₃ or Ir(Lₐ)(L_{b})₂ or Ir(Lₐ)₂(L_{b}), wherein Lₐ is, at each occurrence identically or differently, selected from one, two or three of the group consisting of Lₐ₁ to Lₐ₆₉₅₄, and L_{b} is, at each occurrence identically or differently, selected from one or two of the group consisting of L_{b1} to L_{b158}.

According to an embodiment of the present disclosure, the metal complex is selected from the group consisting of Metal Complex 1 to Metal Complex 6728, wherein the specific structures of Metal Complex 1 to Metal Complex 6728 are referred to claim 18.

According to an embodiment of the present disclosure, further disclosed is an organic electroluminescent device comprising an anode, a cathode and an organic layer disposed between the anode and the cathode, wherein at least one layer of the organic layer comprises the metal complex in any one of the preceding embodiments.

According to an embodiment of the present disclosure, the organic layer comprising the metal complex is a light-emitting layer.

According to an embodiment of the present disclosure, the light-emitting layer further comprises a first host compound.

According to an embodiment of the present disclosure, the light-emitting layer further comprises a first host compound and a second host compound.

According to an embodiment of the present disclosure, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the first host compound has a structure represented by Formula X-1 or Formula X-2:

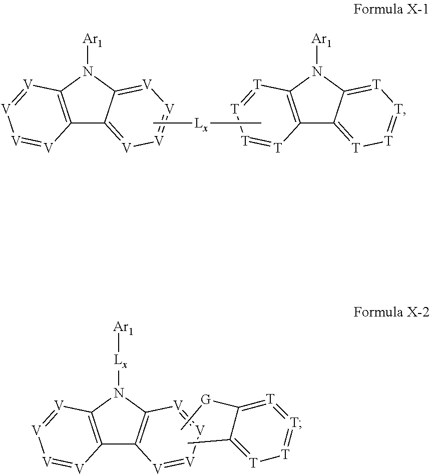

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CRᵥ or N;
in Formula X-1, T is, at each occurrence identically or differently, selected from C, CRₜ or N;
in Formula X-2, T is, at each occurrence identically or differently, selected from CRₜ or N;
R_{g}, Rᵥ and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and Rₜ can be optionally joined to form a ring.

In this embodiment, the expression that “adjacent substituents R_{g}, Rᵥ and Rₜ can be optionally joined to form a ring” is intended to mean that any one or more of groups of adjacent substituents, such as two substituents Rᵥ, two substituents Rₜ, two substituents R_{g}, substituents Rᵥ and Rₜ, substituents Rᵥ and R_{g}, and substituents R_{g} and Rₜ, can be joined to form a ring. Obviously, it is also possible that none of these substituents are joined to form a ring.

According to an embodiment of the present disclosure, the first host compound has a structure represented by one of Formula X-a to Formula X-p:

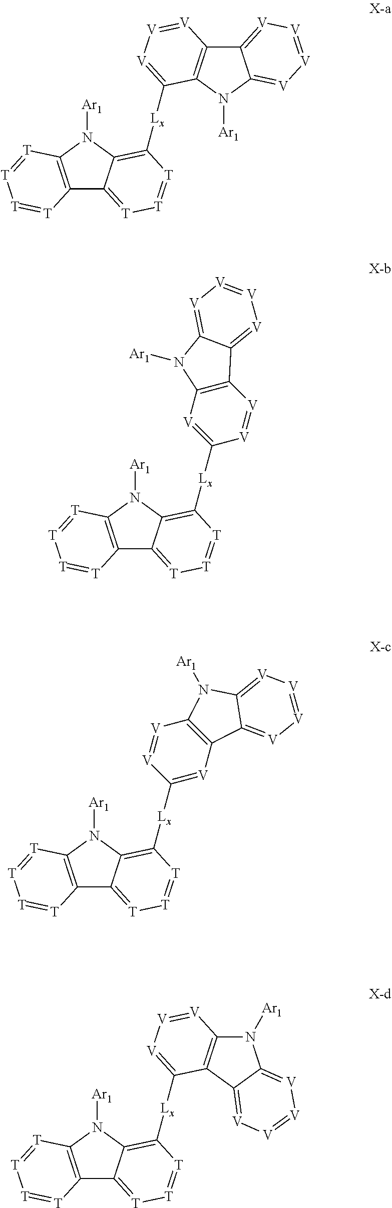

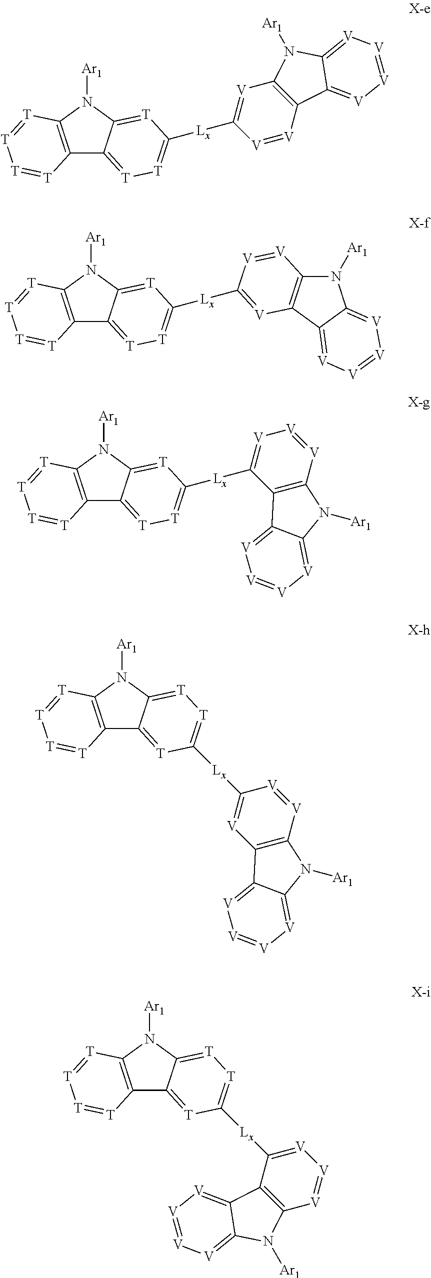

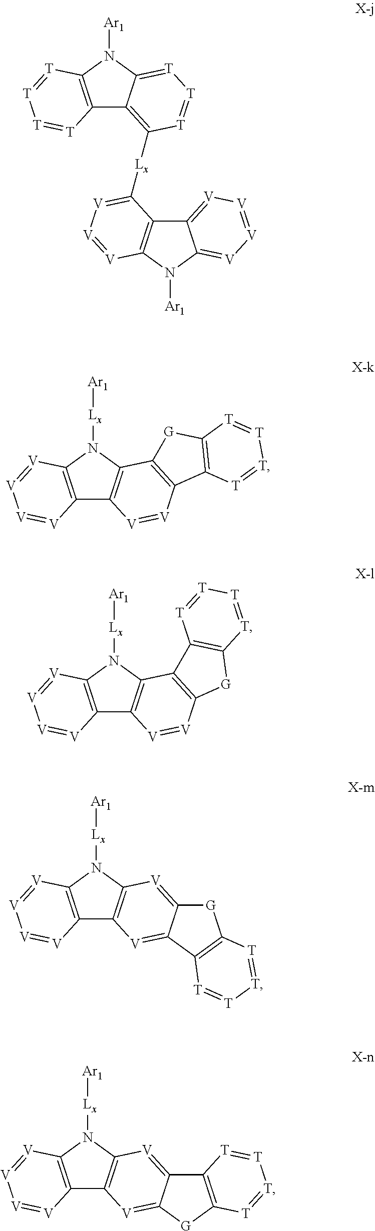

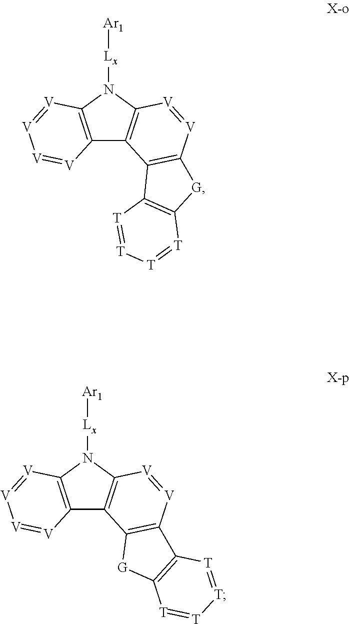

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from CRᵥ or N;
T is, at each occurrence identically or differently, selected from CRₜ or N;
R_{g}, R_{y} and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and Rₜ can be optionally joined to form a ring.

According to an embodiment of the present disclosure, the first host compound is selected from the group consisting of the following compounds:

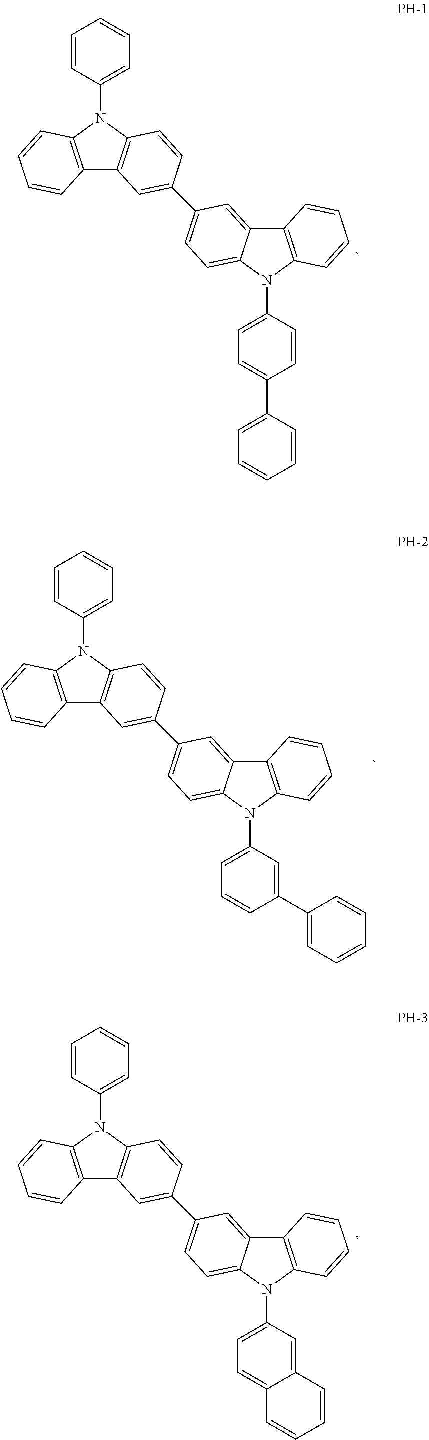 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

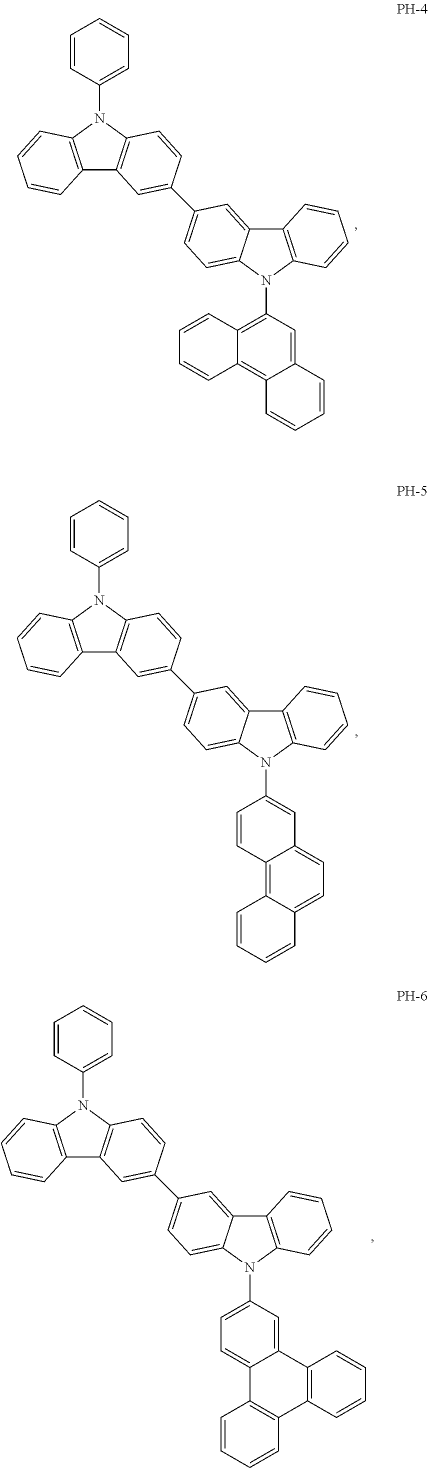 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

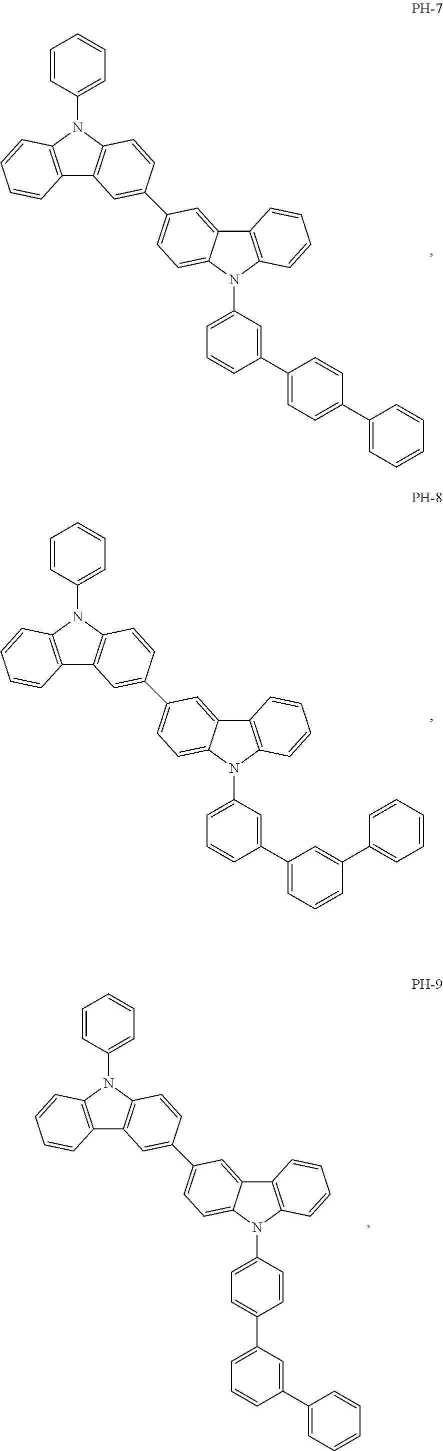 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

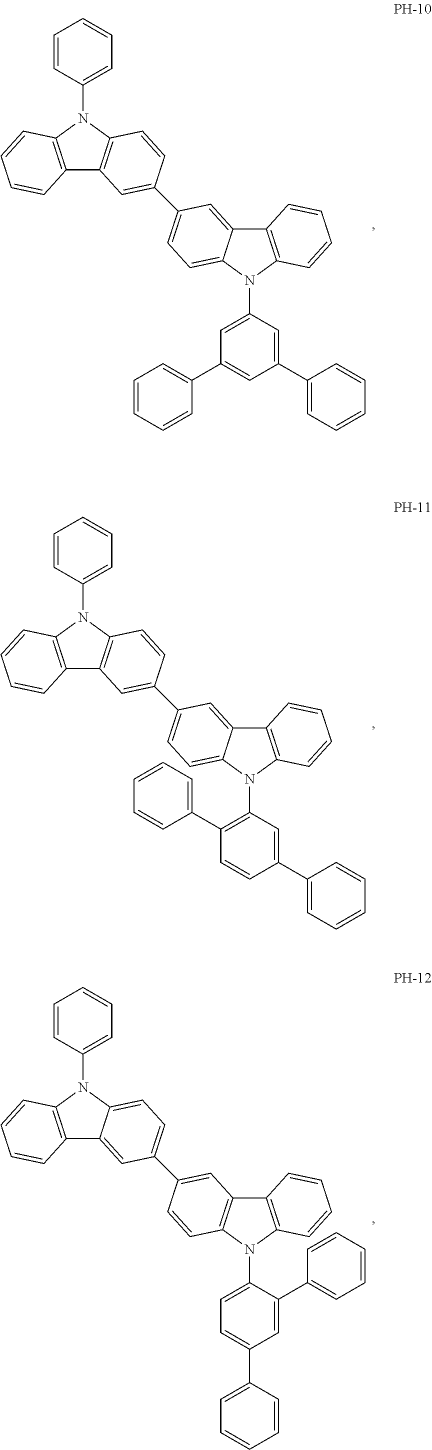 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

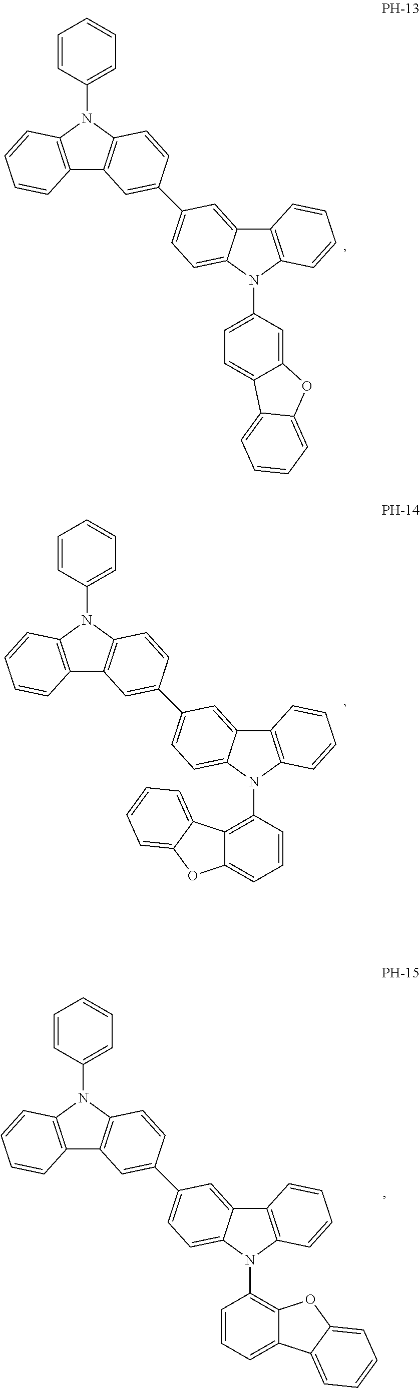 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

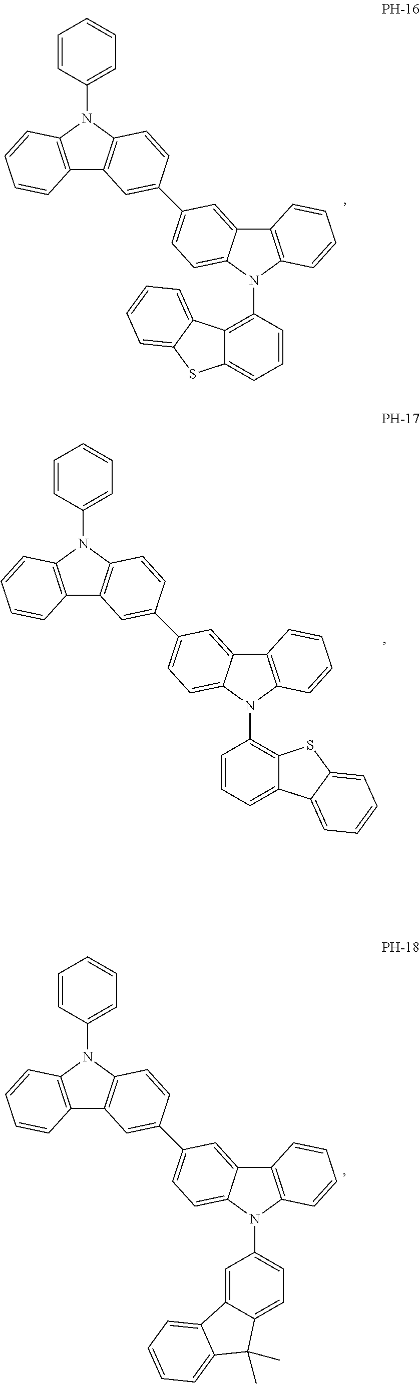 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21]

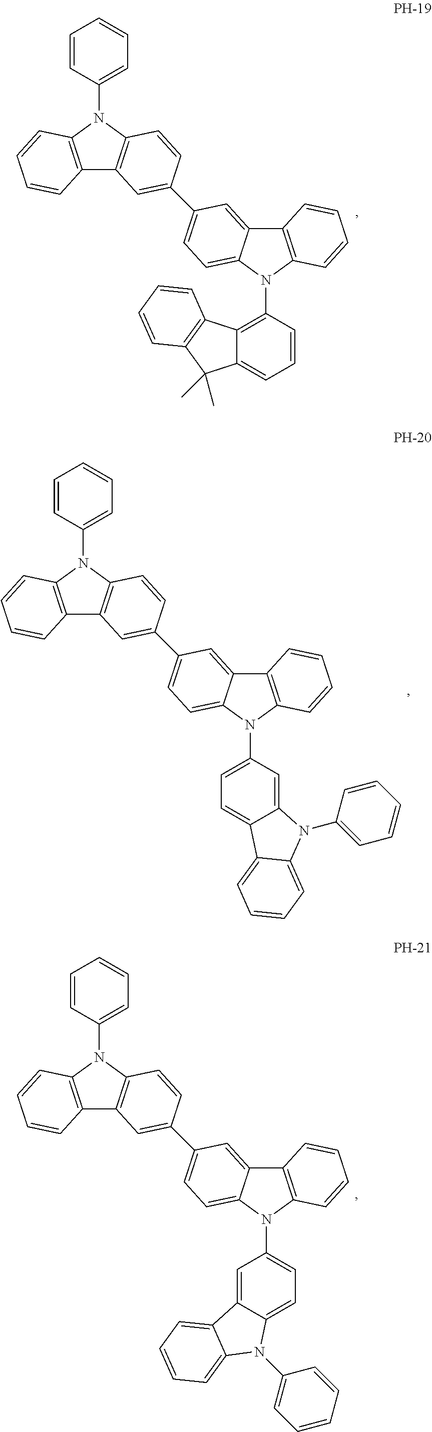 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

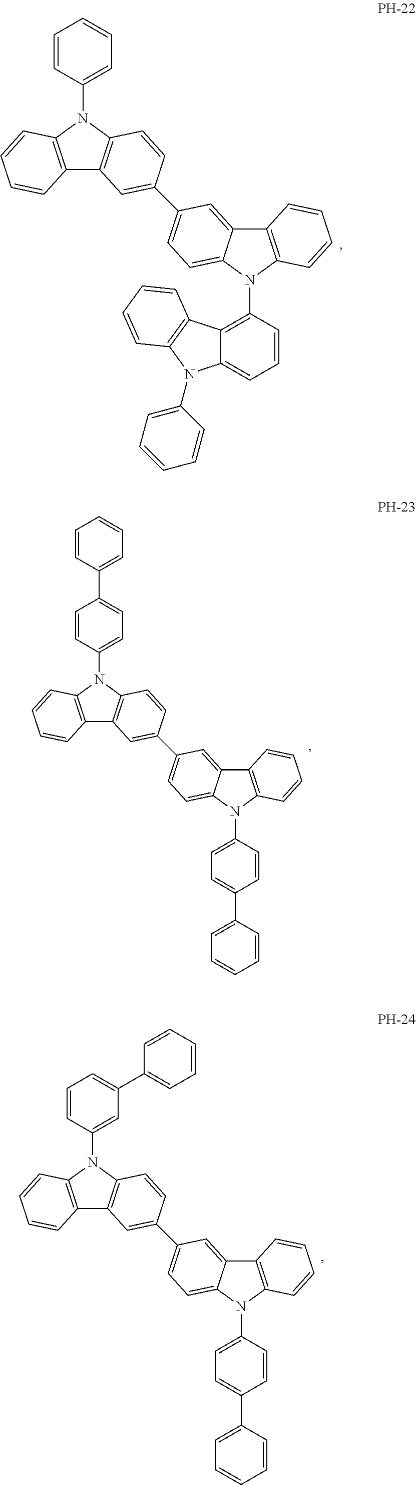 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

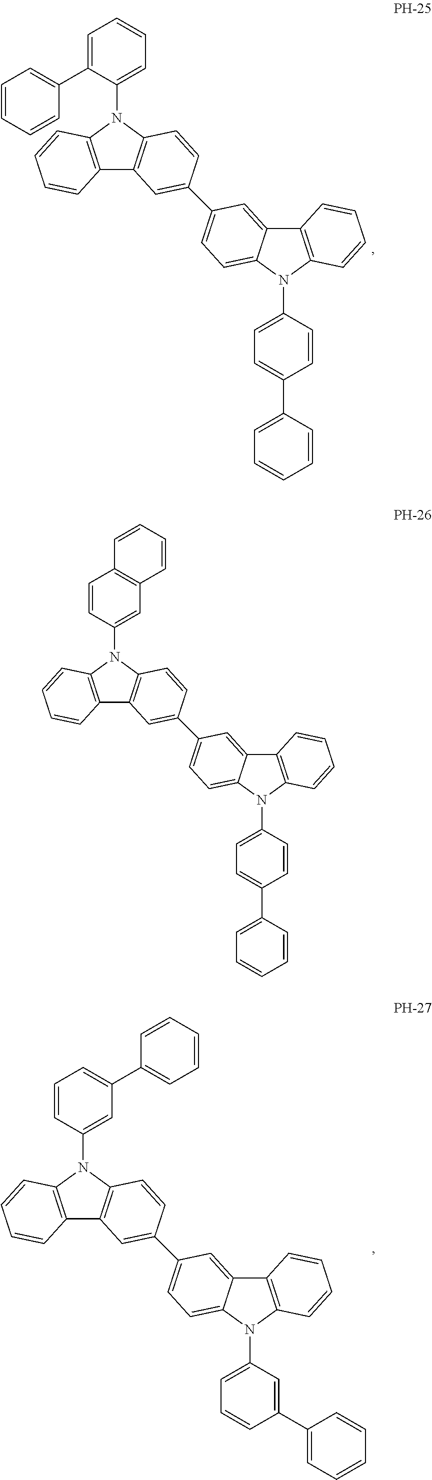 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

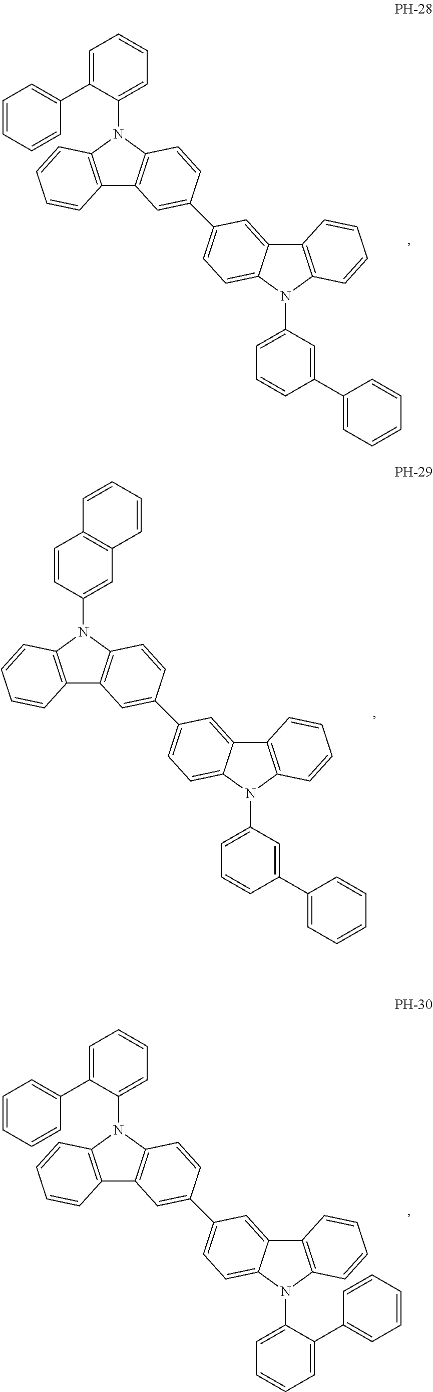 [SMILES: c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1]

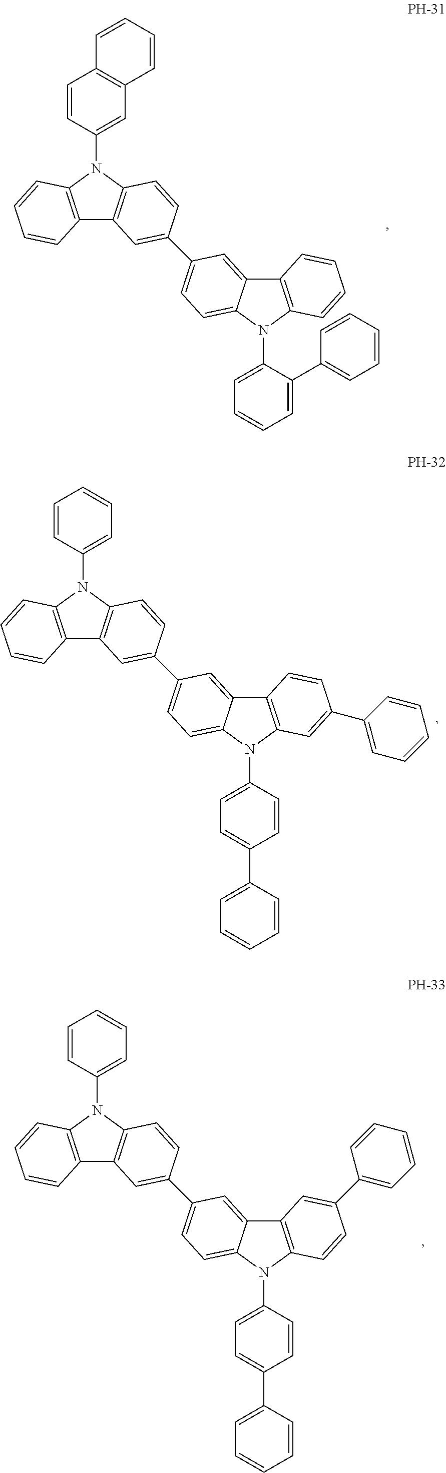 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1]

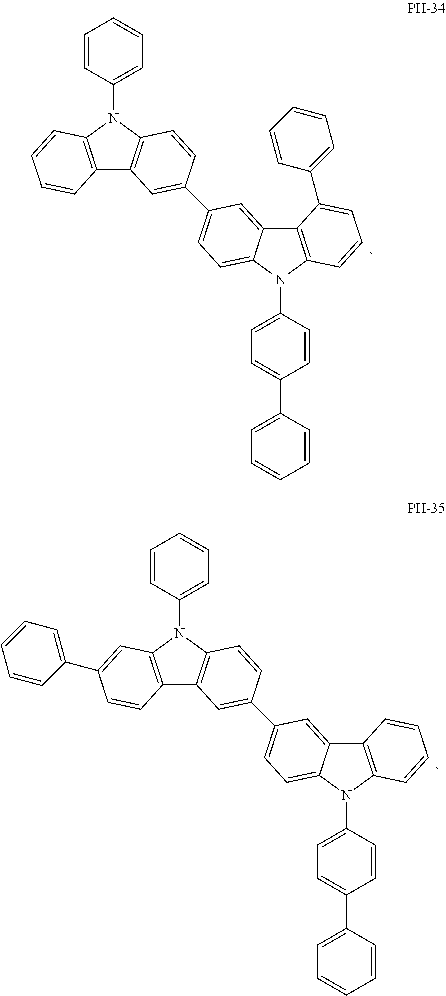 [SMILES: c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2ccc(-n3c4ccccc4c4cc(-c5ccc6c(c5)c5ccc(-c7ccccc7)cc5n6-c5ccccc5)ccc43)cc2)cc1]

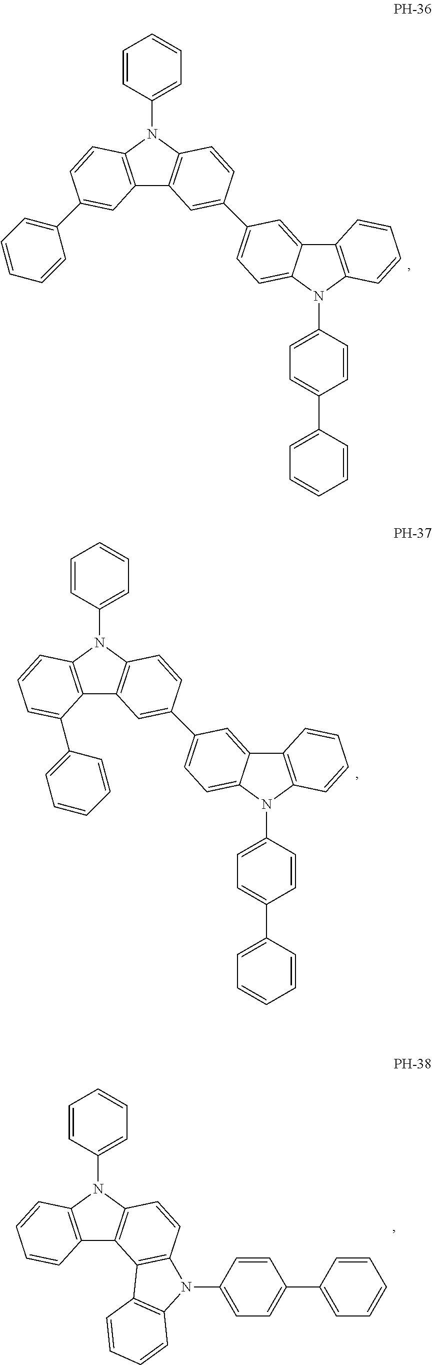 [SMILES: c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1]

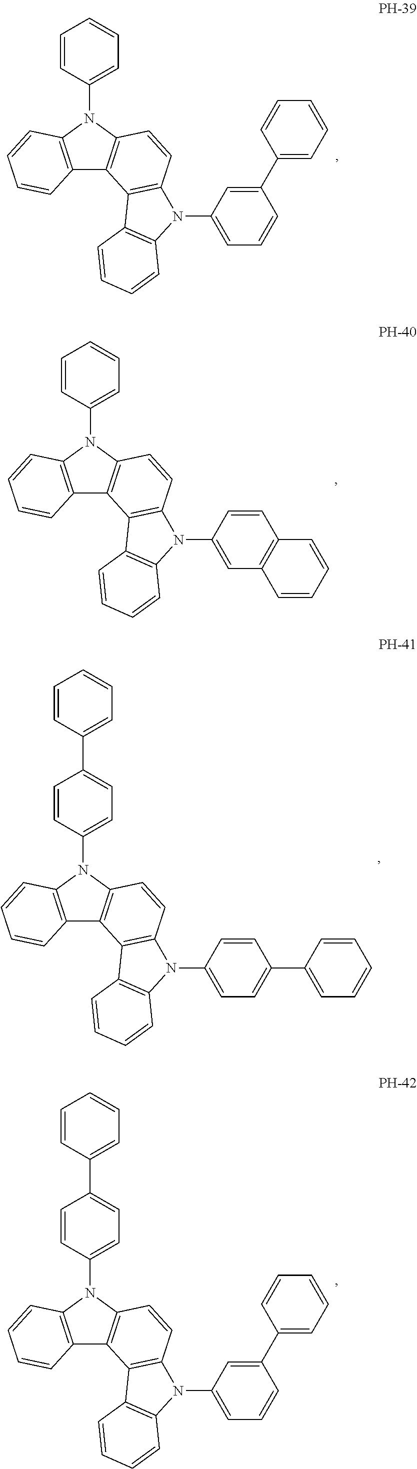 [SMILES: c1ccc(-c2cccc(-n3c4ccccc4c4c5c6ccccc6n(-c6ccccc6)c5ccc43)c2)cc1 ; c1ccc(-n2c3ccccc3c3c4c5ccccc5n(-c5ccc6ccccc6c5)c4ccc32)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1]

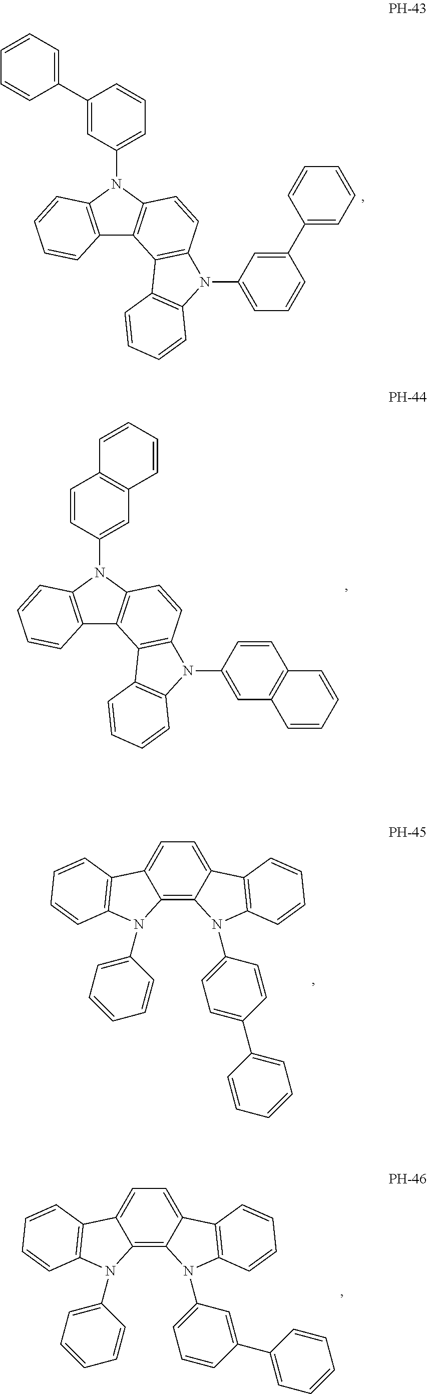 [SMILES: c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1 ; c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1]

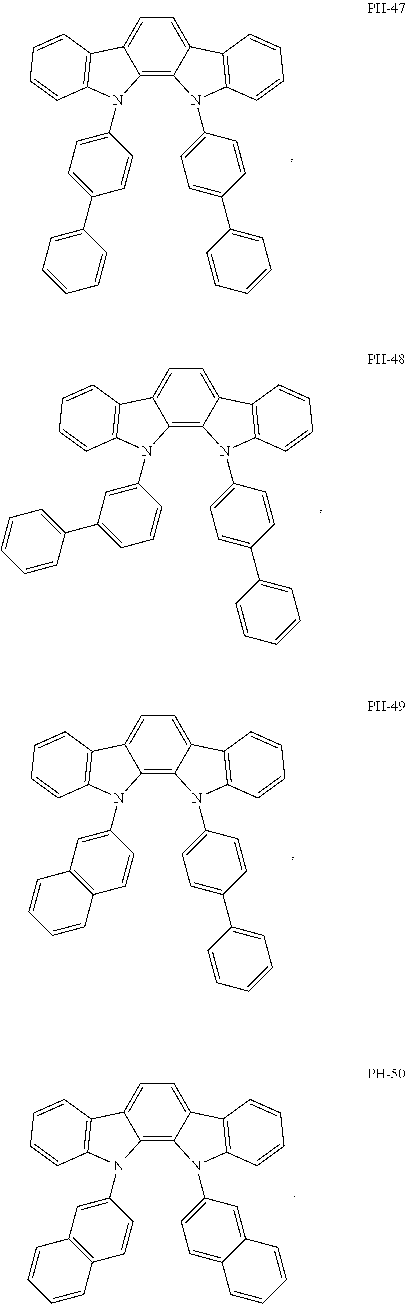 [SMILES: c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to an embodiment of the present disclosure, the second host compound has a structure represented by Formula 4:

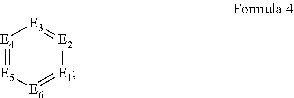

wherein,
E₁ to E₆ are, at each occurrence identically or differently, selected from C, CR_{c} or N, at least two of E₁ to E₆ are N, and at least one of E₁ to E₆ is C and joined to Formula A;

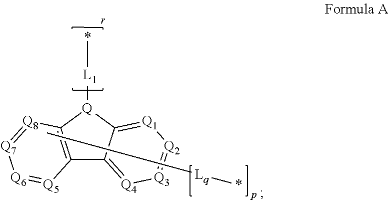

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q} and R_{Q}C═CR_{Q}; when two R_{Q} are present at the same time, the two R_{Q} may be identical or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q} and R_{Q}C═CR_{Q}, p is 1, and r is 0;
L_{q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₑ, R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“*” represents a position where Formula A is joined to Formula 4; and
adjacent substituents Rₑ, R_{Q} and R_{q} can be optionally joined to form a ring.

In the present disclosure, the expression that “adjacent substituents Rₑ, R_{Q} and R_{q} can be optionally joined to form a ring” is intended to mean that any one or more of groups of adjacent substituents, such as two substituents Rₑ, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the second host compound is selected from the group consisting of the following compounds:

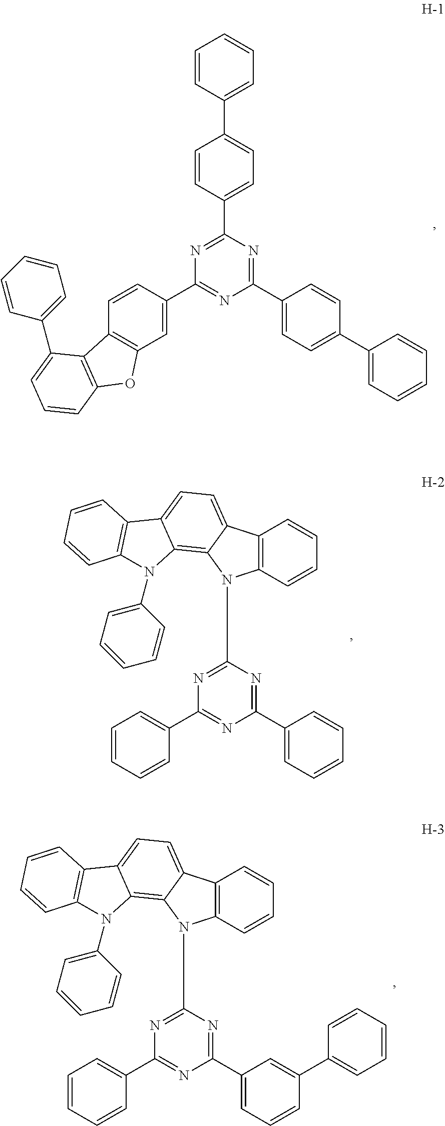 [SMILES: c1ccc(-c2ccc(-c3nc(-c4ccc(-c5ccccc5)cc4)nc(-c4ccc5c(c4)oc4cccc(-c6ccccc6)c45)n3)cc2)cc1 ; c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1]

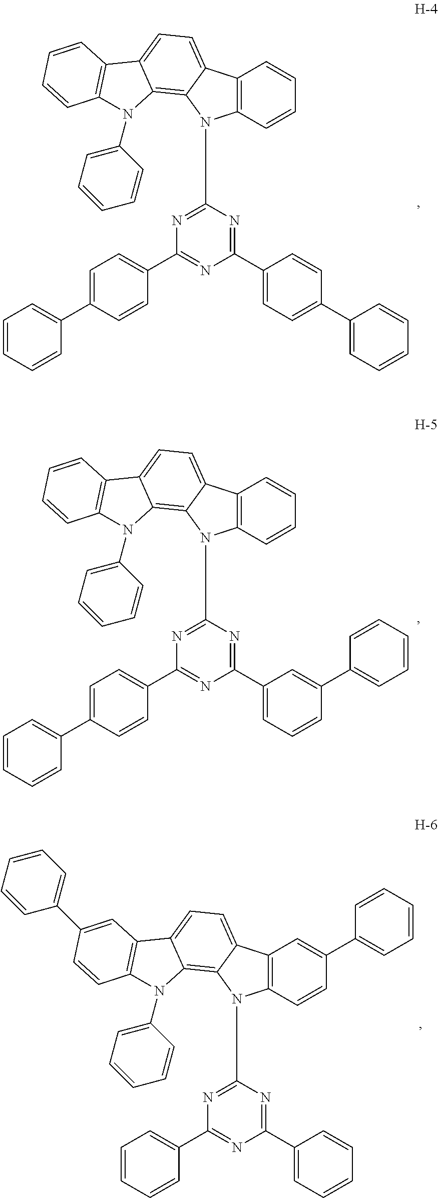 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

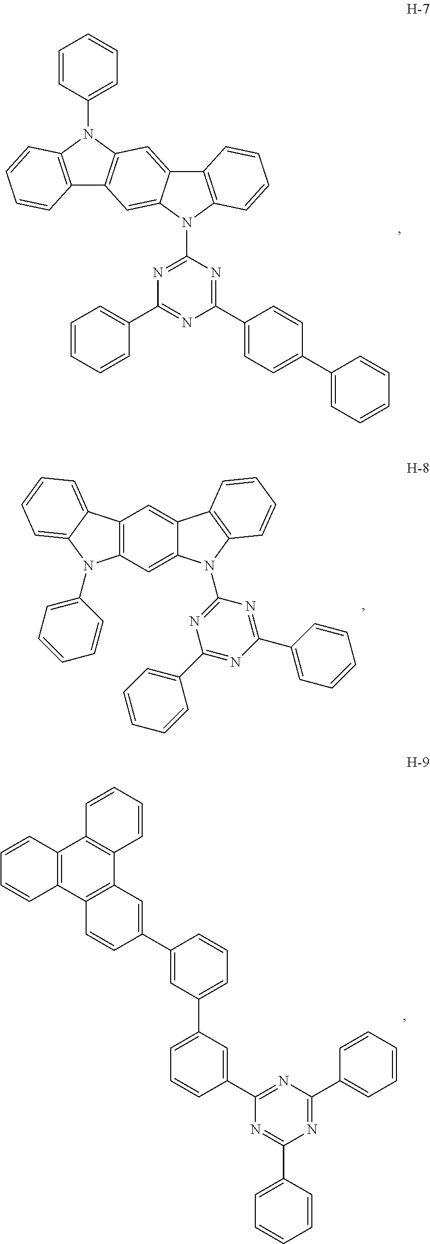 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1]

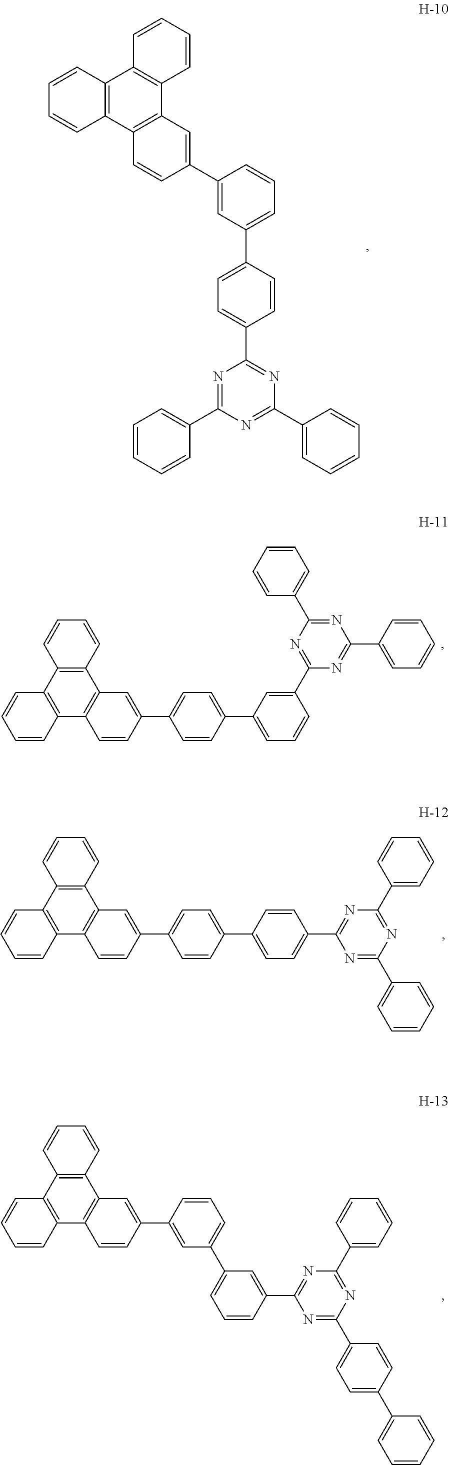 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1]

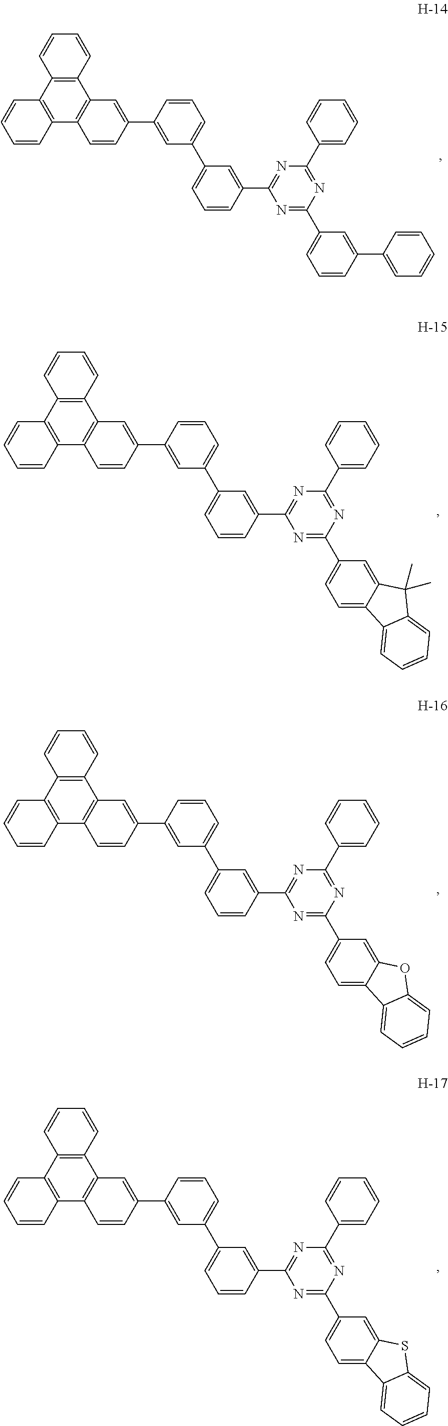 [SMILES: c1ccc(-c2cccc(-c3nc(-c4ccccc4)nc(-c4cccc(-c5cccc(-c6ccc7c8ccccc8c8ccccc8c7c6)c5)c4)n3)c2)cc1 ; CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1]

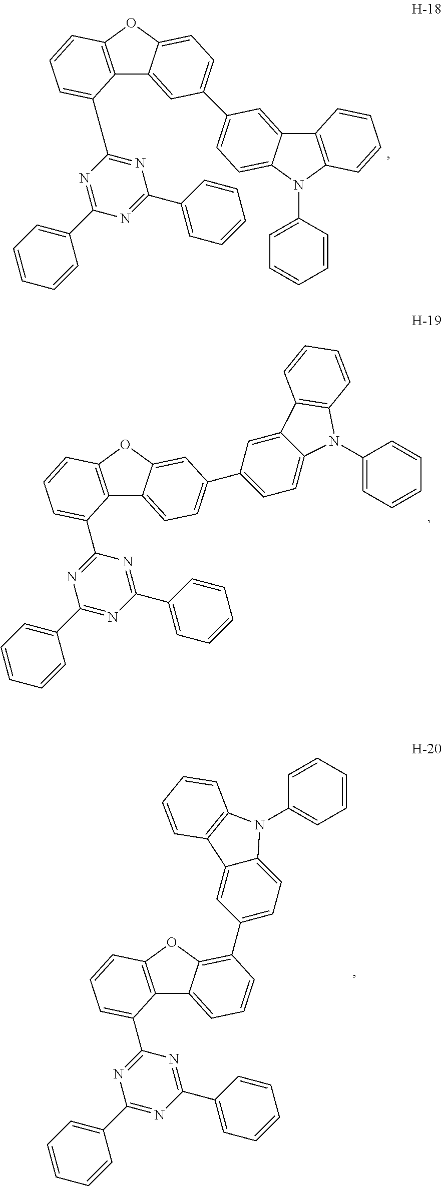 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1]

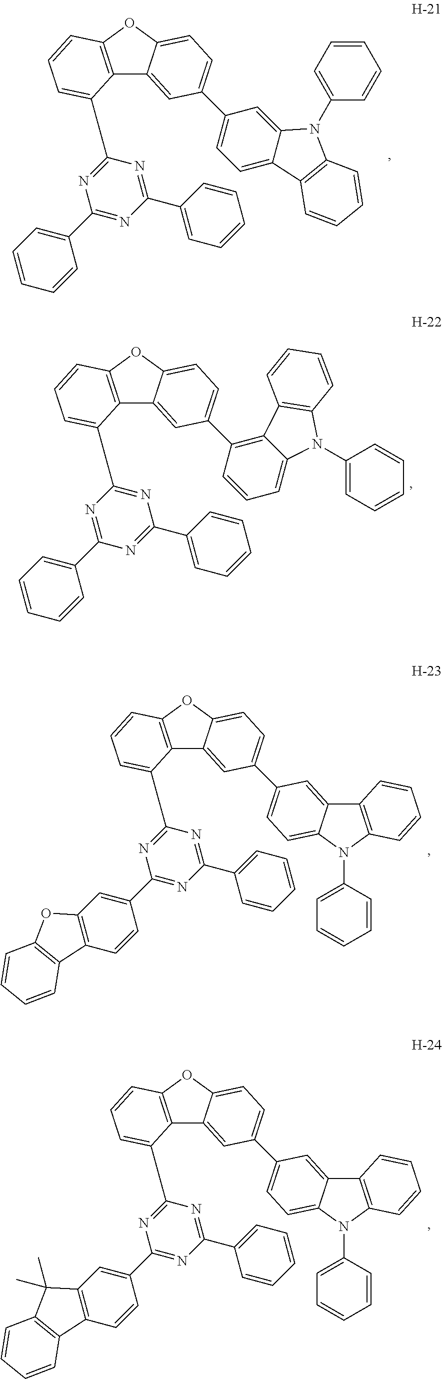 [SMILES: c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21]

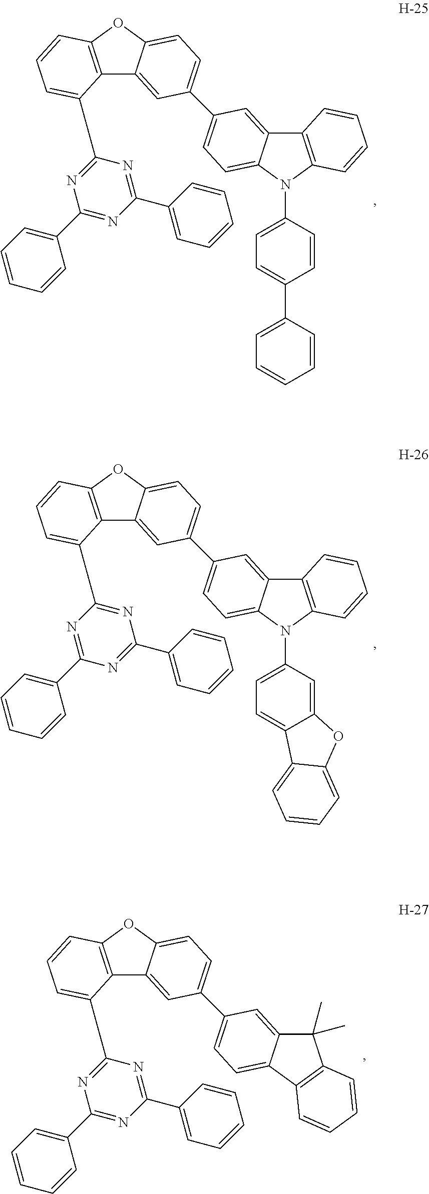 [SMILES: c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21]

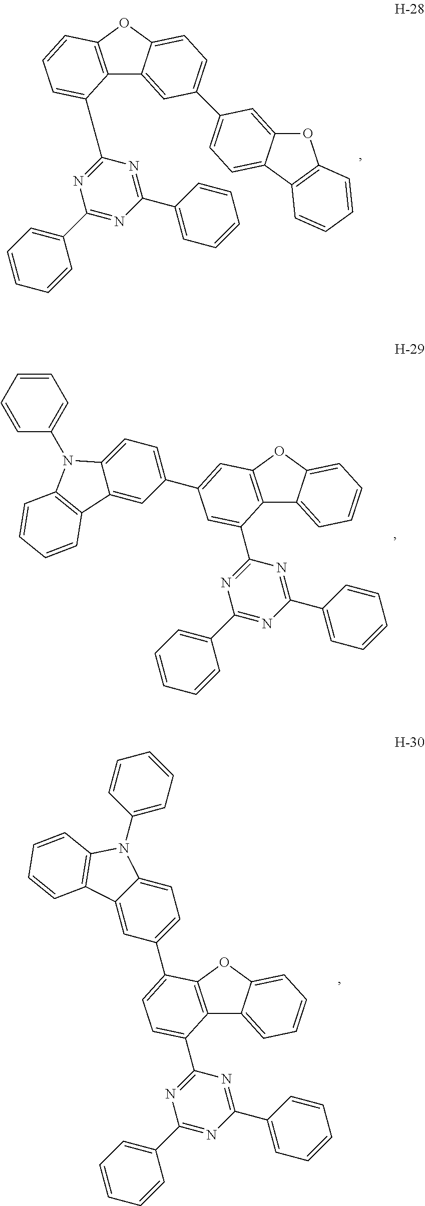 [SMILES: c1ccc(-c2nc(-c3ccccc3)nc(-c3cccc4oc5ccc(-c6ccc7c(c6)oc6ccccc67)cc5c34)n2)cc1 ; c1ccc(-c2nc(-c3ccccc3)nc(-c3cc(-c4ccc5c(c4)c4ccccc4n5-c4ccccc4)cc4oc5ccccc5c34)n2)cc1 ; c1ccc(-c2nc(-c3ccccc3)nc(-c3ccc(-c4ccc5c(c4)c4ccccc4n5-c4ccccc4)c4oc5ccccc5c34)n2)cc1]

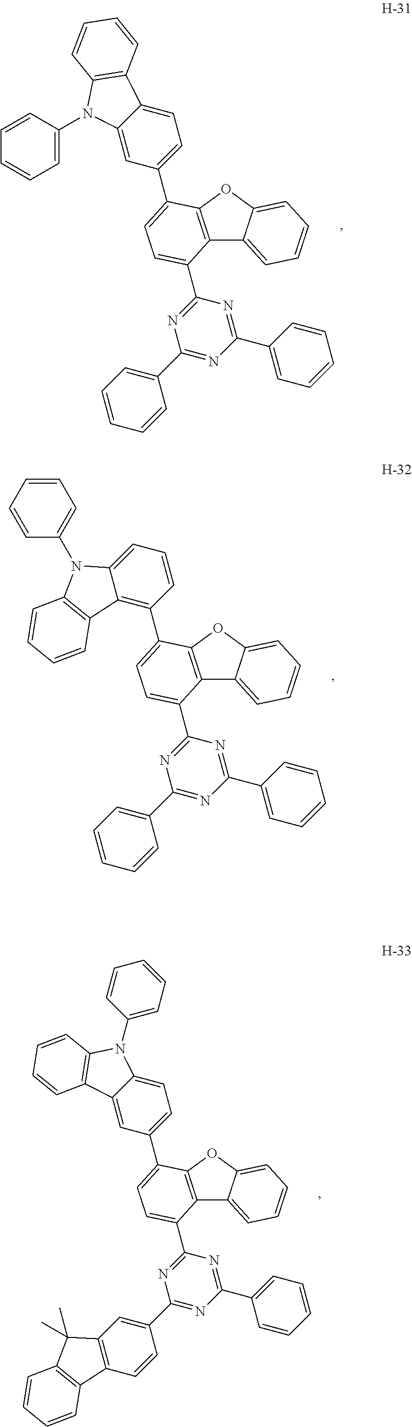 [SMILES: c1ccc(-c2nc(-c3ccccc3)nc(-c3ccc(-c4ccc5c6ccccc6n(-c6ccccc6)c5c4)c4oc5ccccc5c34)n2)cc1 ; c1ccc(-c2nc(-c3ccccc3)nc(-c3ccc(-c4cccc5c4c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21]

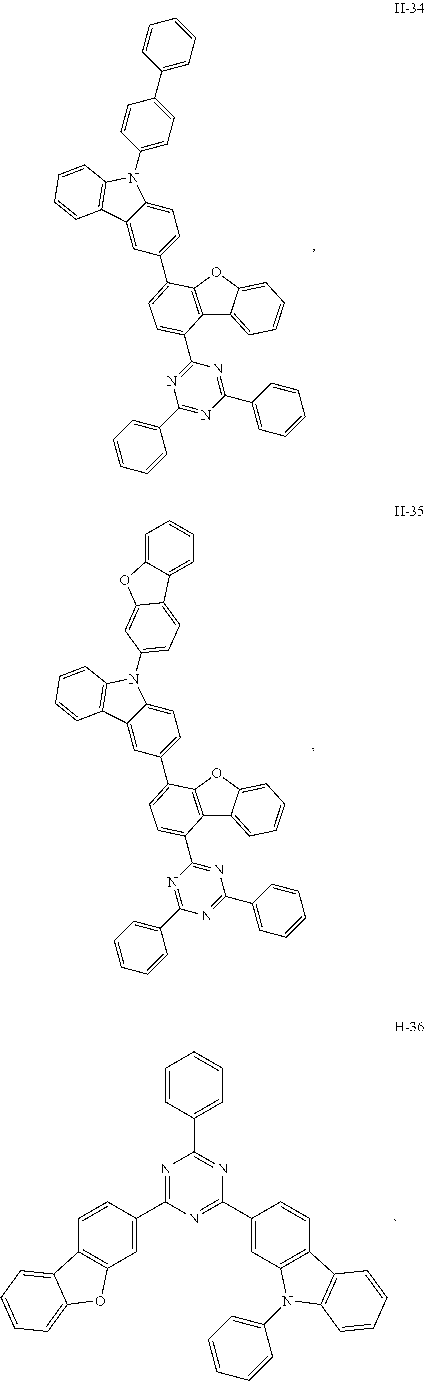 [SMILES: c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1 ; c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1]

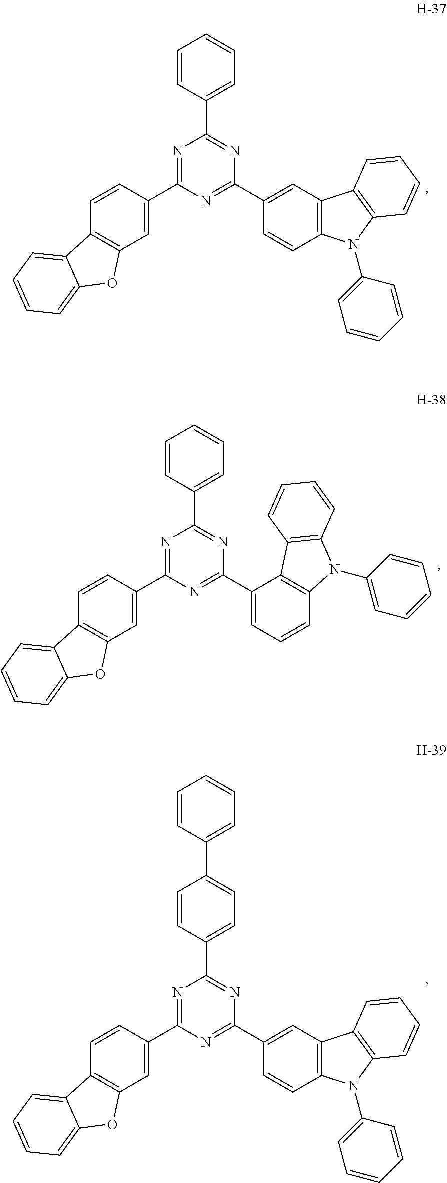 [SMILES: c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1 ; c1ccc(-c2ccc(-c3nc(-c4ccc5c(c4)oc4ccccc45)nc(-c4ccc5c(c4)c4ccccc4n5-c4ccccc4)n3)cc2)cc1]

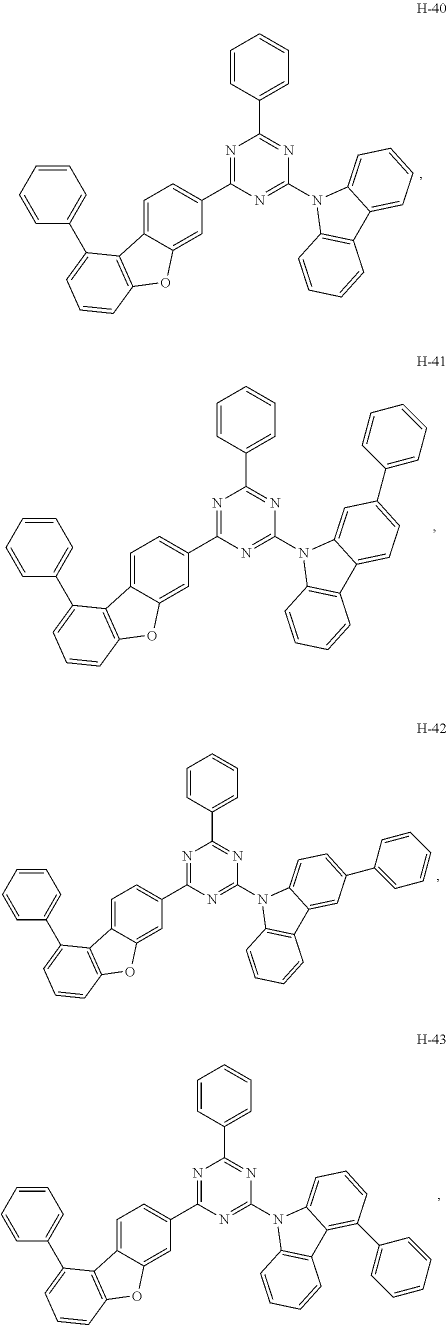 [SMILES: c1ccc(-c2nc(-c3ccc4c(c3)oc3cccc(-c5ccccc5)c34)nc(-n3c4ccccc4c4ccccc43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1 ; c1ccc(-c2nc(-c3ccc4c(c3)oc3cccc(-c5ccccc5)c34)nc(-n3c4ccccc4c4c(-c5ccccc5)cccc43)n2)cc1]

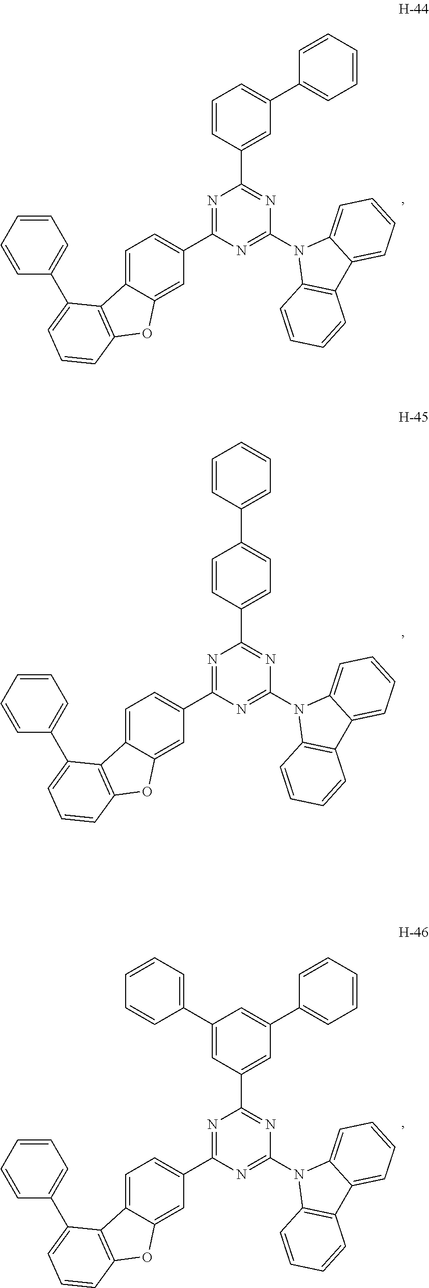 [SMILES: c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1]

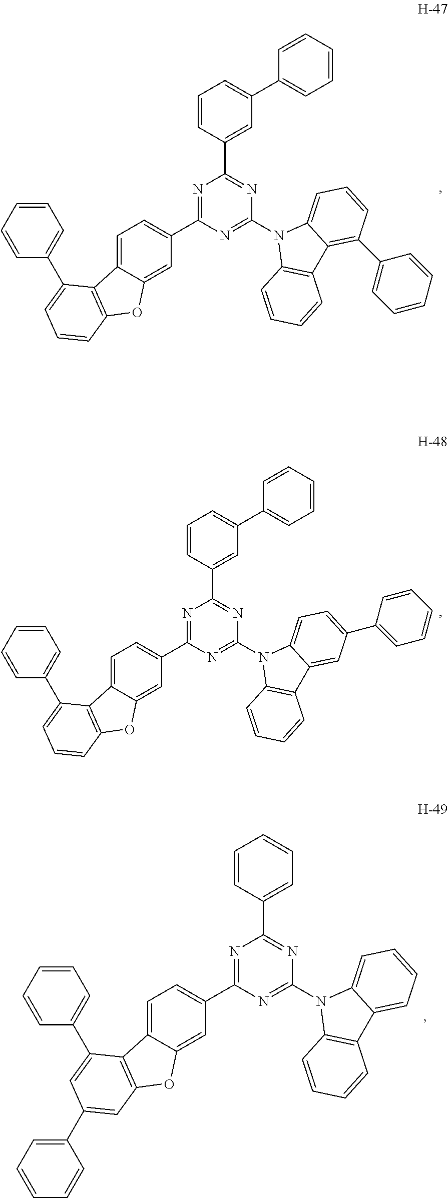 [SMILES: c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1]

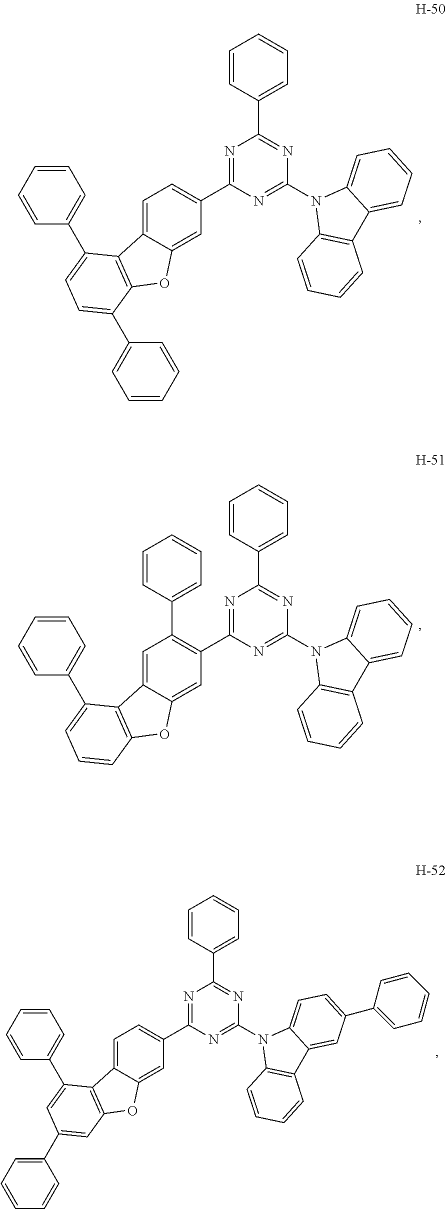 [SMILES: c1ccc(-c2nc(-c3ccc4c(c3)oc3c(-c5ccccc5)ccc(-c5ccccc5)c34)nc(-n3c4ccccc4c4ccccc43)n2)cc1 ; c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1]

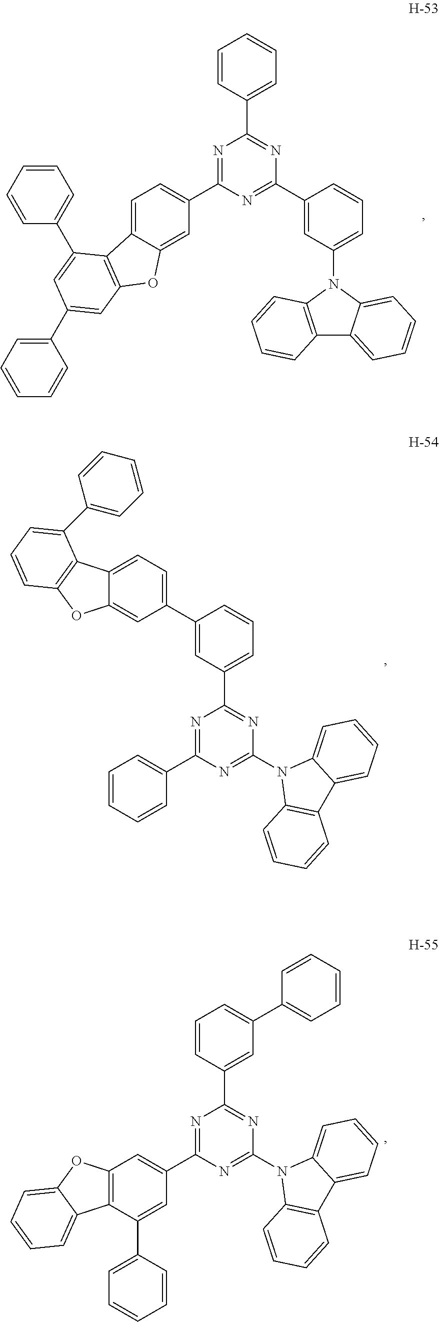 [SMILES: c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1 ; c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2cccc(-c3nc(-c4cc(-c5ccccc5)c5c(c4)oc4ccccc45)nc(-n4c5ccccc5c5ccccc54)n3)c2)cc1]

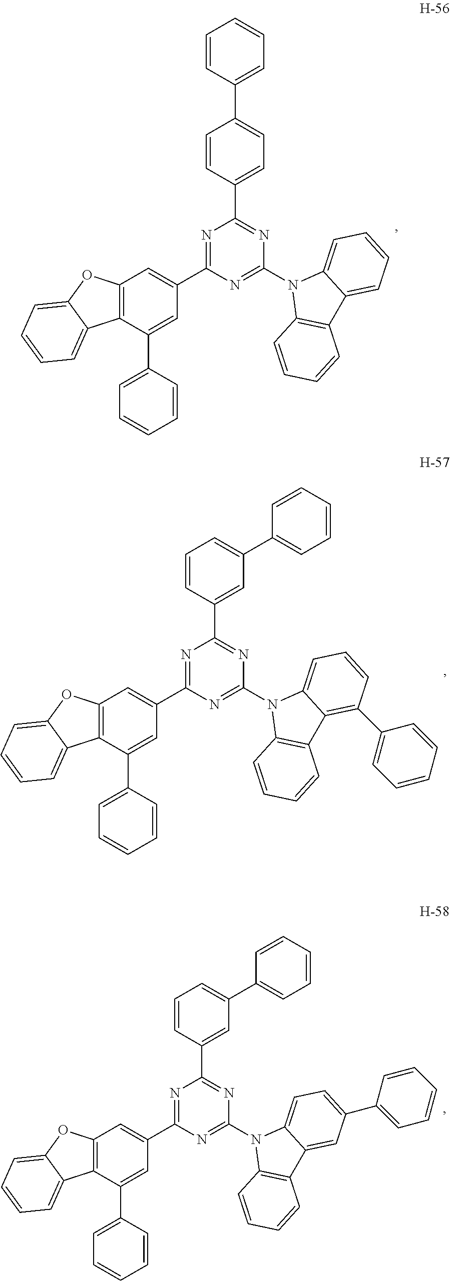 [SMILES: c1ccc(-c2ccc(-c3nc(-c4cc(-c5ccccc5)c5c(c4)oc4ccccc45)nc(-n4c5ccccc5c5ccccc54)n3)cc2)cc1 ; c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1]

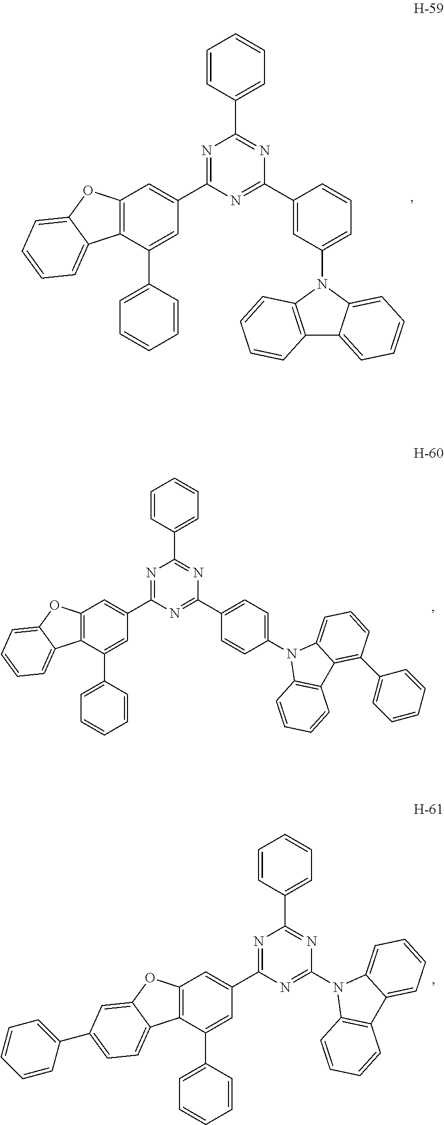 [SMILES: c1ccc(-c2nc(-c3cccc(-n4c5ccccc5c5ccccc54)c3)nc(-c3cc(-c4ccccc4)c4c(c3)oc3ccccc34)n2)cc1 ; c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1]

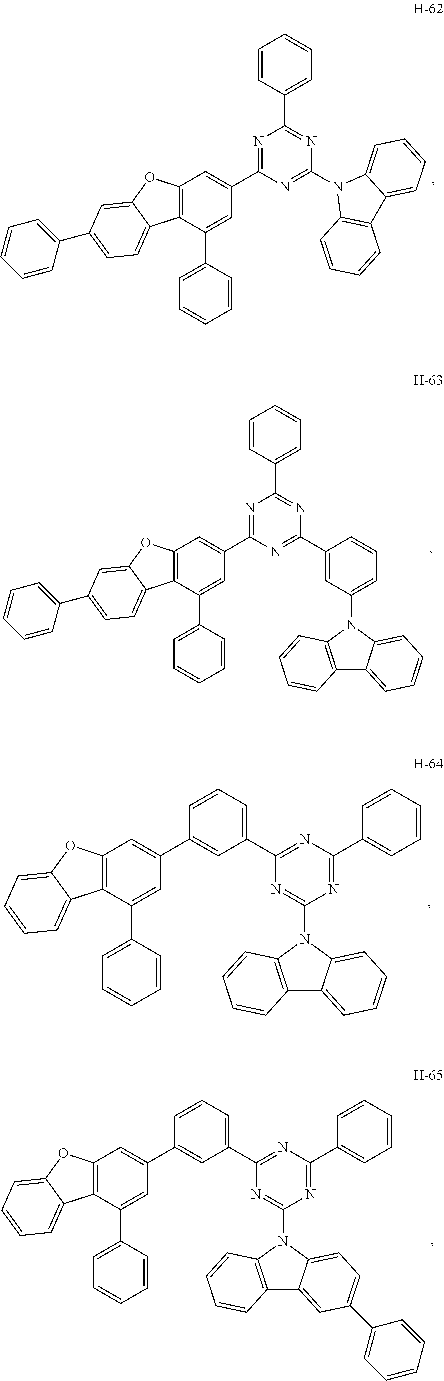 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1]

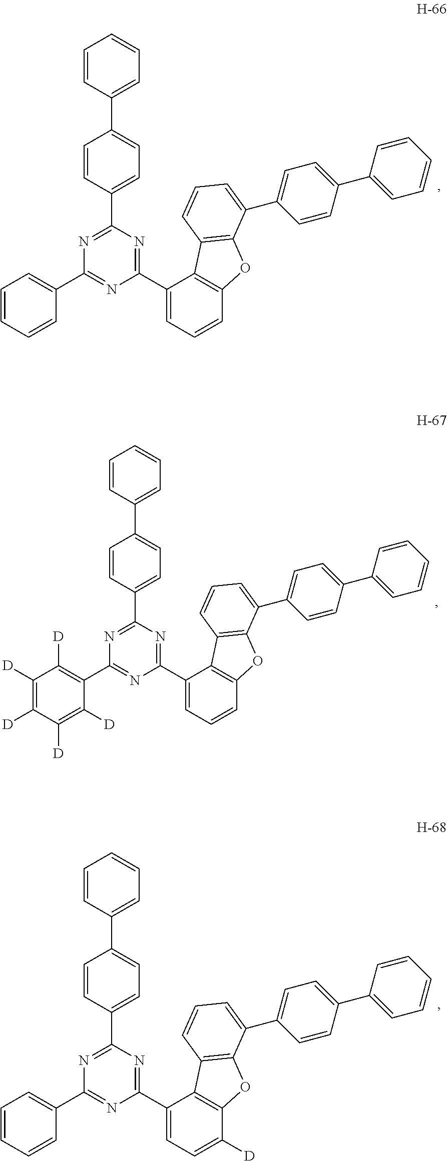 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12]

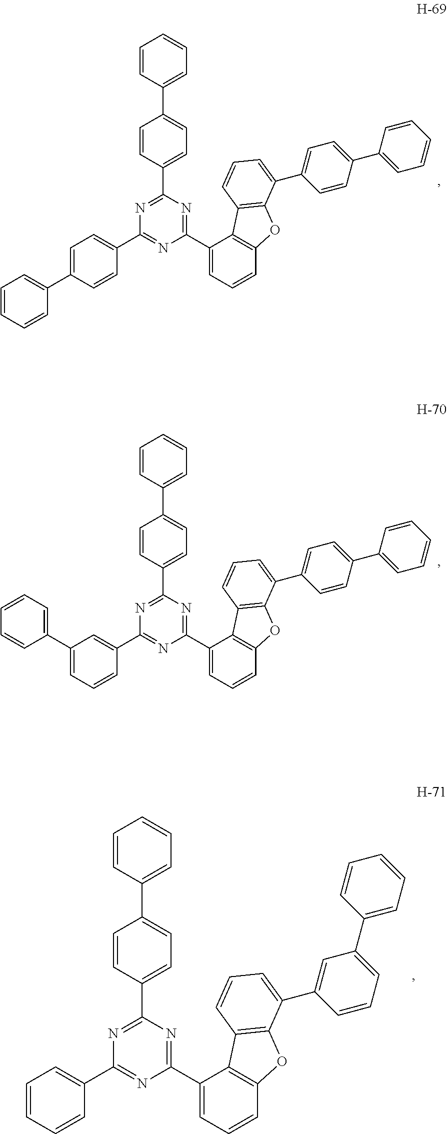 [SMILES: c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1]

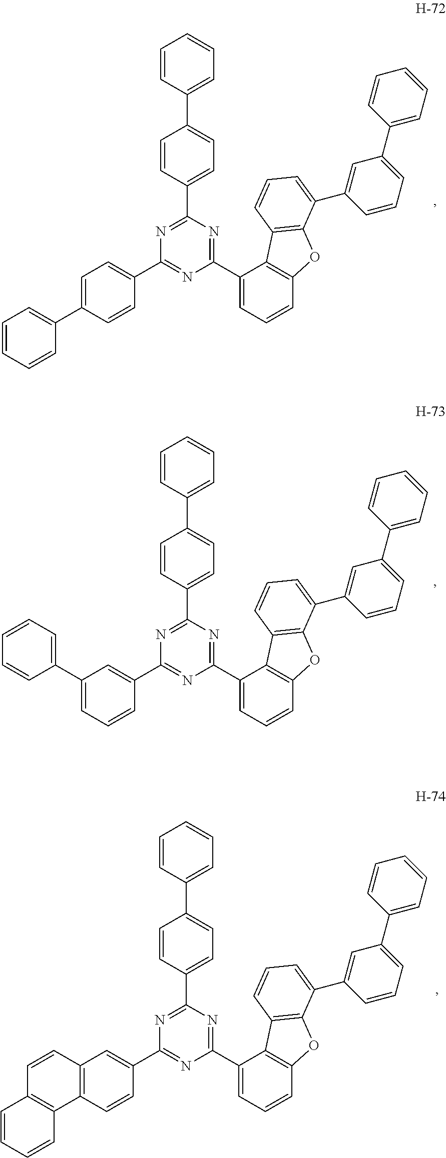 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1]

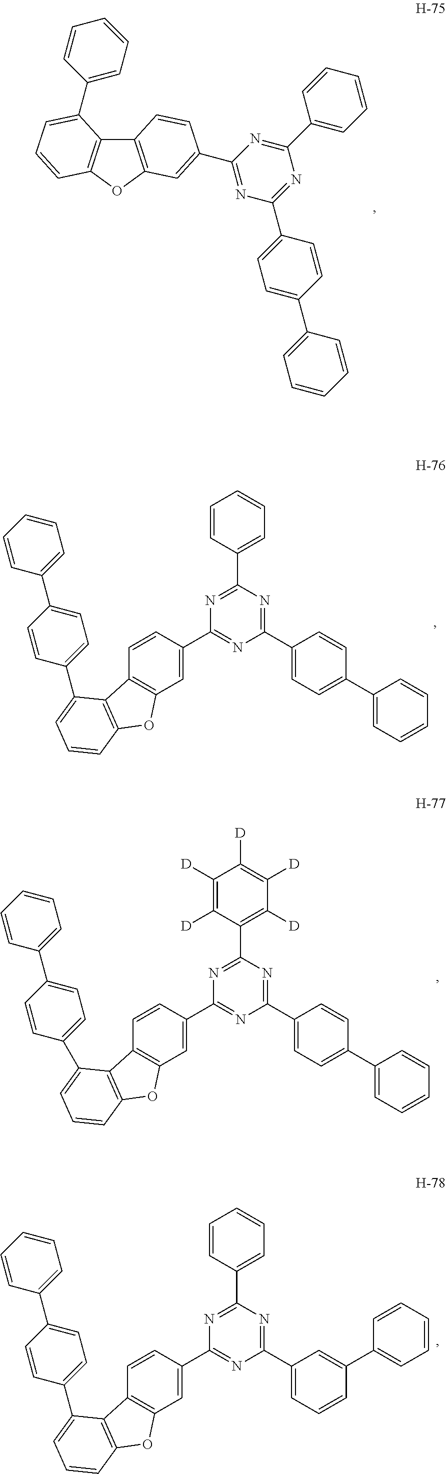 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1]

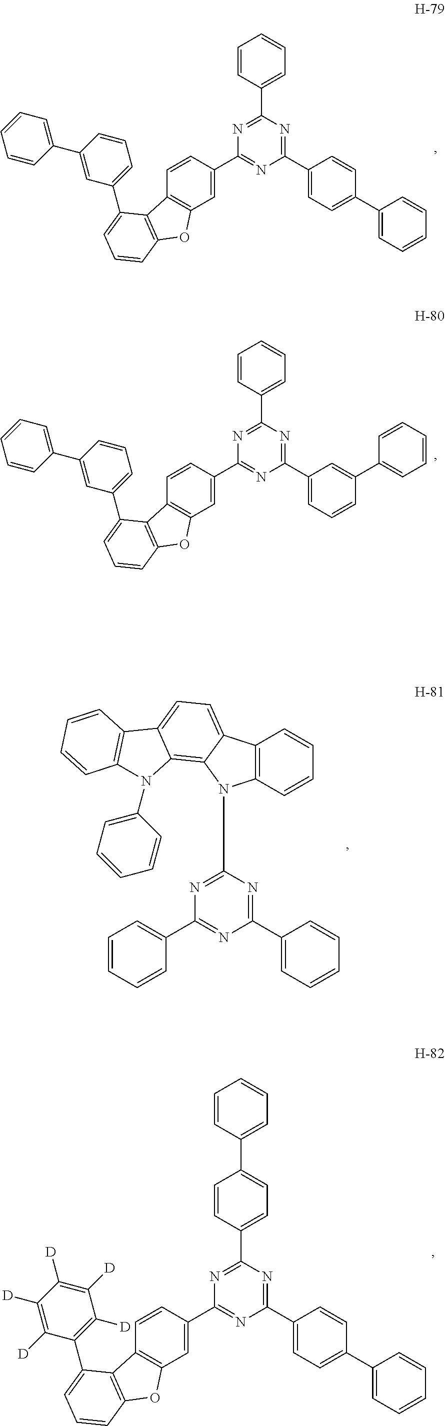 [SMILES: c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2nc(-c3ccccc3)nc(-n3c4ccccc4c4ccc5c6ccccc6n(-c6ccccc6)c5c43)n2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H]]

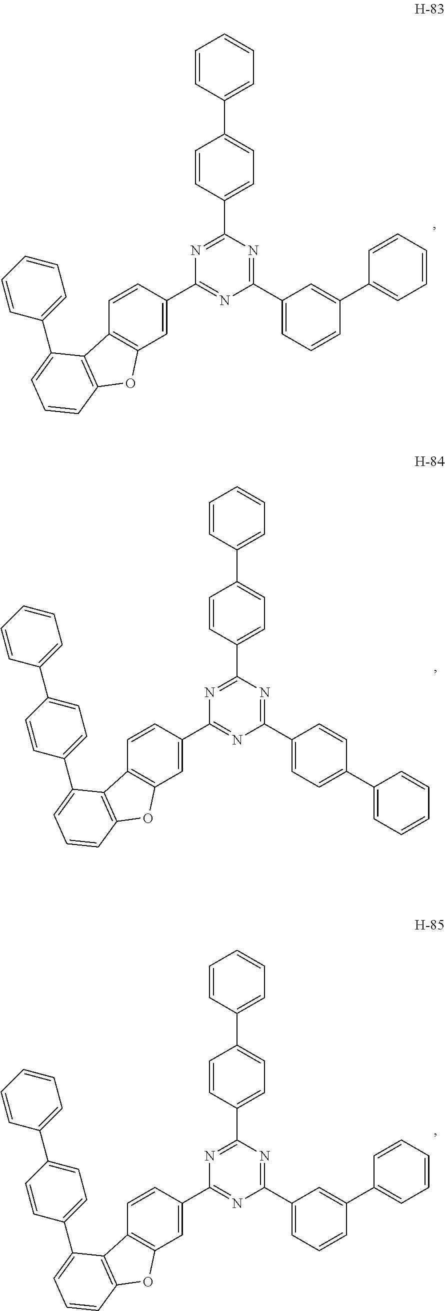 [SMILES: c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1]

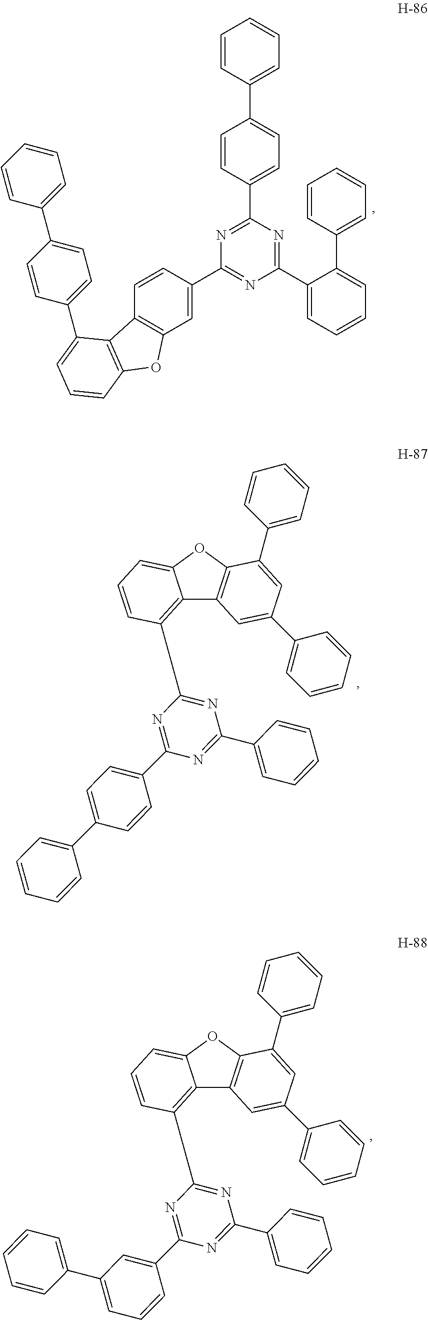 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1]

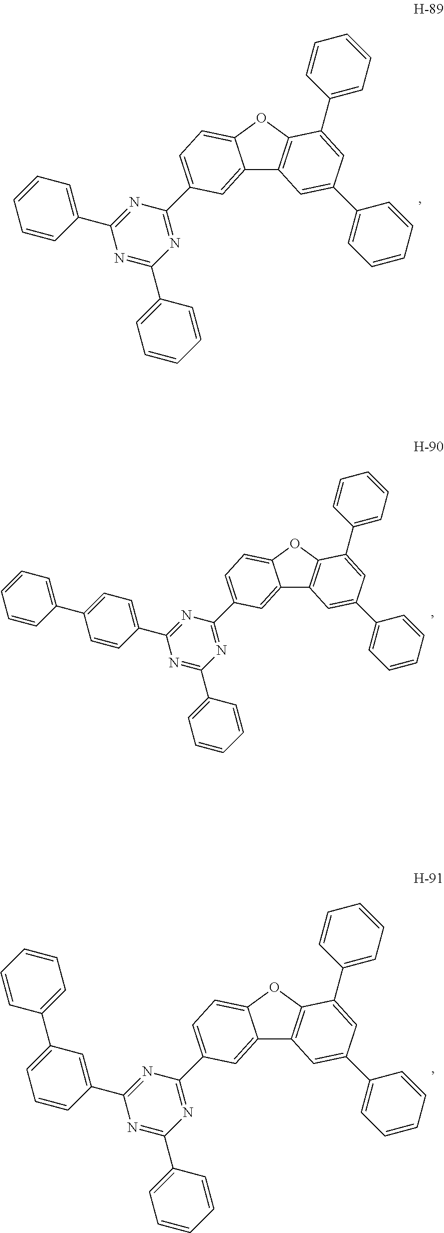 [SMILES: c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1]

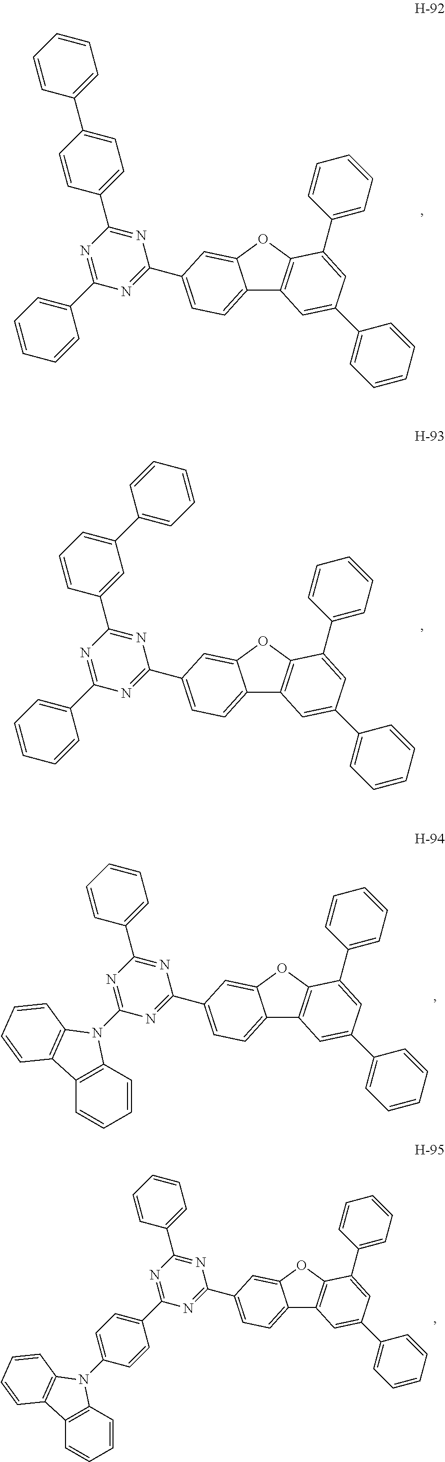 [SMILES: c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1]

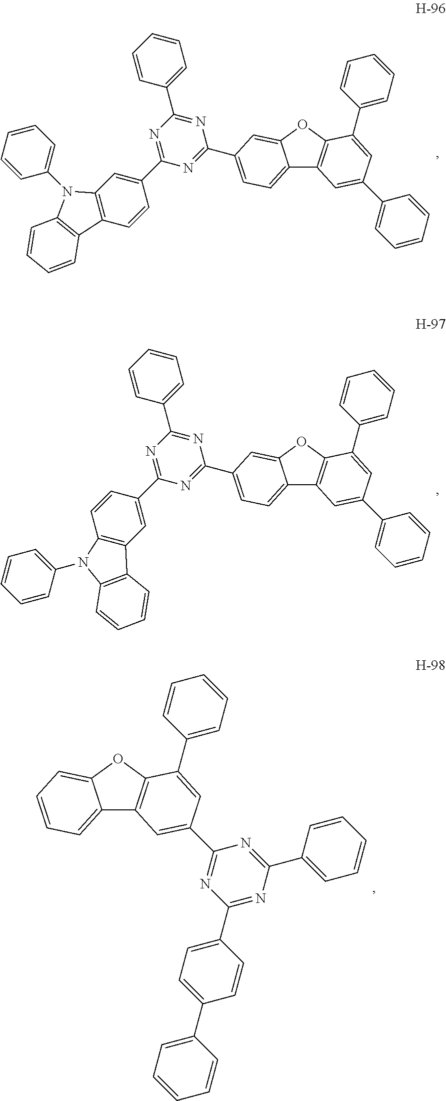 [SMILES: c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1]

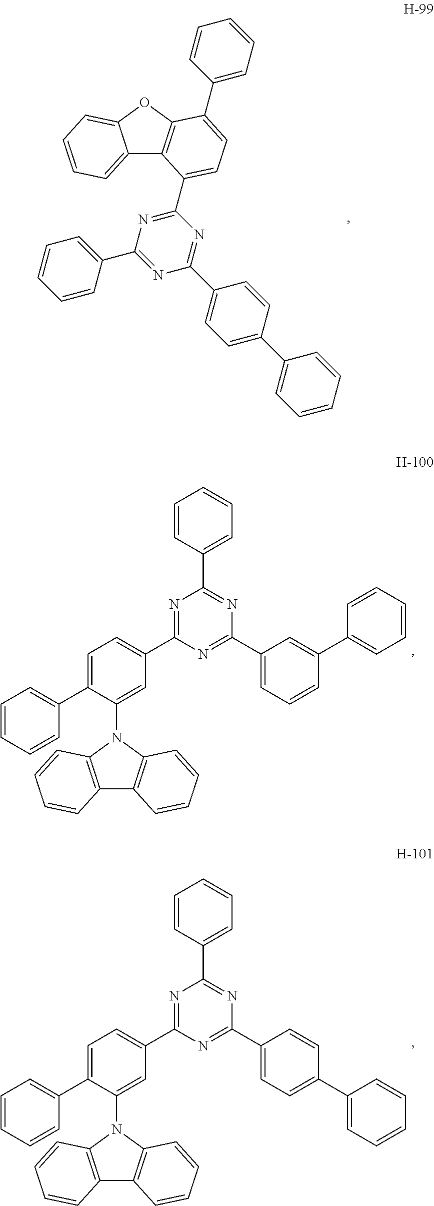 [SMILES: c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1 ; c1ccc(-c2ccc(-c3nc(-c4ccccc4)nc(-c4ccc(-c5ccccc5)c(-n5c6ccccc6c6ccccc65)c4)n3)cc2)cc1]

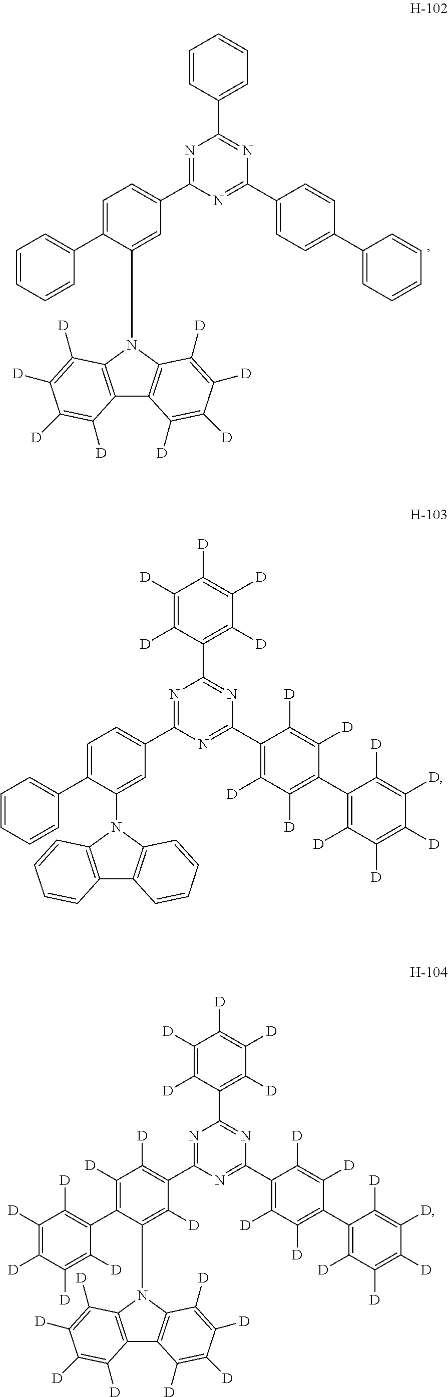

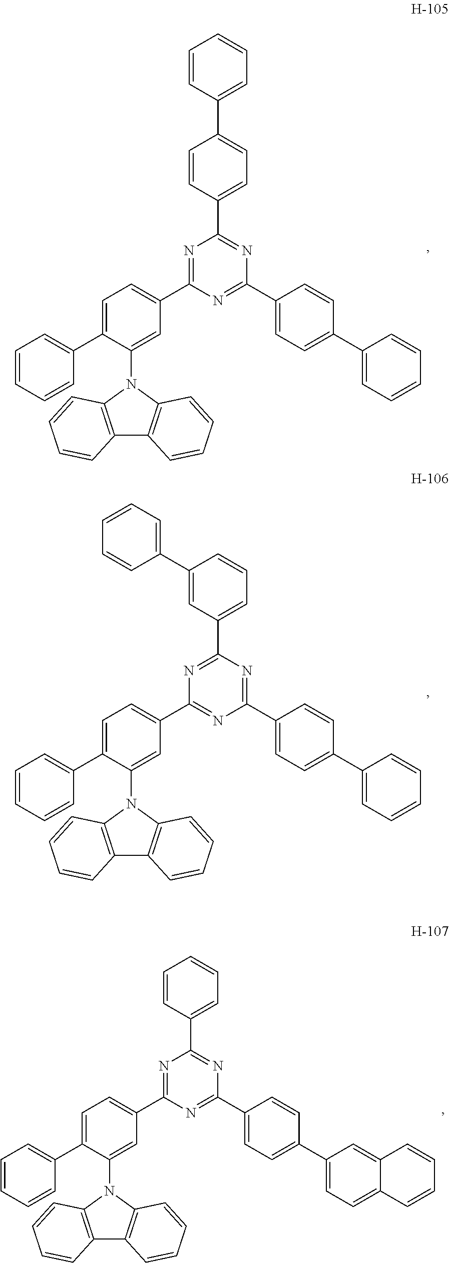 [SMILES: c1ccc(-c2ccc(-c3nc(-c4ccc(-c5ccccc5)cc4)nc(-c4ccc(-c5ccccc5)c(-n5c6ccccc6c6ccccc65)c4)n3)cc2)cc1 ; c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1]

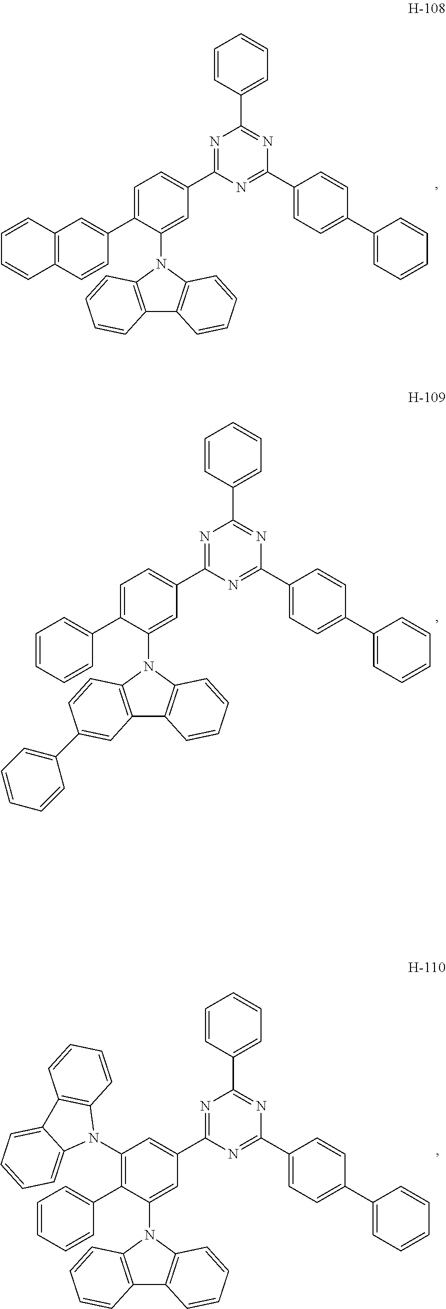 [SMILES: c1ccc(-c2ccc(-c3nc(-c4ccccc4)nc(-c4ccc(-c5ccc6ccccc6c5)c(-n5c6ccccc6c6ccccc65)c4)n3)cc2)cc1 ; c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1 ; c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1]

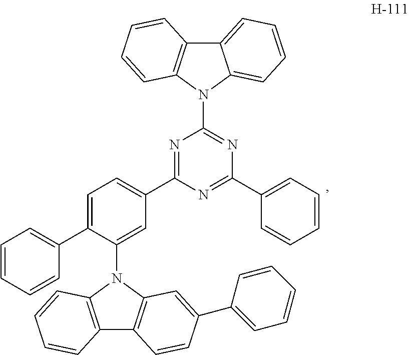 [SMILES: c1ccc(-c2ccc3c4ccccc4n(-c4cc(-c5nc(-c6ccccc6)nc(-n6c7ccccc7c7ccccc76)n5)ccc4-c4ccccc4)c3c2)cc1]

According to an embodiment of the present disclosure, the metal complex is doped in the first host compound and the second host compound, and a weight of the metal complex accounts for 1% to 30% of a total weight of the light-emitting layer.

According to an embodiment of the present disclosure, the metal complex is doped in the first host compound and the second host compound, and the weight of the metal complex accounts for 3% to 13% of the total weight of the light-emitting layer.

According to an embodiment of the present disclosure, the organic electroluminescent device further comprises a hole injection layer. The hole injection layer may be a functional layer comprising a single material or a functional layer comprising multiple materials, wherein the comprised multiple materials are most commonly used as hole transporting materials doped with a certain proportion of p-type conductive doping material. Common p-type doping materials are as follows:

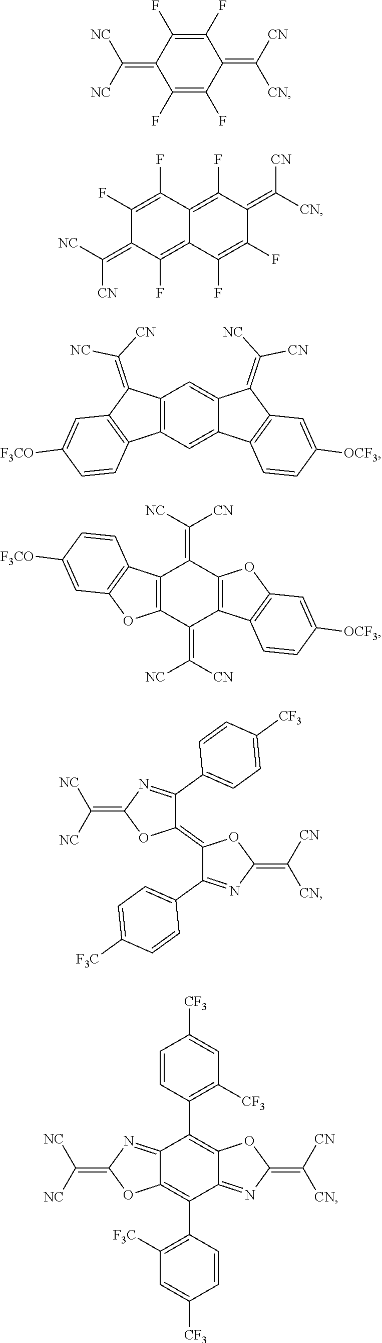

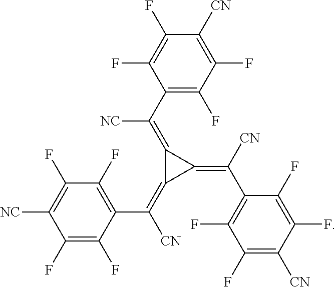 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

According to an embodiment of the present disclosure, disclosed is a compound composition comprising the metal complex in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

### Synthesis Example 1: Synthesis of Metal Complex 5343

### Step 1: Synthesis of Intermediate 3

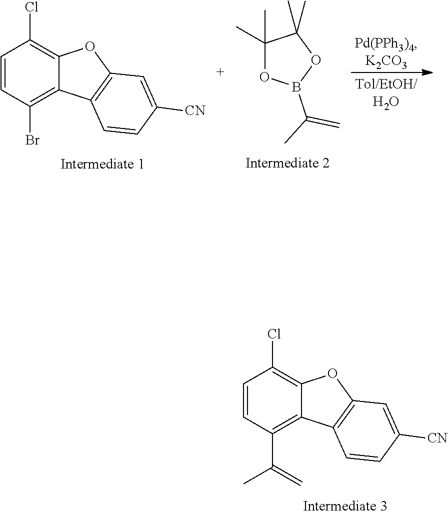 [SMILES: N#Cc1ccc2c(c1)oc1c(Cl)ccc(Br)c12 ; C=C(C)B1OC(C)(C)C(C)(C)O1 ; C=C(C)c1ccc(Cl)c2oc3cc(C#N)ccc3c12]

Intermediate 1 (7.7 g, 25.1 mmol), Intermediate 2 (5.7 mL, 30.1 mmol), tetrakis(triphenylphosphine) palladium (1.4 g, 1.2 mmol), potassium carbonate (6.9 g, 50.2 mmol), toluene/ethanol/water (5/1/1, 70.0 mL) were added to a dry 250 mL round-bottom flask in sequence. Under N₂ protection, a reaction was conducted overnight at 110° C. After the reaction was completed, the reaction solution was extracted with ethyl acetate and purified through column chromatography to obtain a white solid Intermediate 3 (6.0 g, 22.4 mmol, with a yield of 89%).

### Step 2: Synthesis of Intermediate 4

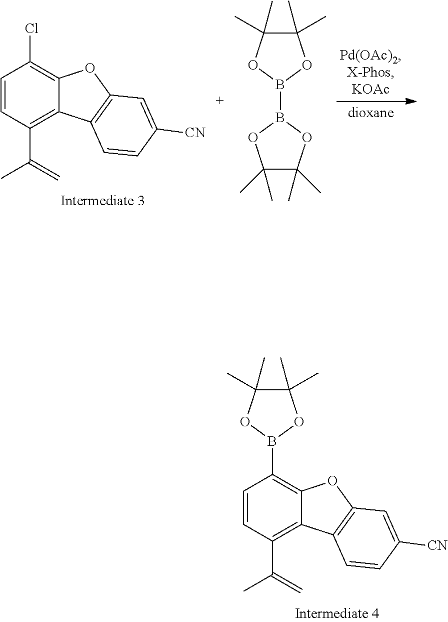

Intermediate 3 (10.0 g, 37.4 mmol), bis(pinacolato)diboron (10.4 g, 41.1 mmol), potassium acetate (7.3 g, 74.8 mmol), palladium acetate (0.4 g, 1.9 mmol), 2-dicyclohexylphosphino-2′,4′,6′-triisopropylbiphenyl (1.8 g, 3.7 mmol) and 1,4-dioxane (100.0 mL) were added to a dry 250 mL round-bottom flask in sequence. Under N₂ protection, a reaction was conducted overnight at 100° C. After the reaction was completed, the reaction system was filtered through Celite, and a filtrate was concentrated under reduced pressure to obtain Intermediate 4, which was directly used for the next step.

### Step 3: Synthesis of Intermediate 5

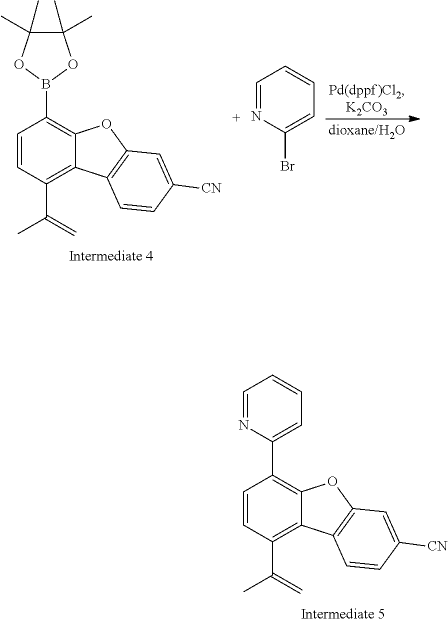 [SMILES: C=C(C)c1ccc(B2OC(C)(C)C(C)(C)O2)c2oc3cc(C#N)ccc3c12 ; Brc1ccccn1 ; C=C(C)c1ccc(-c2ccccn2)c2oc3cc(C#N)ccc3c12]

Intermediate 4, 2-bromopyridine (5.9 g, 37.4 mmol), potassium carbonate (10.3 g, 74.8 mmol), [1,1′-bis(diphenylphosphino)ferrocene]palladium(II) dichloride (1.4 g, 1.9 mmol) and a mixed solvent of 1,4-dioxane/water (90 mL/30 mL) were added to a dry 250 mL round-bottom flask in sequence. Under N₂ protection, a reaction was conducted overnight at 100° C. After the reaction was completed, the reaction solution was extracted with dichloromethane and purified through column chromatography to obtain a white solid Intermediate 5 (8.8 g, 28.4 mmol, with a yield of 76% (two steps)).

### Step 4: Synthesis of Intermediate 6

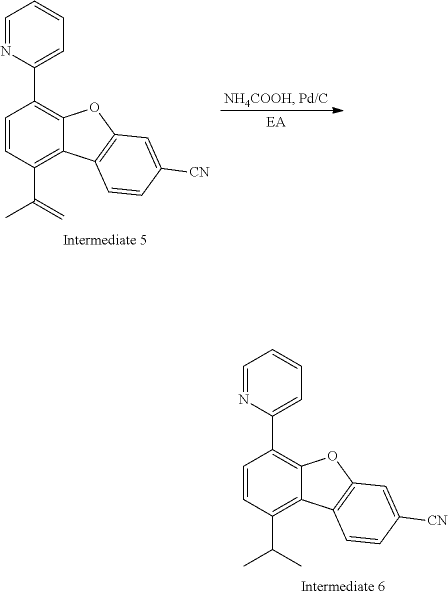 [SMILES: C=C(C)c1ccc(-c2ccccn2)c2oc3cc(C#N)ccc3c12 ; CC(C)c1ccc(-c2ccccn2)c2oc3cc(C#N)ccc3c12]

Intermediate 5 (7.0 g, 22.5 mmol), ethyl acetate (70 mL), ammonium formate (7.1 g, 112.9 mmol) and Pd/C (10%, 1.2 g) were added to a dry 250 mL round-bottom flask in sequence. Under N₂ protection, a reaction was conducted overnight at room temperature. After the reaction was completed, the reaction system was filtered through Celite, and a filtrate was concentrated under reduced pressure and purified through column chromatography to obtain a white solid Intermediate 6 (2.4 g, 7.6 mmol, with a yield of 34%).

### Step 5: Synthesis of Intermediate 7

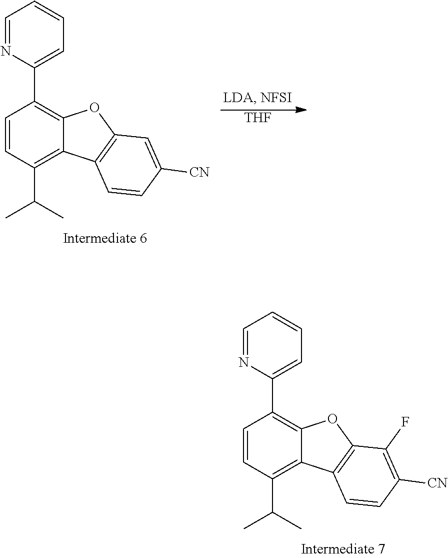 [SMILES: CC(C)c1ccc(-c2ccccn2)c2oc3cc(C#N)ccc3c12 ; CC(C)c1ccc(-c2ccccn2)c2oc3c(F)c(C#N)ccc3c12 ; "THF"]

Intermediate 6 (2.4 g, 7.6 mmol) and tetrahydrofuran (30 mL) were added to a dry 250 mL three-necked round-bottom flask. Under N₂ protection, the reaction system was cooled to −70° C. A tetrahydrofuran solution (6 mL) with 2.0 M di-isopropylamino lithium was slowly added dropwise to the reaction system, and a reaction was conducted for 1.5 h at −70° C. N-Fluorobenzenesulfonimide (4.8 g, 15.3 mmol) was added, and a reaction was conducted at room temperature until the reaction was completed. The reaction solution was quenched with a small amount of water, concentrated under reduced pressure and purified through column chromatography to obtain a white solid Intermediate 7 (2.2 g, 6.6 mmol, with a yield of 87%).

### Step 6: Synthesis of Intermediate 8

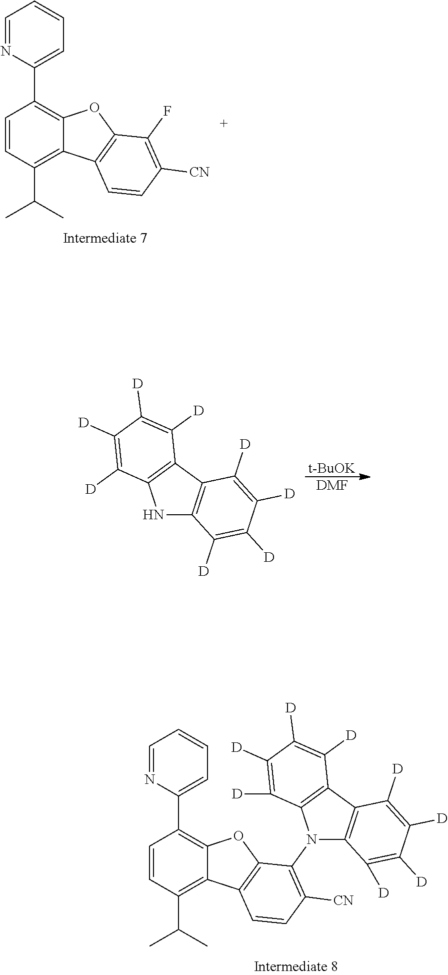

Intermediate 7 (2.2 g, 6.6 mmol), deuterated carbazole (1.4 g, 8.0 mmol), potassium t-butoxide (1.0 g, 9.3 mmol) and DMF (30 mL) were added to a dry 100 mL round-bottom flask in sequence. Under N₂ protection, a reaction was conducted overnight at 100° C. After the reaction was completed, the reaction solution was concentrated under reduced pressure and purified through column chromatography to obtain a white solid Intermediate 8 (2.3 g, 4.7 mmol, with a yield of 72%).

### Step 7: Synthesis of Metal Complex 5343

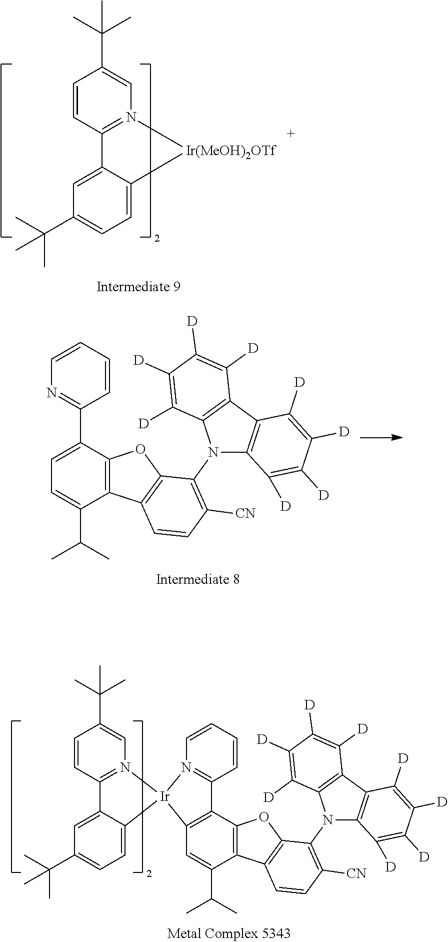

Intermediate 9 (1.1 g, 1.2 mmol), Intermediate 8 (0.7 g, 1.5 mmol), 2-ethoxyethanol (20 mL) and DMF (20 mL) were added to a dry 250 mL round-bottom flask in sequence and heated to react for 5 days at 100° C. under N₂ protection. After the reaction was cooled, the reaction solution was concentrated under reduced pressure and purified through column chromatography to obtain a yellow solid Metal Complex 5343 (0.63 g, 0.52 mmol, with a yield of 43%). The product was confirmed as the target product with a molecular weight of 1209.6.

### Synthesis Example 2: Synthesis of Metal Complex 3525

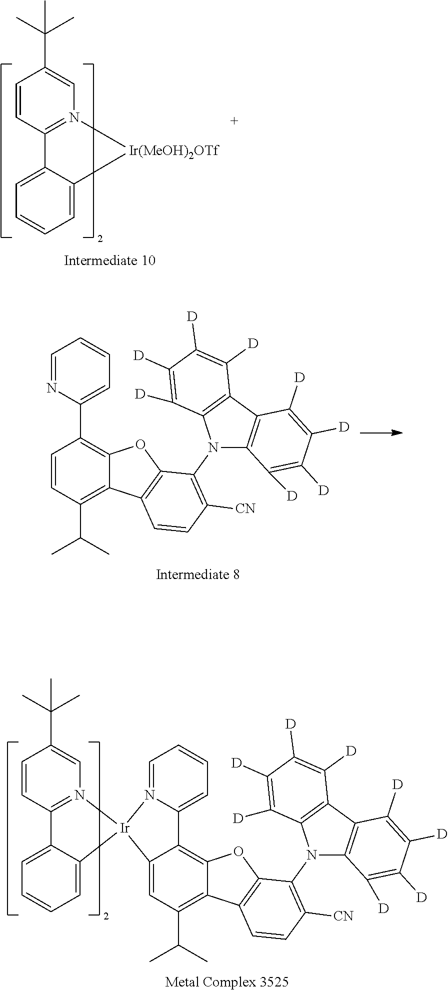

Intermediate 10 (2.0 g, 2.4 mmol), Intermediate 8 (1.4 g, 2.9 mmol), 2-ethoxyethanol (30 mL) and DMF (30 mL) were added to a dry 250 mL round-bottom flask in sequence and heated to react for 5 days at 100° C. under N₂ protection. After the reaction was cooled, the reaction solution was concentrated under reduced pressure and purified through column chromatography to obtain a yellow solid Metal Complex 3525 (1.2 g, 1.09 mmol, with a yield of 46%). The product was confirmed as the target product with a molecular weight of 1097.4.

### Synthesis Example 3: Synthesis of Metal Complex 5291

### Step 1: Synthesis of Intermediate 11

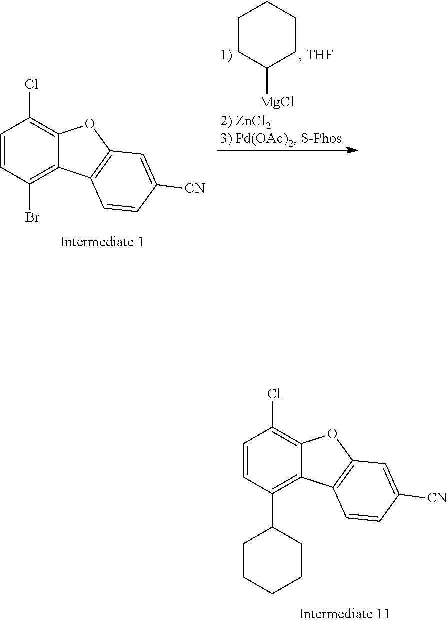

A tetrahydrofuran solution (9 mL) with 1.3 M cyclohexylmagnesium chloride was added to a dry 100 mL three-necked round-bottom flask. Under N₂ protection, a tetrahydrofuran solution (3 mL) with 2.0 M zinc chloride was added to the system in an ice bath. After a reaction was conducted for 1 h, Intermediate 1 (2.0 g, 6.5 mmol), palladium acetate (0.07 g, 0.3 mmol) and 2-dicyclohexylphosphino-2′,6′-dimethoxybiphenyl (0.27 g, 0.6 mmol) were added to the system, and a reaction was conducted overnight at room temperature. After the reaction was completed, the reaction solution was extracted with ethyl acetate and purified through column chromatography to obtain a white solid Intermediate 11 (1.3 g, 4.2 mmol, with a yield of 65%).

### Step 2: Synthesis of Intermediate 12

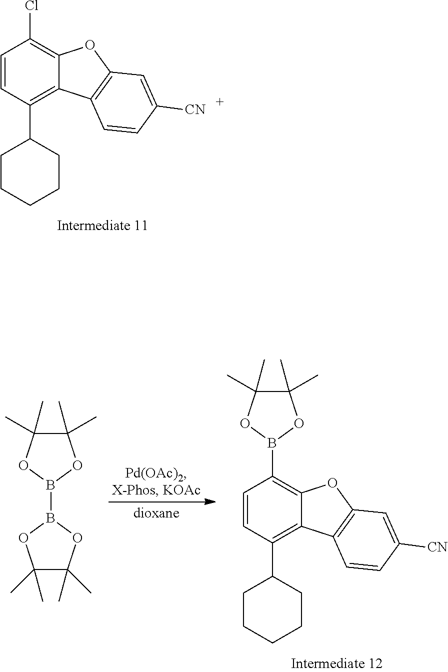

Intermediate 11 (1.3 g, 4.2 mmol), bis(pinacolato)diboron (1.2 g, 4.6 mmol), potassium acetate (0.8 g, 8.4 mmol), palladium acetate (0.05 g, 0.2 mmol), 2-dicyclohexylphosphino-2′,4′,6′-triisopropylbiphenyl (0.2 g, 0.4 mmol) and 1,4-dioxane (30.0 mL) were added to a dry 100 mL round-bottom flask in sequence. Under nitrogen protection, a reaction was conducted overnight at 100° C. After the reaction was completed, the reaction system was filtered through Celite, and a filtrate was concentrated under reduced pressure to obtain Intermediate 12, which was directly used for the next step.

### Step 3: Synthesis of Intermediate 13

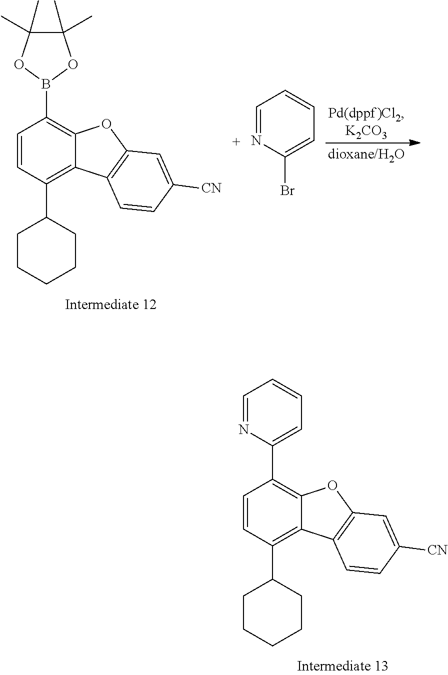 [SMILES: CC1(C)OB(c2ccc(C3CCCCC3)c3c2oc2cc(C#N)ccc23)OC1(C)C ; Brc1ccccn1 ; N#Cc1ccc2c(c1)oc1c(-c3ccccn3)ccc(C3CCCCC3)c12]

Intermediate 12, 2-bromopyridine (0.7 g, 4.2 mmol), potassium carbonate (1.2 g, 8.4 mmol), [1,1′-bis(diphenylphosphino)ferrocene]palladium(II) dichloride (0.15 g, 0.2 mmol) and a mixed solvent of 1,4-dioxane/water (30 mL/10 mL) were added to a dry 100 mL round-bottom flask in sequence. Under nitrogen protection, a reaction was conducted overnight at 100° C. After the reaction was completed, the reaction solution was extracted with dichloromethane and purified through column chromatography to obtain a white solid Intermediate 13 (1.0 g, 2.8 mmol, with a yield of 67% (two steps)).

### Step 4: Synthesis of Intermediate 14

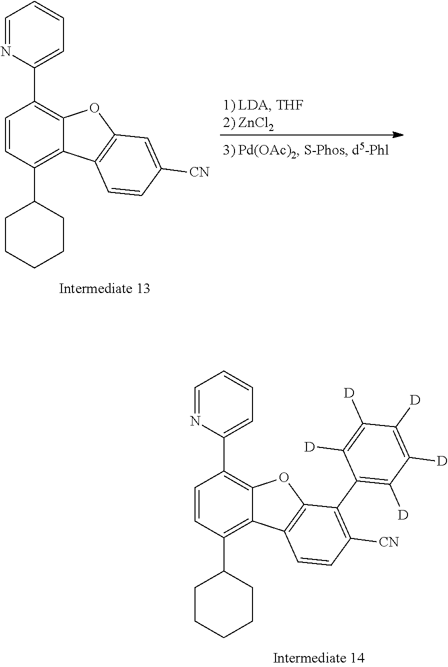 [SMILES: N#Cc1ccc2c(c1)oc1c(-c3ccccn3)ccc(C3CCCCC3)c12 ; [2H]c1c([2H])c([2H])c(-c2c(C#N)ccc3c2oc2c(-c4ccccn4)ccc(C4CCCCC4)c23)c([2H])c1[2H]]

Intermediate 13 (1.0 g, 2.8 mmol) and tetrahydrofuran (30 mL) were added to a dry 100 mL three-necked round-bottom flask. Under nitrogen protection, the reaction system was cooled to −70° C. A tetrahydrofuran solution (2 mL) with 2.0 M di-isopropylamino lithium was slowly added dropwise to the reaction system, and a reaction was conducted for 1.5 h at −70° C. A tetrahydrofuran solution (1 mL) with 2.0 M zinc chloride was added, the reaction system was warmed to room temperature, and the reaction was continuously conducted for 0.5 h. Deuterated iodobenzene (1.2 g, 5.7 mmol), palladium acetate (0.03 g, 0.14 mmol) and 2-dicyclohexylphosphino-2′,6′-dimethoxybiphenyl (0.12 g, 0.28 mmol) were added, and a reaction was conducted overnight at room temperature. After the reaction was completed, the reaction solution was quenched with a small amount of water, concentrated under reduced pressure and purified through column chromatography to obtain a white solid Intermediate 7 (0.7 g, 1.6 mmol, with a yield of 58%).

### Step 5: Synthesis of Metal Complex 5291

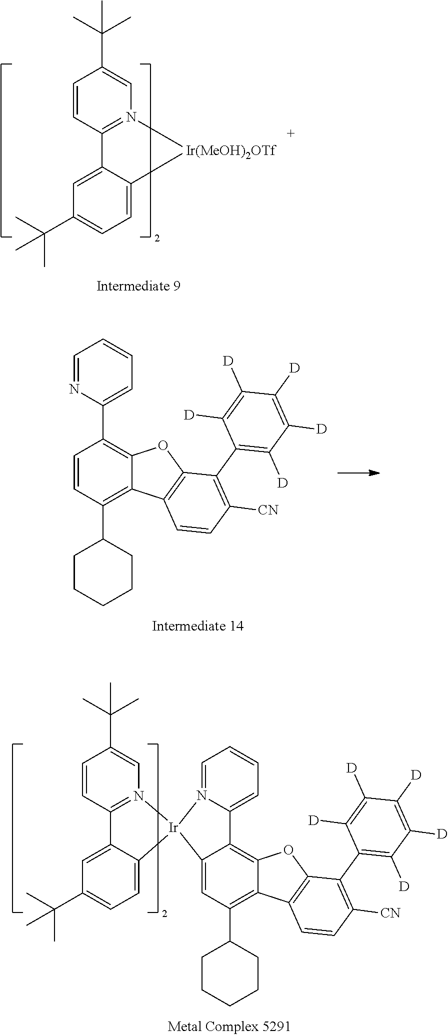

Intermediate 9 (1.0 g, 1.1 mmol), Intermediate 14 (0.6 g, 1.4 mmol), 2-ethoxyethanol (30 mL) and DMF (30 mL) were added to a dry 250 mL round-bottom flask in sequence and heated to react for 5 days at 100° C. under N₂ protection. After the reaction was cooled, the reaction solution was concentrated under reduced pressure and purified through column chromatography to obtain a yellow solid Metal Complex 5291 (0.6 g, 0.52 mmol, with a yield of 48%). The product was confirmed as the target product with a molecular weight of 1157.6.

Those skilled in the art will appreciate that the above preparation methods are merely exemplary. Those skilled in the art can obtain other compound structures of the present disclosure through the modifications of the preparation methods.

### Device Example 1

A glass substrate having an indium tin oxide (ITO) anode with a thickness of 80 nm (with a sheet resistance of 14 to −20 Ω/sq and an emissive area of 0.04 cm²) was cleaned and treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 108 Torr. Compound HT and Compound PD were used as a hole injection layer (HIL). Compound HT was used as a hole transporting layer (HTL). Compound PH-23 was used as an electron blocking layer (EBL). Metal Complex 5343 of the present disclosure was doped in Compound PH-23 and Compound H-40, all of which were co-deposited for use as an emissive layer (EML). On the EML, Compound HB was used as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Example 2

The implementation mode in Device Example 2 was the same as that in Device Example 1, except that in the emissive layer (EML), Metal Complex 5343 of the present disclosure was replaced with Metal Complex 3525.

### Device Example 3

The implementation mode in Device Example 3 was the same as that in Device Example 1, except that in the emissive layer (EML), Metal Complex 5343 of the present disclosure was replaced with Metal Complex 5291.

### Device Comparative Example 1

The implementation mode in Device Comparative Example 1 was the same as that in Device Example 1, except that in the emissive layer (EML), Metal Complex 5343 of the present disclosure was replaced with Compound GD1.

### Device Comparative Example 2

The implementation mode in Device Comparative Example 2 was the same as that in Device Example 1, except that in the emissive layer (EML), Metal Complex 5343 of the present disclosure was replaced with Compound GD2.

### Device Comparative Example 3

The implementation mode in Device Comparative Example 3 was the same as that in Device Example 1, except that in the emissive layer (EML), Metal Complex 5343 of the present disclosure was replaced with Compound GD3.

### Device Comparative Example 4

The implementation mode in Device Comparative Example 4 was the same as that in Device Example 1, except that in the emissive layer (EML), Metal Complex 5343 of the present disclosure was replaced with Compound GD4.

Detailed structures and thicknesses of layers of the devices are shown in the following table. A layer using more than one material is obtained by doping different compounds at their weight ratio as recorded.

TABLE 1
Device structures in Examples 1 to 3 and Comparative Examples 1 to 4

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | PH-23 | PH-23:Compound | HB | ET:Liq |
| | PD (97:3) (100 | (350 Å) | (50 Å) | H-40:Metal Complex | (50 Å) | (40:60) (350 |
| | Å) | | | 5343 (47:47:6) (400 | | Å) |
| | | | | Å) | | |
| Example 2 | Compound | Compound | Compound | Compound | Compound | Compound |
| | HT:Compound | HT | PH-23 | PH-23:Compound | HB | ET:Liq |
| | PD (97:3) (100 | (350 Å) | (50 Å) | H-40:Metal Complex | (50 Å) | (40:60) (350 |
| | Å) | | | 3525 (47:47:6) (400 | | Å) |
| | | | | Å) | | |
| Example 3 | Compound | Compound | Compound | Compound | Compound | Compound |
| | HT:Compound | HT | PH-23 | PH-23:Compound | HB | ET:Liq |
| | PD (97:3) (100 | (350 Å) | (50 Å) | H-40:Metal Complex | (50 Å) | (40:60) (350 |
| | Å) | | | 5291 (47:47:6) (400 | | Å) |
| | | | | Å) | | |
| Comparative | Compound | Compound | Compound | Compound | Compound | Compound |
| Example 1 | HT:Compound | HT | PH-23 | PH-23:Compound | HB | ET:Liq |
| | PD (97:3) (100 | (350 Å) | (50 Å) | H-40:Compound | (50 Å) | (40:60) (350 |
| | Å) | | | GD1 (47:47:6) (400 | | Å) |
| | | | | Å) | | |
| Comparative | Compound | Compound | Compound | Compound | Compound | Compound |
| Example 2 | HT:Compound | HT | PH-23 | PH-23:Compound | HB | ET:Liq |
| | PD (97:3) (100 | (350 Å) | (50 Å) | H-40:Compound | (50 Å) | (40:60) (350 |
| | Å) | | | GD2 (47:47:6) (400 | | Å) |
| | | | | Å) | | |
| Comparative | Compound | Compound | Compound | Compound | Compound | Compound |
| Example 3 | HT:Compound | HT | PH-23 | PH-23:Compound | HB | ET:Liq |
| | PD (97:3) (100 | (350 Å) | (50 Å) | H-40:Compound | (50 Å) | (40:60) (350 |
| | Å) | | | GD3 (47:47:6) (400 | | Å) |
| | | | | Å) | | |
| Comparative | Compound | Compound | Compound | Compound | Compound | Compound |
| Example 4 | HT:Compound | HT | PH-23 | PH-23:Compound | HB | ET:Liq |
| | PD (97:3) (100 | (350 Å) | (50 Å) | H-40:Compound | (50 Å) | (40:60) (350 |
| | Å) | | | GD4 (47:47:6) (400 | | Å) |
| | | | | Å) | | |

The materials used in the devices have the following structures:

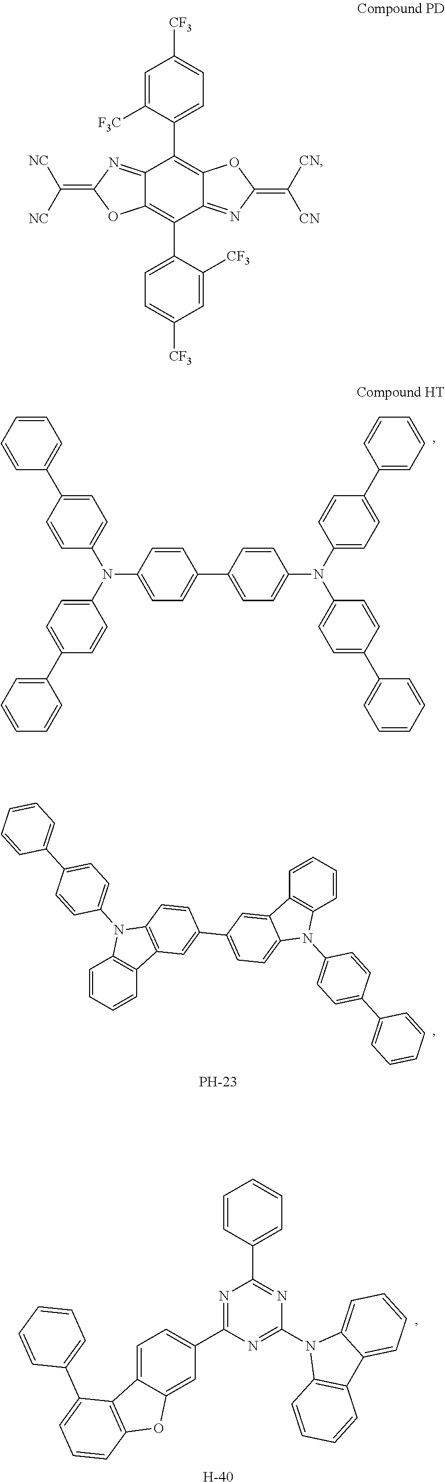

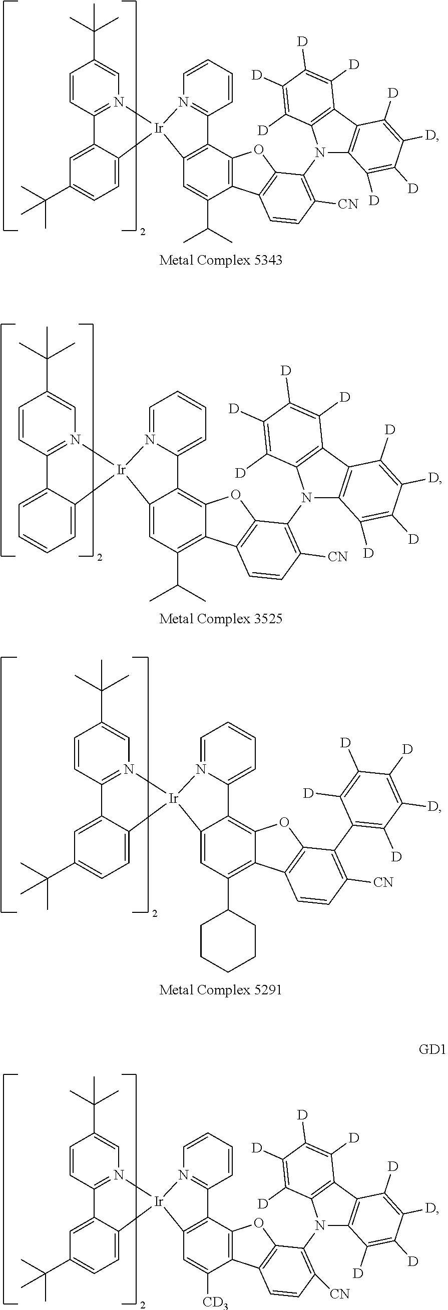

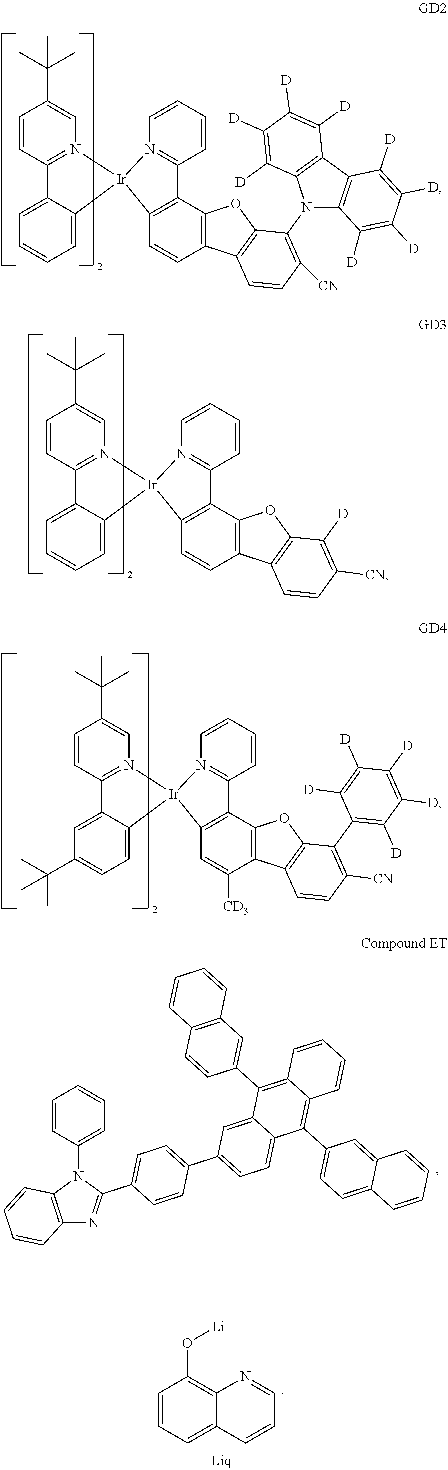

The IVL characteristics of the devices were measured. The CIE data, maximum emission wavelengths (λₘₐₓ) and full width at half maxima (FWHM) of the devices were measured at 15 mA/cm². Capacitance testing was performed on the devices by using an impedance analyzer (Keysight E4990A). A direct current bias voltage of −4 V to 5 V was applied to the electrodes at two ends of the device, and a sinusoidal alternating current voltage signal of 100 mV was superimposed at the same time. The testing was performed at alternating current voltages with a frequency of 500 Hz, separately. The C-V curves of the devices were measured, and the maximum capacitances (Cₘₐₓ) of the devices were obtained. The data was recorded and shown in Table 2.

TABLE 2
Device data in Examples 1 to 3 and Comparative Examples 1 to 4

| Device ID | CIE (x, y) | λₘₐₓ (nm) | FWHM (nm) | Cₘₐₓ/nF |
|---|---|---|---|---|
| Example 1 | (0.317, 0.649) | 525 | 36.1 | 2.61 |
| Example 2 | (0.296, 0.660) | 522 | 31.9 | 3.14 |
| Example 3 | (0.317, 0.649) | 524 | 38.1 | 2.66 |
| Comparative | (0.319, 0.647) | 525 | 43.9 | 3.30 |
| Example 1 | | | | |
| Comparative | (0.343, 0.633) | 531 | 36.4 | 3.68 |
| Example 2 | | | | |
| Comparative | (0.347, 0.629) | 530 | 49.1 | 3.60 |
| Example 3 | | | | |
| Comparative | (0.322, 0.645) | 524 | 48.6 | 3.12 |
| Example 4 | | | | |

### DISCUSSION

Compared with Comparative Example 1, Example 1 has the same ligand L_{b}. The only difference between Example 1 and Comparative Example 1 is that substituents Rₙ in ligands Lₐ are isopropyl whose number of carbon atoms is greater than 2 and deuterated methyl, respectively. As can be seen from the data in Table 2, at 15 mA/cm², the full width at half maximum in Example 1 is 7.8 nm narrower than that in Comparative Example 1, and at a frequency of 500 Hz, the maximum capacitance Cₘₐₓ is 0.69 nF lower.

Compared with Comparative Example 2, Example 2 has the same ligand L_{b}. The only difference between Example 2 and Comparative Example 2 is that substituents Rₙ in ligands Lₐ are isopropyl whose number of carbon atoms is greater than 2 and hydrogen, respectively. As can be seen from the data in Table 2, at 15 mA/cm², the full width at half maximum in Example 2 is 4.5 nm narrower than that in Comparative Example 2, and at a frequency of 500 Hz, the maximum capacitance Cₘₐₓ is 0.54 nF lower.

Compared with Comparative Example 3, Example 2 has the same ligand L_{b}. The differences between Example 2 and Comparative Example 3 are that substituents Rₙ in ligands Lₐ are isopropyl whose number of carbon atoms is greater than 2 and hydrogen, respectively, and substituents Ar in the ligands Lₐ are a deuterated carbazole substituent and deuterium, respectively. When neither Rₙ nor Ar in Comparative Example 3 meets the limitation in the present application, at 15 mA/cm², the full width at half maximum in Example 2 is 17.2 nm narrower than that in Comparative Example 3, and at a frequency of 500 Hz, the maximum capacitance Cₘₐₓ is 0.46 nF lower.

Compared with Comparative Example 4, Example 3 has the same ligand L_{b}. The only difference between Example 3 and Comparative Example 4 is that substituents Rₙ in ligands Lₐ are cyclohexyl whose number of carbon atoms is greater than 2 and deuterated methyl, respectively. At 15 mA/cm², the full width at half maximum in Example 3 is 10.5 nm narrower than that in Comparative Example 4, and at a frequency of 500 Hz, the maximum capacitance Cₘₐₓ is 0.46 nF lower.

The above data indicates that the metal complex comprising the ligand Lₐ having the particular substituents Rₙ and Ar can obtain a narrower full width at half maximum and a lower maximum capacitance compared with the comparative examples without the characteristics in the present disclosure. The organic electroluminescent device can improve the response time and refresh rate of an OLED display device at a low grayscale and can maintain excellent device performance.

It should be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein Lₐ has a structure represented by Formula 1: 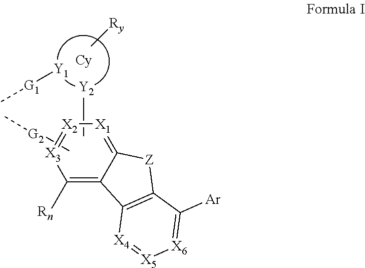
wherein,
Cy is selected from an aromatic ring having 6 to 24 ring atoms which comprises Y₁ and Y₂, a heteroaromatic ring having 5 to 24 ring atoms which comprises Y₁ and Y₂ or a combination thereof;
G₁ and G₂ are, at each occurrence identically or differently, selected from a single bond, O or S;
X₁ to X₃ are, at each occurrence identically or differently, selected from C, CRₓ or N, and one of X₁ to X₃ is selected from C and joined to Y₂;
when G₂ is selected from a single bond, and X₁, X₂ or X₃ is selected from N, X₁, X₂ or X₃ is joined to the metal by forming a metal-nitrogen bond through G₂; or when G₂ is selected from a single bond, O or S, and X₁, X₂ or X₃ is selected from C, X₁, X₂ or X₃ is joined to the metal through G₂;
X₄ to X₆ are, at each occurrence identically or differently, selected from CRₓ or N;
Y₁ and Y₂ are, at each occurrence identically or differently, selected from C or N;
Z is selected from the group consisting of O, S, Se, NR′, CR′R′, SiR′R′ and GeR′R′; when two R′ are present at the same time, the two R′ are identical or different;
R_{y} represents mono-substitution, multiple substitutions or non-substitution; when a plurality of R_{y} are present, the plurality of R_{y} are identical or different;
Ar is selected from substituted or unsubstituted aryl having 6 to 30 carbon atoms or substituted or unsubstituted heteroaryl having 3 to 30 carbon atoms;
Rₙ has a structure represented by Formula 2: 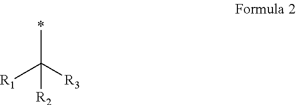
wherein the number of carbon atoms in Rₙ is greater than or equal to 2;
“*” represents a position where Formula 2 is joined to Formula 1;
Rₓ, R_{y}, R′, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
adjacent substituents Rₓ and R′ can be optionally joined to form a ring; and
adjacent substituents R₁, R₂ and R₃ can be optionally joined to form a ring.

2. The metal complex according to claim 1, wherein Cy is, at each occurrence identically or differently, selected from any structure of the group consisting of the following: 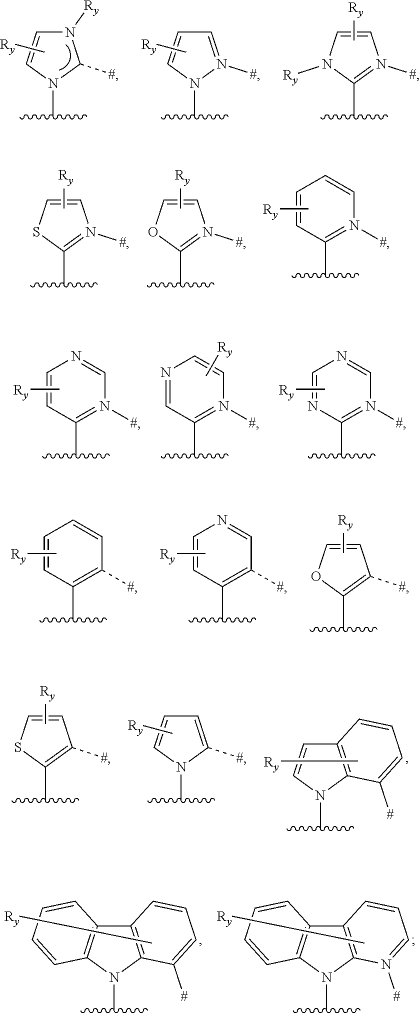
wherein,
R_{y} represents, at each occurrence identically or differently, mono-substitution, multiple substitutions or non-substitution; when a plurality of R_{y} are present in any structure, the plurality of R_{y} are identical or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring; and
“#” represents a position where Cy is joined to the metal M, and “ [symbol] ” represents a position where Cy is joined to X₁, X₂ or X₃.

3. The metal complex according to claim 1, wherein the metal complex has a general formula of M(Lₐ)ₘ(L_{b})ₙ(L_{c})_{q};
M is selected from a metal with a relative atomic mass greater than 40; preferably, the metal M is, at each occurrence identically or differently, selected from the group consisting of Cu, Ag, Au, Rᵤ, Rh, Pd, Os, Ir and Pt;
Lₐ, L_{b} and L_{c} are a first ligand, a second ligand and a third ligand coordinated to the metal M, respectively, and L_{c} is the same as or different from Lₐ or L_{b}, wherein Lₐ, L_{b} and L_{c} can be optionally joined to form a multidentate ligand;
m is selected from 1, 2 or 3, n is selected from 0, 1 or 2, q is selected from 0, 1 or 2, and m+n+q is equal to an oxidation state of the metal M; when m is greater than or equal to 2, a plurality of Lₐ are identical or different; when n is equal to 2, two L_{b} are identical or different; when q is equal to 2, two L_{c} are identical or different;
L_{b} and L_{c} are, at each occurrence identically or differently, selected from a structure represented by any one of the group consisting of: 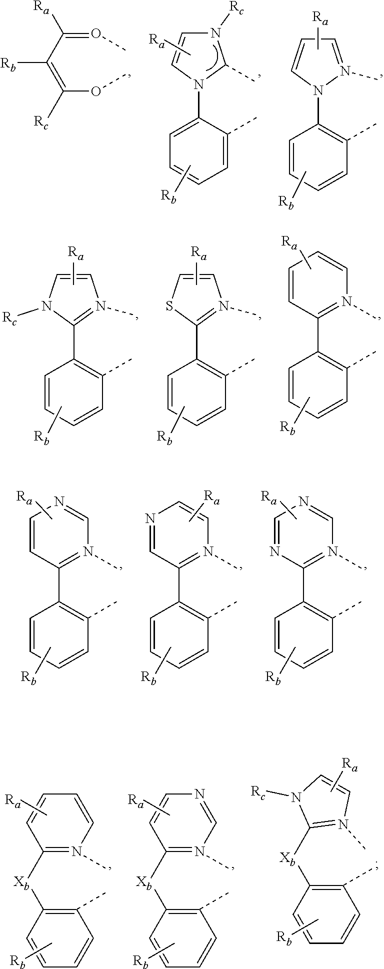
wherein,
X_{b} is, at each occurrence identically or differently, selected from the group consisting of: O, S, Se, NR_{N1} and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

4. The metal complex according to claim 1, wherein G₁ and G₂ are, at each occurrence identically or differently, selected from a single bond or O; preferably, G₁ and G₂ each are a single bond.

5. The metal complex according to claim 1, wherein the metal complex has a general formula structure of Ir(Lₐ)ₘ(L_{b})₃₋ₘ, and the structure is represented by Formula 3: 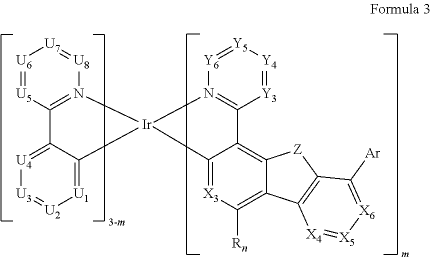
wherein,
m is selected from 1, 2 or 3; when m is selected from 1, two L_{b} are identical or different;
when m is selected from 2 or 3, a plurality of Lₐ are identical or different;
Z is selected from the group consisting of O, S, Se, NR′, CR′R′, SiR′R′ and GeR′R′; when two R′ are present at the same time, the two R′ are identical or different;
U₁ to U₈ are, at each occurrence identically or differently, selected from CRᵤ or N;
X₃ to X₆ are, at each occurrence identically or differently, selected from CRₓ or N;
Y₃ to Y₆ are, at each occurrence identically or differently, selected from CR_{y} or N;
Ar is selected from substituted or unsubstituted aryl having 6 to 30 carbon atoms or substituted or unsubstituted heteroaryl having 3 to 30 carbon atoms;
Rₙ has a structure represented by Formula 2: 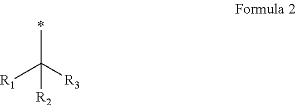
wherein the number of carbon atoms in Rₙ is greater than or equal to 2;
“*” represents a position where Formula 2 is joined to Formula 3;
R′, Rᵤ, Rₓ, R_{y}, R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
adjacent substituents Rₓ and R′ can be optionally joined to form a ring;
adjacent substituents Rᵤ can be optionally joined to form a ring; and
adjacent substituents R₁, R₂ and R₃ can be optionally joined to form a ring.

6. The metal complex according to claim 5, wherein m is selected from 1 or 2; preferably, m is selected from 1.

7. The metal complex according to claim 1, wherein Z is selected from O or S; preferably, Z is selected from O.

8. The metal complex according to claim 1, wherein R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, a cyano group and combinations thereof, and the total number of carbon atoms in R₁, R₂ and R₃ is greater than or equal to 1;
preferably, R₁, R₂ and R₃ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof, and the total number of carbon atoms in R₁, R₂ and R₃ is greater than or equal to 1; and
more preferably, R₁, R₂ and R₃ are, at each occurrence identically or differently, selected from hydrogen, deuterium, substituted or unsubstituted alkyl having 1 to 6 carbon atoms and combinations thereof, and at least one of R₁, R₂ and R₃ is selected from substituted or unsubstituted alkyl having 1 to 6 carbon atoms.

9. The metal complex according to claim 1, wherein Rₙ is, at each occurrence identically or differently, selected from the group consisting of Rₙ₁ to Rₙ₈₅: 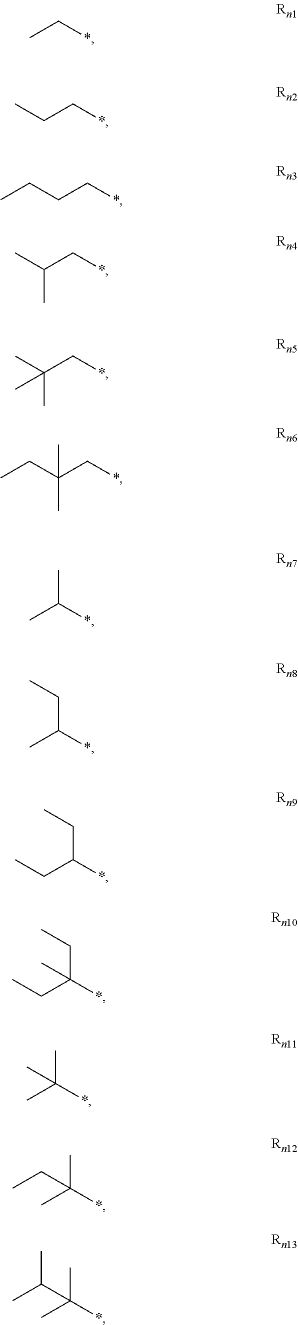 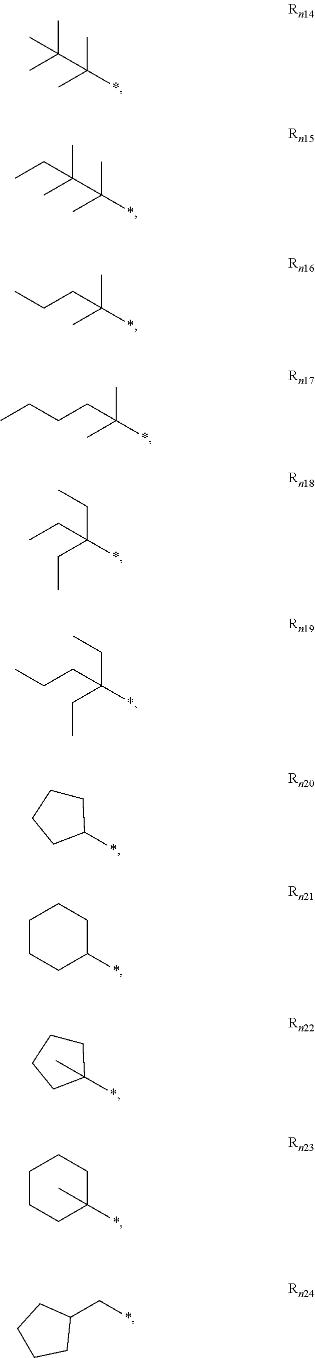 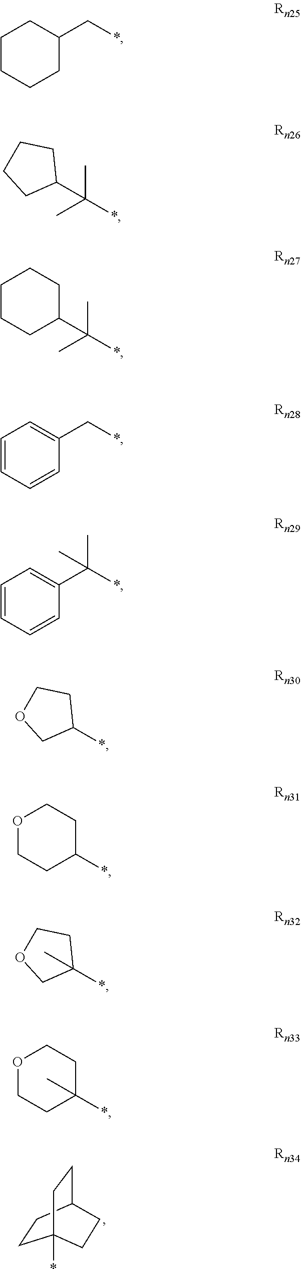 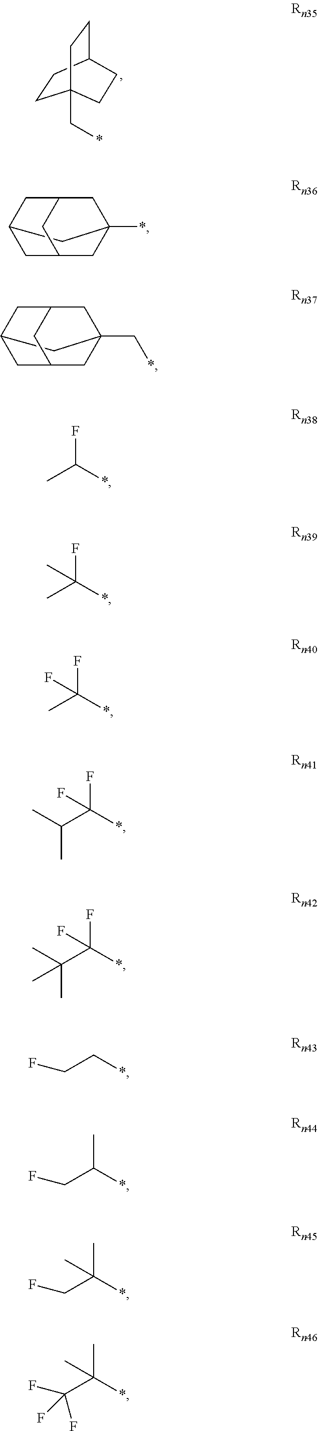 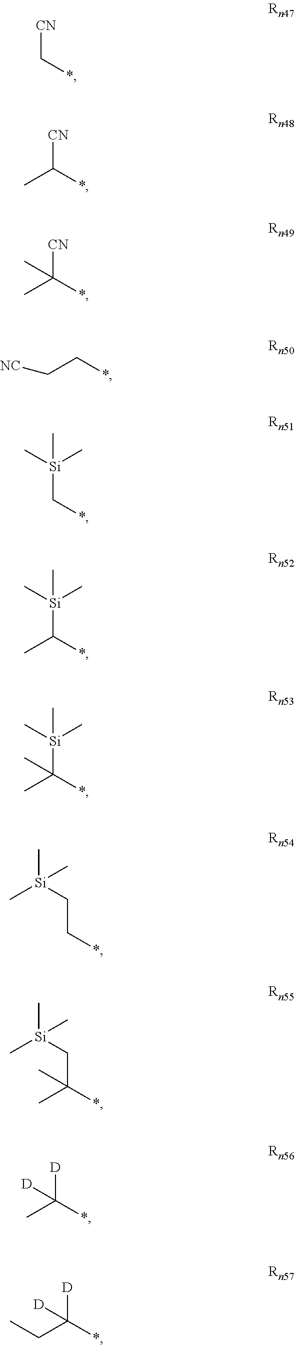 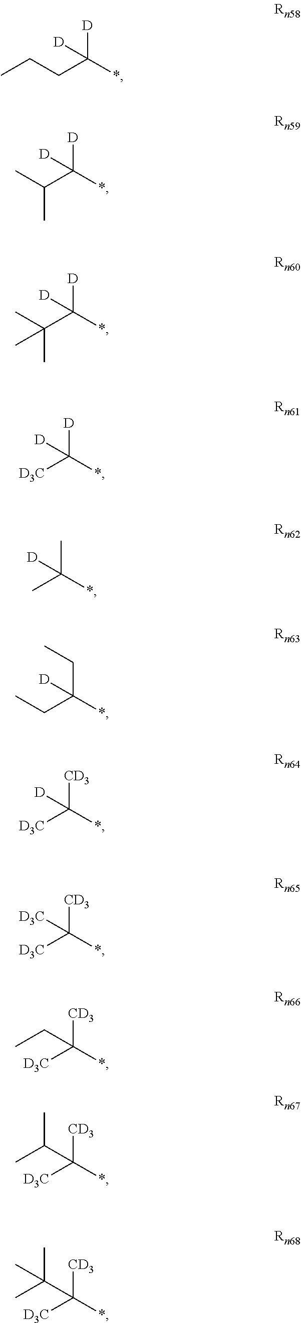 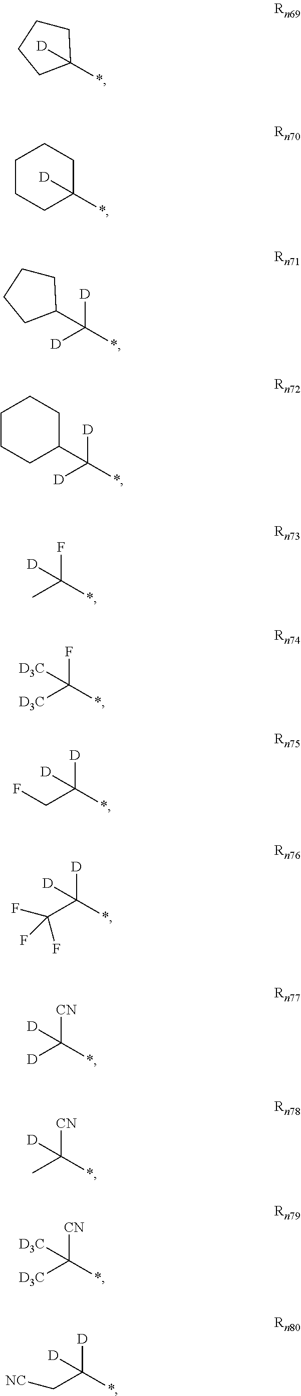 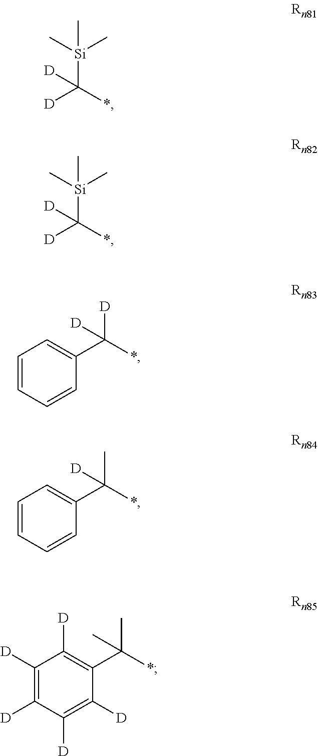
wherein optionally, hydrogen in Rₙ₁ to Rₙ₈₅ can be partially or fully substituted with deuterium.

10. The metal complex according to claim 5, wherein X₃ to X₆ are, at each occurrence identically or differently, selected from CRₓ, and/or Y₃ to Y₆ are, at each occurrence identically or differently, selected from CR_{y}, and/or U₁ to U₈ are, at each occurrence identically or differently, selected from CRᵤ, and Rₓ, R_{y} and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group and combinations thereof;
preferably, Rₓ, R_{y} and Rᵤ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group and combinations thereof; and
more preferably, Rₓ, R_{y} and Rᵤ are, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof.

11. The metal complex according to claim 1, wherein at least one of X₃ to X₆ is selected from CRₓ, the Rₓ is a cyano group or fluorine, and all the carbon atoms in the substituent Rₙ are selected from a primary carbon, a secondary carbon or a tertiary carbon;
preferably, at least one of X₄ to X₆ is selected from CRₓ, the R_{y} is a cyano group or fluorine, and all the carbon atoms in the substituent Rₙ are selected from a primary carbon, a secondary carbon or a tertiary carbon; and
more preferably, X₆ is CRₓ, the Rₓ is a cyano group or fluorine, and all the carbon atoms in the substituent Rₙ are selected from a primary carbon, a secondary carbon or a tertiary carbon.

12. The metal complex according to claim 1, wherein X₃ to X₆ are, at each occurrence identically or differently, selected from CR_{y}, the Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms and combinations thereof, and at least one of all the carbon atoms in the substituent Rₙ is a quaternary carbon;
preferably, X₄ to X₆ are, at each occurrence identically or differently, selected from CRₓ, the Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms and combinations thereof, and at least one of all the carbon atoms in the substituent Rₙ is a quaternary carbon; and
more preferably, X₆ is CRₓ, the Rₓ is, at each occurrence identically or differently, selected from the group consisting of: hydrogen, deuterium, fluorine, a cyano group, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl and combinations thereof, and at least one of all the carbon atoms in the substituent Rₙ is a quaternary carbon.

13. The metal complex according to claim 5, wherein Y₃ to Y₆ are, at each occurrence identically or differently, CR_{y} or N, and at least one of Y₃ to Y₆ is selected from CR_{y}, wherein the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof; and
preferably, at least one of Y₃ to Y₆ is selected from CR_{y}, wherein the R_{y} is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof.

14. The metal complex according to claim 5, wherein at least one or at least two of U₁ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms or a combination thereof, and the total number of carbon atoms in all of the Rᵤ is at least 4; and
preferably, at least one or at least two of U₁ to U₄ and/or U₅ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms or a combination thereof, and the total number of carbon atoms in all of the Rᵤ is at least 4.

15. The metal complex according to claim 1, wherein Ar is, at each occurrence identically or differently, selected from the group consisting of Ar1 to Ar147: 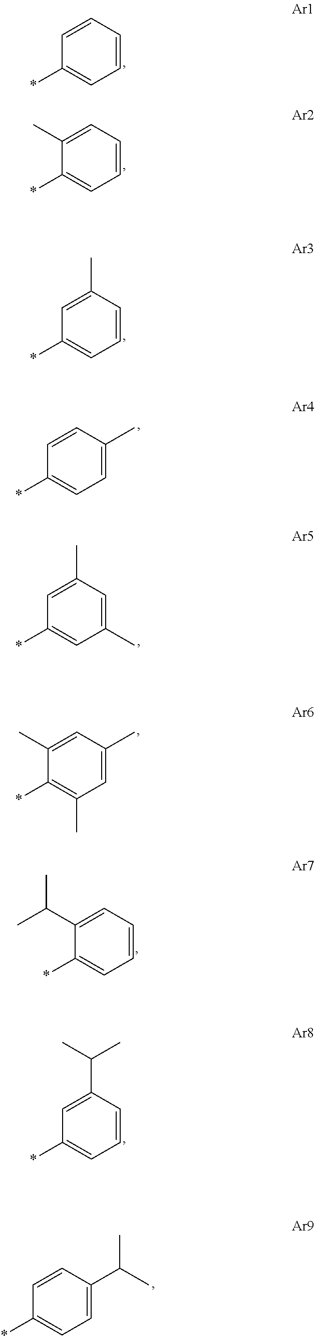 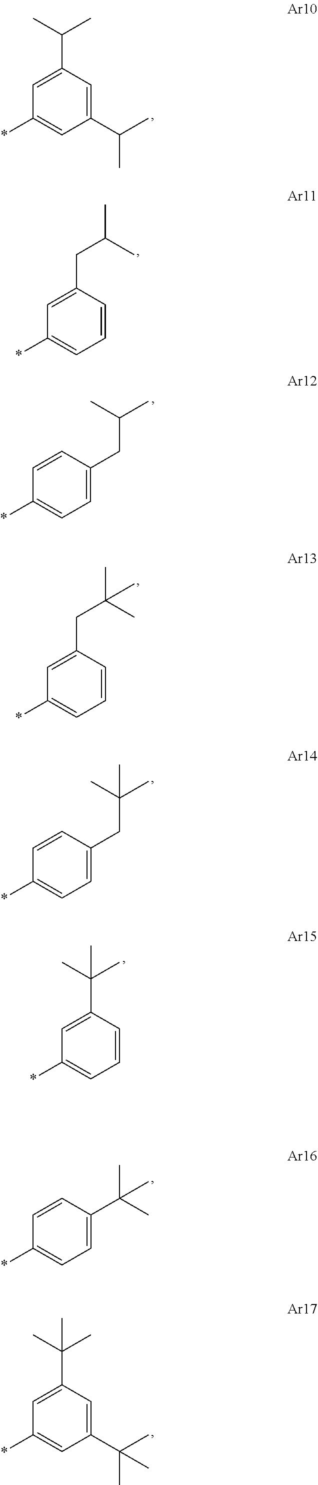 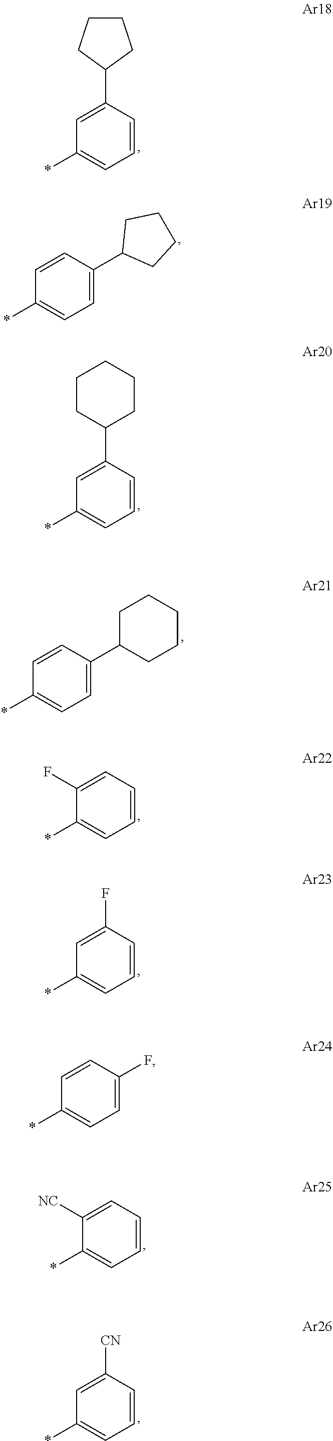 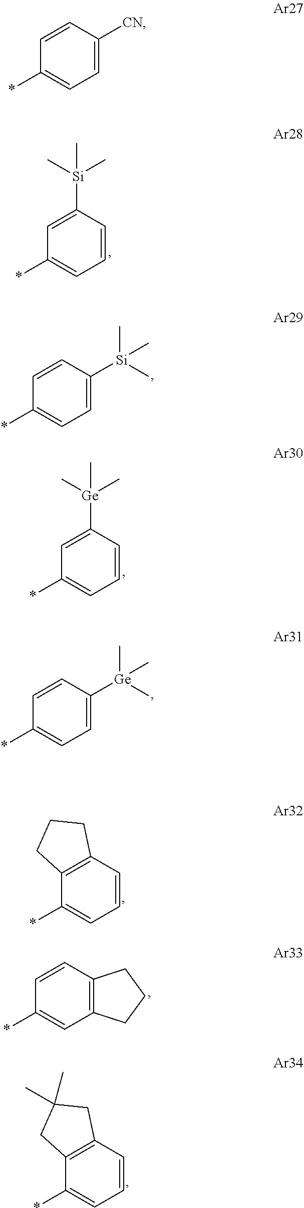 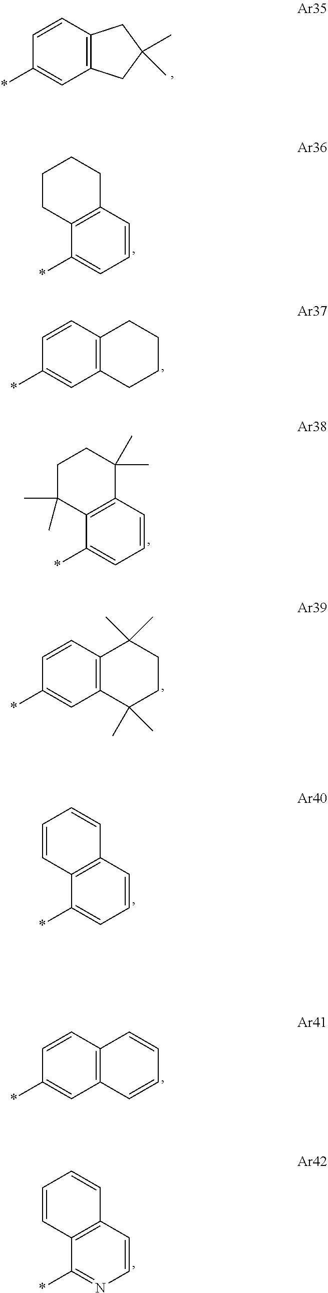 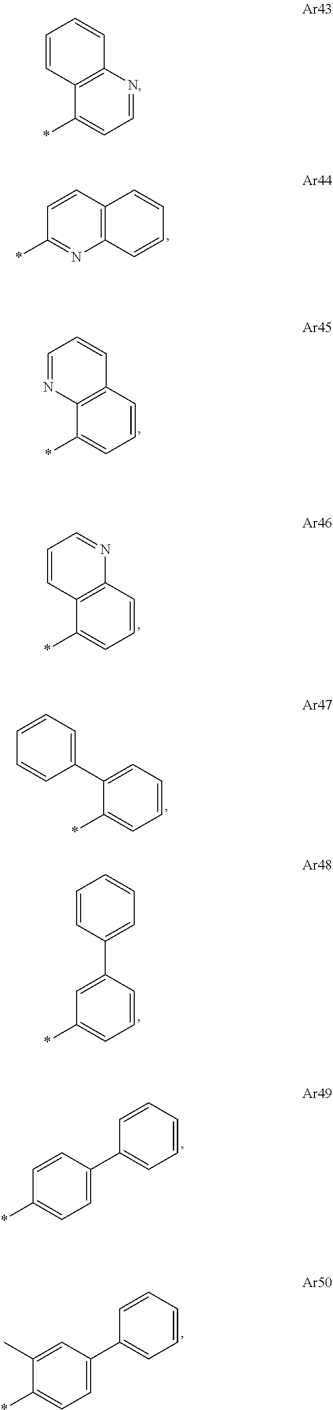 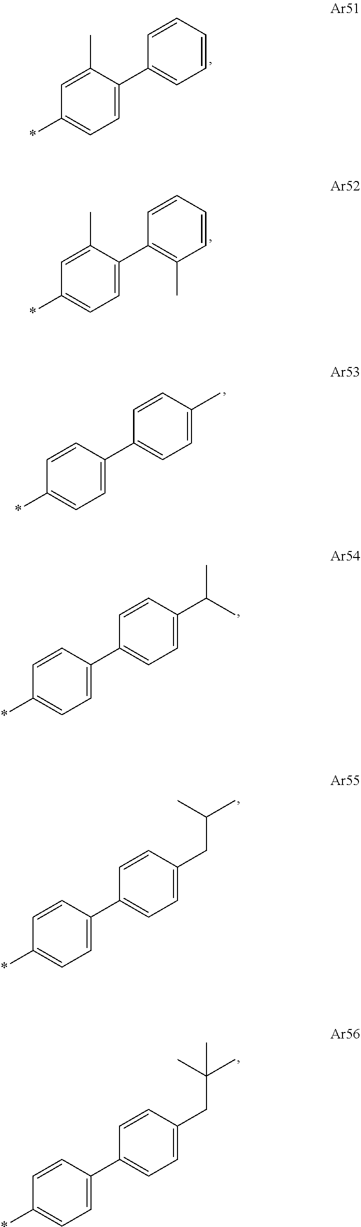 [SMILES: *c1ccc(-c2ccccc2)c(C)c1 ; *c1ccc(-c2ccccc2C)c(C)c1 ; *c1ccc(-c2ccc(C)cc2)cc1 ; *c1ccc(-c2ccc(C(C)C)cc2)cc1 ; *c1ccc(-c2ccc(CC(C)C)cc2)cc1 ; *c1ccc(-c2ccc(CC(C)(C)C)cc2)cc1] 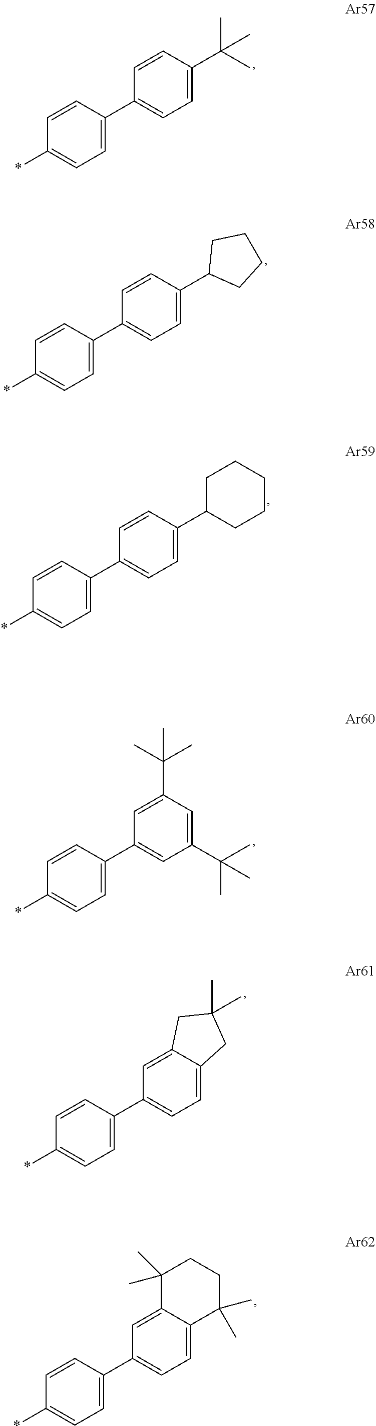 [SMILES: *c1ccc(-c2ccc(C(C)(C)C)cc2)cc1 ; *c1ccc(-c2ccc(C3CCCC3)cc2)cc1 ; *c1ccc(-c2ccc(C3CCCCC3)cc2)cc1 ; *c1ccc(-c2cc(C(C)(C)C)cc(C(C)(C)C)c2)cc1 ; *c1ccc(-c2ccc3c(c2)CC(C)(C)C3)cc1 ; *c1ccc(-c2ccc3c(c2)C(C)(C)CCC3(C)C)cc1] 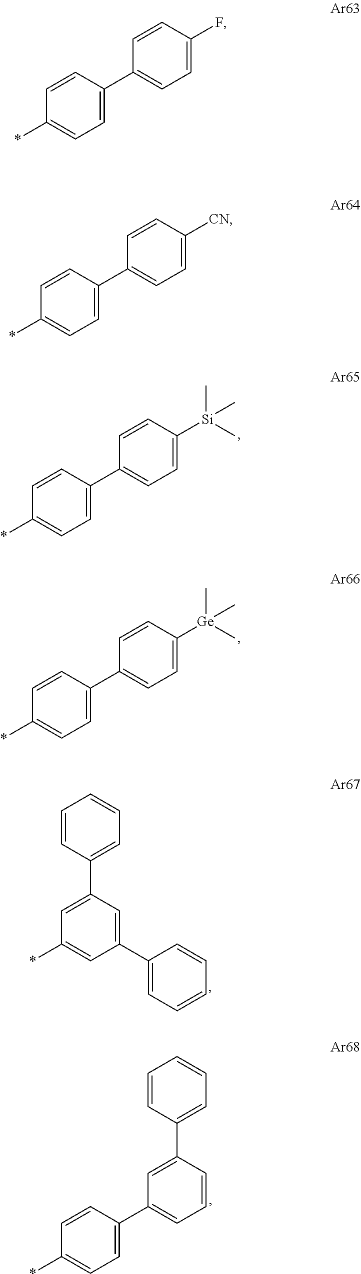 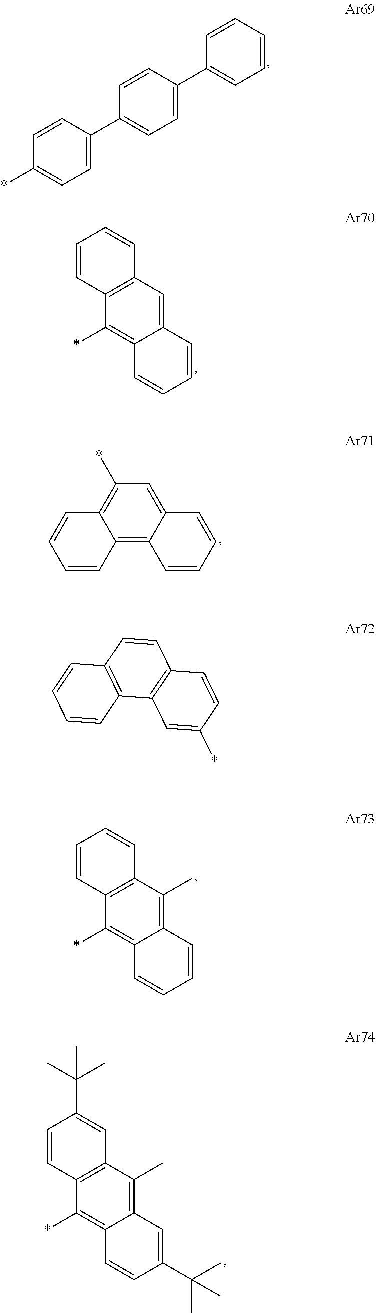 [SMILES: *c1ccc(-c2ccc(-c3ccccc3)cc2)cc1 ; *c1c2ccccc2cc2ccccc12 ; *c1cc2ccccc2c2ccccc12 ; *c1ccc2ccc3ccccc3c2c1 ; *c1c2ccccc2c(C)c2ccccc12 ; *c1c2ccc(C(C)(C)C)cc2c(C)c2cc(C(C)(C)C)ccc12] 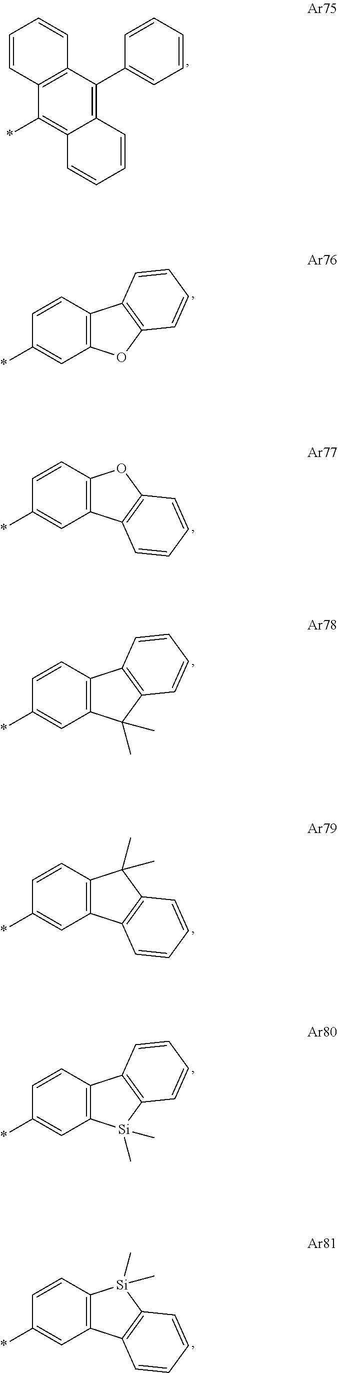 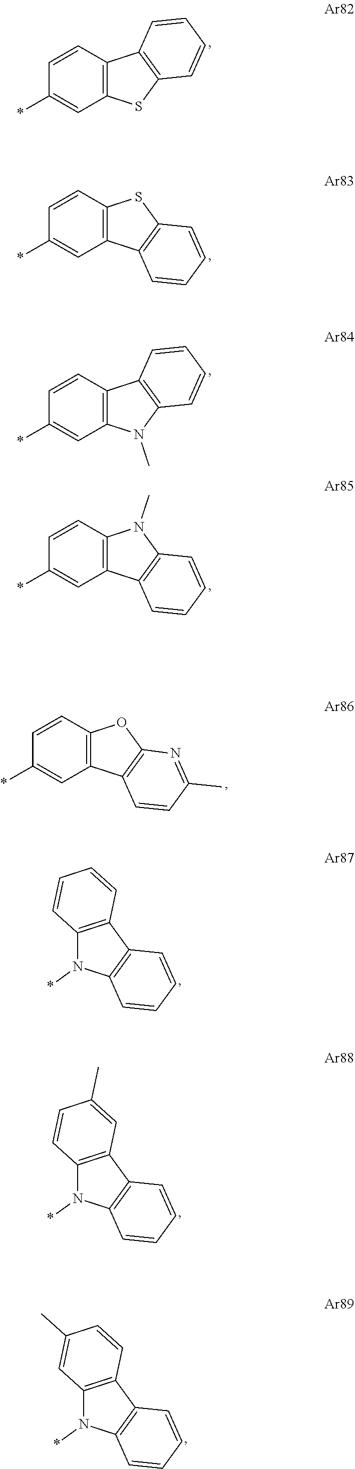 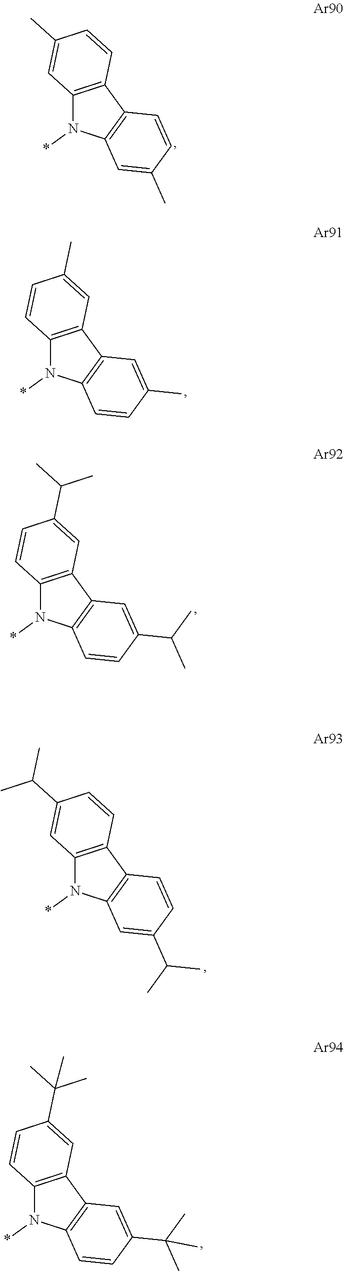 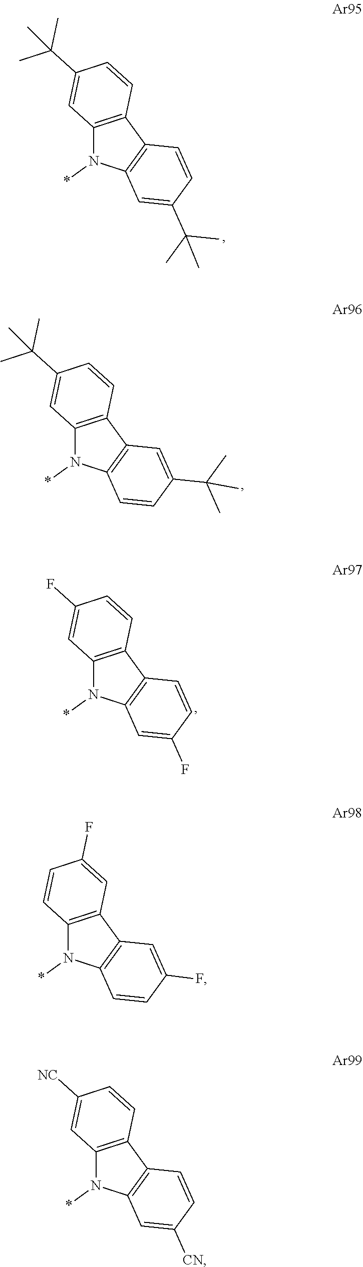 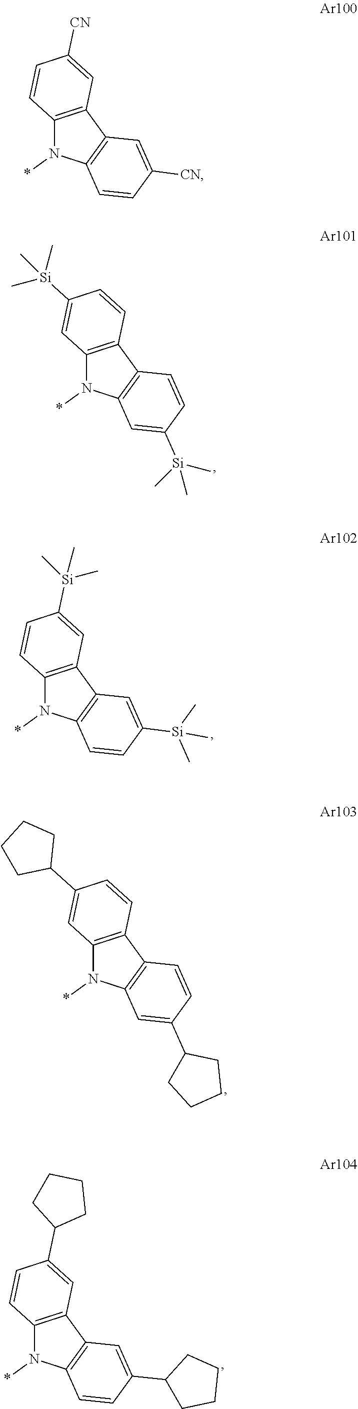 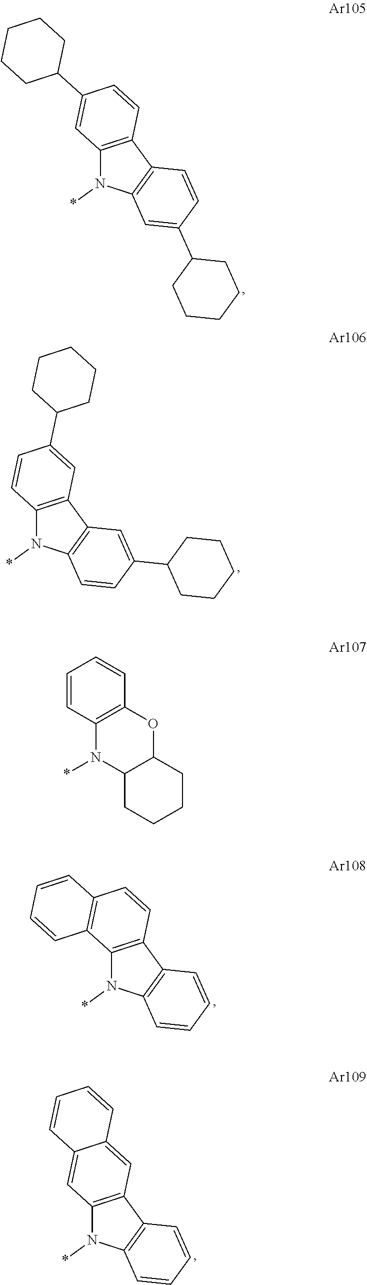 [SMILES: *n1c2cc(C3CCCCC3)ccc2c2ccc(C3CCCCC3)cc21 ; *n1c2ccc(C3CCCCC3)cc2c2cc(C3CCCCC3)ccc21 ; *N1c2ccccc2OC2CCCCC21 ; *n1c2ccccc2c2ccc3ccccc3c21 ; *n1c2ccccc2c2cc3ccccc3cc21] 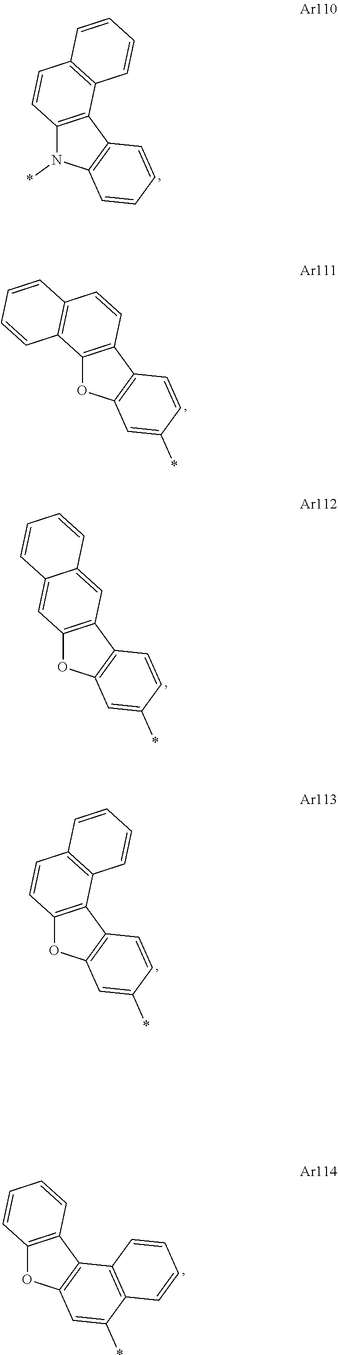 [SMILES: *n1c2ccccc2c2c3ccccc3ccc21 ; *c1ccc2c(c1)oc1c3ccccc3ccc21 ; *c1ccc2c(c1)oc1cc3ccccc3cc12 ; *c1ccc2c(c1)oc1ccc3ccccc3c12 ; *c1cc2oc3ccccc3c2c2ccccc12] 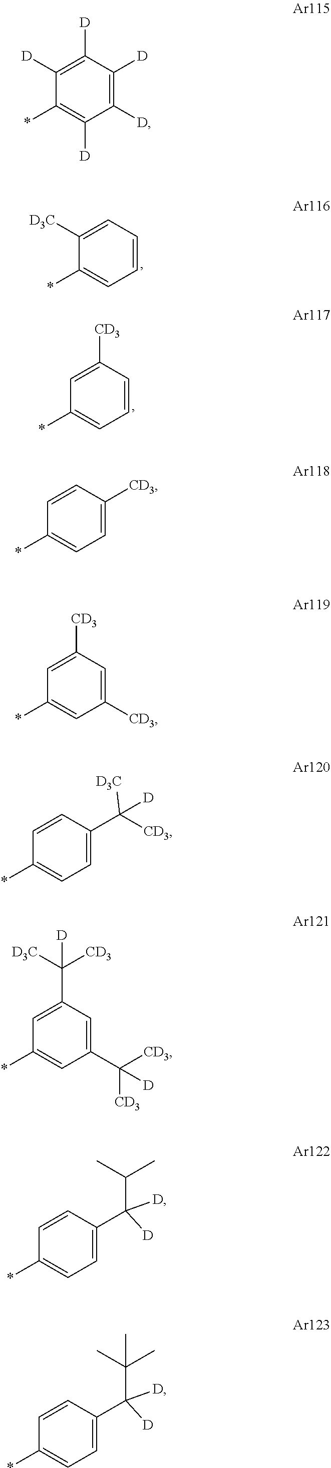 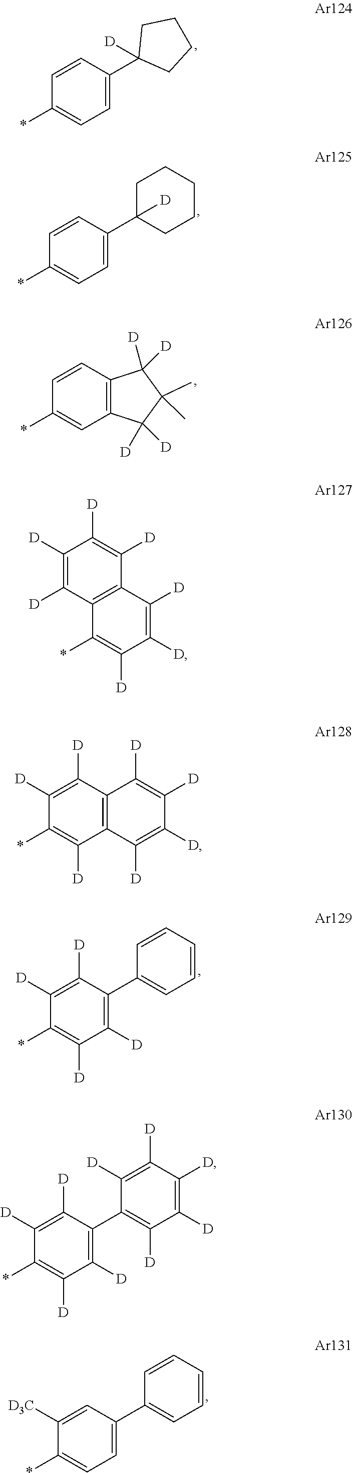 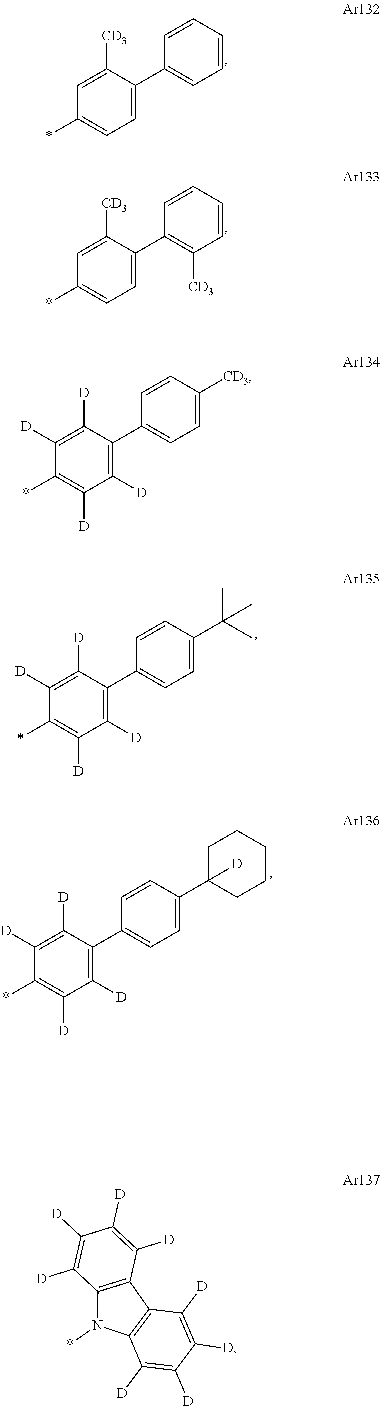 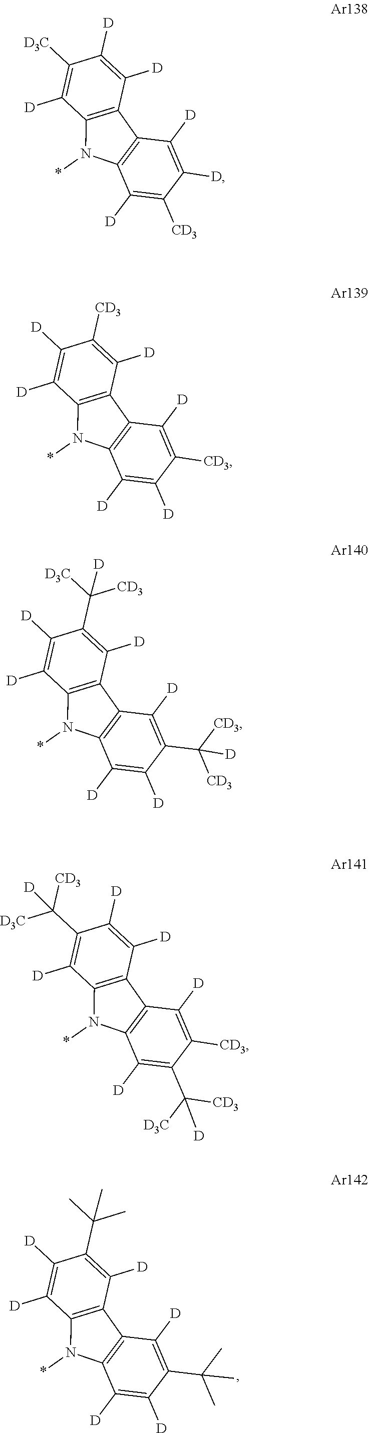 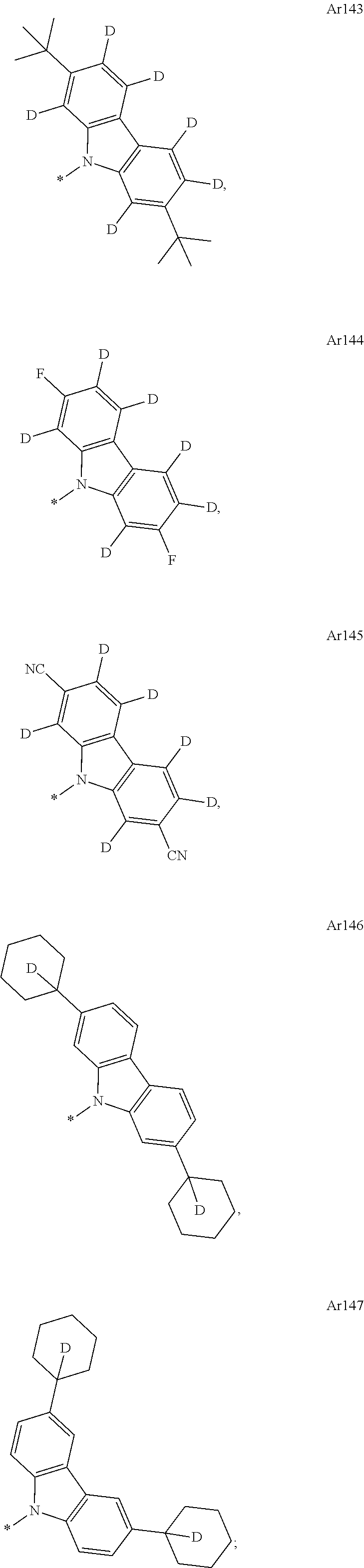
wherein optionally, “*” in Ar1 to Ar147 represents a joining position in Formula 1 or Formula 3, and hydrogen in Ar1 to Ar114, Ar116 to Ar126, Ar129, Ar131 to Ar136, Ar142, Ar143, Ar146 and Ar147 can be partially or fully substituted with deuterium.

16. The metal complex according to claim 1, wherein Lₐ is, at each occurrence identically or differently, selected from the group consisting of Lₐ₁ to Lₐ₆₉₅₄;
wherein Lₐ₁ to Lₐ₆₉₅₄ each have the following structure: 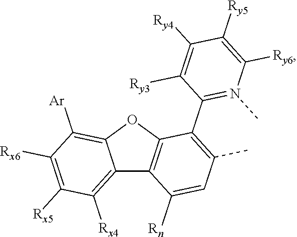
wherein Rₙ, Rₓ₄, Rₓ₅, Rₓ₆, Ar and R_{y3} to R_{y6} are selected from the atoms or groups in the following table:

| Lₐ No. | Rₙ | Ar | Rₓ₄ | Rₓ₅ | Rₓ₆ | R_{y3} | R_{y4} | R_{y5} | R_{y6} |
|---|---|---|---|---|---|---|---|---|---|
| Lₐ₁ | Rₙ₁ | Ar1 | H | H | H | H | H | H | H |
| Lₐ₂ | Rₙ₄ | Ar1 | H | H | H | H | H | H | H |
| Lₐ₃ | Rₙ₅ | Ar1 | H | H | H | H | H | H | H |
| Lₐ₄ | Rₙ₇ | Ar1 | H | H | H | H | H | H | H |
| Lₐ₅ | Rₙ₁₁ | Ar1 | H | H | H | H | H | H | H |
| Lₐ₆ | Rₙ₂₀ | Ar1 | H | H | H | H | H | H | H |
| Lₐ₇ | Rₙ₂₁ | Ar1 | H | H | H | H | H | H | H |
| Lₐ₈ | Rₙ₅₁ | Ar1 | H | H | H | H | H | H | H |
| Lₐ₉ | Rₙ₅₆ | Ar1 | H | H | H | H | H | H | H |
| Lₐ₁₀ | Rₙ₅₉ | Ar1 | H | H | H | H | H | H | H |
| Lₐ₁₁ | Rₙ₆₀ | Ar1 | H | H | H | H | H | H | H |
| Lₐ₁₂ | Rₙ₆₁ | Ar1 | H | H | H | H | H | H | H |
| Lₐ₁₃ | Rₙ₆₂ | Ar1 | H | H | H | H | H | H | H |
| Lₐ₁₄ | Rₙ₆₄ | Ar1 | H | H | H | H | H | H | H |
| Lₐ₁₅ | Rₙ₆₅ | Ar1 | H | H | H | H | H | H | H |
| Lₐ₁₆ | Rₙ₆₉ | Ar1 | H | H | H | H | H | H | H |
| Lₐ₁₇ | Rₙ₇₀ | Ar1 | H | H | H | H | H | H | H |
| Lₐ₁₈ | Rₙ₈₁ | Ar1 | H | H | H | H | H | H | H |
| Lₐ₁₉ | Rₙ₁ | Ar1 | H | H | H | H | H | Rₙ₁₁ | H |
| Lₐ₂₀ | Rₙ₄ | Ar1 | H | H | H | H | H | Rₙ₁₁ | H |
| Lₐ₂₁ | Rₙ₅ | Ar1 | H | H | H | H | H | Rₙ₁₁ | H |
| Lₐ₂₂ | Rₙ₇ | Ar1 | H | H | H | H | H | Rₙ₁₁ | H |
| Lₐ₂₃ | Rₙ₁₁ | Ar1 | H | H | H | H | H | Rₙ₁₁ | H |
| Lₐ₂₄ | Rₙ₂₀ | Ar1 | H | H | H | H | H | Rₙ₁₁ | H |
| Lₐ₂₅ | Rₙ₂₁ | Ar1 | H | H | H | H | H | Rₙ₁₁ | H |
| Lₐ₂₆ | Rₙ₅₁ | Ar1 | H | H | H | H | H | Rₙ₁₁ | H |
| Lₐ₂₇ | Rₙ₅₆ | Ar1 | H | H | H | H | H | Rₙ₁₁ | H |
| Lₐ₂₈ | Rₙ₅₉ | Ar1 | H | H | H | H | H | Rₙ₁₁ | H |
| Lₐ₂₉ | Rₙ₆₀ | Ar1 | H | H | H | H | H | Rₙ₁₁ | H |
| Lₐ₃₀ | Rₙ₆₁ | Ar1 | H | H | H | H | H | Rₙ₁₁ | H |
| Lₐ₃₁ | Rₙ₆₂ | Ar1 | H | H | H | H | H | Rₙ₁₁ | H |
| Lₐ₃₂ | Rₙ₆₄ | Ar1 | H | H | H | H | H | Rₙ₁₁ | H |
| Lₐ₃₃ | Rₙ₆₅ | Ar1 | H | H | H | H | H | Rₙ₁₁ | H |
| Lₐ₃₄ | Rₙ₆₉ | Ar1 | H | H | H | H | H | Rₙ₁₁ | H |
| Lₐ₃₅ | Rₙ₇₀ | Ar1 | H | H | H | H | H | Rₙ₁₁ | H |
| Lₐ₃₆ | Rₙ₈₁ | Ar1 | H | H | H | H | H | Rₙ₁₁ | H |
| Lₐ₃₇ | Rₙ₁ | Ar1 | H | H | H | H | H | Rₙ₅₉ | D |
| Lₐ₃₈ | Rₙ₄ | Ar1 | H | H | H | H | H | Rₙ₅₉ | D |
| Lₐ₃₉ | Rₙ₅ | Ar1 | H | H | H | H | H | Rₙ₅₉ | D |
| Lₐ₄₀ | Rₙ₇ | Ar1 | H | H | H | H | H | Rₙ₅₉ | D |
| Lₐ₄₁ | Rₙ₁₁ | Ar1 | H | H | H | H | H | Rₙ₅₉ | D |
| Lₐ₄₂ | Rₙ₂₀ | Ar1 | H | H | H | H | H | Rₙ₅₉ | D |
| Lₐ₄₃ | Rₙ₂₁ | Ar1 | H | H | H | H | H | Rₙ₅₉ | D |
| Lₐ₄₄ | Rₙ₅₁ | Ar1 | H | H | H | H | H | Rₙ₅₉ | D |
| Lₐ₄₅ | Rₙ₅₆ | Ar1 | H | H | H | H | H | Rₙ₅₉ | D |
| Lₐ₄₆ | Rₙ₅₉ | Ar1 | H | H | H | H | H | Rₙ₅₉ | D |
| Lₐ₄₇ | Rₙ₆₀ | Ar1 | H | H | H | H | H | Rₙ₅₉ | D |
| Lₐ₄₈ | Rₙ₆₁ | Ar1 | H | H | H | H | H | Rₙ₅₉ | D |
| Lₐ₄₉ | Rₙ₆₂ | Ar1 | H | H | H | H | H | Rₙ₅₉ | D |
| Lₐ₅₀ | Rₙ₆₄ | Ar1 | H | H | H | H | H | Rₙ₅₉ | D |
| Lₐ₅₁ | Rₙ₆₅ | Ar1 | H | H | H | H | H | Rₙ₅₉ | D |
| Lₐ₅₂ | Rₙ₆₉ | Ar1 | H | H | H | H | H | Rₙ₅₉ | D |
| Lₐ₅₃ | Rₙ₇₀ | Ar1 | H | H | H | H | H | Rₙ₅₉ | D |
| Lₐ₅₄ | Rₙ₈₁ | Ar1 | H | H | H | H | H | Rₙ₅₉ | D |
| Lₐ₅₅ | Rₙ₁ | Ar1 | H | H | H | H | H | Rₙ₆₀ | D |
| Lₐ₅₆ | Rₙ₄ | Ar1 | H | H | H | H | H | Rₙ₆₀ | D |
| Lₐ₅₇ | Rₙ₅ | Ar1 | H | H | H | H | H | Rₙ₆₀ | D |
| Lₐ₅₈ | Rₙ₇ | Ar1 | H | H | H | H | H | Rₙ₆₀ | D |
| Lₐ₅₉ | Rₙ₁₁ | Ar1 | H | H | H | H | H | Rₙ₆₀ | D |
| Lₐ₆₀ | Rₙ₂₀ | Ar1 | H | H | H | H | H | Rₙ₆₀ | D |
| Lₐ₆₁ | Rₙ₂₁ | Ar1 | H | H | H | H | H | Rₙ₆₀ | D |
| Lₐ₆₂ | Rₙ₅₁ | Ar1 | H | H | H | H | H | Rₙ₆₀ | D |
| Lₐ₆₃ | Rₙ₅₆ | Ar1 | H | H | H | H | H | Rₙ₆₀ | D |
| Lₐ₆₄ | Rₙ₅₉ | Ar1 | H | H | H | H | H | Rₙ₆₀ | D |
| Lₐ₆₅ | Rₙ₆₀ | Ar1 | H | H | H | H | H | Rₙ₆₀ | D |
| Lₐ₆₆ | Rₙ₆₁ | Ar1 | H | H | H | H | H | Rₙ₆₀ | D |
| Lₐ₆₇ | Rₙ₆₂ | Ar1 | H | H | H | H | H | Rₙ₆₀ | D |
| Lₐ₆₈ | Rₙ₆₄ | Ar1 | H | H | H | H | H | Rₙ₆₀ | D |
| Lₐ₆₉ | Rₙ₆₅ | Ar1 | H | H | H | H | H | Rₙ₆₀ | D |
| Lₐ₇₀ | Rₙ₆₉ | Ar1 | H | H | H | H | H | Rₙ₆₀ | D |
| Lₐ₇₁ | Rₙ₇₀ | Ar1 | H | H | H | H | H | Rₙ₆₀ | D |
| Lₐ₇₂ | Rₙ₈₁ | Ar1 | H | H | H | H | H | Rₙ₆₀ | D |
| Lₐ₇₃ | Rₙ₁ | Ar1 | H | H | H | H | H | Rₙ₆₄ | H |
| Lₐ₇₄ | Rₙ₄ | Ar1 | H | H | H | H | H | Rₙ₆₄ | H |
| Lₐ₇₅ | Rₙ₅ | Ar1 | H | H | H | H | H | Rₙ₆₄ | H |
| Lₐ₇₆ | Rₙ₇ | Ar1 | H | H | H | H | H | Rₙ₆₄ | H |
| Lₐ₇₇ | Rₙ₁₁ | Ar1 | H | H | H | H | H | Rₙ₆₄ | H |
| Lₐ₇₈ | Rₙ₂₀ | Ar1 | H | H | H | H | H | Rₙ₆₄ | H |
| Lₐ₇₉ | Rₙ₂₁ | Ar1 | H | H | H | H | H | Rₙ₆₄ | H |
| Lₐ₈₀ | Rₙ₅₁ | Ar1 | H | H | H | H | H | Rₙ₆₄ | H |
| Lₐ₈₁ | Rₙ₅₆ | Ar1 | H | H | H | H | H | Rₙ₆₄ | H |
| Lₐ₈₂ | Rₙ₅₉ | Ar1 | H | H | H | H | H | Rₙ₆₄ | H |
| Lₐ₈₃ | Rₙ₆₀ | Ar1 | H | H | H | H | H | Rₙ₆₄ | H |
| Lₐ₈₄ | Rₙ₆₁ | Ar1 | H | H | H | H | H | Rₙ₆₄ | H |
| Lₐ₈₅ | Rₙ₆₂ | Ar1 | H | H | H | H | H | Rₙ₆₄ | H |
| Lₐ₈₆ | Rₙ₆₄ | Ar1 | H | H | H | H | H | Rₙ₆₄ | H |
| Lₐ₈₇ | Rₙ₆₅ | Ar1 | H | H | H | H | H | Rₙ₆₄ | H |
| Lₐ₈₈ | Rₙ₆₉ | Ar1 | H | H | H | H | H | Rₙ₆₄ | H |
| Lₐ₈₉ | Rₙ₇₀ | Ar1 | H | H | H | H | H | Rₙ₆₄ | H |
| Lₐ₉₀ | Rₙ₈₁ | Ar1 | H | H | H | H | H | Rₙ₆₄ | H |
| Lₐ₉₁ | Rₙ₁ | Ar1 | H | H | H | H | H | Me | H |
| Lₐ₉₂ | Rₙ₄ | Ar1 | H | H | H | H | H | Me | H |
| Lₐ₉₃ | Rₙ₅ | Ar1 | H | H | H | H | H | Me | H |
| Lₐ₉₄ | Rₙ₇ | Ar1 | H | H | H | H | H | Me | H |
| Lₐ₉₅ | Rₙ₁₁ | Ar1 | H | H | H | H | H | Me | H |
| Lₐ₉₆ | Rₙ₂₀ | Ar1 | H | H | H | H | H | Me | H |
| Lₐ₉₇ | Rₙ₂₁ | Ar1 | H | H | H | H | H | Me | H |
| Lₐ₉₈ | Rₙ₅₁ | Ar1 | H | H | H | H | H | Me | H |
| Lₐ₉₉ | Rₙ₅₆ | Ar1 | H | H | H | H | H | Me | H |
| Lₐ₁₀₀ | Rₙ₅₉ | Ar1 | H | H | H | H | H | Me | H |
| Lₐ₁₀₁ | Rₙ₆₀ | Ar1 | H | H | H | H | H | Me | H |
| Lₐ₁₀₂ | Rₙ₆₁ | Ar1 | H | H | H | H | H | Me | H |
| Lₐ₁₀₃ | Rₙ₆₂ | Ar1 | H | H | H | H | H | Me | H |
| Lₐ₁₀₄ | Rₙ₆₄ | Ar1 | H | H | H | H | H | Me | H |
| Lₐ₁₀₅ | Rₙ₆₅ | Ar1 | H | H | H | H | H | Me | H |
| Lₐ₁₀₆ | Rₙ₆₉ | Ar1 | H | H | H | H | H | Me | H |
| Lₐ₁₀₇ | Rₙ₇₀ | Ar1 | H | H | H | H | H | Me | H |
| Lₐ₁₀₈ | Rₙ₈₁ | Ar1 | H | H | H | H | H | Me | H |
| Lₐ₁₀₉ | Rₙ₁ | Ar1 | H | H | H | H | Rₙ₁₁ | H | H |
| Lₐ₁₁₀ | Rₙ₄ | Ar1 | H | H | H | H | Rₙ₁₁ | H | H |
| Lₐ₁₁₁ | Rₙ₅ | Ar1 | H | H | H | H | Rₙ₁₁ | H | H |
| Lₐ₁₁₂ | Rₙ₇ | Ar1 | H | H | H | H | Rₙ₁₁ | H | H |
| Lₐ₁₁₃ | Rₙ₁₁ | Ar1 | H | H | H | H | Rₙ₁₁ | H | H |
| Lₐ₁₁₄ | Rₙ₂₀ | Ar1 | H | H | H | H | Rₙ₁₁ | H | H |
| Lₐ₁₁₅ | Rₙ₂₁ | Ar1 | H | H | H | H | Rₙ₁₁ | H | H |
| Lₐ₁₁₆ | Rₙ₅₁ | Ar1 | H | H | H | H | Rₙ₁₁ | H | H |
| Lₐ₁₁₇ | Rₙ₅₆ | Ar1 | H | H | H | H | Rₙ₁₁ | H | H |
| Lₐ₁₁₈ | Rₙ₅₉ | Ar1 | H | H | H | H | Rₙ₁₁ | H | H |
| Lₐ₁₁₉ | Rₙ₆₀ | Ar1 | H | H | H | H | Rₙ₁₁ | H | H |
| Lₐ₁₂₀ | Rₙ₆₁ | Ar1 | H | H | H | H | Rₙ₁₁ | H | H |
| Lₐ₁₂₁ | Rₙ₆₂ | Ar1 | H | H | H | H | Rₙ₁₁ | H | H |
| Lₐ₁₂₂ | Rₙ₆₄ | Ar1 | H | H | H | H | Rₙ₁₁ | H | H |
| Lₐ₁₂₃ | Rₙ₆₅ | Ar1 | H | H | H | H | Rₙ₁₁ | H | H |
| Lₐ₁₂₄ | Rₙ₆₉ | Ar1 | H | H | H | H | Rₙ₁₁ | H | H |
| Lₐ₁₂₅ | Rₙ₇₀ | Ar1 | H | H | H | H | Rₙ₁₁ | H | H |
| Lₐ₁₂₆ | Rₙ₈₁ | Ar1 | H | H | H | H | Rₙ₁₁ | H | H |
| Lₐ₁₂₇ | Rₙ₁ | Ar1 | H | H | H | H | Rₙ₅₉ | H | D |
| Lₐ₁₂₈ | Rₙ₄ | Ar1 | H | H | H | H | Rₙ₅₉ | H | D |
| Lₐ₁₂₉ | Rₙ₅ | Ar1 | H | H | H | H | Rₙ₅₉ | H | D |
| Lₐ₁₃₀ | Rₙ₇ | Ar1 | H | H | H | H | Rₙ₅₉ | H | D |
| Lₐ₁₃₁ | Rₙ₁₁ | Ar1 | H | H | H | H | Rₙ₅₉ | H | D |
| Lₐ₁₃₂ | Rₙ₂₀ | Ar1 | H | H | H | H | Rₙ₅₉ | H | D |
| Lₐ₁₃₃ | Rₙ₂₁ | Arl | H | H | H | H | Rₙ₅₉ | H | D |
| Lₐ₁₃₄ | Rₙ₅₁ | Ar1 | H | H | H | H | Rₙ₅₉ | H | D |
| Lₐ₁₃₅ | Rₙ₅₆ | Ar1 | H | H | H | H | Rₙ₅₉ | H | D |
| Lₐ₁₃₆ | Rₙ₅₉ | Ar1 | H | H | H | H | Rₙ₅₉ | H | D |
| Lₐ₁₃₇ | Rₙ₆₀ | Ar1 | H | H | H | H | Rₙ₅₉ | H | D |
| Lₐ₁₃₈ | Rₙ₆₁ | Arl | H | H | H | H | Rₙ₅₉ | H | D |
| Lₐ₁₃₉ | Rₙ₆₂ | Ar1 | H | H | H | H | Rₙ₅₉ | H | D |
| Lₐ₁₄₀ | Rₙ₆₄ | Ar1 | H | H | H | H | Rₙ₅₉ | H | D |
| Lₐ₁₄₁ | Rₙ₆₅ | Ar1 | H | H | H | H | Rₙ₅₉ | H | D |
| Lₐ₁₄₂ | Rₙ₆₉ | Ar1 | H | H | H | H | Rₙ₅₉ | H | D |
| Lₐ₁₄₃ | Rₙ₇₀ | Ar1 | H | H | H | H | Rₙ₅₉ | H | D |
| Lₐ₁₄₄ | Rₙ₈₁ | Ar1 | H | H | H | H | Rₙ₅₉ | H | D |
| Lₐ₁₄₅ | Rₙ₁ | Ar1 | H | H | H | H | Rₙ₆₀ | H | D |
| Lₐ₁₄₆ | Rₙ₄ | Ar1 | H | H | H | H | Rₙ₆₀ | H | D |
| Lₐ₁₄₇ | Rₙ₅ | Ar1 | H | H | H | H | Rₙ₆₀ | H | D |
| Lₐ₁₄₈ | Rₙ₇ | Ar1 | H | H | H | H | Rₙ₆₀ | H | D |
| Lₐ₁₄₉ | Rₙ₁₁ | Ar1 | H | H | H | H | Rₙ₆₀ | H | D |
| Lₐ₁₅₀ | Rₙ₂₀ | Ar1 | H | H | H | H | Rₙ₆₀ | H | D |
| Lₐ₁₅₁ | Rₙ₂₁ | Ar1 | H | H | H | H | Rₙ₆₀ | H | D |
| Lₐ₁₅₂ | Rₙ₅₁ | Ar1 | H | H | H | H | Rₙ₆₀ | H | D |
| Lₐ₁₅₃ | Rₙ₅₆ | Ar1 | H | H | H | H | Rₙ₆₀ | H | D |
| Lₐ₁₅₄ | Rₙ₅₉ | Ar1 | H | H | H | H | Rₙ₆₀ | H | D |
| Lₐ₁₅₅ | Rₙ₆₀ | Ar1 | H | H | H | H | Rₙ₆₀ | H | D |
| Lₐ₁₅₆ | Rₙ₆₁ | Ar1 | H | H | H | H | Rₙ₆₀ | H | D |
| Lₐ₁₅₇ | Rₙ₆₂ | Ar | H | H | H | H | Rₙ₆₀ | H | D |
| Lₐ₁₅₈ | Rₙ₆₄ | Ar1 | H | H | H | H | Rₙ₆₀ | H | D |
| Lₐ₁₅₉ | Rₙ₆₅ | Ar1 | H | H | H | H | Rₙ₆₀ | H | D |
| Lₐ₁₆₀ | Rₙ₆₉ | Ar1 | H | H | H | H | Rₙ₆₀ | H | D |
| Lₐ₁₆₁ | Rₙ₇₀ | Ar1 | H | H | H | H | Rₙ₆₀ | H | D |
| Lₐ₁₆₂ | Rₙ₈₁ | Ar1 | H | H | H | H | Rₙ₆₀ | H | D |
| Lₐ₁₆₃ | Rₙ₁ | Ar1 | H | H | H | H | Rₙ₆₄ | H | H |
| Lₐ₁₆₄ | Rₙ₄ | Ar1 | H | H | H | H | Rₙ₆₄ | H | H |
| Lₐ₁₆₅ | Rₙ₅ | Ar1 | H | H | H | H | Rₙ₆₄ | H | H |
| Lₐ₁₆₆ | Rₙ₇ | Ar1 | H | H | H | H | Rₙ₆₄ | H | H |
| Lₐ₁₆₇ | Rₙ₁₁ | Ar1 | H | H | H | H | Rₙ₆₄ | H | H |
| Lₐ₁₆₈ | Rₙ₂₀ | Ar1 | H | H | H | H | Rₙ₆₄ | H | H |
| Lₐ₁₆₉ | Rₙ₂₁ | Ar1 | H | H | H | H | Rₙ₆₄ | H | H |
| Lₐ₁₇₀ | Rₙ₅₁ | Ar1 | H | H | H | H | Rₙ₆₄ | H | H |
| Lₐ₁₇₁ | Rₙ₅₆ | Ar1 | H | H | H | H | Rₙ₆₄ | H | H |
| Lₐ₁₇₂ | Rₙ₅₉ | Ar1 | H | H | H | H | Rₙ₆₄ | H | H |
| Lₐ₁₇₃ | Rₙ₆₀ | Ar1 | H | H | H | H | Rₙ₆₄ | H | H |
| Lₐ₁₇₄ | Rₙ₆₁ | Ar1 | H | H | H | H | Rₙ₆₄ | H | H |
| Lₐ₁₇₅ | Rₙ₆₂ | Ar1 | H | H | H | H | Rₙ₆₄ | H | H |
| Lₐ₁₇₆ | Rₙ₆₄ | Ar1 | H | H | H | H | Rₙ₆₄ | H | H |
| Lₐ₁₇₇ | Rₙ₆₅ | Ar1 | H | H | H | H | Rₙ₆₄ | H | H |
| Lₐ₁₇₈ | Rₙ₆₉ | Ar1 | H | H | H | H | Rₙ₆₄ | H | H |
| Lₐ₁₇₉ | Rₙ₇₀ | Ar1 | H | H | H | H | Rₙ₆₄ | H | H |
| Lₐ₁₈₀ | Rₙ₈₁ | Ar1 | H | H | H | H | Rₙ₆₄ | H | H |
| Lₐ₁₈₁ | Rₙ₁ | Ar1 | H | H | H | H | Me | H | H |
| Lₐ₁₈₂ | Rₙ₄ | Ar1 | H | H | H | H | Me | H | H |
| Lₐ₁₈₃ | Rₙ₅ | Ar1 | H | H | H | H | Me | H | H |
| Lₐ₁₈₄ | Rₙ₇ | Ar1 | H | H | H | H | Me | H | H |
| Lₐ₁₈₅ | Rₙ₁₁ | Ar1 | H | H | H | H | Me | H | H |
| Lₐ₁₈₆ | Rₙ₂₀ | Ar1 | H | H | H | H | Me | H | H |
| Lₐ₁₈₇ | Rₙ₂₁ | Ar1 | H | H | H | H | Me | H | H |
| Lₐ₁₈₈ | Rₙ₅₁ | Ar1 | H | H | H | H | Me | H | H |
| Lₐ₁₈₉ | Rₙ₅₆ | Ar1 | H | H | H | H | Me | H | H |
| Lₐ₁₉₀ | Rₙ₅₉ | Ar1 | H | H | H | H | Me | H | H |
| Lₐ₁₉₁ | Rₙ₆₀ | Ar1 | H | H | H | H | Me | H | H |
| Lₐ₁₉₂ | Rₙ₆₁ | Ar1 | H | H | H | H | Me | H | H |
| Lₐ₁₉₃ | Rₙ₆₂ | Ar1 | H | H | H | H | Me | H | H |
| Lₐ₁₉₄ | Rₙ₆₄ | Ar1 | H | H | H | H | Me | H | H |
| Lₐ₁₉₅ | Rₙ₆₅ | Ar1 | H | H | H | H | Me | H | H |
| Lₐ₁₉₆ | Rₙ₆₉ | Ar1 | H | H | H | H | Me | H | H |
| Lₐ₁₉₇ | Rₙ₇₀ | Ar1 | H | H | H | H | Me | H | H |
| Lₐ₁₉₈ | Rₙ₈₁ | Ar1 | H | H | H | H | Me | H | H |
| Lₐ₁₉₉ | Rₙ₁ | Ar1 | D | H | F | H | H | H | H |
| Lₐ₂₀₀ | Rₙ₄ | Ar1 | H | H | F | H | H | H | H |
| Lₐ₂₀₁ | Rₙ₇ | Ar1 | H | H | F | H | H | H | H |
| Lₐ₂₀₂ | Rₙ₂₀ | Ar1 | H | H | F | H | H | H | H |
| Lₐ₂₀₃ | Rₙ₂₁ | Ar1 | D | H | F | H | H | H | H |
| Lₐ₂₀₄ | Rₙ₅₆ | Ar1 | H | D | F | H | H | H | H |
| Lₐ₂₀₅ | Rₙ₅₉ | Ar1 | H | H | F | H | H | H | H |
| Lₐ₂₀₆ | Rₙ₆₁ | Ar1 | H | H | F | H | H | H | H |
| Lₐ₂₀₇ | Rₙ₆₂ | Ar1 | H | H | F | H | H | H | D |
| Lₐ₂₀₈ | Rₙ₆₄ | Ar1 | H | H | F | H | H | H | H |
| Lₐ₂₀₉ | Rₙ₆₉ | Ar1 | H | H | F | H | H | H | H |
| Lₐ₂₁₀ | Rₙ₇₀ | Ar1 | H | H | F | H | H | H | H |
| Lₐ₂₁₁ | Rₙ₁ | Ar1 | H | H | F | H | Rₙ₁₁ | H | H |
| Lₐ₂₁₂ | Rₙ₄ | Ar1 | H | H | F | H | Rₙ₁₁ | H | H |
| Lₐ₂₁₃ | Rₙ₇ | Ar1 | H | H | F | H | Rₙ₁₁ | H | D |
| Lₐ₂₁₄ | Rₙ₂₀ | Ar1 | H | H | F | H | Rₙ₁₁ | H | H |
| Lₐ₂₁₅ | Rₙ₂₁ | Ar1 | H | H | F | H | Rₙ₁₁ | H | H |
| Lₐ₂₁₆ | Rₙ₅₆ | Ar1 | H | H | F | H | Rₙ₁₁ | D | H |
| Lₐ₂₁₇ | Rₙ₅₉ | Ar1 | H | H | F | H | Rₙ₁₁ | H | H |
| Lₐ₂₁₈ | Rₙ₆₁ | Ar1 | H | H | F | H | Rₙ₁₁ | H | H |
| Lₐ₂₁₉ | Rₙ₆₂ | Ar1 | D | H | F | H | Rₙ₁₁ | H | H |
| Lₐ₂₂₀ | Rₙ₆₄ | Ar1 | H | H | F | H | Rₙ₁₁ | H | H |
| Lₐ₂₂₁ | Rₙ₆₉ | Ar1 | H | H | F | H | Rₙ₁₁ | H | H |
| Lₐ₂₂₂ | Rₙ₇₀ | Ar1 | H | D | F | H | Rₙ₁₁ | H | H |
| Lₐ₂₂₃ | Rₙ₁ | Ar1 | H | H | F | H | Rₙ₆₀ | H | D |
| Lₐ₂₂₄ | Rₙ₄ | Ar1 | H | H | F | H | Rₙ₆₀ | H | D |
| Lₐ₂₂₅ | Rₙ₇ | Ar1 | H | H | F | H | Rₙ₆₀ | H | D |
| Lₐ₂₂₆ | Rₙ₂₀ | Ar1 | H | H | F | H | Rₙ₆₀ | H | D |
| Lₐ₂₂₇ | Rₙ₂₁ | Ar1 | H | H | F | H | Rₙ₆₀ | H | D |
| Lₐ₂₂₈ | Rₙ₅₆ | Ar1 | H | H | F | H | Rₙ₆₀ | H | D |
| Lₐ₂₂₉ | Rₙ₅₉ | Ar1 | H | H | F | H | Rₙ₆₀ | H | D |
| Lₐ₂₃₀ | Rₙ₆₁ | Ar1 | H | H | F | H | Rₙ₆₀ | H | D |
| Lₐ₂₃₁ | Rₙ₆₂ | Ar1 | H | H | F | H | Rₙ₆₀ | H | D |
| Lₐ₂₃₂ | Rₙ₆₄ | Ar1 | H | H | F | H | Rₙ₆₀ | H | D |
| Lₐ₂₃₃ | Rₙ₆₉ | Ar1 | H | H | F | H | Rₙ₆₀ | H | D |
| Lₐ₂₃₄ | Rₙ₇₀ | Ar1 | H | H | F | H | Rₙ₆₀ | H | D |
| Lₐ₂₃₅ | Rₙ₁ | Ar1 | H | H | F | H | H | Rₙ₁₁ | H |
| Lₐ₂₃₆ | Rₙ₄ | Ar1 | H | H | F | H | H | Rₙ₁₁ | H |
| Lₐ₂₃₇ | Rₙ₇ | Ar1 | H | H | F | H | H | Rₙ₁₁ | H |
| Lₐ₂₃₈ | Rₙ₂₀ | Ar1 | H | H | F | H | H | Rₙ₁₁ | H |
| Lₐ₂₃₉ | Rₙ₂₁ | Ar1 | D | H | F | H | H | Rₙ₁₁ | H |
| Lₐ₂₄₀ | Rₙ₅₆ | Ar1 | H | H | F | H | H | Rₙ₁₁ | H |
| Lₐ₂₄₁ | Rₙ₅₉ | Ar1 | H | H | F | H | H | Rₙ₁₁ | H |
| Lₐ₂₄₂ | Rₙ₆₁ | Ar1 | H | H | F | H | H | Rₙ₁₁ | H |
| Lₐ₂₄₃ | Rₙ₆₂ | Ar1 | H | H | F | H | H | Rₙ₁₁ | H |
| Lₐ₂₄₄ | Rₙ₆₄ | Ar1 | H | H | F | H | H | Rₙ₁₁ | H |
| Lₐ₂₄₅ | Rₙ₆₉ | Ar1 | H | H | F | H | H | Rₙ₁₁ | H |
| Lₐ₂₄₆ | Rₙ₇₀ | Ar1 | H | H | F | H | H | Rₙ₁₁ | H |
| Lₐ₂₄₇ | Rₙ₁ | Ar1 | H | H | F | H | H | Rₙ₆₀ | D |
| Lₐ₂₄₈ | Rₙ₄ | Ar1 | H | H | F | H | H | Rₙ₆₀ | D |
| Lₐ₂₄₉ | Rₙ₇ | Ar1 | H | H | F | H | H | Rₙ₆₀ | D |
| Lₐ₂₅₀ | Rₙ₂₀ | Ar1 | H | H | F | H | H | Rₙ₆₀ | D |
| Lₐ₂₅₁ | Rₙ₂₁ | Ar1 | H | H | F | H | H | Rₙ₆₀ | D |
| Lₐ₂₅₂ | Rₙ₅₆ | Ar1 | H | H | F | H | H | Rₙ₆₀ | D |
| Lₐ₂₅₃ | Rₙ₅₉ | Ar1 | H | H | F | H | H | Rₙ₆₀ | D |
| Lₐ₂₅₄ | Rₙ₆₁ | Ar1 | H | H | F | H | H | Rₙ₆₀ | D |
| Lₐ₂₅₅ | Rₙ₆₂ | Ar1 | H | H | F | H | H | Rₙ₆₀ | D |
| Lₐ₂₅₆ | Rₙ₆₄ | Ar1 | H | H | F | H | H | Rₙ₆₀ | D |
| Lₐ₂₅₇ | Rₙ₆₉ | Ar1 | H | H | F | H | H | Rₙ₆₀ | D |
| Lₐ₂₅₈ | Rₙ₇₀ | Ar1 | H | H | F | H | H | Rₙ₆₀ | D |
| Lₐ₂₅₉ | Rₙ₁ | Ar1 | H | H | CN | H | H | H | H |
| Lₐ₂₆₀ | Rₙ₄ | Ar1 | D | H | CN | H | H | H | H |
| Lₐ₂₆₁ | Rₙ₇ | Ar1 | H | H | CN | H | H | H | H |
| Lₐ₂₆₂ | Rₙ₂₀ | Ar1 | H | H | CN | H | H | H | H |
| Lₐ₂₆₃ | Rₙ₂₁ | Ar1 | H | H | CN | H | H | D | H |
| Lₐ₂₆₄ | Rₙ₅₆ | Ar1 | H | H | CN | H | H | H | H |
| Lₐ₂₆₅ | Rₙ₅₉ | Ar1 | H | H | CN | H | H | H | H |
| Lₐ₂₆₆ | Rₙ₆₁ | Ar1 | H | H | CN | H | H | H | H |
| Lₐ₂₆₇ | Rₙ₆₂ | Ar1 | H | H | CN | H | H | H | H |
| Lₐ₂₆₈ | Rₙ₆₄ | Ar1 | H | H | CN | H | H | H | H |
| Lₐ₂₆₉ | Rₙ₆₉ | Ar1 | H | H | CN | H | H | H | H |
| Lₐ₂₇₀ | Rₙ₇₀ | Ar1 | H | H | CN | H | H | H | H |
| Lₐ₂₇₁ | Rₙ₁ | Ar1 | H | CN | H | H | H | H | H |
| Lₐ₂₇₂ | Rₙ₄ | Ar1 | H | CN | H | H | H | H | H |
| Lₐ₂₇₃ | Rₙ₇ | Ar1 | H | CN | D | H | H | H | H |
| Lₐ₂₇₄ | Rₙ₂₀ | Ar1 | H | CN | H | H | H | H | H |
| Lₐ₂₇₅ | Rₙ₂₁ | Ar1 | H | CN | H | H | H | H | H |
| Lₐ₂₇₆ | Rₙ₅₆ | Ar1 | H | CN | H | H | H | H | H |
| Lₐ₂₇₇ | Rₙ₅₉ | Ar1 | H | CN | H | H | H | H | H |
| Lₐ₂₇₈ | Rₙ₆₁ | Ar1 | D | CN | H | H | H | H | H |
| Lₐ₂₇₉ | Rₙ₆₂ | Ar1 | H | CN | H | H | H | H | H |
| Lₐ₂₈₀ | Rₙ₆₄ | Ar1 | H | CN | H | H | H | H | D |
| Lₐ₂₈₁ | Rₙ₆₉ | Ar1 | H | CN | H | H | H | H | H |
| Lₐ₂₈₂ | Rₙ₇₀ | Ar1 | H | CN | H | H | H | H | H |
| Lₐ₂₈₃ | Rₙ₁ | Ar1 | CN | H | H | H | H | H | H |
| Lₐ₂₈₄ | Rₙ₄ | Ar1 | CN | H | H | H | H | H | H |
| Lₐ₂₈₅ | Rₙ₇ | Ar1 | CN | H | H | H | H | H | H |
| Lₐ₂₈₆ | Rₙ₂₀ | Ar1 | CN | H | H | H | H | H | H |
| Lₐ₂₈₇ | Rₙ₂₁ | Ar1 | CN | H | H | H | H | H | H |
| Lₐ₂₈₈ | Rₙ₅₆ | Ar1 | CN | H | H | H | H | H | H |
| Lₐ₂₈₉ | Rₙ₅₉ | Ar1 | CN | H | H | H | H | H | H |
| Lₐ₂₉₀ | Rₙ₆₁ | Ar1 | CN | H | H | H | H | H | H |
| Lₐ₂₉₁ | Rₙ₆₂ | Ar1 | CN | H | H | H | H | H | H |
| Lₐ₂₉₂ | Rₙ₆₄ | Ar1 | CN | H | H | H | H | H | H |
| Lₐ₂₉₃ | Rₙ₆₉ | Ar1 | CN | H | H | H | H | H | H |
| Lₐ₂₉₄ | Rₙ₇₀ | Ar1 | CN | H | H | H | H | H | H |
| Lₐ₂₉₅ | Rₙ₁ | Ar1 | H | H | CN | H | Rₙ₁₁ | H | H |
| Lₐ₂₉₆ | Rₙ₄ | Ar1 | H | H | CN | H | Rₙ₁₁ | H | H |
| Lₐ₂₉₇ | Rₙ₇ | Ar1 | H | H | CN | H | Rₙ₁₁ | H | H |
| Lₐ₂₉₈ | Rₙ₂₀ | Ar1 | H | H | CN | H | Rₙ₁₁ | H | H |
| Lₐ₂₉₉ | Rₙ₂₁ | Ar1 | H | H | CN | H | Rₙ₁₁ | H | H |
| Lₐ₃₀₀ | Rₙ₅₆ | Ar1 | H | H | CN | H | Rₙ₁₁ | H | H |
| Lₐ₃₀₁ | Rₙ₅₉ | Ar1 | H | H | CN | H | Rₙ₁₁ | H | H |
| Lₐ₃₀₂ | Rₙ₆₁ | Ar1 | H | H | CN | H | Rₙ₁₁ | H | H |
| Lₐ₃₀₃ | Rₙ₆₂ | Ar1 | H | H | CN | H | Rₙ₁₁ | H | H |
| Lₐ₃₀₄ | Rₙ₆₄ | Ar1 | H | H | CN | H | Rₙ₁₁ | H | H |
| Lₐ₃₀₅ | Rₙ₆₉ | Ar1 | H | H | CN | H | Rₙ₁₁ | H | H |
| Lₐ₃₀₆ | Rₙ₇₀ | Ar1 | H | H | CN | H | Rₙ₁₁ | H | H |
| Lₐ₃₀₇ | Rₙ₁ | Ar1 | H | H | CN | H | Rₙ₆₀ | H | D |
| Lₐ₃₀₈ | Rₙ₄ | Ar1 | H | H | CN | H | Rₙ₆₀ | H | D |
| Lₐ₃₀₉ | Rₙ₇ | Ar1 | H | H | CN | H | Rₙ₆₀ | H | D |
| Lₐ₃₁₀ | Rₙ₂₀ | Ar1 | H | H | CN | H | Rₙ₆₀ | H | D |
| Lₐ₃₁₁ | Rₙ₂₁ | Ar1 | H | H | CN | H | Rₙ₆₀ | H | D |
| Lₐ₃₁₂ | Rₙ₅₆ | Ar1 | H | H | CN | H | Rₙ₆₀ | H | D |
| Lₐ₃₁₃ | Rₙ₅₉ | Ar1 | H | H | CN | H | Rₙ₆₀ | H | D |
| Lₐ₃₁₄ | Rₙ₆₁ | Ar1 | H | H | CN | H | Rₙ₆₀ | H | H |
| Lₐ₃₁₅ | Rₙ₆₂ | Ar1 | H | H | CN | H | Rₙ₆₀ | H | H |
| Lₐ₃₁₆ | Rₙ₆₄ | Ar1 | H | H | CN | H | Rₙ₆₀ | H | H |
| Lₐ₃₁₇ | Rₙ₆₉ | Ar1 | H | H | CN | H | Rₙ₆₀ | H | H |
| Lₐ₃₁₈ | Rₙ₇₀ | Ar1 | H | H | CN | H | Rₙ₆₀ | H | H |
| Lₐ₃₁₉ | Rₙ₁ | Ar1 | H | H | CN | H | Rₙ₆₄ | H | H |
| Lₐ₃₂₀ | Rₙ₄ | Ar1 | H | H | CN | H | Rₙ₆₄ | H | H |
| Lₐ₃₂₁ | Rₙ₇ | Ar1 | H | H | CN | H | Rₙ₆₄ | H | H |
| Lₐ₃₂₂ | Rₙ₂₀ | Ar1 | H | H | CN | H | Rₙ₆₄ | H | H |
| Lₐ₃₂₃ | Rₙ₂₁ | Ar1 | H | H | CN | H | Rₙ₆₄ | H | H |
| Lₐ₃₂₄ | Rₙ₅₆ | Ar1 | H | H | CN | H | Rₙ₆₄ | H | H |
| Lₐ₃₂₅ | Rₙ₅₉ | Ar1 | D | H | CN | H | Rₙ₆₄ | H | H |
| Lₐ₃₂₆ | Rₙ₆₁ | Ar1 | H | H | CN | H | Rₙ₆₄ | H | H |
| Lₐ₃₂₇ | Rₙ₆₂ | Ar1 | H | D | CN | H | Rₙ₆₄ | H | H |
| Lₐ₃₂₈ | Rₙ₆₄ | Ar1 | H | H | CN | H | Rₙ₆₄ | H | H |
| Lₐ₃₂₉ | Rₙ₆₉ | Ar1 | H | H | CN | H | Rₙ₆₄ | H | H |
| Lₐ₃₃₀ | Rₙ₇₀ | Ar1 | H | H | CN | H | Rₙ₆₄ | H | H |
| Lₐ₃₃₁ | Rₙ₁ | Ar1 | H | H | CN | H | H | Rₙ₁₁ | H |
| Lₐ₃₃₂ | Rₙ₄ | Ar1 | H | H | CN | H | H | Rₙ₁₁ | H |
| Lₐ₃₃₃ | Rₙ₇ | Ar1 | H | H | CN | H | H | Rₙ₁₁ | H |
| Lₐ₃₃₄ | Rₙ₂₀ | Ar1 | H | H | CN | H | H | Rₙ₁₁ | H |
| Lₐ₃₃₅ | Rₙ₂₁ | Ar1 | H | H | CN | H | H | Rₙ₁₁ | H |
| Lₐ₃₃₆ | Rₙ₅₆ | Ar1 | H | H | CN | H | H | Rₙ₁₁ | H |
| Lₐ₃₃₇ | Rₙ₅₉ | Arl | H | H | CN | H | H | Rₙ₁₁ | H |
| Lₐ₃₃₈ | Rₙ₆₁ | Ar1 | H | H | CN | H | H | Rₙ₁₁ | H |
| Lₐ₃₃₉ | Rₙ₆₂ | Ar1 | H | H | CN | H | H | Rₙ₁₁ | H |
| Lₐ₃₄₀ | Rₙ₆₄ | Ar1 | H | H | CN | H | H | Rₙ₁₁ | H |
| Lₐ₃₄₁ | Rₙ₆₉ | Ar1 | H | H | CN | H | H | Rₙ₁₁ | H |
| Lₐ₃₄₂ | Rₙ₇₀ | Ar1 | H | H | CN | H | H | Rₙ₁₁ | H |
| Lₐ₃₄₃ | Rₙ₁ | Ar1 | H | H | CN | H | H | Rₙ₆₀ | H |
| Lₐ₃₄₄ | Rₙ₄ | Ar1 | H | H | CN | H | H | Rₙ₆₀ | H |
| Lₐ₃₄₅ | Rₙ₇ | Ar1 | H | H | CN | H | H | Rₙ₆₀ | H |
| Lₐ₃₄₆ | Rₙ₂₀ | Ar1 | H | H | CN | H | H | Rₙ₆₀ | H |
| Lₐ₃₄₇ | Rₙ₂₁ | Ar1 | H | H | CN | H | H | Rₙ₆₀ | H |
| Lₐ₃₄₈ | Rₙ₅₆ | Ar1 | H | H | CN | H | H | Rₙ₆₀ | D |
| Lₐ₃₄₉ | Rₙ₅₉ | Ar1 | H | H | CN | H | H | Rₙ₆₀ | D |
| Lₐ₃₅₀ | Rₙ₆₁ | Ar1 | H | H | CN | H | H | Rₙ₆₀ | D |
| Lₐ₃₅₁ | Rₙ₆₂ | Ar1 | H | H | CN | H | H | Rₙ₆₀ | D |
| Lₐ₃₅₂ | Rₙ₆₄ | Ar1 | H | H | CN | H | H | Rₙ₆₀ | D |
| Lₐ₃₅₃ | Rₙ₆₉ | Ar1 | H | H | CN | H | H | Rₙ₆₀ | D |
| Lₐ₃₅₄ | Rₙ₇₀ | Ar1 | H | H | CN | H | H | Rₙ₆₀ | D |
| Lₐ₃₅₅ | Rₙ₁ | Ar1 | H | H | CN | H | H | Rₙ₆₄ | H |
| Lₐ₃₅₆ | Rₙ₄ | Ar1 | H | H | CN | H | H | Rₙ₆₄ | H |
| Lₐ₃₅₇ | Rₙ₇ | Ar1 | H | H | CN | H | H | Rₙ₆₄ | H |
| Lₐ₃₅₈ | Rₙ₂₀ | Ar1 | H | H | CN | H | H | Rₙ₆₄ | H |
| Lₐ₃₅₉ | Rₙ₂₁ | Ar1 | H | H | CN | H | H | Rₙ₆₄ | H |
| Lₐ₃₆₀ | Rₙ₅₆ | Ar1 | H | H | CN | H | H | Rₙ₆₄ | H |
| Lₐ₃₆₁ | Rₙ₅₉ | Ar1 | H | H | CN | H | H | Rₙ₆₄ | H |
| Lₐ₃₆₂ | Rₙ₆₁ | Ar1 | H | H | CN | H | H | Rₙ₆₄ | H |
| Lₐ₃₆₃ | Rₙ₆₂ | Ar1 | H | H | CN | H | H | Rₙ₆₄ | H |
| Lₐ₃₆₄ | Rₙ₆₄ | Ar1 | H | H | CN | H | H | Rₙ₆₄ | H |
| Lₐ₃₆₅ | Rₙ₆₉ | Ar1 | H | H | CN | H | H | Rₙ₆₄ | H |
| Lₐ₃₆₆ | Rₙ₇₀ | Ar1 | D | H | CN | H | H | Rₙ₆₄ | H |
| Lₐ₃₆₇ | Rₙ₁ | Ar16 | H | H | H | H | H | H | D |
| Lₐ₃₆₈ | Rₙ₄ | Ar16 | H | H | H | H | H | H | H |
| Lₐ₃₆₉ | Rₙ₅ | Ar16 | H | H | H | H | H | H | H |
| Lₐ₃₇₀ | Rₙ₇ | Ar16 | H | H | H | H | H | H | H |
| Lₐ₃₇₁ | Rₙ₁₁ | Ar16 | H | H | H | D | H | H | H |
| Lₐ₃₇₂ | Rₙ₂₀ | Ar16 | H | H | H | H | H | H | H |
| Lₐ₃₇₃ | Rₙ₂₁ | Ar16 | H | H | H | H | H | H | H |
| Lₐ₃₇₄ | Rₙ₅₁ | Ar16 | H | H | H | H | H | H | H |
| Lₐ₃₇₅ | Rₙ₅₆ | Ar16 | H | H | H | H | H | H | H |
| Lₐ₃₇₆ | Rₙ₅₉ | Ar16 | H | H | H | H | H | H | H |
| Lₐ₃₇₇ | Rₙ₆₀ | Ar16 | H | H | H | H | H | H | H |
| Lₐ₃₇₈ | Rₙ₆₁ | Ar16 | H | H | H | H | H | H | H |
| Lₐ₃₇₉ | Rₙ₆₂ | Ar16 | H | H | H | H | H | H | H |
| Lₐ₃₈₀ | Rₙ₆₄ | Ar16 | D | H | H | H | H | H | H |
| Lₐ₃₈₁ | Rₙ₆₅ | Ar16 | H | H | H | H | H | H | H |
| Lₐ₃₈₂ | Rₙ₆₉ | Ar16 | H | H | H | H | H | H | H |
| Lₐ₃₈₃ | Rₙ₇₀ | Ar16 | H | H | H | H | H | H | H |
| Lₐ₃₈₄ | Rₙ₈₁ | Ar16 | H | H | H | H | H | H | H |
| Lₐ₃₈₅ | Rₙ₁ | Ar16 | H | H | H | H | H | Rₙ₁₁ | H |
| Lₐ₃₈₆ | Rₙ₄ | Ar16 | H | H | H | H | H | Rₙ₁₁ | H |
| Lₐ₃₈₇ | Rₙ₅ | Ar16 | H | H | H | H | H | Rₙ₁₁ | H |
| Lₐ₃₈₈ | Rₙ₇ | Ar16 | H | H | H | H | H | Rₙ₁₁ | H |
| Lₐ₃₈₉ | Rₙ₁₁ | Ar16 | H | H | H | H | H | Rₙ₁₁ | H |
| Lₐ₃₉₀ | Rₙ₂₀ | Ar16 | H | H | H | H | H | Rₙ₁₁ | H |
| Lₐ₃₉₁ | Rₙ₂₁ | Ar16 | H | H | H | H | H | Rₙ₁₁ | H |
| Lₐ₃₉₂ | Rₙ₅₁ | Ar16 | H | H | H | H | H | Rₙ₁₁ | H |
| Lₐ₃₉₃ | Rₙ₅₆ | Ar16 | H | H | H | H | H | Rₙ₁₁ | H |
| Lₐ₃₉₄ | Rₙ₅₉ | Ar16 | H | H | H | H | H | Rₙ₁₁ | H |
| Lₐ₃₉₅ | Rₙ₆₀ | Ar16 | H | H | H | H | H | Rₙ₁₁ | H |
| Lₐ₃₉₆ | Rₙ₆₁ | Ar16 | H | H | H | H | H | Rₙ₁₁ | H |
| Lₐ₃₉₇ | Rₙ₆₂ | Ar16 | H | H | H | H | H | Rₙ₁₁ | H |
| Lₐ₃₉₈ | Rₙ₆₄ | Ar16 | H | H | H | H | H | Rₙ₁₁ | H |
| Lₐ₃₉₉ | Rₙ₆₅ | Ar16 | H | H | H | H | H | Rₙ₁₁ | H |
| Lₐ₄₀₀ | Rₙ₆₉ | Ar16 | H | H | H | H | H | Rₙ₁₁ | H |
| Lₐ₄₀₁ | Rₙ₇₀ | Ar16 | H | H | H | H | H | Rₙ₁₁ | H |
| Lₐ₄₀₂ | Rₙ₈₁ | Ar16 | H | H | H | H | H | Rₙ₁₁ | H |
| Lₐ₄₀₃ | Rₙ₁ | Ar16 | H | H | H | H | H | Rₙ₅₉ | H |
| Lₐ₄₀₄ | Rₙ₄ | Ar16 | H | H | H | H | H | Rₙ₅₉ | H |
| Lₐ₄₀₅ | Rₙ₅ | Ar16 | H | H | H | H | H | Rₙ₅₉ | H |
| Lₐ₄₀₆ | Rₙ₇ | Ar16 | H | H | H | H | H | Rₙ₅₉ | H |
| Lₐ₄₀₇ | Rₙ₁₁ | Ar16 | H | H | H | H | H | Rₙ₅₉ | H |
| Lₐ₄₀₈ | Rₙ₂₀ | Ar16 | H | H | H | H | H | Rₙ₅₉ | H |
| Lₐ₄₀₉ | Rₙ₂₁ | Ar16 | H | H | H | H | H | Rₙ₅₉ | H |
| Lₐ₄₁₀ | Rₙ₅₁ | Ar16 | H | H | H | H | H | Rₙ₅₉ | H |
| Lₐ₄₁₁ | Rₙ₅₆ | Ar16 | H | H | H | H | H | Rₙ₅₉ | H |
| Lₐ₄₁₂ | Rₙ₅₉ | Ar16 | H | H | H | H | H | Rₙ₅₉ | H |
| Lₐ₄₁₃ | Rₙ₆₀ | Ar16 | H | H | H | H | H | Rₙ₅₉ | H |
| Lₐ₄₁₄ | Rₙ₆₁ | Ar16 | H | H | H | H | H | Rₙ₅₉ | H |
| Lₐ₄₁₅ | Rₙ₆₂ | Ar16 | H | H | H | H | H | Rₙ₅₉ | H |
| Lₐ₄₁₆ | Rₙ₆₄ | Ar16 | H | H | H | H | H | Rₙ₅₉ | H |
| Lₐ₄₁₇ | Rₙ₆₅ | Ar16 | H | H | H | H | H | Rₙ₅₉ | H |
| Lₐ₄₁₈ | Rₙ₆₉ | Ar16 | H | H | H | H | H | Rₙ₅₉ | H |
| Lₐ₄₁₉ | Rₙ₇₀ | Ar16 | H | H | H | H | H | Rₙ₅₉ | H |
| Lₐ₄₂₀ | Rₙ₈₁ | Ar16 | H | H | H | H | H | Rₙ₅₉ | H |
| Lₐ₄₂₁ | Rₙ₁ | Ar16 | H | H | H | H | H | Rₙ₆₀ | H |
| Lₐ₄₂₂ | Rₙ₄ | Ar16 | H | H | H | H | H | Rₙ₆₀ | H |
| Lₐ₄₂₃ | Rₙ₅ | Ar16 | H | H | H | H | H | Rₙ₆₀ | H |
| Lₐ₄₂₄ | Rₙ₇ | Ar16 | H | H | H | H | H | Rₙ₆₀ | H |
| Lₐ₄₂₅ | Rₙ₁₁ | Ar16 | H | H | H | H | H | Rₙ₆₀ | H |
| Lₐ₄₂₆ | Rₙ₂₀ | Ar16 | H | H | H | H | H | Rₙ₆₀ | H |
| Lₐ₄₂₇ | Rₙ₂₁ | Ar16 | H | H | H | H | H | Rₙ₆₀ | H |
| Lₐ₄₂₈ | Rₙ₅₁ | Ar16 | H | H | H | H | H | Rₙ₆₀ | H |
| Lₐ₄₂₉ | Rₙ₅₆ | Ar16 | H | H | H | H | H | Rₙ₆₀ | H |
| Lₐ₄₃₀ | Rₙ₅₉ | Ar16 | H | H | H | H | H | Rₙ₆₀ | H |
| Lₐ₄₃₁ | Rₙ₆₀ | Ar16 | H | H | H | H | H | Rₙ₆₀ | H |
| Lₐ₄₃₂ | Rₙ₆₁ | Ar16 | H | H | H | H | H | Rₙ₆₀ | H |
| Lₐ₄₃₃ | Rₙ₆₂ | Ar16 | H | H | H | H | H | Rₙ₆₀ | H |
| Lₐ₄₃₄ | Rₙ₆₄ | Ar16 | H | H | H | H | H | Rₙ₆₀ | H |
| Lₐ₄₃₅ | Rₙ₆₅ | Ar16 | H | H | H | H | H | Rₙ₆₀ | H |
| Lₐ₄₃₆ | Rₙ₆₉ | Ar16 | H | H | H | H | H | Rₙ₆₀ | H |
| Lₐ₄₃₇ | Rₙ₇₀ | Ar16 | H | H | H | H | H | Rₙ₆₀ | H |
| Lₐ₄₃₈ | Rₙ₈₁ | Ar16 | H | H | H | H | H | Rₙ₆₀ | H |
| Lₐ₄₃₉ | Rₙ₁ | Ar16 | H | H | H | H | H | Rₙ₆₄ | H |
| Lₐ₄₄₀ | Rₙ₄ | Ar16 | H | H | H | H | H | Rₙ₆₄ | H |
| Lₐ₄₄₁ | Rₙ₅ | Ar16 | H | H | H | H | H | Rₙ₆₄ | H |
| Lₐ₄₄₂ | Rₙ₇ | Ar16 | H | H | H | H | H | Rₙ₆₄ | H |
| Lₐ₄₄₃ | Rₙ₁₁ | Ar16 | H | H | H | H | H | Rₙ₆₄ | H |
| Lₐ₄₄₄ | Rₙ₂₀ | Ar16 | H | H | H | H | H | Rₙ₆₄ | H |
| Lₐ₄₄₅ | Rₙ₂₁ | Ar16 | H | H | H | H | H | Rₙ₆₄ | H |
| Lₐ₄₄₆ | Rₙ₅₁ | Ar16 | H | H | H | H | H | Rₙ₆₄ | H |
| Lₐ₄₄₇ | Rₙ₅₆ | Ar16 | H | H | H | H | H | Rₙ₆₄ | H |
| Lₐ₄₄₈ | Rₙ₅₉ | Ar16 | H | H | H | H | H | Rₙ₆₄ | H |
| Lₐ₄₄₉ | Rₙ₆₀ | Ar16 | H | H | H | H | H | Rₙ₆₄ | H |
| Lₐ₄₅₀ | Rₙ₆₁ | Ar16 | H | H | H | H | H | Rₙ₆₄ | H |
| Lₐ₄₅₁ | Rₙ₆₂ | Ar16 | H | H | H | H | H | Rₙ₆₄ | H |
| Lₐ₄₅₂ | Rₙ₆₄ | Ar16 | H | H | H | H | H | Rₙ₆₄ | H |
| Lₐ₄₅₃ | Rₙ₆₅ | Ar16 | H | H | H | H | H | Rₙ₆₄ | H |
| Lₐ₄₅₄ | Rₙ₆₉ | Ar16 | H | H | H | H | H | Rₙ₆₄ | H |
| Lₐ₄₅₅ | Rₙ₇₀ | Ar16 | H | H | H | H | H | Rₙ₆₄ | H |
| Lₐ₄₅₆ | Rₙ₈₁ | Ar16 | H | H | H | H | H | Rₙ₆₄ | H |
| Lₐ₄₅₇ | Rₙ₁ | Ar16 | H | H | H | H | H | Me | H |
| Lₐ₄₅₈ | Rₙ₄ | Ar16 | H | H | H | H | H | Me | H |
| Lₐ₄₅₉ | Rₙ₅ | Ar16 | H | H | H | H | H | Me | H |
| Lₐ₄₆₀ | Rₙ₇ | Ar16 | H | H | H | H | H | Me | H |
| Lₐ₄₆₁ | Rₙ₁₁ | Ar16 | H | H | H | H | H | Me | H |
| Lₐ₄₆₂ | Rₙ₂₀ | Ar16 | H | H | H | H | H | Me | H |
| Lₐ₄₆₃ | Rₙ₂₁ | Ar16 | H | H | H | H | H | Me | H |
| Lₐ₄₆₄ | Rₙ₅₁ | Ar16 | H | H | H | H | H | Me | H |
| Lₐ₄₆₅ | Rₙ₅₆ | Ar16 | H | H | H | H | H | Me | H |
| Lₐ₄₆₆ | Rₙ₅₉ | Ar16 | H | H | H | H | H | Me | H |
| Lₐ₄₆₇ | Rₙ₆₀ | Ar16 | H | H | H | H | H | Me | H |
| Lₐ₄₆₈ | Rₙ₆₁ | Ar16 | H | H | H | H | H | Me | H |
| Lₐ₄₆₉ | Rₙ₆₂ | Ar16 | H | H | H | H | H | Me | H |
| Lₐ₄₇₀ | Rₙ₆₄ | Ar16 | H | H | H | H | H | Me | H |
| Lₐ₄₇₁ | Rₙ₆₅ | Ar16 | H | H | H | H | H | Me | H |
| Lₐ₄₇₂ | Rₙ₆₉ | Ar16 | H | H | H | H | H | Me | H |
| Lₐ₄₇₃ | Rₙ₇₀ | Ar16 | H | H | H | H | H | Me | H |
| Lₐ₄₇₄ | Rₙ₈₁ | Ar16 | H | H | H | H | H | Me | H |
| Lₐ₄₇₅ | Rₙ₁ | Ar16 | H | H | H | H | Rₙ₁₁ | H | H |
| Lₐ₄₇₆ | Rₙ₄ | Ar16 | H | H | H | H | Rₙ₁₁ | H | H |
| Lₐ₄₇₇ | Rₙ₅ | Ar16 | H | H | H | H | Rₙ₁₁ | H | H |
| Lₐ₄₇₈ | Rₙ₇ | Ar16 | H | H | H | H | Rₙ₁₁ | H | H |
| Lₐ₄₇₉ | Rₙ₁₁ | Ar16 | H | H | H | H | Rₙ₁₁ | H | H |
| Lₐ₄₈₀ | Rₙ₂₀ | Ar16 | H | H | H | H | Rₙ₁₁ | H | H |
| Lₐ₄₈₁ | Rₙ₂₁ | Ar16 | H | H | H | H | Rₙ₁₁ | H | H |
| Lₐ₄₈₂ | Rₙ₅₁ | Ar16 | H | H | H | H | Rₙ₁₁ | H | H |
| Lₐ₄₈₃ | Rₙ₅₆ | Ar16 | H | H | H | H | Rₙ₁₁ | H | H |
| Lₐ₄₈₄ | Rₙ₅₉ | Ar16 | H | H | H | H | Rₙ₁₁ | H | H |
| Lₐ₄₈₅ | Rₙ₆₀ | Ar16 | H | H | H | H | Rₙ₁₁ | H | H |
| Lₐ₄₈₆ | Rₙ₆₁ | Ar16 | H | H | H | H | Rₙ₁₁ | H | H |
| Lₐ₄₈₇ | Rₙ₆₂ | Ar16 | H | H | H | H | Rₙ₁₁ | H | H |
| Lₐ₄₈₈ | Rₙ₆₄ | Ar16 | H | H | H | H | Rₙ₁₁ | H | H |
| Lₐ₄₈₉ | Rₙ₆₅ | Ar16 | H | H | H | H | Rₙ₁₁ | H | H |
| Lₐ₄₉₀ | Rₙ₆₉ | Ar16 | H | H | H | H | Rₙ₁₁ | H | H |
| Lₐ₄₉₁ | Rₙ₇₀ | Ar16 | H | H | H | H | Rₙ₁₁ | H | H |
| Lₐ₄₉₂ | Rₙ₈₁ | Ar16 | H | H | H | H | Rₙ₁₁ | H | H |
| Lₐ₄₉₃ | Rₙ₁ | Ar16 | H | H | H | H | Rₙ₅₉ | H | H |
| Lₐ₄₉₄ | Rₙ₄ | Ar16 | H | H | H | H | Rₙ₅₉ | H | H |
| Lₐ₄₉₅ | Rₙ₅ | Ar16 | H | H | H | H | Rₙ₅₉ | H | H |
| Lₐ₄₉₆ | Rₙ₇ | Ar16 | H | H | H | H | Rₙ₅₉ | H | H |
| Lₐ₄₉₇ | Rₙ₁₁ | Ar16 | H | H | H | H | Rₙ₅₉ | H | H |
| Lₐ₄₉₈ | Rₙ₂₀ | Ar16 | H | H | H | H | Rₙ₅₉ | H | H |
| Lₐ₄₉₉ | Rₙ₂₁ | Ar16 | H | H | H | H | Rₙ₅₉ | H | H |
| Lₐ₅₀₀ | Rₙ₅₁ | Ar16 | H | H | H | H | Rₙ₅₉ | H | H |
| Lₐ₅₀₁ | Rₙ₅₆ | Ar16 | H | H | H | H | Rₙ₅₉ | H | H |
| Lₐ₅₀₂ | Rₙ₅₉ | Ar16 | H | H | H | H | Rₙ₅₉ | H | H |
| Lₐ₅₀₃ | Rₙ₆₀ | Ar16 | H | H | H | H | Rₙ₅₉ | H | H |
| Lₐ₅₀₄ | Rₙ₆₁ | Ar16 | H | H | H | H | Rₙ₅₉ | H | H |
| Lₐ₅₀₅ | Rₙ₆₂ | Ar16 | H | H | H | H | Rₙ₅₉ | H | H |
| Lₐ₅₀₆ | Rₙ₆₄ | Ar16 | H | H | H | H | Rₙ₅₉ | H | H |
| Lₐ₅₀₇ | Rₙ₆₅ | Ar16 | H | H | H | H | Rₙ₅₉ | H | H |
| Lₐ₅₀₈ | Rₙ₆₉ | Ar16 | H | H | H | H | Rₙ₅₉ | H | H |
| Lₐ₅₀₉ | Rₙ₇₀ | Ar16 | H | H | H | H | Rₙ₅₉ | H | H |
| Lₐ₅₁₀ | Rₙ₈₁ | Ar16 | H | H | H | H | Rₙ₅₉ | H | H |
| Lₐ₅₁₁ | Rₙ₁ | Ar16 | H | H | H | H | Rₙ₆₀ | H | H |
| Lₐ₅₁₂ | Rₙ₄ | Ar16 | H | H | H | H | Rₙ₆₀ | H | H |
| Lₐ₅₁₃ | Rₙ₅ | Ar16 | H | H | H | H | Rₙ₆₀ | H | H |
| Lₐ₅₁₄ | Rₙ₇ | Ar16 | H | H | H | H | Rₙ₆₀ | H | H |
| Lₐ₅₁₅ | Rₙ₁₁ | Ar16 | H | H | H | H | Rₙ₆₀ | H | H |
| Lₐ₅₁₆ | Rₙ₂₀ | Ar16 | H | H | H | H | Rₙ₆₀ | H | H |
| Lₐ₅₁₇ | Rₙ₂₁ | Ar16 | H | H | H | H | Rₙ₆₀ | H | H |
| Lₐ₅₁₈ | Rₙ₅₁ | Ar16 | H | H | H | H | Rₙ₆₀ | H | H |
| Lₐ₅₁₉ | Rₙ₅₆ | Ar16 | H | H | H | H | Rₙ₆₀ | H | H |
| Lₐ₅₂₀ | Rₙ₅₉ | Ar16 | H | H | H | H | Rₙ₆₀ | H | H |
| Lₐ₅₂₁ | Rₙ₆₀ | Ar16 | H | H | H | H | Rₙ₆₀ | H | H |
| Lₐ₅₂₂ | Rₙ₆₁ | Ar16 | H | H | H | H | Rₙ₆₀ | H | H |
| Lₐ₅₂₃ | Rₙ₆₂ | Ar16 | H | H | H | H | Rₙ₆₀ | H | H |
| Lₐ₅₂₄ | Rₙ₆₄ | Ar16 | H | H | H | H | Rₙ₆₀ | H | H |
| Lₐ₅₂₅ | Rₙ₆₅ | Ar16 | H | H | H | H | Rₙ₆₀ | H | H |
| Lₐ₅₂₆ | Rₙ₆₉ | Ar16 | H | H | H | H | Rₙ₆₀ | H | H |
| Lₐ₅₂₇ | Rₙ₇₀ | Ar16 | H | H | H | H | Rₙ₆₀ | H | H |
| Lₐ₅₂₈ | Rₙ₈₁ | Ar16 | H | H | H | H | Rₙ₆₀ | H | H |
| Lₐ₅₂₉ | Rₙ₁ | Ar16 | H | H | H | H | Rₙ₆₄ | H | H |
| Lₐ₅₃₀ | Rₙ₄ | Ar16 | H | H | H | H | Rₙ₆₄ | H | H |
| Lₐ₅₃₁ | Rₙ₅ | Ar16 | H | H | H | H | Rₙ₆₄ | H | H |
| Lₐ₅₃₂ | Rₙ₇ | Ar16 | H | H | H | H | Rₙ₆₄ | H | H |
| Lₐ₅₃₃ | Rₙ₁₁ | Ar16 | H | H | H | H | Rₙ₆₄ | H | H |
| Lₐ₅₃₄ | Rₙ₂₀ | Ar16 | H | H | H | H | Rₙ₆₄ | H | H |
| Lₐ₅₃₅ | Rₙ₂₁ | Ar16 | H | H | H | H | Rₙ₆₄ | H | H |
| Lₐ₅₃₆ | Rₙ₅₁ | Ar16 | H | H | H | H | Rₙ₆₄ | H | H |
| Lₐ₅₃₇ | Rₙ₅₆ | Ar16 | H | H | H | H | Rₙ₆₄ | H | H |
| Lₐ₅₃₈ | Rₙ₅₉ | Ar16 | H | H | H | H | Rₙ₆₄ | H | H |
| Lₐ₅₃₉ | Rₙ₆₀ | Ar16 | H | H | H | H | Rₙ₆₄ | H | H |
| Lₐ₅₄₀ | Rₙ₆₁ | Ar16 | H | H | H | H | Rₙ₆₄ | H | H |
| Lₐ₅₄₁ | Rₙ₆₂ | Ar16 | H | H | H | H | Rₙ₆₄ | H | H |
| Lₐ₅₄₂ | Rₙ₆₄ | Ar16 | H | H | H | H | Rₙ₆₄ | H | H |
| Lₐ₅₄₃ | Rₙ₆₅ | Ar16 | H | H | H | H | Rₙ₆₄ | H | H |
| Lₐ₅₄₄ | Rₙ₆₉ | Ar16 | H | H | H | H | Rₙ₆₄ | H | H |
| Lₐ₅₄₅ | Rₙ₇₀ | Ar16 | H | H | H | H | Rₙ₆₄ | H | H |
| Lₐ₅₄₆ | Rₙ₈₁ | Ar16 | H | H | H | H | Rₙ₆₄ | H | H |
| Lₐ₅₄₇ | Rₙ₁ | Ar16 | H | H | H | H | Me | H | H |
| Lₐ₅₄₈ | Rₙ₄ | Ar16 | H | H | H | H | Me | H | H |
| Lₐ₅₄₉ | Rₙ₅ | Ar16 | H | H | H | H | Me | H | H |
| Lₐ₅₅₀ | Rₙ₇ | Ar16 | H | H | H | H | Me | H | H |
| Lₐ₅₅₁ | Rₙ₁₁ | Ar16 | H | H | H | H | Me | H | H |
| Lₐ₅₅₂ | Rₙ₂₀ | Ar16 | H | H | H | H | Me | H | H |
| Lₐ₅₅₃ | Rₙ₂₁ | Ar16 | H | H | H | H | Me | H | H |
| Lₐ₅₅₄ | Rₙ₅₁ | Ar16 | H | H | H | H | Me | H | H |
| Lₐ₅₅₅ | Rₙ₅₆ | Ar16 | H | H | H | H | Me | H | H |
| Lₐ₅₅₆ | Rₙ₅₉ | Ar16 | H | H | H | H | Me | H | H |
| Lₐ₅₅₇ | Rₙ₆₀ | Ar16 | H | H | H | H | Me | H | H |
| Lₐ₅₅₈ | Rₙ₆₁ | Ar16 | H | H | H | H | Me | H | H |
| Lₐ₅₅₉ | Rₙ₆₂ | Ar16 | H | H | H | H | Me | H | H |
| Lₐ₅₆₀ | Rₙ₆₄ | Ar16 | H | H | H | H | Me | H | H |
| Lₐ₅₆₁ | Rₙ₆₅ | Ar16 | H | H | H | H | Me | H | H |
| Lₐ₅₆₂ | Rₙ₆₉ | Ar16 | H | H | H | H | Me | H | H |
| Lₐ₅₆₃ | Rₙ₇₀ | Ar16 | H | H | H | H | Me | H | H |
| Lₐ₅₆₄ | Rₙ₈₁ | Ar16 | H | H | H | H | Me | H | H |
| Lₐ₅₆₅ | Rₙ₁ | Ar16 | H | H | F | H | H | H | H |
| Lₐ₅₆₆ | Rₙ₄ | Ar16 | H | H | F | H | H | H | H |
| Lₐ₅₆₇ | Rₙ₇ | Ar16 | H | H | F | H | H | H | H |
| Lₐ₅₆₈ | Rₙ₂₀ | Ar16 | H | H | F | H | H | H | H |
| Lₐ₅₆₉ | Rₙ₂₁ | Ar16 | H | H | F | H | H | H | H |
| Lₐ₅₇₀ | Rₙ₅₆ | Ar16 | H | H | F | H | H | H | H |
| Lₐ₅₇₁ | Rₙ₅₉ | Ar16 | H | H | F | H | H | H | H |
| Lₐ₅₇₂ | Rₙ₆₁ | Ar16 | H | H | F | H | H | H | H |
| Lₐ₅₇₃ | Rₙ₆₂ | Ar16 | H | H | F | H | H | H | H |
| Lₐ₅₇₄ | Rₙ₆₄ | Ar16 | H | H | F | H | H | H | H |
| Lₐ₅₇₅ | Rₙ₆₉ | Ar16 | H | H | F | H | H | H | H |
| Lₐ₅₇₆ | Rₙ₇₀ | Ar16 | H | H | F | H | H | H | H |
| Lₐ₅₇₇ | Rₙ₁ | Ar16 | H | H | F | H | Rₙ₁₁ | H | H |
| Lₐ₅₇₈ | Rₙ₄ | Ar16 | H | H | F | H | Rₙ₁₁ | H | H |
| Lₐ₅₇₉ | Rₙ₇ | Ar16 | H | H | F | H | Rₙ₁₁ | H | H |
| Lₐ₅₈₀ | R₁₂₀ | Ar16 | H | H | F | H | Rₙ₁₁ | H | H |
| Lₐ₅₈₁ | Rₙ₂₁ | Ar16 | H | H | F | H | Rₙ₁₁ | H | H |
| Lₐ₅₈₂ | Rₙ₅₆ | Ar16 | H | H | F | H | Rₙ₁₁ | H | H |
| Lₐ₅₈₃ | Rₙ₅₉ | Ar16 | H | H | F | H | Rₙ₁₁ | H | H |
| Lₐ₅₈₄ | Rₙ₆₁ | Ar16 | H | H | F | H | Rₙ₁₁ | H | H |
| Lₐ₅₈₅ | Rₙ₆₂ | Ar16 | H | H | F | H | Rₙ₁₁ | H | H |
| Lₐ₅₈₆ | Rₙ₆₄ | Ar16 | H | H | F | H | Rₙ₁₁ | H | H |
| Lₐ₅₈₇ | Rₙ₆₉ | Ar16 | H | H | F | H | Rₙ₁₁ | H | H |
| Lₐ₅₈₈ | Rₙ₇₀ | Ar16 | H | H | F | H | Rₙ₁₁ | H | H |
| Lₐ₅₈₉ | Rₙ₁ | Ar16 | H | H | F | H | Rₙ₆₀ | H | H |
| Lₐ₅₉₀ | Rₙ₄ | Ar16 | H | H | F | H | Rₙ₆₀ | H | H |
| Lₐ₅₉₁ | Rₙ₇ | Ar16 | H | H | F | H | Rₙ₆₀ | H | H |
| Lₐ₅₉₂ | Rₙ₂₀ | Ar16 | H | H | F | H | Rₙ₆₀ | H | H |
| Lₐ₅₉₃ | Rₙ₂₁ | Ar16 | H | H | F | H | Rₙ₆₀ | H | H |
| Lₐ₅₉₄ | Rₙ₅₆ | Ar16 | H | H | F | H | Rₙ₆₀ | H | H |
| Lₐ₅₉₅ | Rₙ₅₉ | Ar16 | H | H | F | H | Rₙ₆₀ | H | H |
| Lₐ₅₉₆ | Rₙ₆₁ | Ar16 | H | H | F | H | Rₙ₆₀ | H | H |
| Lₐ₅₉₇ | Rₙ₆₂ | Ar16 | H | H | F | H | Rₙ₆₀ | H | H |
| Lₐ₅₉₈ | Rₙ₆₄ | Ar16 | H | H | F | H | Rₙ₆₀ | H | H |
| Lₐ₅₉₉ | Rₙ₆₉ | Ar16 | H | H | F | H | Rₙ₆₀ | H | H |
| Lₐ₆₀₀ | Rₙ₇₀ | Ar16 | H | H | F | H | Rₙ₆₀ | H | H |
| Lₐ₆₀₁ | Rₙ₁ | Ar16 | H | H | F | H | H | Rₙ₁₁ | H |
| Lₐ₆₀₂ | Rₙ₄ | Ar16 | H | H | F | H | H | Rₙ₁₁ | H |
| Lₐ₆₀₃ | Rₙ₇ | Ar16 | H | H | F | H | H | Rₙ₁₁ | H |
| Lₐ₆₀₄ | Rₙ₂₀ | Ar16 | H | H | F | H | H | Rₙ₁₁ | H |
| Lₐ₆₀₅ | Rₙ₂₁ | Ar16 | H | H | F | H | H | Rₙ₁₁ | H |
| Lₐ₆₀₆ | Rₙ₅₆ | Ar16 | H | H | F | H | H | Rₙ₁₁ | H |
| Lₐ₆₀₇ | Rₙ₅₉ | Ar16 | H | H | F | H | H | Rₙ₁₁ | H |
| Lₐ₆₀₈ | Rₙ₆₁ | Ar16 | H | H | F | H | H | Rₙ₁₁ | H |
| Lₐ₆₀₉ | Rₙ₆₂ | Ar16 | H | H | F | H | H | Rₙ₁₁ | H |
| Lₐ₆₁₀ | Rₙ₆₄ | Ar16 | H | H | F | H | H | Rₙ₁₁ | H |
| Lₐ₆₁₁ | Rₙ₆₉ | Ar16 | H | H | F | H | H | Rₙ₁₁ | H |
| Lₐ₆₁₂ | Rₙ₇₀ | Ar16 | H | H | F | H | H | Rₙ₁₁ | H |
| Lₐ₆₁₃ | Rₙ₁ | Ar16 | H | H | F | H | H | Rₙ₆₀ | H |
| Lₐ₆₁₄ | Rₙ₄ | Ar16 | H | H | F | H | H | Rₙ₆₀ | H |
| Lₐ₆₁₅ | Rₙ₇ | Ar16 | H | H | F | H | H | Rₙ₆₀ | H |
| Lₐ₆₁₆ | Rₙ₂₀ | Ar16 | H | H | F | H | H | Rₙ₆₀ | H |
| Lₐ₆₁₇ | Rₙ₂₁ | Ar16 | H | H | F | H | H | Rₙ₆₀ | H |
| Lₐ₆₁₈ | Rₙ₅₆ | Ar16 | H | H | F | H | H | Rₙ₆₀ | H |
| Lₐ₆₁₉ | Rₙ₅₉ | Ar16 | H | H | F | H | H | Rₙ₆₀ | H |
| Lₐ₆₂₀ | Rₙ₆₁ | Ar16 | H | H | F | H | H | Rₙ₆₀ | H |
| Lₐ₆₂₁ | Rₙ₆₂ | Ar16 | H | H | F | H | H | Rₙ₆₀ | H |
| Lₐ₆₂₂ | Rₙ₆₄ | Ar16 | H | H | F | H | H | Rₙ₆₀ | H |
| Lₐ₆₂₃ | Rₙ₆₉ | Ar16 | H | H | F | H | H | Rₙ₆₀ | H |
| Lₐ₆₂₄ | Rₙ₇₀ | Ar16 | H | H | F | H | H | Rₙ₆₀ | H |
| Lₐ₆₂₅ | Rₙ₁ | Ar16 | H | H | CN | H | H | H | H |
| Lₐ₆₂₆ | Rₙ₄ | Ar16 | H | H | CN | H | H | H | H |
| Lₐ₆₂₇ | Rₙ₇ | Ar16 | H | H | CN | H | H | H | H |
| Lₐ₆₂₈ | Rₙ₂₀ | Ar16 | H | H | CN | H | H | H | H |
| Lₐ₆₂₉ | Rₙ₂₁ | Ar16 | H | H | CN | H | H | H | H |
| Lₐ₆₃₀ | Rₙ₅₆ | Ar16 | H | H | CN | H | H | H | H |
| Lₐ₆₃₁ | Rₙ₅₉ | Ar16 | H | H | CN | H | H | H | H |
| Lₐ₆₃₂ | Rₙ₆₁ | Ar16 | H | H | CN | H | H | H | H |
| Lₐ₆₃₃ | Rₙ₆₂ | Ar16 | H | H | CN | H | H | H | H |
| Lₐ₆₃₄ | Rₙ₆₄ | Ar16 | H | H | CN | H | H | H | H |
| Lₐ₆₃₅ | Rₙ₆₉ | Ar16 | H | H | CN | H | H | H | H |
| Lₐ₆₃₆ | Rₙ₇₀ | Ar16 | H | H | CN | H | H | H | H |
| Lₐ₆₃₇ | Rₙ₁ | Ar16 | H | CN | H | H | H | H | H |
| Lₐ₆₃₈ | Rₙ₄ | Ar16 | H | CN | H | H | H | H | H |
| Lₐ₆₃₉ | Rₙ₇ | Ar16 | H | CN | H | H | H | H | H |
| Lₐ₆₄₀ | Rₙ₂₀ | Ar16 | H | CN | H | H | H | H | H |
| Lₐ₆₄₁ | Rₙ₂₁ | Ar16 | H | CN | H | H | H | H | H |
| Lₐ₆₄₂ | Rₙ₅₆ | Ar16 | H | CN | H | H | H | H | H |
| Lₐ₆₄₃ | Rₙ₅₉ | Ar16 | H | CN | H | H | H | H | H |
| Lₐ₆₄₄ | Rₙ₆₁ | Ar16 | H | CN | H | H | H | H | H |
| Lₐ₆₄₅ | Rₙ₆₂ | Ar16 | H | CN | H | H | H | H | H |
| Lₐ₆₄₆ | Rₙ₆₄ | Ar16 | H | CN | H | H | H | H | H |
| Lₐ₆₄₇ | Rₙ₆₉ | Ar16 | H | CN | H | H | H | H | H |
| Lₐ₆₄₈ | Rₙ₇₀ | Ar16 | H | CN | H | H | H | H | H |
| Lₐ₆₄₉ | Rₙ₁ | Ar16 | CN | H | H | H | H | H | H |
| Lₐ₆₅₀ | Rₙ₄ | Ar16 | CN | H | H | H | H | H | H |
| Lₐ₆₅₁ | Rₙ₇ | Ar16 | CN | H | H | H | H | H | H |
| Lₐ₆₅₂ | Rₙ₂₀ | Ar16 | CN | H | H | H | H | H | H |
| Lₐ₆₅₃ | Rₙ₂₁ | Ar16 | CN | H | H | H | H | H | H |
| Lₐ₆₅₄ | Rₙ₅₆ | Ar16 | CN | H | H | H | H | H | H |
| Lₐ₆₅₅ | Rₙ₅₉ | Ar16 | CN | H | H | H | H | H | H |
| Lₐ₆₅₆ | Rₙ₆₁ | Ar16 | CN | H | H | H | H | H | H |
| Lₐ₆₅₇ | Rₙ₆₂ | Ar16 | CN | H | H | H | H | H | H |
| Lₐ₆₅₈ | Rₙ₆₄ | Ar16 | CN | H | H | H | H | H | H |
| Lₐ₆₅₉ | Rₙ₆₉ | Ar16 | CN | H | H | H | H | H | H |
| Lₐ₆₆₀ | Rₙ₇₀ | Ar16 | CN | H | H | H | H | H | H |
| Lₐ₆₆₁ | Rₙ₁ | Ar16 | H | H | CN | H | Rₙ₁₁ | H | H |
| Lₐ₆₆₂ | Rₙ₄ | Ar16 | H | H | CN | H | Rₙ₁₁ | H | H |
| Lₐ₆₆₃ | Rₙ₇ | Ar16 | H | H | CN | H | Rₙ₁₁ | H | H |
| Lₐ₆₆₄ | Rₙ₂₀ | Ar16 | H | H | CN | H | Rₙ₁₁ | H | H |
| Lₐ₆₆₅ | Rₙ₂₁ | Ar16 | H | H | CN | H | Rₙ₁₁ | H | H |
| Lₐ₆₆₆ | Rₙ₅₆ | Ar16 | H | H | CN | H | Rₙ₁₁ | H | H |
| Lₐ₆₆₇ | Rₙ₅₉ | Ar16 | H | H | CN | H | Rₙ₁₁ | H | H |
| Lₐ₆₆₈ | Rₙ₆₁ | Ar16 | H | H | CN | H | Rₙ₁₁ | H | H |
| Lₐ₆₆₉ | Rₙ₆₂ | Ar16 | H | H | CN | H | Rₙ₁₁ | H | H |
| Lₐ₆₇₀ | Rₙ₆₄ | Ar16 | H | H | CN | H | Rₙ₁₁ | H | H |
| Lₐ₆₇₁ | Rₙ₆₉ | Ar16 | H | H | CN | H | Rₙ₁₁ | H | H |
| Lₐ₆₇₂ | Rₙ₇₀ | Ar16 | D | H | CN | H | Rₙ₁₁ | H | H |
| Lₐ₆₇₃ | Rₙ₁ | Ar16 | H | H | CN | H | Rₙ₆₀ | H | H |
| Lₐ₆₇₄ | Rₙ₄ | Ar16 | H | H | CN | H | Rₙ₆₀ | H | H |
| Lₐ₆₇₅ | Rₙ₇ | Ar16 | H | H | CN | H | Rₙ₆₀ | H | H |
| Lₐ₆₇₆ | Rₙ₂₀ | Ar16 | H | H | CN | H | Rₙ₆₀ | H | H |
| Lₐ₆₇₇ | Rₙ₂₁ | Ar16 | H | H | CN | H | Rₙ₆₀ | H | H |
| Lₐ₆₇₈ | Rₙ₅₆ | Ar16 | H | H | CN | H | Rₙ₆₀ | H | H |
| Lₐ₆₇₉ | Rₙ₅₉ | Ar16 | H | H | CN | H | Rₙ₆₀ | H | H |
| Lₐ₆₈₀ | Rₙ₆₁ | Ar16 | H | H | CN | H | Rₙ₆₀ | H | H |
| Lₐ₆₈₁ | Rₙ₆₂ | Ar16 | H | H | CN | H | Rₙ₆₀ | H | H |
| Lₐ₆₈₂ | Rₙ₆₄ | Ar16 | H | H | CN | H | Rₙ₆₀ | H | H |
| Lₐ₆₈₃ | Rₙ₆₉ | Ar16 | H | H | CN | H | Rₙ₆₀ | H | H |
| Lₐ₆₈₄ | Rₙ₇₀ | Ar16 | H | H | CN | H | Rₙ₆₀ | H | H |
| Lₐ₆₈₅ | Rₙ₁ | Ar16 | H | H | CN | H | Rₙ₆₄ | H | H |
| Lₐ₆₈₆ | Rₙ₄ | Ar16 | H | H | CN | H | Rₙ₆₄ | H | H |
| Lₐ₆₈₇ | Rₙ₇ | Ar16 | H | H | CN | H | Rₙ₆₄ | H | H |
| Lₐ₆₈₈ | Rₙ₂₀ | Ar16 | H | H | CN | H | Rₙ₆₄ | H | H |
| Lₐ₆₈₉ | Rₙ₂₁ | Ar16 | H | H | CN | H | Rₙ₆₄ | H | H |
| Lₐ₆₉₀ | Rₙ₅₆ | Ar16 | H | H | CN | H | Rₙ₆₄ | H | H |
| Lₐ₆₉₁ | Rₙ₅₉ | Ar16 | H | H | CN | H | Rₙ₆₄ | H | H |
| Lₐ₆₉₂ | Rₙ₆₁ | Ar16 | H | H | CN | H | Rₙ₆₄ | H | H |
| Lₐ₆₉₃ | Rₙ₆₂ | Ar16 | H | H | CN | H | Rₙ₆₄ | H | H |
| Lₐ₆₉₄ | Rₙ₆₄ | Ar16 | H | H | CN | H | Rₙ₆₄ | H | H |
| Lₐ₆₉₅ | Rₙ₆₉ | Ar16 | H | H | CN | H | Rₙ₆₄ | H | H |
| Lₐ₆₉₆ | Rₙ₇₀ | Ar16 | H | H | CN | H | Rₙ₆₄ | H | H |
| Lₐ₆₉₇ | Rₙ₁ | Ar16 | H | H | CN | H | H | Rₙ₁₁ | H |
| Lₐ₆₉₈ | Rₙ₄ | Ar16 | H | D | CN | H | H | Rₙ₁₁ | H |
| Lₐ₆₉₉ | Rₙ₇ | Ar16 | H | H | CN | H | H | Rₙ₁₁ | H |
| Lₐ₇₀₀ | Rₙ₂₀ | Ar16 | H | H | CN | H | H | Rₙ₁₁ | H |
| Lₐ₇₀₁ | Rₙ₂₁ | Ar16 | H | H | CN | H | H | Rₙ₁₁ | H |
| Lₐ₇₀₂ | Rₙ₅₆ | Ar16 | H | H | CN | H | H | Rₙ₁₁ | H |
| Lₐ₇₀₃ | Rₙ₅₉ | Ar16 | H | H | CN | H | H | Rₙ₁₁ | H |
| Lₐ₇₀₄ | Rₙ₆₁ | Ar16 | H | H | CN | H | H | Rₙ₁₁ | H |
| Lₐ₇₀₅ | Rₙ₆₂ | Ar16 | H | H | CN | H | H | Rₙ₁₁ | H |
| Lₐ₇₀₆ | Rₙ₆₄ | Ar16 | H | H | CN | H | H | Rₙ₁₁ | H |
| Lₐ₇₀₇ | Rₙ₆₉ | Ar16 | H | H | CN | H | H | Rₙ₁₁ | H |
| Lₐ₇₀₈ | Rₙ₇₀ | Ar16 | H | H | CN | H | H | Rₙ₁₁ | H |
| Lₐ₇₀₉ | Rₙ₁ | Ar16 | H | H | CN | H | H | Rₙ₆₀ | H |
| Lₐ₇₁₀ | Rₙ₄ | Ar16 | H | H | CN | H | H | Rₙ₆₀ | H |
| Lₐ₇₁₁ | Rₙ₇ | Ar16 | H | H | CN | H | H | Rₙ₆₀ | H |
| Lₐ₇₁₂ | Rₙ₂₀ | Ar16 | H | H | CN | H | H | Rₙ₆₀ | D |
| Lₐ₇₁₃ | Rₙ₂₁ | Ar16 | H | H | CN | H | H | Rₙ₆₀ | H |
| Lₐ₇₁₄ | Rₙ₅₆ | Ar16 | H | H | CN | H | H | Rₙ₆₀ | H |
| Lₐ₇₁₅ | Rₙ₅₉ | Ar16 | H | H | CN | H | H | Rₙ₆₀ | H |
| Lₐ₇₁₆ | Rₙ₆₁ | Ar16 | H | H | CN | H | H | Rₙ₆₀ | H |
| Lₐ₇₁₇ | Rₙ₆₂ | Ar16 | H | H | CN | H | H | Rₙ₆₀ | H |
| Lₐ₇₁₈ | Rₙ₆₄ | Ar16 | H | H | CN | H | H | Rₙ₆₀ | H |
| Lₐ₇₁₉ | Rₙ₆₉ | Ar16 | H | H | CN | H | H | Rₙ₆₀ | H |
| Lₐ₇₂₀ | Rₙ₇₀ | Ar16 | H | H | CN | H | H | Rₙ₆₀ | H |
| Lₐ₇₂₁ | Rₙ₁ | Ar16 | H | H | CN | H | H | Rₙ₆₄ | H |
| Lₐ₇₂₂ | Rₙ₄ | Ar16 | H | H | CN | H | H | Rₙ₆₄ | H |
| Lₐ₇₂₃ | Rₙ₇ | Ar16 | H | H | CN | H | H | Rₙ₆₄ | H |
| Lₐ₇₂₄ | Rₙ₂₀ | Ar16 | H | H | CN | H | H | Rₙ₆₄ | H |
| Lₐ₇₂₅ | Rₙ₂₁ | Ar16 | H | H | CN | H | H | Rₙ₆₄ | H |
| Lₐ₇₂₆ | Rₙ₅₆ | Ar16 | H | H | CN | H | H | Rₙ₆₄ | H |
| Lₐ₇₂₇ | Rₙ₅₉ | Ar16 | H | H | CN | H | H | Rₙ₆₄ | H |
| Lₐ₇₂₈ | Rₙ₆₁ | Ar16 | H | H | CN | H | H | Rₙ₆₄ | H |
| Lₐ₇₂₉ | Rₙ₆₂ | Ar16 | H | H | CN | H | H | Rₙ₆₄ | H |
| Lₐ₇₃₀ | Rₙ₆₄ | Ar16 | H | H | CN | H | H | Rₙ₆₄ | H |
| Lₐ₇₃₁ | Rₙ₆₉ | Ar16 | H | H | CN | H | H | Rₙ₆₄ | H |
| Lₐ₇₃₂ | Rₙ₇₀ | Ar16 | H | H | CN | H | H | Rₙ₆₄ | H |
| Lₐ₇₃₃ | Rₙ₁ | Ar21 | H | D | H | H | H | H | H |
| Lₐ₇₃₄ | Rₙ₄ | Ar21 | H | H | H | H | H | H | H |
| Lₐ₇₃₅ | Rₙ₅ | Ar21 | H | H | H | H | H | H | H |
| Lₐ₇₃₆ | Rₙ₇ | Ar21 | H | H | H | H | H | H | H |
| Lₐ₇₃₇ | Rₙ₁₁ | Ar21 | H | H | H | H | H | H | H |
| Lₐ₇₃₈ | Rₙ₂₀ | Ar21 | H | H | H | H | H | H | H |
| Lₐ₇₃₉ | Rₙ₂₁ | Ar21 | H | H | H | H | H | H | H |
| Lₐ₇₄₀ | Rₙ₅₁ | Ar21 | H | H | H | H | H | H | H |
| Lₐ₇₄₁ | Rₙ₅₆ | Ar21 | H | H | H | H | H | H | H |
| Lₐ₇₄₂ | Rₙ₅₉ | Ar21 | H | H | H | H | H | H | H |
| Lₐ₇₄₃ | Rₙ₆₀ | Ar21 | H | H | H | H | H | H | H |
| Lₐ₇₄₄ | Rₙ₆₁ | Ar21 | H | H | H | H | H | H | H |
| Lₐ₇₄₅ | Rₙ₆₂ | Ar21 | H | H | H | H | H | H | H |
| Lₐ₇₄₆ | Rₙ₆₄ | Ar21 | H | H | H | H | H | H | H |
| Lₐ₇₄₇ | Rₙ₆₅ | Ar21 | H | H | H | H | H | H | H |
| Lₐ₇₄₈ | Rₙ₆₉ | Ar21 | H | H | H | H | H | H | H |
| Lₐ₇₄₉ | Rₙ₇₀ | Ar21 | H | H | H | H | H | H | H |
| Lₐ₇₅₀ | Rₙ₈₁ | Ar21 | D | H | H | H | H | H | H |
| Lₐ₇₅₁ | Rₙ₁ | Ar21 | H | H | H | H | H | Rₙ₁₁ | H |
| Lₐ₇₅₂ | Rₙ₄ | Ar21 | H | H | H | H | H | Rₙ₁₁ | H |
| Lₐ₇₅₃ | Rₙ₅ | Ar21 | H | H | H | H | H | Rₙ₁₁ | H |
| Lₐ₇₅₄ | Rₙ₇ | Ar21 | H | H | H | H | H | Rₙ₁₁ | H |
| Lₐ₇₅₅ | Rₙ₁₁ | Ar21 | H | H | H | H | H | Rₙ₁₁ | H |
| Lₐ₇₅₆ | Rₙ₂₀ | Ar21 | H | H | H | H | H | Rₙ₁₁ | H |
| Lₐ₇₅₇ | Rₙ₂₁ | Ar21 | H | H | H | H | H | Rₙ₁₁ | H |
| Lₐ₇₅₈ | Rₙ₅₁ | Ar21 | H | H | H | H | H | Rₙ₁₁ | H |
| Lₐ₇₅₉ | Rₙ₅₆ | Ar21 | H | H | H | H | H | Rₙ₁₁ | H |
| Lₐ₇₆₀ | Rₙ₅₉ | Ar21 | H | H | H | H | H | Rₙ₁₁ | H |
| Lₐ₇₆₁ | Rₙ₆₀ | Ar21 | H | H | H | H | H | Rₙ₁₁ | H |
| Lₐ₇₆₂ | Rₙ₆₁ | Ar21 | H | H | H | H | H | Rₙ₁₁ | H |
| Lₐ₇₆₃ | Rₙ₆₂ | Ar21 | H | H | H | H | H | Rₙ₁₁ | H |
| Lₐ₇₆₄ | Rₙ₆₄ | Ar21 | H | H | H | H | H | Rₙ₁₁ | H |
| Lₐ₇₆₅ | Rₙ₆₅ | Ar21 | H | H | H | H | H | Rₙ₁₁ | H |
| Lₐ₇₆₆ | Rₙ₆₉ | Ar21 | H | H | H | H | H | Rₙ₁₁ | H |
| Lₐ₇₆₇ | Rₙ₇₀ | Ar21 | H | H | H | H | H | Rₙ₁₁ | H |
| Lₐ₇₆₈ | Rₙ₈₁ | Ar21 | H | H | H | H | H | Rₙ₁₁ | H |
| Lₐ₇₆₉ | Rₙ₁ | Ar21 | H | H | H | H | H | Rₙ₅₉ | H |
| Lₐ₇₇₀ | Rₙ₄ | Ar21 | H | H | H | H | H | Rₙ₅₉ | H |
| Lₐ₇₇₁ | Rₙ₅ | Ar21 | H | H | H | H | H | Rₙ₅₉ | H |
| Lₐ₇₇₂ | Rₙ₇ | Ar21 | H | H | H | H | H | Rₙ₅₉ | H |
| Lₐ₇₇₃ | Rₙ₁₁ | Ar21 | H | H | H | H | H | Rₙ₅₉ | H |
| Lₐ₇₇₄ | Rₙ₂₀ | Ar21 | H | H | H | H | H | Rₙ₅₉ | H |
| Lₐ₇₇₅ | Rₙ₂₁ | Ar21 | H | H | H | H | H | Rₙ₅₉ | H |
| Lₐ₇₇₆ | Rₙ₅₁ | Ar21 | H | H | H | H | H | Rₙ₅₉ | H |
| Lₐ₇₇₇ | Rₙ₅₆ | Ar21 | H | H | H | H | H | Rₙ₅₉ | H |
| Lₐ₇₇₈ | Rₙ₅₉ | Ar21 | H | H | H | H | H | Rₙ₅₉ | H |
| Lₐ₇₇₉ | Rₙ₆₀ | Ar21 | H | H | H | H | H | Rₙ₅₉ | H |
| Lₐ₇₈₀ | Rₙ₆₁ | Ar21 | H | H | H | H | H | Rₙ₅₉ | H |
| Lₐ₇₈₁ | Rₙ₆₂ | Ar21 | H | H | H | H | H | Rₙ₅₉ | H |
| Lₐ₇₈₂ | Rₙ₆₄ | Ar21 | H | H | H | H | H | Rₙ₅₉ | H |
| Lₐ₇₈₃ | Rₙ₆₅ | Ar21 | H | H | H | H | H | Rₙ₅₉ | H |
| Lₐ₇₈₄ | Rₙ₆₉ | Ar21 | H | H | H | H | H | Rₙ₅₉ | H |
| Lₐ₇₈₅ | Rₙ₇₀ | Ar21 | H | H | H | H | H | Rₙ₅₉ | H |
| Lₐ₇₈₆ | Rₙ₈₁ | Ar21 | H | H | H | H | H | Rₙ₅₉ | H |
| Lₐ₇₈₇ | Rₙ₁ | Ar21 | H | H | H | H | H | Rₙ₆₀ | H |
| Lₐ₇₈₈ | Rₙ₄ | Ar21 | H | H | H | H | H | Rₙ₆₀ | H |
| Lₐ₇₈₉ | Rₙ₅ | Ar21 | H | H | H | H | H | Rₙ₆₀ | H |
| Lₐ₇₉₀ | Rₙ₇ | Ar21 | H | H | H | H | H | Rₙ₆₀ | H |
| Lₐ₇₉₁ | Rₙ₁₁ | Ar21 | H | H | H | H | H | Rₙ₆₀ | H |
| Lₐ₇₉₂ | Rₙ₂₀ | Ar21 | H | H | H | H | H | Rₙ₆₀ | H |
| Lₐ₇₉₃ | Rₙ₂₁ | Ar21 | H | H | H | H | H | Rₙ₆₀ | H |
| Lₐ₇₉₄ | Rₙ₅₁ | Ar21 | H | H | H | H | H | Rₙ₆₀ | H |
| Lₐ₇₉₅ | Rₙ₅₆ | Ar21 | H | H | H | H | H | Rₙ₆₀ | H |
| Lₐ₇₉₆ | Rₙ₅₉ | Ar21 | H | H | H | H | H | Rₙ₆₀ | H |
| Lₐ₇₉₇ | Rₙ₆₀ | Ar21 | H | H | H | H | H | Rₙ₆₀ | H |
| Lₐ₇₉₈ | Rₙ₆₁ | Ar21 | H | H | H | H | H | Rₙ₆₀ | H |
| Lₐ₇₉₉ | Rₙ₆₂ | Ar21 | H | H | H | H | H | Rₙ₆₀ | H |
| Lₐ₈₀₀ | Rₙ₆₄ | Ar21 | H | H | H | H | H | Rₙ₆₀ | H |
| Lₐ₈₀₁ | Rₙ₆₅ | Ar21 | H | H | H | H | H | Rₙ₆₀ | H |
| Lₐ₈₀₂ | Rₙ₆₉ | Ar21 | H | H | H | H | H | Rₙ₆₀ | D |
| Lₐ₈₀₃ | Rₙ₇₀ | Ar21 | H | H | H | H | H | Rₙ₆₀ | H |
| Lₐ₈₀₄ | Rₙ₈₁ | Ar21 | H | H | H | H | H | Rₙ₆₀ | H |
| Lₐ₈₀₅ | Rₙ₁ | Ar21 | H | H | H | H | H | Rₙ₆₄ | H |
| Lₐ₈₀₆ | Rₙ₄ | Ar21 | H | H | H | H | H | Rₙ₆₄ | H |
| Lₐ₈₀₇ | Rₙ₅ | Ar21 | H | H | H | H | H | Rₙ₆₄ | H |
| Lₐ₈₀₈ | Rₙ₇ | Ar21 | H | H | H | H | H | Rₙ₆₄ | H |
| Lₐ₈₀₉ | Rₙ₁₁ | Ar21 | H | H | H | H | H | Rₙ₆₄ | H |
| Lₐ₈₁₀ | Rₙ₂₀ | Ar21 | H | H | H | H | H | Rₙ₆₄ | H |
| Lₐ₈₁₁ | Rₙ₂₁ | Ar21 | H | H | H | H | H | Rₙ₆₄ | H |
| Lₐ₈₁₂ | Rₙ₅₁ | Ar21 | H | H | H | H | H | Rₙ₆₄ | H |
| Lₐ₈₁₃ | Rₙ₅₆ | Ar21 | H | H | H | H | H | Rₙ₆₄ | H |
| Lₐ₈₁₄ | Rₙ₅₉ | Ar21 | H | H | H | H | H | Rₙ₆₄ | H |
| Lₐ₈₁₅ | Rₙ₆₀ | Ar21 | H | H | H | H | H | Rₙ₆₄ | H |
| Lₐ₈₁₆ | Rₙ₆₁ | Ar21 | H | H | H | H | H | Rₙ₆₄ | H |
| Lₐ₈₁₇ | Rₙ₆₂ | Ar21 | H | H | H | H | H | Rₙ₆₄ | H |
| Lₐ₈₁₈ | Rₙ₆₄ | Ar21 | H | H | H | H | H | Rₙ₆₄ | H |
| Lₐ₈₁₉ | Rₙ₆₅ | Ar21 | H | H | H | H | H | Rₙ₆₄ | H |
| Lₐ₈₂₀ | Rₙ₆₉ | Ar21 | H | H | H | H | H | Rₙ₆₄ | H |
| Lₐ₈₂₁ | Rₙ₇₀ | Ar21 | H | H | H | H | H | Rₙ₆₄ | H |
| Lₐ₈₂₂ | Rₙ₈₁ | Ar21 | H | H | H | H | H | Rₙ₆₄ | H |
| Lₐ₈₂₃ | Rₙ₁ | Ar21 | H | H | H | H | H | Me | H |
| Lₐ₈₂₄ | Rₙ₄ | Ar21 | H | H | H | H | H | Me | H |
| Lₐ₈₂₅ | Rₙ₅ | Ar21 | H | H | H | H | H | Me | H |
| Lₐ₈₂₆ | Rₙ₇ | Ar21 | H | H | H | H | H | Me | H |
| Lₐ₈₂₇ | Rₙ₁₁ | Ar21 | H | H | H | H | H | Me | H |
| Lₐ₈₂₈ | Rₙ₂₀ | Ar21 | H | H | H | H | H | Me | H |
| Lₐ₈₂₉ | Rₙ₂₁ | Ar21 | H | H | H | H | H | Me | H |
| Lₐ₈₃₀ | Rₙ₅₁ | Ar21 | H | H | H | H | H | Me | H |
| Lₐ₈₃₁ | Rₙ₅₆ | Ar21 | H | H | H | H | H | Me | H |
| Lₐ₈₃₂ | Rₙ₅₉ | Ar21 | H | H | H | H | H | Me | H |
| Lₐ₈₃₃ | Rₙ₆₀ | Ar21 | H | H | H | H | H | Me | H |
| Lₐ₈₃₄ | Rₙ₆₁ | Ar21 | H | H | H | H | H | Me | H |
| Lₐ₈₃₅ | Rₙ₆₂ | Ar21 | H | H | H | H | H | Me | H |
| Lₐ₈₃₆ | Rₙ₆₄ | Ar21 | H | H | H | H | H | Me | H |
| Lₐ₈₃₇ | Rₙ₆₅ | Ar21 | H | H | H | H | H | Me | H |
| Lₐ₈₃₈ | Rₙ₆₉ | Ar21 | H | H | H | H | H | Me | H |
| Lₐ₈₃₉ | Rₙ₇₀ | Ar21 | H | H | H | H | H | Me | H |
| Lₐ₈₄₀ | Rₙ₈₁ | Ar21 | H | H | H | H | H | Me | H |
| Lₐ₈₄₁ | Rₙ₁ | Ar21 | H | H | H | H | Rₙ₁₁ | H | H |
| Lₐ₈₄₂ | Rₙ₄ | Ar21 | H | H | H | H | Rₙ₁₁ | H | H |
| Lₐ₈₄₃ | Rₙ₅ | Ar21 | H | H | H | H | Rₙ₁₁ | H | H |
| Lₐ₈₄₄ | Rₙ₇ | Ar21 | H | H | H | H | Rₙ₁₁ | H | H |
| Lₐ₈₄₅ | Rₙ₁₁ | Ar21 | H | H | H | H | Rₙ₁₁ | H | H |
| Lₐ₈₄₆ | Rₙ₂₀ | Ar21 | H | H | H | H | Rₙ₁₁ | H | H |
| Lₐ₈₄₇ | Rₙ₂₁ | Ar21 | H | H | H | H | Rₙ₁₁ | H | H |
| Lₐ₈₄₈ | Rₙ₅₁ | Ar21 | H | H | H | H | Rₙ₁₁ | H | H |
| Lₐ₈₄₉ | Rₙ₅₆ | Ar21 | H | H | H | H | Rₙ₁₁ | H | H |
| Lₐ₈₅₀ | Rₙ₅₉ | Ar21 | H | H | H | H | Rₙ₁₁ | H | H |
| Lₐ₈₅₁ | Rₙ₆₀ | Ar21 | H | H | H | H | Rₙ₁₁ | H | H |
| Lₐ₈₅₂ | Rₙ₆₁ | Ar21 | H | H | H | H | Rₙ₁₁ | H | H |
| Lₐ₈₅₃ | Rₙ₆₂ | Ar21 | H | H | H | H | Rₙ₁₁ | H | H |
| Lₐ₈₅₄ | Rₙ₆₄ | Ar21 | H | H | H | H | Rₙ₁₁ | H | H |
| Lₐ₈₅₅ | Rₙ₆₅ | Ar21 | H | H | H | H | Rₙ₁₁ | H | H |
| Lₐ₈₅₆ | Rₙ₆₉ | Ar21 | H | H | H | H | Rₙ₁₁ | H | H |
| Lₐ₈₅₇ | Rₙ₇₀ | Ar21 | H | H | H | H | Rₙ₁₁ | H | H |
| Lₐ₈₅₈ | Rₙ₈₁ | Ar21 | H | H | H | H | Rₙ₁₁ | H | H |
| Lₐ₈₅₉ | Rₙ₁ | Ar21 | H | H | H | H | Rₙ₅₉ | H | H |
| Lₐ₈₆₀ | Rₙ₄ | Ar21 | H | H | H | H | Rₙ₅₉ | H | H |
| Lₐ₈₆₁ | Rₙ₅ | Ar21 | H | H | H | H | Rₙ₅₉ | H | H |
| Lₐ₈₆₂ | Rₙ₇ | Ar21 | H | H | H | H | Rₙ₅₉ | H | H |
| Lₐ₈₆₃ | Rₙ₁₁ | Ar21 | H | H | H | H | Rₙ₅₉ | H | H |
| Lₐ₈₆₄ | Rₙ₂₀ | Ar21 | H | H | H | H | Rₙ₅₉ | H | H |
| Lₐ₈₆₅ | Rₙ₂₁ | Ar21 | H | H | H | H | Rₙ₅₉ | H | H |
| Lₐ₈₆₆ | Rₙ₅₁ | Ar21 | H | H | H | H | Rₙ₅₉ | H | H |
| Lₐ₈₆₇ | Rₙ₅₆ | Ar21 | H | H | H | H | Rₙ₅₉ | H | H |
| Lₐ₈₆₈ | Rₙ₅₉ | Ar21 | H | H | H | H | Rₙ₅₉ | H | H |
| Lₐ₈₆₉ | Rₙ₆₀ | Ar21 | H | H | H | H | Rₙ₅₉ | H | H |
| Lₐ₈₇₀ | Rₙ₆₁ | Ar21 | H | H | H | H | Rₙ₅₉ | H | H |
| Lₐ₈₇₁ | Rₙ₆₂ | Ar21 | H | H | H | H | Rₙ₅₉ | H | H |
| Lₐ₈₇₂ | Rₙ₆₄ | Ar21 | H | H | H | H | Rₙ₅₉ | H | H |
| Lₐ₈₇₃ | Rₙ₆₅ | Ar21 | H | H | H | H | Rₙ₅₉ | H | H |
| Lₐ₈₇₄ | Rₙ₆₉ | Ar21 | H | H | H | H | Rₙ₅₉ | H | H |
| Lₐ₈₇₅ | Rₙ₇₀ | Ar21 | H | H | H | H | Rₙ₅₉ | H | H |
| Lₐ₈₇₆ | Rₙ₈₁ | Ar21 | H | H | H | H | Rₙ₅₉ | H | H |
| Lₐ₈₇₇ | Rₙ₁ | Ar21 | H | H | H | H | Rₙ₆₀ | H | H |
| Lₐ₈₇₈ | Rₙ₄ | Ar21 | H | H | H | H | Rₙ₆₀ | H | H |
| Lₐ₈₇₉ | Rₙ₅ | Ar21 | H | H | H | H | Rₙ₆₀ | H | H |
| Lₐ₈₈₀ | Rₙ₇ | Ar21 | H | H | H | H | Rₙ₆₀ | H | H |
| Lₐ₈₈₁ | Rₙ₁₁ | Ar21 | H | H | H | H | Rₙ₆₀ | H | H |
| Lₐ₈₈₂ | Rₙ₂₀ | Ar21 | H | H | H | H | Rₙ₆₀ | H | H |
| Lₐ₈₈₃ | Rₙ₂₁ | Ar21 | H | H | H | H | Rₙ₆₀ | H | H |
| Lₐ₈₈₄ | Rₙ₅₁ | Ar21 | H | H | H | H | Rₙ₆₀ | H | H |
| Lₐ₈₈₅ | Rₙ₅₆ | Ar21 | H | H | H | H | Rₙ₆₀ | H | H |
| Lₐ₈₈₆ | Rₙ₅₉ | Ar21 | H | H | H | H | Rₙ₆₀ | H | H |
| Lₐ₈₈₇ | Rₙ₆₀ | Ar21 | H | H | H | H | Rₙ₆₀ | H | H |
| Lₐ₈₈₈ | Rₙ₆₁ | Ar21 | H | H | H | H | Rₙ₆₀ | H | H |
| Lₐ₈₈₉ | Rₙ₆₂ | Ar21 | H | H | H | H | Rₙ₆₀ | H | H |
| Lₐ₈₉₀ | Rₙ₆₄ | Ar21 | H | H | H | H | Rₙ₆₀ | H | H |
| Lₐ₈₉₁ | Rₙ₆₅ | Ar21 | H | H | H | H | Rₙ₆₀ | H | H |
| Lₐ₈₉₂ | Rₙ₆₉ | Ar21 | H | H | H | H | Rₙ₆₀ | H | H |
| Lₐ₈₉₃ | Rₙ₇₀ | Ar21 | H | H | H | H | Rₙ₆₀ | H | H |
| Lₐ₈₉₄ | Rₙ₈₁ | Ar21 | H | H | H | H | Rₙ₆₀ | H | H |
| Lₐ₈₉₅ | Rₙ₁ | Ar21 | H | H | H | H | Rₙ₆₄ | H | H |
| Lₐ₈₉₆ | Rₙ₄ | Ar21 | H | H | H | H | Rₙ₆₄ | H | H |
| Lₐ₈₉₇ | Rₙ₅ | Ar21 | H | H | H | H | Rₙ₆₄ | H | H |
| Lₐ₈₉₈ | Rₙ₇ | Ar21 | H | H | H | H | Rₙ₆₄ | H | H |
| Lₐ₈₉₉ | Rₙ₁₁ | Ar21 | H | H | H | H | Rₙ₆₄ | H | H |
| Lₐ₉₀₀ | Rₙ₂₀ | Ar21 | H | H | H | H | Rₙ₆₄ | H | H |
| Lₐ₉₀₁ | Rₙ₂₁ | Ar21 | H | H | H | H | Rₙ₆₄ | H | H |
| Lₐ₉₀₂ | Rₙ₅₁ | Ar21 | H | H | H | H | Rₙ₆₄ | H | H |
| Lₐ₉₀₃ | Rₙ₅₆ | Ar21 | H | H | H | H | Rₙ₆₄ | H | H |
| Lₐ₉₀₄ | Rₙ₅₉ | Ar21 | H | H | H | H | Rₙ₆₄ | H | H |
| Lₐ₉₀₅ | Rₙ₆₀ | Ar21 | H | H | H | H | Rₙ₆₄ | H | H |
| Lₐ₉₀₆ | Rₙ₆₁ | Ar21 | H | H | H | H | Rₙ₆₄ | H | H |
| Lₐ₉₀₇ | Rₙ₆₂ | Ar21 | H | H | H | H | Rₙ₆₄ | H | H |
| Lₐ₉₀₈ | Rₙ₆₄ | Ar21 | H | H | H | H | Rₙ₆₄ | H | H |
| Lₐ₉₀₉ | Rₙ₆₅ | Ar21 | H | H | H | H | Rₙ₆₄ | H | H |
| Lₐ₉₁₀ | Rₙ₆₉ | Ar21 | H | H | H | H | Rₙ₆₄ | H | H |
| Lₐ₉₁₁ | Rₙ₇₀ | Ar21 | H | H | H | H | Rₙ₆₄ | H | H |
| Lₐ₉₁₂ | Rₙ₈₁ | Ar21 | H | H | H | H | Rₙ₆₄ | H | H |
| Lₐ₉₁₃ | Rₙ₁ | Ar21 | H | H | H | H | Me | H | H |
| Lₐ₉₁₄ | Rₙ₄ | Ar21 | H | H | H | H | Me | H | H |
| Lₐ₉₁₅ | Rₙ₅ | Ar21 | H | H | H | H | Me | H | H |
| Lₐ₉₁₆ | Rₙ₇ | Ar21 | H | H | H | H | Me | H | H |
| Lₐ₉₁₇ | Rₙ₁₁ | Ar21 | H | H | H | H | Me | H | H |
| Lₐ₉₁₈ | Rₙ₂₀ | Ar21 | H | H | H | H | Me | H | H |
| Lₐ₉₁₉ | Rₙ₂₁ | Ar21 | H | H | H | H | Me | H | H |
| Lₐ₉₂₀ | Rₙ₅₁ | Ar21 | H | H | H | H | Me | H | H |
| Lₐ₉₂₁ | Rₙ₅₆ | Ar21 | H | H | H | H | Me | H | H |
| Lₐ₉₂₂ | Rₙ₅₉ | Ar21 | H | H | H | H | Me | H | H |
| Lₐ₉₂₃ | Rₙ₆₀ | Ar21 | H | H | H | H | Me | H | H |
| Lₐ₉₂₄ | Rₙ₆₁ | Ar21 | H | H | H | H | Me | H | H |
| Lₐ₉₂₅ | Rₙ₆₂ | Ar21 | H | H | H | H | Me | H | H |
| Lₐ₉₂₆ | Rₙ₆₄ | Ar21 | H | H | H | H | Me | H | H |
| Lₐ₉₂₇ | Rₙ₆₅ | Ar21 | H | H | H | H | Me | H | H |
| Lₐ₉₂₈ | Rₙ₆₉ | Ar21 | H | H | H | H | Me | H | H |
| Lₐ₉₂₉ | Rₙ₇₀ | Ar21 | H | H | H | H | Me | H | H |
| Lₐ₉₃₀ | Rₙ₈₁ | Ar21 | H | H | H | H | Me | H | H |
| Lₐ₉₃₁ | Rₙ₁ | Ar21 | H | H | F | H | H | H | H |
| Lₐ₉₃₂ | Rₙ₄ | Ar21 | H | H | F | H | H | H | H |
| Lₐ₉₃₃ | Rₙ₇ | Ar21 | H | H | F | H | H | H | H |
| Lₐ₉₃₄ | Rₙ₂₀ | Ar21 | H | H | F | H | H | H | H |
| Lₐ₉₃₅ | Rₙ₂₁ | Ar21 | D | H | F | H | H | H | H |
| Lₐ₉₃₆ | Rₙ₅₆ | Ar21 | H | H | F | H | H | H | H |
| Lₐ₉₃₇ | Rₙ₅₉ | Ar21 | H | H | F | H | H | H | H |
| Lₐ₉₃₈ | Rₙ₆₁ | Ar21 | H | H | F | H | H | H | H |
| Lₐ₉₃₉ | Rₙ₆₂ | Ar21 | H | H | F | H | H | H | H |
| Lₐ₉₄₀ | Rₙ₆₄ | Ar21 | H | H | F | H | H | H | H |
| Lₐ₉₄₁ | Rₙ₆₉ | Ar21 | H | H | F | H | H | H | H |
| Lₐ₉₄₂ | Rₙ₇₀ | Ar21 | H | H | F | H | H | H | H |
| Lₐ₉₄₃ | Rₙ₁ | Ar21 | H | H | F | H | Rₙ₁₁ | H | H |
| Lₐ₉₄₄ | Rₙ₄ | Ar21 | H | H | F | H | Rₙ₁₁ | H | H |
| Lₐ₉₄₅ | Rₙ₇ | Ar21 | H | H | F | H | Rₙ₁₁ | H | H |
| Lₐ₉₄₆ | Rₙ₂₀ | Ar21 | H | H | F | H | Rₙ₁₁ | H | H |
| Lₐ₉₄₇ | Rₙ₂₁ | Ar21 | H | H | F | H | Rₙ₁₁ | H | H |
| Lₐ₉₄₈ | Rₙ₅₆ | Ar21 | H | H | F | H | Rₙ₁₁ | H | H |
| Lₐ₉₄₉ | Rₙ₅₉ | Ar21 | H | H | F | H | Rₙ₁₁ | H | H |
| Lₐ₉₅₀ | Rₙ₆₁ | Ar21 | H | H | F | H | Rₙ₁₁ | H | H |
| Lₐ₉₅₁ | Rₙ₆₂ | Ar21 | H | H | F | H | Rₙ₁₁ | H | H |
| Lₐ₉₅₂ | Rₙ₆₄ | Ar21 | H | H | F | H | Rₙ₁₁ | H | H |
| Lₐ₉₅₃ | Rₙ₆₉ | Ar21 | H | H | F | H | Rₙ₁₁ | H | H |
| Lₐ₉₅₄ | Rₙ₇₀ | Ar21 | H | H | F | H | Rₙ₁₁ | H | H |
| Lₐ₉₅₅ | Rₙ₁ | Ar21 | H | H | F | H | Rₙ₆₀ | H | H |
| Lₐ₉₅₆ | Rₙ₄ | Ar21 | H | H | F | H | Rₙ₆₀ | H | H |
| Lₐ₉₅₇ | Rₙ₇ | Ar21 | H | H | F | H | Rₙ₆₀ | H | H |
| Lₐ₉₅₈ | Rₙ₂₀ | Ar21 | H | H | F | H | Rₙ₆₀ | H | H |
| Lₐ₉₅₉ | Rₙ₂₁ | Ar21 | H | H | F | H | Rₙ₆₀ | H | H |
| Lₐ₉₆₀ | Rₙ₅₆ | Ar21 | H | H | F | H | Rₙ₆₀ | H | H |
| Lₐ₉₆₁ | Rₙ₅₉ | Ar21 | H | H | F | H | Rₙ₆₀ | H | H |
| Lₐ₉₆₂ | Rₙ₆₁ | Ar21 | H | H | F | H | Rₙ₆₀ | H | H |
| Lₐ₉₆₃ | Rₙ₆₂ | Ar21 | H | H | F | H | Rₙ₆₀ | H | H |
| Lₐ₉₆₄ | Rₙ₆₄ | Ar21 | H | H | F | H | Rₙ₆₀ | H | H |
| Lₐ₉₆₅ | Rₙ₆₉ | Ar21 | H | H | F | H | Rₙ₆₀ | H | H |
| Lₐ₉₆₆ | Rₙ₇₀ | Ar21 | H | H | F | H | Rₙ₆₀ | H | H |
| Lₐ₉₆₇ | Rₙ₁ | Ar21 | H | H | F | H | H | Rₙ₁₁ | H |
| Lₐ₉₆₈ | Rₙ₄ | Ar21 | H | H | F | H | H | Rₙ₁₁ | H |
| Lₐ₉₆₉ | Rₙ₇ | Ar21 | H | H | F | H | H | Rₙ₁₁ | H |
| Lₐ₉₇₀ | Rₙ₂₀ | Ar21 | H | H | F | H | H | Rₙ₁₁ | H |
| Lₐ₉₇₁ | Rₙ₂₁ | Ar21 | H | H | F | H | H | Rₙ₁₁ | H |
| Lₐ₉₇₂ | Rₙ₅₆ | Ar21 | H | H | F | H | H | Rₙ₁₁ | H |
| Lₐ₉₇₃ | Rₙ₅₉ | Ar21 | H | H | F | H | H | Rₙ₁₁ | H |
| Lₐ₉₇₄ | Rₙ₆₁ | Ar21 | H | H | F | H | H | Rₙ₁₁ | H |
| Lₐ₉₇₅ | Rₙ₆₂ | Ar21 | H | D | F | H | H | Rₙ₁₁ | H |
| Lₐ₉₇₆ | Rₙ₆₄ | Ar21 | H | H | F | H | H | Rₙ₁₁ | H |
| Lₐ₉₇₇ | Rₙ₆₉ | Ar21 | H | H | F | H | H | Rₙ₁₁ | H |
| Lₐ₉₇₈ | Rₙ₇₀ | Ar21 | H | H | F | H | H | Rₙ₁₁ | H |
| Lₐ₉₇₉ | Rₙ₁ | Ar21 | H | H | F | H | H | Rₙ₆₀ | H |
| Lₐ₉₈₀ | Rₙ₄ | Ar21 | H | H | F | H | H | Rₙ₆₀ | H |
| Lₐ₉₈₁ | Rₙ₇ | Ar21 | H | H | F | H | H | Rₙ₆₀ | H |
| Lₐ₉₈₂ | Rₙ₂₀ | Ar21 | H | H | F | H | H | Rₙ₆₀ | H |
| Lₐ₉₈₃ | Rₙ₂₁ | Ar21 | H | H | F | H | H | Rₙ₆₀ | H |
| Lₐ₉₈₄ | Rₙ₅₆ | Ar21 | H | H | F | H | H | Rₙ₆₀ | H |
| Lₐ₉₈₅ | Rₙ₅₉ | Ar21 | H | H | F | H | H | Rₙ₆₀ | H |
| Lₐ₉₈₆ | Rₙ₆₁ | Ar21 | H | H | F | H | H | Rₙ₆₀ | H |
| Lₐ₉₈₇ | Rₙ₆₂ | Ar21 | H | H | F | H | H | Rₙ₆₀ | H |
| Lₐ₉₈₈ | Rₙ₆₄ | Ar21 | H | H | F | H | H | Rₙ₆₀ | H |
| Lₐ₉₈₉ | Rₙ₆₉ | Ar21 | H | H | F | H | H | Rₙ₆₀ | H |
| Lₐ₉₉₀ | Rₙ₇₀ | Ar21 | H | H | F | H | H | Rₙ₆₀ | H |
| Lₐ₉₉₁ | Rₙ₁ | Ar21 | H | H | CN | H | H | H | H |
| Lₐ₉₉₂ | Rₙ₄ | Ar21 | D | H | CN | H | H | H | H |
| Lₐ₉₉₃ | Rₙ₇ | Ar21 | H | H | CN | H | H | H | H |
| Lₐ₉₉₄ | Rₙ₂₀ | Ar21 | H | H | CN | H | H | H | H |
| Lₐ₉₉₅ | Rₙ₂₁ | Ar21 | H | H | CN | H | H | H | H |
| Lₐ₉₉₆ | Rₙ₅₆ | Ar21 | H | H | CN | H | H | H | H |
| Lₐ₉₉₇ | Rₙ₅₉ | Ar21 | H | H | CN | H | H | H | H |
| Lₐ₉₉₈ | Rₙ₆₁ | Ar21 | H | H | CN | H | H | H | H |
| Lₐ₉₉₉ | Rₙ₆₂ | Ar21 | H | H | CN | H | H | H | H |
| Lₐ₁₀₀₀ | Rₙ₆₄ | Ar21 | H | H | CN | H | H | H | H |
| Lₐ₁₀₀₁ | Rₙ₆₉ | Ar21 | H | H | CN | H | H | H | H |
| Lₐ₁₀₀₂ | Rₙ₇₀ | Ar21 | H | H | CN | H | H | H | H |
| Lₐ₁₀₀₃ | Rₙ₁ | Ar21 | H | CN | H | H | H | H | H |
| Lₐ₁₀₀₄ | Rₙ₄ | Ar21 | H | CN | D | H | H | H | H |
| Lₐ₁₀₀₅ | Rₙ₇ | Ar21 | H | CN | H | H | H | H | H |
| Lₐ₁₀₀₆ | Rₙ₂₀ | Ar21 | H | CN | H | H | H | H | H |
| Lₐ₁₀₀₇ | Rₙ₂₁ | Ar21 | H | CN | H | H | H | H | H |
| Lₐ₁₀₀₈ | Rₙ₅₆ | Ar21 | H | CN | H | H | H | H | H |
| Lₐ₁₀₀₉ | Rₙ₅₉ | Ar21 | H | CN | H | H | H | H | H |
| Lₐ₁₀₁₀ | Rₙ₆₁ | Ar21 | H | CN | H | H | H | H | H |
| Lₐ₁₀₁₁ | Rₙ₆₂ | Ar21 | H | CN | H | H | H | H | H |
| Lₐ₁₀₁₂ | Rₙ₆₄ | Ar21 | H | CN | H | H | H | H | H |
| Lₐ₁₀₁₃ | Rₙ₆₉ | Ar21 | H | CN | H | H | H | H | H |
| Lₐ₁₀₁₄ | Rₙ₇₀ | Ar21 | H | CN | H | H | H | H | H |
| Lₐ₁₀₁₅ | Rₙ₁ | Ar21 | CN | H | H | H | H | H | H |
| Lₐ₁₀₁₆ | Rₙ₄ | Ar21 | CN | H | H | H | H | H | H |
| Lₐ₁₀₁₇ | Rₙ₇ | Ar21 | CN | H | H | H | H | H | H |
| Lₐ₁₀₁₈ | Rₙ₂₀ | Ar21 | CN | H | H | H | H | H | H |
| Lₐ₁₀₁₉ | Rₙ₂₁ | Ar21 | CN | D | H | H | H | H | H |
| Lₐ₁₀₂₀ | Rₙ₅₆ | Ar21 | CN | H | H | H | H | H | H |
| Lₐ₁₀₂₁ | Rₙ₅₉ | Ar21 | CN | H | H | H | H | H | H |
| Lₐ₁₀₂₂ | Rₙ₆₁ | Ar21 | CN | H | H | H | H | H | H |
| Lₐ₁₀₂₃ | Rₙ₆₂ | Ar21 | CN | H | H | H | H | H | H |
| Lₐ₁₀₂₄ | Rₙ₆₄ | Ar21 | CN | H | H | H | H | H | H |
| Lₐ₁₀₂₅ | Rₙ₆₉ | Ar21 | CN | H | H | H | H | H | H |
| Lₐ₁₀₂₆ | Rₙ₇₀ | Ar21 | CN | H | H | H | H | H | H |
| Lₐ₁₀₂₇ | Rₙ₁ | Ar21 | H | H | CN | H | Rₙ₁₁ | H | H |
| Lₐ₁₀₂₈ | Rₙ₄ | Ar21 | H | H | CN | H | Rₙ₁₁ | H | H |
| Lₐ₁₀₂₉ | Rₙ₇ | Ar21 | H | H | CN | H | Rₙ₁₁ | H | H |
| Lₐ₁₀₃₀ | Rₙ₂₀ | Ar21 | H | H | CN | H | Rₙ₁₁ | H | H |
| Lₐ₁₀₃₁ | Rₙ₂₁ | Ar21 | H | H | CN | H | Rₙ₁₁ | H | H |
| Lₐ₁₀₃₂ | Rₙ₅₆ | Ar21 | H | H | CN | H | Rₙ₁₁ | H | H |
| Lₐ₁₀₃₃ | Rₙ₅₉ | Ar21 | H | H | CN | H | Rₙ₁₁ | H | H |
| Lₐ₁₀₃₄ | Rₙ₆₁ | Ar21 | H | H | CN | H | Rₙ₁₁ | H | H |
| Lₐ₁₀₃₅ | Rₙ₆₂ | Ar21 | H | H | CN | H | Rₙ₁₁ | H | H |
| Lₐ₁₀₃₆ | Rₙ₆₄ | Ar21 | H | H | CN | H | Rₙ₁₁ | H | H |
| Lₐ₁₀₃₇ | Rₙ₆₉ | Ar21 | H | H | CN | H | Rₙ₁₁ | H | H |
| Lₐ₁₀₃₈ | Rₙ₇₀ | Ar21 | H | H | CN | H | Rₙ₁₁ | H | H |
| Lₐ₁₀₃₉ | Rₙ₁ | Ar21 | H | H | CN | H | Rₙ₆₀ | H | D |
| Lₐ₁₀₄₀ | Rₙ₄ | Ar21 | H | H | CN | H | Rₙ₆₀ | H | H |
| Lₐ₁₀₄₁ | Rₙ₇ | Ar21 | H | H | CN | H | Rₙ₆₀ | H | H |
| Lₐ₁₀₄₂ | Rₙ₂₀ | Ar21 | H | H | CN | H | Rₙ₆₀ | H | H |
| Lₐ₁₀₄₃ | Rₙ₂₁ | Ar21 | H | H | CN | H | Rₙ₆₀ | H | H |
| Lₐ₁₀₄₄ | Rₙ₅₆ | Ar21 | H | H | CN | H | Rₙ₆₀ | H | H |
| Lₐ₁₀₄₅ | Rₙ₅₉ | Ar21 | H | H | CN | H | Rₙ₆₀ | H | H |
| Lₐ₁₀₄₆ | Rₙ₆₁ | Ar21 | H | H | CN | H | Rₙ₆₀ | H | H |
| Lₐ₁₀₄₇ | Rₙ₆₂ | Ar21 | H | H | CN | H | Rₙ₆₀ | H | H |
| Lₐ₁₀₄₈ | Rₙ₆₄ | Ar21 | H | H | CN | H | Rₙ₆₀ | H | H |
| Lₐ₁₀₄₉ | Rₙ₆₉ | Ar21 | H | H | CN | H | Rₙ₆₀ | H | H |
| Lₐ₁₀₅₀ | Rₙ₇₀ | Ar21 | H | H | CN | H | Rₙ₆₀ | H | H |
| Lₐ₁₀₅₁ | Rₙ₁ | Ar21 | H | H | CN | H | Rₙ₆₄ | H | H |
| Lₐ₁₀₅₂ | Rₙ₄ | Ar21 | H | H | CN | H | Rₙ₆₄ | H | H |
| Lₐ₁₀₅₃ | Rₙ₇ | Ar21 | H | H | CN | H | Rₙ₆₄ | H | H |
| Lₐ₁₀₅₄ | Rₙ₂₀ | Ar21 | H | H | CN | H | Rₙ₆₄ | H | H |
| Lₐ₁₀₅₅ | Rₙ₂₁ | Ar21 | H | H | CN | H | Rₙ₆₄ | H | H |
| Lₐ₁₀₅₆ | Rₙ₅₆ | Ar21 | H | H | CN | H | Rₙ₆₄ | H | H |
| Lₐ₁₀₅₇ | Rₙ₅₉ | Ar21 | H | H | CN | H | Rₙ₆₄ | H | H |
| Lₐ₁₀₅₈ | Rₙ₆₁ | Ar21 | H | H | CN | H | Rₙ₆₄ | H | H |
| Lₐ₁₀₅₉ | Rₙ₆₂ | Ar21 | H | H | CN | H | Rₙ₆₄ | H | H |
| Lₐ₁₀₆₀ | Rₙ₆₄ | Ar21 | H | H | CN | H | Rₙ₆₄ | H | H |
| Lₐ₁₀₆₁ | Rₙ₆₉ | Ar21 | H | H | CN | H | Rₙ₆₄ | H | H |
| Lₐ₁₀₆₂ | Rₙ₇₀ | Ar21 | H | H | CN | H | Rₙ₆₄ | H | H |
| Lₐ₁₀₆₃ | Rₙ₁ | Ar21 | H | H | CN | H | H | Rₙ₁₁ | H |
| Lₐ₁₀₆₄ | Rₙ₄ | Ar21 | H | H | CN | H | H | Rₙ₁₁ | H |
| Lₐ₁₀₆₅ | Rₙ₇ | Ar21 | H | H | CN | H | H | Rₙ₁₁ | H |
| Lₐ₁₀₆₆ | Rₙ₂₀ | Ar21 | H | H | CN | H | H | Rₙ₁₁ | H |
| Lₐ₁₀₆₇ | Rₙ₂₁ | Ar21 | H | H | CN | H | H | Rₙ₁₁ | H |
| Lₐ₁₀₆₈ | Rₙ₅₆ | Ar21 | H | D | CN | H | H | Rₙ₁₁ | H |
| Lₐ₁₀₆₉ | Rₙ₅₉ | Ar21 | H | H | CN | H | H | Rₙ₁₁ | H |
| Lₐ₁₀₇₀ | Rₙ₆₁ | Ar21 | H | H | CN | H | H | Rₙ₁₁ | H |
| Lₐ₁₀₇₁ | Rₙ₆₂ | Ar21 | H | H | CN | H | H | Rₙ₁₁ | H |
| Lₐ₁₀₇₂ | Rₙ₆₄ | Ar21 | H | H | CN | H | H | Rₙ₁₁ | H |
| Lₐ₁₀₇₃ | Rₙ₆₉ | Ar21 | H | H | CN | H | H | Rₙ₁₁ | H |
| Lₐ₁₀₇₄ | Rₙ₇₀ | Ar21 | H | H | CN | H | H | Rₙ₁₁ | H |
| Lₐ₁₀₇₅ | Rₙ₁ | Ar21 | H | H | CN | H | H | Rₙ₆₀ | H |
| Lₐ₁₀₇₆ | Rₙ₄ | Ar21 | H | H | CN | H | H | Rₙ₆₀ | H |
| Lₐ₁₀₇₇ | Rₙ₇ | Ar21 | H | H | CN | H | H | Rₙ₆₀ | H |
| Lₐ₁₀₇₈ | Rₙ₂₀ | Ar21 | H | H | CN | H | H | Rₙ₆₀ | H |
| Lₐ₁₀₇₉ | Rₙ₂₁ | Ar21 | H | H | CN | H | H | Rₙ₆₀ | D |
| Lₐ₁₀₈₀ | Rₙ₅₆ | Ar21 | H | H | CN | H | H | Rₙ₆₀ | H |
| Lₐ₁₀₈₁ | Rₙ₅₉ | Ar21 | H | H | CN | H | H | Rₙ₆₀ | H |
| Lₐ₁₀₈₂ | Rₙ₆₁ | Ar21 | H | H | CN | H | H | Rₙ₆₀ | H |
| Lₐ₁₀₈₃ | Rₙ₆₂ | Ar21 | H | H | CN | H | H | Rₙ₆₀ | H |
| Lₐ₁₀₈₄ | Rₙ₆₄ | Ar21 | H | H | CN | H | H | Rₙ₆₀ | H |
| Lₐ₁₀₈₅ | Rₙ₆₉ | Ar21 | H | H | CN | H | H | Rₙ₆₀ | H |
| Lₐ₁₀₈₆ | Rₙ₇₀ | Ar21 | H | H | CN | H | H | Rₙ₆₀ | H |
| Lₐ₁₀₈₇ | Rₙ₁ | Ar21 | H | H | CN | H | H | Rₙ₆₄ | H |
| Lₐ₁₀₈₈ | Rₙ₄ | Ar21 | H | H | CN | H | H | Rₙ₆₄ | H |
| Lₐ₁₀₈₉ | Rₙ₇ | Ar21 | H | H | CN | H | H | Rₙ₆₄ | H |
| Lₐ₁₀₉₀ | Rₙ₂₀ | Ar21 | H | H | CN | H | H | Rₙ₆₄ | H |
| Lₐ₁₀₉₁ | Rₙ₂₁ | Ar21 | H | H | CN | H | H | Rₙ₆₄ | H |
| Lₐ₁₀₉₂ | Rₙ₅₆ | Ar21 | H | H | CN | H | H | Rₙ₆₄ | H |
| Lₐ₁₀₉₃ | Rₙ₅₉ | Ar21 | H | H | CN | H | H | Rₙ₆₄ | H |
| Lₐ₁₀₉₄ | Rₙ₆₁ | Ar21 | D | H | CN | H | H | Rₙ₆₄ | H |
| Lₐ₁₀₉₅ | Rₙ₆₂ | Ar21 | H | H | CN | H | H | Rₙ₆₄ | H |
| Lₐ₁₀₉₆ | Rₙ₆₄ | Ar21 | H | H | CN | H | H | Rₙ₆₄ | H |
| Lₐ₁₀₉₇ | Rₙ₆₉ | Ar21 | H | H | CN | H | H | Rₙ₆₄ | H |
| Lₐ₁₀₉₈ | Rₙ₇₀ | Ar21 | H | H | CN | H | H | Rₙ₆₄ | H |
| Lₐ₁₀₉₉ | Rₙ₁ | Ar27 | H | H | H | H | H | H | H |
| Lₐ₁₁₀₀ | Rₙ₄ | Ar27 | H | H | H | H | H | H | H |
| Lₐ₁₁₀₁ | Rₙ₅ | Ar27 | H | H | H | H | H | H | H |
| Lₐ₁₁₀₂ | Rₙ₇ | Ar27 | H | H | H | H | H | H | H |
| Lₐ₁₁₀₃ | Rₙ₁₁ | Ar27 | H | H | H | H | H | H | H |
| Lₐ₁₁₀₄ | Rₙ₂₀ | Ar27 | H | H | H | H | H | H | H |
| Lₐ₁₁₀₅ | Rₙ₂₁ | Ar27 | H | H | H | H | H | H | H |
| Lₐ₁₁₀₆ | Rₙ₅₁ | Ar27 | H | H | H | H | H | H | H |
| Lₐ₁₁₀₇ | Rₙ₅₆ | Ar27 | H | H | H | H | H | H | H |
| Lₐ₁₁₀₈ | Rₙ₅₉ | Ar27 | H | H | H | H | H | H | H |
| Lₐ₁₁₀₉ | Rₙ₆₀ | Ar27 | H | H | H | H | H | H | H |
| Lₐ₁₁₁₀ | Rₙ₆₁ | Ar27 | H | H | H | H | H | H | H |
| Lₐ₁₁₁₁ | Rₙ₆₂ | Ar27 | H | H | H | H | H | H | H |
| Lₐ₁₁₁₂ | Rₙ₆₄ | Ar27 | H | H | H | H | H | H | H |
| Lₐ₁₁₁₃ | Rₙ₆₅ | Ar27 | H | H | H | H | H | H | H |
| Lₐ₁₁₁₄ | Rₙ₆₉ | Ar27 | H | H | H | H | H | H | H |
| Lₐ₁₁₁₅ | Rₙ₇₀ | Ar27 | H | H | H | H | H | H | H |
| Lₐ₁₁₁₆ | Rₙ₈₁ | Ar27 | H | H | H | H | H | H | H |
| Lₐ₁₁₁₇ | Rₙ₁ | Ar27 | H | H | H | H | H | Rₙ₁₁ | H |
| Lₐ₁₁₁₈ | Rₙ₄ | Ar27 | H | H | H | H | H | Rₙ₁₁ | H |
| Lₐ₁₁₁₉ | Rₙ₅ | Ar27 | H | H | H | H | H | Rₙ₁₁ | H |
| Lₐ₁₁₂₀ | Rₙ₇ | Ar27 | H | H | H | H | H | Rₙ₁₁ | H |
| Lₐ₁₁₂₁ | Rₙ₁₁ | Ar27 | H | H | H | H | H | Rₙ₁₁ | H |
| Lₐ₁₁₂₂ | Rₙ₂₀ | Ar27 | H | H | H | H | H | Rₙ₁₁ | H |
| Lₐ₁₁₂₃ | Rₙ₂₁ | Ar27 | H | H | H | H | H | Rₙ₁₁ | H |
| Lₐ₁₁₂₄ | Rₙ₅₁ | Ar27 | H | H | H | H | H | Rₙ₁₁ | H |
| Lₐ₁₁₂₅ | Rₙ₅₆ | Ar27 | H | H | H | H | H | Rₙ₁₁ | H |
| Lₐ₁₁₂₆ | Rₙ₅₉ | Ar27 | H | H | H | H | H | Rₙ₁₁ | H |
| Lₐ₁₁₂₇ | Rₙ₆₀ | Ar27 | H | H | H | H | H | Rₙ₁₁ | H |
| Lₐ₁₁₂₈ | Rₙ₆₁ | Ar27 | H | H | H | H | H | Rₙ₁₁ | H |
| Lₐ₁₁₂₉ | Rₙ₆₂ | Ar27 | H | H | H | H | H | Rₙ₁₁ | H |
| Lₐ₁₁₃₀ | Rₙ₆₄ | Ar27 | H | H | H | H | H | Rₙ₁₁ | H |
| Lₐ₁₁₃₁ | Rₙ₆₅ | Ar27 | H | H | H | H | H | Rₙ₁₁ | H |
| Lₐ₁₁₃₂ | Rₙ₆₉ | Ar27 | H | H | H | H | H | Rₙ₁₁ | H |
| Lₐ₁₁₃₃ | Rₙ₇₀ | Ar27 | H | H | H | H | H | Rₙ₁₁ | H |
| Lₐ₁₁₃₄ | Rₙ₈₁ | Ar27 | H | H | H | H | H | Rₙ₁₁ | H |
| Lₐ₁₁₃₅ | Rₙ₁ | Ar27 | H | H | H | H | H | Rₙ₅₉ | H |
| Lₐ₁₁₃₆ | Rₙ₄ | Ar27 | H | H | H | H | H | Rₙ₅₉ | H |
| Lₐ₁₁₃₇ | Rₙ₅ | Ar27 | H | H | H | H | H | Rₙ₅₉ | H |
| Lₐ₁₁₃₈ | Rₙ₇ | Ar27 | H | H | H | H | H | Rₙ₅₉ | H |
| Lₐ₁₁₃₉ | Rₙ₁₁ | Ar27 | H | H | H | H | H | Rₙ₅₉ | H |
| Lₐ₁₁₄₀ | Rₙ₂₀ | Ar27 | H | H | H | H | H | Rₙ₅₉ | H |
| Lₐ₁₁₄₁ | Rₙ₂₁ | Ar27 | H | H | H | H | H | Rₙ₅₉ | H |
| Lₐ₁₁₄₂ | Rₙ₅₁ | Ar27 | H | H | H | H | H | Rₙ₅₉ | H |
| Lₐ₁₁₄₃ | Rₙ₅₆ | Ar27 | H | H | H | H | H | Rₙ₅₉ | H |
| Lₐ₁₁₄₄ | Rₙ₅₉ | Ar27 | H | H | H | H | H | Rₙ₅₉ | H |
| Lₐ₁₁₄₅ | Rₙ₆₀ | Ar27 | H | H | H | H | H | Rₙ₅₉ | H |
| Lₐ₁₁₄₆ | Rₙ₆₁ | Ar27 | H | H | H | H | H | Rₙ₅₉ | H |
| Lₐ₁₁₄₇ | Rₙ₆₂ | Ar27 | H | H | H | H | H | Rₙ₅₉ | H |
| Lₐ₁₁₄₈ | Rₙ₆₄ | Ar27 | H | H | H | H | H | Rₙ₅₉ | H |
| Lₐ₁₁₄₉ | Rₙ₆₅ | Ar27 | H | H | H | H | H | Rₙ₅₉ | H |
| Lₐ₁₁₅₀ | Rₙ₆₉ | Ar27 | H | H | H | H | H | Rₙ₅₉ | H |
| Lₐ₁₁₅₁ | Rₙ₇₀ | Ar27 | H | H | H | H | H | Rₙ₅₉ | H |
| Lₐ₁₁₅₂ | Rₙ₈₁ | Ar27 | H | H | H | H | H | Rₙ₅₉ | H |
| Lₐ₁₁₅₃ | Rₙ₁ | Ar27 | H | H | H | H | H | Rₙ₆₀ | H |
| Lₐ₁₁₅₄ | Rₙ₄ | Ar27 | H | H | H | H | H | Rₙ₆₀ | H |
| Lₐ₁₁₅₅ | Rₙ₅ | Ar27 | H | H | H | H | H | Rₙ₆₀ | H |
| Lₐ₁₁₅₆ | Rₙ₇ | Ar27 | H | H | H | H | H | Rₙ₆₀ | H |
| Lₐ₁₁₅₇ | Rₙ₁₁ | Ar27 | H | H | H | H | H | Rₙ₆₀ | H |
| Lₐ₁₁₅₈ | Rₙ₂₀ | Ar27 | H | H | H | H | H | Rₙ₆₀ | H |
| Lₐ₁₁₅₉ | Rₙ₂₁ | Ar27 | H | H | H | H | H | Rₙ₆₀ | H |
| Lₐ₁₁₆₀ | Rₙ₅₁ | Ar27 | H | H | H | H | H | Rₙ₆₀ | H |
| Lₐ₁₁₆₁ | Rₙ₅₆ | Ar27 | H | H | H | H | H | Rₙ₆₀ | H |
| Lₐ₁₁₆₂ | Rₙ₅₉ | Ar27 | H | H | H | H | H | Rₙ₆₀ | H |
| Lₐ₁₁₆₃ | Rₙ₆₀ | Ar27 | H | H | H | H | H | Rₙ₆₀ | H |
| Lₐ₁₁₆₄ | Rₙ₆₁ | Ar27 | H | H | H | H | H | Rₙ₆₀ | H |
| Lₐ₁₁₆₅ | Rₙ₆₂ | Ar27 | H | H | H | H | H | Rₙ₆₀ | H |
| Lₐ₁₁₆₆ | Rₙ₆₄ | Ar27 | H | H | H | H | H | Rₙ₆₀ | H |
| Lₐ₁₁₆₇ | Rₙ₆₅ | Ar27 | H | H | H | H | H | Rₙ₆₀ | H |
| Lₐ₁₁₆₈ | Rₙ₆₉ | Ar27 | H | H | H | H | H | Rₙ₆₀ | H |
| Lₐ₁₁₆₉ | Rₙ₇₀ | Ar27 | H | H | H | H | H | Rₙ₆₀ | H |
| Lₐ₁₁₇₀ | Rₙ₈₁ | Ar27 | H | H | H | H | H | Rₙ₆₀ | H |
| Lₐ₁₁₇₁ | Rₙ₁ | Ar27 | H | H | H | H | H | Rₙ₆₄ | H |
| Lₐ₁₁₇₂ | Rₙ₄ | Ar27 | H | H | H | H | H | Rₙ₆₄ | H |
| Lₐ₁₁₇₃ | Rₙ₅ | Ar27 | H | H | H | H | H | Rₙ₆₄ | H |
| Lₐ₁₁₇₄ | Rₙ₇ | Ar27 | H | H | H | H | H | Rₙ₆₄ | H |
| Lₐ₁₁₇₅ | Rₙ₁₁ | Ar27 | H | H | H | H | H | Rₙ₆₄ | H |
| Lₐ₁₁₇₆ | Rₙ₂₀ | Ar27 | H | H | H | H | H | Rₙ₆₄ | H |
| Lₐ₁₁₇₇ | Rₙ₂₁ | Ar27 | H | H | H | H | H | Rₙ₆₄ | H |
| Lₐ₁₁₇₈ | Rₙ₅₁ | Ar27 | H | H | H | H | H | Rₙ₆₄ | H |
| Lₐ₁₁₇₉ | Rₙ₅₆ | Ar27 | H | H | H | H | H | Rₙ₆₄ | H |
| Lₐ₁₁₈₀ | Rₙ₅₉ | Ar27 | H | H | H | H | H | Rₙ₆₄ | H |
| Lₐ₁₁₈₁ | Rₙ₆₀ | Ar27 | H | H | H | H | H | Rₙ₆₄ | H |
| Lₐ₁₁₈₂ | Rₙ₆₁ | Ar27 | H | H | H | H | H | Rₙ₆₄ | H |
| Lₐ₁₁₈₃ | Rₙ₆₂ | Ar27 | H | H | H | H | H | Rₙ₆₄ | H |
| Lₐ₁₁₈₄ | Rₙ₆₄ | Ar27 | H | H | H | H | H | Rₙ₆₄ | H |
| Lₐ₁₁₈₅ | Rₙ₆₅ | Ar27 | H | H | H | H | H | Rₙ₆₄ | H |
| Lₐ₁₁₈₆ | Rₙ₆₉ | Ar27 | H | H | H | H | H | Rₙ₆₄ | H |
| Lₐ₁₁₈₇ | Rₙ₇₀ | Ar27 | H | H | H | H | H | Rₙ₆₄ | H |
| Lₐ₁₁₈₈ | Rₙ₈₁ | Ar27 | H | H | H | H | H | Rₙ₆₄ | H |
| Lₐ₁₁₈₉ | Rₙ₁ | Ar27 | H | H | H | H | H | Me | H |
| Lₐ₁₁₉₀ | Rₙ₄ | Ar27 | H | H | H | H | H | Me | H |
| Lₐ₁₁₉₁ | Rₙ₅ | Ar27 | H | H | H | H | H | Me | H |
| Lₐ₁₁₉₂ | Rₙ₇ | Ar27 | H | H | H | H | H | Me | H |
| Lₐ₁₁₉₃ | Rₙ₁₁ | Ar27 | H | H | H | H | H | Me | H |
| Lₐ₁₁₉₄ | Rₙ₂₀ | Ar27 | H | H | H | H | H | Me | H |
| Lₐ₁₁₉₅ | Rₙ₂₁ | Ar27 | H | H | H | H | H | Me | H |
| Lₐ₁₁₉₆ | Rₙ₅₁ | Ar27 | H | H | H | H | H | Me | H |
| Lₐ₁₁₉₇ | Rₙ₅₆ | Ar27 | H | H | H | H | H | Me | H |
| Lₐ₁₁₉₈ | Rₙ₅₉ | Ar27 | H | H | H | H | H | Me | H |
| Lₐ₁₁₉₉ | Rₙ₆₀ | Ar27 | H | H | H | H | H | Me | H |
| Lₐ₁₂₀₀ | Rₙ₆₁ | Ar27 | H | H | H | H | H | Me | H |
| Lₐ₁₂₀₁ | Rₙ₆₂ | Ar27 | H | H | H | H | H | Me | H |
| Lₐ₁₂₀₂ | Rₙ₆₄ | Ar27 | H | H | H | H | H | Me | H |
| Lₐ₁₂₀₃ | Rₙ₆₅ | Ar27 | H | H | H | H | H | Me | H |
| Lₐ₁₂₀₄ | Rₙ₆₉ | Ar27 | H | H | H | H | H | Me | H |
| Lₐ₁₂₀₅ | Rₙ₇₀ | Ar27 | H | H | H | H | H | Me | H |
| Lₐ₁₂₀₆ | Rₙ₈₁ | Ar27 | H | H | H | H | H | Me | H |
| Lₐ₁₂₀₇ | Rₙ₁ | Ar27 | H | H | H | H | Rₙ₁₁ | H | H |
| Lₐ₁₂₀₈ | Rₙ₄ | Ar27 | H | H | H | H | Rₙ₁₁ | H | H |
| Lₐ₁₂₀₉ | Rₙ₅ | Ar27 | H | H | H | H | Rₙ₁₁ | H | H |
| Lₐ₁₂₁₀ | Rₙ₇ | Ar27 | H | H | H | H | Rₙ₁₁ | H | H |
| Lₐ₁₂₁₁ | Rₙ₁₁ | Ar27 | H | H | H | H | Rₙ₁₁ | H | H |
| Lₐ₁₂₁₂ | Rₙ₂₀ | Ar27 | H | H | H | H | Rₙ₁₁ | H | H |
| Lₐ₁₂₁₃ | Rₙ₂₁ | Ar27 | H | H | H | H | Rₙ₁₁ | H | H |
| Lₐ₁₂₁₄ | Rₙ₅₁ | Ar27 | H | H | H | H | Rₙ₁₁ | H | H |
| Lₐ₁₂₁₅ | Rₙ₅₆ | Ar27 | H | H | H | H | Rₙ₁₁ | H | H |
| Lₐ₁₂₁₆ | Rₙ₅₉ | Ar27 | H | H | H | H | Rₙ₁₁ | H | H |
| Lₐ₁₂₁₇ | Rₙ₆₀ | Ar27 | H | H | H | H | Rₙ₁₁ | H | H |
| Lₐ₁₂₁₈ | Rₙ₆₁ | Ar27 | H | H | H | H | Rₙ₁₁ | H | H |
| Lₐ₁₂₁₉ | Rₙ₆₂ | Ar27 | H | H | H | H | Rₙ₁₁ | H | H |
| Lₐ₁₂₂₀ | Rₙ₆₄ | Ar27 | H | H | H | H | Rₙ₁₁ | H | H |
| Lₐ₁₂₂₁ | Rₙ₆₅ | Ar27 | H | H | H | H | Rₙ₁₁ | H | H |
| Lₐ₁₂₂₂ | Rₙ₆₉ | Ar27 | H | H | H | H | Rₙ₁₁ | H | H |
| Lₐ₁₂₂₃ | Rₙ₇₀ | Ar27 | H | H | H | H | Rₙ₁₁ | H | H |
| Lₐ₁₂₂₄ | Rₙ₈₁ | Ar27 | H | H | H | H | Rₙ₁₁ | H | H |
| Lₐ₁₂₂₅ | Rₙ₁ | Ar27 | H | H | H | H | Rₙ₅₉ | H | H |
| Lₐ₁₂₂₆ | Rₙ₄ | Ar27 | H | H | H | H | Rₙ₅₉ | H | H |
| Lₐ₁₂₂₇ | Rₙ₅ | Ar27 | H | H | H | H | Rₙ₅₉ | H | H |
| Lₐ₁₂₂₈ | Rₙ₇ | Ar27 | H | H | H | H | Rₙ₅₉ | H | H |
| Lₐ₁₂₂₉ | Rₙ₁₁ | Ar27 | H | H | H | H | Rₙ₅₉ | H | H |
| Lₐ₁₂₃₀ | Rₙ₂₀ | Ar27 | H | H | H | H | Rₙ₅₉ | H | H |
| Lₐ₁₂₃₁ | Rₙ₂₁ | Ar27 | H | H | H | H | Rₙ₅₉ | H | H |
| Lₐ₁₂₃₂ | Rₙ₅₁ | Ar27 | H | H | H | H | Rₙ₅₉ | H | H |
| Lₐ₁₂₃₃ | Rₙ₅₆ | Ar27 | H | H | H | H | Rₙ₅₉ | H | H |
| Lₐ₁₂₃₄ | Rₙ₅₉ | Ar27 | H | H | H | H | Rₙ₅₉ | H | H |
| Lₐ₁₂₃₅ | Rₙ₆₀ | Ar27 | H | H | H | H | Rₙ₅₉ | H | H |
| Lₐ₁₂₃₆ | Rₙ₆₁ | Ar27 | H | H | H | H | Rₙ₅₉ | H | H |
| Lₐ₁₂₃₇ | Rₙ₆₂ | Ar27 | H | H | H | H | Rₙ₅₉ | H | H |
| Lₐ₁₂₃₈ | Rₙ₆₄ | Ar27 | H | H | H | H | Rₙ₅₉ | H | H |
| Lₐ₁₂₃₉ | Rₙ₆₅ | Ar27 | H | H | H | H | Rₙ₅₉ | H | H |
| Lₐ₁₂₄₀ | Rₙ₆₉ | Ar27 | H | H | H | H | Rₙ₅₉ | H | H |
| Lₐ₁₂₄₁ | Rₙ₇₀ | Ar27 | H | H | H | H | Rₙ₅₉ | H | H |
| Lₐ₁₂₄₂ | Rₙ₈₁ | Ar27 | H | H | H | H | Rₙ₅₉ | H | H |
| Lₐ₁₂₄₃ | Rₙ₁ | Ar27 | H | H | H | H | Rₙ₆₀ | H | H |
| Lₐ₁₂₄₄ | Rₙ₄ | Ar27 | H | H | H | H | Rₙ₆₀ | H | H |
| Lₐ₁₂₄₅ | Rₙ₅ | Ar27 | H | H | H | H | Rₙ₆₀ | H | H |
| Lₐ₁₂₄₆ | Rₙ₇ | Ar27 | H | H | H | H | Rₙ₆₀ | H | H |
| Lₐ₁₂₄₇ | Rₙ₁₁ | Ar27 | H | H | H | H | Rₙ₆₀ | H | H |
| Lₐ₁₂₄₈ | Rₙ₂₀ | Ar27 | H | H | H | H | Rₙ₆₀ | H | H |
| Lₐ₁₂₄₉ | Rₙ₂₁ | Ar27 | H | H | H | H | Rₙ₆₀ | H | H |
| Lₐ₁₂₅₀ | Rₙ₅₁ | Ar27 | H | H | H | H | Rₙ₆₀ | H | H |
| Lₐ₁₂₅₁ | Rₙ₅₆ | Ar27 | H | H | H | H | Rₙ₆₀ | H | H |
| Lₐ₁₂₅₂ | Rₙ₅₉ | Ar27 | H | H | H | H | Rₙ₆₀ | H | H |
| Lₐ₁₂₅₃ | Rₙ₆₀ | Ar27 | H | H | H | H | Rₙ₆₀ | H | H |
| Lₐ₁₂₅₄ | Rₙ₆₁ | Ar27 | H | H | H | H | Rₙ₆₀ | H | H |
| Lₐ₁₂₅₅ | Rₙ₆₂ | Ar27 | H | H | H | H | Rₙ₆₀ | H | H |
| Lₐ₁₂₅₆ | Rₙ₆₄ | Ar27 | H | H | H | H | Rₙ₆₀ | H | H |
| Lₐ₁₂₅₇ | Rₙ₆₅ | Ar27 | H | H | H | H | Rₙ₆₀ | H | H |
| Lₐ₁₂₅₈ | Rₙ₆₉ | Ar27 | H | H | H | H | Rₙ₆₀ | H | H |
| Lₐ₁₂₅₉ | Rₙ₇₀ | Ar27 | H | H | H | H | Rₙ₆₀ | H | H |
| Lₐ₁₂₆₀ | Rₙ₈₁ | Ar27 | H | H | H | H | Rₙ₆₀ | H | H |
| Lₐ₁₂₆₁ | Rₙ₁ | Ar27 | H | H | H | H | Rₙ₆₄ | H | H |
| Lₐ₁₂₆₂ | Rₙ₄ | Ar27 | H | H | H | H | Rₙ₆₄ | H | H |
| Lₐ₁₂₆₃ | Rₙ₅ | Ar27 | H | H | H | H | Rₙ₆₄ | H | H |
| Lₐ₁₂₆₄ | Rₙ₇ | Ar27 | H | H | H | H | Rₙ₆₄ | H | H |
| Lₐ₁₂₆₅ | Rₙ₁₁ | Ar27 | H | H | H | H | Rₙ₆₄ | H | H |
| Lₐ₁₂₆₆ | Rₙ₂₀ | Ar27 | H | H | H | H | Rₙ₆₄ | H | H |
| Lₐ₁₂₆₇ | Rₙ₂₁ | Ar27 | H | H | H | H | Rₙ₆₄ | H | H |
| Lₐ₁₂₆₈ | Rₙ₅₁ | Ar27 | H | H | H | H | Rₙ₆₄ | H | H |
| Lₐ₁₂₆₉ | Rₙ₅₆ | Ar27 | H | H | H | H | Rₙ₆₄ | H | H |
| Lₐ₁₂₇₀ | Rₙ₅₉ | Ar27 | H | H | H | H | Rₙ₆₄ | H | H |
| Lₐ₁₂₇₁ | Rₙ₆₀ | Ar27 | H | H | H | H | Rₙ₆₄ | H | H |
| Lₐ₁₂₇₂ | Rₙ₆₁ | Ar27 | H | H | H | H | Rₙ₆₄ | H | H |
| Lₐ₁₂₇₃ | Rₙ₆₂ | Ar27 | H | H | H | H | Rₙ₆₄ | H | H |
| Lₐ₁₂₇₄ | Rₙ₆₄ | Ar27 | H | H | H | H | Rₙ₆₄ | H | H |
| Lₐ₁₂₇₅ | Rₙ₆₅ | Ar27 | H | H | H | H | Rₙ₆₄ | H | H |
| Lₐ₁₂₇₆ | Rₙ₆₉ | Ar27 | H | H | H | H | Rₙ₆₄ | H | H |
| Lₐ₁₂₇₇ | Rₙ₇₀ | Ar27 | H | H | H | H | Rₙ₆₄ | H | H |
| Lₐ₁₂₇₈ | Rₙ₈₁ | Ar27 | H | H | H | H | Rₙ₆₄ | H | H |
| Lₐ₁₂₇₉ | Rₙ₁ | Ar27 | H | H | H | H | Me | H | H |
| Lₐ₁₂₈₀ | Rₙ₄ | Ar27 | H | H | H | H | Me | H | H |
| Lₐ₁₂₈₁ | Rₙ₅ | Ar27 | H | H | H | H | Me | H | H |
| Lₐ₁₂₈₂ | Rₙ₇ | Ar27 | H | H | H | H | Me | H | H |
| Lₐ₁₂₈₃ | Rₙ₁₁ | Ar27 | H | H | H | H | Me | H | H |
| Lₐ₁₂₈₄ | Rₙ₂₀ | Ar27 | H | H | H | H | Me | H | H |
| Lₐ₁₂₈₅ | Rₙ₂₁ | Ar27 | H | H | H | H | Me | H | H |
| Lₐ₁₂₈₆ | Rₙ₅₁ | Ar27 | H | H | H | H | Me | H | H |
| Lₐ₁₂₈₇ | Rₙ₅₆ | Ar27 | H | H | H | H | Me | H | H |
| Lₐ₁₂₈₈ | Rₙ₅₉ | Ar27 | H | H | H | H | Me | H | H |
| Lₐ₁₂₈₉ | Rₙ₆₀ | Ar27 | H | H | H | H | Me | H | H |
| Lₐ₁₂₉₀ | Rₙ₆₁ | Ar27 | H | H | H | H | Me | H | H |
| Lₐ₁₂₉₁ | Rₙ₆₂ | Ar27 | H | H | H | H | Me | H | H |
| Lₐ₁₂₉₂ | Rₙ₆₄ | Ar27 | H | H | H | H | Me | H | H |
| Lₐ₁₂₉₃ | Rₙ₆₅ | Ar27 | H | H | H | H | Me | H | H |
| Lₐ₁₂₉₄ | Rₙ₆₉ | Ar27 | H | H | H | H | Me | H | H |
| Lₐ₁₂₉₅ | Rₙ₇₀ | Ar27 | H | H | H | H | Me | H | H |
| Lₐ₁₂₉₆ | Rₙ₈₁ | Ar27 | H | H | H | H | Me | H | H |
| Lₐ₁₂₉₇ | Rₙ₁ | Ar27 | H | H | F | H | H | H | H |
| Lₐ₁₂₉₈ | Rₙ₄ | Ar27 | H | H | F | H | H | H | H |
| Lₐ₁₂₉₉ | Rₙ₇ | Ar27 | H | H | F | H | H | H | H |
| Lₐ₁₃₀₀ | Rₙ₂₀ | Ar27 | H | H | F | H | H | H | H |
| Lₐ₁₃₀₁ | Rₙ₂₁ | Ar27 | H | H | F | H | H | H | H |
| Lₐ₁₃₀₂ | Rₙ₅₆ | Ar27 | H | H | F | H | H | H | H |
| Lₐ₁₃₀₃ | Rₙ₅₉ | Ar27 | H | D | F | H | H | H | H |
| Lₐ₁₃₀₄ | Rₙ₆₁ | Ar27 | H | H | F | H | H | H | H |
| Lₐ₁₃₀₅ | Rₙ₆₂ | Ar27 | H | H | F | H | H | H | H |
| Lₐ₁₃₀₆ | Rₙ₆₄ | Ar27 | H | H | F | H | H | H | H |
| Lₐ₁₃₀₇ | Rₙ₆₉ | Ar27 | H | H | F | H | H | H | H |
| Lₐ₁₃₀₈ | Rₙ₇₀ | Ar27 | H | H | F | H | H | H | H |
| Lₐ₁₃₀₉ | Rₙ₁ | Ar27 | H | H | F | H | Rₙ₁₁ | H | H |
| Lₐ₁₃₁₀ | Rₙ₄ | Ar27 | H | H | F | H | Rₙ₁₁ | H | H |
| Lₐ₁₃₁₁ | Rₙ₇ | Ar27 | H | H | F | H | Rₙ₁₁ | H | H |
| Lₐ₁₃₁₂ | Rₙ₂₀ | Ar27 | H | H | F | H | Rₙ₁₁ | H | H |
| Lₐ₁₃₁₃ | Rₙ₂₁ | Ar27 | H | H | F | H | Rₙ₁₁ | H | H |
| Lₐ₁₃₁₄ | Rₙ₅₆ | Ar27 | H | H | F | H | Rₙ₁₁ | H | H |
| Lₐ₁₃₁₅ | Rₙ₅₉ | Ar27 | H | H | F | H | Rₙ₁₁ | H | H |
| Lₐ₁₃₁₆ | Rₙ₆₁ | Ar27 | H | H | F | H | Rₙ₁₁ | H | H |
| Lₐ₁₃₁₇ | Rₙ₆₂ | Ar27 | H | H | F | H | Rₙ₁₁ | H | H |
| Lₐ₁₃₁₈ | Rₙ₆₄ | Ar27 | H | H | F | H | Rₙ₁₁ | H | H |
| Lₐ₁₃₁₉ | Rₙ₆₉ | Ar27 | H | H | F | H | Rₙ₁₁ | H | H |
| Lₐ₁₃₂₀ | Rₙ₇₀ | Ar27 | H | H | F | H | Rₙ₁₁ | H | H |
| Lₐ₁₃₂₁ | Rₙ₁ | Ar27 | H | H | F | H | Rₙ₆₀ | H | H |
| Lₐ₁₃₂₂ | Rₙ₄ | Ar27 | H | H | F | H | Rₙ₆₀ | H | H |
| Lₐ₁₃₂₃ | Rₙ₇ | Ar27 | H | H | F | H | Rₙ₆₀ | H | H |
| Lₐ₁₃₂₄ | Rₙ₂₀ | Ar27 | H | H | F | H | Rₙ₆₀ | H | H |
| Lₐ₁₃₂₅ | Rₙ₂₁ | Ar27 | H | H | F | H | Rₙ₆₀ | H | H |
| Lₐ₁₃₂₆ | Rₙ₅₆ | Ar27 | H | H | F | H | Rₙ₆₀ | H | H |
| Lₐ₁₃₂₇ | Rₙ₅₉ | Ar27 | H | H | F | H | Rₙ₆₀ | H | H |
| Lₐ₁₃₂₈ | Rₙ₆₁ | Ar27 | H | H | F | H | Rₙ₆₀ | H | H |
| Lₐ₁₃₂₉ | Rₙ₆₂ | Ar27 | H | H | F | H | Rₙ₆₀ | H | H |
| Lₐ₁₃₃₀ | Rₙ₆₄ | Ar27 | H | H | F | H | Rₙ₆₀ | H | H |
| Lₐ₁₃₃₁ | Rₙ₆₉ | Ar27 | H | H | F | H | Rₙ₆₀ | H | H |
| Lₐ₁₃₃₂ | Rₙ₇₀ | Ar27 | H | H | F | H | Rₙ₆₀ | H | H |
| Lₐ₁₃₃₃ | Rₙ₁ | Ar27 | H | H | F | H | H | Rₙ₁₁ | H |
| Lₐ₁₃₃₄ | Rₙ₄ | Ar27 | H | H | F | H | H | Rₙ₁₁ | H |
| Lₐ₁₃₃₅ | Rₙ₇ | Ar27 | H | H | F | H | H | Rₙ₁₁ | H |
| Lₐ₁₃₃₆ | Rₙ₂₀ | Ar27 | H | H | F | H | H | Rₙ₁₁ | H |
| Lₐ₁₃₃₇ | Rₙ₂₁ | Ar27 | H | H | F | H | H | Rₙ₁₁ | H |
| Lₐ₁₃₃₈ | Rₙ₅₆ | Ar27 | H | H | F | H | H | Rₙ₁₁ | H |
| Lₐ₁₃₃₉ | Rₙ₅₉ | Ar27 | H | H | F | H | H | Rₙ₁₁ | H |
| Lₐ₁₃₄₀ | Rₙ₆₁ | Ar27 | H | H | F | H | H | Rₙ₁₁ | H |
| Lₐ₁₃₄₁ | Rₙ₆₂ | Ar27 | H | H | F | H | H | Rₙ₁₁ | H |
| Lₐ₁₃₄₂ | Rₙ₆₄ | Ar27 | H | H | F | H | H | Rₙ₁₁ | H |
| Lₐ₁₃₄₃ | Rₙ₆₉ | Ar27 | H | H | F | H | H | Rₙ₁₁ | H |
| Lₐ₁₃₄₄ | Rₙ₇₀ | Ar27 | H | H | F | H | H | Rₙ₁₁ | H |
| Lₐ₁₃₄₅ | Rₙ₁ | Ar27 | H | H | F | H | H | Rₙ₆₀ | H |
| Lₐ₁₃₄₆ | Rₙ₄ | Ar27 | H | H | F | H | H | Rₙ₆₀ | H |
| Lₐ₁₃₄₇ | Rₙ₇ | Ar27 | D | H | F | H | H | Rₙ₆₀ | H |
| Lₐ₁₃₄₈ | Rₙ₂₀ | Ar27 | H | H | F | H | H | Rₙ₆₀ | H |
| Lₐ₁₃₄₉ | Rₙ₂₁ | Ar27 | H | H | F | H | H | Rₙ₆₀ | H |
| Lₐ₁₃₅₀ | Rₙ₅₆ | Ar27 | H | H | F | H | H | Rₙ₆₀ | H |
| Lₐ₁₃₅₁ | Rₙ₅₉ | Ar27 | H | H | F | H | H | Rₙ₆₀ | H |
| Lₐ₁₃₅₂ | Rₙ₆₁ | Ar27 | H | H | F | H | H | Rₙ₆₀ | H |
| Lₐ₁₃₅₃ | Rₙ₆₂ | Ar27 | H | H | F | H | H | Rₙ₆₀ | H |
| Lₐ₁₃₅₄ | Rₙ₆₄ | Ar27 | H | H | F | H | H | Rₙ₆₀ | H |
| Lₐ₁₃₅₅ | Rₙ₆₉ | Ar27 | H | H | F | H | H | Rₙ₆₀ | H |
| Lₐ₁₃₅₆ | Rₙ₇₀ | Ar27 | H | H | F | H | H | Rₙ₆₀ | H |
| Lₐ₁₃₅₇ | Rₙ₁ | Ar27 | H | H | CN | H | H | H | H |
| Lₐ₁₃₅₈ | Rₙ₄ | Ar27 | H | H | CN | H | H | H | H |
| Lₐ₁₃₅₉ | Rₙ₇ | Ar27 | H | H | CN | H | H | H | H |
| Lₐ₁₃₆₀ | Rₙ₂₀ | Ar27 | H | H | CN | H | H | H | H |
| Lₐ₁₃₆₁ | Rₙ₂₁ | Ar27 | H | H | CN | H | H | H | H |
| Lₐ₁₃₆₂ | Rₙ₅₆ | Ar27 | H | H | CN | H | H | H | H |
| Lₐ₁₃₆₃ | Rₙ₅₉ | Ar27 | H | H | CN | H | H | H | H |
| Lₐ₁₃₆₄ | Rₙ₆₁ | Ar27 | H | H | CN | H | H | H | H |
| Lₐ₁₃₆₅ | Rₙ₆₂ | Ar27 | H | H | CN | H | H | H | H |
| Lₐ₁₃₆₆ | Rₙ₆₄ | Ar27 | H | H | CN | H | H | H | H |
| Lₐ₁₃₆₇ | Rₙ₆₉ | Ar27 | H | H | CN | H | H | H | H |
| Lₐ₁₃₆₈ | Rₙ₇₀ | Ar27 | H | H | CN | H | H | H | H |
| Lₐ₁₃₆₉ | Rₙ₁ | Ar27 | H | CN | H | H | H | H | H |
| Lₐ₁₃₇₀ | Rₙ₄ | Ar27 | H | CN | H | H | H | H | H |
| Lₐ₁₃₇₁ | Rₙ₇ | Ar27 | H | CN | H | H | H | H | H |
| Lₐ₁₃₇₂ | Rₙ₂₀ | Ar27 | H | CN | H | H | H | H | H |
| Lₐ₁₃₇₃ | Rₙ₂₁ | Ar27 | H | CN | H | H | H | H | H |
| Lₐ₁₃₇₄ | Rₙ₅₆ | Ar27 | H | CN | H | H | H | H | H |
| Lₐ₁₃₇₅ | Rₙ₅₉ | Ar27 | H | CN | D | H | H | H | H |
| Lₐ₁₃₇₆ | Rₙ₆₁ | Ar27 | H | CN | H | H | H | H | H |
| Lₐ₁₃₇₇ | Rₙ₆₂ | Ar27 | H | CN | H | H | H | H | H |
| Lₐ₁₃₇₈ | Rₙ₆₄ | Ar27 | H | CN | H | H | H | H | H |
| Lₐ₁₃₇₉ | Rₙ₆₉ | Ar27 | H | CN | H | H | H | H | H |
| Lₐ₁₃₈₀ | Rₙ₇₀ | Ar27 | H | CN | H | H | H | H | H |
| Lₐ₁₃₈₁ | Rₙ₁ | Ar27 | CN | H | H | H | H | H | H |
| Lₐ₁₃₈₂ | Rₙ₄ | Ar27 | CN | H | H | H | H | H | H |
| Lₐ₁₃₈₃ | Rₙ₇ | Ar27 | CN | H | H | H | H | H | H |
| Lₐ₁₃₈₄ | Rₙ₂₀ | Ar27 | CN | H | H | H | H | H | H |
| Lₐ₁₃₈₅ | Rₙ₂₁ | Ar27 | CN | H | H | H | H | H | H |
| Lₐ₁₃₈₆ | Rₙ₅₆ | Ar27 | CN | H | H | H | H | H | H |
| Lₐ₁₃₈₇ | Rₙ₅₉ | Ar27 | CN | H | H | H | H | H | H |
| Lₐ₁₃₈₈ | Rₙ₆₁ | Ar27 | CN | H | H | H | H | H | H |
| Lₐ₁₃₈₉ | Rₙ₆₂ | Ar27 | CN | H | H | H | H | H | H |
| Lₐ₁₃₉₀ | Rₙ₆₄ | Ar27 | CN | H | H | H | H | H | H |
| Lₐ₁₃₉₁ | Rₙ₆₉ | Ar27 | CN | H | H | H | H | H | H |
| Lₐ₁₃₉₂ | Rₙ₇₀ | Ar27 | CN | H | H | H | H | H | H |
| Lₐ₁₃₉₃ | Rₙ₁ | Ar27 | H | H | CN | H | Rₙ₁₁ | H | H |
| Lₐ₁₃₉₄ | Rₙ₄ | Ar27 | H | H | CN | H | Rₙ₁₁ | H | H |
| Lₐ₁₃₉₅ | Rₙ₇ | Ar27 | H | H | CN | H | Rₙ₁₁ | H | H |
| Lₐ₁₃₉₆ | Rₙ₂₀ | Ar27 | H | H | CN | H | Rₙ₁₁ | H | H |
| Lₐ₁₃₉₇ | Rₙ₂₁ | Ar27 | H | H | CN | H | Rₙ₁₁ | H | H |
| Lₐ₁₃₉₈ | Rₙ₅₆ | Ar27 | H | H | CN | H | Rₙ₁₁ | H | H |
| Lₐ₁₃₉₉ | Rₙ₅₉ | Ar27 | H | H | CN | H | Rₙ₁₁ | H | H |
| Lₐ₁₄₀₀ | Rₙ₆₁ | Ar27 | H | H | CN | H | Rₙ₁₁ | H | H |
| Lₐ₁₄₀₁ | Rₙ₆₂ | Ar27 | H | H | CN | H | Rₙ₁₁ | H | H |
| Lₐ₁₄₀₂ | Rₙ₆₄ | Ar27 | H | H | CN | H | Rₙ₁₁ | H | H |
| Lₐ₁₄₀₃ | Rₙ₆₉ | Ar27 | H | H | CN | H | Rₙ₁₁ | H | H |
| Lₐ₁₄₀₄ | Rₙ₇₀ | Ar27 | H | H | CN | H | Rₙ₁₁ | H | H |
| Lₐ₁₄₀₅ | Rₙ₁ | Ar27 | H | H | CN | H | Rₙ₆₀ | H | H |
| Lₐ₁₄₀₆ | Rₙ₄ | Ar27 | H | H | CN | H | Rₙ₆₀ | H | H |
| Lₐ₁₄₀₇ | Rₙ₇ | Ar27 | H | H | CN | H | Rₙ₆₀ | H | H |
| Lₐ₁₄₀₈ | Rₙ₂₀ | Ar27 | H | H | CN | H | Rₙ₆₀ | H | H |
| Lₐ₁₄₀₉ | Rₙ₂₁ | Ar27 | H | H | CN | H | Rₙ₆₀ | H | H |
| Lₐ₁₄₁₀ | Rₙ₅₆ | Ar27 | H | H | CN | H | Rₙ₆₀ | H | H |
| Lₐ₁₄₁₁ | Rₙ₅₉ | Ar27 | H | H | CN | H | Rₙ₆₀ | H | H |
| Lₐ₁₄₁₂ | Rₙ₆₁ | Ar27 | H | H | CN | H | Rₙ₆₀ | H | H |
| Lₐ₁₄₁₃ | Rₙ₆₂ | Ar27 | H | H | CN | H | Rₙ₆₀ | H | H |
| Lₐ₁₄₁₄ | Rₙ₆₄ | Ar27 | H | H | CN | H | Rₙ₆₀ | H | H |
| Lₐ₁₄₁₅ | Rₙ₆₉ | Ar27 | H | H | CN | H | Rₙ₆₀ | H | H |
| Lₐ₁₄₁₆ | Rₙ₇₀ | Ar27 | H | H | CN | H | Rₙ₆₀ | H | H |
| Lₐ₁₄₁₇ | Rₙ₁ | Ar27 | H | H | CN | H | Rₙ₆₄ | H | H |
| Lₐ₁₄₁₈ | Rₙ₄ | Ar27 | H | H | CN | H | Rₙ₆₄ | H | H |
| Lₐ₁₄₁₉ | Rₙ₇ | Ar27 | H | H | CN | H | Rₙ₆₄ | H | H |
| Lₐ₁₄₂₀ | Rₙ₂₀ | Ar27 | H | H | CN | H | Rₙ₆₄ | H | H |
| Lₐ₁₄₂₁ | Rₙ₂₁ | Ar27 | H | H | CN | H | Rₙ₆₄ | H | H |
| Lₐ₁₄₂₂ | Rₙ₅₆ | Ar27 | H | H | CN | H | Rₙ₆₄ | H | H |
| Lₐ₁₄₂₃ | Rₙ₅₉ | Ar27 | H | H | CN | H | Rₙ₆₄ | H | H |
| Lₐ₁₄₂₄ | Rₙ₆₁ | Ar27 | H | H | CN | H | Rₙ₆₄ | H | H |
| Lₐ₁₄₂₅ | Rₙ₆₂ | Ar27 | H | H | CN | H | Rₙ₆₄ | H | H |
| Lₐ₁₄₂₆ | Rₙ₆₄ | Ar27 | H | H | CN | H | Rₙ₆₄ | H | H |
| Lₐ₁₄₂₇ | Rₙ₆₉ | Ar27 | H | H | CN | H | Rₙ₆₄ | H | H |
| Lₐ₁₄₂₈ | Rₙ₇₀ | Ar27 | H | H | CN | H | Rₙ₆₄ | H | H |
| Lₐ₁₄₂₉ | Rₙ₁ | Ar27 | H | H | CN | H | H | Rₙ₁₁ | H |
| Lₐ₁₄₃₀ | Rₙ₄ | Ar27 | H | H | CN | H | H | Rₙ₁₁ | H |
| Lₐ₁₄₃₁ | Rₙ₇ | Ar27 | H | H | CN | H | H | Rₙ₁₁ | H |
| Lₐ₁₄₃₂ | Rₙ₂₀ | Ar27 | H | D | CN | H | H | Rₙ₁₁ | H |
| Lₐ₁₄₃₃ | Rₙ₂₁ | Ar27 | H | H | CN | H | H | Rₙ₁₁ | H |
| Lₐ₁₄₃₄ | Rₙ₅₆ | Ar27 | H | H | CN | H | H | Rₙ₁₁ | H |
| Lₐ₁₄₃₅ | Rₙ₅₉ | Ar27 | H | H | CN | H | H | Rₙ₁₁ | H |
| Lₐ₁₄₃₆ | Rₙ₆₁ | Ar27 | H | H | CN | H | H | Rₙ₁₁ | H |
| Lₐ₁₄₃₇ | Rₙ₆₂ | Ar27 | H | H | CN | H | H | Rₙ₁₁ | H |
| Lₐ₁₄₃₈ | Rₙ₆₄ | Ar27 | D | H | CN | H | H | Rₙ₁₁ | H |
| Lₐ₁₄₃₉ | Rₙ₆₉ | Ar27 | H | H | CN | H | H | Rₙ₁₁ | H |
| Lₐ₁₄₄₀ | Rₙ₇₀ | Ar27 | H | H | CN | H | H | Rₙ₁₁ | H |
| Lₐ₁₄₄₁ | Rₙ₁ | Ar27 | H | H | CN | H | H | Rₙ₆₀ | H |
| Lₐ₁₄₄₂ | Rₙ₄ | Ar27 | H | H | CN | H | H | Rₙ₆₀ | H |
| Lₐ₁₄₄₃ | Rₙ₇ | Ar27 | H | H | CN | H | H | Rₙ₆₀ | H |
| Lₐ₁₄₄₄ | R₁₂₀ | Ar27 | H | H | CN | H | H | Rₙ₆₀ | H |
| Lₐ₁₄₄₅ | Rₙ₂₁ | Ar27 | H | H | CN | H | H | Rₙ₆₀ | H |
| Lₐ₁₄₄₆ | Rₙ₅₆ | Ar27 | H | H | CN | H | H | Rₙ₆₀ | D |
| Lₐ₁₄₄₇ | Rₙ₅₉ | Ar27 | H | H | CN | H | H | Rₙ₆₀ | H |
| Lₐ₁₄₄₈ | Rₙ₆₁ | Ar27 | H | H | CN | H | H | Rₙ₆₀ | H |
| Lₐ₁₄₄₉ | Rₙ₆₂ | Ar27 | H | H | CN | H | H | Rₙ₆₀ | H |
| Lₐ₁₄₅₀ | Rₙ₆₄ | Ar27 | H | H | CN | H | H | Rₙ₆₀ | H |
| Lₐ₁₄₅₁ | Rₙ₆₉ | Ar27 | H | H | CN | H | D | Rₙ₆₀ | H |
| Lₐ₁₄₅₂ | Rₙ₇₀ | Ar27 | H | H | CN | H | H | Rₙ₆₀ | H |
| Lₐ₁₄₅₃ | Rₙ₁ | Ar27 | H | H | CN | H | H | Rₙ₆₄ | H |
| Lₐ₁₄₅₄ | Rₙ₄ | Ar27 | H | H | CN | H | H | Rₙ₆₄ | H |
| Lₐ₁₄₅₅ | Rₙ₇ | Ar27 | H | H | CN | H | H | Rₙ₆₄ | H |
| Lₐ₁₄₅₆ | Rₙ₂₀ | Ar27 | H | H | CN | H | H | Rₙ₆₄ | H |
| Lₐ₁₄₅₇ | Rₙ₂₁ | Ar27 | H | H | CN | H | H | Rₙ₆₄ | H |
| Lₐ₁₄₅₈ | Rₙ₅₆ | Ar27 | H | H | CN | H | H | Rₙ₆₄ | H |
| Lₐ₁₄₅₉ | Rₙ₅₉ | Ar27 | H | H | CN | H | H | Rₙ₆₄ | H |
| Lₐ₁₄₆₀ | Rₙ₆₁ | Ar27 | H | H | CN | H | H | Rₙ₆₄ | H |
| Lₐ₁₄₆₁ | Rₙ₆₂ | Ar27 | H | H | CN | H | H | Rₙ₆₄ | H |
| Lₐ₁₄₆₂ | Rₙ₆₄ | Ar27 | H | H | CN | H | H | Rₙ₆₄ | H |
| Lₐ₁₄₆₃ | Rₙ₆₉ | Ar27 | H | H | CN | H | H | Rₙ₆₄ | H |
| Lₐ₁₄₆₄ | Rₙ₇₀ | Ar27 | H | H | CN | H | H | Rₙ₆₄ | H |
| Lₐ₁₄₆₅ | Rₙ₁ | Ar29 | H | H | H | H | H | H | H |
| Lₐ₁₄₆₆ | Rₙ₄ | Ar29 | H | H | H | H | H | H | H |
| Lₐ₁₄₆₇ | Rₙ₅ | Ar29 | H | H | H | H | H | H | H |
| Lₐ₁₄₆₈ | Rₙ₇ | Ar29 | H | H | H | H | H | H | H |
| Lₐ₁₄₆₉ | Rₙ₁₁ | Ar29 | H | H | H | H | H | H | H |
| Lₐ₁₄₇₀ | Rₙ₂₀ | Ar29 | H | H | H | H | H | H | H |
| Lₐ₁₄₇₁ | Rₙ₂₁ | Ar29 | H | H | H | H | H | H | H |
| Lₐ₁₄₇₂ | Rₙ₅₁ | Ar29 | H | H | H | H | H | H | H |
| Lₐ₁₄₇₃ | Rₙ₅₆ | Ar29 | H | H | H | H | H | H | H |
| Lₐ₁₄₇₄ | Rₙ₅₉ | Ar29 | H | H | H | H | H | H | H |
| Lₐ₁₄₇₅ | Rₙ₆₀ | Ar29 | H | H | H | H | H | H | H |
| Lₐ₁₄₇₆ | Rₙ₆₁ | Ar29 | H | H | H | H | H | H | H |
| Lₐ₁₄₇₇ | Rₙ₆₂ | Ar29 | H | H | H | H | H | H | H |
| Lₐ₁₄₇₈ | Rₙ₆₄ | Ar29 | H | H | H | H | H | H | H |
| Lₐ₁₄₇₉ | Rₙ₆₅ | Ar29 | H | H | H | H | H | H | H |
| Lₐ₁₄₈₀ | Rₙ₆₉ | Ar29 | H | H | H | H | H | H | H |
| Lₐ₁₄₈₁ | Rₙ₇₀ | Ar29 | H | H | H | H | H | H | H |
| Lₐ₁₄₈₂ | Rₙ₈₁ | Ar29 | H | H | H | H | H | H | H |
| Lₐ₁₄₈₃ | Rₙ₁ | Ar29 | H | H | H | H | H | Rₙ₁₁ | H |
| Lₐ₁₄₈₄ | Rₙ₄ | Ar29 | H | H | H | H | H | Rₙ₁₁ | H |
| Lₐ₁₄₈₅ | Rₙ₅ | Ar29 | H | H | H | H | H | Rₙ₁₁ | H |
| Lₐ₁₄₈₆ | Rₙ₇ | Ar29 | H | H | H | H | H | Rₙ₁₁ | H |
| Lₐ₁₄₈₇ | Rₙ₁₁ | Ar29 | H | H | H | H | H | Rₙ₁₁ | H |
| Lₐ₁₄₈₈ | Rₙ₂₀ | Ar29 | H | H | H | H | H | Rₙ₁₁ | H |
| Lₐ₁₄₈₉ | Rₙ₂₁ | Ar29 | H | H | H | H | H | Rₙ₁₁ | H |
| Lₐ₁₄₉₀ | Rₙ₅₁ | Ar29 | H | H | H | H | H | Rₙ₁₁ | H |
| Lₐ₁₄₉₁ | Rₙ₅₆ | Ar29 | H | H | H | H | H | Rₙ₁₁ | H |
| Lₐ₁₄₉₂ | Rₙ₅₉ | Ar29 | H | H | H | H | H | Rₙ₁₁ | H |
| Lₐ₁₄₉₃ | Rₙ₆₀ | Ar29 | H | H | H | H | H | Rₙ₁₁ | H |
| Lₐ₁₄₉₄ | Rₙ₆₁ | Ar29 | H | H | H | H | H | Rₙ₁₁ | H |
| Lₐ₁₄₉₅ | Rₙ₆₂ | Ar29 | H | H | H | H | H | Rₙ₁₁ | H |
| Lₐ₁₄₉₆ | Rₙ₆₄ | Ar29 | H | H | H | H | H | Rₙ₁₁ | H |
| Lₐ₁₄₉₇ | Rₙ₆₅ | Ar29 | H | H | H | H | H | Rₙ₁₁ | H |
| Lₐ₁₄₉₈ | Rₙ₆₉ | Ar29 | H | H | H | H | H | Rₙ₁₁ | H |
| Lₐ₁₄₉₉ | Rₙ₇₀ | Ar29 | H | H | H | H | H | Rₙ₁₁ | H |
| Lₐ₁₅₀₀ | Rₙ₈₁ | Ar29 | H | H | H | H | H | Rₙ₁₁ | H |
| Lₐ₁₅₀₁ | Rₙ₁ | Ar29 | H | H | H | H | H | Rₙ₅₉ | H |
| Lₐ₁₅₀₂ | Rₙ₄ | Ar29 | H | H | H | H | H | Rₙ₅₉ | H |
| Lₐ₁₅₀₃ | Rₙ₅ | Ar29 | H | H | H | H | H | Rₙ₅₉ | H |
| Lₐ₁₅₀₄ | Rₙ₇ | Ar29 | H | H | H | H | H | Rₙ₅₉ | H |
| Lₐ₁₅₀₅ | Rₙ₁₁ | Ar29 | H | H | H | H | H | Rₙ₅₉ | H |
| Lₐ₁₅₀₆ | Rₙ₂₀ | Ar29 | H | H | H | H | H | Rₙ₅₉ | H |
| Lₐ₁₅₀₇ | Rₙ₂₁ | Ar29 | H | H | H | H | H | Rₙ₅₉ | H |
| Lₐ₁₅₀₈ | Rₙ₅₁ | Ar29 | H | H | H | H | H | Rₙ₅₉ | H |
| Lₐ₁₅₀₉ | Rₙ₅₆ | Ar29 | H | H | H | H | H | Rₙ₅₉ | H |
| Lₐ₁₅₁₀ | Rₙ₅₉ | Ar29 | H | H | H | H | H | Rₙ₅₉ | H |
| Lₐ₁₅₁₁ | Rₙ₆₀ | Ar29 | H | H | H | H | H | Rₙ₅₉ | H |
| Lₐ₁₅₁₂ | Rₙ₆₁ | Ar29 | H | H | H | H | H | Rₙ₅₉ | H |
| Lₐ₁₅₁₃ | Rₙ₆₂ | Ar29 | H | H | H | H | H | Rₙ₅₉ | H |
| Lₐ₁₅₁₄ | Rₙ₆₄ | Ar29 | H | H | H | H | H | Rₙ₅₉ | H |
| Lₐ₁₅₁₅ | Rₙ₆₅ | Ar29 | H | H | H | H | H | Rₙ₅₉ | H |
| Lₐ₁₅₁₆ | Rₙ₆₉ | Ar29 | H | H | H | H | H | Rₙ₅₉ | H |
| Lₐ₁₅₁₇ | Rₙ₇₀ | Ar29 | H | H | H | H | H | Rₙ₅₉ | H |
| Lₐ₁₅₁₈ | Rₙ₈₁ | Ar29 | H | H | H | H | H | Rₙ₅₉ | H |
| Lₐ₁₅₁₉ | Rₙ₁ | Ar29 | H | H | H | H | H | Rₙ₆₀ | H |
| Lₐ₁₅₂₀ | Rₙ₄ | Ar29 | H | H | H | H | H | Rₙ₆₀ | H |
| Lₐ₁₅₂₁ | Rₙ₅ | Ar29 | H | H | H | H | H | Rₙ₆₀ | H |
| Lₐ₁₅₂₂ | Rₙ₇ | Ar29 | H | H | H | H | H | Rₙ₆₀ | H |
| Lₐ₁₅₂₃ | Rₙ₁₁ | Ar29 | H | H | H | H | H | Rₙ₆₀ | H |
| Lₐ₁₅₂₄ | Rₙ₂₀ | Ar29 | H | H | H | H | H | Rₙ₆₀ | H |
| Lₐ₁₅₂₅ | Rₙ₂₁ | Ar29 | H | H | H | H | H | Rₙ₆₀ | H |
| Lₐ₁₅₂₆ | Rₙ₅₁ | Ar29 | H | H | H | H | H | Rₙ₆₀ | H |
| Lₐ₁₅₂₇ | Rₙ₅₆ | Ar29 | H | H | H | H | H | Rₙ₆₀ | H |
| Lₐ₁₅₂₈ | Rₙ₅₉ | Ar29 | H | H | H | H | H | Rₙ₆₀ | H |
| Lₐ₁₅₂₉ | Rₙ₆₀ | Ar29 | H | H | H | H | H | Rₙ₆₀ | H |
| Lₐ₁₅₃₀ | Rₙ₆₁ | Ar29 | H | H | H | H | H | Rₙ₆₀ | H |
| Lₐ₁₅₃₁ | Rₙ₆₂ | Ar29 | H | H | H | H | H | Rₙ₆₀ | H |
| Lₐ₁₅₃₂ | Rₙ₆₄ | Ar29 | H | H | H | H | H | Rₙ₆₀ | H |
| Lₐ₁₅₃₃ | Rₙ₆₅ | Ar29 | H | H | H | H | H | Rₙ₆₀ | H |
| Lₐ₁₅₃₄ | Rₙ₆₉ | Ar29 | H | H | H | H | H | Rₙ₆₀ | H |
| Lₐ₁₅₃₅ | Rₙ₇₀ | Ar29 | H | H | H | H | H | Rₙ₆₀ | H |
| Lₐ₁₅₃₆ | Rₙ₈₁ | Ar29 | H | H | H | H | H | Rₙ₆₀ | H |
| Lₐ₁₅₃₇ | Rₙ₁ | Ar29 | H | H | H | H | H | Rₙ₆₄ | H |
| Lₐ₁₅₃₈ | Rₙ₄ | Ar29 | H | H | H | H | H | Rₙ₆₄ | H |
| Lₐ₁₅₃₉ | Rₙ₅ | Ar29 | H | H | H | H | H | Rₙ₆₄ | H |
| Lₐ₁₅₄₀ | Rₙ₇ | Ar29 | H | H | H | H | H | Rₙ₆₄ | H |
| Lₐ₁₅₄₁ | Rₙ₁₁ | Ar29 | H | H | H | H | H | Rₙ₆₄ | H |
| Lₐ₁₅₄₂ | Rₙ₂₀ | Ar29 | H | H | H | H | H | Rₙ₆₄ | H |
| Lₐ₁₅₄₃ | Rₙ₂₁ | Ar29 | H | H | H | H | H | Rₙ₆₄ | H |
| Lₐ₁₅₄₄ | Rₙ₅₁ | Ar29 | H | H | H | H | H | Rₙ₆₄ | H |
| Lₐ₁₅₄₅ | Rₙ₅₆ | Ar29 | H | H | H | H | H | Rₙ₆₄ | H |
| Lₐ₁₅₄₆ | Rₙ₅₉ | Ar29 | H | H | H | H | H | Rₙ₆₄ | H |
| Lₐ₁₅₄₇ | Rₙ₆₀ | Ar29 | H | H | H | H | H | Rₙ₆₄ | H |
| Lₐ₁₅₄₈ | Rₙ₆₁ | Ar29 | H | H | H | H | H | Rₙ₆₄ | H |
| Lₐ₁₅₄₉ | Rₙ₆₂ | Ar29 | H | H | H | H | H | Rₙ₆₄ | H |
| Lₐ₁₅₅₀ | Rₙ₆₄ | Ar29 | H | H | H | H | H | Rₙ₆₄ | H |
| Lₐ₁₅₅₁ | Rₙ₆₅ | Ar29 | H | H | H | H | H | Rₙ₆₄ | H |
| Lₐ₁₅₅₂ | Rₙ₆₉ | Ar29 | H | H | H | H | H | Rₙ₆₄ | H |
| Lₐ₁₅₅₃ | Rₙ₇₀ | Ar29 | H | H | H | H | H | Rₙ₆₄ | H |
| Lₐ₁₅₅₄ | Rₙ₈₁ | Ar29 | H | H | H | H | H | Rₙ₆₄ | H |
| Lₐ₁₅₅₅ | Rₙ₁ | Ar29 | H | H | H | H | H | Me | H |
| Lₐ₁₅₅₆ | Rₙ₄ | Ar29 | H | H | H | H | H | Me | H |
| Lₐ₁₅₅₇ | Rₙ₅ | Ar29 | H | H | H | H | H | Me | H |
| Lₐ₁₅₅₈ | Rₙ₇ | Ar29 | H | H | H | H | H | Me | H |
| Lₐ₁₅₅₉ | Rₙ₁₁ | Ar29 | H | H | H | H | H | Me | H |
| Lₐ₁₅₆₀ | Rₙ₂₀ | Ar29 | H | H | H | H | H | Me | H |
| Lₐ₁₅₆₁ | Rₙ₂₁ | Ar29 | H | H | H | H | H | Me | H |
| Lₐ₁₅₆₂ | Rₙ₅₁ | Ar29 | H | H | H | H | H | Me | H |
| Lₐ₁₅₆₃ | Rₙ₅₆ | Ar29 | H | H | H | H | H | Me | H |
| Lₐ₁₅₆₄ | Rₙ₅₉ | Ar29 | H | H | H | H | H | Me | H |
| Lₐ₁₅₆₅ | Rₙ₆₀ | Ar29 | H | H | H | H | H | Me | H |
| Lₐ₁₅₆₆ | Rₙ₆₁ | Ar29 | H | H | H | H | H | Me | H |
| Lₐ₁₅₆₇ | Rₙ₆₂ | Ar29 | H | H | H | H | H | Me | H |
| Lₐ₁₅₆₈ | Rₙ₆₄ | Ar29 | H | H | H | H | H | Me | H |
| Lₐ₁₅₆₉ | Rₙ₆₅ | Ar29 | H | H | H | H | H | Me | H |
| Lₐ₁₅₇₀ | Rₙ₆₉ | Ar29 | H | H | H | H | H | Me | H |
| Lₐ₁₅₇₁ | Rₙ₇₀ | Ar29 | H | H | H | H | H | Me | H |
| Lₐ₁₅₇₂ | Rₙ₈₁ | Ar29 | H | H | H | H | H | Me | H |
| Lₐ₁₅₇₃ | Rₙ₁ | Ar29 | H | H | H | H | Rₙ₁₁ | H | H |
| Lₐ₁₅₇₄ | Rₙ₄ | Ar29 | H | H | H | H | Rₙ₁₁ | H | H |
| Lₐ₁₅₇₅ | Rₙ₅ | Ar29 | H | H | H | H | Rₙ₁₁ | H | H |
| Lₐ₁₅₇₆ | Rₙ₇ | Ar29 | H | H | H | H | Rₙ₁₁ | H | H |
| Lₐ₁₅₇₇ | Rₙ₁₁ | Ar29 | H | H | H | H | Rₙ₁₁ | H | H |
| Lₐ₁₅₇₈ | Rₙ₂₀ | Ar29 | H | H | H | H | Rₙ₁₁ | H | H |
| Lₐ₁₅₇₉ | Rₙ₂₁ | Ar29 | H | H | H | H | Rₙ₁₁ | H | H |
| Lₐ₁₅₈₀ | Rₙ₅₁ | Ar29 | H | H | H | H | Rₙ₁₁ | H | H |
| Lₐ₁₅₈₁ | Rₙ₅₆ | Ar29 | H | H | H | H | Rₙ₁₁ | H | H |
| Lₐ₁₅₈₂ | Rₙ₅₉ | Ar29 | H | H | H | H | Rₙ₁₁ | H | H |
| Lₐ₁₅₈₃ | Rₙ₆₀ | Ar29 | H | H | H | H | Rₙ₁₁ | H | H |
| Lₐ₁₅₈₄ | Rₙ₆₁ | Ar29 | H | H | H | H | Rₙ₁₁ | H | H |
| Lₐ₁₅₈₅ | Rₙ₆₂ | Ar29 | H | H | H | H | Rₙ₁₁ | H | H |
| Lₐ₁₅₈₆ | Rₙ₆₄ | Ar29 | H | H | H | H | Rₙ₁₁ | H | H |
| Lₐ₁₅₈₇ | Rₙ₆₅ | Ar29 | H | H | H | H | Rₙ₁₁ | H | H |
| Lₐ₁₅₈₈ | Rₙ₆₉ | Ar29 | H | H | H | H | Rₙ₁₁ | H | H |
| Lₐ₁₅₈₉ | Rₙ₇₀ | Ar29 | H | H | H | H | Rₙ₁₁ | H | H |
| Lₐ₁₅₉₀ | Rₙ₈₁ | Ar29 | H | H | H | H | Rₙ₁₁ | H | H |
| Lₐ₁₅₉₁ | Rₙ₁ | Ar29 | H | H | H | H | Rₙ₅₉ | H | H |
| Lₐ₁₅₉₂ | Rₙ₄ | Ar29 | H | H | H | H | Rₙ₅₉ | H | H |
| Lₐ₁₅₉₃ | Rₙ₅ | Ar29 | H | H | H | H | Rₙ₅₉ | H | H |
| Lₐ₁₅₉₄ | Rₙ₇ | Ar29 | H | H | H | H | Rₙ₅₉ | H | H |
| Lₐ₁₅₉₅ | Rₙ₁₁ | Ar29 | H | H | H | H | Rₙ₅₉ | H | H |
| Lₐ₁₅₉₆ | Rₙ₂₀ | Ar29 | H | H | H | H | Rₙ₅₉ | H | H |
| Lₐ₁₅₉₇ | Rₙ₂₁ | Ar29 | H | H | H | H | Rₙ₅₉ | H | H |
| Lₐ₁₅₉₈ | Rₙ₅₁ | Ar29 | H | H | H | H | Rₙ₅₉ | H | H |
| Lₐ₁₅₉₉ | Rₙ₅₆ | Ar29 | H | H | H | H | Rₙ₅₉ | H | H |
| Lₐ₁₆₀₀ | Rₙ₅₉ | Ar29 | H | H | H | H | Rₙ₅₉ | H | H |
| Lₐ₁₆₀₁ | Rₙ₆₀ | Ar29 | H | H | H | H | Rₙ₅₉ | H | H |
| Lₐ₁₆₀₂ | Rₙ₆₁ | Ar29 | H | H | H | H | Rₙ₅₉ | H | H |
| Lₐ₁₆₀₃ | Rₙ₆₂ | Ar29 | H | H | H | H | Rₙ₅₉ | H | H |
| Lₐ₁₆₀₄ | Rₙ₆₄ | Ar29 | H | H | H | H | Rₙ₅₉ | H | H |
| Lₐ₁₆₀₅ | Rₙ₆₅ | Ar29 | H | H | H | H | Rₙ₅₉ | H | H |
| Lₐ₁₆₀₆ | Rₙ₆₉ | Ar29 | H | H | H | H | Rₙ₅₉ | H | H |
| Lₐ₁₆₀₇ | Rₙ₇₀ | Ar29 | H | H | H | H | Rₙ₅₉ | H | H |
| Lₐ₁₆₀₈ | Rₙ₈₁ | Ar29 | H | H | H | H | Rₙ₅₉ | H | H |
| Lₐ₁₆₀₉ | Rₙ₁ | Ar29 | H | H | H | H | Rₙ₆₀ | H | H |
| Lₐ₁₆₁₀ | Rₙ₄ | Ar29 | H | H | H | H | Rₙ₆₀ | H | H |
| Lₐ₁₆₁₁ | Rₙ₅ | Ar29 | H | H | H | H | Rₙ₆₀ | H | H |
| Lₐ₁₆₁₂ | Rₙ₇ | Ar29 | H | H | H | H | Rₙ₆₀ | H | H |
| Lₐ₁₆₁₃ | Rₙ₁₁ | Ar29 | H | H | H | H | Rₙ₆₀ | H | H |
| Lₐ₁₆₁₄ | Rₙ₂₀ | Ar29 | H | H | H | H | Rₙ₆₀ | H | H |
| Lₐ₁₆₁₅ | Rₙ₂₁ | Ar29 | H | H | H | H | Rₙ₆₀ | H | H |
| Lₐ₁₆₁₆ | Rₙ₅₁ | Ar29 | H | H | H | H | Rₙ₆₀ | H | D |
| Lₐ₁₆₁₇ | Rₙ₅₆ | Ar29 | H | H | H | H | Rₙ₆₀ | H | H |
| Lₐ₁₆₁₈ | Rₙ₅₉ | Ar29 | H | H | H | H | Rₙ₆₀ | H | H |
| Lₐ₁₆₁₉ | Rₙ₆₀ | Ar29 | H | H | H | H | Rₙ₆₀ | H | H |
| Lₐ₁₆₂₀ | Rₙ₆₁ | Ar29 | H | H | H | H | Rₙ₆₀ | H | H |
| Lₐ₁₆₂₁ | Rₙ₆₂ | Ar29 | H | H | H | H | Rₙ₆₀ | H | H |
| Lₐ₁₆₂₂ | Rₙ₆₄ | Ar29 | H | H | H | H | Rₙ₆₀ | H | H |
| Lₐ₁₆₂₃ | Rₙ₆₅ | Ar29 | H | H | H | H | Rₙ₆₀ | H | H |
| Lₐ₁₆₂₄ | Rₙ₆₉ | Ar29 | H | H | H | H | Rₙ₆₀ | H | H |
| Lₐ₁₆₂₅ | Rₙ₇₀ | Ar29 | H | H | H | H | Rₙ₆₀ | H | H |
| Lₐ₁₆₂₆ | Rₙ₈₁ | Ar29 | H | H | H | H | Rₙ₆₀ | H | H |
| Lₐ₁₆₂₇ | Rₙ₁ | Ar29 | H | H | H | H | Rₙ₆₄ | H | H |
| Lₐ₁₆₂₈ | Rₙ₄ | Ar29 | H | H | H | H | Rₙ₆₄ | H | H |
| Lₐ₁₆₂₉ | Rₙ₅ | Ar29 | H | H | H | H | Rₙ₆₄ | H | H |
| Lₐ₁₆₃₀ | Rₙ₇ | Ar29 | H | H | H | H | Rₙ₆₄ | H | H |
| Lₐ₁₆₃₁ | Rₙ₁₁ | Ar29 | H | H | H | H | Rₙ₆₄ | H | H |
| Lₐ₁₆₃₂ | Rₙ₂₀ | Ar29 | H | H | H | H | Rₙ₆₄ | H | H |
| Lₐ₁₆₃₃ | Rₙ₂₁ | Ar29 | H | H | H | H | Rₙ₆₄ | H | H |
| Lₐ₁₆₃₄ | Rₙ₅₁ | Ar29 | H | H | H | H | Rₙ₆₄ | H | H |
| Lₐ₁₆₃₅ | Rₙ₅₆ | Ar29 | H | H | H | H | Rₙ₆₄ | H | H |
| Lₐ₁₆₃₆ | Rₙ₅₉ | Ar29 | H | H | H | H | Rₙ₆₄ | H | H |
| Lₐ₁₆₃₇ | Rₙ₆₀ | Ar29 | H | H | H | H | Rₙ₆₄ | H | H |
| Lₐ₁₆₃₈ | Rₙ₆₁ | Ar29 | H | H | H | H | Rₙ₆₄ | H | H |
| Lₐ₁₆₃₉ | Rₙ₆₂ | Ar29 | H | H | H | H | Rₙ₆₄ | H | H |
| Lₐ₁₆₄₀ | Rₙ₆₄ | Ar29 | H | H | H | H | Rₙ₆₄ | H | H |
| Lₐ₁₆₄₁ | Rₙ₆₅ | Ar29 | H | H | H | H | Rₙ₆₄ | H | H |
| Lₐ₁₆₄₂ | Rₙ₆₉ | Ar29 | H | H | H | H | Rₙ₆₄ | H | H |
| Lₐ₁₆₄₃ | Rₙ₇₀ | Ar29 | H | H | H | H | Rₙ₆₄ | H | H |
| Lₐ₁₆₄₄ | Rₙ₈₁ | Ar29 | H | H | H | H | Rₙ₆₄ | H | H |
| Lₐ₁₆₄₅ | Rₙ₁ | Ar29 | H | H | H | H | Me | H | H |
| Lₐ₁₆₄₆ | Rₙ₄ | Ar29 | H | H | H | H | Me | H | H |
| Lₐ₁₆₄₇ | Rₙ₅ | Ar29 | H | H | H | H | Me | H | H |
| Lₐ₁₆₄₈ | Rₙ₇ | Ar29 | H | H | H | H | Me | H | H |
| Lₐ₁₆₄₉ | Rₙ₁₁ | Ar29 | H | H | H | H | Me | H | H |
| Lₐ₁₆₅₀ | Rₙ₂₀ | Ar29 | H | H | H | H | Me | H | H |
| Lₐ₁₆₅₁ | Rₙ₂₁ | Ar29 | H | H | H | H | Me | H | H |
| Lₐ₁₆₅₂ | Rₙ₅₁ | Ar29 | H | H | H | H | Me | H | H |
| Lₐ₁₆₅₃ | Rₙ₅₆ | Ar29 | H | H | H | H | Me | H | H |
| Lₐ₁₆₅₄ | Rₙ₅₉ | Ar29 | H | H | H | H | Me | H | H |
| Lₐ₁₆₅₅ | Rₙ₆₀ | Ar29 | H | H | H | H | Me | H | H |
| Lₐ₁₆₅₆ | Rₙ₆₁ | Ar29 | H | H | H | H | Me | H | H |
| Lₐ₁₆₅₇ | Rₙ₆₂ | Ar29 | H | H | H | H | Me | H | H |
| Lₐ₁₆₅₈ | Rₙ₆₄ | Ar29 | H | H | H | H | Me | H | H |
| Lₐ₁₆₅₉ | Rₙ₆₅ | Ar29 | H | H | H | H | Me | H | H |
| Lₐ₁₆₆₀ | Rₙ₆₉ | Ar29 | H | H | H | H | Me | H | H |
| Lₐ₁₆₆₁ | Rₙ₇₀ | Ar29 | H | H | H | H | Me | H | H |
| Lₐ₁₆₆₂ | Rₙ₈₁ | Ar29 | H | H | H | H | Me | H | H |
| Lₐ₁₆₆₃ | Rₙ₁ | Ar29 | H | H | F | H | H | H | H |
| Lₐ₁₆₆₄ | Rₙ₄ | Ar29 | H | D | F | H | H | H | H |
| Lₐ₁₆₆₅ | Rₙ₇ | Ar29 | H | H | F | H | H | H | H |
| Lₐ₁₆₆₆ | Rₙ₂₀ | Ar29 | H | H | F | H | H | H | H |
| Lₐ₁₆₆₇ | Rₙ₂₁ | Ar29 | H | H | F | H | H | H | H |
| Lₐ₁₆₆₈ | Rₙ₅₆ | Ar29 | D | H | F | H | H | H | H |
| Lₐ₁₆₆₉ | Rₙ₅₉ | Ar29 | H | H | F | H | H | H | H |
| Lₐ₁₆₇₀ | Rₙ₆₁ | Ar29 | H | H | F | H | H | H | H |
| Lₐ₁₆₇₁ | Rₙ₆₂ | Ar29 | H | H | F | H | H | H | H |
| Lₐ₁₆₇₂ | Rₙ₆₄ | Ar29 | H | H | F | H | H | H | H |
| Lₐ₁₆₇₃ | Rₙ₆₉ | Ar29 | H | H | F | H | H | H | H |
| Lₐ₁₆₇₄ | Rₙ₇₀ | Ar29 | H | H | F | H | H | H | H |
| Lₐ₁₆₇₅ | Rₙ₁ | Ar29 | H | H | F | H | Rₙ₁₁ | H | H |
| Lₐ₁₆₇₆ | Rₙ₄ | Ar29 | H | H | F | H | Rₙ₁₁ | H | H |
| Lₐ₁₆₇₇ | Rₙ₇ | Ar29 | H | H | F | H | Rₙ₁₁ | H | H |
| Lₐ₁₆₇₈ | Rₙ₂₀ | Ar29 | H | H | F | H | Rₙ₁₁ | H | H |
| Lₐ₁₆₇₉ | Rₙ₂₁ | Ar29 | H | H | F | H | Rₙ₁₁ | H | H |
| Lₐ₁₆₈₀ | Rₙ₅₆ | Ar29 | H | H | F | H | Rₙ₁₁ | H | H |
| Lₐ₁₆₈₁ | Rₙ₅₉ | Ar29 | H | H | F | H | Rₙ₁₁ | H | H |
| Lₐ₁₆₈₂ | Rₙ₆₁ | Ar29 | H | H | F | H | Rₙ₁₁ | H | H |
| Lₐ₁₆₈₃ | Rₙ₆₂ | Ar29 | H | H | F | H | Rₙ₁₁ | H | H |
| Lₐ₁₆₈₄ | Rₙ₆₄ | Ar29 | H | H | F | H | Rₙ₁₁ | H | H |
| Lₐ₁₆₈₅ | Rₙ₆₉ | Ar29 | H | H | F | H | Rₙ₁₁ | H | H |
| Lₐ₁₆₈₆ | Rₙ₇₀ | Ar29 | H | H | F | H | Rₙ₁₁ | H | H |
| Lₐ₁₆₈₇ | Rₙ₁ | Ar29 | H | H | F | H | Rₙ₆₀ | H | H |
| Lₐ₁₆₈₈ | Rₙ₄ | Ar29 | H | H | F | H | Rₙ₆₀ | H | H |
| Lₐ₁₆₈₉ | Rₙ₇ | Ar29 | H | H | F | H | Rₙ₆₀ | H | H |
| Lₐ₁₆₉₀ | Rₙ₂₀ | Ar29 | H | H | F | H | Rₙ₆₀ | H | H |
| Lₐ₁₆₉₁ | Rₙ₂₁ | Ar29 | H | H | F | H | Rₙ₆₀ | H | H |
| Lₐ₁₆₉₂ | Rₙ₅₆ | Ar29 | H | H | F | H | Rₙ₆₀ | H | H |
| Lₐ₁₆₉₃ | Rₙ₅₉ | Ar29 | H | H | F | H | Rₙ₆₀ | H | H |
| Lₐ₁₆₉₄ | Rₙ₆₁ | Ar29 | H | H | F | H | Rₙ₆₀ | H | H |
| Lₐ₁₆₉₅ | Rₙ₆₂ | Ar29 | H | H | F | H | Rₙ₆₀ | H | H |
| Lₐ₁₆₉₆ | Rₙ₆₄ | Ar29 | H | H | F | H | Rₙ₆₀ | H | H |
| Lₐ₁₆₉₇ | Rₙ₆₉ | Ar29 | H | H | F | H | Rₙ₆₀ | H | H |
| Lₐ₁₆₉₈ | Rₙ₇₀ | Ar29 | H | H | F | H | Rₙ₆₀ | H | H |
| Lₐ₁₆₉₉ | Rₙ₁ | Ar29 | H | H | F | H | H | Rₙ₁₁ | H |
| Lₐ₁₇₀₀ | Rₙ₄ | Ar29 | H | H | F | H | H | Rₙ₁₁ | H |
| Lₐ₁₇₀₁ | Rₙ₇ | Ar29 | H | H | F | H | H | Rₙ₁₁ | H |
| Lₐ₁₇₀₂ | Rₙ₂₀ | Ar29 | H | H | F | H | H | Rₙ₁₁ | H |
| Lₐ₁₇₀₃ | Rₙ₂₁ | Ar29 | H | H | F | H | H | Rₙ₁₁ | H |
| Lₐ₁₇₀₄ | Rₙ₅₆ | Ar29 | H | H | F | H | H | Rₙ₁₁ | H |
| Lₐ₁₇₀₅ | Rₙ₅₉ | Ar29 | H | H | F | H | H | Rₙ₁₁ | H |
| Lₐ₁₇₀₆ | Rₙ₆₁ | Ar29 | H | H | F | H | H | Rₙ₁₁ | H |
| Lₐ₁₇₀₇ | Rₙ₆₂ | Ar29 | H | H | F | H | H | Rₙ₁₁ | H |
| Lₐ₁₇₀₈ | Rₙ₆₄ | Ar29 | H | H | F | H | H | Rₙ₁₁ | H |
| Lₐ₁₇₀₉ | Rₙ₆₉ | Ar29 | H | H | F | H | H | Rₙ₁₁ | H |
| Lₐ₁₇₁₀ | Rₙ₇₀ | Ar29 | H | H | F | H | H | Rₙ₁₁ | H |
| Lₐ₁₇₁₁ | Rₙ₁ | Ar29 | H | H | F | H | H | Rₙ₆₀ | H |
| Lₐ₁₇₁₂ | Rₙ₄ | Ar29 | H | H | F | H | H | Rₙ₆₀ | H |
| Lₐ₁₇₁₃ | Rₙ₇ | Ar29 | H | H | F | H | H | Rₙ₆₀ | H |
| Lₐ₁₇₁₄ | Rₙ₂₀ | Ar29 | H | H | F | H | H | Rₙ₆₀ | H |
| Lₐ₁₇₁₅ | Rₙ₂₁ | Ar29 | H | H | F | H | H | Rₙ₆₀ | H |
| Lₐ₁₇₁₆ | Rₙ₅₆ | Ar29 | H | H | F | H | H | Rₙ₆₀ | H |
| Lₐ₁₇₁₇ | Rₙ₅₉ | Ar29 | H | H | F | H | H | Rₙ₆₀ | H |
| Lₐ₁₇₁₈ | Rₙ₆₁ | Ar29 | H | H | F | H | H | Rₙ₆₀ | H |
| Lₐ₁₇₁₉ | Rₙ₆₂ | Ar29 | H | H | F | H | H | Rₙ₆₀ | H |
| Lₐ₁₇₂₀ | Rₙ₆₄ | Ar29 | H | H | F | H | H | Rₙ₆₀ | H |
| Lₐ₁₇₂₁ | Rₙ₆₉ | Ar29 | H | H | F | H | H | Rₙ₆₀ | H |
| Lₐ₁₇₂₂ | Rₙ₇₀ | Ar29 | H | H | F | H | H | Rₙ₆₀ | H |
| Lₐ₁₇₂₃ | Rₙ₁ | Ar29 | H | H | CN | H | H | H | H |
| Lₐ₁₇₂₄ | Rₙ₄ | Ar29 | H | H | CN | H | H | H | H |
| Lₐ₁₇₂₅ | Rₙ₇ | Ar29 | H | H | CN | H | H | H | H |
| Lₐ₁₇₂₆ | Rₙ₂₀ | Ar29 | H | H | CN | H | H | H | H |
| Lₐ₁₇₂₇ | Rₙ₂₁ | Ar29 | D | H | CN | H | H | H | H |
| Lₐ₁₇₂₈ | Rₙ₅₆ | Ar29 | H | H | CN | H | H | H | H |
| Lₐ₁₇₂₉ | Rₙ₅₉ | Ar29 | H | H | CN | H | H | H | H |
| Lₐ₁₇₃₀ | Rₙ₆₁ | Ar29 | H | H | CN | H | H | H | H |
| Lₐ₁₇₃₁ | Rₙ₆₂ | Ar29 | H | H | CN | H | H | H | H |
| Lₐ₁₇₃₂ | Rₙ₆₄ | Ar29 | H | H | CN | H | H | H | H |
| Lₐ₁₇₃₃ | Rₙ₆₉ | Ar29 | H | H | CN | H | H | H | H |
| Lₐ₁₇₃₄ | Rₙ₇₀ | Ar29 | H | H | CN | H | H | H | H |
| Lₐ₁₇₃₅ | Rₙ₁ | Ar29 | H | CN | H | H | H | H | H |
| Lₐ₁₇₃₆ | Rₙ₄ | Ar29 | H | CN | H | H | H | H | H |
| Lₐ₁₇₃₇ | Rₙ₇ | Ar29 | H | CN | H | H | H | H | H |
| Lₐ₁₇₃₈ | Rₙ₂₀ | Ar29 | H | CN | H | H | H | H | H |
| Lₐ₁₇₃₉ | Rₙ₂₁ | Ar29 | H | CN | H | H | H | H | H |
| Lₐ₁₇₄₀ | Rₙ₅₆ | Ar29 | H | CN | H | H | H | H | H |
| Lₐ₁₇₄₁ | Rₙ₅₉ | Ar29 | H | CN | H | H | H | H | H |
| Lₐ₁₇₄₂ | Rₙ₆₁ | Ar29 | H | CN | H | H | H | H | H |
| Lₐ₁₇₄₃ | Rₙ₆₂ | Ar29 | H | CN | H | H | H | H | H |
| Lₐ₁₇₄₄ | Rₙ₆₄ | Ar29 | H | CN | H | H | H | H | H |
| Lₐ₁₇₄₅ | Rₙ₆₉ | Ar29 | D | CN | H | H | H | H | H |
| Lₐ₁₇₄₆ | Rₙ₇₀ | Ar29 | H | CN | H | H | H | H | H |
| Lₐ₁₇₄₇ | Rₙ₁ | Ar29 | CN | H | H | H | H | H | H |
| Lₐ₁₇₄₈ | Rₙ₄ | Ar29 | CN | H | H | H | H | H | H |
| Lₐ₁₇₄₉ | Rₙ₇ | Ar29 | CN | H | H | H | H | H | H |
| Lₐ₁₇₅₀ | Rₙ₂₀ | Ar29 | CN | H | H | H | H | H | H |
| Lₐ₁₇₅₁ | Rₙ₂₁ | Ar29 | CN | H | H | H | H | H | H |
| Lₐ₁₇₅₂ | Rₙ₅₆ | Ar29 | CN | H | H | H | H | H | H |
| Lₐ₁₇₅₃ | Rₙ₅₉ | Ar29 | CN | H | H | H | H | H | H |
| Lₐ₁₇₅₄ | Rₙ₆₁ | Ar29 | CN | H | H | H | H | H | H |
| Lₐ₁₇₅₅ | Rₙ₆₂ | Ar29 | CN | H | H | H | H | H | H |
| Lₐ₁₇₅₆ | Rₙ₆₄ | Ar29 | CN | H | H | H | H | H | H |
| Lₐ₁₇₅₇ | Rₙ₆₉ | Ar29 | CN | H | H | H | H | H | H |
| Lₐ₁₇₅₈ | Rₙ₇₀ | Ar29 | CN | H | H | H | H | H | H |
| Lₐ₁₇₅₉ | Rₙ₁ | Ar29 | H | H | CN | H | Rₙ₁₁ | H | H |
| Lₐ₁₇₆₀ | Rₙ₄ | Ar29 | H | H | CN | H | Rₙ₁₁ | H | H |
| Lₐ₁₇₆₁ | Rₙ₇ | Ar29 | H | H | CN | H | Rₙ₁₁ | H | H |
| Lₐ₁₇₆₂ | Rₙ₂₀ | Ar29 | H | H | CN | H | Rₙ₁₁ | H | H |
| Lₐ₁₇₆₃ | Rₙ₂₁ | Ar29 | H | H | CN | H | Rₙ₁₁ | H | H |
| Lₐ₁₇₆₄ | Rₙ₅₆ | Ar29 | H | H | CN | H | Rₙ₁₁ | H | H |
| Lₐ₁₇₆₅ | Rₙ₅₉ | Ar29 | H | D | CN | H | Rₙ₁₁ | H | H |
| Lₐ₁₇₆₆ | Rₙ₆₁ | Ar29 | H | H | CN | H | Rₙ₁₁ | H | H |
| Lₐ₁₇₆₇ | Rₙ₆₂ | Ar29 | H | H | CN | H | Rₙ₁₁ | H | H |
| Lₐ₁₇₆₈ | Rₙ₆₄ | Ar29 | H | H | CN | H | Rₙ₁₁ | H | H |
| Lₐ₁₇₆₉ | Rₙ₆₉ | Ar29 | H | H | CN | H | Rₙ₁₁ | H | H |
| Lₐ₁₇₇₀ | Rₙ₇₀ | Ar29 | H | H | CN | H | Rₙ₁₁ | H | H |
| Lₐ₁₇₇₁ | Rₙ₁ | Ar29 | H | H | CN | H | Rₙ₆₀ | D | H |
| Lₐ₁₇₇₂ | Rₙ₄ | Ar29 | H | H | CN | H | Rₙ₆₀ | H | H |
| Lₐ₁₇₇₃ | Rₙ₇ | Ar29 | H | H | CN | H | Rₙ₆₀ | H | H |
| Lₐ₁₇₇₄ | Rₙ₂₀ | Ar29 | H | H | CN | H | Rₙ₆₀ | H | H |
| Lₐ₁₇₇₅ | Rₙ₂₁ | Ar29 | H | H | CN | H | Rₙ₆₀ | H | H |
| Lₐ₁₇₇₆ | Rₙ₅₆ | Ar29 | H | H | CN | H | Rₙ₆₀ | H | D |
| Lₐ₁₇₇₇ | Rₙ₅₉ | Ar29 | H | H | CN | H | Rₙ₆₀ | H | H |
| Lₐ₁₇₇₈ | Rₙ₆₁ | Ar29 | H | H | CN | H | Rₙ₆₀ | H | H |
| Lₐ₁₇₇₉ | Rₙ₆₂ | Ar29 | H | H | CN | H | Rₙ₆₀ | H | H |
| Lₐ₁₇₈₀ | Rₙ₆₄ | Ar29 | H | H | CN | H | Rₙ₆₀ | H | H |
| Lₐ₁₇₈₁ | Rₙ₆₉ | Ar29 | H | H | CN | H | Rₙ₆₀ | H | H |
| Lₐ₁₇₈₂ | Rₙ₇₀ | Ar29 | H | H | CN | H | Rₙ₆₀ | H | H |
| Lₐ₁₇₈₃ | Rₙ₁ | Ar29 | H | H | CN | H | Rₙ₆₄ | H | H |
| Lₐ₁₇₈₄ | Rₙ₄ | Ar29 | H | H | CN | H | Rₙ₆₄ | H | H |
| Lₐ₁₇₈₅ | Rₙ₇ | Ar29 | H | H | CN | H | Rₙ₆₄ | H | H |
| Lₐ₁₇₈₆ | Rₙ₂₀ | Ar29 | H | H | CN | H | Rₙ₆₄ | H | H |
| Lₐ₁₇₈₇ | Rₙ₂₁ | Ar29 | H | H | CN | H | Rₙ₆₄ | H | H |
| Lₐ₁₇₈₈ | Rₙ₅₆ | Ar29 | H | H | CN | H | Rₙ₆₄ | H | H |
| Lₐ₁₇₈₉ | Rₙ₅₉ | Ar29 | H | H | CN | H | Rₙ₆₄ | H | H |
| Lₐ₁₇₉₀ | Rₙ₆₁ | Ar29 | H | H | CN | H | Rₙ₆₄ | H | H |
| Lₐ₁₇₉₁ | Rₙ₆₂ | Ar29 | H | H | CN | H | Rₙ₆₄ | H | H |
| Lₐ₁₇₉₂ | Rₙ₆₄ | Ar29 | H | H | CN | H | Rₙ₆₄ | H | H |
| Lₐ₁₇₉₃ | Rₙ₆₉ | Ar29 | H | H | CN | H | Rₙ₆₄ | H | H |
| Lₐ₁₇₉₄ | Rₙ₇₀ | Ar29 | H | H | CN | H | Rₙ₆₄ | H | H |
| Lₐ₁₇₉₅ | Rₙ₁ | Ar29 | H | H | CN | H | H | Rₙ₁₁ | H |
| Lₐ₁₇₉₆ | Rₙ₄ | Ar29 | H | H | CN | H | H | Rₙ₁₁ | H |
| Lₐ₁₇₉₇ | Rₙ₇ | Ar29 | H | H | CN | H | H | Rₙ₁₁ | H |
| Lₐ₁₇₉₈ | Rₙ₂₀ | Ar29 | H | H | CN | H | H | Rₙ₁₁ | H |
| Lₐ₁₇₉₉ | Rₙ₂₁ | Ar29 | H | H | CN | H | H | Rₙ₁₁ | H |
| Lₐ₁₈₀₀ | Rₙ₅₆ | Ar29 | H | H | CN | H | H | Rₙ₁₁ | H |
| Lₐ₁₈₀₁ | Rₙ₅₉ | Ar29 | H | H | CN | H | H | Rₙ₁₁ | H |
| Lₐ₁₈₀₂ | Rₙ₆₁ | Ar29 | H | H | CN | H | H | Rₙ₁₁ | H |
| Lₐ₁₈₀₃ | Rₙ₆₂ | Ar29 | H | H | CN | H | H | Rₙ₁₁ | H |
| Lₐ₁₈₀₄ | Rₙ₆₄ | Ar29 | H | H | CN | H | H | Rₙ₁₁ | H |
| Lₐ₁₈₀₅ | Rₙ₆₉ | Ar29 | H | H | CN | H | H | Rₙ₁₁ | H |
| Lₐ₁₈₀₆ | Rₙ₇₀ | Ar29 | H | H | CN | H | H | Rₙ₁₁ | H |
| Lₐ₁₈₀₇ | Rₙ₁ | Ar29 | H | H | CN | H | H | Rₙ₆₀ | H |
| Lₐ₁₈₀₈ | Rₙ₄ | Ar29 | H | H | CN | H | H | Rₙ₆₀ | H |
| Lₐ₁₈₀₉ | Rₙ₇ | Ar29 | H | H | CN | H | H | Rₙ₆₀ | H |
| Lₐ₁₈₁₀ | Rₙ₂₀ | Ar29 | H | H | CN | H | H | Rₙ₆₀ | H |
| Lₐ₁₈₁₁ | Rₙ₂₁ | Ar29 | H | H | CN | H | H | Rₙ₆₀ | H |
| Lₐ₁₈₁₂ | Rₙ₅₆ | Ar29 | H | H | CN | H | H | Rₙ₆₀ | H |
| Lₐ₁₈₁₃ | Rₙ₅₉ | Ar29 | H | H | CN | H | H | Rₙ₆₀ | H |
| Lₐ₁₈₁₄ | Rₙ₆₁ | Ar29 | H | H | CN | H | H | Rₙ₆₀ | H |
| Lₐ₁₈₁₅ | Rₙ₆₂ | Ar29 | H | H | CN | H | H | Rₙ₆₀ | H |
| Lₐ₁₈₁₆ | Rₙ₆₄ | Ar29 | H | H | CN | H | H | Rₙ₆₀ | H |
| Lₐ₁₈₁₇ | Rₙ₆₉ | Ar29 | H | H | CN | H | H | Rₙ₆₀ | H |
| Lₐ₁₈₁₈ | Rₙ₇₀ | Ar29 | H | H | CN | H | H | Rₙ₆₀ | H |
| Lₐ₁₈₁₉ | Rₙ₁ | Ar29 | H | H | CN | H | H | Rₙ₆₄ | H |
| Lₐ₁₈₂₀ | Rₙ₄ | Ar29 | H | H | CN | H | H | Rₙ₆₄ | H |
| Lₐ₁₈₂₁ | Rₙ₇ | Ar29 | H | H | CN | H | H | Rₙ₆₄ | H |
| Lₐ₁₈₂₂ | Rₙ₂₀ | Ar29 | H | H | CN | H | H | Rₙ₆₄ | H |
| Lₐ₁₈₂₃ | Rₙ₂₁ | Ar29 | H | H | CN | H | H | Rₙ₆₄ | H |
| Lₐ₁₈₂₄ | Rₙ₅₆ | Ar29 | H | H | CN | H | H | Rₙ₆₄ | H |
| Lₐ₁₈₂₅ | Rₙ₅₉ | Ar29 | H | H | CN | H | H | Rₙ₆₄ | H |
| Lₐ₁₈₂₆ | Rₙ₆₁ | Ar29 | H | H | CN | H | H | Rₙ₆₄ | H |
| Lₐ₁₈₂₇ | Rₙ₆₂ | Ar29 | H | H | CN | H | H | Rₙ₆₄ | H |
| Lₐ₁₈₂₈ | Rₙ₆₄ | Ar29 | H | H | CN | H | H | Rₙ₆₄ | H |
| Lₐ₁₈₂₉ | Rₙ₆₉ | Ar29 | H | H | CN | H | H | Rₙ₆₄ | H |
| Lₐ₁₈₃₀ | Rₙ₇₀ | Ar29 | H | H | CN | H | H | Rₙ₆₄ | H |
| Lₐ₁₈₃₁ | Rₙ₁ | Ar35 | H | H | H | H | H | H | H |
| Lₐ₁₈₃₂ | Rₙ₄ | Ar35 | H | H | H | H | H | H | H |
| Lₐ₁₈₃₃ | Rₙ₅ | Ar35 | H | H | H | H | H | H | H |
| Lₐ₁₈₃₄ | Rₙ₇ | Ar35 | H | H | H | H | H | H | H |
| Lₐ₁₈₃₅ | Rₙ₁₁ | Ar35 | H | H | H | H | H | H | H |
| Lₐ₁₈₃₆ | Rₙ₂₀ | Ar35 | H | H | H | H | H | H | H |
| Lₐ₁₈₃₇ | Rₙ₂₁ | Ar35 | H | H | H | H | H | H | H |
| Lₐ₁₈₃₈ | Rₙ₅₁ | Ar35 | H | H | H | H | H | H | H |
| Lₐ₁₈₃₉ | Rₙ₅₆ | Ar35 | H | H | H | H | H | H | H |
| Lₐ₁₈₄₀ | Rₙ₅₉ | Ar35 | H | H | H | H | H | H | H |
| Lₐ₁₈₄₁ | Rₙ₆₀ | Ar35 | H | H | H | H | H | H | H |
| Lₐ₁₈₄₂ | Rₙ₆₁ | Ar35 | H | H | H | H | H | H | H |
| Lₐ₁₈₄₃ | Rₙ₆₂ | Ar35 | H | H | H | H | H | H | H |
| Lₐ₁₈₄₄ | Rₙ₆₄ | Ar35 | H | H | H | H | H | H | H |
| Lₐ₁₈₄₅ | Rₙ₆₅ | Ar35 | H | H | H | H | H | H | H |
| Lₐ₁₈₄₆ | Rₙ₆₉ | Ar35 | H | H | H | H | H | H | H |
| Lₐ₁₈₄₇ | Rₙ₇₀ | Ar35 | H | H | H | H | H | H | H |
| Lₐ₁₈₄₈ | Rₙ₈₁ | Ar35 | H | H | H | H | H | H | H |
| Lₐ₁₈₄₉ | Rₙ₁ | Ar35 | H | H | H | H | H | Rₙ₁₁ | H |
| Lₐ₁₈₅₀ | Rₙ₄ | Ar35 | H | H | H | H | H | Rₙ₁₁ | H |
| Lₐ₁₈₅₁ | Rₙ₅ | Ar35 | H | H | H | H | H | Rₙ₁₁ | H |
| Lₐ₁₈₅₂ | Rₙ₇ | Ar35 | H | H | H | H | H | Rₙ₁₁ | H |
| Lₐ₁₈₅₃ | Rₙ₁₁ | Ar35 | H | H | H | H | H | Rₙ₁₁ | H |
| Lₐ₁₈₅₄ | Rₙ₂₀ | Ar35 | H | H | H | H | H | Rₙ₁₁ | H |
| Lₐ₁₈₅₅ | Rₙ₂₁ | Ar35 | H | H | H | H | H | Rₙ₁₁ | H |
| Lₐ₁₈₅₆ | Rₙ₅₁ | Ar35 | H | H | H | H | H | Rₙ₁₁ | H |
| Lₐ₁₈₅₇ | Rₙ₅₆ | Ar35 | H | H | H | H | H | Rₙ₁₁ | H |
| Lₐ₁₈₅₈ | Rₙ₅₉ | Ar35 | H | H | H | H | H | Rₙ₁₁ | H |
| Lₐ₁₈₅₉ | Rₙ₆₀ | Ar35 | H | H | H | H | H | Rₙ₁₁ | H |
| Lₐ₁₈₆₀ | Rₙ₆₁ | Ar35 | H | H | H | H | H | Rₙ₁₁ | H |
| Lₐ₁₈₆₁ | Rₙ₆₂ | Ar35 | H | H | H | H | H | Rₙ₁₁ | H |
| Lₐ₁₈₆₂ | Rₙ₆₄ | Ar35 | H | H | H | H | H | Rₙ₁₁ | H |
| Lₐ₁₈₆₃ | Rₙ₆₅ | Ar35 | H | H | H | H | H | Rₙ₁₁ | H |
| Lₐ₁₈₆₄ | Rₙ₆₉ | Ar35 | H | H | H | H | H | Rₙ₁₁ | H |
| Lₐ₁₈₆₅ | Rₙ₇₀ | Ar35 | H | H | H | H | H | Rₙ₁₁ | H |
| Lₐ₁₈₆₆ | Rₙ₈₁ | Ar35 | H | H | H | H | H | Rₙ₁₁ | H |
| Lₐ₁₈₆₇ | Rₙ₁ | Ar35 | H | H | H | H | H | Rₙ₅₉ | H |
| Lₐ₁₈₆₈ | Rₙ₄ | Ar35 | H | H | H | H | H | Rₙ₅₉ | H |
| Lₐ₁₈₆₉ | Rₙ₅ | Ar35 | H | H | H | H | H | Rₙ₅₉ | H |
| Lₐ₁₈₇₀ | Rₙ₇ | Ar35 | H | H | H | H | H | Rₙ₅₉ | H |
| Lₐ₁₈₇₁ | Rₙ₁₁ | Ar35 | H | H | H | H | H | Rₙ₅₉ | H |
| Lₐ₁₈₇₂ | Rₙ₂₀ | Ar35 | H | H | H | H | H | Rₙ₅₉ | H |
| Lₐ₁₈₇₃ | Rₙ₂₁ | Ar35 | H | H | H | H | H | Rₙ₅₉ | H |
| Lₐ₁₈₇₄ | Rₙ₅₁ | Ar35 | H | H | H | H | H | Rₙ₅₉ | H |
| Lₐ₁₈₇₅ | Rₙ₅₆ | Ar35 | H | H | H | H | H | Rₙ₅₉ | H |
| Lₐ₁₈₇₆ | Rₙ₅₉ | Ar35 | H | D | H | H | H | Rₙ₅₉ | H |
| Lₐ₁₈₇₇ | Rₙ₆₀ | Ar35 | H | H | H | H | H | Rₙ₅₉ | H |
| Lₐ₁₈₇₈ | Rₙ₆₁ | Ar35 | H | H | H | H | H | Rₙ₅₉ | H |
| Lₐ₁₈₇₉ | Rₙ₆₂ | Ar35 | H | H | H | H | H | Rₙ₅₉ | H |
| Lₐ₁₈₈₀ | Rₙ₆₄ | Ar35 | H | H | H | H | H | Rₙ₅₉ | H |
| Lₐ₁₈₈₁ | Rₙ₆₅ | Ar35 | H | H | H | H | H | Rₙ₅₉ | H |
| Lₐ₁₈₈₂ | Rₙ₆₉ | Ar35 | H | H | H | H | H | Rₙ₅₉ | H |
| Lₐ₁₈₈₃ | Rₙ₇₀ | Ar35 | H | H | H | H | H | Rₙ₅₉ | H |
| Lₐ₁₈₈₄ | Rₙ₈₁ | Ar35 | H | H | H | H | H | Rₙ₅₉ | H |
| Lₐ₁₈₈₅ | Rₙ₁ | Ar35 | H | H | H | H | H | Rₙ₆₀ | H |
| Lₐ₁₈₈₆ | Rₙ₄ | Ar35 | H | H | H | D | H | Rₙ₆₀ | H |
| Lₐ₁₈₈₇ | Rₙ₅ | Ar35 | D | H | H | H | H | Rₙ₆₀ | H |
| Lₐ₁₈₈₈ | Rₙ₇ | Ar35 | H | H | H | H | H | Rₙ₆₀ | H |
| Lₐ₁₈₈₉ | Rₙ₁₁ | Ar35 | H | H | H | H | H | Rₙ₆₀ | H |
| Lₐ₁₈₉₀ | Rₙ₂₀ | Ar35 | H | H | H | H | H | Rₙ₆₀ | H |
| Lₐ₁₈₉₁ | Rₙ₂₁ | Ar35 | H | H | H | H | H | Rₙ₆₀ | H |
| Lₐ₁₈₉₂ | Rₙ₅₁ | Ar35 | H | H | H | H | H | Rₙ₆₀ | H |
| Lₐ₁₈₉₃ | Rₙ₅₆ | Ar35 | H | H | H | H | H | Rₙ₆₀ | H |
| Lₐ₁₈₉₄ | Rₙ₅₉ | Ar35 | H | H | H | H | H | Rₙ₆₀ | H |
| Lₐ₁₈₉₅ | Rₙ₆₀ | Ar35 | H | H | H | H | H | Rₙ₆₀ | H |
| Lₐ₁₈₉₆ | Rₙ₆₁ | Ar35 | H | H | H | H | H | Rₙ₆₀ | H |
| Lₐ₁₈₉₇ | Rₙ₆₂ | Ar35 | H | H | H | H | H | Rₙ₆₀ | H |
| Lₐ₁₈₉₈ | Rₙ₆₄ | Ar35 | H | H | H | H | H | Rₙ₆₀ | H |
| Lₐ₁₈₉₉ | Rₙ₆₅ | Ar35 | H | H | H | H | H | Rₙ₆₀ | H |
| Lₐ₁₉₀₀ | Rₙ₆₉ | Ar35 | H | H | H | H | H | Rₙ₆₀ | H |
| Lₐ₁₉₀₁ | Rₙ₇₀ | Ar35 | H | H | H | H | H | Rₙ₆₀ | H |
| Lₐ₁₉₀₂ | Rₙ₈₁ | Ar35 | H | H | H | H | H | Rₙ₆₀ | H |
| Lₐ₁₉₀₃ | Rₙ₁ | Ar35 | H | H | H | H | H | Rₙ₆₄ | H |
| Lₐ₁₉₀₄ | Rₙ₄ | Ar35 | H | H | H | H | H | Rₙ₆₄ | H |
| Lₐ₁₉₀₅ | Rₙ₅ | Ar35 | H | H | H | H | H | Rₙ₆₄ | H |
| Lₐ₁₉₀₆ | Rₙ₇ | Ar35 | H | H | H | H | H | Rₙ₆₄ | H |
| Lₐ₁₉₀₇ | Rₙ₁₁ | Ar35 | H | H | H | H | H | Rₙ₆₄ | H |
| Lₐ₁₉₀₈ | Rₙ₂₀ | Ar35 | H | H | H | H | H | Rₙ₆₄ | H |
| Lₐ₁₉₀₉ | Rₙ₂₁ | Ar35 | H | H | H | H | H | Rₙ₆₄ | H |
| Lₐ₁₉₁₀ | Rₙ₅₁ | Ar35 | H | H | H | H | H | Rₙ₆₄ | H |
| Lₐ₁₉₁₁ | Rₙ₅₆ | Ar35 | H | H | H | H | H | Rₙ₆₄ | H |
| Lₐ₁₉₁₂ | Rₙ₅₉ | Ar35 | H | H | H | H | H | Rₙ₆₄ | H |
| Lₐ₁₉₁₃ | Rₙ₆₀ | Ar35 | H | H | H | H | H | Rₙ₆₄ | H |
| Lₐ₁₉₁₄ | Rₙ₆₁ | Ar35 | H | H | H | H | H | Rₙ₆₄ | H |
| Lₐ₁₉₁₅ | Rₙ₆₂ | Ar35 | H | H | H | H | H | Rₙ₆₄ | H |
| Lₐ₁₉₁₆ | Rₙ₆₄ | Ar35 | H | H | H | H | H | Rₙ₆₄ | H |
| Lₐ₁₉₁₇ | Rₙ₆₅ | Ar35 | H | H | H | H | H | Rₙ₆₄ | H |
| Lₐ₁₉₁₈ | Rₙ₆₉ | Ar35 | H | H | H | H | H | Rₙ₆₄ | H |
| Lₐ₁₉₁₉ | Rₙ₇₀ | Ar35 | H | H | H | H | H | Rₙ₆₄ | H |
| Lₐ₁₉₂₀ | Rₙ₈₁ | Ar35 | H | H | H | H | H | Rₙ₆₄ | H |
| Lₐ₁₉₂₁ | Rₙ₁ | Ar35 | H | H | H | H | H | Me | H |
| Lₐ₁₉₂₂ | Rₙ₄ | Ar35 | H | H | H | H | H | Me | H |
| Lₐ₁₉₂₃ | Rₙ₅ | Ar35 | H | H | H | H | H | Me | H |
| Lₐ₁₉₂₄ | Rₙ₇ | Ar35 | H | H | H | H | H | Me | H |
| Lₐ₁₉₂₅ | Rₙ₁₁ | Ar35 | H | H | H | H | H | Me | H |
| Lₐ₁₉₂₆ | Rₙ₂₀ | Ar35 | H | H | H | H | H | Me | H |
| Lₐ₁₉₂₇ | Rₙ₂₁ | Ar35 | H | H | H | H | H | Me | H |
| Lₐ₁₉₂₈ | Rₙ₅₁ | Ar35 | H | H | H | H | H | Me | H |
| Lₐ₁₉₂₉ | Rₙ₅₆ | Ar35 | H | H | H | H | H | Me | H |
| Lₐ₁₉₃₀ | Rₙ₅₉ | Ar35 | H | H | H | H | H | Me | H |
| Lₐ₁₉₃₁ | Rₙ₆₀ | Ar35 | H | H | H | H | H | Me | H |
| Lₐ₁₉₃₂ | Rₙ₆₁ | Ar35 | H | H | H | H | H | Me | H |
| Lₐ₁₉₃₃ | Rₙ₆₂ | Ar35 | H | H | H | H | H | Me | H |
| Lₐ₁₉₃₄ | Rₙ₆₄ | Ar35 | H | H | H | H | H | Me | H |
| Lₐ₁₉₃₅ | Rₙ₆₅ | Ar35 | H | H | H | H | H | Me | H |
| Lₐ₁₉₃₆ | Rₙ₆₉ | Ar35 | H | H | H | H | H | Me | H |
| Lₐ₁₉₃₇ | Rₙ₇₀ | Ar35 | H | H | H | H | H | Me | H |
| Lₐ₁₉₃₈ | Rₙ₈₁ | Ar35 | H | H | H | H | H | Me | H |
| Lₐ₁₉₃₉ | Rₙ₁ | Ar35 | H | H | H | H | Rₙ₁₁ | H | H |
| Lₐ₁₉₄₀ | Rₙ₄ | Ar35 | H | H | H | H | Rₙ₁₁ | H | H |
| Lₐ₁₉₄₁ | Rₙ₅ | Ar35 | H | H | H | H | Rₙ₁₁ | H | H |
| Lₐ₁₉₄₂ | Rₙ₇ | Ar35 | H | H | H | H | Rₙ₁₁ | H | H |
| Lₐ₁₉₄₃ | Rₙ₁₁ | Ar35 | H | H | H | H | Rₙ₁₁ | H | H |
| Lₐ₁₉₄₄ | Rₙ₂₀ | Ar35 | H | H | H | H | Rₙ₁₁ | H | H |
| Lₐ₁₉₄₅ | Rₙ₂₁ | Ar35 | H | H | H | H | Rₙ₁₁ | H | H |
| Lₐ₁₉₄₆ | Rₙ₅₁ | Ar35 | H | H | H | H | Rₙ₁₁ | H | H |
| Lₐ₁₉₄₇ | Rₙ₅₆ | Ar35 | H | H | H | H | Rₙ₁₁ | H | H |
| Lₐ₁₉₄₈ | Rₙ₅₉ | Ar35 | H | H | H | H | Rₙ₁₁ | H | H |
| Lₐ₁₉₄₉ | Rₙ₆₀ | Ar35 | H | H | H | H | Rₙ₁₁ | H | H |
| Lₐ₁₉₅₀ | Rₙ₆₁ | Ar35 | H | H | H | H | Rₙ₁₁ | H | H |
| Lₐ₁₉₅₁ | Rₙ₆₂ | Ar35 | H | H | H | H | Rₙ₁₁ | H | H |
| Lₐ₁₉₅₂ | Rₙ₆₄ | Ar35 | H | H | H | H | Rₙ₁₁ | H | H |
| Lₐ₁₉₅₃ | Rₙ₆₅ | Ar35 | H | H | H | H | Rₙ₁₁ | H | H |
| Lₐ₁₉₅₄ | Rₙ₆₉ | Ar35 | H | H | H | H | Rₙ₁₁ | H | H |
| Lₐ₁₉₅₅ | Rₙ₇₀ | Ar35 | H | H | H | H | Rₙ₁₁ | H | H |
| Lₐ₁₉₅₆ | Rₙ₈₁ | Ar35 | H | H | H | H | Rₙ₁₁ | H | H |
| Lₐ₁₉₅₇ | Rₙ₁ | Ar35 | H | H | H | H | Rₙ₅₉ | H | H |
| Lₐ₁₉₅₈ | Rₙ₄ | Ar35 | H | H | H | H | Rₙ₅₉ | H | H |
| Lₐ₁₉₅₉ | Rₙ₅ | Ar35 | H | H | H | H | Rₙ₅₉ | H | H |
| Lₐ₁₉₆₀ | Rₙ₇ | Ar35 | H | H | H | H | Rₙ₅₉ | H | H |
| Lₐ₁₉₆₁ | Rₙ₁₁ | Ar35 | H | H | H | H | Rₙ₅₉ | H | H |
| Lₐ₁₉₆₂ | Rₙ₂₀ | Ar35 | H | H | H | H | Rₙ₅₉ | H | H |
| Lₐ₁₉₆₃ | Rₙ₂₁ | Ar35 | H | H | H | H | Rₙ₅₉ | H | H |
| Lₐ₁₉₆₄ | Rₙ₅₁ | Ar35 | H | H | H | H | Rₙ₅₉ | H | H |
| Lₐ₁₉₆₅ | Rₙ₅₆ | Ar35 | H | H | H | H | Rₙ₅₉ | H | H |
| Lₐ₁₉₆₆ | Rₙ₅₉ | Ar35 | H | H | H | H | Rₙ₅₉ | H | H |
| Lₐ₁₉₆₇ | Rₙ₆₀ | Ar35 | H | H | H | H | Rₙ₅₉ | H | H |
| Lₐ₁₉₆₈ | Rₙ₆₁ | Ar35 | H | H | H | H | Rₙ₅₉ | H | H |
| Lₐ₁₉₆₉ | Rₙ₆₂ | Ar35 | H | H | H | H | Rₙ₅₉ | H | H |
| Lₐ₁₉₇₀ | Rₙ₆₄ | Ar35 | H | H | H | H | Rₙ₅₉ | H | H |
| Lₐ₁₉₇₁ | Rₙ₆₅ | Ar35 | H | H | H | H | Rₙ₅₉ | H | H |
| Lₐ₁₉₇₂ | Rₙ₆₉ | Ar35 | H | H | H | H | Rₙ₅₉ | H | H |
| Lₐ₁₉₇₃ | Rₙ₇₀ | Ar35 | H | H | H | H | Rₙ₅₉ | H | H |
| Lₐ₁₉₇₄ | Rₙ₈₁ | Ar35 | H | H | H | H | Rₙ₅₉ | H | H |
| Lₐ₁₉₇₅ | Rₙ₁ | Ar35 | H | H | H | H | Rₙ₆₀ | H | H |
| Lₐ₁₉₇₆ | Rₙ₄ | Ar35 | H | H | H | H | Rₙ₆₀ | H | H |
| Lₐ₁₉₇₇ | Rₙ₅ | Ar35 | H | H | H | H | Rₙ₆₀ | H | H |
| Lₐ₁₉₇₈ | Rₙ₇ | Ar35 | H | H | H | H | Rₙ₆₀ | H | H |
| Lₐ₁₉₇₉ | Rₙ₁₁ | Ar35 | H | H | H | H | Rₙ₆₀ | H | H |
| Lₐ₁₉₈₀ | Rₙ₂₀ | Ar35 | H | H | H | H | Rₙ₆₀ | H | H |
| Lₐ₁₉₈₁ | Rₙ₂₁ | Ar35 | H | H | H | H | Rₙ₆₀ | H | H |
| Lₐ₁₉₈₂ | Rₙ₅₁ | Ar35 | H | H | H | H | Rₙ₆₀ | H | H |
| Lₐ₁₉₈₃ | Rₙ₅₆ | Ar35 | H | H | H | H | Rₙ₆₀ | H | H |
| Lₐ₁₉₈₄ | Rₙ₅₉ | Ar35 | H | H | H | H | Rₙ₆₀ | H | H |
| Lₐ₁₉₈₅ | Rₙ₆₀ | Ar35 | H | H | H | H | Rₙ₆₀ | H | H |
| Lₐ₁₉₈₆ | Rₙ₆₁ | Ar35 | H | H | H | H | Rₙ₆₀ | H | H |
| Lₐ₁₉₈₇ | Rₙ₆₂ | Ar35 | H | H | H | H | Rₙ₆₀ | H | H |
| Lₐ₁₉₈₈ | Rₙ₆₄ | Ar35 | H | H | H | H | Rₙ₆₀ | H | H |
| Lₐ₁₉₈₉ | Rₙ₆₅ | Ar35 | H | H | H | H | Rₙ₆₀ | H | H |
| Lₐ₁₉₉₀ | Rₙ₆₉ | Ar35 | H | H | H | H | Rₙ₆₀ | H | H |
| Lₐ₁₉₉₁ | Rₙ₇₀ | Ar35 | H | H | H | H | Rₙ₆₀ | H | H |
| Lₐ₁₉₉₂ | Rₙ₈₁ | Ar35 | H | H | H | H | Rₙ₆₀ | H | H |
| Lₐ₁₉₉₃ | Rₙ₁ | Ar35 | H | H | H | H | Rₙ₆₄ | H | H |
| Lₐ₁₉₉₄ | Rₙ₄ | Ar35 | H | H | H | H | Rₙ₆₄ | H | H |
| Lₐ₁₉₉₅ | Rₙ₅ | Ar35 | H | H | H | H | Rₙ₆₄ | H | H |
| Lₐ₁₉₉₆ | Rₙ₇ | Ar35 | H | H | H | H | Rₙ₆₄ | H | H |
| Lₐ₁₉₉₇ | Rₙ₁₁ | Ar35 | H | H | H | H | Rₙ₆₄ | H | H |
| Lₐ₁₉₉₈ | Rₙ₂₀ | Ar35 | H | H | H | H | Rₙ₆₄ | H | H |
| Lₐ₁₉₉₉ | Rₙ₂₁ | Ar35 | H | H | H | H | Rₙ₆₄ | H | H |
| Lₐ₂₀₀₀ | Rₙ₅₁ | Ar35 | H | H | H | H | Rₙ₆₄ | H | H |
| Lₐ₂₀₀₁ | Rₙ₅₆ | Ar35 | H | H | H | H | Rₙ₆₄ | H | H |
| Lₐ₂₀₀₂ | Rₙ₅₉ | Ar35 | H | H | H | H | Rₙ₆₄ | H | H |
| Lₐ₂₀₀₃ | Rₙ₆₀ | Ar35 | H | H | H | H | Rₙ₆₄ | H | H |
| Lₐ₂₀₀₄ | Rₙ₆₁ | Ar35 | H | H | H | H | Rₙ₆₄ | H | H |
| Lₐ₂₀₀₅ | Rₙ₆₂ | Ar35 | H | H | H | H | Rₙ₆₄ | H | H |
| Lₐ₂₀₀₆ | Rₙ₆₄ | Ar35 | H | H | H | H | Rₙ₆₄ | H | H |
| Lₐ₂₀₀₇ | Rₙ₆₅ | Ar35 | H | H | H | H | Rₙ₆₄ | H | H |
| Lₐ₂₀₀₈ | Rₙ₆₉ | Ar35 | H | H | H | H | Rₙ₆₄ | H | H |
| Lₐ₂₀₀₉ | Rₙ₇₀ | Ar35 | H | H | H | H | Rₙ₆₄ | H | H |
| Lₐ₂₀₁₀ | Rₙ₈₁ | Ar35 | H | H | H | H | Rₙ₆₄ | H | H |
| Lₐ₂₀₁₁ | Rₙ₁ | Ar35 | H | H | H | H | Me | H | H |
| Lₐ₂₀₁₂ | Rₙ₄ | Ar35 | H | H | H | H | Me | H | H |
| Lₐ₂₀₁₃ | Rₙ₅ | Ar35 | H | H | H | H | Me | H | H |
| Lₐ₂₀₁₄ | Rₙ₇ | Ar35 | H | H | H | H | Me | H | H |
| Lₐ₂₀₁₅ | Rₙ₁₁ | Ar35 | H | H | H | H | Me | H | H |
| Lₐ₂₀₁₆ | Rₙ₂₀ | Ar35 | H | H | H | H | Me | H | H |
| Lₐ₂₀₁₇ | Rₙ₂₁ | Ar35 | H | H | H | H | Me | H | H |
| Lₐ₂₀₁₈ | Rₙ₅₁ | Ar35 | H | H | H | H | Me | H | H |
| Lₐ₂₀₁₉ | Rₙ₅₆ | Ar35 | H | H | H | H | Me | H | H |
| Lₐ₂₀₂₀ | Rₙ₅₉ | Ar35 | H | H | H | H | Me | H | H |
| Lₐ₂₀₂₁ | Rₙ₆₀ | Ar35 | H | H | H | H | Me | H | H |
| Lₐ₂₀₂₂ | Rₙ₆₁ | Ar35 | H | H | H | H | Me | H | H |
| Lₐ₂₀₂₃ | Rₙ₆₂ | Ar35 | H | H | H | H | Me | H | H |
| Lₐ₂₀₂₄ | Rₙ₆₄ | Ar35 | H | H | H | H | Me | H | H |
| Lₐ₂₀₂₅ | Rₙ₆₅ | Ar35 | H | H | H | H | Me | H | H |
| Lₐ₂₀₂₆ | Rₙ₆₉ | Ar35 | H | H | H | H | Me | H | H |
| Lₐ₂₀₂₇ | Rₙ₇₀ | Ar35 | H | H | H | H | Me | H | H |
| Lₐ₂₀₂₈ | Rₙ₈₁ | Ar35 | H | H | H | H | Me | H | H |
| Lₐ₂₀₂₉ | Rₙ₁ | Ar35 | H | H | F | H | H | H | H |
| Lₐ₂₀₃₀ | Rₙ₄ | Ar35 | H | H | F | H | H | H | H |
| Lₐ₂₀₃₁ | Rₙ₇ | Ar35 | H | H | F | H | H | H | H |
| Lₐ₂₀₃₂ | Rₙ₂₀ | Ar35 | H | H | F | H | H | H | H |
| Lₐ₂₀₃₃ | Rₙ₂₁ | Ar35 | H | H | F | H | H | H | H |
| Lₐ₂₀₃₄ | Rₙ₅₆ | Ar35 | H | H | F | H | H | H | H |
| Lₐ₂₀₃₅ | Rₙ₅₉ | Ar35 | H | H | F | H | H | H | H |
| Lₐ₂₀₃₆ | Rₙ₆₁ | Ar35 | H | H | F | H | H | H | H |
| Lₐ₂₀₃₇ | Rₙ₆₂ | Ar35 | H | H | F | H | H | H | H |
| Lₐ₂₀₃₈ | Rₙ₆₄ | Ar35 | H | H | F | H | H | H | H |
| Lₐ₂₀₃₉ | Rₙ₆₉ | Ar35 | H | H | F | H | H | H | H |
| Lₐ₂₀₄₀ | Rₙ₇₀ | Ar35 | H | H | F | H | H | H | H |
| Lₐ₂₀₄₁ | Rₙ₁ | Ar35 | H | H | F | H | Rₙ₁₁ | H | H |
| Lₐ₂₀₄₂ | Rₙ₄ | Ar35 | H | H | F | H | Rₙ₁₁ | H | H |
| Lₐ₂₀₄₃ | Rₙ₇ | Ar35 | H | H | F | H | Rₙ₁₁ | H | H |
| Lₐ₂₀₄₄ | Rₙ₂₀ | Ar35 | H | H | F | H | Rₙ₁₁ | H | H |
| Lₐ₂₀₄₅ | Rₙ₂₁ | Ar35 | H | H | F | H | Rₙ₁₁ | H | H |
| Lₐ₂₀₄₆ | Rₙ₅₆ | Ar35 | H | H | F | H | Rₙ₁₁ | H | H |
| Lₐ₂₀₄₇ | Rₙ₅₉ | Ar35 | H | H | F | H | Rₙ₁₁ | H | H |
| Lₐ₂₀₄₈ | Rₙ₆₁ | Ar35 | H | H | F | H | Rₙ₁₁ | H | H |
| Lₐ₂₀₄₉ | Rₙ₆₂ | Ar35 | H | H | F | H | Rₙ₁₁ | H | H |
| Lₐ₂₀₅₀ | Rₙ₆₄ | Ar35 | H | D | F | H | Rₙ₁₁ | H | H |
| Lₐ₂₀₅₁ | Rₙ₆₉ | Ar35 | H | H | F | H | Rₙ₁₁ | H | H |
| Lₐ₂₀₅₂ | Rₙ₇₀ | Ar35 | H | H | F | H | Rₙ₁₁ | H | H |
| Lₐ₂₀₅₃ | Rₙ₁ | Ar35 | H | H | F | H | Rₙ₆₀ | H | H |
| Lₐ₂₀₅₄ | Rₙ₄ | Ar35 | H | H | F | H | Rₙ₆₀ | H | H |
| Lₐ₂₀₅₅ | Rₙ₇ | Ar35 | H | H | F | H | Rₙ₆₀ | H | H |
| Lₐ₂₀₅₆ | Rₙ₂₀ | Ar35 | H | H | F | H | Rₙ₆₀ | H | D |
| Lₐ₂₀₅₇ | Rₙ₂₁ | Ar35 | H | H | F | H | Rₙ₆₀ | H | H |
| Lₐ₂₀₅₈ | Rₙ₅₆ | Ar35 | H | H | F | H | Rₙ₆₀ | H | H |
| Lₐ₂₀₅₉ | Rₙ₅₉ | Ar35 | H | H | F | H | Rₙ₆₀ | H | H |
| Lₐ₂₀₆₀ | Rₙ₆₁ | Ar35 | H | H | F | H | Rₙ₆₀ | H | H |
| Lₐ₂₀₆₁ | Rₙ₆₂ | Ar35 | H | H | F | H | Rₙ₆₀ | H | H |
| Lₐ₂₀₆₂ | Rₙ₆₄ | Ar35 | H | H | F | H | Rₙ₆₀ | H | H |
| Lₐ₂₀₆₃ | Rₙ₆₉ | Ar35 | H | H | F | H | Rₙ₆₀ | H | H |
| Lₐ₂₀₆₄ | Rₙ₇₀ | Ar35 | D | H | F | H | Rₙ₆₀ | H | H |
| Lₐ₂₀₆₅ | Rₙ₁ | Ar35 | H | H | F | H | H | Rₙ₁₁ | H |
| Lₐ₂₀₆₆ | Rₙ₄ | Ar35 | H | H | F | H | H | Rₙ₁₁ | H |
| Lₐ₂₀₆₇ | Rₙ₇ | Ar35 | H | H | F | H | H | Rₙ₁₁ | H |
| Lₐ₂₀₆₈ | Rₙ₂₀ | Ar35 | H | H | F | H | H | Rₙ₁₁ | H |
| Lₐ₂₀₆₉ | Rₙ₂₁ | Ar35 | H | H | F | H | H | Rₙ₁₁ | H |
| Lₐ₂₀₇₀ | Rₙ₅₆ | Ar35 | H | H | F | H | H | Rₙ₁₁ | H |
| Lₐ₂₀₇₁ | Rₙ₅₉ | Ar35 | H | H | F | H | H | Rₙ₁₁ | H |
| Lₐ₂₀₇₂ | Rₙ₆₁ | Ar35 | H | H | F | H | H | Rₙ₁₁ | H |
| Lₐ₂₀₇₃ | Rₙ₆₂ | Ar35 | H | H | F | H | H | Rₙ₁₁ | H |
| Lₐ₂₀₇₄ | Rₙ₆₄ | Ar35 | H | H | F | H | H | Rₙ₁₁ | H |
| Lₐ₂₀₇₅ | Rₙ₆₉ | Ar35 | H | H | F | H | H | Rₙ₁₁ | H |
| Lₐ₂₀₇₆ | Rₙ₇₀ | Ar35 | H | H | F | H | H | Rₙ₁₁ | H |
| Lₐ₂₀₇₇ | Rₙ₁ | Ar35 | H | H | F | H | H | Rₙ₆₀ | H |
| Lₐ₂₀₇₈ | Rₙ₄ | Ar35 | H | H | F | H | H | Rₙ₆₀ | H |
| Lₐ₂₀₇₉ | Rₙ₇ | Ar35 | H | H | F | H | H | Rₙ₆₀ | H |
| Lₐ₂₀₈₀ | Rₙ₂₀ | Ar35 | H | H | F | H | H | Rₙ₆₀ | H |
| Lₐ₂₀₈₁ | Rₙ₂₁ | Ar35 | H | H | F | H | H | Rₙ₆₀ | H |
| Lₐ₂₀₈₂ | Rₙ₅₆ | Ar35 | H | H | F | H | H | Rₙ₆₀ | H |
| Lₐ₂₀₈₃ | Rₙ₅₉ | Ar35 | H | H | F | H | H | Rₙ₆₀ | H |
| Lₐ₂₀₈₄ | Rₙ₆₁ | Ar35 | H | H | F | H | H | Rₙ₆₀ | H |
| Lₐ₂₀₈₅ | Rₙ₆₂ | Ar35 | H | H | F | H | H | Rₙ₆₀ | H |
| Lₐ₂₀₈₆ | Rₙ₆₄ | Ar35 | H | H | F | H | H | Rₙ₆₀ | H |
| Lₐ₂₀₈₇ | Rₙ₆₉ | Ar35 | H | H | F | H | H | Rₙ₆₀ | H |
| Lₐ₂₀₈₈ | Rₙ₇₀ | Ar35 | H | H | F | H | H | Rₙ₆₀ | H |
| Lₐ₂₀₈₉ | Rₙ₁ | Ar35 | H | H | CN | H | H | H | H |
| Lₐ₂₀₉₀ | Rₙ₄ | Ar35 | H | H | CN | H | H | H | H |
| Lₐ₂₀₉₁ | Rₙ₇ | Ar35 | H | H | CN | H | H | H | H |
| Lₐ₂₀₉₂ | Rₙ₂₀ | Ar35 | H | H | CN | H | H | H | H |
| Lₐ₂₀₉₃ | Rₙ₂₁ | Ar35 | H | H | CN | H | H | H | H |
| Lₐ₂₀₉₄ | Rₙ₅₆ | Ar35 | H | H | CN | H | H | H | H |
| Lₐ₂₀₉₅ | Rₙ₅₉ | Ar35 | H | H | CN | H | H | H | H |
| Lₐ₂₀₉₆ | Rₙ₆₁ | Ar35 | H | H | CN | H | H | H | H |
| Lₐ₂₀₉₇ | Rₙ₆₂ | Ar35 | H | H | CN | H | H | H | H |
| Lₐ₂₀₉₈ | Rₙ₆₄ | Ar35 | H | H | CN | H | H | H | H |
| Lₐ₂₀₉₉ | Rₙ₆₉ | Ar35 | H | H | CN | H | H | H | H |
| Lₐ₂₁₀₀ | Rₙ₇₀ | Ar35 | H | H | CN | H | H | H | H |
| Lₐ₂₁₀₁ | Rₙ₁ | Ar35 | H | CN | H | H | H | H | H |
| Lₐ₂₁₀₂ | Rₙ₄ | Ar35 | H | CN | H | H | H | H | H |
| Lₐ₂₁₀₃ | Rₙ₇ | Ar35 | H | CN | H | H | H | H | H |
| Lₐ₂₁₀₄ | Rₙ₂₀ | Ar35 | H | CN | H | H | H | H | H |
| Lₐ₂₁₀₅ | Rₙ₂₁ | Ar35 | H | CN | H | H | H | H | H |
| Lₐ₂₁₀₆ | Rₙ₅₆ | Ar35 | H | CN | H | H | H | H | H |
| Lₐ₂₁₀₇ | Rₙ₅₉ | Ar35 | H | CN | H | H | H | H | H |
| Lₐ₂₁₀₈ | Rₙ₆₁ | Ar35 | H | CN | H | H | H | H | H |
| Lₐ₂₁₀₉ | Rₙ₆₂ | Ar35 | H | CN | H | H | H | H | H |
| Lₐ₂₁₁₀ | Rₙ₆₄ | Ar35 | H | CN | H | H | H | H | H |
| Lₐ₂₁₁₁ | Rₙ₆₉ | Ar35 | H | CN | H | H | H | H | H |
| Lₐ₂₁₁₂ | Rₙ₇₀ | Ar35 | H | CN | H | H | H | H | H |
| Lₐ₂₁₁₃ | Rₙ₁ | Ar35 | CN | H | H | H | H | H | H |
| Lₐ₂₁₁₄ | Rₙ₄ | Ar35 | CN | H | H | H | H | H | H |
| Lₐ₂₁₁₅ | Rₙ₇ | Ar35 | CN | H | H | H | H | H | H |
| Lₐ₂₁₁₆ | Rₙ₂₀ | Ar35 | CN | H | H | H | H | H | H |
| Lₐ₂₁₁₇ | Rₙ₂₁ | Ar35 | CN | H | H | H | H | H | H |
| Lₐ₂₁₁₈ | Rₙ₅₆ | Ar35 | CN | H | H | H | H | H | H |
| Lₐ₂₁₁₉ | Rₙ₅₉ | Ar35 | CN | H | D | H | H | H | H |
| Lₐ₂₁₂₀ | Rₙ₆₁ | Ar35 | CN | H | H | H | H | H | H |
| Lₐ₂₁₂₁ | Rₙ₆₂ | Ar35 | CN | H | H | H | H | H | H |
| Lₐ₂₁₂₂ | Rₙ₆₄ | Ar35 | CN | H | H | H | H | H | H |
| Lₐ₂₁₂₃ | Rₙ₆₉ | Ar35 | CN | H | H | H | H | H | H |
| Lₐ₂₁₂₄ | Rₙ₇₀ | Ar35 | CN | H | H | H | H | H | H |
| Lₐ₂₁₂₅ | Rₙ₁ | Ar35 | H | D | CN | H | Rₙ₁₁ | H | H |
| Lₐ₂₁₂₆ | Rₙ₄ | Ar35 | H | H | CN | H | Rₙ₁₁ | H | H |
| Lₐ₂₁₂₇ | Rₙ₇ | Ar35 | H | H | CN | H | Rₙ₁₁ | H | H |
| Lₐ₂₁₂₈ | Rₙ₂₀ | Ar35 | H | H | CN | H | Rₙ₁₁ | H | H |
| Lₐ₂₁₂₉ | Rₙ₂₁ | Ar35 | H | H | CN | H | Rₙ₁₁ | H | H |
| Lₐ₂₁₃₀ | Rₙ₅₆ | Ar35 | H | H | CN | H | Rₙ₁₁ | H | H |
| Lₐ₂₁₃₁ | Rₙ₅₉ | Ar35 | H | H | CN | H | Rₙ₁₁ | H | H |
| Lₐ₂₁₃₂ | Rₙ₆₁ | Ar35 | H | H | CN | H | Rₙ₁₁ | H | H |
| Lₐ₂₁₃₃ | Rₙ₆₂ | Ar35 | H | H | CN | H | Rₙ₁₁ | H | H |
| Lₐ₂₁₃₄ | Rₙ₆₄ | Ar35 | H | H | CN | H | Rₙ₁₁ | H | H |
| Lₐ₂₁₃₅ | Rₙ₆₉ | Ar35 | H | H | CN | H | Rₙ₁₁ | H | H |
| Lₐ₂₁₃₆ | Rₙ₇₀ | Ar35 | H | H | CN | H | Rₙ₁₁ | H | H |
| Lₐ₂₁₃₇ | Rₙ₁ | Ar35 | H | H | CN | H | Rₙ₆₀ | H | H |
| Lₐ₂₁₃₈ | Rₙ₄ | Ar35 | H | H | CN | H | Rₙ₆₀ | H | H |
| Lₐ₂₁₃₉ | Rₙ₇ | Ar35 | H | H | CN | H | Rₙ₆₀ | H | H |
| Lₐ₂₁₄₀ | Rₙ₂₀ | Ar35 | H | H | CN | H | Rₙ₆₀ | H | H |
| Lₐ₂₁₄₁ | Rₙ₂₁ | Ar35 | H | H | CN | H | Rₙ₆₀ | H | H |
| Lₐ₂₁₄₂ | Rₙ₅₆ | Ar35 | H | H | CN | H | Rₙ₆₀ | H | H |
| Lₐ₂₁₄₃ | Rₙ₅₉ | Ar35 | H | H | CN | H | Rₙ₆₀ | H | H |
| Lₐ₂₁₄₄ | Rₙ₆₁ | Ar35 | H | H | CN | H | Rₙ₆₀ | H | H |
| Lₐ₂₁₄₅ | Rₙ₆₂ | Ar35 | H | H | CN | H | Rₙ₆₀ | H | H |
| Lₐ₂₁₄₆ | Rₙ₆₄ | Ar35 | H | H | CN | H | Rₙ₆₀ | H | H |
| Lₐ₂₁₄₇ | Rₙ₆₉ | Ar35 | H | H | CN | H | Rₙ₆₀ | H | H |
| Lₐ₂₁₄₈ | Rₙ₇₀ | Ar35 | H | H | CN | H | Rₙ₆₀ | H | H |
| Lₐ₂₁₄₉ | Rₙ₁ | Ar35 | H | H | CN | H | Rₙ₆₄ | H | H |
| Lₐ₂₁₅₀ | Rₙ₄ | Ar35 | H | H | CN | H | Rₙ₆₄ | H | H |
| Lₐ₂₁₅₁ | Rₙ₇ | Ar35 | H | H | CN | H | Rₙ₆₄ | H | H |
| Lₐ₂₁₅₂ | Rₙ₂₀ | Ar35 | H | H | CN | H | Rₙ₆₄ | H | H |
| Lₐ₂₁₅₃ | Rₙ₂₁ | Ar35 | H | H | CN | H | Rₙ₆₄ | H | H |
| Lₐ₂₁₅₄ | Rₙ₅₆ | Ar35 | H | H | CN | H | Rₙ₆₄ | H | H |
| Lₐ₂₁₅₅ | Rₙ₅₉ | Ar35 | H | H | CN | H | Rₙ₆₄ | H | H |
| Lₐ₂₁₅₆ | Rₙ₆₁ | Ar35 | H | H | CN | H | Rₙ₆₄ | H | H |
| Lₐ₂₁₅₇ | Rₙ₆₂ | Ar35 | H | H | CN | H | Rₙ₆₄ | H | H |
| Lₐ₂₁₅₈ | Rₙ₆₄ | Ar35 | H | H | CN | H | Rₙ₆₄ | H | H |
| Lₐ₂₁₅₉ | Rₙ₆₉ | Ar35 | H | H | CN | H | Rₙ₆₄ | H | H |
| Lₐ₂₁₆₀ | Rₙ₇₀ | Ar35 | H | H | CN | H | Rₙ₆₄ | H | H |
| Lₐ₂₁₆₁ | Rₙ₁ | Ar35 | H | H | CN | H | H | Rₙ₁₁ | H |
| Lₐ₂₁₆₂ | Rₙ₄ | Ar35 | H | H | CN | H | H | Rₙ₁₁ | H |
| Lₐ₂₁₆₃ | Rₙ₇ | Ar35 | H | H | CN | H | H | Rₙ₁₁ | H |
| Lₐ₂₁₆₄ | Rₙ₂₀ | Ar35 | H | H | CN | H | H | Rₙ₁₁ | H |
| Lₐ₂₁₆₅ | Rₙ₂₁ | Ar35 | H | H | CN | H | H | Rₙ₁₁ | H |
| Lₐ₂₁₆₆ | Rₙ₅₆ | Ar35 | H | H | CN | H | H | Rₙ₁₁ | H |
| Lₐ₂₁₆₇ | Rₙ₅₉ | Ar35 | H | H | CN | H | H | Rₙ₁₁ | H |
| Lₐ₂₁₆₈ | Rₙ₆₁ | Ar35 | H | H | CN | H | H | Rₙ₁₁ | H |
| Lₐ₂₁₆₉ | Rₙ₆₂ | Ar35 | H | H | CN | H | H | Rₙ₁₁ | H |
| Lₐ₂₁₇₀ | Rₙ₆₄ | Ar35 | H | H | CN | H | H | Rₙ₁₁ | H |
| Lₐ₂₁₇₁ | Rₙ₆₉ | Ar35 | H | H | CN | H | H | Rₙ₁₁ | H |
| Lₐ₂₁₇₂ | Rₙ₇₀ | Ar35 | H | H | CN | H | H | Rₙ₁₁ | H |
| Lₐ₂₁₇₃ | Rₙ₁ | Ar35 | H | H | CN | H | H | Rₙ₆₀ | H |
| Lₐ₂₁₇₄ | Rₙ₄ | Ar35 | H | H | CN | H | H | Rₙ₆₀ | H |
| Lₐ₂₁₇₅ | Rₙ₇ | Ar35 | H | H | CN | H | H | Rₙ₆₀ | H |
| Lₐ₂₁₇₆ | Rₙ₂₀ | Ar35 | H | H | CN | H | H | Rₙ₆₀ | H |
| Lₐ₂₁₇₇ | Rₙ₂₁ | Ar35 | H | H | CN | H | H | Rₙ₆₀ | H |
| Lₐ₂₁₇₈ | Rₙ₅₆ | Ar35 | H | H | CN | H | H | Rₙ₆₀ | H |
| Lₐ₂₁₇₉ | Rₙ₅₉ | Ar35 | H | H | CN | H | H | Rₙ₆₀ | D |
| Lₐ₂₁₈₀ | Rₙ₆₁ | Ar35 | H | H | CN | H | H | Rₙ₆₀ | H |
| Lₐ₂₁₈₁ | Rₙ₆₂ | Ar35 | H | H | CN | H | H | Rₙ₆₀ | H |
| Lₐ₂₁₈₂ | Rₙ₆₄ | Ar35 | H | H | CN | H | H | Rₙ₆₀ | H |
| Lₐ₂₁₈₃ | Rₙ₆₉ | Ar35 | H | H | CN | H | H | Rₙ₆₀ | H |
| Lₐ₂₁₈₄ | Rₙ₇₀ | Ar35 | H | D | CN | H | H | Rₙ₆₀ | H |
| Lₐ₂₁₈₅ | Rₙ₁ | Ar35 | H | H | CN | H | H | Rₙ₆₄ | H |
| Lₐ₂₁₈₆ | Rₙ₄ | Ar35 | H | H | CN | H | H | Rₙ₆₄ | H |
| Lₐ₂₁₈₇ | Rₙ₇ | Ar35 | H | H | CN | H | H | Rₙ₆₄ | H |
| Lₐ₂₁₈₈ | Rₙ₂₀ | Ar35 | H | H | CN | H | H | Rₙ₆₄ | H |
| Lₐ₂₁₈₉ | Rₙ₂₁ | Ar35 | D | H | CN | H | H | Rₙ₆₄ | H |
| Lₐ₂₁₉₀ | Rₙ₅₆ | Ar35 | H | H | CN | H | H | Rₙ₆₄ | H |
| Lₐ₂₁₉₁ | Rₙ₅₉ | Ar35 | H | H | CN | H | H | Rₙ₆ | H |
| Lₐ₂₁₉₂ | Rₙ₆₁ | Ar35 | H | H | CN | H | H | Rₙ₆₄ | H |
| Lₐ₂₁₉₃ | Rₙ₆₂ | Ar35 | H | H | CN | H | H | Rₙ₆₄ | H |
| Lₐ₂₁₉₄ | Rₙ₆₄ | Ar35 | H | H | CN | H | H | Rₙ₆₄ | H |
| Lₐ₂₁₉₅ | Rₙ₆₉ | Ar35 | H | H | CN | H | H | Rₙ₆₄ | H |
| Lₐ₂₁₉₆ | Rₙ₇₀ | Ar35 | H | H | CN | H | H | Rₙ₆₄ | H |
| Lₐ₂₁₉₇ | Rₙ₁ | Ar39 | H | H | H | H | H | H | H |
| Lₐ₂₁₉₈ | Rₙ₄ | Ar39 | H | H | H | H | H | H | H |
| Lₐ₂₁₉₉ | Rₙ₅ | Ar39 | H | H | H | H | H | H | H |
| Lₐ₂₂₀₀ | Rₙ₇ | Ar39 | H | H | H | H | H | H | H |
| Lₐ₂₂₀₁ | Rₙ₁₁ | Ar39 | H | H | H | H | H | H | H |
| Lₐ₂₂₀₂ | Rₙ₂₀ | Ar39 | H | H | H | H | H | H | H |
| Lₐ₂₂₀₃ | Rₙ₂₁ | Ar39 | H | H | H | H | H | H | H |
| Lₐ₂₂₀₄ | Rₙ₅₁ | Ar39 | H | H | H | H | H | H | H |
| Lₐ₂₂₀₅ | Rₙ₅₆ | Ar39 | H | H | H | H | H | H | H |
| Lₐ₂₂₀₆ | Rₙ₅₉ | Ar39 | H | H | H | H | H | H | H |
| Lₐ₂₂₀₇ | Rₙ₆₀ | Ar39 | H | H | H | H | H | H | H |
| Lₐ₂₂₀₈ | Rₙ₆₁ | Ar39 | H | H | H | H | H | H | H |
| Lₐ₂₂₀₉ | Rₙ₆₂ | Ar39 | H | H | H | H | H | H | H |
| Lₐ₂₂₁₀ | Rₙ₆₄ | Ar39 | H | H | H | H | H | H | H |
| Lₐ₂₂₁₁ | Rₙ₆₅ | Ar39 | H | H | H | H | H | H | H |
| Lₐ₂₂₁₂ | Rₙ₆₉ | Ar39 | H | H | H | H | H | H | H |
| Lₐ₂₂₁₃ | Rₙ₇₀ | Ar39 | H | H | H | H | H | H | H |
| Lₐ₂₂₁₄ | Rₙ₈₁ | Ar39 | H | H | H | H | H | H | H |
| Lₐ₂₂₁₅ | Rₙ₁ | Ar39 | H | H | H | H | H | Rₙ₁₁ | H |
| Lₐ₂₂₁₆ | Rₙ₄ | Ar39 | H | H | H | H | H | Rₙ₁₁ | H |
| Lₐ₂₂₁₇ | Rₙ₅ | Ar39 | H | H | H | H | H | Rₙ₁₁ | H |
| Lₐ₂₂₁₈ | Rₙ₇ | Ar39 | H | H | H | H | H | Rₙ₁₁ | H |
| Lₐ₂₂₁₉ | Rₙ₁₁ | Ar39 | H | H | H | H | H | Rₙ₁₁ | H |
| Lₐ₂₂₂₀ | Rₙ₂₀ | Ar39 | H | H | H | H | H | Rₙ₁₁ | H |
| Lₐ₂₂₂₁ | Rₙ₂₁ | Ar39 | H | H | H | H | H | Rₙ₁₁ | H |
| Lₐ₂₂₂₂ | Rₙ₅₁ | Ar39 | H | H | H | H | H | Rₙ₁₁ | H |
| Lₐ₂₂₂₃ | Rₙ₅₆ | Ar39 | H | H | H | H | H | Rₙ₁₁ | H |
| Lₐ₂₂₂₄ | Rₙ₅₉ | Ar39 | H | H | H | H | H | Rₙ₁₁ | H |
| Lₐ₂₂₂₅ | Rₙ₆₀ | Ar39 | H | H | H | H | H | Rₙ₁₁ | H |
| Lₐ₂₂₂₆ | Rₙ₆₁ | Ar39 | H | H | H | H | H | Rₙ₁₁ | H |
| Lₐ₂₂₂₇ | Rₙ₆₂ | Ar39 | H | H | H | H | H | Rₙ₁₁ | H |
| Lₐ₂₂₂₈ | Rₙ₆₄ | Ar39 | H | H | H | H | H | Rₙ₁₁ | H |
| Lₐ₂₂₂₉ | Rₙ₆₅ | Ar39 | H | H | H | H | H | Rₙ₁₁ | H |
| Lₐ₂₂₃₀ | Rₙ₆₉ | Ar39 | H | H | H | H | H | Rₙ₁₁ | H |
| Lₐ₂₂₃₁ | Rₙ₇₀ | Ar39 | H | H | H | H | H | Rₙ₁₁ | H |
| Lₐ₂₂₃₂ | Rₙ₈₁ | Ar39 | H | H | H | H | H | Rₙ₁₁ | H |
| Lₐ₂₂₃₃ | Rₙ₁ | Ar39 | H | H | H | H | H | Rₙ₅₉ | H |
| Lₐ₂₂₃₄ | Rₙ₄ | Ar39 | H | H | H | H | H | Rₙ₅₉ | H |
| Lₐ₂₂₃₅ | Rₙ₅ | Ar39 | H | H | H | H | H | Rₙ₅₉ | H |
| Lₐ₂₂₃₆ | Rₙ₇ | Ar39 | H | H | H | H | H | Rₙ₅₉ | H |
| Lₐ₂₂₃₇ | Rₙ₁₁ | Ar39 | H | H | H | H | H | Rₙ₅₉ | H |
| Lₐ₂₂₃₈ | Rₙ₂₀ | Ar39 | H | H | H | H | H | Rₙ₅₉ | H |
| Lₐ₂₂₃₉ | Rₙ₂₁ | Ar39 | H | H | H | H | H | Rₙ₅₉ | H |
| Lₐ₂₂₄₀ | Rₙ₅₁ | Ar39 | H | H | H | H | H | Rₙ₅₉ | H |
| Lₐ₂₂₄₁ | Rₙ₅₆ | Ar39 | H | H | H | H | H | Rₙ₅₉ | H |
| Lₐ₂₂₄₂ | Rₙ₅₉ | Ar39 | H | H | H | H | H | Rₙ₅₉ | H |
| Lₐ₂₂₄₃ | Rₙ₆₀ | Ar39 | H | H | H | H | H | Rₙ₅₉ | H |
| Lₐ₂₂₄₄ | Rₙ₆₁ | Ar39 | H | H | H | H | H | Rₙ₅₉ | H |
| Lₐ₂₂₄₅ | Rₙ₆₂ | Ar39 | H | H | H | H | H | Rₙ₅₉ | H |
| Lₐ₂₂₄₆ | Rₙ₆₄ | Ar39 | H | H | H | H | H | Rₙ₅₉ | H |
| Lₐ₂₂₄₇ | Rₙ₆₅ | Ar39 | H | H | H | H | H | Rₙ₅₉ | H |
| Lₐ₂₂₄₈ | Rₙ₆₉ | Ar39 | H | H | H | H | H | Rₙ₅₉ | H |
| Lₐ₂₂₄₉ | Rₙ₇₀ | Ar39 | H | H | H | H | H | Rₙ₅₉ | H |
| Lₐ₂₂₅₀ | Rₙ₈₁ | Ar39 | H | H | H | H | H | Rₙ₅₉ | H |
| Lₐ₂₂₅₁ | Rₙ₁ | Ar39 | H | H | H | H | H | Rₙ₆₀ | H |
| Lₐ₂₂₅₂ | Rₙ₄ | Ar39 | H | H | H | H | H | Rₙ₆₀ | H |
| Lₐ₂₂₅₃ | Rₙ₅ | Ar39 | H | H | H | H | H | Rₙ₆₀ | H |
| Lₐ₂₂₅₄ | Rₙ₇ | Ar39 | H | H | H | H | H | Rₙ₆₀ | H |
| Lₐ₂₂₅₅ | Rₙ₁₁ | Ar39 | H | H | H | H | H | Rₙ₆₀ | H |
| Lₐ₂₂₅₆ | Rₙ₂₀ | Ar39 | H | H | H | H | H | Rₙ₆₀ | H |
| Lₐ₂₂₅₇ | Rₙ₂₁ | Ar39 | H | H | H | H | H | Rₙ₆₀ | H |
| Lₐ₂₂₅₈ | Rₙ₅₁ | Ar39 | H | H | H | H | H | Rₙ₆₀ | H |
| Lₐ₂₂₅₉ | Rₙ₅₆ | Ar39 | H | H | H | H | H | Rₙ₆₀ | H |
| Lₐ₂₂₆₀ | Rₙ₅₉ | Ar39 | H | H | H | H | H | Rₙ₆₀ | H |
| Lₐ₂₂₆₁ | Rₙ₆₀ | Ar39 | H | H | H | H | H | Rₙ₆₀ | H |
| Lₐ₂₂₆₂ | Rₙ₆₁ | Ar39 | H | H | H | H | H | Rₙ₆₀ | H |
| Lₐ₂₂₆₃ | Rₙ₆₂ | Ar39 | H | H | H | H | H | Rₙ₆₀ | H |
| Lₐ₂₂₆₄ | Rₙ₆₄ | Ar39 | H | H | H | H | H | Rₙ₆₀ | H |
| Lₐ₂₂₆₅ | Rₙ₆₅ | Ar39 | H | H | H | H | H | Rₙ₆₀ | H |
| Lₐ₂₂₆₆ | Rₙ₆₉ | Ar39 | H | H | H | H | H | Rₙ₆₀ | H |
| Lₐ₂₂₆₇ | Rₙ₇₀ | Ar39 | H | H | H | H | H | Rₙ₆₀ | H |
| Lₐ₂₂₆₈ | Rₙ₈₁ | Ar39 | H | H | H | H | H | Rₙ₆₀ | H |
| Lₐ₂₂₆₉ | Rₙ₁ | Ar39 | H | H | H | H | H | Rₙ₆₄ | H |
| Lₐ₂₂₇₀ | Rₙ₄ | Ar39 | H | H | H | H | H | Rₙ₆₄ | H |
| Lₐ₂₂₇₁ | Rₙ₅ | Ar39 | H | H | H | H | H | Rₙ₆₄ | H |
| Lₐ₂₂₇₂ | Rₙ₇ | Ar39 | H | H | H | H | H | Rₙ₆₄ | H |
| Lₐ₂₂₇₃ | Rₙ₁₁ | Ar39 | H | H | H | H | H | Rₙ₆₄ | H |
| Lₐ₂₂₇₄ | Rₙ₂₀ | Ar39 | H | H | H | H | H | Rₙ₆₄ | H |
| Lₐ₂₂₇₅ | Rₙ₂₁ | Ar39 | H | H | H | H | H | Rₙ₆₄ | H |
| Lₐ₂₂₇₆ | Rₙ₅₁ | Ar39 | H | H | H | H | H | Rₙ₆₄ | H |
| Lₐ₂₂₇₇ | Rₙ₅₆ | Ar39 | H | H | H | H | H | Rₙ₆₄ | H |
| Lₐ₂₂₇₈ | Rₙ₅₉ | Ar39 | H | H | H | H | H | Rₙ₆₄ | H |
| Lₐ₂₂₇₉ | Rₙ₆₀ | Ar39 | H | H | H | H | H | Rₙ₆₄ | H |
| Lₐ₂₂₈₀ | Rₙ₆₁ | Ar39 | H | H | H | H | H | Rₙ₆₄ | H |
| Lₐ₂₂₈₁ | Rₙ₆₂ | Ar39 | H | H | H | H | H | Rₙ₆₄ | H |
| Lₐ₂₂₈₂ | Rₙ₆₄ | Ar39 | H | H | H | H | H | Rₙ₆₄ | H |
| Lₐ₂₂₈₃ | Rₙ₆₅ | Ar39 | H | H | H | H | H | Rₙ₆₄ | H |
| Lₐ₂₂₈₄ | Rₙ₆₉ | Ar39 | H | H | H | H | H | Rₙ₆₄ | H |
| Lₐ₂₂₈₅ | Rₙ₇₀ | Ar39 | H | H | H | H | H | Rₙ₆₄ | H |
| Lₐ₂₂₈₆ | Rₙ₈₁ | Ar39 | H | H | H | H | H | Rₙ₆₄ | H |
| Lₐ₂₂₈₇ | Rₙ₁ | Ar39 | H | H | H | H | H | Me | H |
| Lₐ₂₂₈₈ | Rₙ₄ | Ar39 | H | H | H | H | H | Me | H |
| Lₐ₂₂₈₉ | Rₙ₅ | Ar39 | H | H | H | H | H | Me | H |
| Lₐ₂₂₉₀ | Rₙ₇ | Ar39 | H | H | H | H | H | Me | H |
| Lₐ₂₂₉₁ | Rₙ₁₁ | Ar39 | H | H | H | H | H | Me | H |
| Lₐ₂₂₉₂ | Rₙ₂₀ | Ar39 | H | H | H | H | H | Me | H |
| Lₐ₂₂₉₃ | Rₙ₂₁ | Ar39 | H | H | H | H | H | Me | H |
| Lₐ₂₂₉₄ | Rₙ₅₁ | Ar39 | H | H | H | H | H | Me | H |
| Lₐ₂₂₉₅ | Rₙ₅₆ | Ar39 | H | H | H | H | H | Me | H |
| Lₐ₂₂₉₆ | Rₙ₅₉ | Ar39 | H | H | H | H | H | Me | H |
| Lₐ₂₂₉₇ | Rₙ₆₀ | Ar39 | H | H | H | H | H | Me | H |
| Lₐ₂₂₉₈ | Rₙ₆₁ | Ar39 | H | H | H | H | H | Me | H |
| Lₐ₂₂₉₉ | Rₙ₆₂ | Ar39 | H | H | H | H | H | Me | H |
| Lₐ₂₃₀₀ | Rₙ₆₄ | Ar39 | H | H | H | H | H | Me | H |
| Lₐ₂₃₀₁ | Rₙ₆₅ | Ar39 | H | H | H | H | H | Me | H |
| Lₐ₂₃₀₂ | Rₙ₆₉ | Ar39 | H | H | H | H | H | Me | H |
| Lₐ₂₃₀₃ | Rₙ₇₀ | Ar39 | H | H | H | H | H | Me | H |
| Lₐ₂₃₀₄ | Rₙ₈₁ | Ar39 | H | H | H | H | H | Me | H |
| Lₐ₂₃₀₅ | Rₙ₁ | Ar39 | H | H | H | H | Rₙ₁₁ | H | H |
| Lₐ₂₃₀₆ | Rₙ₄ | Ar39 | H | H | H | H | Rₙ₁₁ | H | H |
| Lₐ₂₃₀₇ | Rₙ₅ | Ar39 | H | H | H | H | Rₙ₁₁ | H | H |
| Lₐ₂₃₀₈ | Rₙ₇ | Ar39 | H | H | H | H | Rₙ₁₁ | H | H |
| Lₐ₂₃₀₉ | Rₙ₁₁ | Ar39 | H | H | H | H | Rₙ₁₁ | H | H |
| Lₐ₂₃₁₀ | Rₙ₂₀ | Ar39 | H | H | H | H | Rₙ₁₁ | H | H |
| Lₐ₂₃₁₁ | Rₙ₂₁ | Ar39 | H | H | H | H | Rₙ₁₁ | H | H |
| Lₐ₂₃₁₂ | Rₙ₅₁ | Ar39 | H | H | H | H | Rₙ₁₁ | H | H |
| Lₐ₂₃₁₃ | Rₙ₅₆ | Ar39 | H | H | H | H | Rₙ₁₁ | H | H |
| Lₐ₂₃₁₄ | Rₙ₅₉ | Ar39 | H | H | H | H | Rₙ₁₁ | H | H |
| Lₐ₂₃₁₅ | Rₙ₆₀ | Ar39 | H | H | H | H | Rₙ₁₁ | H | H |
| Lₐ₂₃₁₆ | Rₙ₆₁ | Ar39 | H | H | H | H | Rₙ₁₁ | H | H |
| Lₐ₂₃₁₇ | Rₙ₆₂ | Ar39 | H | H | H | H | Rₙ₁₁ | H | H |
| Lₐ₂₃₁₈ | Rₙ₆₄ | Ar39 | H | H | H | H | Rₙ₁₁ | H | H |
| Lₐ₂₃₁₉ | Rₙ₆₅ | Ar39 | H | H | H | H | Rₙ₁₁ | H | H |
| Lₐ₂₃₂₀ | Rₙ₆₉ | Ar39 | H | H | H | H | Rₙ₁₁ | H | H |
| Lₐ₂₃₂₁ | Rₙ₇₀ | Ar39 | H | H | H | H | Rₙ₁₁ | H | H |
| Lₐ₂₃₂₂ | Rₙ₈₁ | Ar39 | H | H | H | H | Rₙ₁₁ | H | H |
| Lₐ₂₃₂₃ | Rₙ₁ | Ar39 | H | H | H | H | Rₙ₅₉ | H | H |
| Lₐ₂₃₂₄ | Rₙ₄ | Ar39 | H | H | H | H | Rₙ₅₉ | H | H |
| Lₐ₂₃₂₅ | Rₙ₅ | Ar39 | H | H | H | H | Rₙ₅₉ | H | H |
| Lₐ₂₃₂₆ | Rₙ₇ | Ar39 | H | H | H | H | Rₙ₅₉ | H | H |
| Lₐ₂₃₂₇ | Rₙ₁₁ | Ar39 | H | H | H | H | Rₙ₅₉ | H | H |
| Lₐ₂₃₂₈ | Rₙ₂₀ | Ar39 | H | H | H | H | Rₙ₅₉ | H | H |
| Lₐ₂₃₂₉ | Rₙ₂₁ | Ar39 | H | H | H | H | Rₙ₅₉ | H | H |
| Lₐ₂₃₃₀ | Rₙ₅₁ | Ar39 | H | H | H | H | Rₙ₅₉ | H | H |
| Lₐ₂₃₃₁ | Rₙ₅₆ | Ar39 | H | H | H | H | Rₙ₅₉ | H | H |
| Lₐ₂₃₃₂ | Rₙ₅₉ | Ar39 | H | H | H | H | Rₙ₅₉ | H | H |
| Lₐ₂₃₃₃ | Rₙ₆₀ | Ar39 | H | H | H | H | Rₙ₅₉ | H | H |
| Lₐ₂₃₃₄ | Rₙ₆₁ | Ar39 | H | H | H | H | Rₙ₅₉ | H | H |
| Lₐ₂₃₃₅ | Rₙ₆₂ | Ar39 | H | H | H | H | Rₙ₅₉ | H | H |
| Lₐ₂₃₃₆ | Rₙ₆₄ | Ar39 | H | H | H | H | Rₙ₅₉ | H | H |
| Lₐ₂₃₃₇ | Rₙ₆₅ | Ar39 | H | H | H | H | Rₙ₅₉ | H | H |
| Lₐ₂₃₃₈ | Rₙ₆₉ | Ar39 | H | H | H | H | Rₙ₅₉ | H | H |
| Lₐ₂₃₃₉ | Rₙ₇₀ | Ar39 | H | H | H | H | Rₙ₅₉ | H | H |
| Lₐ₂₃₄₀ | Rₙ₈₁ | Ar39 | H | H | H | H | Rₙ₅₉ | H | H |
| Lₐ₂₃₄₁ | Rₙ₁ | Ar39 | H | H | H | H | Rₙ₆₀ | H | H |
| Lₐ₂₃₄₂ | Rₙ₄ | Ar39 | H | H | H | H | Rₙ₆₀ | H | H |
| Lₐ₂₃₄₃ | Rₙ₅ | Ar39 | H | H | H | H | Rₙ₆₀ | H | H |
| Lₐ₂₃₄₄ | Rₙ₇ | Ar39 | H | H | H | H | Rₙ₆₀ | H | H |
| Lₐ₂₃₄₅ | Rₙ₁₁ | Ar39 | H | H | H | H | Rₙ₆₀ | H | H |
| Lₐ₂₃₄₆ | Rₙ₂₀ | Ar39 | H | H | H | H | Rₙ₆₀ | H | H |
| Lₐ₂₃₄₇ | Rₙ₂₁ | Ar39 | H | H | H | H | Rₙ₆₀ | H | H |
| Lₐ₂₃₄₈ | Rₙ₅₁ | Ar39 | H | H | H | H | Rₙ₆₀ | H | H |
| Lₐ₂₃₄₉ | Rₙ₅₆ | Ar39 | H | H | H | H | Rₙ₆₀ | H | H |
| Lₐ₂₃₅₀ | Rₙ₅₉ | Ar39 | H | H | H | H | Rₙ₆₀ | H | H |
| Lₐ₂₃₅₁ | Rₙ₆₀ | Ar39 | H | H | H | H | Rₙ₆₀ | H | H |
| Lₐ₂₃₅₂ | Rₙ₆₁ | Ar39 | H | H | H | H | Rₙ₆₀ | H | H |
| Lₐ₂₃₅₃ | Rₙ₆₂ | Ar39 | H | H | H | H | Rₙ₆₀ | H | H |
| Lₐ₂₃₅₄ | Rₙ₆₄ | Ar39 | H | H | H | H | Rₙ₆₀ | H | H |
| Lₐ₂₃₅₅ | Rₙ₆₅ | Ar39 | H | H | H | H | Rₙ₆₀ | H | H |
| Lₐ₂₃₅₆ | Rₙ₆₉ | Ar39 | H | H | H | H | Rₙ₆₀ | H | H |
| Lₐ₂₃₅₇ | Rₙ₇₀ | Ar39 | H | H | H | H | Rₙ₆₀ | H | H |
| Lₐ₂₃₅₈ | Rₙ₈₁ | Ar39 | H | H | H | H | Rₙ₆₀ | H | H |
| Lₐ₂₃₅₉ | Rₙ₁ | Ar39 | H | H | H | H | Rₙ₆₄ | H | H |
| Lₐ₂₃₆₀ | Rₙ₄ | Ar39 | H | H | H | H | Rₙ₆₄ | H | H |
| Lₐ₂₃₆₁ | Rₙ₅ | Ar39 | H | H | H | H | Rₙ₆₄ | H | H |
| Lₐ₂₃₆₂ | Rₙ₇ | Ar39 | H | H | H | H | Rₙ₆₄ | H | H |
| Lₐ₂₃₆₃ | Rₙ₁₁ | Ar39 | H | H | H | H | Rₙ₆₄ | H | H |
| Lₐ₂₃₆₄ | Rₙ₂₀ | Ar39 | H | H | H | H | Rₙ₆₄ | H | H |
| Lₐ₂₃₆₅ | Rₙ₂₁ | Ar39 | H | H | H | H | Rₙ₆₄ | H | H |
| Lₐ₂₃₆₆ | Rₙ₅₁ | Ar39 | H | H | H | H | Rₙ₆₄ | H | H |
| Lₐ₂₃₆₇ | Rₙ₅₆ | Ar39 | H | H | H | H | Rₙ₆₄ | H | H |
| Lₐ₂₃₆₈ | Rₙ₅₉ | Ar39 | H | H | H | H | Rₙ₆₄ | H | H |
| Lₐ₂₃₆₉ | Rₙ₆₀ | Ar39 | H | H | H | H | Rₙ₆₄ | H | H |
| Lₐ₂₃₇₀ | Rₙ₆₁ | Ar39 | H | H | H | H | Rₙ₆₄ | H | H |
| Lₐ₂₃₇₁ | Rₙ₆₂ | Ar39 | H | H | H | H | Rₙ₆₄ | H | H |
| Lₐ₂₃₇₂ | Rₙ₆₄ | Ar39 | H | H | H | H | Rₙ₆₄ | H | H |
| Lₐ₂₃₇₃ | Rₙ₆₅ | Ar39 | H | H | H | H | Rₙ₆₄ | H | H |
| Lₐ₂₃₇₄ | Rₙ₆₉ | Ar39 | H | H | H | H | Rₙ₆₄ | H | H |
| Lₐ₂₃₇₅ | Rₙ₇₀ | Ar39 | H | H | H | H | Rₙ₆₄ | H | H |
| Lₐ₂₃₇₆ | Rₙ₈₁ | Ar39 | H | H | H | H | Rₙ₆₄ | H | H |
| Lₐ₂₃₇₇ | Rₙ₁ | Ar39 | H | H | H | H | Me | H | H |
| Lₐ₂₃₇₈ | Rₙ₄ | Ar39 | H | H | H | H | Me | H | H |
| Lₐ₂₃₇₉ | Rₙ₅ | Ar39 | H | H | H | H | Me | H | H |
| Lₐ₂₃₈₀ | Rₙ₇ | Ar39 | H | H | H | H | Me | H | H |
| Lₐ₂₃₈₁ | Rₙ₁₁ | Ar39 | H | H | H | H | Me | H | H |
| Lₐ₂₃₈₂ | Rₙ₂₀ | Ar39 | H | H | H | H | Me | H | H |
| Lₐ₂₃₈₃ | Rₙ₂₁ | Ar39 | H | H | H | H | Me | H | H |
| Lₐ₂₃₈₄ | Rₙ₅₁ | Ar39 | H | H | H | H | Me | H | H |
| Lₐ₂₃₈₅ | Rₙ₅₆ | Ar39 | H | H | H | H | Me | H | H |
| Lₐ₂₃₈₆ | Rₙ₅₉ | Ar39 | H | H | H | H | Me | H | H |
| Lₐ₂₃₈₇ | Rₙ₆₀ | Ar39 | H | H | H | H | Me | H | H |
| Lₐ₂₃₈₈ | Rₙ₆₁ | Ar39 | H | H | H | H | Me | H | H |
| Lₐ₂₃₈₉ | Rₙ₆₂ | Ar39 | H | H | H | H | Me | H | H |
| Lₐ₂₃₉₀ | Rₙ₆₄ | Ar39 | H | H | H | H | Me | H | H |
| Lₐ₂₃₉₁ | Rₙ₆₅ | Ar39 | H | H | H | H | Me | H | H |
| Lₐ₂₃₉₂ | Rₙ₆₉ | Ar39 | H | H | H | H | Me | H | H |
| Lₐ₂₃₉₃ | Rₙ₇₀ | Ar39 | H | H | H | H | Me | H | H |
| Lₐ₂₃₉₄ | Rₙ₈₁ | Ar39 | H | H | H | H | Me | H | H |
| Lₐ₂₃₉₅ | Rₙ₁ | Ar39 | H | H | F | H | H | H | D |
| Lₐ₂₃₉₆ | Rₙ₄ | Ar39 | H | H | F | H | H | H | H |
| Lₐ₂₃₉₇ | Rₙ₇ | Ar39 | D | H | F | H | H | H | H |
| Lₐ₂₃₉₈ | Rₙ₂₀ | Ar39 | H | H | F | H | H | H | H |
| Lₐ₂₃₉₉ | Rₙ₂₁ | Ar39 | H | H | F | H | H | H | H |
| Lₐ₂₄₀₀ | Rₙ₅₆ | Ar39 | H | H | F | H | H | H | H |
| Lₐ₂₄₀₁ | Rₙ₅₉ | Ar39 | H | H | F | H | H | H | H |
| Lₐ₂₄₀₂ | Rₙ₆₁ | Ar39 | H | H | F | H | H | H | H |
| Lₐ₂₄₀₃ | Rₙ₆₂ | Ar39 | H | D | F | H | H | H | H |
| Lₐ₂₄₀₄ | Rₙ₆₄ | Ar39 | H | H | F | H | H | H | H |
| Lₐ₂₄₀₅ | Rₙ₆₉ | Ar39 | H | H | F | H | H | H | H |
| Lₐ₂₄₀₆ | Rₙ₇₀ | Ar39 | H | H | F | H | H | H | H |
| Lₐ₂₄₀₇ | Rₙ₁ | Ar39 | H | H | F | H | Rₙ₁₁ | H | H |
| Lₐ₂₄₀₈ | Rₙ₄ | Ar39 | H | H | F | H | Rₙ₁₁ | H | H |
| Lₐ₂₄₀₉ | Rₙ₇ | Ar39 | H | H | F | H | Rₙ₁₁ | H | H |
| Lₐ₂₄₁₀ | Rₙ₂₀ | Ar39 | H | H | F | H | Rₙ₁₁ | H | H |
| Lₐ₂₄₁₁ | Rₙ₂₁ | Ar39 | H | H | F | H | Rₙ₁₁ | H | H |
| Lₐ₂₄₁₂ | Rₙ₅₆ | Ar39 | H | H | F | H | Rₙ₁₁ | H | H |
| Lₐ₂₄₁₃ | Rₙ₅₉ | Ar39 | H | H | F | H | Rₙ₁₁ | H | H |
| Lₐ₂₄₁₄ | Rₙ₆₁ | Ar39 | H | H | F | H | Rₙ₁₁ | H | H |
| Lₐ₂₄₁₅ | Rₙ₆₂ | Ar39 | H | H | F | H | Rₙ₁₁ | H | H |
| Lₐ₂₄₁₆ | Rₙ₆₄ | Ar39 | H | H | F | H | Rₙ₁₁ | H | H |
| Lₐ₂₄₁₇ | Rₙ₆₉ | Ar39 | H | H | F | H | Rₙ₁₁ | H | H |
| Lₐ₂₄₁₈ | Rₙ₇₀ | Ar39 | H | H | F | H | Rₙ₁₁ | H | H |
| Lₐ₂₄₁₉ | Rₙ₁ | Ar39 | H | H | F | H | Rₙ₆₀ | H | H |
| Lₐ₂₄₂₀ | Rₙ₄ | Ar39 | H | H | F | H | Rₙ₆₀ | H | H |
| Lₐ₂₄₂₁ | Rₙ₇ | Ar39 | H | H | F | H | Rₙ₆₀ | H | H |
| Lₐ₂₄₂₂ | Rₙ₂₀ | Ar39 | H | H | F | H | Rₙ₆₀ | H | H |
| Lₐ₂₄₂₃ | Rₙ₂₁ | Ar39 | H | H | F | H | Rₙ₆₀ | H | H |
| Lₐ₂₄₂₄ | Rₙ₅₆ | Ar39 | H | H | F | H | Rₙ₆₀ | H | H |
| Lₐ₂₄₂₅ | Rₙ₅₉ | Ar39 | H | H | F | H | Rₙ₆₀ | H | H |
| Lₐ₂₄₂₆ | Rₙ₆₁ | Ar39 | H | H | F | H | Rₙ₆₀ | H | H |
| Lₐ₂₄₂₇ | Rₙ₆₂ | Ar39 | H | H | F | H | Rₙ₆₀ | H | H |
| Lₐ₂₄₂₈ | Rₙ₆₄ | Ar39 | H | H | F | H | Rₙ₆₀ | H | H |
| Lₐ₂₄₂₉ | Rₙ₆₉ | Ar39 | H | H | F | H | Rₙ₆₀ | H | H |
| Lₐ₂₄₃₀ | Rₙ₇₀ | Ar39 | H | H | F | H | Rₙ₆₀ | H | H |
| Lₐ₂₄₃₁ | Rₙ₁ | Ar39 | H | H | F | H | H | Rₙ₁₁ | H |
| Lₐ₂₄₃₂ | Rₙ₄ | Ar39 | H | H | F | H | H | Rₙ₁₁ | H |
| Lₐ₂₄₃₃ | Rₙ₇ | Ar39 | H | H | F | H | H | Rₙ₁₁ | H |
| Lₐ₂₄₃₄ | Rₙ₂₀ | Ar39 | H | H | F | H | H | Rₙ₁₁ | H |
| Lₐ₂₄₃₅ | Rₙ₂₁ | Ar39 | H | H | F | H | H | Rₙ₁₁ | H |
| Lₐ₂₄₃₆ | Rₙ₅₆ | Ar39 | H | H | F | H | H | Rₙ₁₁ | H |
| Lₐ₂₄₃₇ | Rₙ₅₉ | Ar39 | H | H | F | H | H | Rₙ₁₁ | H |
| Lₐ₂₄₃₈ | Rₙ₆₁ | Ar39 | H | H | F | H | H | Rₙ₁₁ | H |
| Lₐ₂₄₃₉ | Rₙ₆₂ | Ar39 | H | H | F | H | H | Rₙ₁₁ | H |
| Lₐ₂₄₄₀ | Rₙ₆₄ | Ar39 | H | H | F | H | H | Rₙ₁₁ | H |
| Lₐ₂₄₄₁ | Rₙ₆₉ | Ar39 | H | H | F | H | H | Rₙ₁₁ | H |
| Lₐ₂₄₄₂ | Rₙ₇₀ | Ar39 | H | H | F | H | H | Rₙ₁₁ | H |
| Lₐ₂₄₄₃ | Rₙ₁ | Ar39 | H | H | F | H | H | Rₙ₆₀ | H |
| Lₐ₂₄₄₄ | Rₙ₄ | Ar39 | H | H | F | H | H | Rₙ₆₀ | H |
| Lₐ₂₄₄₅ | Rₙ₇ | Ar39 | H | H | F | H | H | Rₙ₆₀ | H |
| Lₐ₂₄₄₆ | Rₙ₂₀ | Ar39 | H | H | F | H | H | Rₙ₆₀ | H |
| Lₐ₂₄₄₇ | Rₙ₂₁ | Ar39 | H | H | F | H | H | Rₙ₆₀ | H |
| Lₐ₂₄₄₈ | Rₙ₅₆ | Ar39 | H | H | F | H | H | Rₙ₆₀ | H |
| Lₐ₂₄₄₉ | Rₙ₅₉ | Ar39 | H | H | F | H | H | Rₙ₆₀ | H |
| Lₐ₂₄₅₀ | Rₙ₆₁ | Ar39 | H | H | F | H | H | Rₙ₆₀ | H |
| Lₐ₂₄₅₁ | Rₙ₆₂ | Ar39 | H | H | F | H | H | Rₙ₆₀ | H |
| Lₐ₂₄₅₂ | Rₙ₆₄ | Ar39 | H | H | F | H | H | Rₙ₆₀ | H |
| Lₐ₂₄₅₃ | Rₙ₆₉ | Ar39 | H | H | F | H | H | Rₙ₆₀ | H |
| Lₐ₂₄₅₄ | Rₙ₇₀ | Ar39 | H | H | F | H | H | Rₙ₆₀ | H |
| Lₐ₂₄₅₅ | Rₙ₁ | Ar39 | H | H | CN | H | H | H | H |
| Lₐ₂₄₅₆ | Rₙ₄ | Ar39 | H | H | CN | H | H | H | H |
| Lₐ₂₄₅₇ | Rₙ₇ | Ar39 | H | H | CN | H | H | H | H |
| Lₐ₂₄₅₈ | Rₙ₂₀ | Ar39 | H | H | CN | H | H | H | H |
| Lₐ₂₄₅₉ | Rₙ₂₁ | Ar39 | H | H | CN | H | H | H | H |
| Lₐ₂₄₆₀ | Rₙ₅₆ | Ar39 | H | H | CN | H | H | H | H |
| Lₐ₂₄₆₁ | Rₙ₅₉ | Ar39 | H | H | CN | H | H | H | H |
| Lₐ₂₄₆₂ | Rₙ₆₁ | Ar39 | H | H | CN | H | H | H | H |
| Lₐ₂₄₆₃ | Rₙ₆₂ | Ar39 | H | H | CN | H | H | H | H |
| Lₐ₂₄₆₄ | Rₙ₆₄ | Ar39 | H | H | CN | H | H | H | H |
| Lₐ₂₄₆₅ | Rₙ₆₉ | Ar39 | H | H | CN | H | H | H | H |
| Lₐ₂₄₆₆ | Rₙ₇₀ | Ar39 | H | H | CN | H | H | H | H |
| Lₐ₂₄₆₇ | Rₙ₁ | Ar39 | H | CN | H | H | H | H | H |
| Lₐ₂₄₆₈ | Rₙ₄ | Ar39 | H | CN | H | H | H | H | H |
| Lₐ₂₄₆₉ | Rₙ₇ | Ar39 | H | CN | H | H | H | H | H |
| Lₐ₂₄₇₀ | Rₙ₂₀ | Ar39 | H | CN | H | H | H | H | H |
| Lₐ₂₄₇₁ | Rₙ₂₁ | Ar39 | H | CN | H | H | H | H | H |
| Lₐ₂₄₇₂ | Rₙ₅₆ | Ar39 | H | CN | H | H | H | H | H |
| Lₐ₂₄₇₃ | Rₙ₅₉ | Ar39 | H | CN | H | H | H | H | H |
| Lₐ₂₄₇₄ | Rₙ₆₁ | Ar39 | H | CN | H | H | H | H | H |
| Lₐ₂₄₇₅ | Rₙ₆₂ | Ar39 | H | CN | H | H | H | H | H |
| Lₐ₂₄₇₆ | Rₙ₆₄ | Ar39 | H | CN | H | H | H | H | H |
| Lₐ₂₄₇₇ | Rₙ₆₉ | Ar39 | H | CN | H | H | H | H | H |
| Lₐ₂₄₇₈ | Rₙ₇₀ | Ar39 | H | CN | H | H | H | H | H |
| Lₐ₂₄₇₉ | Rₙ₁ | Ar39 | CN | H | H | H | H | H | H |
| Lₐ₂₄₈₀ | Rₙ₄ | Ar39 | CN | H | H | H | H | H | H |
| Lₐ₂₄₈₁ | Rₙ₇ | Ar39 | CN | H | H | H | H | H | H |
| Lₐ₂₄₈₂ | Rₙ₂₀ | Ar39 | CN | H | H | H | H | H | H |
| Lₐ₂₄₈₃ | Rₙ₂₁ | Ar39 | CN | H | H | H | H | H | H |
| Lₐ₂₄₈₄ | Rₙ₅₆ | Ar39 | CN | H | H | H | H | H | H |
| Lₐ₂₄₈₅ | Rₙ₅₉ | Ar39 | CN | H | H | H | H | H | H |
| Lₐ₂₄₈₆ | Rₙ₆₁ | Ar39 | CN | H | H | H | H | H | H |
| Lₐ₂₄₈₇ | Rₙ₆₂ | Ar39 | CN | H | H | H | H | H | H |
| Lₐ₂₄₈₈ | Rₙ₆₄ | Ar39 | CN | H | H | H | H | H | H |
| Lₐ₂₄₈₉ | Rₙ₆₉ | Ar39 | CN | H | H | H | H | H | H |
| Lₐ₂₄₉₀ | Rₙ₇₀ | Ar39 | CN | H | H | H | H | H | H |
| Lₐ₂₄₉₁ | Rₙ₁ | Ar39 | H | H | CN | H | Rₙ₁₁ | H | H |
| Lₐ₂₄₉₂ | Rₙ₄ | Ar39 | H | H | CN | H | Rₙ₁₁ | H | H |
| Lₐ₂₄₉₃ | Rₙ₇ | Ar39 | H | H | CN | H | Rₙ₁₁ | H | H |
| Lₐ₂₄₉₄ | Rₙ₂₀ | Ar39 | H | H | CN | H | Rₙ₁₁ | H | H |
| Lₐ₂₄₉₅ | Rₙ₂₁ | Ar39 | H | H | CN | H | Rₙ₁₁ | H | H |
| Lₐ₂₄₉₆ | Rₙ₅₆ | Ar39 | H | H | CN | H | Rₙ₁₁ | H | H |
| Lₐ₂₄₉₇ | Rₙ₅₉ | Ar39 | H | H | CN | H | Rₙ₁₁ | H | H |
| Lₐ₂₄₉₈ | Rₙ₆₁ | Ar39 | H | H | CN | H | Rₙ₁₁ | H | H |
| Lₐ₂₄₉₉ | Rₙ₆₂ | Ar39 | H | H | CN | H | Rₙ₁₁ | H | H |
| Lₐ₂₅₀₀ | Rₙ₆₄ | Ar39 | H | H | CN | H | Rₙ₁₁ | H | H |
| Lₐ₂₅₀₁ | Rₙ₆₉ | Ar39 | H | H | CN | H | Rₙ₁₁ | H | H |
| Lₐ₂₅₀₂ | Rₙ₇₀ | Ar39 | H | H | CN | H | Rₙ₁₁ | H | H |
| Lₐ₂₅₀₃ | Rₙ₁ | Ar39 | H | H | CN | H | Rₙ₆₀ | H | H |
| Lₐ₂₅₀₄ | Rₙ₄ | Ar39 | H | H | CN | H | Rₙ₆₀ | H | H |
| Lₐ₂₅₀₅ | Rₙ₇ | Ar39 | H | H | CN | H | Rₙ₆₀ | H | H |
| Lₐ₂₅₀₆ | Rₙ₂₀ | Ar39 | H | H | CN | H | Rₙ₆₀ | H | H |
| Lₐ₂₅₀₇ | Rₙ₂₁ | Ar39 | H | H | CN | H | Rₙ₆₀ | H | H |
| Lₐ₂₅₀₈ | Rₙ₅₆ | Ar39 | H | H | CN | H | Rₙ₆₀ | H | H |
| Lₐ₂₅₀₉ | Rₙ₅₉ | Ar39 | H | H | CN | H | Rₙ₆₀ | H | D |
| Lₐ₂₅₁₀ | Rₙ₆₁ | Ar39 | H | H | CN | H | Rₙ₆₀ | H | H |
| Lₐ₂₅₁₁ | Rₙ₆₂ | Ar39 | H | H | CN | H | Rₙ₆₀ | H | H |
| Lₐ₂₅₁₂ | Rₙ₆₄ | Ar39 | H | H | CN | H | Rₙ₆₀ | H | H |
| Lₐ₂₅₁₃ | Rₙ₆₉ | Ar39 | H | H | CN | H | Rₙ₆₀ | H | H |
| Lₐ₂₅₁₄ | Rₙ₇₀ | Ar39 | H | H | CN | H | Rₙ₆₀ | H | H |
| Lₐ₂₅₁₅ | Rₙ₁ | Ar39 | H | H | CN | H | Rₙ₆₄ | H | H |
| Lₐ₂₅₁₆ | Rₙ₄ | Ar39 | H | H | CN | H | Rₙ₆₄ | H | H |
| Lₐ₂₅₁₇ | Rₙ₇ | Ar39 | H | H | CN | H | Rₙ₆₄ | H | H |
| Lₐ₂₅₁₈ | Rₙ₂₀ | Ar39 | H | H | CN | H | Rₙ₆₄ | H | H |
| Lₐ₂₅₁₉ | Rₙ₂₁ | Ar39 | H | H | CN | H | Rₙ₆₄ | H | H |
| Lₐ₂₅₂₀ | Rₙ₅₆ | Ar39 | H | H | CN | H | Rₙ₆₄ | H | H |
| Lₐ₂₅₂₁ | Rₙ₅₉ | Ar39 | H | H | CN | H | Rₙ₆₄ | H | H |
| Lₐ₂₅₂₂ | Rₙ₆₁ | Ar39 | H | H | CN | H | Rₙ₆₄ | H | H |
| Lₐ₂₅₂₃ | Rₙ₆₂ | Ar39 | H | H | CN | H | Rₙ₆₄ | H | H |
| Lₐ₂₅₂₄ | Rₙ₆₄ | Ar39 | H | H | CN | H | Rₙ₆₄ | H | H |
| Lₐ₂₅₂₅ | Rₙ₆₉ | Ar39 | H | H | CN | H | Rₙ₆₄ | H | H |
| Lₐ₂₅₂₆ | Rₙ₇₀ | Ar39 | H | H | CN | H | Rₙ₆₄ | H | H |
| Lₐ₂₅₂₇ | Rₙ₁ | Ar39 | H | H | CN | H | H | Rₙ₁₁ | H |
| Lₐ₂₅₂₈ | Rₙ₄ | Ar39 | H | H | CN | H | H | Rₙ₁₁ | H |
| Lₐ₂₅₂₉ | Rₙ₇ | Ar39 | H | H | CN | H | H | Rₙ₁₁ | H |
| Lₐ₂₅₃₀ | Rₙ₂₀ | Ar39 | H | H | CN | H | H | Rₙ₁₁ | H |
| Lₐ₂₅₃₁ | Rₙ₂₁ | Ar39 | H | H | CN | H | H | Rₙ₁₁ | H |
| Lₐ₂₅₃₂ | Rₙ₅₆ | Ar39 | H | H | CN | H | H | Rₙ₁₁ | H |
| Lₐ₂₅₃₃ | Rₙ₅₉ | Ar39 | H | H | CN | H | H | Rₙ₁₁ | H |
| Lₐ₂₅₃₄ | Rₙ₆₁ | Ar39 | H | H | CN | H | H | Rₙ₁₁ | H |
| Lₐ₂₅₃₅ | Rₙ₆₂ | Ar39 | H | H | CN | H | H | Rₙ₁₁ | H |
| Lₐ₂₅₃₆ | Rₙ₆₄ | Ar39 | H | H | CN | H | H | Rₙ₁₁ | H |
| Lₐ₂₅₃₇ | Rₙ₆₉ | Ar39 | H | H | CN | H | H | Rₙ₁₁ | H |
| Lₐ₂₅₃₈ | Rₙ₇₀ | Ar39 | H | H | CN | H | H | Rₙ₁₁ | H |
| Lₐ₂₅₃₉ | Rₙ₁ | Ar39 | H | H | CN | H | H | Rₙ₆₀ | H |
| Lₐ₂₅₄₀ | Rₙ₄ | Ar39 | H | D | CN | H | H | Rₙ₆₀ | H |
| Lₐ₂₅₄₁ | Rₙ₇ | Ar39 | H | H | CN | H | H | Rₙ₆₀ | H |
| Lₐ₂₅₄₂ | Rₙ₂₀ | Ar39 | H | H | CN | H | H | Rₙ₆₀ | H |
| Lₐ₂₅₄₃ | Rₙ₂₁ | Ar39 | H | H | CN | H | H | Rₙ₆₀ | H |
| Lₐ₂₅₄₄ | Rₙ₅₆ | Ar39 | H | H | CN | H | H | Rₙ₆₀ | H |
| Lₐ₂₅₄₅ | Rₙ₅₉ | Ar39 | H | H | CN | H | H | Rₙ₆₀ | H |
| Lₐ₂₅₄₆ | Rₙ₆₁ | Ar39 | H | H | CN | H | H | Rₙ₆₀ | H |
| Lₐ₂₅₄₇ | Rₙ₆₂ | Ar39 | H | H | CN | H | H | Rₙ₆₀ | H |
| Lₐ₂₅₄₈ | Rₙ₆₄ | Ar39 | H | H | CN | H | H | Rₙ₆₀ | H |
| Lₐ₂₅₄₉ | Rₙ₆₉ | Ar39 | H | H | CN | H | H | Rₙ₆₀ | H |
| Lₐ₂₅₅₀ | Rₙ₇₀ | Ar39 | H | H | CN | H | H | Rₙ₆₀ | H |
| Lₐ₂₅₅₁ | Rₙ₁ | Ar39 | H | H | CN | H | H | Rₙ₆₄ | H |
| Lₐ₂₅₅₂ | Rₙ₄ | Ar39 | H | H | CN | H | H | Rₙ₆₄ | H |
| Lₐ₂₅₅₃ | Rₙ₇ | Ar39 | H | H | CN | H | H | Rₙ₆₄ | H |
| Lₐ₂₅₅₄ | Rₙ₂₀ | Ar39 | H | H | CN | H | H | Rₙ₆₄ | H |
| Lₐ₂₅₅₅ | Rₙ₂₁ | Ar39 | H | H | CN | H | H | Rₙ₆₄ | H |
| Lₐ₂₅₅₆ | Rₙ₅₆ | Ar39 | H | H | CN | H | H | Rₙ₆₄ | H |
| Lₐ₂₅₅₇ | Rₙ₅₉ | Ar39 | D | H | CN | H | H | Rₙ₆₄ | H |
| Lₐ₂₅₅₈ | Rₙ₆₁ | Ar39 | H | H | CN | H | H | Rₙ₆₄ | H |
| Lₐ₂₅₅₉ | Rₙ₆₂ | Ar39 | H | H | CN | H | H | Rₙ₆₄ | H |
| Lₐ₂₅₆₀ | Rₙ₆₄ | Ar39 | H | H | CN | H | H | Rₙ₆₄ | H |
| Lₐ₂₅₆₁ | Rₙ₆₉ | Ar39 | H | H | CN | H | H | Rₙ₆₄ | H |
| Lₐ₂₅₆₂ | Rₙ₇₀ | Ar39 | H | H | CN | H | H | Rₙ₆₄ | H |
| Lₐ₂₅₆₃ | Rₙ₁ | Ar41 | H | H | H | H | H | H | D |
| Lₐ₂₅₆₄ | Rₙ₄ | Ar41 | H | H | H | H | H | H | H |
| Lₐ₂₅₆₅ | Rₙ₅ | Ar41 | H | H | H | H | H | H | H |
| Lₐ₂₅₆₆ | Rₙ₇ | Ar41 | H | H | H | H | H | H | H |
| Lₐ₂₅₆₇ | Rₙ₁₁ | Ar41 | H | H | H | H | H | H | H |
| Lₐ₂₅₆₈ | Rₙ₂₀ | Ar41 | H | H | H | H | D | H | H |
| Lₐ₂₅₆₉ | Rₙ₂₁ | Ar41 | H | H | H | H | H | H | H |
| Lₐ₂₅₇₀ | Rₙ₅₁ | Ar41 | H | H | H | H | H | H | H |
| Lₐ₂₅₇₁ | Rₙ₅₆ | Ar41 | H | H | H | H | H | H | H |
| Lₐ₂₅₇₂ | Rₙ₅₉ | Ar41 | H | H | H | H | H | H | H |
| Lₐ₂₅₇₃ | Rₙ₆₀ | Ar41 | D | H | H | H | H | H | H |
| Lₐ₂₅₇₄ | Rₙ₆₁ | Ar41 | H | H | H | H | H | H | H |
| Lₐ₂₅₇₅ | Rₙ₆₂ | Ar41 | H | H | H | H | H | H | H |
| Lₐ₂₅₇₆ | Rₙ₆₄ | Ar41 | H | H | H | H | H | H | H |
| Lₐ₂₅₇₇ | Rₙ₆₅ | Ar41 | H | H | H | H | H | H | H |
| Lₐ₂₅₇₈ | Rₙ₆₉ | Ar41 | H | H | H | H | H | H | H |
| Lₐ₂₅₇₉ | Rₙ₇₀ | Ar41 | H | H | H | H | H | H | H |
| Lₐ₂₅₈₀ | Rₙ₈₁ | Ar41 | H | H | H | H | H | H | H |
| Lₐ₂₅₈₁ | Rₙ₁ | Ar41 | H | H | H | H | H | Rₙ₁₁ | H |
| Lₐ₂₅₈₂ | Rₙ₄ | Ar41 | H | H | H | H | H | Rₙ₁₁ | H |
| Lₐ₂₅₈₃ | Rₙ₅ | Ar41 | H | H | H | H | H | Rₙ₁₁ | H |
| Lₐ₂₅₈₄ | Rₙ₇ | Ar41 | H | H | H | H | H | Rₙ₁₁ | H |
| Lₐ₂₅₈₅ | Rₙ₁₁ | Ar41 | H | H | H | H | H | Rₙ₁₁ | H |
| Lₐ₂₅₈₆ | Rₙ₂₀ | Ar41 | H | H | H | H | H | Rₙ₁₁ | H |
| Lₐ₂₅₈₇ | Rₙ₂₁ | Ar41 | H | H | H | H | H | Rₙ₁₁ | H |
| Lₐ₂₅₈₈ | Rₙ₅₁ | Ar41 | H | H | H | H | H | Rₙ₁₁ | H |
| Lₐ₂₅₈₉ | Rₙ₅₆ | Ar41 | H | H | H | H | H | Rₙ₁₁ | H |
| Lₐ₂₅₉₀ | Rₙ₅₉ | Ar41 | H | H | H | H | H | Rₙ₁₁ | H |
| Lₐ₂₅₉₁ | Rₙ₆₀ | Ar41 | H | H | H | H | H | Rₙ₁₁ | H |
| Lₐ₂₅₉₂ | Rₙ₆₁ | Ar41 | H | H | H | H | H | Rₙ₁₁ | H |
| Lₐ₂₅₉₃ | Rₙ₆₂ | Ar41 | H | H | H | H | H | Rₙ₁₁ | H |
| Lₐ₂₅₉₄ | Rₙ₆₄ | Ar41 | H | H | H | H | H | Rₙ₁₁ | H |
| Lₐ₂₅₉₅ | Rₙ₆₅ | Ar41 | H | H | H | H | H | Rₙ₁₁ | H |
| Lₐ₂₅₉₆ | Rₙ₆₉ | Ar41 | H | H | H | H | H | Rₙ₁₁ | H |
| Lₐ₂₅₉₇ | Rₙ₇₀ | Ar41 | H | H | H | H | H | Rₙ₁₁ | H |
| Lₐ₂₅₉₈ | Rₙ₈₁ | Ar41 | H | H | H | H | H | Rₙ₁₁ | H |
| Lₐ₂₅₉₉ | Rₙ₁ | Ar41 | H | H | H | H | H | Rₙ₅₉ | H |
| Lₐ₂₆₀₀ | Rₙ₄ | Ar41 | H | H | H | H | H | Rₙ₅₉ | H |
| Lₐ₂₆₀₁ | Rₙ₅ | Ar41 | H | H | H | H | H | Rₙ₅₉ | H |
| Lₐ₂₆₀₂ | Rₙ₇ | Ar41 | H | H | H | H | H | Rₙ₅₉ | H |
| Lₐ₂₆₀₃ | Rₙ₁₁ | Ar41 | H | H | H | H | H | Rₙ₅₉ | H |
| Lₐ₂₆₀₄ | Rₙ₂₀ | Ar41 | H | H | H | H | H | Rₙ₅₉ | H |
| Lₐ₂₆₀₅ | Rₙ₂₁ | Ar41 | H | H | H | H | H | Rₙ₅₉ | H |
| Lₐ₂₆₀₆ | Rₙ₅₁ | Ar41 | H | H | H | H | H | Rₙ₅₉ | H |
| Lₐ₂₆₀₇ | Rₙ₅₆ | Ar41 | H | H | H | H | H | Rₙ₅₉ | H |
| Lₐ₂₆₀₈ | Rₙ₅₉ | Ar41 | H | H | H | H | H | Rₙ₅₉ | H |
| Lₐ₂₆₀₉ | Rₙ₆₀ | Ar41 | H | H | H | H | H | Rₙ₅₉ | H |
| Lₐ₂₆₁₀ | Rₙ₆₁ | Ar41 | H | H | H | H | H | Rₙ₅₉ | H |
| Lₐ₂₆₁₁ | Rₙ₆₂ | Ar41 | H | H | H | H | H | Rₙ₅₉ | H |
| Lₐ₂₆₁₂ | Rₙ₆₄ | Ar41 | H | H | H | H | H | Rₙ₅₉ | H |
| Lₐ₂₆₁₃ | Rₙ₆₅ | Ar41 | H | H | H | H | H | Rₙ₅₉ | H |
| Lₐ₂₆₁₄ | Rₙ₆₉ | Ar41 | H | H | H | H | H | Rₙ₅₉ | H |
| Lₐ₂₆₁₅ | Rₙ₇₀ | Ar41 | H | H | H | H | H | Rₙ₅₉ | H |
| Lₐ₂₆₁₆ | Rₙ₈₁ | Ar41 | H | H | H | H | H | Rₙ₅₉ | H |
| Lₐ₂₆₁₇ | Rₙ₁ | Ar41 | H | H | H | H | H | Rₙ₆₀ | H |
| Lₐ₂₆₁₈ | Rₙ₄ | Ar41 | H | H | H | H | H | Rₙ₆₀ | H |
| Lₐ₂₆₁₉ | Rₙ₅ | Ar41 | H | H | H | H | H | Rₙ₆₀ | H |
| Lₐ₂₆₂₀ | Rₙ₇ | Ar41 | H | H | H | H | H | Rₙ₆₀ | H |
| Lₐ₂₆₂₁ | Rₙ₁₁ | Ar41 | H | H | H | H | H | Rₙ₆₀ | H |
| Lₐ₂₆₂₂ | Rₙ₂₀ | Ar41 | H | H | H | H | H | Rₙ₆₀ | H |
| Lₐ₂₆₂₃ | Rₙ₂₁ | Ar41 | H | H | H | H | H | Rₙ₆₀ | H |
| Lₐ₂₆₂₄ | Rₙ₅₁ | Ar41 | H | H | H | H | H | Rₙ₆₀ | H |
| Lₐ₂₆₂₅ | Rₙ₅₆ | Ar41 | H | H | H | H | H | Rₙ₆₀ | H |
| Lₐ₂₆₂₆ | Rₙ₅₉ | Ar41 | H | H | H | H | H | Rₙ₆₀ | H |
| Lₐ₂₆₂₇ | Rₙ₆₀ | Ar41 | H | H | H | H | H | Rₙ₆₀ | H |
| Lₐ₂₆₂₈ | Rₙ₆₁ | Ar41 | H | H | H | H | H | Rₙ₆₀ | H |
| Lₐ₂₆₂₉ | Rₙ₆₂ | Ar41 | H | H | H | H | H | Rₙ₆₀ | H |
| Lₐ₂₆₃₀ | Rₙ₆₄ | Ar41 | H | H | H | H | H | Rₙ₆₀ | H |
| Lₐ₂₆₃₁ | Rₙ₆₅ | Ar41 | H | H | H | H | H | Rₙ₆₀ | H |
| Lₐ₂₆₃₂ | Rₙ₆₉ | Ar41 | H | H | H | H | H | Rₙ₆₀ | H |
| Lₐ₂₆₃₃ | Rₙ₇₀ | Ar41 | H | H | H | H | H | Rₙ₆₀ | H |
| Lₐ₂₆₃₄ | Rₙ₈₁ | Ar41 | H | H | H | H | H | Rₙ₆₀ | H |
| Lₐ₂₆₃₅ | Rₙ₁ | Ar41 | H | H | H | H | H | Rₙ₆₄ | H |
| Lₐ₂₆₃₆ | Rₙ₄ | Ar41 | H | H | H | H | H | Rₙ₆₄ | H |
| Lₐ₂₆₃₇ | Rₙ₅ | Ar41 | H | H | H | H | H | Rₙ₆₄ | H |
| Lₐ₂₆₃₈ | Rₙ₇ | Ar41 | H | H | H | H | H | Rₙ₆₄ | H |
| Lₐ₂₆₃₉ | Rₙ₁₁ | Ar41 | H | H | H | H | H | Rₙ₆₄ | H |
| Lₐ₂₆₄₀ | Rₙ₂₀ | Ar41 | H | H | H | H | H | Rₙ₆₄ | H |
| Lₐ₂₆₄₁ | Rₙ₂₁ | Ar41 | H | H | H | H | H | Rₙ₆₄ | H |
| Lₐ₂₆₄₂ | Rₙ₅₁ | Ar41 | H | H | H | H | H | Rₙ₆₄ | H |
| Lₐ₂₆₄₃ | Rₙ₅₆ | Ar41 | H | H | H | H | H | Rₙ₆₄ | H |
| Lₐ₂₆₄₄ | Rₙ₅₉ | Ar41 | H | H | H | H | H | Rₙ₆₄ | H |
| Lₐ₂₆₄₅ | Rₙ₆₀ | Ar41 | H | H | H | H | H | Rₙ₆₄ | H |
| Lₐ₂₆₄₆ | Rₙ₆₁ | Ar41 | H | H | H | H | H | Rₙ₆₄ | H |
| Lₐ₂₆₄₇ | Rₙ₆₂ | Ar41 | H | H | H | H | H | Rₙ₆₄ | H |
| Lₐ₂₆₄₈ | Rₙ₆₄ | Ar41 | H | H | H | H | H | Rₙ₆₄ | H |
| Lₐ₂₆₄₉ | Rₙ₆₅ | Ar41 | H | H | H | H | H | Rₙ₆₄ | H |
| Lₐ₂₆₅₀ | Rₙ₆₉ | Ar41 | H | H | H | H | H | Rₙ₆₄ | H |
| Lₐ₂₆₅₁ | Rₙ₇₀ | Ar41 | H | H | H | H | H | Rₙ₆₄ | H |
| Lₐ₂₆₅₂ | Rₙ₈₁ | Ar41 | H | H | H | H | H | Rₙ₆₄ | H |
| Lₐ₂₆₅₃ | Rₙ₁ | Ar41 | H | H | H | H | H | Me | H |
| Lₐ₂₆₅₄ | Rₙ₄ | Ar41 | H | H | H | H | H | Me | H |
| Lₐ₂₆₅₅ | Rₙ₅ | Ar41 | H | H | H | H | H | Me | H |
| Lₐ₂₆₅₆ | Rₙ₇ | Ar41 | H | H | H | H | H | Me | H |
| Lₐ₂₆₅₇ | Rₙ₁₁ | Ar41 | H | H | H | H | H | Me | H |
| Lₐ₂₆₅₈ | Rₙ₂₀ | Ar41 | H | H | H | H | H | Me | H |
| Lₐ₂₆₅₉ | Rₙ₂₁ | Ar41 | H | H | H | H | H | Me | H |
| Lₐ₂₆₆₀ | Rₙ₅₁ | Ar41 | H | H | H | H | H | Me | H |
| Lₐ₂₆₆₁ | Rₙ₅₆ | Ar41 | H | H | H | H | H | Me | H |
| Lₐ₂₆₆₂ | Rₙ₅₉ | Ar41 | H | H | H | H | H | CD₃ | H |
| Lₐ₂₆₆₃ | Rₙ₆₀ | Ar41 | H | H | H | H | H | Me | H |
| Lₐ₂₆₆₄ | Rₙ₆₁ | Ar41 | H | H | H | H | H | Me | H |
| Lₐ₂₆₆₅ | Rₙ₆₂ | Ar41 | H | H | H | H | H | Me | H |
| Lₐ₂₆₆₆ | Rₙ₆₄ | Ar41 | H | H | H | H | H | Me | H |
| Lₐ₂₆₆₇ | Rₙ₆₅ | Ar41 | H | H | H | H | H | Me | H |
| Lₐ₂₆₆₈ | Rₙ₆₉ | Ar41 | H | H | H | H | H | Me | D |
| Lₐ₂₆₆₉ | Rₙ₇₀ | Ar41 | H | H | H | H | H | Me | H |
| Lₐ₂₆₇₀ | Rₙ₈₁ | Ar41 | H | H | H | H | H | Me | H |
| Lₐ₂₆₇₁ | Rₙ₁ | Ar41 | H | H | H | H | Rₙ₁₁ | H | H |
| Lₐ₂₆₇₂ | Rₙ₄ | Ar41 | H | H | H | H | Rₙ₁₁ | H | H |
| Lₐ₂₆₇₃ | Rₙ₅ | Ar41 | H | H | H | H | Rₙ₁₁ | H | H |
| Lₐ₂₆₇₄ | Rₙ₇ | Ar41 | H | H | H | H | Rₙ₁₁ | H | H |
| Lₐ₂₆₇₅ | Rₙ₁₁ | Ar41 | H | H | H | H | Rₙ₁₁ | H | H |
| Lₐ₂₆₇₆ | Rₙ₂₀ | Ar41 | H | H | H | H | Rₙ₁₁ | H | H |
| Lₐ₂₆₇₇ | Rₙ₂₁ | Ar41 | H | H | H | H | Rₙ₁₁ | H | H |
| Lₐ₂₆₇₈ | Rₙ₅₁ | Ar41 | H | H | H | H | Rₙ₁₁ | H | H |
| Lₐ₂₆₇₉ | Rₙ₅₆ | Ar41 | H | H | H | H | Rₙ₁₁ | H | H |
| Lₐ₂₆₈₀ | Rₙ₅₉ | Ar41 | H | H | H | H | Rₙ₁₁ | H | H |
| Lₐ₂₆₈₁ | Rₙ₆₀ | Ar41 | H | H | H | H | Rₙ₁₁ | H | H |
| Lₐ₂₆₈₂ | Rₙ₆₁ | Ar41 | H | H | H | H | Rₙ₁₁ | H | H |
| Lₐ₂₆₈₃ | Rₙ₆₂ | Ar41 | H | H | H | H | Rₙ₁₁ | H | H |
| Lₐ₂₆₈₄ | Rₙ₆₄ | Ar41 | H | H | H | H | Rₙ₁₁ | H | H |
| Lₐ₂₆₈₅ | Rₙ₆₅ | Ar41 | H | H | H | H | Rₙ₁₁ | H | H |
| Lₐ₂₆₈₆ | Rₙ₆₉ | Ar41 | H | H | H | H | Rₙ₁₁ | H | H |
| Lₐ₂₆₈₇ | Rₙ₇₀ | Ar41 | H | H | H | H | Rₙ₁₁ | H | H |
| Lₐ₂₆₈₈ | Rₙ₈₁ | Ar41 | H | H | H | H | Rₙ₁₁ | H | H |
| Lₐ₂₆₈₉ | Rₙ₁ | Ar41 | H | H | H | H | Rₙ₅₉ | H | H |
| Lₐ₂₆₉₀ | Rₙ₄ | Ar41 | H | H | H | H | Rₙ₅₉ | H | H |
| Lₐ₂₆₉₁ | Rₙ₅ | Ar41 | H | H | H | H | Rₙ₅₉ | H | H |
| Lₐ₂₆₉₂ | Rₙ₇ | Ar41 | H | H | H | H | Rₙ₅₉ | H | H |
| Lₐ₂₆₉₃ | Rₙ₁₁ | Ar41 | H | H | H | H | Rₙ₅₉ | H | H |
| Lₐ₂₆₉₄ | Rₙ₂₀ | Ar41 | H | H | H | H | Rₙ₅₉ | H | H |
| Lₐ₂₆₉₅ | Rₙ₂₁ | Ar41 | H | H | H | H | Rₙ₅₉ | H | H |
| Lₐ₂₆₉₆ | Rₙ₅₁ | Ar41 | H | H | H | H | Rₙ₅₉ | H | H |
| Lₐ₂₆₉₇ | Rₙ₅₆ | Ar41 | H | H | H | H | Rₙ₅₉ | H | H |
| Lₐ₂₆₉₈ | Rₙ₅₉ | Ar41 | H | H | H | H | Rₙ₅₉ | H | H |
| Lₐ₂₆₉₉ | Rₙ₆₀ | Ar41 | H | H | H | H | Rₙ₅₉ | H | H |
| Lₐ₂₇₀₀ | Rₙ₆₁ | Ar41 | H | H | H | H | Rₙ₅₉ | H | H |
| Lₐ₂₇₀₁ | Rₙ₆₂ | Ar41 | H | H | H | H | Rₙ₅₉ | H | H |
| Lₐ₂₇₀₂ | Rₙ₆₄ | Ar41 | H | H | H | H | Rₙ₅₉ | H | H |
| Lₐ₂₇₀₃ | Rₙ₆₅ | Ar41 | H | H | H | H | Rₙ₅₉ | H | H |
| Lₐ₂₇₀₄ | Rₙ₆₉ | Ar41 | H | H | H | H | Rₙ₅₉ | H | H |
| Lₐ₂₇₀₅ | Rₙ₇₀ | Ar41 | H | H | H | H | Rₙ₅₉ | H | H |
| Lₐ₂₇₀₆ | Rₙ₈₁ | Ar41 | H | H | H | H | Rₙ₅₉ | H | H |
| Lₐ₂₇₀₇ | Rₙ₁ | Ar41 | H | H | H | H | Rₙ₆₀ | H | H |
| Lₐ₂₇₀₈ | Rₙ₄ | Ar41 | H | H | H | H | Rₙ₆₀ | H | H |
| Lₐ₂₇₀₉ | Rₙ₅ | Ar41 | H | H | H | H | Rₙ₆₀ | H | H |
| Lₐ₂₇₁₀ | Rₙ₇ | Ar41 | H | H | H | H | Rₙ₆₀ | H | H |
| Lₐ₂₇₁₁ | Rₙ₁₁ | Ar41 | H | H | H | H | Rₙ₆₀ | H | H |
| Lₐ₂₇₁₂ | Rₙ₂₀ | Ar41 | H | H | H | H | Rₙ₆₀ | H | H |
| Lₐ₂₇₁₃ | Rₙ₂₁ | Ar41 | H | H | H | H | Rₙ₆₀ | H | H |
| Lₐ₂₇₁₄ | Rₙ₅₁ | Ar41 | H | H | H | H | Rₙ₆₀ | H | H |
| Lₐ₂₇₁₅ | Rₙ₅₆ | Ar41 | H | H | H | H | Rₙ₆₀ | H | H |
| Lₐ₂₇₁₆ | Rₙ₅₉ | Ar41 | H | H | H | H | Rₙ₆₀ | H | H |
| Lₐ₂₇₁₇ | Rₙ₆₀ | Ar41 | H | H | H | H | Rₙ₆₀ | H | H |
| Lₐ₂₇₁₈ | Rₙ₆₁ | Ar41 | H | H | H | H | Rₙ₆₀ | H | H |
| Lₐ₂₇₁₉ | Rₙ₆₂ | Ar41 | H | H | H | H | Rₙ₆₀ | H | H |
| Lₐ₂₇₂₀ | Rₙ₆₄ | Ar41 | H | H | H | H | Rₙ₆₀ | H | H |
| Lₐ₂₇₂₁ | Rₙ₆₅ | Ar41 | H | H | H | H | Rₙ₆₀ | H | H |
| Lₐ₂₇₂₂ | Rₙ₆₉ | Ar41 | H | H | H | H | Rₙ₆₀ | H | H |
| Lₐ₂₇₂₃ | Rₙ₇₀ | Ar41 | H | H | H | H | Rₙ₆₀ | H | H |
| Lₐ₂₇₂₄ | Rₙ₈₁ | Ar41 | H | H | H | H | Rₙ₆₀ | H | H |
| Lₐ₂₇₂₅ | Rₙ₁ | Ar41 | H | H | H | H | Rₙ₆₄ | H | H |
| Lₐ₂₇₂₆ | Rₙ₄ | Ar41 | H | H | H | H | Rₙ₆₄ | H | H |
| Lₐ₂₇₂₇ | Rₙ₅ | Ar41 | H | H | H | H | Rₙ₆₄ | H | H |
| Lₐ₂₇₂₈ | Rₙ₇ | Ar41 | H | H | H | H | Rₙ₆₄ | H | H |
| Lₐ₂₇₂₉ | Rₙ₁₁ | Ar41 | H | H | H | H | Rₙ₆₄ | H | H |
| Lₐ₂₇₃₀ | Rₙ₂₀ | Ar41 | H | H | H | H | Rₙ₆₄ | H | H |
| Lₐ₂₇₃₁ | Rₙ₂₁ | Ar41 | H | H | H | H | Rₙ₆₄ | H | H |
| Lₐ₂₇₃₂ | Rₙ₅₁ | Ar41 | H | H | H | H | Rₙ₆₄ | H | H |
| Lₐ₂₇₃₃ | Rₙ₅₆ | Ar41 | H | H | H | H | Rₙ₆₄ | H | H |
| Lₐ₂₇₃₄ | Rₙ₅₉ | Ar41 | H | H | H | H | Rₙ₆₄ | H | H |
| Lₐ₂₇₃₅ | Rₙ₆₀ | Ar41 | H | H | H | H | Rₙ₆₄ | H | H |
| Lₐ₂₇₃₆ | Rₙ₆₁ | Ar41 | H | H | H | H | Rₙ₆₄ | H | H |
| Lₐ₂₇₃₇ | Rₙ₆₂ | Ar41 | H | H | H | H | Rₙ₆₄ | H | H |
| Lₐ₂₇₃₈ | Rₙ₆₄ | Ar41 | H | H | H | H | Rₙ₆₄ | H | H |
| Lₐ₂₇₃₉ | Rₙ₆₅ | Ar41 | H | H | H | H | Rₙ₆₄ | H | H |
| Lₐ₂₇₄₀ | Rₙ₆₉ | Ar41 | H | H | H | H | Rₙ₆₄ | H | H |
| Lₐ₂₇₄₁ | Rₙ₇₀ | Ar41 | H | H | H | H | Rₙ₆₄ | H | H |
| Lₐ₂₇₄₂ | Rₙ₈₁ | Ar41 | H | H | H | H | Rₙ₆₄ | H | H |
| Lₐ₂₇₄₃ | Rₙ₁ | Ar41 | H | H | H | H | Me | H | H |
| Lₐ₂₇₄₄ | Rₙ₄ | Ar41 | H | H | H | H | Me | H | H |
| Lₐ₂₇₄₅ | Rₙ₅ | Ar41 | H | H | H | H | Me | H | H |
| Lₐ₂₇₄₆ | Rₙ₇ | Ar41 | H | H | H | H | Me | H | H |
| Lₐ₂₇₄₇ | Rₙ₁₁ | Ar41 | H | H | H | H | Me | H | H |
| Lₐ₂₇₄₈ | Rₙ₂₀ | Ar41 | H | H | H | H | Me | H | H |
| Lₐ₂₇₄₉ | Rₙ₂₁ | Ar41 | H | H | H | H | Me | H | H |
| Lₐ₂₇₅₀ | Rₙ₅₁ | Ar41 | H | H | H | H | Me | H | H |
| Lₐ₂₇₅₁ | Rₙ₅₆ | Ar41 | H | H | H | H | Me | H | H |
| Lₐ₂₇₅₂ | Rₙ₅₉ | Ar41 | H | H | H | H | Me | H | H |
| Lₐ₂₇₅₃ | Rₙ₆₀ | Ar41 | H | H | H | H | Me | H | H |
| Lₐ₂₇₅₄ | Rₙ₆₁ | Ar41 | H | H | H | H | Me | H | H |
| Lₐ₂₇₅₅ | Rₙ₆₂ | Ar41 | H | H | H | H | Me | H | H |
| Lₐ₂₇₅₆ | Rₙ₆₄ | Ar41 | H | H | H | H | Me | H | H |
| Lₐ₂₇₅₇ | Rₙ₆₅ | Ar41 | H | H | H | H | Me | H | H |
| Lₐ₂₇₅₈ | Rₙ₆₉ | Ar41 | H | H | H | H | Me | H | H |
| Lₐ₂₇₅₉ | Rₙ₇₀ | Ar41 | H | H | H | H | Me | H | H |
| Lₐ₂₇₆₀ | Rₙ₈₁ | Ar41 | H | H | H | H | Me | H | H |
| Lₐ₂₇₆₁ | Rₙ₁ | Ar41 | D | H | F | H | H | H | H |
| Lₐ₂₇₆₂ | Rₙ₄ | Ar41 | H | H | F | H | H | H | H |
| Lₐ₂₇₆₃ | Rₙ₇ | Ar41 | H | H | F | H | H | H | H |
| Lₐ₂₇₆₄ | Rₙ₂₀ | Ar41 | H | H | F | H | H | H | H |
| Lₐ₂₇₆₅ | Rₙ₂₁ | Ar41 | H | H | F | H | H | H | H |
| Lₐ₂₇₆₆ | Rₙ₅₆ | Ar41 | H | H | F | H | H | H | H |
| Lₐ₂₇₆₇ | Rₙ₅₉ | Ar41 | H | H | F | H | H | H | H |
| Lₐ₂₇₆₈ | Rₙ₆₁ | Ar41 | H | H | F | H | H | H | H |
| Lₐ₂₇₆₉ | Rₙ₆₂ | Ar41 | H | H | F | H | H | H | H |
| Lₐ₂₇₇₀ | Rₙ₆₄ | Ar41 | H | H | F | H | H | H | H |
| Lₐ₂₇₇₁ | Rₙ₆₉ | Ar41 | H | H | F | H | H | H | H |
| Lₐ₂₇₇₂ | Rₙ₇₀ | Ar41 | H | D | F | H | H | H | H |
| Lₐ₂₇₇₃ | Rₙ₁ | Ar41 | H | H | F | H | Rₙ₁₁ | H | H |
| Lₐ₂₇₇₄ | Rₙ₄ | Ar41 | H | H | F | H | Rₙ₁₁ | H | H |
| Lₐ₂₇₇₅ | Rₙ₇ | Ar41 | H | H | F | H | Rₙ₁₁ | H | H |
| Lₐ₂₇₇₆ | Rₙ₂₀ | Ar41 | H | H | F | H | Rₙ₁₁ | H | H |
| Lₐ₂₇₇₇ | Rₙ₂₁ | Ar41 | H | H | F | H | Rₙ₁₁ | H | H |
| Lₐ₂₇₇₈ | Rₙ₅₆ | Ar41 | H | H | F | H | Rₙ₁₁ | H | H |
| Lₐ₂₇₇₉ | Rₙ₅₉ | Ar41 | H | H | F | H | Rₙ₁₁ | H | H |
| Lₐ₂₇₈₀ | Rₙ₆₁ | Ar41 | H | H | F | H | Rₙ₁₁ | H | H |
| Lₐ₂₇₈₁ | Rₙ₆₂ | Ar41 | H | H | F | H | Rₙ₁₁ | H | H |
| Lₐ₂₇₈₂ | Rₙ₆₄ | Ar41 | H | H | F | H | Rₙ₁₁ | H | H |
| Lₐ₂₇₈₃ | Rₙ₆₉ | Ar41 | H | H | F | H | Rₙ₁₁ | H | H |
| Lₐ₂₇₈₄ | Rₙ₇₀ | Ar41 | H | H | F | H | Rₙ₁₁ | H | H |
| Lₐ₂₇₈₅ | Rₙ₁ | Ar41 | H | H | F | H | Rₙ₆₀ | H | H |
| Lₐ₂₇₈₆ | Rₙ₄ | Ar41 | H | H | F | H | Rₙ₆₀ | H | H |
| Lₐ₂₇₈₇ | Rₙ₇ | Ar41 | H | H | F | H | Rₙ₆₀ | H | H |
| Lₐ₂₇₈₈ | Rₙ₂₀ | Ar41 | H | H | F | H | Rₙ₆₀ | H | H |
| Lₐ₂₇₈₉ | Rₙ₂₁ | Ar41 | H | H | F | H | Rₙ₆₀ | H | H |
| Lₐ₂₇₉₀ | Rₙ₅₆ | Ar41 | H | H | F | H | Rₙ₆₀ | H | H |
| Lₐ₂₇₉₁ | Rₙ₅₉ | Ar41 | H | H | F | H | Rₙ₆₀ | H | H |
| Lₐ₂₇₉₂ | Rₙ₆₁ | Ar41 | H | H | F | H | Rₙ₆₀ | H | H |
| Lₐ₂₇₉₃ | Rₙ₆₂ | Ar41 | H | H | F | H | Rₙ₆₀ | H | H |
| Lₐ₂₇₉₄ | Rₙ₆₄ | Ar41 | H | H | F | H | Rₙ₆₀ | H | H |
| Lₐ₂₇₉₅ | Rₙ₆₉ | Ar41 | H | H | F | H | Rₙ₆₀ | H | H |
| Lₐ₂₇₉₆ | Rₙ₇₀ | Ar41 | H | H | F | H | Rₙ₆₀ | H | H |
| Lₐ₂₇₉₇ | Rₙ₁ | Ar41 | H | H | F | H | H | Rₙ₁₁ | H |
| Lₐ₂₇₉₈ | Rₙ₄ | Ar41 | H | H | F | H | H | Rₙ₁₁ | H |
| Lₐ₂₇₉₉ | Rₙ₇ | Ar41 | H | H | F | H | H | Rₙ₁₁ | H |
| Lₐ₂₈₀₀ | Rₙ₂₀ | Ar41 | H | H | F | H | H | Rₙ₁₁ | H |
| Lₐ₂₈₀₁ | Rₙ₂₁ | Ar41 | H | H | F | H | H | Rₙ₁₁ | H |
| Lₐ₂₈₀₂ | Rₙ₅₆ | Ar41 | H | H | F | H | H | Rₙ₁₁ | H |
| Lₐ₂₈₀₃ | Rₙ₅₉ | Ar41 | H | H | F | H | H | Rₙ₁₁ | H |
| Lₐ₂₈₀₄ | Rₙ₆₁ | Ar41 | H | H | F | H | H | Rₙ₁₁ | H |
| Lₐ₂₈₀₅ | Rₙ₆₂ | Ar41 | H | H | F | H | H | Rₙ₁₁ | H |
| Lₐ₂₈₀₆ | Rₙ₆₄ | Ar41 | H | H | F | H | H | Rₙ₁₁ | H |
| Lₐ₂₈₀₇ | Rₙ₆₉ | Ar41 | H | H | F | H | H | Rₙ₁₁ | H |
| Lₐ₂₈₀₈ | Rₙ₇₀ | Ar41 | H | H | F | H | H | Rₙ₁₁ | H |
| Lₐ₂₈₀₉ | Rₙ₁ | Ar41 | H | H | F | H | H | Rₙ₆₀ | H |
| Lₐ₂₈₁₀ | Rₙ₄ | Ar41 | H | H | F | H | H | Rₙ₆₀ | H |
| Lₐ₂₈₁₁ | Rₙ₇ | Ar41 | H | H | F | H | H | Rₙ₆₀ | H |
| Lₐ₂₈₁₂ | Rₙ₂₀ | Ar41 | H | H | F | H | H | Rₙ₆₀ | H |
| Lₐ₂₈₁₃ | Rₙ₂₁ | Ar41 | H | H | F | H | H | Rₙ₆₀ | H |
| Lₐ₂₈₁₄ | Rₙ₅₆ | Ar41 | H | H | F | H | H | Rₙ₆₀ | H |
| Lₐ₂₈₁₅ | Rₙ₅₉ | Ar41 | H | H | F | H | H | Rₙ₆₀ | H |
| Lₐ₂₈₁₆ | Rₙ₆₁ | Ar41 | H | H | F | H | H | Rₙ₆₀ | H |
| Lₐ₂₈₁₇ | Rₙ₆₂ | Ar41 | H | H | F | H | H | Rₙ₆₀ | H |
| Lₐ₂₈₁₈ | Rₙ₆₄ | Ar41 | H | H | F | H | H | Rₙ₆₀ | H |
| Lₐ₂₈₁₉ | Rₙ₆₉ | Ar41 | H | H | F | H | H | Rₙ₆₀ | H |
| Lₐ₂₈₂₀ | Rₙ₇₀ | Ar41 | H | H | F | H | H | Rₙ₆₀ | H |
| Lₐ₂₈₂₁ | Rₙ₁ | Ar41 | H | H | CN | H | H | H | H |
| Lₐ₂₈₂₂ | Rₙ₄ | Ar41 | H | H | CN | H | H | H | H |
| Lₐ₂₈₂₃ | Rₙ₇ | Ar41 | H | H | CN | H | H | H | H |
| Lₐ₂₈₂₄ | Rₙ₂₀ | Ar41 | H | H | CN | H | H | H | H |
| Lₐ₂₈₂₅ | Rₙ₂₁ | Ar41 | H | H | CN | H | H | H | H |
| Lₐ₂₈₂₆ | Rₙ₅₆ | Ar41 | H | H | CN | H | H | H | H |
| Lₐ₂₈₂₇ | Rₙ₅₉ | Ar41 | H | H | CN | H | H | H | H |
| Lₐ₂₈₂₈ | Rₙ₆₁ | Ar41 | H | H | CN | H | H | H | H |
| Lₐ₂₈₂₉ | Rₙ₆₂ | Ar41 | H | H | CN | H | H | H | H |
| Lₐ₂₈₃₀ | Rₙ₆₄ | Ar41 | H | H | CN | H | H | H | H |
| Lₐ₂₈₃₁ | Rₙ₆₉ | Ar41 | H | H | CN | H | H | H | H |
| Lₐ₂₈₃₂ | Rₙ₇₀ | Ar41 | H | H | CN | H | H | H | H |
| Lₐ₂₈₃₃ | Rₙ₁ | Ar41 | H | CN | D | H | H | H | H |
| Lₐ₂₈₃₄ | Rₙ₄ | Ar41 | H | CN | H | H | H | H | H |
| Lₐ₂₈₃₅ | Rₙ₇ | Ar41 | H | CN | H | H | H | H | H |
| Lₐ₂₈₃₆ | Rₙ₂₀ | Ar41 | H | CN | H | H | H | H | H |
| Lₐ₂₈₃₇ | Rₙ₂₁ | Ar41 | H | CN | H | H | H | H | H |
| Lₐ₂₈₃₈ | Rₙ₅₆ | Ar41 | H | CN | H | H | H | H | H |
| Lₐ₂₈₃₉ | Rₙ₅₉ | Ar41 | H | CN | H | H | H | H | H |
| Lₐ₂₈₄₀ | Rₙ₆₁ | Ar41 | H | CN | H | H | H | H | H |
| Lₐ₂₈₄₁ | Rₙ₆₂ | Ar41 | H | CN | H | H | H | H | H |
| Lₐ₂₈₄₂ | Rₙ₆₄ | Ar41 | H | CN | H | H | H | H | H |
| Lₐ₂₈₄₃ | Rₙ₆₉ | Ar41 | H | CN | H | H | H | H | H |
| Lₐ₂₈₄₄ | Rₙ₇₀ | Ar41 | H | CN | H | H | H | H | H |
| Lₐ₂₈₄₅ | Rₙ₁ | Ar41 | CN | H | H | H | H | H | H |
| Lₐ₂₈₄₆ | Rₙ₄ | Ar41 | CN | H | H | H | H | H | H |
| Lₐ₂₈₄₇ | Rₙ₇ | Ar41 | CN | H | H | H | H | H | H |
| Lₐ₂₈₄₈ | Rₙ₂₀ | Ar41 | CN | H | H | H | H | H | H |
| Lₐ₂₈₄₉ | Rₙ₂₁ | Ar41 | CN | H | H | H | H | H | H |
| Lₐ₂₈₅₀ | Rₙ₅₆ | Ar41 | CN | D | H | H | H | H | H |
| Lₐ₂₈₅₁ | Rₙ₅₉ | Ar41 | CN | H | H | H | H | H | H |
| Lₐ₂₈₅₂ | Rₙ₆₁ | Ar41 | CN | H | H | H | H | H | H |
| Lₐ₂₈₅₃ | Rₙ₆₂ | Ar41 | CN | H | H | H | H | H | H |
| Lₐ₂₈₅₄ | Rₙ₆₄ | Ar41 | CN | H | H | H | H | H | H |
| Lₐ₂₈₅₅ | Rₙ₆₉ | Ar41 | CN | H | H | H | H | H | H |
| Lₐ₂₈₅₆ | Rₙ₇₀ | Ar41 | CN | H | H | H | H | H | H |
| Lₐ₂₈₅₇ | Rₙ₁ | Ar41 | H | H | CN | H | Rₙ₁₁ | H | H |
| Lₐ₂₈₅₈ | Rₙ₄ | Ar41 | H | H | CN | H | Rₙ₁₁ | H | H |
| Lₐ₂₈₅₉ | Rₙ₇ | Ar41 | H | H | CN | H | Rₙ₁₁ | H | H |
| Lₐ₂₈₆₀ | Rₙ₂₀ | Ar41 | H | H | CN | H | Rₙ₁₁ | H | H |
| Lₐ₂₈₆₁ | Rₙ₂₁ | Ar41 | H | H | CN | H | Rₙ₁₁ | H | H |
| Lₐ₂₈₆₂ | Rₙ₅₆ | Ar41 | H | H | CN | H | Rₙ₁₁ | H | H |
| Lₐ₂₈₆₃ | Rₙ₅₉ | Ar41 | H | H | CN | H | Rₙ₁₁ | H | H |
| Lₐ₂₈₆₄ | Rₙ₆₁ | Ar41 | H | H | CN | H | Rₙ₁₁ | H | H |
| Lₐ₂₈₆₅ | Rₙ₆₂ | Ar41 | H | H | CN | H | Rₙ₁₁ | H | H |
| Lₐ₂₈₆₆ | Rₙ₆₄ | Ar41 | H | H | CN | H | Rₙ₁₁ | H | H |
| Lₐ₂₈₆₇ | Rₙ₆₉ | Ar41 | H | H | CN | H | Rₙ₁₁ | H | H |
| Lₐ₂₈₆₈ | Rₙ₇₀ | Ar41 | H | H | CN | H | Rₙ₁₁ | H | H |
| Lₐ₂₈₆₉ | Rₙ₁ | Ar41 | H | H | CN | H | Rₙ₆₀ | H | H |
| Lₐ₂₈₇₀ | Rₙ₄ | Ar41 | H | H | CN | H | Rₙ₆₀ | H | H |
| Lₐ₂₈₇₁ | Rₙ₇ | Ar41 | H | H | CN | H | Rₙ₆₀ | H | H |
| Lₐ₂₈₇₂ | Rₙ₂₀ | Ar41 | H | H | CN | H | Rₙ₆₀ | H | H |
| Lₐ₂₈₇₃ | Rₙ₂₁ | Ar41 | H | H | CN | H | Rₙ₆₀ | H | H |
| Lₐ₂₈₇₄ | Rₙ₅₆ | Ar41 | H | H | CN | H | Rₙ₆₀ | H | H |
| Lₐ₂₈₇₅ | Rₙ₅₉ | Ar41 | H | H | CN | H | Rₙ₆₀ | H | H |
| Lₐ₂₈₇₆ | Rₙ₆₁ | Ar41 | H | H | CN | H | Rₙ₆₀ | H | H |
| Lₐ₂₈₇₇ | Rₙ₆₂ | Ar41 | H | H | CN | H | Rₙ₆₀ | H | H |
| Lₐ₂₈₇₈ | Rₙ₆₄ | Ar41 | H | H | CN | H | Rₙ₆₀ | H | H |
| Lₐ₂₈₇₉ | Rₙ₆₉ | Ar41 | H | H | CN | H | Rₙ₆₀ | H | H |
| Lₐ₂₈₈₀ | Rₙ₇₀ | Ar41 | H | H | CN | H | Rₙ₆₀ | H | H |
| Lₐ₂₈₈₁ | Rₙ₁ | Ar41 | H | H | CN | H | Rₙ₆₄ | H | H |
| Lₐ₂₈₈₂ | Rₙ₄ | Ar41 | H | H | CN | H | Rₙ₆₄ | H | H |
| Lₐ₂₈₈₃ | Rₙ₇ | Ar41 | H | H | CN | H | Rₙ₆₄ | H | H |
| Lₐ₂₈₈₄ | Rₙ₂₀ | Ar41 | H | H | CN | H | Rₙ₆₄ | H | H |
| Lₐ₂₈₈₅ | Rₙ₂₁ | Ar41 | H | H | CN | H | Rₙ₆₄ | H | H |
| Lₐ₂₈₈₆ | Rₙ₅₆ | Ar41 | H | H | CN | H | Rₙ₆₄ | H | H |
| Lₐ₂₈₈₇ | Rₙ₅₉ | Ar41 | H | H | CN | H | Rₙ₆₄ | H | H |
| Lₐ₂₈₈₈ | Rₙ₆₁ | Ar41 | H | H | CN | H | Rₙ₆₄ | H | H |
| Lₐ₂₈₈₉ | Rₙ₆₂ | Ar41 | H | H | CN | H | Rₙ₆₄ | H | H |
| Lₐ₂₈₉₀ | Rₙ₆₄ | Ar41 | H | H | CN | H | Rₙ₆₄ | H | H |
| Lₐ₂₈₉₁ | Rₙ₆₉ | Ar41 | H | H | CN | H | Rₙ₆₄ | H | H |
| Lₐ₂₈₉₂ | Rₙ₇₀ | Ar41 | H | H | CN | H | Rₙ₆₄ | H | H |
| Lₐ₂₈₉₃ | Rₙ₁ | Ar41 | H | H | CN | H | H | Rₙ₁₁ | H |
| Lₐ₂₈₉₄ | Rₙ₄ | Ar41 | H | H | CN | H | H | Rₙ₁₁ | H |
| Lₐ₂₈₉₅ | Rₙ₇ | Ar41 | H | H | CN | H | H | Rₙ₁₁ | H |
| Lₐ₂₈₉₆ | Rₙ₂₀ | Ar41 | H | H | CN | H | H | Rₙ₁₁ | H |
| Lₐ₂₈₉₇ | Rₙ₂₁ | Ar41 | H | H | CN | H | H | Rₙ₁₁ | H |
| Lₐ₂₈₉₈ | Rₙ₅₆ | Ar41 | H | H | CN | H | H | Rₙ₁₁ | H |
| Lₐ₂₈₉₉ | Rₙ₅₉ | Ar41 | H | H | CN | H | H | Rₙ₁₁ | H |
| Lₐ₂₉₀₀ | Rₙ₆₁ | Ar41 | H | H | CN | H | H | Rₙ₁₁ | H |
| Lₐ₂₉₀₁ | Rₙ₆ | Ar41 | H | H | CN | H | H | Rₙ₁₁ | H |
| Lₐ₂₉₀₂ | Rₙ₆₄ | Ar41 | H | H | CN | H | H | Rₙ₁₁ | H |
| Lₐ₂₉₀₃ | Rₙ₆₉ | Ar41 | H | H | CN | H | H | Rₙ₁₁ | H |
| Lₐ₂₉₀₄ | Rₙ₇₀ | Ar41 | H | H | CN | H | H | Rₙ₁₁ | H |
| Lₐ₂₉₀₅ | Rₙ₁ | Ar41 | H | H | CN | H | H | Rₙ₆₀ | H |
| Lₐ₂₉₀₆ | Rₙ₄ | Ar41 | H | H | CN | H | H | Rₙ₆₀ | H |
| Lₐ₂₉₀₇ | Rₙ₇ | Ar41 | H | D | CN | H | H | Rₙ₆₀ | H |
| Lₐ₂₉₀₈ | Rₙ₂₀ | Ar41 | H | H | CN | H | H | Rₙ₆₀ | H |
| Lₐ₂₉₀₉ | Rₙ₂₁ | Ar41 | H | H | CN | H | H | Rₙ₆₀ | H |
| Lₐ₂₉₁₀ | Rₙ₅₆ | Ar41 | H | H | CN | H | H | Rₙ₆₀ | H |
| Lₐ₂₉₁₁ | Rₙ₅₉ | Ar41 | H | H | CN | H | H | Rₙ₆₀ | H |
| Lₐ₂₉₁₂ | Rₙ₆₁ | Ar41 | H | H | CN | H | H | Rₙ₆₀ | H |
| Lₐ₂₉₁₃ | Rₙ₆₂ | Ar41 | H | H | CN | H | H | Rₙ₆₀ | H |
| Lₐ₂₉₁₄ | Rₙ₆₄ | Ar41 | H | H | CN | H | H | Rₙ₆₀ | D |
| Lₐ₂₉₁₅ | Rₙ₆₉ | Ar41 | H | H | CN | H | H | Rₙ₆₀ | H |
| Lₐ₂₉₁₆ | Rₙ₇₀ | Ar41 | H | H | CN | H | H | Rₙ₆₀ | H |
| Lₐ₂₉₁₇ | Rₙ₁ | Ar41 | H | H | CN | H | H | Rₙ₆₄ | H |
| Lₐ₂₉₁₈ | Rₙ₄ | Ar41 | H | H | CN | H | H | Rₙ₆₄ | H |
| Lₐ₂₉₁₉ | Rₙ₇ | Ar41 | H | H | CN | H | H | Rₙ₆₄ | H |
| Lₐ₂₉₂₀ | Rₙ₂₀ | Ar41 | H | H | CN | H | H | Rₙ₆₄ | H |
| Lₐ₂₉₂₁ | Rₙ₂₁ | Ar41 | H | H | CN | H | H | Rₙ₆₄ | H |
| Lₐ₂₉₂₂ | Rₙ₅₆ | Ar41 | H | H | CN | H | H | Rₙ₆₄ | H |
| Lₐ₂₉₂₃ | Rₙ₅₉ | Ar41 | H | H | CN | H | H | Rₙ₆₄ | H |
| Lₐ₂₉₂₄ | Rₙ₆₁ | Ar41 | H | H | CN | H | H | Rₙ₆₄ | H |
| Lₐ₂₉₂₅ | Rₙ₆₂ | Ar41 | H | H | CN | H | H | Rₙ₆₄ | H |
| Lₐ₂₉₂₆ | Rₙ₆₄ | Ar41 | H | H | CN | H | H | Rₙ₆₄ | H |
| Lₐ₂₉₂₇ | Rₙ₆₉ | Ar41 | H | H | CN | H | H | Rₙ₆₄ | H |
| Lₐ₂₉₂₈ | Rₙ₇₀ | Ar41 | D | H | CN | H | H | Rₙ₆₄ | H |
| Lₐ₂₉₂₉ | Rₙ₁ | Ar49 | H | H | H | H | H | H | H |
| Lₐ₂₉₃₀ | Rₙ₄ | Ar49 | H | H | H | H | H | H | H |
| Lₐ₂₉₃₁ | Rₙ₅ | Ar49 | H | H | H | H | H | H | H |
| Lₐ₂₉₃₂ | Rₙ₇ | Ar49 | H | H | H | H | H | H | H |
| Lₐ₂₉₃₃ | Rₙ₁₁ | Ar49 | H | H | H | H | H | H | H |
| Lₐ₂₉₃₄ | Rₙ₂₀ | Ar49 | H | H | H | H | H | H | H |
| Lₐ₂₉₃₅ | Rₙ₂₁ | Ar49 | H | H | H | H | H | H | H |
| Lₐ₂₉₃₆ | Rₙ₅₁ | Ar49 | H | H | H | H | H | H | H |
| Lₐ₂₉₃₇ | Rₙ₅₆ | Ar49 | H | H | H | H | H | H | H |
| Lₐ₂₉₃₈ | Rₙ₅₉ | Ar49 | H | H | H | H | H | H | H |
| Lₐ₂₉₃₉ | Rₙ₆₀ | Ar49 | H | H | H | H | H | H | H |
| Lₐ₂₉₄₀ | Rₙ₆₁ | Ar49 | H | H | H | H | H | H | H |
| Lₐ₂₉₄₁ | Rₙ₆₂ | Ar49 | H | H | H | H | H | H | H |
| Lₐ₂₉₄₂ | Rₙ₆₄ | Ar49 | H | H | H | H | H | H | H |
| Lₐ₂₉₄₃ | Rₙ₆₅ | Ar49 | H | H | H | H | H | H | H |
| Lₐ₂₉₄₄ | Rₙ₆₉ | Ar49 | H | H | H | H | H | H | H |
| Lₐ₂₉₄₅ | Rₙ₇₀ | Ar49 | H | H | H | H | H | H | H |
| Lₐ₂₉₄₆ | Rₙ₈₁ | Ar49 | H | H | H | H | H | H | H |
| Lₐ₂₉₄₇ | Rₙ₁ | Ar49 | H | H | H | H | H | Rₙ₁₁ | H |
| Lₐ₂₉₄₈ | Rₙ₄ | Ar49 | H | H | H | H | H | Rₙ₁₁ | H |
| Lₐ₂₉₄₉ | Rₙ₅ | Ar49 | H | H | H | H | H | Rₙ₁₁ | H |
| Lₐ₂₉₅₀ | Rₙ₇ | Ar49 | H | H | H | H | H | Rₙ₁₁ | H |
| Lₐ₂₉₅₁ | Rₙ₁₁ | Ar49 | H | H | H | H | H | Rₙ₁₁ | H |
| Lₐ₂₉₅₂ | Rₙ₂₀ | Ar49 | H | H | H | H | H | Rₙ₁₁ | H |
| Lₐ₂₉₅₃ | Rₙ₂₁ | Ar49 | H | H | H | H | H | Rₙ₁₁ | H |
| Lₐ₂₉₅₄ | Rₙ₅₁ | Ar49 | H | H | H | H | H | Rₙ₁₁ | H |
| Lₐ₂₉₅₅ | Rₙ₅₆ | Ar49 | H | H | H | H | H | Rₙ₁₁ | H |
| Lₐ₂₉₅₆ | Rₙ₅₉ | Ar49 | H | H | H | H | H | Rₙ₁₁ | H |
| Lₐ₂₉₅₇ | Rₙ₆₀ | Ar49 | H | H | H | H | H | Rₙ₁₁ | H |
| Lₐ₂₉₅₈ | Rₙ₆₁ | Ar49 | H | H | H | H | H | Rₙ₁₁ | H |
| Lₐ₂₉₅₉ | Rₙ₆₂ | Ar49 | H | H | H | H | H | Rₙ₁₁ | H |
| Lₐ₂₉₆₀ | Rₙ₆₄ | Ar49 | H | H | H | H | H | Rₙ₁₁ | H |
| Lₐ₂₉₆₁ | Rₙ₆₅ | Ar49 | H | H | H | H | H | Rₙ₁₁ | H |
| Lₐ₂₉₆₂ | Rₙ₆₉ | Ar49 | H | H | H | H | H | Rₙ₁₁ | H |
| Lₐ₂₉₆₃ | Rₙ₇₀ | Ar49 | H | H | H | H | H | Rₙ₁₁ | H |
| Lₐ₂₉₆₄ | Rₙ₈₁ | Ar49 | H | H | H | H | H | Rₙ₁₁ | H |
| Lₐ₂₉₆₅ | Rₙ₁ | Ar49 | H | H | H | H | H | Rₙ₅₉ | H |
| Lₐ₂₉₆₆ | Rₙ₄ | Ar49 | H | H | H | H | H | Rₙ₅₉ | H |
| Lₐ₂₉₆₇ | Rₙ₅ | Ar49 | H | H | H | H | H | Rₙ₅₉ | H |
| Lₐ₂₉₆₈ | Rₙ₇ | Ar49 | H | H | H | H | H | Rₙ₅₉ | H |
| Lₐ₂₉₆₉ | Rₙ₁₁ | Ar49 | H | H | H | H | H | Rₙ₅₉ | H |
| Lₐ₂₉₇₀ | Rₙ₂₀ | Ar49 | H | H | H | H | H | Rₙ₅₉ | H |
| Lₐ₂₉₇₁ | Rₙ₂₁ | Ar49 | H | H | H | H | H | Rₙ₅₉ | H |
| Lₐ₂₉₇₂ | Rₙ₅₁ | Ar49 | H | H | H | H | H | Rₙ₅₉ | H |
| Lₐ₂₉₇₃ | Rₙ₅₆ | Ar49 | H | H | H | H | H | Rₙ₅₉ | H |
| Lₐ₂₉₇₄ | Rₙ₅₉ | Ar49 | H | H | H | H | H | Rₙ₅₉ | H |
| Lₐ₂₉₇₅ | Rₙ₆₀ | Ar49 | H | H | H | H | H | Rₙ₅₉ | H |
| Lₐ₂₉₇₆ | Rₙ₆₁ | Ar49 | H | H | H | H | H | Rₙ₅₉ | H |
| Lₐ₂₉₇₇ | Rₙ₆₂ | Ar49 | H | H | H | H | H | Rₙ₅₉ | H |
| Lₐ₂₉₇₈ | Rₙ₆₄ | Ar49 | H | H | H | H | H | Rₙ₅₉ | H |
| Lₐ₂₉₇₉ | Rₙ₆₅ | Ar49 | H | H | H | H | H | Rₙ₅₉ | H |
| Lₐ₂₉₈₀ | Rₙ₆₉ | Ar49 | H | H | H | H | H | Rₙ₅₉ | H |
| Lₐ₂₉₈₁ | Rₙ₇₀ | Ar49 | H | H | H | H | H | Rₙ₅₉ | H |
| Lₐ₂₉₈₂ | Rₙ₈₁ | Ar49 | H | H | H | H | H | Rₙ₅₉ | H |
| Lₐ₂₉₈₃ | Rₙ₁ | Ar49 | H | H | H | H | H | Rₙ₆₀ | H |
| Lₐ₂₉₈₄ | Rₙ₄ | Ar49 | H | H | H | H | H | Rₙ₆₀ | H |
| Lₐ₂₉₈₅ | Rₙ₅ | Ar49 | H | H | H | H | H | Rₙ₆₀ | H |
| Lₐ₂₉₈₆ | Rₙ₇ | Ar49 | H | H | H | H | H | Rₙ₆₀ | H |
| Lₐ₂₉₈₇ | Rₙ₁₁ | Ar49 | H | H | H | H | H | Rₙ₆₀ | H |
| Lₐ₂₉₈₈ | Rₙ₂₀ | Ar49 | H | H | H | H | H | Rₙ₆₀ | H |
| Lₐ₂₉₈₉ | Rₙ₂₁ | Ar49 | H | H | H | H | H | Rₙ₆₀ | H |
| Lₐ₂₉₉₀ | Rₙ₅₁ | Ar49 | H | H | H | H | H | Rₙ₆₀ | H |
| Lₐ₂₉₉₁ | Rₙ₅₆ | Ar49 | H | H | H | H | H | Rₙ₆₀ | H |
| Lₐ₂₉₉₂ | Rₙ₅₉ | Ar49 | H | H | H | H | H | Rₙ₆₀ | H |
| Lₐ₂₉₉₃ | Rₙ₆₀ | Ar49 | H | H | H | H | H | Rₙ₆₀ | H |
| Lₐ₂₉₉₄ | Rₙ₆₁ | Ar49 | H | H | H | H | H | Rₙ₆₀ | H |
| Lₐ₂₉₉₅ | Rₙ₆₂ | Ar49 | H | H | H | H | H | Rₙ₆₀ | H |
| Lₐ₂₉₉₆ | Rₙ₆₄ | Ar49 | H | H | H | H | H | Rₙ₆₀ | H |
| Lₐ₂₉₉₇ | Rₙ₆₅ | Ar49 | H | H | H | H | H | Rₙ₆₀ | H |
| Lₐ₂₉₉₈ | Rₙ₆₉ | Ar49 | H | H | H | H | H | Rₙ₆₀ | H |
| Lₐ₂₉₉₉ | Rₙ₇₀ | Ar49 | H | H | H | H | H | Rₙ₆₀ | H |
| Lₐ₃₀₀₀ | Rₙ₈₁ | Ar49 | H | H | H | H | H | Rₙ₆₀ | H |
| Lₐ₃₀₀₁ | Rₙ₁ | Ar49 | H | H | H | H | H | Rₙ₆₄ | H |
| Lₐ₃₀₀₂ | Rₙ₄ | Ar49 | H | H | H | H | H | Rₙ₆₄ | H |
| Lₐ₃₀₀₃ | Rₙ₅ | Ar49 | H | H | H | H | H | Rₙ₆₄ | H |
| Lₐ₃₀₀₄ | Rₙ₇ | Ar49 | H | H | H | H | H | Rₙ₆₄ | H |
| Lₐ₃₀₀₅ | Rₙ₁₁ | Ar49 | H | H | H | H | H | Rₙ₆₄ | H |
| Lₐ₃₀₀₆ | Rₙ₂₀ | Ar49 | H | H | H | H | H | Rₙ₆₄ | H |
| Lₐ₃₀₀₇ | Rₙ₂₁ | Ar49 | H | H | H | H | H | Rₙ₆₄ | H |
| Lₐ₃₀₀₈ | Rₙ₅₁ | Ar49 | H | H | H | H | H | Rₙ₆₄ | H |
| Lₐ₃₀₀₉ | Rₙ₅₆ | Ar49 | H | H | H | H | H | Rₙ₆₄ | H |
| Lₐ₃₀₁₀ | Rₙ₅₉ | Ar49 | H | H | H | H | H | Rₙ₆₄ | H |
| Lₐ₃₀₁₁ | Rₙ₆₀ | Ar49 | H | H | H | H | H | Rₙ₆₄ | H |
| Lₐ₃₀₁₂ | Rₙ₆₁ | Ar49 | H | H | H | H | H | Rₙ₆₄ | H |
| Lₐ₃₀₁₃ | Rₙ₆₂ | Ar49 | H | H | H | H | H | Rₙ₆₄ | H |
| Lₐ₃₀₁₄ | Rₙ₆₄ | Ar49 | H | H | H | H | H | Rₙ₆₄ | H |
| Lₐ₃₀₁₅ | Rₙ₆₅ | Ar49 | H | H | H | H | H | Rₙ₆₄ | H |
| Lₐ₃₀₁₆ | Rₙ₆₉ | Ar49 | H | H | H | H | H | Rₙ₆₄ | H |
| Lₐ₃₀₁₇ | Rₙ₇₀ | Ar49 | H | H | H | H | H | Rₙ₆₄ | H |
| Lₐ₃₀₁₈ | Rₙ₈₁ | Ar49 | H | H | H | H | H | Rₙ₆₄ | H |
| Lₐ₃₀₁₉ | Rₙ₁ | Ar49 | H | H | H | H | H | Me | H |
| Lₐ₃₀₂₀ | Rₙ₄ | Ar49 | H | H | H | H | H | Me | H |
| Lₐ₃₀₂₁ | Rₙ₅ | Ar49 | H | H | H | H | H | Me | H |
| Lₐ₃₀₂₂ | Rₙ₇ | Ar49 | H | H | H | H | H | Me | H |
| Lₐ₃₀₂₃ | Rₙ₁₁ | Ar49 | H | H | H | H | H | Me | H |
| Lₐ₃₀₂₄ | Rₙ₂₀ | Ar49 | H | H | H | H | H | Me | H |
| Lₐ₃₀₂₅ | Rₙ₂₁ | Ar49 | H | H | H | H | H | Me | H |
| Lₐ₃₀₂₆ | Rₙ₅₁ | Ar49 | H | H | H | H | H | Me | H |
| Lₐ₃₀₂₇ | Rₙ₅₆ | Ar49 | H | H | H | H | H | Me | H |
| Lₐ₃₀₂₈ | Rₙ₅₉ | Ar49 | H | H | H | H | H | Me | H |
| Lₐ₃₀₂₉ | Rₙ₆₀ | Ar49 | H | H | H | H | H | Me | H |
| Lₐ₃₀₃₀ | Rₙ₆₁ | Ar49 | H | H | H | H | H | Me | H |
| Lₐ₃₀₃₁ | Rₙ₆₂ | Ar49 | H | H | H | H | H | Me | H |
| Lₐ₃₀₃₂ | Rₙ₆₄ | Ar49 | H | H | H | H | H | Me | H |
| Lₐ₃₀₃₃ | Rₙ₆₅ | Ar49 | H | H | H | H | H | Me | H |
| Lₐ₃₀₃₄ | Rₙ₆₉ | Ar49 | H | H | H | H | H | Me | H |
| Lₐ₃₀₃₅ | Rₙ₇₀ | Ar49 | H | H | H | H | H | Me | H |
| Lₐ₃₀₃₆ | Rₙ₈₁ | Ar49 | H | H | H | H | H | Me | H |
| Lₐ₃₀₃₇ | Rₙ₁ | Ar49 | H | H | H | H | Rₙ₁₁ | H | H |
| Lₐ₃₀₃₈ | Rₙ₄ | Ar49 | H | H | H | H | Rₙ₁₁ | H | H |
| Lₐ₃₀₃₉ | Rₙ₅ | Ar49 | H | H | H | H | Rₙ₁₁ | H | H |
| Lₐ₃₀₄₀ | Rₙ₇ | Ar49 | H | H | H | H | Rₙ₁₁ | H | H |
| Lₐ₃₀₄₁ | Rₙ₁₁ | Ar49 | H | H | H | H | Rₙ₁₁ | H | H |
| Lₐ₃₀₄₂ | Rₙ₂₀ | Ar49 | H | H | H | H | Rₙ₁₁ | H | H |
| Lₐ₃₀₄₃ | Rₙ₂₁ | Ar49 | H | H | H | H | Rₙ₁₁ | H | H |
| Lₐ₃₀₄₄ | Rₙ₅₁ | Ar49 | H | H | H | H | Rₙ₁₁ | H | H |
| Lₐ₃₀₄₅ | Rₙ₅₆ | Ar49 | H | H | H | H | Rₙ₁₁ | H | H |
| Lₐ₃₀₄₆ | Rₙ₅₉ | Ar49 | H | H | H | H | Rₙ₁₁ | H | H |
| Lₐ₃₀₄₇ | Rₙ₆₀ | Ar49 | H | H | H | H | Rₙ₁₁ | H | H |
| Lₐ₃₀₄₈ | Rₙ₆₁ | Ar49 | H | H | H | H | Rₙ₁₁ | H | H |
| Lₐ₃₀₄₉ | Rₙ₆₂ | Ar49 | H | H | H | H | Rₙ₁₁ | H | H |
| Lₐ₃₀₅₀ | Rₙ₆₄ | Ar49 | H | H | H | H | Rₙ₁₁ | H | H |
| Lₐ₃₀₅₁ | Rₙ₆₅ | Ar49 | H | H | H | H | Rₙ₁₁ | H | H |
| Lₐ₃₀₅₂ | Rₙ₆₉ | Ar49 | H | H | H | H | Rₙ₁₁ | H | H |
| Lₐ₃₀₅₃ | Rₙ₇₀ | Ar49 | H | H | H | H | Rₙ₁₁ | H | H |
| Lₐ₃₀₅₄ | Rₙ₈₁ | Ar49 | H | H | H | H | Rₙ₁₁ | H | H |
| Lₐ₃₀₅₅ | Rₙ₁ | Ar49 | H | H | H | H | Rₙ₅₉ | H | H |
| Lₐ₃₀₅₆ | Rₙ₄ | Ar49 | H | H | H | H | Rₙ₅₉ | H | H |
| Lₐ₃₀₅₇ | Rₙ₅ | Ar49 | H | H | H | H | Rₙ₅₉ | H | H |
| Lₐ₃₀₅₈ | Rₙ₇ | Ar49 | H | H | H | H | Rₙ₅₉ | H | H |
| Lₐ₃₀₅₉ | Rₙ₁₁ | Ar49 | H | H | H | H | Rₙ₅₉ | H | H |
| Lₐ₃₀₆₀ | Rₙ₂₀ | Ar49 | H | H | H | H | Rₙ₅₉ | H | H |
| Lₐ₃₀₆₁ | Rₙ₂₁ | Ar49 | H | H | H | H | Rₙ₅₉ | H | H |
| Lₐ₃₀₆₂ | Rₙ₅₁ | Ar49 | H | H | H | H | Rₙ₅₉ | H | H |
| Lₐ₃₀₆₃ | Rₙ₅₆ | Ar49 | H | H | H | H | Rₙ₅₉ | H | H |
| Lₐ₃₀₆₄ | Rₙ₅₉ | Ar49 | H | H | H | H | Rₙ₅₉ | H | H |
| Lₐ₃₀₆₅ | Rₙ₆₀ | Ar49 | H | H | H | H | Rₙ₅₉ | H | H |
| Lₐ₃₀₆₆ | Rₙ₆₁ | Ar49 | H | H | H | H | Rₙ₅₉ | H | H |
| Lₐ₃₀₆₇ | Rₙ₆₂ | Ar49 | H | H | H | H | Rₙ₅₉ | H | H |
| Lₐ₃₀₆₈ | Rₙ₆₄ | Ar49 | H | H | H | H | Rₙ₅₉ | H | H |
| Lₐ₃₀₆₉ | Rₙ₆₅ | Ar49 | H | H | H | H | Rₙ₅₉ | H | H |
| Lₐ₃₀₇₀ | Rₙ₆₉ | Ar49 | H | H | H | H | Rₙ₅₉ | H | H |
| Lₐ₃₀₇₁ | Rₙ₇₀ | Ar49 | H | H | H | H | Rₙ₅₉ | H | H |
| Lₐ₃₀₇₂ | Rₙ₈₁ | Ar49 | H | H | H | H | Rₙ₅₉ | H | H |
| Lₐ₃₀₇₃ | Rₙ₁ | Ar49 | D | H | H | H | Rₙ₆₀ | H | H |
| Lₐ₃₀₇₄ | Rₙ₄ | Ar49 | H | H | H | H | Rₙ₆₀ | H | H |
| Lₐ₃₀₇₅ | Rₙ₅ | Ar49 | H | H | H | H | Rₙ₆₀ | H | H |
| Lₐ₃₀₇₆ | Rₙ₇ | Ar49 | H | H | H | H | Rₙ₆₀ | H | H |
| Lₐ₃₀₇₇ | Rₙ₁₁ | Ar49 | H | H | H | H | Rₙ₆₀ | H | H |
| Lₐ₃₀₇₈ | Rₙ₂₀ | Ar49 | H | H | H | H | Rₙ₆₀ | H | H |
| Lₐ₃₀₇₉ | Rₙ₂₁ | Ar49 | H | H | H | H | Rₙ₆₀ | H | H |
| Lₐ₃₀₈₀ | Rₙ₅₁ | Ar49 | H | H | H | H | Rₙ₆₀ | H | H |
| Lₐ₃₀₈₁ | Rₙ₅₆ | Ar49 | H | H | H | H | Rₙ₆₀ | H | H |
| Lₐ₃₀₈₂ | Rₙ₅₉ | Ar49 | H | H | H | H | Rₙ₆₀ | H | H |
| Lₐ₃₀₈₃ | Rₙ₆₀ | Ar49 | H | H | H | H | Rₙ₆₀ | H | H |
| Lₐ₃₀₈₄ | Rₙ₆₁ | Ar49 | H | H | H | H | Rₙ₆₀ | H | H |
| Lₐ₃₀₈₅ | Rₙ₆₂ | Ar49 | H | H | H | H | Rₙ₆₀ | H | H |
| Lₐ₃₀₈₆ | Rₙ₆₄ | Ar49 | H | H | H | H | Rₙ₆₀ | H | H |
| Lₐ₃₀₈₇ | Rₙ₆₅ | Ar49 | H | H | H | H | Rₙ₆₀ | H | H |
| Lₐ₃₀₈₈ | Rₙ₆₉ | Ar49 | H | H | H | H | Rₙ₆₀ | H | H |
| Lₐ₃₀₈₉ | Rₙ₇₀ | Ar49 | H | H | H | H | Rₙ₆₀ | H | H |
| Lₐ₃₀₉₀ | Rₙ₈₁ | Ar49 | H | H | H | H | Rₙ₆₀ | H | H |
| Lₐ₃₀₉₁ | Rₙ₁ | Ar49 | H | H | H | H | Rₙ₆₄ | H | H |
| Lₐ₃₀₉₂ | Rₙ₄ | Ar49 | H | H | H | H | Rₙ₆₄ | H | H |
| Lₐ₃₀₉₃ | Rₙ₅ | Ar49 | H | H | H | H | Rₙ₆₄ | H | H |
| Lₐ₃₀₉₄ | Rₙ₇ | Ar49 | H | H | H | H | Rₙ₆₄ | H | H |
| Lₐ₃₀₉₅ | Rₙ₁₁ | Ar49 | H | H | H | H | Rₙ₆₄ | H | H |
| Lₐ₃₀₉₆ | Rₙ₂₀ | Ar49 | H | H | H | H | Rₙ₆₄ | H | H |
| Lₐ₃₀₉₇ | Rₙ₂₁ | Ar49 | H | H | H | H | Rₙ₆₄ | H | H |
| Lₐ₃₀₉₈ | Rₙ₅₁ | Ar49 | H | H | H | H | Rₙ₆₄ | H | H |
| Lₐ₃₀₉₉ | Rₙ₅₆ | Ar49 | H | H | H | H | Rₙ₆₄ | H | H |
| Lₐ₃₁₀₀ | Rₙ₅₉ | Ar49 | H | H | H | H | Rₙ₆₄ | H | H |
| Lₐ₃₁₀₁ | Rₙ₆₀ | Ar49 | H | H | H | H | Rₙ₆₄ | H | H |
| Lₐ₃₁₀₂ | Rₙ₆₁ | Ar49 | H | H | H | H | Rₙ₆₄ | H | H |
| Lₐ₃₁₀₃ | Rₙ₆₂ | Ar49 | H | H | H | H | Rₙ₆₄ | H | H |
| Lₐ₃₁₀₄ | Rₙ₆₄ | Ar49 | H | H | H | H | Rₙ₆₄ | H | H |
| Lₐ₃₁₀₅ | Rₙ₆₅ | Ar49 | H | H | H | H | Rₙ₆₄ | H | H |
| Lₐ₃₁₀₆ | Rₙ₆₉ | Ar49 | H | H | H | H | Rₙ₆₄ | H | H |
| Lₐ₃₁₀₇ | Rₙ₇₀ | Ar49 | H | H | H | H | Rₙ₆₄ | H | H |
| Lₐ₃₁₀₈ | Rₙ₈₁ | Ar49 | H | H | H | H | Rₙ₆₄ | H | H |
| Lₐ₃₁₀₉ | Rₙ₁ | Ar49 | H | H | H | H | Me | H | H |
| Lₐ₃₁₁₀ | Rₙ₄ | Ar49 | H | H | H | H | Me | H | H |
| Lₐ₃₁₁₁ | Rₙ₅ | Ar49 | H | H | H | H | Me | H | H |
| Lₐ₃₁₁₂ | Rₙ₇ | Ar49 | H | H | H | H | Me | H | H |
| Lₐ₃₁₁₃ | Rₙ₁₁ | Ar49 | H | H | H | H | Me | H | H |
| Lₐ₃₁₁₄ | Rₙ₂₀ | Ar49 | H | H | H | H | Me | H | H |
| Lₐ₃₁₁₅ | Rₙ₂₁ | Ar49 | H | H | H | H | Me | H | H |
| Lₐ₃₁₁₆ | Rₙ₅₁ | Ar49 | H | H | H | H | Me | H | H |
| Lₐ₃₁₁₇ | Rₙ₅₆ | Ar49 | H | H | H | H | Me | H | H |
| Lₐ₃₁₁₈ | Rₙ₅₉ | Ar49 | H | H | H | H | Me | H | H |
| Lₐ₃₁₁₉ | Rₙ₆₀ | Ar49 | H | H | H | H | Me | H | H |
| Lₐ₃₁₂₀ | Rₙ₆₁ | Ar49 | H | H | H | H | Me | H | H |
| Lₐ₃₁₂₁ | Rₙ₆₂ | Ar49 | H | H | H | H | Me | H | H |
| Lₐ₃₁₂₂ | Rₙ₆₄ | Ar49 | H | H | H | H | Me | H | H |
| Lₐ₃₁₂₃ | Rₙ₆₅ | Ar49 | H | H | H | H | Me | H | H |
| Lₐ₃₁₂₄ | Rₙ₆₉ | Ar49 | H | H | H | H | Me | H | H |
| Lₐ₃₁₂₅ | Rₙ₇₀ | Ar49 | H | H | H | H | Me | H | H |
| Lₐ₃₁₂₆ | Rₙ₈₁ | Ar49 | H | H | H | H | Me | H | H |
| Lₐ₃₁₂₇ | Rₙ₁ | Ar49 | H | H | F | H | H | H | H |
| Lₐ₃₁₂₈ | Rₙ₄ | Ar49 | H | H | F | H | H | H | H |
| Lₐ₃₁₂₉ | Rₙ₇ | Ar49 | H | H | F | H | H | H | H |
| Lₐ₃₁₃₀ | Rₙ₂₀ | Ar49 | H | D | F | H | H | H | H |
| Lₐ₃₁₃₁ | Rₙ₂₁ | Ar49 | H | H | F | H | H | H | H |
| Lₐ₃₁₃₂ | Rₙ₅₆ | Ar49 | H | H | F | H | H | H | H |
| Lₐ₃₁₃₃ | Rₙ₅₉ | Ar49 | H | H | F | H | H | H | H |
| Lₐ₃₁₃₄ | Rₙ₆₁ | Ar49 | H | H | F | H | H | H | H |
| Lₐ₃₁₃₅ | Rₙ₆₂ | Ar49 | H | H | F | H | H | H | H |
| Lₐ₃₁₃₆ | Rₙ₆₄ | Ar49 | H | H | F | H | H | H | H |
| Lₐ₃₁₃₇ | Rₙ₆₉ | Ar49 | H | H | F | H | H | H | H |
| Lₐ₃₁₃₈ | Rₙ₇₀ | Ar49 | H | H | F | H | H | H | H |
| Lₐ₃₁₃₉ | Rₙ₁ | Ar49 | H | H | F | H | Rₙ₁₁ | H | H |
| Lₐ₃₁₄₀ | Rₙ₄ | Ar49 | H | H | F | H | Rₙ₁₁ | H | H |
| Lₐ₃₁₄₁ | Rₙ₇ | Ar49 | H | H | F | H | Rₙ₁₁ | H | H |
| Lₐ₃₁₄₂ | Rₙ₂₀ | Ar49 | H | H | F | H | Rₙ₁₁ | H | H |
| Lₐ₃₁₄₃ | Rₙ₂₁ | Ar49 | H | H | F | H | Rₙ₁₁ | H | H |
| Lₐ₃₁₄₄ | Rₙ₅₆ | Ar49 | H | H | F | H | Rₙ₁₁ | H | H |
| Lₐ₃₁₄₅ | Rₙ₅₉ | Ar49 | H | H | F | H | Rₙ₁₁ | H | H |
| Lₐ₃₁₄₆ | Rₙ₆₁ | Ar49 | H | H | F | H | Rₙ₁₁ | H | H |
| Lₐ₃₁₄₇ | Rₙ₆₂ | Ar49 | H | H | F | H | Rₙ₁₁ | H | H |
| Lₐ₃₁₄₈ | Rₙ₆₄ | Ar49 | H | H | F | H | Rₙ₁₁ | H | H |
| Lₐ₃₁₄₉ | Rₙ₆₉ | Ar49 | H | H | F | H | Rₙ₁₁ | H | H |
| Lₐ₃₁₅₀ | Rₙ₇₀ | Ar49 | H | H | F | H | Rₙ₁₁ | H | H |
| Lₐ₃₁₅₁ | Rₙ₁ | Ar49 | H | H | F | H | Rₙ₆₀ | H | H |
| Lₐ₃₁₅₂ | Rₙ₄ | Ar49 | H | H | F | H | Rₙ₆₀ | H | H |
| Lₐ₃₁₅₃ | Rₙ₇ | Ar49 | H | H | F | H | Rₙ₆₀ | H | H |
| Lₐ₃₁₅₄ | Rₙ₂₀ | Ar49 | D | H | F | H | Rₙ₆₀ | H | H |
| Lₐ₃₁₅₅ | Rₙ₂₁ | Ar49 | H | H | F | H | Rₙ₆₀ | H | H |
| Lₐ₃₁₅₆ | Rₙ₅₆ | Ar49 | H | H | F | H | Rₙ₆₀ | H | H |
| Lₐ₃₁₅₇ | Rₙ₅₉ | Ar49 | H | H | F | H | Rₙ₆₀ | H | H |
| Lₐ₃₁₅₈ | Rₙ₆₁ | Ar49 | H | H | F | H | Rₙ₆₀ | H | H |
| Lₐ₃₁₅₉ | Rₙ₆₂ | Ar49 | H | H | F | H | Rₙ₆₀ | H | H |
| Lₐ₃₁₆₀ | Rₙ₆₄ | Ar49 | H | H | F | H | Rₙ₆₀ | H | H |
| Lₐ₃₁₆₁ | Rₙ₆₉ | Ar49 | H | H | F | H | Rₙ₆₀ | H | H |
| Lₐ₃₁₆₂ | Rₙ₇₀ | Ar49 | H | H | F | H | Rₙ₆₀ | H | H |
| Lₐ₃₁₆₃ | Rₙ₁ | Ar49 | H | H | F | H | H | Rₙ₁₁ | H |
| Lₐ₃₁₆₄ | Rₙ₄ | Ar49 | H | H | F | H | H | Rₙ₁₁ | H |
| Lₐ₃₁₆₅ | Rₙ₇ | Ar49 | H | H | F | H | H | Rₙ₁₁ | H |
| Lₐ₃₁₆₆ | Rₙ₂₀ | Ar49 | H | H | F | H | H | Rₙ₁₁ | H |
| Lₐ₃₁₆₇ | Rₙ₂₁ | Ar49 | H | H | F | H | H | Rₙ₁₁ | H |
| Lₐ₃₁₆₈ | Rₙ₅₆ | Ar49 | H | H | F | H | H | Rₙ₁₁ | H |
| Lₐ₃₁₆₉ | Rₙ₅₉ | Ar49 | H | H | F | H | H | Rₙ₁₁ | H |
| Lₐ₃₁₇₀ | Rₙ₆₁ | Ar49 | H | H | F | H | H | Rₙ₁₁ | H |
| Lₐ₃₁₇₁ | Rₙ₆₂ | Ar49 | H | H | F | H | H | Rₙ₁₁ | H |
| Lₐ₃₁₇₂ | Rₙ₆₄ | Ar49 | H | H | F | H | H | Rₙ₁₁ | H |
| Lₐ₃₁₇₃ | Rₙ₆₉ | Ar49 | H | H | F | H | H | Rₙ₁₁ | H |
| Lₐ₃₁₇₄ | Rₙ₇₀ | Ar49 | H | H | F | H | H | Rₙ₁₁ | H |
| Lₐ₃₁₇₅ | Rₙ₁ | Ar49 | H | H | F | H | H | Rₙ₆₀ | H |
| Lₐ₃₁₇₆ | Rₙ₄ | Ar49 | H | H | F | H | H | Rₙ₆₀ | H |
| Lₐ₃₁₇₇ | Rₙ₇ | Ar49 | H | H | F | H | H | Rₙ₆₀ | H |
| Lₐ₃₁₇₈ | Rₙ₂₀ | Ar49 | H | H | F | H | H | Rₙ₆₀ | H |
| Lₐ₃₁₇₉ | Rₙ₂₁ | Ar49 | H | H | F | H | H | Rₙ₆₀ | H |
| Lₐ₃₁₈₀ | Rₙ₅₆ | Ar49 | H | H | F | H | H | Rₙ₆₀ | H |
| Lₐ₃₁₈₁ | Rₙ₅₉ | Ar49 | H | H | F | H | H | Rₙ₆₀ | H |
| Lₐ₃₁₈₂ | Rₙ₆₁ | Ar49 | H | H | F | H | H | Rₙ₆₀ | H |
| Lₐ₃₁₈₃ | Rₙ₆₂ | Ar49 | H | H | F | H | H | Rₙ₆₀ | H |
| Lₐ₃₁₈₄ | Rₙ₆₄ | Ar49 | H | H | F | H | H | Rₙ₆₀ | H |
| Lₐ₃₁₈₅ | Rₙ₆₉ | Ar49 | H | H | F | H | H | Rₙ₆₀ | H |
| Lₐ₃₁₈₆ | Rₙ₇₀ | Ar49 | H | H | F | H | H | Rₙ₆₀ | H |
| Lₐ₃₁₈₇ | Rₙ₁ | Ar49 | H | H | CN | H | H | H | H |
| Lₐ₃₁₈₈ | Rₙ₄ | Ar49 | H | H | CN | H | H | H | H |
| Lₐ₃₁₈₉ | Rₙ₇ | Ar49 | H | H | CN | H | H | H | H |
| Lₐ₃₁₉₀ | Rₙ₂₀ | Ar49 | H | H | CN | H | H | H | H |
| Lₐ₃₁₉₁ | Rₙ₂₁ | Ar49 | H | H | CN | H | H | H | H |
| Lₐ₃₁₉₂ | Rₙ₅₆ | Ar49 | H | H | CN | H | H | H | H |
| Lₐ₃₁₉₃ | Rₙ₅₉ | Ar49 | H | H | CN | H | H | H | H |
| Lₐ₃₁₉₄ | Rₙ₆₁ | Ar49 | H | H | CN | H | H | H | H |
| Lₐ₃₁₉₅ | Rₙ₆₂ | Ar49 | H | H | CN | H | H | H | H |
| Lₐ₃₁₉₆ | Rₙ₆₄ | Ar49 | H | H | CN | H | H | H | H |
| Lₐ₃₁₉₇ | Rₙ₆₉ | Ar49 | H | H | CN | H | H | H | H |
| Lₐ₃₁₉₈ | Rₙ₇₀ | Ar49 | H | H | CN | H | H | H | H |
| Lₐ₃₁₉₉ | Rₙ₁ | Ar49 | H | CN | H | H | H | H | H |
| Lₐ₃₂₀₀ | Rₙ₄ | Ar49 | H | CN | H | H | H | H | H |
| Lₐ₃₂₀₁ | Rₙ₇ | Ar49 | H | CN | H | H | H | H | H |
| Lₐ₃₂₀₂ | Rₙ₂₀ | Ar49 | H | CN | H | H | H | H | H |
| Lₐ₃₂₀₃ | Rₙ₂₁ | Ar49 | H | CN | H | H | H | H | H |
| Lₐ₃₂₀₄ | Rₙ₅₆ | Ar49 | H | CN | H | H | H | H | H |
| Lₐ₃₂₀₅ | Rₙ₅₉ | Ar49 | H | CN | H | H | H | H | H |
| Lₐ₃₂₀₆ | Rₙ₆₁ | Ar49 | H | CN | H | H | H | H | H |
| Lₐ₃₂₀₇ | Rₙ₆₂ | Ar49 | H | CN | H | H | H | H | H |
| Lₐ₃₂₀₈ | Rₙ₆₄ | Ar49 | H | CN | H | H | H | H | H |
| Lₐ₃₂₀₉ | Rₙ₆₉ | Ar49 | H | CN | H | H | H | H | H |
| Lₐ₃₂₁₀ | Rₙ₇₀ | Ar49 | H | CN | H | H | H | H | H |
| Lₐ₃₂₁₁ | Rₙ₁ | Ar49 | CN | H | H | H | H | H | H |
| Lₐ₃₂₁₂ | Rₙ₄ | Ar49 | CN | H | H | H | H | H | H |
| Lₐ₃₂₁₃ | Rₙ₇ | Ar49 | CN | H | H | H | H | H | H |
| Lₐ₃₂₁₄ | Rₙ₂₀ | Ar49 | CN | H | H | H | H | H | H |
| Lₐ₃₂₁₅ | Rₙ₂₁ | Ar49 | CN | H | H | H | H | H | H |
| Lₐ₃₂₁₆ | Rₙ₅₆ | Ar49 | CN | H | H | H | H | H | H |
| Lₐ₃₂₁₇ | Rₙ₅₉ | Ar49 | CN | H | H | H | H | H | H |
| Lₐ₃₂₁₈ | Rₙ₆₁ | Ar49 | CN | H | H | H | H | H | H |
| Lₐ₃₂₁₉ | Rₙ₆₂ | Ar49 | CN | H | H | H | H | H | H |
| Lₐ₃₂₂₀ | Rₙ₆₄ | Ar49 | CN | H | H | H | H | H | H |
| Lₐ₃₂₂₁ | Rₙ₆₉ | Ar49 | CN | H | H | H | H | H | H |
| Lₐ₃₂₂₂ | Rₙ₇₀ | Ar49 | CN | H | H | H | H | H | H |
| Lₐ₃₂₂₃ | Rₙ₁ | Ar49 | H | H | CN | H | Rₙ₁₁ | H | H |
| Lₐ₃₂₂₄ | Rₙ₄ | Ar49 | H | H | CN | H | Rₙ₁₁ | H | H |
| Lₐ₃₂₂₅ | Rₙ₇ | Ar49 | H | H | CN | H | Rₙ₁₁ | H | H |
| Lₐ₃₂₂₆ | Rₙ₂₀ | Ar49 | H | H | CN | H | Rₙ₁₁ | H | H |
| Lₐ₃₂₂₇ | Rₙ₂₁ | Ar49 | H | H | CN | H | Rₙ₁₁ | H | H |
| Lₐ₃₂₂₈ | Rₙ₅₆ | Ar49 | H | H | CN | H | Rₙ₁₁ | H | H |
| Lₐ₃₂₂₉ | Rₙ₅₉ | Ar49 | H | H | CN | H | Rₙ₁₁ | H | H |
| Lₐ₃₂₃₀ | Rₙ₆₁ | Ar49 | H | H | CN | H | Rₙ₁₁ | H | H |
| Lₐ₃₂₃₁ | Rₙ₆₂ | Ar49 | H | H | CN | H | Rₙ₁₁ | H | H |
| Lₐ₃₂₃₂ | Rₙ₆₄ | Ar49 | H | H | CN | H | Rₙ₁₁ | H | H |
| Lₐ₃₂₃₃ | Rₙ₆₉ | Ar49 | H | H | CN | H | Rₙ₁₁ | H | H |
| Lₐ₃₂₃₄ | Rₙ₇₀ | Ar49 | H | H | CN | H | Rₙ₁₁ | H | H |
| Lₐ₃₂₃₅ | Rₙ₁ | Ar49 | H | H | CN | H | Rₙ₆₀ | H | H |
| Lₐ₃₂₃₆ | Rₙ₄ | Ar49 | H | H | CN | H | Rₙ₆₀ | H | H |
| Lₐ₃₂₃₇ | Rₙ₇ | Ar49 | H | H | CN | H | Rₙ₆₀ | H | H |
| Lₐ₃₂₃₈ | Rₙ₂₀ | Ar49 | H | H | CN | H | Rₙ₆₀ | H | H |
| Lₐ₃₂₃₉ | Rₙ₂₁ | Ar49 | H | H | CN | H | Rₙ₆₀ | H | H |
| Lₐ₃₂₄₀ | Rₙ₅₆ | Ar49 | H | H | CN | H | Rₙ₆₀ | H | H |
| Lₐ₃₂₄₁ | Rₙ₅₉ | Ar49 | H | H | CN | H | Rₙ₆₀ | H | H |
| Lₐ₃₂₄₂ | Rₙ₆₁ | Ar49 | H | H | CN | H | Rₙ₆₀ | H | H |
| Lₐ₃₂₄₃ | Rₙ₆₂ | Ar49 | H | H | CN | H | Rₙ₆₀ | H | H |
| Lₐ₃₂₄₄ | Rₙ₆₄ | Ar49 | H | H | CN | H | Rₙ₆₀ | H | H |
| Lₐ₃₂₄₅ | Rₙ₆₉ | Ar49 | H | H | CN | H | Rₙ₆₀ | H | H |
| Lₐ₃₂₄₆ | Rₙ₇₀ | Ar49 | H | H | CN | H | Rₙ₆₀ | H | H |
| Lₐ₃₂₄₇ | Rₙ₁ | Ar49 | H | H | CN | H | Rₙ₆₄ | H | H |
| Lₐ₃₂₄₈ | Rₙ₄ | Ar49 | H | H | CN | H | Rₙ₆₄ | H | H |
| Lₐ₃₂₄₉ | Rₙ₇ | Ar49 | H | H | CN | H | Rₙ₆₄ | H | H |
| Lₐ₃₂₅₀ | Rₙ₂₀ | Ar49 | H | H | CN | H | Rₙ₆₄ | H | H |
| Lₐ₃₂₅₁ | Rₙ₂₁ | Ar49 | H | H | CN | H | Rₙ₆₄ | H | H |
| Lₐ₃₂₅₂ | Rₙ₅₆ | Ar49 | H | H | CN | H | Rₙ₆₄ | H | H |
| Lₐ₃₂₅₃ | Rₙ₅₉ | Ar49 | H | H | CN | H | Rₙ₆₄ | H | H |
| Lₐ₃₂₅₄ | Rₙ₆₁ | Ar49 | H | H | CN | H | Rₙ₆₄ | H | H |
| Lₐ₃₂₅₅ | Rₙ₆₂ | Ar49 | H | H | CN | H | Rₙ₆₄ | H | H |
| Lₐ₃₂₅₆ | Rₙ₆₄ | Ar49 | H | H | CN | H | Rₙ₆₄ | H | H |
| Lₐ₃₂₅₇ | Rₙ₆₉ | Ar49 | H | H | CN | H | Rₙ₆₄ | H | H |
| Lₐ₃₂₅₈ | Rₙ₇₀ | Ar49 | H | H | CN | H | Rₙ₆₄ | H | H |
| Lₐ₃₂₅₉ | Rₙ₁ | Ar49 | H | H | CN | H | H | Rₙ₁₁ | H |
| Lₐ₃₂₆₀ | Rₙ₄ | Ar49 | H | H | CN | H | H | Rₙ₁₁ | H |
| Lₐ₃₂₆₁ | Rₙ₇ | Ar49 | H | H | CN | H | H | Rₙ₁₁ | H |
| Lₐ₃₂₆₂ | Rₙ₂₀ | Ar49 | H | H | CN | H | H | Rₙ₁₁ | H |
| Lₐ₃₂₆₃ | Rₙ₂₁ | Ar49 | D | H | CN | H | H | Rₙ₁₁ | H |
| Lₐ₃₂₆₄ | Rₙ₅₆ | Ar49 | H | H | CN | H | H | Rₙ₁₁ | H |
| Lₐ₃₂₆₅ | Rₙ₅₉ | Ar49 | H | H | CN | H | H | Rₙ₁₁ | H |
| Lₐ₃₂₆₆ | Rₙ₆₁ | Ar49 | H | H | CN | H | H | Rₙ₁₁ | H |
| Lₐ₃₂₆₇ | Rₙ₆₂ | Ar49 | H | H | CN | H | H | Rₙ₁₁ | H |
| Lₐ₃₂₆₈ | Rₙ₆₄ | Ar49 | H | H | CN | H | H | Rₙ₁₁ | H |
| Lₐ₃₂₆₉ | Rₙ₆₉ | Ar49 | H | H | CN | H | H | Rₙ₁₁ | H |
| Lₐ₃₂₇₀ | Rₙ₇₀ | Ar49 | H | H | CN | H | H | Rₙ₁₁ | H |
| Lₐ₃₂₇₁ | Rₙ₁ | Ar49 | H | H | CN | H | H | Rₙ₆₀ | H |
| Lₐ₃₂₇₂ | Rₙ₄ | Ar49 | H | H | CN | H | H | Rₙ₆₀ | H |
| Lₐ₃₂₇₃ | Rₙ₇ | Ar49 | H | H | CN | H | H | Rₙ₆₀ | H |
| Lₐ₃₂₇₄ | Rₙ₂₀ | Ar49 | H | D | CN | H | H | Rₙ₆₀ | H |
| Lₐ₃₂₇₅ | Rₙ₂₁ | Ar49 | H | H | CN | H | H | Rₙ₆₀ | H |
| Lₐ₃₂₇₆ | Rₙ₅₆ | Ar49 | H | H | CN | H | H | Rₙ₆₀ | H |
| Lₐ₃₂₇₇ | Rₙ₅₉ | Ar49 | H | H | CN | H | H | Rₙ₆₀ | H |
| Lₐ₃₂₇₈ | Rₙ₆₁ | Ar49 | H | H | CN | H | H | Rₙ₆₀ | H |
| Lₐ₃₂₇₉ | Rₙ₆₂ | Ar49 | H | H | CN | H | H | Rₙ₆₀ | H |
| Lₐ₃₂₈₀ | Rₙ₆₄ | Ar49 | H | H | CN | H | H | Rₙ₆₀ | H |
| Lₐ₃₂₈₁ | Rₙ₆₉ | Ar49 | H | H | CN | H | H | Rₙ₆₀ | H |
| Lₐ₃₂₈₂ | Rₙ₇₀ | Ar49 | H | H | CN | H | H | Rₙ₆₀ | H |
| Lₐ₃₂₈₃ | Rₙ₁ | Ar49 | H | H | CN | H | H | Rₙ₆₄ | H |
| Lₐ₃₂₈₄ | Rₙ₄ | Ar49 | H | H | CN | H | H | Rₙ₆₄ | H |
| Lₐ₃₂₈₅ | Rₙ₇ | Ar49 | H | H | CN | H | H | Rₙ₆₄ | H |
| Lₐ₃₂₈₆ | Rₙ₂₀ | Ar49 | H | H | CN | H | H | Rₙ₆₄ | H |
| Lₐ₃₂₈₇ | Rₙ₂₁ | Ar49 | H | H | CN | H | H | Rₙ₆₄ | H |
| Lₐ₃₂₈₈ | Rₙ₅₆ | Ar49 | H | H | CN | H | H | Rₙ₆₄ | H |
| Lₐ₃₂₈₉ | Rₙ₅₉ | Ar49 | H | H | CN | H | H | Rₙ₆₄ | H |
| Lₐ₃₂₉₀ | Rₙ₆₁ | Ar49 | H | H | CN | H | H | Rₙ₆₄ | H |
| Lₐ₃₂₉₁ | Rₙ₆₂ | Ar49 | H | H | CN | H | H | Rₙ₆₄ | H |
| Lₐ₃₂₉₂ | Rₙ₆₄ | Ar49 | H | H | CN | H | H | Rₙ₆₄ | H |
| Lₐ₃₂₉₃ | Rₙ₆₉ | Ar49 | H | H | CN | H | H | Rₙ₆₄ | H |
| Lₐ₃₂₉₄ | Rₙ₇₀ | Ar49 | H | H | CN | H | H | Rₙ₆₄ | H |
| Lₐ₃₂₉₅ | Rₙ₁ | Ar57 | H | H | H | H | H | H | H |
| Lₐ₃₂₉₆ | Rₙ₄ | Ar57 | H | H | H | H | H | H | H |
| Lₐ₃₂₉₇ | Rₙ₅ | Ar57 | H | H | H | H | H | H | H |
| Lₐ₃₂₉₈ | Rₙ₇ | Ar57 | H | H | H | H | H | H | H |
| Lₐ₃₂₉₉ | Rₙ₁₁ | Ar57 | H | H | H | H | H | H | H |
| Lₐ₃₃₀₀ | Rₙ₂₀ | Ar57 | H | H | H | H | H | H | H |
| Lₐ₃₃₀₁ | Rₙ₂₁ | Ar57 | H | H | H | H | H | H | H |
| Lₐ₃₃₀₂ | Rₙ₅₁ | Ar57 | H | H | H | H | H | H | H |
| Lₐ₃₃₀₃ | Rₙ₅₆ | Ar57 | H | H | H | H | H | H | H |
| Lₐ₃₃₀₄ | Rₙ₅₉ | Ar57 | H | H | H | H | H | H | H |
| Lₐ₃₃₀₅ | Rₙ₆₀ | Ar57 | H | H | H | H | H | H | H |
| Lₐ₃₃₀₆ | Rₙ₆₁ | Ar57 | H | H | H | H | H | H | H |
| Lₐ₃₃₀₇ | Rₙ₆₂ | Ar57 | H | H | H | H | H | H | H |
| Lₐ₃₃₀₈ | Rₙ₆₄ | Ar57 | H | H | H | H | H | H | H |
| Lₐ₃₃₀₉ | Rₙ₆₅ | Ar57 | H | H | H | H | H | H | H |
| Lₐ₃₃₁₀ | Rₙ₆₉ | Ar57 | H | H | H | H | H | H | H |
| Lₐ₃₃₁₁ | Rₙ₇₀ | Ar57 | H | H | H | H | H | H | H |
| Lₐ₃₃₁₂ | Rₙ₈₁ | Ar57 | H | H | H | H | H | H | H |
| Lₐ₃₃₁₃ | Rₙ₁ | Ar57 | H | H | H | H | H | Rₙ₁₁ | H |
| Lₐ₃₃₁₄ | Rₙ₄ | Ar57 | H | H | H | H | H | Rₙ₁₁ | H |
| Lₐ₃₃₁₅ | Rₙ₅ | Ar57 | H | H | H | H | H | Rₙ₁₁ | H |
| Lₐ₃₃₁₆ | Rₙ₇ | Ar57 | H | H | H | H | H | Rₙ₁₁ | H |
| Lₐ₃₃₁₇ | Rₙ₁₁ | Ar57 | H | H | H | H | H | Rₙ₁₁ | H |
| Lₐ₃₃₁₈ | Rₙ₂₀ | Ar57 | H | H | H | H | H | Rₙ₁₁ | H |
| Lₐ₃₃₁₉ | Rₙ₂₁ | Ar57 | H | H | H | H | H | Rₙ₁₁ | H |
| Lₐ₃₃₂₀ | Rₙ₅₁ | Ar57 | H | H | H | H | H | Rₙ₁₁ | H |
| Lₐ₃₃₂₁ | Rₙ₅₆ | Ar57 | H | H | H | H | H | Rₙ₁₁ | H |
| Lₐ₃₃₂₂ | Rₙ₅₉ | Ar57 | H | H | H | H | H | Rₙ₁₁ | H |
| Lₐ₃₃₂₃ | Rₙ₆₀ | Ar57 | H | H | H | H | H | Rₙ₁₁ | H |
| Lₐ₃₃₂₄ | Rₙ₆₁ | Ar57 | H | H | H | H | H | Rₙ₁₁ | H |
| Lₐ₃₃₂₅ | Rₙ₆₂ | Ar57 | H | H | H | H | H | Rₙ₁₁ | H |
| Lₐ₃₃₂₆ | Rₙ₆₄ | Ar57 | H | H | H | H | H | Rₙ₁₁ | H |
| Lₐ₃₃₂₇ | Rₙ₆₅ | Ar57 | H | H | H | H | H | Rₙ₁₁ | H |
| Lₐ₃₃₂₈ | Rₙ₆₉ | Ar57 | H | H | H | H | H | Rₙ₁₁ | H |
| Lₐ₃₃₂₉ | Rₙ₇₀ | Ar57 | H | H | H | H | H | Rₙ₁₁ | H |
| Lₐ₃₃₃₀ | Rₙ₈₁ | Ar57 | H | H | H | H | H | Rₙ₁₁ | H |
| Lₐ₃₃₃₁ | Rₙ₁ | Ar57 | H | H | H | H | H | Rₙ₅₉ | H |
| Lₐ₃₃₃₂ | Rₙ₄ | Ar57 | H | H | H | H | H | Rₙ₅₉ | H |
| Lₐ₃₃₃₃ | Rₙ₅ | Ar57 | H | H | H | H | H | Rₙ₅₉ | H |
| Lₐ₃₃₃₄ | Rₙ₇ | Ar57 | H | H | H | H | H | Rₙ₅₉ | H |
| Lₐ₃₃₃₅ | Rₙ₁₁ | Ar57 | H | H | H | H | H | Rₙ₅₉ | H |
| Lₐ₃₃₃₆ | Rₙ₂₀ | Ar57 | H | H | H | H | H | Rₙ₅₉ | H |
| Lₐ₃₃₃₇ | Rₙ₂₁ | Ar57 | H | H | H | H | H | Rₙ₅₉ | H |
| Lₐ₃₃₃₈ | Rₙ₅₁ | Ar57 | H | H | H | H | H | Rₙ₅₉ | H |
| Lₐ₃₃₃₉ | Rₙ₅₆ | Ar57 | H | H | H | H | H | Rₙ₅₉ | H |
| Lₐ₃₃₄₀ | Rₙ₅₉ | Ar57 | H | H | H | H | H | Rₙ₅₉ | H |
| Lₐ₃₃₄₁ | Rₙ₆₀ | Ar57 | H | H | H | H | H | Rₙ₅₉ | H |
| Lₐ₃₃₄₂ | Rₙ₆₁ | Ar57 | H | H | H | H | H | Rₙ₅₉ | H |
| Lₐ₃₃₄₃ | Rₙ₆₂ | Ar57 | H | H | H | H | H | Rₙ₅₉ | H |
| Lₐ₃₃₄₄ | Rₙ₆₄ | Ar57 | H | H | H | H | H | Rₙ₅₉ | H |
| Lₐ₃₃₄₅ | Rₙ₆₅ | Ar57 | H | H | H | H | H | Rₙ₅₉ | H |
| Lₐ₃₃₄₆ | Rₙ₆₉ | Ar57 | H | H | H | H | H | Rₙ₅₉ | H |
| Lₐ₃₃₄₇ | Rₙ₇₀ | Ar57 | H | H | H | H | H | Rₙ₅₉ | H |
| Lₐ₃₃₄₈ | Rₙ₈₁ | Ar57 | H | H | H | H | H | Rₙ₅₉ | H |
| Lₐ₃₃₄₉ | Rₙ₁ | Ar57 | H | H | H | H | H | Rₙ₆₀ | H |
| Lₐ₃₃₅₀ | Rₙ | Ar57 | H | H | H | H | H | Rₙ₆₀ | H |
| Lₐ₃₃₅₁ | Rₙ | Ar57 | H | H | H | H | H | Rₙ₆₀ | H |
| Lₐ₃₃₅₂ | Rₙ | Ar57 | H | H | H | H | H | Rₙ₆₀ | H |
| Lₐ₃₃₅₃ | Rₙ₁₁ | Ar57 | H | H | H | H | H | Rₙ₆₀ | H |
| Lₐ₃₃₅₄ | Rₙ₂₀ | Ar57 | H | H | H | H | H | Rₙ₆₀ | H |
| Lₐ₃₃₅₅ | Rₙ₂₁ | Ar57 | H | H | H | H | H | Rₙ₆₀ | H |
| Lₐ₃₃₅₆ | Rₙ₅₁ | Ar57 | H | H | H | H | H | Rₙ₆₀ | H |
| Lₐ₃₃₅₇ | Rₙ₅₆ | Ar57 | H | H | H | H | H | Rₙ₆₀ | H |
| Lₐ₃₃₅₈ | Rₙ₅₉ | Ar57 | H | H | H | H | H | Rₙ₆₀ | H |
| Lₐ₃₃₅₉ | Rₙ₆₀ | Ar57 | H | H | H | H | H | Rₙ₆₀ | H |
| Lₐ₃₃₆₀ | Rₙ₆₁ | Ar57 | H | H | H | H | H | Rₙ₆₀ | H |
| Lₐ₃₃₆₁ | Rₙ₆₂ | Ar57 | H | H | H | H | H | Rₙ₆₀ | H |
| Lₐ₃₃₆₂ | Rₙ₆₄ | Ar57 | H | H | H | H | H | Rₙ₆₀ | H |
| Lₐ₃₃₆₃ | Rₙ₆₅ | Ar57 | H | H | H | H | H | Rₙ₆₀ | H |
| Lₐ₃₃₆₄ | Rₙ₆₉ | Ar57 | H | H | H | H | H | Rₙ₆₀ | H |
| Lₐ₃₃₆₅ | Rₙ₇₀ | Ar57 | H | H | H | H | H | Rₙ₆₀ | H |
| Lₐ₃₃₆₆ | Rₙ₈₁ | Ar57 | H | H | H | H | H | Rₙ₆₀ | H |
| Lₐ₃₃₆₇ | Rₙ₁ | Ar57 | H | H | H | H | H | Rₙ₆₄ | H |
| Lₐ₃₃₆₈ | Rₙ₄ | Ar57 | H | H | H | H | H | Rₙ₆₄ | H |
| Lₐ₃₃₆₉ | Rₙ₅ | Ar57 | H | H | H | H | H | Rₙ₆₄ | H |
| Lₐ₃₃₇₀ | Rₙ₇ | Ar57 | H | H | H | H | H | Rₙ₆₄ | H |
| Lₐ₃₃₇₁ | Rₙ₁₁ | Ar57 | H | H | H | H | H | Rₙ₆₄ | H |
| Lₐ₃₃₇₂ | Rₙ₂₀ | Ar57 | H | H | H | H | H | Rₙ₆₄ | H |
| Lₐ₃₃₇₃ | Rₙ₂₁ | Ar57 | H | H | H | H | H | Rₙ₆₄ | H |
| Lₐ₃₃₇₄ | Rₙ₅₁ | Ar57 | H | H | H | H | H | Rₙ₆₄ | H |
| Lₐ₃₃₇₅ | Rₙ₅₆ | Ar57 | H | H | H | H | H | Rₙ₆₄ | H |
| Lₐ₃₃₇₆ | Rₙ₅₉ | Ar57 | H | H | H | H | H | Rₙ₆₄ | H |
| Lₐ₃₃₇₇ | Rₙ₆₀ | Ar57 | H | H | H | H | H | Rₙ₆₄ | H |
| Lₐ₃₃₇₈ | Rₙ₆₁ | Ar57 | H | H | H | H | H | Rₙ₆₄ | H |
| Lₐ₃₃₇₉ | Rₙ₆₂ | Ar57 | H | H | H | H | H | Rₙ₆₄ | H |
| Lₐ₃₃₈₀ | Rₙ₆₄ | Ar57 | H | H | H | H | H | Rₙ₆₄ | H |
| Lₐ₃₃₈₁ | Rₙ₆₅ | Ar57 | H | H | H | H | H | Rₙ₆₄ | H |
| Lₐ₃₃₈₂ | Rₙ₆₉ | Ar57 | H | H | H | H | H | Rₙ₆₄ | H |
| Lₐ₃₃₈₃ | Rₙ₇₀ | Ar57 | H | H | H | H | H | Rₙ₆₄ | H |
| Lₐ₃₃₈₄ | Rₙ₈₁ | Ar57 | H | H | H | H | H | Rₙ₆₄ | H |
| Lₐ₃₃₈₅ | Rₙ₁ | Ar57 | H | H | H | H | H | Me | H |
| Lₐ₃₃₈₆ | Rₙ₄ | Ar57 | H | H | H | H | H | Me | H |
| Lₐ₃₃₈₇ | Rₙ₅ | Ar57 | H | H | H | H | H | Me | H |
| Lₐ₃₃₈₈ | Rₙ₇ | Ar57 | H | H | H | H | H | Me | H |
| Lₐ₃₃₈₉ | Rₙ₁₁ | Ar57 | H | H | H | H | H | Me | H |
| Lₐ₃₃₉₀ | Rₙ₂₀ | Ar57 | H | H | H | H | H | Me | H |
| Lₐ₃₃₉₁ | Rₙ₂₁ | Ar57 | H | H | H | H | H | Me | H |
| Lₐ₃₃₉₂ | Rₙ₅₁ | Ar57 | H | H | H | H | H | Me | H |
| Lₐ₃₃₉₃ | Rₙ₅₆ | Ar57 | H | H | H | H | H | Me | H |
| Lₐ₃₃₉₄ | Rₙ₅₉ | Ar57 | H | H | H | H | H | Me | H |
| Lₐ₃₃₉₅ | Rₙ₆₀ | Ar57 | H | H | H | H | H | Me | H |
| Lₐ₃₃₉₆ | Rₙ₆₁ | Ar57 | H | H | H | H | H | Me | H |
| Lₐ₃₃₉₇ | Rₙ₆₂ | Ar57 | H | H | H | H | H | Me | H |
| Lₐ₃₃₉₈ | Rₙ₆₄ | Ar57 | H | H | H | H | H | Me | H |
| Lₐ₃₃₉₉ | Rₙ₆₅ | Ar57 | H | H | H | H | H | Me | H |
| Lₐ₃₄₀₀ | Rₙ₆₉ | Ar57 | H | H | H | H | H | Me | H |
| Lₐ₃₄₀₁ | Rₙ₇₀ | Ar57 | H | H | H | H | H | Me | H |
| Lₐ₃₄₀₂ | Rₙ₈₁ | Ar57 | H | H | H | H | H | Me | H |
| Lₐ₃₄₀₃ | Rₙ₁ | Ar57 | H | H | H | H | Rₙ₁₁ | H | H |
| Lₐ₃₄₀₄ | Rₙ₄ | Ar57 | H | H | H | H | Rₙ₁₁ | H | H |
| Lₐ₃₄₀₅ | Rₙ₅ | Ar57 | H | H | H | H | Rₙ₁₁ | H | H |
| Lₐ₃₄₀₆ | Rₙ₇ | Ar57 | H | H | H | H | Rₙ₁₁ | H | H |
| Lₐ₃₄₀₇ | Rₙ₁₁ | Ar57 | H | H | H | H | Rₙ₁₁ | H | H |
| Lₐ₃₄₀₈ | Rₙ₂₀ | Ar57 | H | H | H | H | Rₙ₁₁ | H | H |
| Lₐ₃₄₀₉ | Rₙ₂₁ | Ar57 | H | H | H | H | Rₙ₁₁ | H | H |
| Lₐ₃₄₁₀ | Rₙ₅₁ | Ar57 | H | H | H | H | Rₙ₁₁ | H | H |
| Lₐ₃₄₁₁ | Rₙ₅₆ | Ar57 | H | H | H | H | Rₙ₁₁ | H | H |
| Lₐ₃₄₁₂ | Rₙ₅₉ | Ar57 | H | H | H | H | Rₙ₁₁ | H | H |
| Lₐ₃₄₁₃ | Rₙ₆₀ | Ar57 | H | H | H | H | Rₙ₁₁ | H | H |
| Lₐ₃₄₁₄ | Rₙ₆₁ | Ar57 | H | H | H | H | Rₙ₁₁ | H | H |
| Lₐ₃₄₁₅ | Rₙ₆₂ | Ar57 | H | H | H | H | Rₙ₁₁ | H | H |
| Lₐ₃₄₁₆ | Rₙ₆₄ | Ar57 | H | H | H | H | Rₙ₁₁ | H | H |
| Lₐ₃₄₁₇ | Rₙ₆₅ | Ar57 | H | H | H | H | Rₙ₁₁ | H | H |
| Lₐ₃₄₁₈ | Rₙ₆₉ | Ar57 | H | H | H | H | Rₙ₁₁ | H | H |
| Lₐ₃₄₁₉ | Rₙ₇₀ | Ar57 | H | H | H | H | Rₙ₁₁ | H | H |
| Lₐ₃₄₂₀ | Rₙ₈₁ | Ar57 | H | H | H | H | Rₙ₁₁ | H | H |
| Lₐ₃₄₂₁ | Rₙ₁ | Ar57 | H | H | H | H | Rₙ₅₉ | H | H |
| Lₐ₃₄₂₂ | Rₙ₄ | Ar57 | H | H | H | H | Rₙ₅₉ | H | H |
| Lₐ₃₄₂₃ | Rₙ₅ | Ar57 | H | H | H | H | Rₙ₅₉ | H | H |
| Lₐ₃₄₂₄ | Rₙ₇ | Ar57 | H | H | H | H | Rₙ₅₉ | H | H |
| Lₐ₃₄₂₅ | Rₙ₁₁ | Ar57 | H | H | H | H | Rₙ₅₉ | H | H |
| Lₐ₃₄₂₆ | Rₙ₂₀ | Ar57 | H | H | H | H | Rₙ₅₉ | H | H |
| Lₐ₃₄₂₇ | Rₙ₂₁ | Ar57 | H | H | H | H | Rₙ₅₉ | H | H |
| Lₐ₃₄₂₈ | Rₙ₅₁ | Ar57 | H | H | H | H | Rₙ₅₉ | H | H |
| Lₐ₃₄₂₉ | Rₙ₅₆ | Ar57 | H | H | H | H | Rₙ₅₉ | H | H |
| Lₐ₃₄₃₀ | Rₙ₅₉ | Ar57 | H | H | H | H | Rₙ₅₉ | H | H |
| Lₐ₃₄₃₁ | Rₙ₆₀ | Ar57 | H | H | H | H | Rₙ₅₉ | H | H |
| Lₐ₃₄₃₂ | Rₙ₆₁ | Ar57 | H | H | H | H | Rₙ₅₉ | H | H |
| Lₐ₃₄₃₃ | Rₙ₆₂ | Ar57 | H | H | H | H | Rₙ₅₉ | H | H |
| Lₐ₃₄₃₄ | Rₙ₆₄ | Ar57 | H | H | H | H | Rₙ₅₉ | H | H |
| Lₐ₃₄₃₅ | Rₙ₆₅ | Ar57 | H | H | H | H | Rₙ₅₉ | H | H |
| Lₐ₃₄₃₆ | Rₙ₆₉ | Ar57 | H | H | H | H | Rₙ₅₉ | H | H |
| Lₐ₃₄₃₇ | Rₙ₇₀ | Ar57 | H | H | H | H | Rₙ₅₉ | H | H |
| Lₐ₃₄₃₈ | Rₙ₈₁ | Ar57 | H | H | H | H | Rₙ₅₉ | H | H |
| Lₐ₃₄₃₉ | Rₙ₁ | Ar57 | H | H | H | H | Rₙ₆₀ | H | H |
| Lₐ₃₄₄₀ | Rₙ₄ | Ar57 | H | H | H | H | Rₙ₆₀ | H | H |
| Lₐ₃₄₄₁ | Rₙ₅ | Ar57 | H | H | H | H | Rₙ₆₀ | H | H |
| Lₐ₃₄₄₂ | Rₙ₇ | Ar57 | H | H | H | H | Rₙ₆₀ | H | H |
| Lₐ₃₄₄₃ | Rₙ₁₁ | Ar57 | H | H | H | H | Rₙ₆₀ | H | H |
| Lₐ₃₄₄₄ | Rₙ₂₀ | Ar57 | H | H | H | H | Rₙ₆₀ | H | H |
| Lₐ₃₄₄₅ | Rₙ₂₁ | Ar57 | H | H | H | H | Rₙ₆₀ | H | H |
| Lₐ₃₄₄₆ | Rₙ₅₁ | Ar57 | H | H | H | H | Rₙ₆₀ | H | H |
| Lₐ₃₄₄₇ | Rₙ₅₆ | Ar57 | H | H | H | H | Rₙ₆₀ | H | H |
| Lₐ₃₄₄₈ | Rₙ₅₉ | Ar57 | H | H | H | H | Rₙ₆₀ | H | H |
| Lₐ₃₄₄₉ | Rₙ₆₀ | Ar57 | H | H | H | H | Rₙ₆₀ | H | H |
| Lₐ₃₄₅₀ | Rₙ₆₁ | Ar57 | H | H | H | H | Rₙ₆₀ | H | H |
| Lₐ₃₄₅₁ | Rₙ₆₂ | Ar57 | H | H | H | H | Rₙ₆₀ | H | H |
| Lₐ₃₄₅₂ | Rₙ₆₄ | Ar57 | H | H | H | H | Rₙ₆₀ | H | H |
| Lₐ₃₄₅₃ | Rₙ₆₅ | Ar57 | H | H | H | H | Rₙ₆₀ | H | H |
| Lₐ₃₄₅₄ | Rₙ₆₉ | Ar57 | H | H | H | H | Rₙ₆₀ | H | H |
| Lₐ₃₄₅₅ | Rₙ₇₀ | Ar57 | H | H | H | H | Rₙ₆₀ | H | H |
| Lₐ₃₄₅₆ | Rₙ₈₁ | Ar57 | H | H | H | H | Rₙ₆₀ | H | H |
| Lₐ₃₄₅₇ | Rₙ₁ | Ar57 | H | H | H | H | Rₙ₆₄ | H | H |
| Lₐ₃₄₅₈ | Rₙ₄ | Ar57 | H | H | H | H | Rₙ₆₄ | H | H |
| Lₐ₃₄₅₉ | Rₙ₅ | Ar57 | H | H | H | H | Rₙ₆₄ | H | H |
| Lₐ₃₄₆₀ | Rₙ₇ | Ar57 | H | H | H | H | Rₙ₆₄ | H | H |
| Lₐ₃₄₆₁ | Rₙ₁₁ | Ar57 | H | H | H | H | Rₙ₆₄ | H | H |
| Lₐ₃₄₆₂ | Rₙ₂₀ | Ar57 | H | H | H | H | Rₙ₆₄ | H | H |
| Lₐ₃₄₆₃ | Rₙ₂₁ | Ar57 | H | H | H | H | Rₙ₆₄ | H | H |
| Lₐ₃₄₆₄ | Rₙ₅₁ | Ar57 | H | H | H | H | Rₙ₆₄ | H | H |
| Lₐ₃₄₆₅ | Rₙ₅₆ | Ar57 | H | H | H | H | Rₙ₆₄ | H | H |
| Lₐ₃₄₆₆ | Rₙ₅₉ | Ar57 | H | H | H | H | Rₙ₆₄ | H | H |
| Lₐ₃₄₆₇ | Rₙ₆₀ | Ar57 | H | H | H | H | Rₙ₆₄ | H | H |
| Lₐ₃₄₆₈ | Rₙ₆₁ | Ar57 | H | H | H | H | Rₙ₆₄ | H | H |
| Lₐ₃₄₆₉ | Rₙ₆₂ | Ar57 | H | H | H | H | Rₙ₆₄ | H | H |
| Lₐ₃₄₇₀ | Rₙ₆₄ | Ar57 | H | H | H | H | Rₙ₆₄ | H | H |
| Lₐ₃₄₇₁ | Rₙ₆₅ | Ar57 | H | H | H | H | Rₙ₆₄ | H | H |
| Lₐ₃₄₇₂ | Rₙ₆₉ | Ar57 | H | H | H | H | Rₙ₆₄ | H | H |
| Lₐ₃₄₇₃ | Rₙ₇₀ | Ar57 | H | H | H | H | Rₙ₆₄ | H | H |
| Lₐ₃₄₇₄ | Rₙ₈₁ | Ar57 | H | H | H | H | Rₙ₆₄ | H | H |
| Lₐ₃₄₇₅ | Rₙ₁ | Ar57 | H | H | H | H | Me | H | H |
| Lₐ₃₄₇₆ | Rₙ₄ | Ar57 | H | H | H | H | Me | H | H |
| Lₐ₃₄₇₇ | Rₙ₅ | Ar57 | H | H | H | H | Me | H | H |
| Lₐ₃₄₇₈ | Rₙ₇ | Ar57 | H | H | H | H | Me | H | H |
| Lₐ₃₄₇₉ | Rₙ₁₁ | Ar57 | H | H | H | H | Me | H | H |
| Lₐ₃₄₈₀ | Rₙ₂₀ | Ar57 | H | H | H | H | Me | H | H |
| Lₐ₃₄₈₁ | Rₙ₂₁ | Ar57 | H | H | H | H | Me | H | H |
| Lₐ₃₄₈₂ | Rₙ₅₁ | Ar57 | H | H | H | H | Me | H | H |
| Lₐ₃₄₈₃ | Rₙ₅₆ | Ar57 | H | H | H | H | Me | H | H |
| Lₐ₃₄₈₄ | Rₙ₅₉ | Ar57 | H | H | H | H | Me | H | H |
| Lₐ₃₄₈₅ | Rₙ₆₀ | Ar57 | H | H | H | H | Me | H | H |
| Lₐ₃₄₈₆ | Rₙ₆₁ | Ar57 | H | H | H | H | Me | H | H |
| Lₐ₃₄₈₇ | Rₙ₆₂ | Ar57 | H | H | H | H | Me | H | H |
| Lₐ₃₄₈₈ | Rₙ₆₄ | Ar57 | H | H | H | H | Me | H | H |
| Lₐ₃₄₈₉ | Rₙ₆₅ | Ar57 | H | H | H | H | Me | H | H |
| Lₐ₃₄₉₀ | Rₙ₆₉ | Ar57 | H | H | H | H | Me | H | H |
| Lₐ₃₄₉₁ | Rₙ₇₀ | Ar57 | H | H | H | H | Me | H | H |
| Lₐ₃₄₉₂ | Rₙ₈₁ | Ar57 | H | H | H | H | Me | H | H |
| Lₐ₃₄₉₃ | Rₙ₁ | Ar57 | H | H | F | H | H | H | H |
| Lₐ₃₄₉₄ | Rₙ₄ | Ar57 | H | D | F | H | H | H | H |
| Lₐ₃₄₉₅ | Rₙ₇ | Ar57 | H | H | F | H | H | H | H |
| Lₐ₃₄₉₆ | Rₙ₂₀ | Ar57 | H | H | F | H | H | H | H |
| Lₐ₃₄₉₇ | Rₙ₂₁ | Ar57 | H | H | F | H | H | H | H |
| Lₐ₃₄₉₈ | Rₙ₅₆ | Ar57 | H | H | F | H | H | H | H |
| Lₐ₃₄₉₉ | Rₙ₅₉ | Ar57 | H | H | F | H | H | H | H |
| Lₐ₃₅₀₀ | Rₙ₆₁ | Ar57 | H | H | F | H | H | H | H |
| Lₐ₃₅₀₁ | Rₙ₆₂ | Ar57 | D | H | F | H | H | H | H |
| Lₐ₃₅₀₂ | Rₙ₆₄ | Ar57 | H | H | F | H | H | H | H |
| Lₐ₃₅₀₃ | Rₙ₆₉ | Ar57 | H | H | F | H | H | H | H |
| Lₐ₃₅₀₄ | Rₙ₇₀ | Ar57 | H | H | F | H | H | H | H |
| Lₐ₃₅₀₅ | Rₙ₁ | Ar57 | H | H | F | H | Rₙ₁₁ | H | H |
| Lₐ₃₅₀₆ | Rₙ₄ | Ar57 | H | H | F | H | Rₙ₁₁ | H | H |
| Lₐ₃₅₀₇ | Rₙ₇ | Ar57 | H | H | F | H | Rₙ₁₁ | H | H |
| Lₐ₃₅₀₈ | Rₙ₂₀ | Ar57 | H | H | F | H | Rₙ₁₁ | H | H |
| Lₐ₃₅₀₉ | Rₙ₂₁ | Ar57 | H | H | F | H | Rₙ₁₁ | H | H |
| Lₐ₃₅₁₀ | Rₙ₅₆ | Ar57 | H | H | F | H | Rₙ₁₁ | H | H |
| Lₐ₃₅₁₁ | Rₙ₅₉ | Ar57 | H | H | F | H | Rₙ₁₁ | H | H |
| Lₐ₃₅₁₂ | Rₙ₆₁ | Ar57 | H | H | F | H | Rₙ₁₁ | H | H |
| Lₐ₃₅₁₃ | Rₙ₆₂ | Ar57 | H | H | F | H | Rₙ₁₁ | H | H |
| Lₐ₃₅₁₄ | Rₙ₆₄ | Ar57 | H | H | F | H | Rₙ₁₁ | H | H |
| Lₐ₃₅₁₅ | Rₙ₆₉ | Ar57 | H | H | F | H | Rₙ₁₁ | H | H |
| Lₐ₃₅₁₆ | Rₙ₇₀ | Ar57 | H | H | F | H | Rₙ₁₁ | H | H |
| Lₐ₃₅₁₇ | Rₙ₁ | Ar57 | H | H | F | H | Rₙ₆₀ | H | H |
| Lₐ₃₅₁₈ | Rₙ₄ | Ar57 | H | H | F | H | Rₙ₆₀ | H | H |
| Lₐ₃₅₁₉ | Rₙ₇ | Ar57 | H | H | F | H | Rₙ₆₀ | H | H |
| Lₐ₃₅₂₀ | Rₙ₂₀ | Ar57 | H | H | F | H | Rₙ₆₀ | H | H |
| Lₐ₃₅₂₁ | Rₙ₂₁ | Ar57 | H | H | F | H | Rₙ₆₀ | H | H |
| Lₐ₃₅₂₂ | Rₙ₅₆ | Ar57 | H | H | F | H | Rₙ₆₀ | H | H |
| Lₐ₃₅₂₃ | Rₙ₅₉ | Ar57 | H | H | F | H | Rₙ₆₀ | H | H |
| Lₐ₃₅₂₄ | Rₙ₆₁ | Ar57 | H | H | F | H | Rₙ₆₀ | H | H |
| Lₐ₃₅₂₅ | Rₙ₆₂ | Ar57 | H | H | F | H | Rₙ₆₀ | H | H |
| Lₐ₃₅₂₆ | Rₙ₆₄ | Ar57 | H | H | F | H | Rₙ₆₀ | H | H |
| Lₐ₃₅₂₇ | Rₙ₆₉ | Ar57 | H | H | F | H | Rₙ₆₀ | H | H |
| Lₐ₃₅₂₈ | Rₙ₇₀ | Ar57 | H | H | F | H | Rₙ₆₀ | H | H |
| Lₐ₃₅₂₉ | Rₙ₁ | Ar57 | H | H | F | H | H | Rₙ₁₁ | H |
| Lₐ₃₅₃₀ | Rₙ₄ | Ar57 | H | H | F | H | H | Rₙ₁₁ | H |
| Lₐ₃₅₃₁ | Rₙ₇ | Ar57 | H | H | F | H | H | Rₙ₁₁ | H |
| Lₐ₃₅₃₂ | Rₙ₂₀ | Ar57 | H | H | F | H | H | Rₙ₁₁ | H |
| Lₐ₃₅₃₃ | Rₙ₂₁ | Ar57 | H | H | F | H | H | Rₙ₁₁ | H |
| Lₐ₃₅₃₄ | Rₙ₅₆ | Ar57 | H | H | F | H | H | Rₙ₁₁ | H |
| Lₐ₃₅₃₅ | Rₙ₅₉ | Ar57 | H | H | F | H | H | Rₙ₁₁ | H |
| Lₐ₃₅₃₆ | Rₙ₆₁ | Ar57 | H | H | F | H | H | Rₙ₁₁ | H |
| Lₐ₃₅₃₇ | Rₙ₆₂ | Ar57 | H | H | F | H | H | Rₙ₁₁ | H |
| Lₐ₃₅₃₈ | Rₙ₆₄ | Ar57 | H | H | F | H | H | Rₙ₁₁ | H |
| Lₐ₃₅₃₉ | Rₙ₆₉ | Ar57 | H | H | F | H | H | Rₙ₁₁ | H |
| Lₐ₃₅₄₀ | Rₙ₇₀ | Ar57 | H | H | F | H | H | Rₙ₁₁ | H |
| Lₐ₃₅₄₁ | Rₙ₁ | Ar57 | H | H | F | H | H | Rₙ₆₀ | H |
| Lₐ₃₅₄₂ | Rₙ₄ | Ar57 | H | H | F | H | H | Rₙ₆₀ | H |
| Lₐ₃₅₄₃ | Rₙ₇ | Ar57 | H | H | F | H | H | Rₙ₆₀ | H |
| Lₐ₃₅₄₄ | Rₙ₂₀ | Ar57 | H | H | F | H | H | Rₙ₆₀ | D |
| Lₐ₃₅₄₅ | Rₙ₂₁ | Ar57 | H | H | F | H | H | Rₙ₆₀ | H |
| Lₐ₃₅₄₆ | Rₙ₅₆ | Ar57 | H | H | F | H | H | Rₙ₆₀ | H |
| Lₐ₃₅₄₇ | Rₙ₅₉ | Ar57 | H | H | F | H | H | Rₙ₆₀ | H |
| Lₐ₃₅₄₈ | Rₙ₆₁ | Ar57 | H | H | F | H | H | Rₙ₆₀ | H |
| Lₐ₃₅₄₉ | Rₙ₆₂ | Ar57 | H | H | F | H | H | Rₙ₆₀ | H |
| Lₐ₃₅₅₀ | Rₙ₆₄ | Ar57 | H | H | F | H | H | Rₙ₆₀ | H |
| Lₐ₃₅₅₁ | Rₙ₆₉ | Ar57 | H | H | F | H | H | Rₙ₆₀ | H |
| Lₐ₃₅₅₂ | Rₙ₇₀ | Ar57 | H | H | F | H | H | Rₙ₆₀ | H |
| Lₐ₃₅₅₃ | Rₙ₁ | Ar57 | H | H | CN | H | H | H | H |
| Lₐ₃₅₅₄ | Rₙ₄ | Ar57 | H | H | CN | H | H | H | H |
| Lₐ₃₅₅₅ | Rₙ₇ | Ar57 | H | H | CN | H | H | H | H |
| Lₐ₃₅₅₆ | Rₙ₂₀ | Ar57 | H | H | CN | H | H | H | H |
| Lₐ₃₅₅₇ | Rₙ₂₁ | Ar57 | H | H | CN | H | H | H | H |
| Lₐ₃₅₅₈ | Rₙ₅₆ | Ar57 | H | D | CN | H | H | H | H |
| Lₐ₃₅₅₉ | Rₙ₅₉ | Ar57 | H | H | CN | H | H | H | H |
| Lₐ₃₅₆₀ | Rₙ₆₁ | Ar57 | H | H | CN | H | H | H | H |
| Lₐ₃₅₆₁ | Rₙ₆₂ | Ar57 | H | H | CN | H | H | H | H |
| Lₐ₃₅₆₂ | Rₙ₆₄ | Ar57 | H | H | CN | H | H | H | H |
| Lₐ₃₅₆₃ | Rₙ₆₉ | Ar57 | H | H | CN | H | H | H | H |
| Lₐ₃₅₆₄ | Rₙ₇₀ | Ar57 | D | H | CN | H | H | H | H |
| Lₐ₃₅₆₅ | Rₙ₁ | Ar57 | H | CN | H | H | H | H | H |
| Lₐ₃₅₆₆ | Rₙ₄ | Ar57 | H | CN | H | H | H | H | H |
| Lₐ₃₅₆₇ | Rₙ₇ | Ar57 | H | CN | H | H | H | H | H |
| Lₐ₃₅₆₈ | Rₙ₂₀ | Ar57 | H | CN | H | H | H | H | H |
| Lₐ₃₅₆₉ | Rₙ₂₁ | Ar57 | H | CN | H | H | H | H | H |
| Lₐ₃₅₇₀ | Rₙ₅₆ | Ar57 | H | CN | H | H | H | H | H |
| Lₐ₃₅₇₁ | Rₙ₅₉ | Ar57 | H | CN | H | H | H | H | H |
| Lₐ₃₅₇₂ | Rₙ₆₁ | Ar57 | H | CN | H | H | H | H | H |
| Lₐ₃₅₇₃ | Rₙ₆₂ | Ar57 | H | CN | H | H | H | H | H |
| Lₐ₃₅₇₄ | Rₙ₆₄ | Ar57 | H | CN | H | H | H | H | H |
| Lₐ₃₅₇₅ | Rₙ₆₉ | Ar57 | H | CN | H | H | H | H | H |
| Lₐ₃₅₇₆ | Rₙ₇₀ | Ar57 | H | CN | H | H | H | H | H |
| Lₐ₃₅₇₇ | Rₙ₁ | Ar57 | CN | H | H | H | H | H | H |
| Lₐ₃₅₇₈ | Rₙ₄ | Ar57 | CN | H | H | H | H | H | H |
| Lₐ₃₅₇₉ | Rₙ₇ | Ar57 | CN | H | H | H | H | H | H |
| Lₐ₃₅₈₀ | Rₙ₂₀ | Ar57 | CN | H | H | H | H | H | H |
| Lₐ₃₅₈₁ | Rₙ₂₁ | Ar57 | CN | H | H | H | H | H | H |
| Lₐ₃₅₈₂ | Rₙ₅₆ | Ar57 | CN | H | H | H | H | H | H |
| Lₐ₃₅₈₃ | Rₙ₅₉ | Ar57 | CN | H | H | H | H | H | H |
| Lₐ₃₅₈₄ | Rₙ₆₁ | Ar57 | CN | H | H | H | H | H | H |
| Lₐ₃₅₈₅ | Rₙ₆₂ | Ar57 | CN | H | H | H | H | H | H |
| Lₐ₃₅₈₆ | Rₙ₆₄ | Ar57 | CN | H | H | H | H | H | H |
| Lₐ₃₅₈₇ | Rₙ₆₉ | Ar57 | CN | H | D | H | H | H | H |
| Lₐ₃₅₈₈ | Rₙ₇₀ | Ar57 | CN | H | H | H | H | H | H |
| Lₐ₃₅₈₉ | Rₙ₁ | Ar57 | H | H | CN | H | Rₙ₁₁ | H | H |
| Lₐ₃₅₉₀ | Rₙ₄ | Ar57 | H | H | CN | H | Rₙ₁₁ | H | H |
| Lₐ₃₅₉₁ | Rₙ₇ | Ar57 | H | H | CN | H | Rₙ₁₁ | H | H |
| Lₐ₃₅₉₂ | Rₙ₂₀ | Ar57 | H | H | CN | H | Rₙ₁₁ | H | H |
| Lₐ₃₅₉₃ | Rₙ₂₁ | Ar57 | H | H | CN | H | Rₙ₁₁ | H | H |
| Lₐ₃₅₉₄ | Rₙ₅₆ | Ar57 | H | H | CN | H | Rₙ₁₁ | H | H |
| Lₐ₃₅₉₅ | Rₙ₅₉ | Ar57 | H | H | CN | H | Rₙ₁₁ | H | H |
| Lₐ₃₅₉₆ | Rₙ₆₁ | Ar57 | H | H | CN | H | Rₙ₁₁ | H | H |
| Lₐ₃₅₉₇ | Rₙ₆₂ | Ar57 | H | H | CN | H | Rₙ₁₁ | H | H |
| Lₐ₃₅₉₈ | Rₙ₆₄ | Ar57 | H | H | CN | H | Rₙ₁₁ | H | H |
| Lₐ₃₅₉₉ | Rₙ₆₉ | Ar57 | H | H | CN | H | Rₙ₁₁ | H | H |
| Lₐ₃₆₀₀ | Rₙ₇₀ | Ar57 | H | H | CN | H | Rₙ₁₁ | H | H |
| Lₐ₃₆₀₁ | Rₙ₁ | Ar57 | H | H | CN | H | Rₙ₆₀ | H | D |
| Lₐ₃₆₀₂ | Rₙ₄ | Ar57 | H | H | CN | H | Rₙ₆₀ | H | H |
| Lₐ₃₆₀₃ | Rₙ₇ | Ar57 | H | H | CN | H | Rₙ₆₀ | H | H |
| Lₐ₃₆₀₄ | Rₙ₂₀ | Ar57 | H | H | CN | H | Rₙ₆₀ | H | H |
| Lₐ₃₆₀₅ | Rₙ₂₁ | Ar57 | H | H | CN | H | Rₙ₆₀ | H | H |
| Lₐ₃₆₀₆ | Rₙ₅₆ | Ar57 | H | H | CN | H | Rₙ₆₀ | H | H |
| Lₐ₃₆₀₇ | Rₙ₅₉ | Ar57 | H | H | CN | H | Rₙ₆₀ | H | H |
| Lₐ₃₆₀₈ | Rₙ₆₁ | Ar57 | H | H | CN | H | Rₙ₆₀ | H | H |
| Lₐ₃₆₀₉ | Rₙ₆₂ | Ar57 | H | H | CN | H | Rₙ₆₀ | H | H |
| Lₐ₃₆₁₀ | Rₙ₆₄ | Ar57 | H | H | CN | H | Rₙ₆₀ | H | H |
| Lₐ₃₆₁₁ | Rₙ₆₉ | Ar57 | H | H | CN | H | Rₙ₆₀ | H | H |
| Lₐ₃₆₁₂ | Rₙ₇₀ | Ar57 | H | H | CN | H | Rₙ₆₀ | H | H |
| Lₐ₃₆₁₃ | Rₙ₁ | Ar57 | H | H | CN | H | Rₙ₆₄ | H | H |
| Lₐ₃₆₁₄ | Rₙ₄ | Ar57 | H | H | CN | H | Rₙ₆₄ | H | H |
| Lₐ₃₆₁₅ | Rₙ₇ | Ar57 | H | H | CN | H | Rₙ₆₄ | H | H |
| Lₐ₃₆₁₆ | Rₙ₂₀ | Ar57 | H | H | CN | H | Rₙ₆₄ | H | H |
| Lₐ₃₆₁₇ | Rₙ₂₁ | Ar57 | H | H | CN | H | Rₙ₆₄ | H | H |
| Lₐ₃₆₁₈ | Rₙ₅₆ | Ar57 | H | H | CN | H | Rₙ₆₄ | H | H |
| Lₐ₃₆₁₉ | Rₙ₅₉ | Ar57 | H | H | CN | H | Rₙ₆₄ | H | H |
| Lₐ₃₆₂₀ | Rₙ₆₁ | Ar57 | H | H | CN | H | Rₙ₆₄ | H | H |
| Lₐ₃₆₂₁ | Rₙ₆₂ | Ar57 | H | H | CN | H | Rₙ₆₄ | H | H |
| Lₐ₃₆₂₂ | Rₙ₆₄ | Ar57 | H | H | CN | H | Rₙ₆₄ | H | H |
| Lₐ₃₆₂₃ | Rₙ₆₉ | Ar57 | H | H | CN | H | Rₙ₆₄ | H | H |
| Lₐ₃₆₂₄ | Rₙ₇₀ | Ar57 | H | H | CN | H | Rₙ₆₄ | H | H |
| Lₐ₃₆₂₅ | Rₙ₁ | Ar57 | H | H | CN | H | H | Rₙ₁₁ | H |
| Lₐ₃₆₂₆ | Rₙ₄ | Ar57 | H | H | CN | H | H | Rₙ₁₁ | H |
| Lₐ₃₆₂₇ | Rₙ₇ | Ar57 | H | H | CN | H | H | Rₙ₁₁ | H |
| Lₐ₃₆₂₈ | Rₙ₂₀ | Ar57 | H | H | CN | H | H | Rₙ₁₁ | H |
| Lₐ₃₆₂₉ | Rₙ₂₁ | Ar57 | H | H | CN | H | H | Rₙ₁₁ | H |
| Lₐ₃₆₃₀ | Rₙ₅₆ | Ar57 | H | H | CN | H | H | Rₙ₁₁ | H |
| Lₐ₃₆₃₁ | Rₙ₅₉ | Ar57 | H | H | CN | H | H | Rₙ₁₁ | H |
| Lₐ₃₆₃₂ | Rₙ₆₁ | Ar57 | H | H | CN | H | H | Rₙ₁₁ | H |
| Lₐ₃₆₃₃ | Rₙ₆₂ | Ar57 | H | H | CN | H | H | Rₙ₁₁ | H |
| Lₐ₃₆₃₄ | Rₙ₆₄ | Ar57 | H | H | CN | H | H | Rₙ₁₁ | H |
| Lₐ₃₆₃₅ | Rₙ₆₉ | Ar57 | H | H | CN | H | H | Rₙ₁₁ | H |
| Lₐ₃₆₃₆ | Rₙ₇₀ | Ar57 | H | H | CN | H | H | Rₙ₁₁ | H |
| Lₐ₃₆₃₇ | Rₙ₁ | Ar57 | H | H | CN | H | H | Rₙ₆₀ | H |
| Lₐ₃₆₃₈ | Rₙ₄ | Ar57 | H | H | CN | H | H | Rₙ₆₀ | D |
| Lₐ₃₆₃₉ | Rₙ₇ | Ar57 | H | H | CN | H | H | Rₙ₆₀ | H |
| Lₐ₃₆₄₀ | Rₙ₂₀ | Ar57 | H | H | CN | H | H | Rₙ₆₀ | H |
| Lₐ₃₆₄₁ | Rₙ₂₁ | Ar57 | H | H | CN | H | H | Rₙ₆₀ | H |
| Lₐ₃₆₄₂ | Rₙ₅₆ | Ar57 | H | H | CN | H | H | Rₙ₆₀ | H |
| Lₐ₃₆₄₃ | Rₙ₅₉ | Ar57 | H | H | CN | H | H | Rₙ₆₀ | H |
| Lₐ₃₆₄₄ | Rₙ₆₁ | Ar57 | H | H | CN | H | H | Rₙ₆₀ | H |
| Lₐ₃₆₄₅ | Rₙ₆₂ | Ar57 | H | H | CN | H | H | Rₙ₆₀ | H |
| Lₐ₃₆₄₆ | Rₙ₆₄ | Ar57 | D | H | CN | H | H | Rₙ₆₀ | H |
| Lₐ₃₆₄₇ | Rₙ₆₉ | Ar57 | H | H | CN | H | H | Rₙ₆₀ | H |
| Lₐ₃₆₄₈ | Rₙ₇₀ | Ar57 | H | H | CN | H | H | Rₙ₆₀ | H |
| Lₐ₃₆₄₉ | Rₙ₁ | Ar57 | H | H | CN | H | H | Rₙ₆₄ | H |
| Lₐ₃₆₅₀ | Rₙ₄ | Ar57 | H | H | CN | H | H | Rₙ₆₄ | H |
| Lₐ₃₆₅₁ | Rₙ₇ | Ar57 | H | H | CN | H | H | Rₙ₆₄ | H |
| Lₐ₃₆₅₂ | Rₙ₂₀ | Ar57 | H | H | CN | H | H | Rₙ₆₄ | H |
| Lₐ₃₆₅₃ | Rₙ₂₁ | Ar57 | H | H | CN | H | H | Rₙ₆₄ | H |
| Lₐ₃₆₅₄ | Rₙ₅₆ | Ar57 | H | H | CN | H | H | Rₙ₆₄ | H |
| Lₐ₃₆₅₅ | Rₙ₅₉ | Ar57 | H | H | CN | H | H | Rₙ₆₄ | H |
| Lₐ₃₆₅₆ | Rₙ₆₁ | Ar57 | H | D | CN | H | H | Rₙ₆₄ | H |
| Lₐ₃₆₅₇ | Rₙ₆₂ | Ar57 | H | H | CN | H | H | Rₙ₆₄ | H |
| Lₐ₃₆₅₈ | Rₙ₆₄ | Ar57 | H | H | CN | H | H | Rₙ₆₄ | H |
| Lₐ₃₆₅₉ | Rₙ₆₉ | Ar57 | H | H | CN | H | H | Rₙ₆₄ | H |
| Lₐ₃₆₆₀ | Rₙ₇₀ | Ar57 | H | H | CN | H | H | Rₙ₆₄ | H |
| Lₐ₃₆₆₁ | Rₙ₁ | Ar87 | H | H | H | H | H | H | H |
| Lₐ₃₆₆₂ | Rₙ₄ | Ar87 | H | H | H | H | H | H | H |
| Lₐ₃₆₆₃ | Rₙ₅ | Ar87 | H | H | H | H | H | H | H |
| Lₐ₃₆₆₄ | Rₙ₇ | Ar87 | H | H | H | H | H | H | H |
| Lₐ₃₆₆₅ | Rₙ₁₁ | Ar87 | H | H | H | H | H | H | H |
| Lₐ₃₆₆₆ | Rₙ₂₀ | Ar87 | H | H | H | H | H | H | H |
| Lₐ₃₆₆₇ | Rₙ₂₁ | Ar87 | H | H | H | H | H | H | H |
| Lₐ₃₆₆₈ | Rₙ₅₁ | Ar87 | H | H | D | H | H | H | H |
| Lₐ₃₆₆₉ | Rₙ₅₆ | Ar87 | H | H | H | H | H | H | H |
| Lₐ₃₆₇₀ | Rₙ₅₉ | Ar87 | H | H | H | H | H | H | H |
| Lₐ₃₆₇₁ | Rₙ₆₀ | Ar87 | H | H | H | H | H | H | H |
| Lₐ₃₆₇₂ | Rₙ₆₁ | Ar87 | D | H | H | H | H | H | H |
| Lₐ₃₆₇₃ | Rₙ₆₂ | Ar87 | H | H | H | H | H | H | H |
| Lₐ₃₆₇₄ | Rₙ₆₄ | Ar87 | H | H | H | H | H | H | H |
| Lₐ₃₆₇₅ | Rₙ₆₅ | Ar87 | H | H | H | H | H | H | H |
| Lₐ₃₆₇₆ | Rₙ₆₉ | Ar87 | H | H | H | H | H | H | H |
| Lₐ₃₆₇₇ | Rₙ₇₀ | Ar87 | H | H | H | H | H | H | H |
| Lₐ₃₆₇₈ | Rₙ₈₁ | Ar87 | H | H | H | H | H | H | H |
| Lₐ₃₆₇₉ | Rₙ₁ | Ar87 | H | H | H | H | H | Rₙ₁₁ | H |
| Lₐ₃₆₈₀ | Rₙ₄ | Ar87 | H | H | H | H | H | Rₙ₁₁ | H |
| Lₐ₃₆₈₁ | Rₙ₅ | Ar87 | H | H | H | H | H | Rₙ₁₁ | H |
| Lₐ₃₆₈₂ | Rₙ₇ | Ar87 | H | H | H | H | H | Rₙ₁₁ | H |
| Lₐ₃₆₈₃ | Rₙ₁₁ | Ar87 | H | H | H | H | H | Rₙ₁₁ | H |
| Lₐ₃₆₈₄ | Rₙ₂₀ | Ar87 | H | H | H | H | H | Rₙ₁₁ | H |
| Lₐ₃₆₈₅ | Rₙ₂₁ | Ar87 | H | H | H | H | H | Rₙ₁₁ | H |
| Lₐ₃₆₈₆ | Rₙ₅₁ | Ar87 | H | H | H | H | H | Rₙ₁₁ | H |
| Lₐ₃₆₈₇ | Rₙ₅₆ | Ar87 | H | H | H | H | H | Rₙ₁₁ | H |
| Lₐ₃₆₈₈ | Rₙ₅₉ | Ar87 | H | H | H | H | H | Rₙ₁₁ | H |
| Lₐ₃₆₈₉ | Rₙ₆₀ | Ar87 | H | H | H | H | H | Rₙ₁₁ | H |
| Lₐ₃₆₉₀ | Rₙ₆₁ | Ar87 | H | H | H | H | H | Rₙ₁₁ | H |
| Lₐ₃₆₉₁ | Rₙ₆₂ | Ar87 | H | H | H | H | H | Rₙ₁₁ | H |
| Lₐ₃₆₉₂ | Rₙ₆₄ | Ar87 | H | H | H | H | H | Rₙ₁₁ | H |
| Lₐ₃₆₉₃ | Rₙ₆₅ | Ar87 | H | H | H | H | H | Rₙ₁₁ | H |
| Lₐ₃₆₉₄ | Rₙ₆₉ | Ar87 | H | H | H | H | H | Rₙ₁₁ | H |
| Lₐ₃₆₉₅ | Rₙ₇₀ | Ar87 | H | H | H | H | H | Rₙ₁₁ | H |
| Lₐ₃₆₉₆ | Rₙ₈₁ | Ar87 | H | H | H | H | H | Rₙ₁₁ | H |
| Lₐ₃₆₉₇ | Rₙ₁ | Ar87 | H | H | H | H | H | Rₙ₅₉ | H |
| Lₐ₃₆₉₈ | Rₙ₄ | Ar87 | H | H | H | H | H | Rₙ₅₉ | H |
| Lₐ₃₆₉₉ | Rₙ₅ | Ar87 | H | H | H | H | H | Rₙ₅₉ | H |
| Lₐ₃₇₀₀ | Rₙ₇ | Ar87 | H | H | H | H | H | Rₙ₅₉ | H |
| Lₐ₃₇₀₁ | Rₙ₁₁ | Ar87 | H | H | H | H | H | Rₙ₅₉ | H |
| Lₐ₃₇₀₂ | Rₙ₂₀ | Ar87 | H | H | H | H | H | Rₙ₅₉ | H |
| Lₐ₃₇₀₃ | Rₙ₂₁ | Ar87 | H | H | H | H | H | Rₙ₅₉ | H |
| Lₐ₃₇₀₄ | Rₙ₅₁ | Ar87 | H | H | H | H | H | Rₙ₅₉ | H |
| Lₐ₃₇₀₅ | Rₙ₅₆ | Ar87 | H | H | H | H | H | Rₙ₅₉ | H |
| Lₐ₃₇₀₆ | Rₙ₅₉ | Ar87 | H | H | H | H | H | Rₙ₅₉ | H |
| Lₐ₃₇₀₇ | Rₙ₆₀ | Ar87 | H | H | H | H | H | Rₙ₅₉ | H |
| Lₐ₃₇₀₈ | Rₙ₆₁ | Ar87 | H | H | H | H | H | Rₙ₅₉ | H |
| Lₐ₃₇₀₉ | Rₙ₆₂ | Ar87 | H | H | H | H | H | Rₙ₅₉ | H |
| Lₐ₃₇₁₀ | Rₙ₆₄ | Ar87 | H | H | H | H | H | Rₙ₅₉ | H |
| Lₐ₃₇₁₁ | Rₙ₆₅ | Ar87 | H | H | H | H | H | Rₙ₅₉ | H |
| Lₐ₃₇₁₂ | Rₙ₆₉ | Ar87 | H | H | H | H | H | Rₙ₅₉ | H |
| Lₐ₃₇₁₃ | Rₙ₇₀ | Ar87 | H | H | H | H | H | Rₙ₅₉ | H |
| Lₐ₃₇₁₄ | Rₙ₈₁ | Ar87 | H | H | H | H | H | Rₙ₅₉ | H |
| Lₐ₃₇₁₅ | Rₙ₁ | Ar87 | H | H | H | H | H | Rₙ₆₀ | H |
| Lₐ₃₇₁₆ | Rₙ₄ | Ar87 | H | H | H | H | H | Rₙ₆₀ | H |
| Lₐ₃₇₁₇ | Rₙ₅ | Ar87 | H | H | H | H | H | Rₙ₆₀ | H |
| Lₐ₃₇₁₈ | Rₙ₇ | Ar87 | H | H | H | H | H | Rₙ₆₀ | H |
| Lₐ₃₇₁₉ | Rₙ₁₁ | Ar87 | H | H | H | H | H | Rₙ₆₀ | H |
| Lₐ₃₇₂₀ | Rₙ₂₀ | Ar87 | H | H | H | H | H | Rₙ₆₀ | H |
| Lₐ₃₇₂₁ | Rₙ₂₁ | Ar87 | H | H | H | H | H | Rₙ₆₀ | H |
| Lₐ₃₇₂₂ | Rₙ₅₁ | Ar87 | H | H | H | H | H | Rₙ₆₀ | H |
| Lₐ₃₇₂₃ | Rₙ₅₆ | Ar87 | H | H | H | H | H | Rₙ₆₀ | H |
| Lₐ₃₇₂₄ | Rₙ₅₉ | Ar87 | H | H | H | H | H | Rₙ₆₀ | H |
| Lₐ₃₇₂₅ | Rₙ₆₀ | Ar87 | H | H | H | H | H | Rₙ₆₀ | H |
| Lₐ₃₇₂₆ | Rₙ₆₁ | Ar87 | H | H | H | H | H | Rₙ₆₀ | H |
| Lₐ₃₇₂₇ | Rₙ₆₂ | Ar87 | H | H | H | H | H | Rₙ₆₀ | H |
| Lₐ₃₇₂₈ | Rₙ₆₄ | Ar87 | H | H | H | H | H | Rₙ₆₀ | H |
| Lₐ₃₇₂₉ | Rₙ₆₅ | Ar87 | H | H | H | H | H | Rₙ₆₀ | H |
| Lₐ₃₇₃₀ | Rₙ₆₉ | Ar87 | H | H | H | H | H | Rₙ₆₀ | H |
| Lₐ₃₇₃₁ | Rₙ₇₀ | Ar87 | H | H | H | H | H | Rₙ₆₀ | H |
| Lₐ₃₇₃₂ | Rₙ₈₁ | Ar87 | H | H | H | H | H | Rₙ₆₀ | H |
| Lₐ₃₇₃₃ | Rₙ₁ | Ar87 | H | H | H | H | H | Rₙ₆₄ | H |
| Lₐ₃₇₃₄ | Rₙ₄ | Ar87 | H | H | H | H | H | Rₙ₆₄ | H |
| Lₐ₃₇₃₅ | Rₙ₅ | Ar87 | H | H | H | H | H | Rₙ₆₄ | H |
| Lₐ₃₇₃₆ | Rₙ₇ | Ar87 | H | H | H | H | H | Rₙ₆₄ | H |
| Lₐ₃₇₃₇ | Rₙ₁₁ | Ar87 | H | H | H | H | H | Rₙ₆₄ | H |
| Lₐ₃₇₃₈ | Rₙ₂₀ | Ar87 | H | H | H | H | H | Rₙ₆₄ | H |
| Lₐ₃₇₃₉ | Rₙ₂₁ | Ar87 | H | H | H | H | H | Rₙ₆₄ | H |
| Lₐ₃₇₄₀ | Rₙ₅₁ | Ar87 | H | H | H | H | H | Rₙ₆₄ | H |
| Lₐ₃₇₄₁ | Rₙ₅₆ | Ar87 | H | H | H | H | H | Rₙ₆₄ | H |
| Lₐ₃₇₄₂ | Rₙ₅₉ | Ar87 | H | H | H | H | H | Rₙ₆₄ | H |
| Lₐ₃₇₄₃ | Rₙ₆₀ | Ar87 | H | H | H | H | H | Rₙ₆₄ | H |
| Lₐ₃₇₄₄ | Rₙ₆₁ | Ar87 | H | H | H | H | H | Rₙ₆₄ | H |
| Lₐ₃₇₄₅ | Rₙ₆₂ | Ar87 | H | H | H | H | H | Rₙ₆₄ | H |
| Lₐ₃₇₄₆ | Rₙ₆₄ | Ar87 | H | H | H | H | H | Rₙ₆₄ | H |
| Lₐ₃₇₄₇ | Rₙ₆₅ | Ar87 | H | H | H | H | H | Rₙ₆₄ | H |
| Lₐ₃₇₄₈ | Rₙ₆₉ | Ar87 | H | H | H | H | H | Rₙ₆₄ | H |
| Lₐ₃₇₄₉ | Rₙ₇₀ | Ar87 | H | H | H | H | H | Rₙ₆₄ | H |
| Lₐ₃₇₅₀ | Rₙ₈₁ | Ar87 | H | H | H | H | H | Rₙ₆₄ | H |
| Lₐ₃₇₅₁ | Rₙ₁ | Ar87 | H | H | H | H | H | Me | H |
| Lₐ₃₇₅₂ | Rₙ₄ | Ar87 | H | H | H | H | H | Me | H |
| Lₐ₃₇₅₃ | Rₙ₅ | Ar87 | H | H | H | H | H | Me | H |
| Lₐ₃₇₅₄ | Rₙ₇ | Ar87 | H | H | H | H | H | Me | H |
| Lₐ₃₇₅₅ | Rₙ₁₁ | Ar87 | H | H | H | H | H | Me | H |
| Lₐ₃₇₅₆ | Rₙ₂₀ | Ar87 | H | H | H | H | H | Me | H |
| Lₐ₃₇₅₇ | Rₙ₂₁ | Ar87 | H | H | H | H | H | Me | H |
| Lₐ₃₇₅₈ | Rₙ₅₁ | Ar87 | H | H | H | H | H | Me | H |
| Lₐ₃₇₅₉ | Rₙ₅₆ | Ar87 | H | H | H | H | H | Me | H |
| Lₐ₃₇₆₀ | Rₙ₅₉ | Ar87 | H | H | H | H | H | Me | H |
| Lₐ₃₇₆₁ | Rₙ₆₀ | Ar87 | H | H | H | H | H | Me | H |
| Lₐ₃₇₆₂ | Rₙ₆₁ | Ar87 | H | H | H | H | H | Me | H |
| Lₐ₃₇₆₃ | Rₙ₆₂ | Ar87 | H | H | H | H | H | Me | H |
| Lₐ₃₇₆₄ | Rₙ₆₄ | Ar87 | H | H | H | H | H | Me | H |
| Lₐ₃₇₆₅ | Rₙ₆₅ | Ar87 | H | H | H | H | H | Me | H |
| Lₐ₃₇₆₆ | Rₙ₆₉ | Ar87 | H | H | H | H | H | Me | H |
| Lₐ₃₇₆₇ | Rₙ₇₀ | Ar87 | H | H | H | H | H | Me | H |
| Lₐ₃₇₆₈ | Rₙ₈₁ | Ar87 | H | H | H | H | H | Me | H |
| Lₐ₃₇₆₉ | Rₙ₁ | Ar87 | H | H | H | H | Rₙ₁₁ | H | H |
| Lₐ₃₇₇₀ | Rₙ₄ | Ar87 | H | H | H | H | Rₙ₁₁ | H | H |
| Lₐ₃₇₇₁ | Rₙ₅ | Ar87 | H | H | H | H | Rₙ₁₁ | H | H |
| Lₐ₃₇₇₂ | Rₙ₇ | Ar87 | H | H | H | H | Rₙ₁₁ | H | H |
| Lₐ₃₇₇₃ | Rₙ₁₁ | Ar87 | H | H | H | H | Rₙ₁₁ | H | H |
| Lₐ₃₇₇₄ | Rₙ₂₀ | Ar87 | H | H | H | H | Rₙ₁₁ | H | H |
| Lₐ₃₇₇₅ | Rₙ₂₁ | Ar87 | H | H | H | H | Rₙ₁₁ | H | H |
| Lₐ₃₇₇₆ | Rₙ₅₁ | Ar87 | H | H | H | H | Rₙ₁₁ | H | H |
| Lₐ₃₇₇₇ | Rₙ₅₆ | Ar87 | H | H | H | H | Rₙ₁₁ | H | H |
| Lₐ₃₇₇₈ | Rₙ₅₉ | Ar87 | H | H | H | H | Rₙ₁₁ | H | H |
| Lₐ₃₇₇₉ | Rₙ₆₀ | Ar87 | H | H | H | H | Rₙ₁₁ | H | H |
| Lₐ₃₇₈₀ | Rₙ₆₁ | Ar87 | H | H | H | H | Rₙ₁₁ | H | H |
| Lₐ₃₇₈₁ | Rₙ₆₂ | Ar87 | H | H | H | H | Rₙ₁₁ | H | H |
| Lₐ₃₇₈₂ | Rₙ₆₄ | Ar87 | H | H | H | H | Rₙ₁₁ | H | H |
| Lₐ₃₇₈₃ | Rₙ₆₅ | Ar87 | H | H | H | H | Rₙ₁₁ | H | H |
| Lₐ₃₇₈₄ | Rₙ₆₉ | Ar87 | H | H | H | H | Rₙ₁₁ | H | H |
| Lₐ₃₇₈₅ | Rₙ₇₀ | Ar87 | H | H | H | H | Rₙ₁₁ | H | H |
| Lₐ₃₇₈₆ | Rₙ₈₁ | Ar87 | H | H | H | H | Rₙ₁₁ | H | H |
| Lₐ₃₇₈₇ | Rₙ₁ | Ar87 | H | H | H | H | Rₙ₅₉ | H | H |
| Lₐ₃₇₈₈ | Rₙ₄ | Ar87 | H | H | H | H | Rₙ₅₉ | H | H |
| Lₐ₃₇₈₉ | Rₙ₅ | Ar87 | H | H | H | H | Rₙ₅₉ | H | H |
| Lₐ₃₇₉₀ | Rₙ₇ | Ar87 | H | H | H | H | Rₙ₅₉ | H | H |
| Lₐ₃₇₉₁ | Rₙ₁₁ | Ar87 | H | H | H | H | Rₙ₅₉ | H | H |
| Lₐ₃₇₉₂ | Rₙ₂₀ | Ar87 | H | H | H | H | Rₙ₅₉ | H | H |
| Lₐ₃₇₉₃ | Rₙ₂₁ | Ar87 | H | H | H | H | Rₙ₅₉ | H | H |
| Lₐ₃₇₉₄ | Rₙ₅₁ | Ar87 | H | H | H | H | Rₙ₅₉ | H | H |
| Lₐ₃₇₉₅ | Rₙ₅₆ | Ar87 | H | H | H | H | Rₙ₅₉ | H | H |
| Lₐ₃₇₉₆ | Rₙ₅₉ | Ar87 | H | H | H | H | Rₙ₅₉ | H | H |
| Lₐ₃₇₉₇ | Rₙ₆₀ | Ar87 | H | H | H | H | Rₙ₅₉ | H | H |
| Lₐ₃₇₉₈ | Rₙ₆₁ | Ar87 | H | H | H | H | Rₙ₅₉ | H | H |
| Lₐ₃₇₉₉ | Rₙ₆₂ | Ar87 | H | H | H | H | Rₙ₅₉ | H | H |
| Lₐ₃₈₀₀ | Rₙ₆₄ | Ar87 | H | H | H | H | Rₙ₅₉ | H | H |
| Lₐ₃₈₀₁ | Rₙ₆₅ | Ar87 | H | H | H | H | Rₙ₅₉ | H | H |
| Lₐ₃₈₀₂ | Rₙ₆₉ | Ar87 | H | H | H | H | Rₙ₅₉ | H | H |
| Lₐ₃₈₀₃ | Rₙ₇₀ | Ar87 | H | H | H | H | Rₙ₅₉ | H | H |
| Lₐ₃₈₀₄ | Rₙ₈₁ | Ar87 | H | H | H | H | Rₙ₅₉ | H | H |
| Lₐ₃₈₀₅ | Rₙ₁ | Ar87 | H | H | H | H | Rₙ₆₀ | H | H |
| Lₐ₃₈₀₆ | Rₙ₄ | Ar87 | H | H | H | H | Rₙ₆₀ | H | H |
| Lₐ₃₈₀₇ | Rₙ₅ | Ar87 | H | H | H | H | Rₙ₆₀ | H | H |
| Lₐ₃₈₀₈ | Rₙ₇ | Ar87 | H | H | H | H | Rₙ₆₀ | H | H |
| Lₐ₃₈₀₉ | Rₙ₁₁ | Ar87 | H | H | H | H | Rₙ₆₀ | H | H |
| Lₐ₃₈₁₀ | Rₙ₂₀ | Ar87 | H | H | H | H | Rₙ₆₀ | H | H |
| Lₐ₃₈₁₁ | Rₙ₂₁ | Ar87 | H | H | H | H | Rₙ₆₀ | H | H |
| Lₐ₃₈₁₂ | Rₙ₅₁ | Ar87 | H | H | H | H | Rₙ₆₀ | H | H |
| Lₐ₃₈₁₃ | Rₙ₅₆ | Ar87 | H | H | H | H | Rₙ₆₀ | H | H |
| Lₐ₃₈₁₄ | Rₙ₅₉ | Ar87 | H | H | H | H | Rₙ₆₀ | H | H |
| Lₐ₃₈₁₅ | Rₙ₆₀ | Ar87 | H | H | H | H | Rₙ₆₀ | H | H |
| Lₐ₃₈₁₆ | Rₙ₆₁ | Ar87 | H | H | H | H | Rₙ₆₀ | H | H |
| Lₐ₃₈₁₇ | Rₙ₆₂ | Ar87 | H | H | H | H | Rₙ₆₀ | H | H |
| Lₐ₃₈₁₈ | Rₙ₆₄ | Ar87 | H | H | H | H | Rₙ₆₀ | H | H |
| Lₐ₃₈₁₉ | Rₙ₆₅ | Ar87 | H | H | H | H | Rₙ₆₀ | H | H |
| Lₐ₃₈₂₀ | Rₙ₆₉ | Ar87 | H | H | H | H | Rₙ₆₀ | H | H |
| Lₐ₃₈₂₁ | Rₙ₇₀ | Ar87 | H | H | H | H | Rₙ₆₀ | H | H |
| Lₐ₃₈₂₂ | Rₙ₈₁ | Ar87 | H | H | H | H | Rₙ₆₀ | H | H |
| Lₐ₃₈₂₃ | Rₙ₁ | Ar87 | H | H | H | H | Rₙ₆₄ | H | H |
| Lₐ₃₈₂₄ | Rₙ₄ | Ar87 | H | H | H | H | Rₙ₆₄ | H | H |
| Lₐ₃₈₂₅ | Rₙ₅ | Ar87 | H | H | H | H | Rₙ₆₄ | H | H |
| Lₐ₃₈₂₆ | Rₙ₇ | Ar87 | H | H | H | H | Rₙ₆₄ | H | H |
| Lₐ₃₈₂₇ | Rₙ₁₁ | Ar87 | H | H | H | H | Rₙ₆₄ | H | H |
| Lₐ₃₈₂₈ | Rₙ₂₀ | Ar87 | H | H | H | H | Rₙ₆₄ | H | H |
| Lₐ₃₈₂₉ | Rₙ₂₁ | Ar87 | H | H | H | H | Rₙ₆₄ | H | H |
| Lₐ₃₈₃₀ | Rₙ₅₁ | Ar87 | H | H | H | H | Rₙ₆₄ | H | H |
| Lₐ₃₈₃₁ | Rₙ₅₆ | Ar87 | H | H | H | H | Rₙ₆₄ | H | H |
| Lₐ₃₈₃₂ | Rₙ₅₉ | Ar87 | H | H | H | H | Rₙ₆₄ | H | H |
| Lₐ₃₈₃₃ | Rₙ₆₀ | Ar87 | H | H | H | H | Rₙ₆₄ | H | H |
| Lₐ₃₈₃₄ | Rₙ₆₁ | Ar87 | H | H | H | H | Rₙ₆₄ | H | H |
| Lₐ₃₈₃₅ | Rₙ₆₂ | Ar87 | H | H | H | H | Rₙ₆₄ | H | H |
| Lₐ₃₈₃₆ | Rₙ₆₄ | Ar87 | H | H | H | H | Rₙ₆₄ | H | H |
| Lₐ₃₈₃₇ | Rₙ₆₅ | Ar87 | H | H | H | H | Rₙ₆₄ | H | H |
| Lₐ₃₈₃₈ | Rₙ₆₉ | Ar87 | H | H | H | H | Rₙ₆₄ | H | H |
| Lₐ₃₈₃₉ | Rₙ₇₀ | Ar87 | H | H | H | H | Rₙ₆₄ | H | H |
| Lₐ₃₈₄₀ | Rₙ₈₁ | Ar87 | H | H | H | H | Rₙ₆₄ | H | H |
| Lₐ₃₈₄₁ | Rₙ₁ | Ar87 | H | H | H | H | Me | H | H |
| Lₐ₃₈₄₂ | Rₙ₄ | Ar87 | H | H | H | H | Me | H | H |
| Lₐ₃₈₄₃ | Rₙ₅ | Ar87 | H | H | H | H | Me | H | H |
| Lₐ₃₈₄₄ | Rₙ₇ | Ar87 | H | H | H | H | Me | H | H |
| Lₐ₃₈₄₅ | Rₙ₁₁ | Ar87 | H | H | H | H | Me | H | H |
| Lₐ₃₈₄₆ | Rₙ₂₀ | Ar87 | H | H | H | H | Me | H | H |
| Lₐ₃₈₄₇ | Rₙ₂₁ | Ar87 | H | H | H | H | Me | H | H |
| Lₐ₃₈₄₈ | Rₙ₅₁ | Ar87 | H | H | H | H | Me | H | H |
| Lₐ₃₈₄₉ | Rₙ₅₆ | Ar87 | H | H | H | H | Me | H | H |
| Lₐ₃₈₅₀ | Rₙ₅₉ | Ar87 | H | H | H | H | Me | H | H |
| Lₐ₃₈₅₁ | Rₙ₆₀ | Ar87 | H | H | H | H | Me | H | H |
| Lₐ₃₈₅₂ | Rₙ₆₁ | Ar87 | H | H | H | H | Me | H | H |
| Lₐ₃₈₅₃ | Rₙ₆₂ | Ar87 | H | H | H | H | Me | H | H |
| Lₐ₃₈₅₄ | Rₙ₆₄ | Ar87 | H | H | H | H | Me | H | H |
| Lₐ₃₈₅₅ | Rₙ₆₅ | Ar87 | H | H | H | H | Me | H | H |
| Lₐ₃₈₅₆ | Rₙ₆₉ | Ar87 | H | H | H | H | Me | H | H |
| Lₐ₃₈₅₇ | Rₙ₇₀ | Ar87 | H | H | H | H | Me | H | H |
| Lₐ₃₈₅₈ | Rₙ₈₁ | Ar87 | H | H | H | H | Me | H | H |
| Lₐ₃₈₅₉ | Rₙ₁ | Ar87 | H | H | F | H | H | H | H |
| Lₐ₃₈₆₀ | Rₙ₄ | Ar87 | D | H | F | H | H | H | H |
| Lₐ₃₈₆₁ | Rₙ₇ | Ar87 | H | H | F | H | H | H | H |
| Lₐ₃₈₆₂ | Rₙ₂₀ | Ar87 | H | H | F | H | H | H | H |
| Lₐ₃₈₆₃ | Rₙ₂₁ | Ar87 | H | H | F | H | H | H | H |
| Lₐ₃₈₆₄ | Rₙ₅₆ | Ar87 | H | H | F | H | H | H | H |
| Lₐ₃₈₆₅ | Rₙ₅₉ | Ar87 | H | H | F | H | H | H | H |
| Lₐ₃₈₆₆ | Rₙ₆₁ | Ar87 | H | D | F | H | H | H | H |
| Lₐ₃₈₆₇ | Rₙ₆₂ | Ar87 | H | H | F | H | H | H | H |
| Lₐ₃₈₆₈ | Rₙ₆₄ | Ar87 | H | H | F | H | H | H | H |
| Lₐ₃₈₆₉ | Rₙ₆₉ | Ar87 | H | H | F | H | H | H | H |
| Lₐ₃₈₇₀ | Rₙ₇₀ | Ar87 | H | H | F | H | H | H | H |
| Lₐ₃₈₇₁ | Rₙ₁ | Ar87 | H | H | F | H | Rₙ₁₁ | H | H |
| Lₐ₃₈₇₂ | Rₙ₄ | Ar87 | H | H | F | H | Rₙ₁₁ | H | H |
| Lₐ₃₈₇₃ | Rₙ₇ | Ar87 | H | H | F | H | Rₙ₁₁ | H | H |
| Lₐ₃₈₇₄ | Rₙ₂₀ | Ar87 | H | H | F | H | Rₙ₁₁ | H | H |
| Lₐ₃₈₇₅ | Rₙ₂₁ | Ar87 | H | H | F | H | Rₙ₁₁ | H | H |
| Lₐ₃₈₇₆ | Rₙ₅₆ | Ar87 | H | H | F | H | Rₙ₁₁ | H | H |
| Lₐ₃₈₇₇ | Rₙ₅₉ | Ar87 | H | H | F | H | Rₙ₁₁ | H | H |
| Lₐ₃₈₇₈ | Rₙ₆₁ | Ar87 | H | H | F | H | Rₙ₁₁ | H | H |
| Lₐ₃₈₇₉ | Rₙ₆₂ | Ar87 | H | H | F | H | Rₙ₁₁ | H | H |
| Lₐ₃₈₈₀ | Rₙ₆₄ | Ar87 | H | H | F | H | Rₙ₁₁ | H | H |
| Lₐ₃₈₈₁ | Rₙ₆₉ | Ar87 | H | H | F | H | Rₙ₁₁ | H | H |
| Lₐ₃₈₈₂ | Rₙ₇₀ | Ar87 | H | H | F | H | Rₙ₁₁ | H | H |
| Lₐ₃₈₈₃ | Rₙ₁ | Ar87 | H | H | F | H | Rₙ₆₀ | H | H |
| Lₐ₃₈₈₄ | Rₙ₄ | Ar87 | H | H | F | H | Rₙ₆₀ | H | H |
| Lₐ₃₈₈₅ | Rₙ₇ | Ar87 | H | H | F | H | Rₙ₆₀ | H | H |
| Lₐ₃₈₈₆ | Rₙ₂₀ | Ar87 | H | H | F | H | Rₙ₆₀ | H | H |
| Lₐ₃₈₈₇ | Rₙ₂₁ | Ar87 | H | H | F | H | Rₙ₆₀ | H | H |
| Lₐ₃₈₈₈ | Rₙ₅₆ | Ar87 | H | H | F | H | Rₙ₆₀ | H | H |
| Lₐ₃₈₈₉ | Rₙ₅₉ | Ar87 | H | H | F | H | Rₙ₆₀ | H | H |
| Lₐ₃₈₉₀ | Rₙ₆₁ | Ar87 | H | H | F | H | Rₙ₆₀ | H | H |
| Lₐ₃₈₉₁ | Rₙ₆₂ | Ar87 | H | H | F | H | Rₙ₆₀ | H | H |
| Lₐ₃₈₉₂ | Rₙ₆₄ | Ar87 | H | H | F | H | Rₙ₆₀ | H | H |
| Lₐ₃₈₉₃ | Rₙ₆₉ | Ar87 | H | H | F | H | Rₙ₆₀ | H | H |
| Lₐ₃₈₉₄ | Rₙ₇₀ | Ar87 | H | H | F | H | Rₙ₆₀ | H | H |
| Lₐ₃₈₉₅ | Rₙ₁ | Ar87 | H | D | F | H | H | Rₙ₁₁ | H |
| Lₐ₃₈₉₆ | Rₙ₄ | Ar87 | H | H | F | H | H | Rₙ₁₁ | H |
| Lₐ₃₈₉₇ | Rₙ₇ | Ar87 | H | H | F | H | H | Rₙ₁₁ | H |
| Lₐ₃₈₉₈ | Rₙ₂₀ | Ar87 | H | H | F | H | H | Rₙ₁₁ | H |
| Lₐ₃₈₉₉ | Rₙ₂₁ | Ar87 | H | H | F | H | H | Rₙ₁₁ | H |
| Lₐ₃₉₀₀ | Rₙ₅₆ | Ar87 | H | H | F | H | H | Rₙ₁₁ | H |
| Lₐ₃₉₀₁ | Rₙ₅₉ | Ar87 | H | H | F | H | H | Rₙ₁₁ | H |
| Lₐ₃₉₀₂ | Rₙ₆₁ | Ar87 | H | H | F | H | H | Rₙ₁₁ | H |
| Lₐ₃₉₀₃ | Rₙ₆₂ | Ar87 | H | H | F | D | H | Rₙ₁₁ | H |
| Lₐ₃₉₀₄ | Rₙ₆₄ | Ar87 | H | H | F | H | H | Rₙ₁₁ | H |
| Lₐ₃₉₀₅ | Rₙ₆₉ | Ar87 | H | H | F | H | H | Rₙ₁₁ | H |
| Lₐ₃₉₀₆ | Rₙ₇₀ | Ar87 | H | H | F | H | H | Rₙ₁₁ | H |
| Lₐ₃₉₀₇ | Rₙ₁ | Ar87 | H | H | F | H | H | Rₙ₆₀ | H |
| Lₐ₃₉₀₈ | Rₙ₄ | Ar87 | H | H | F | H | H | Rₙ₆₀ | H |
| Lₐ₃₉₀₉ | Rₙ₇ | Ar87 | H | H | F | H | H | Rₙ₆₀ | H |
| Lₐ₃₉₁₀ | Rₙ₂₀ | Ar87 | H | H | F | H | H | Rₙ₆₀ | H |
| Lₐ₃₉₁₁ | Rₙ₂₁ | Ar87 | H | H | F | H | H | Rₙ₆₀ | H |
| Lₐ₃₉₁₂ | Rₙ₅₆ | Ar87 | D | H | F | H | H | Rₙ₆₀ | H |
| Lₐ₃₉₁₃ | Rₙ₅₉ | Ar87 | H | H | F | H | H | Rₙ₆₀ | H |
| Lₐ₃₉₁₄ | Rₙ₆₁ | Ar87 | H | H | F | H | H | Rₙ₆₀ | H |
| Lₐ₃₉₁₅ | Rₙ₆₂ | Ar87 | H | H | F | H | H | Rₙ₆₀ | H |
| Lₐ₃₉₁₆ | Rₙ₆₄ | Ar87 | H | H | F | H | H | Rₙ₆₀ | H |
| Lₐ₃₉₁₇ | Rₙ₆₉ | Ar87 | H | H | F | H | H | Rₙ₆₀ | H |
| Lₐ₃₉₁₈ | Rₙ₇₀ | Ar87 | H | H | F | H | H | Rₙ₆₀ | H |
| Lₐ₃₉₁₉ | Rₙ₁ | Ar87 | H | H | CN | H | H | H | H |
| Lₐ₃₉₂₀ | Rₙ₄ | Ar87 | H | H | CN | H | H | H | H |
| Lₐ₃₉₂₁ | Rₙ₇ | Ar87 | H | H | CN | H | H | H | H |
| Lₐ₃₉₂₂ | Rₙ₂₀ | Ar87 | H | H | CN | H | H | H | H |
| Lₐ₃₉₂₃ | Rₙ₂₁ | Ar87 | H | H | CN | H | H | H | H |
| Lₐ₃₉₂₄ | Rₙ₅₆ | Ar87 | H | H | CN | H | H | H | H |
| Lₐ₃₉₂₅ | Rₙ₅₉ | Ar87 | H | H | CN | H | H | H | H |
| Lₐ₃₉₂₆ | Rₙ₆₁ | Ar87 | H | H | CN | H | H | H | H |
| Lₐ₃₉₂₇ | Rₙ₆₂ | Ar87 | H | H | CN | H | H | H | H |
| Lₐ₃₉₂₈ | Rₙ₆₄ | Ar87 | H | H | CN | H | H | H | H |
| Lₐ₃₉₂₉ | Rₙ₆₉ | Ar87 | H | H | CN | H | H | H | H |
| Lₐ₃₉₃₀ | Rₙ₇₀ | Ar87 | H | H | CN | H | H | H | H |
| Lₐ₃₉₃₁ | Rₙ₁ | Ar87 | H | CN | H | H | H | H | H |
| Lₐ₃₉₃₂ | Rₙ₄ | Ar87 | H | CN | H | H | H | H | H |
| Lₐ₃₉₃₃ | Rₙ₇ | Ar87 | H | CN | H | H | H | H | H |
| Lₐ₃₉₃₄ | Rₙ₂₀ | Ar87 | H | CN | H | H | H | H | H |
| Lₐ₃₉₃₅ | Rₙ₂₁ | Ar87 | H | CN | H | H | H | H | H |
| Lₐ₃₉₃₆ | Rₙ₅₆ | Ar87 | H | CN | H | H | H | H | H |
| Lₐ₃₉₃₇ | Rₙ₅₉ | Ar87 | H | CN | H | H | H | H | H |
| Lₐ₃₉₃₈ | Rₙ₆₁ | Ar87 | H | CN | H | H | H | H | H |
| Lₐ₃₉₃₉ | Rₙ₆₂ | Ar87 | H | CN | H | H | H | H | H |
| Lₐ₃₉₄₀ | Rₙ₆₄ | Ar87 | H | CN | H | H | H | H | H |
| Lₐ₃₉₄₁ | Rₙ₆₉ | Ar87 | H | CN | H | H | H | H | H |
| Lₐ₃₉₄₂ | Rₙ₇₀ | Ar87 | H | CN | H | H | H | H | H |
| Lₐ₃₉₄₃ | Rₙ₁ | Ar87 | CN | H | H | H | D | H | H |
| Lₐ₃₉₄₄ | Rₙ₄ | Ar87 | CN | H | H | H | H | H | H |
| Lₐ₃₉₄₅ | Rₙ₇ | Ar87 | CN | H | H | H | H | H | H |
| Lₐ₃₉₄₆ | Rₙ₂₀ | Ar87 | CN | H | H | H | H | H | H |
| Lₐ₃₉₄₇ | Rₙ₂₁ | Ar87 | CN | H | H | H | H | H | H |
| Lₐ₃₉₄₈ | Rₙ₅₆ | Ar87 | CN | H | H | H | H | H | H |
| Lₐ₃₉₄₉ | Rₙ₅₉ | Ar87 | CN | H | H | H | H | H | H |
| Lₐ₃₉₅₀ | Rₙ₆₁ | Ar87 | CN | H | H | H | H | H | H |
| Lₐ₃₉₅₁ | Rₙ₆₂ | Ar87 | CN | H | H | H | H | H | H |
| Lₐ₃₉₅₂ | Rₙ₆₄ | Ar87 | CN | H | H | H | H | H | H |
| Lₐ₃₉₅₃ | Rₙ₆₉ | Ar87 | CN | H | H | H | H | H | H |
| Lₐ₃₉₅₄ | Rₙ₇₀ | Ar87 | CN | H | H | H | H | H | H |
| Lₐ₃₉₅₅ | Rₙ₁ | Ar87 | H | H | CN | H | Rₙ₁₁ | H | H |
| Lₐ₃₉₅₆ | Rₙ₄ | Ar87 | H | H | CN | H | Rₙ₁₁ | H | H |
| Lₐ₃₉₅₇ | Rₙ₇ | Ar87 | H | D | CN | H | Rₙ₁₁ | H | H |
| Lₐ₃₉₅₈ | Rₙ₂₀ | Ar87 | H | H | CN | H | Rₙ₁₁ | H | H |
| Lₐ₃₉₅₉ | Rₙ₂₁ | Ar87 | H | H | CN | H | Rₙ₁₁ | H | H |
| Lₐ₃₉₆₀ | Rₙ₅₆ | Ar87 | H | H | CN | H | Rₙ₁₁ | H | H |
| Lₐ₃₉₆₁ | Rₙ₅₉ | Ar87 | H | H | CN | H | Rₙ₁₁ | H | H |
| Lₐ₃₉₆₂ | Rₙ₆₁ | Ar87 | H | H | CN | H | Rₙ₁₁ | H | H |
| Lₐ₃₉₆₃ | Rₙ₆₂ | Ar87 | H | H | CN | H | Rₙ₁₁ | H | H |
| Lₐ₃₉₆₄ | Rₙ₆₄ | Ar87 | H | H | CN | H | Rₙ₁₁ | H | H |
| Lₐ₃₉₆₅ | Rₙ₆₉ | Ar87 | H | H | CN | H | Rₙ₁₁ | H | H |
| Lₐ₃₉₆₆ | Rₙ₇₀ | Ar87 | H | H | CN | H | Rₙ₁₁ | H | H |
| Lₐ₃₉₆₇ | Rₙ₁ | Ar87 | H | H | CN | H | Rₙ₆₀ | H | H |
| Lₐ₃₉₆₈ | Rₙ₄ | Ar87 | H | H | CN | H | Rₙ₆₀ | H | H |
| Lₐ₃₉₆₉ | Rₙ₇ | Ar87 | H | H | CN | H | Rₙ₆₀ | H | H |
| Lₐ₃₉₇₀ | Rₙ₂₀ | Ar87 | H | H | CN | H | Rₙ₆₀ | H | H |
| Lₐ₃₉₇₁ | Rₙ₂₁ | Ar87 | H | H | CN | H | Rₙ₆₀ | H | H |
| Lₐ₃₉₇₂ | Rₙ₅₆ | Ar87 | H | H | CN | H | Rₙ₆₀ | H | H |
| Lₐ₃₉₇₃ | Rₙ₅₉ | Ar87 | D | H | CN | H | Rₙ₆₀ | H | H |
| Lₐ₃₉₇₄ | Rₙ₆₁ | Ar87 | H | H | CN | H | Rₙ₆₀ | H | H |
| Lₐ₃₉₇₅ | Rₙ₆₂ | Ar87 | H | H | CN | H | Rₙ₆₀ | H | H |
| Lₐ₃₉₇₆ | Rₙ₆₄ | Ar87 | H | H | CN | H | Rₙ₆₀ | H | H |
| Lₐ₃₉₇₇ | Rₙ₆₉ | Ar87 | H | H | CN | H | Rₙ₆₀ | H | H |
| Lₐ₃₉₇₈ | Rₙ₇₀ | Ar87 | H | H | CN | H | Rₙ₆₀ | H | H |
| Lₐ₃₉₇₉ | Rₙ₁ | Ar87 | H | H | CN | H | Rₙ₆₄ | H | H |
| Lₐ₃₉₈₀ | Rₙ₄ | Ar87 | H | H | CN | H | Rₙ₆₄ | H | H |
| Lₐ₃₉₈₁ | Rₙ₇ | Ar87 | H | H | CN | H | Rₙ₆₄ | H | H |
| Lₐ₃₉₈₂ | Rₙ₂₀ | Ar87 | H | H | CN | H | Rₙ₆₄ | H | H |
| Lₐ₃₉₈₃ | Rₙ₂₁ | Ar87 | H | H | CN | H | Rₙ₆₄ | H | H |
| Lₐ₃₉₈₄ | Rₙ₅₆ | Ar87 | H | H | CN | H | Rₙ₆₄ | H | H |
| Lₐ₃₉₈₅ | Rₙ₅₉ | Ar87 | H | H | CN | H | Rₙ₆₄ | H | H |
| Lₐ₃₉₈₆ | Rₙ₆₁ | Ar87 | H | H | CN | H | Rₙ₆₄ | H | H |
| Lₐ₃₉₈₇ | Rₙ₆₂ | Ar87 | H | H | CN | H | Rₙ₆₄ | H | H |
| Lₐ₃₉₈₈ | Rₙ₆₄ | Ar87 | H | H | CN | H | Rₙ₆₄ | H | H |
| Lₐ₃₉₈₉ | Rₙ₆₉ | Ar87 | H | H | CN | H | Rₙ₆₄ | H | H |
| Lₐ₃₉₉₀ | Rₙ₇₀ | Ar87 | H | H | CN | H | Rₙ₆₄ | H | H |
| Lₐ₃₉₉₁ | Rₙ₁ | Ar87 | H | H | CN | H | H | Rₙ₁₁ | H |
| Lₐ₃₉₉₂ | Rₙ₄ | Ar87 | H | H | CN | H | H | Rₙ₁₁ | H |
| Lₐ₃₉₉₃ | Rₙ₇ | Ar87 | H | H | CN | H | H | Rₙ₁₁ | H |
| Lₐ₃₉₉₄ | Rₙ₂₀ | Ar87 | H | H | CN | H | H | Rₙ₁₁ | H |
| Lₐ₃₉₉₅ | Rₙ₂₁ | Ar87 | H | H | CN | H | H | Rₙ₁₁ | H |
| Lₐ₃₉₉₆ | Rₙ₅₆ | Ar87 | H | H | CN | H | H | Rₙ₁₁ | H |
| Lₐ₃₉₉₇ | Rₙ₅₉ | Ar87 | H | H | CN | H | H | Rₙ₁₁ | H |
| Lₐ₃₉₉₈ | Rₙ₆₁ | Ar87 | H | H | CN | H | H | Rₙ₁₁ | H |
| Lₐ₃₉₉₉ | Rₙ₆₂ | Ar87 | H | H | CN | H | H | Rₙ₁₁ | H |
| Lₐ₄₀₀₀ | Rₙ₆₄ | Ar87 | H | H | CN | H | H | Rₙ₁₁ | H |
| Lₐ₄₀₀₁ | Rₙ₆₉ | Ar87 | H | H | CN | H | H | Rₙ₁₁ | H |
| Lₐ₄₀₀₂ | Rₙ₇₀ | Ar87 | H | H | CN | H | H | Rₙ₁₁ | H |
| Lₐ₄₀₀₃ | Rₙ₁ | Ar87 | H | H | CN | H | H | Rₙ₆₀ | D |
| Lₐ₄₀₀₄ | Rₙ₄ | Ar87 | H | H | CN | H | H | Rₙ₆₀ | H |
| Lₐ₄₀₀₅ | Rₙ₇ | Ar87 | H | H | CN | H | H | Rₙ₆₀ | H |
| Lₐ₄₀₀₆ | Rₙ₂₀ | Ar87 | H | H | CN | H | H | Rₙ₆₀ | H |
| Lₐ₄₀₀₇ | Rₙ₂₁ | Ar87 | H | D | CN | H | H | Rₙ₆₀ | H |
| Lₐ₄₀₀₈ | Rₙ₅₆ | Ar87 | H | H | CN | H | H | Rₙ₆₀ | H |
| Lₐ₄₀₀₉ | Rₙ₅₉ | Ar87 | H | H | CN | H | H | Rₙ₆₀ | H |
| Lₐ₄₀₁₀ | Rₙ₆₁ | Ar87 | H | H | CN | H | H | Rₙ₆₀ | H |
| Lₐ₄₀₁₁ | Rₙ₆₂ | Ar87 | H | H | CN | H | H | Rₙ₆₀ | H |
| Lₐ₄₀₁₂ | Rₙ₆₄ | Ar87 | H | H | CN | H | H | Rₙ₆₀ | H |
| Lₐ₄₀₁₃ | Rₙ₆₉ | Ar87 | H | H | CN | H | H | Rₙ₆₀ | H |
| Lₐ₄₀₁₄ | Rₙ₇₀ | Ar87 | H | H | CN | H | H | Rₙ₆₀ | H |
| Lₐ₄₀₁₅ | Rₙ₁ | Ar87 | H | H | CN | H | H | Rₙ₆₄ | H |
| Lₐ₄₀₁₆ | Rₙ₄ | Ar87 | H | H | CN | H | H | Rₙ₆₄ | H |
| Lₐ₄₀₁₇ | Rₙ₇ | Ar87 | H | H | CN | H | H | Rₙ₆₄ | H |
| Lₐ₄₀₁₈ | Rₙ₂₀ | Ar87 | H | H | CN | H | H | Rₙ₆₄ | H |
| Lₐ₄₀₁₉ | Rₙ₂₁ | Ar87 | H | H | CN | H | H | Rₙ₆₄ | H |
| Lₐ₄₀₂₀ | Rₙ₅₆ | Ar87 | H | H | CN | H | H | Rₙ₆₄ | H |
| Lₐ₄₀₂₁ | Rₙ₅₉ | Ar87 | H | H | CN | H | H | Rₙ₆₄ | H |
| Lₐ₄₀₂₂ | Rₙ₆₁ | Ar87 | H | H | CN | H | H | Rₙ₆₄ | H |
| Lₐ₄₀₂₃ | Rₙ₆₂ | Ar87 | H | H | CN | H | H | Rₙ₆₄ | H |
| Lₐ₄₀₂₄ | Rₙ₆₄ | Ar87 | H | H | CN | H | H | Rₙ₆₄ | H |
| Lₐ₄₀₂₅ | Rₙ₆₉ | Ar87 | D | H | CN | H | H | Rₙ₆₄ | H |
| Lₐ₄₀₂₆ | Rₙ₇₀ | Ar87 | H | H | CN | H | H | Rₙ₆₄ | H |
| Lₐ₄₀₂₇ | Rₙ₁ | Ar94 | H | H | H | H | H | H | H |
| Lₐ₄₀₂₈ | Rₙ₄ | Ar94 | H | H | H | H | H | H | H |
| Lₐ₄₀₂₉ | Rₙ₅ | Ar94 | H | H | H | H | H | H | H |
| Lₐ₄₀₃₀ | Rₙ₇ | Ar94 | H | H | H | H | H | H | H |
| Lₐ₄₀₃₁ | Rₙ₁₁ | Ar94 | H | H | H | H | H | H | H |
| Lₐ₄₀₃₂ | Rₙ₂₀ | Ar94 | H | H | H | H | H | H | H |
| Lₐ₄₀₃₃ | Rₙ₂₁ | Ar94 | H | H | H | H | H | H | H |
| Lₐ₄₀₃₄ | Rₙ₅₁ | Ar94 | H | H | H | H | H | H | H |
| Lₐ₄₀₃₅ | Rₙ₅₆ | Ar94 | H | H | H | H | H | H | H |
| Lₐ₄₀₃₆ | Rₙ₅₉ | Ar94 | H | H | H | H | H | H | H |
| Lₐ₄₀₃₇ | Rₙ₆₀ | Ar94 | H | H | H | H | H | H | H |
| Lₐ₄₀₃₈ | Rₙ₆₁ | Ar94 | H | H | H | H | H | H | H |
| Lₐ₄₀₃₉ | Rₙ₆₂ | Ar94 | H | H | H | H | H | H | H |
| Lₐ₄₀₄₀ | Rₙ₆₄ | Ar94 | H | H | H | H | H | H | H |
| Lₐ₄₀₄₁ | Rₙ₆₅ | Ar94 | H | H | H | H | H | H | H |
| Lₐ₄₀₄₂ | Rₙ₆₉ | Ar94 | H | H | H | H | H | H | H |
| Lₐ₄₀₄₃ | Rₙ₇₀ | Ar94 | H | H | H | H | H | H | H |
| Lₐ₄₀₄₄ | Rₙ₈₁ | Ar94 | H | H | H | H | H | H | H |
| Lₐ₄₀₄₅ | Rₙ₁ | Ar94 | H | H | H | H | H | Rₙ₁₁ | H |
| Lₐ₄₀₄₆ | Rₙ₄ | Ar94 | H | H | H | H | H | Rₙ₁₁ | H |
| Lₐ₄₀₄₇ | Rₙ₅ | Ar94 | H | H | H | H | H | Rₙ₁₁ | H |
| Lₐ₄₀₄₈ | Rₙ₇ | Ar94 | H | H | H | H | H | Rₙ₁₁ | H |
| Lₐ₄₀₄₉ | Rₙ₁₁ | Ar94 | H | H | H | H | H | Rₙ₁₁ | H |
| Lₐ₄₀₅₀ | Rₙ₂₀ | Ar94 | H | H | H | H | H | Rₙ₁₁ | H |
| Lₐ₄₀₅₁ | Rₙ₂₁ | Ar94 | H | H | H | H | H | Rₙ₁₁ | H |
| Lₐ₄₀₅₂ | Rₙ₅₁ | Ar94 | H | H | H | H | H | Rₙ₁₁ | H |
| Lₐ₄₀₅₃ | Rₙ₅₆ | Ar94 | H | H | H | H | H | Rₙ₁₁ | H |
| Lₐ₄₀₅₄ | Rₙ₅₉ | Ar94 | H | H | H | H | H | Rₙ₁₁ | H |
| Lₐ₄₀₅₅ | Rₙ₆₀ | Ar94 | H | H | H | H | H | Rₙ₁₁ | H |
| Lₐ₄₀₅₆ | Rₙ₆₁ | Ar94 | H | H | H | H | H | Rₙ₁₁ | H |
| Lₐ₄₀₅₇ | Rₙ₆₂ | Ar94 | H | H | H | H | H | Rₙ₁₁ | H |
| Lₐ₄₀₅₈ | Rₙ₆₄ | Ar94 | H | H | H | H | H | Rₙ₁₁ | H |
| Lₐ₄₀₅₉ | Rₙ₆₅ | Ar94 | H | H | H | H | H | Rₙ₁₁ | H |
| Lₐ₄₀₆₀ | Rₙ₆₉ | Ar94 | H | H | H | H | H | Rₙ₁₁ | H |
| Lₐ₄₀₆₁ | Rₙ₇₀ | Ar94 | H | H | H | H | H | Rₙ₁₁ | H |
| Lₐ₄₀₆₂ | Rₙ₈₁ | Ar94 | H | H | H | H | H | Rₙ₁₁ | H |
| Lₐ₄₀₆₃ | Rₙ₁ | Ar94 | H | H | H | H | H | Rₙ₅₉ | H |
| Lₐ₄₀₆₄ | Rₙ₄ | Ar94 | H | H | H | H | H | Rₙ₅₉ | H |
| Lₐ₄₀₆₅ | Rₙ₅ | Ar94 | H | H | H | H | H | Rₙ₅₉ | H |
| Lₐ₄₀₆₆ | Rₙ₇ | Ar94 | H | H | H | H | H | Rₙ₅₉ | H |
| Lₐ₄₀₆₇ | Rₙ₁ | Ar94 | H | H | H | H | H | Rₙ₅₉ | H |
| Lₐ₄₀₆₈ | Rₙ₂₀ | Ar94 | H | H | H | H | H | Rₙ₅₉ | H |
| Lₐ₄₀₆₉ | Rₙ₂₁ | Ar94 | H | H | H | H | H | Rₙ₅₉ | H |
| Lₐ₄₀₇₀ | Rₙ₅₁ | Ar94 | H | H | H | H | H | Rₙ₅₉ | H |
| Lₐ₄₀₇₁ | Rₙ₅₆ | Ar94 | H | H | H | H | H | Rₙ₅₉ | H |
| Lₐ₄₀₇₂ | Rₙ₅₉ | Ar94 | H | H | H | H | H | Rₙ₅₉ | H |
| Lₐ₄₀₇₃ | Rₙ₆₀ | Ar94 | H | H | H | H | H | Rₙ₅₉ | H |
| Lₐ₄₀₇₄ | Rₙ₆₁ | Ar94 | H | H | H | H | H | Rₙ₅₉ | H |
| Lₐ₄₀₇₅ | Rₙ₆₂ | Ar94 | H | H | H | H | H | Rₙ₅₉ | H |
| Lₐ₄₀₇₆ | Rₙ₆₄ | Ar94 | H | H | H | H | H | Rₙ₅₉ | H |
| Lₐ₄₀₇₇ | Rₙ₆₅ | Ar94 | H | H | H | H | H | Rₙ₅₉ | H |
| Lₐ₄₀₇₈ | Rₙ₆₉ | Ar94 | H | H | H | H | H | Rₙ₅₉ | H |
| Lₐ₄₀₇₉ | Rₙ₇₀ | Ar94 | H | H | H | H | H | Rₙ₅₉ | H |
| Lₐ₄₀₈₀ | Rₙ₈₁ | Ar94 | H | H | H | H | H | Rₙ₅₉ | H |
| Lₐ₄₀₈₁ | Rₙ₁ | Ar94 | H | H | H | H | H | Rₙ₆₀ | H |
| Lₐ₄₀₈₂ | Rₙ₄ | Ar94 | H | H | H | H | H | Rₙ₆₀ | H |
| Lₐ₄₀₈₃ | Rₙ₅ | Ar94 | H | H | H | H | H | Rₙ₆₀ | H |
| Lₐ₄₀₈₄ | Rₙ₇ | Ar94 | H | H | H | H | H | Rₙ₆₀ | H |
| Lₐ₄₀₈₅ | Rₙ₁₁ | Ar94 | H | H | H | H | H | Rₙ₆₀ | H |
| Lₐ₄₀₈₆ | Rₙ₂₀ | Ar94 | H | H | H | H | H | Rₙ₆₀ | H |
| Lₐ₄₀₈₇ | Rₙ₂₁ | Ar94 | H | H | H | H | H | Rₙ₆₀ | H |
| Lₐ₄₀₈₈ | Rₙ₅₁ | Ar94 | H | H | H | H | H | Rₙ₆₀ | H |
| Lₐ₄₀₈₉ | Rₙ₅₆ | Ar94 | H | H | H | H | H | Rₙ₆₀ | H |
| Lₐ₄₀₉₀ | Rₙ₅₉ | Ar94 | H | H | H | H | H | Rₙ₆₀ | H |
| Lₐ₄₀₉₁ | Rₙ₆₀ | Ar94 | H | H | H | H | H | Rₙ₆₀ | H |
| Lₐ₄₀₉₂ | Rₙ₆₁ | Ar94 | H | H | H | H | H | Rₙ₆₀ | H |
| Lₐ₄₀₉₃ | Rₙ₆₂ | Ar94 | H | H | H | H | H | Rₙ₆₀ | H |
| Lₐ₄₀₉₄ | Rₙ₆₄ | Ar94 | H | H | H | H | H | Rₙ₆₀ | H |
| Lₐ₄₀₉₅ | Rₙ₆₅ | Ar94 | H | H | H | H | H | Rₙ₆₀ | H |
| Lₐ₄₀₉₆ | Rₙ₆₉ | Ar94 | H | H | H | H | H | Rₙ₆₀ | H |
| Lₐ₄₀₉₇ | Rₙ₇₀ | Ar94 | H | H | H | H | H | Rₙ₆₀ | H |
| Lₐ₄₀₉₈ | Rₙ₈₁ | Ar94 | H | H | H | H | H | Rₙ₆₀ | H |
| Lₐ₄₀₉₉ | Rₙ₁ | Ar94 | H | H | H | H | H | Rₙ₆₄ | H |
| Lₐ₄₁₀₀ | Rₙ₄ | Ar94 | H | H | H | H | H | Rₙ₆₄ | H |
| Lₐ₄₁₀₁ | Rₙ₅ | Ar94 | H | H | H | H | H | Rₙ₆₄ | H |
| Lₐ₄₁₀₂ | Rₙ₇ | Ar94 | H | H | H | H | H | Rₙ₆₄ | H |
| Lₐ₄₁₀₃ | Rₙ₁₁ | Ar94 | H | H | H | H | H | Rₙ₆₄ | H |
| Lₐ₄₁₀₄ | Rₙ₂₀ | Ar94 | H | H | H | H | H | Rₙ₆₄ | H |
| Lₐ₄₁₀₅ | Rₙ₂₁ | Ar94 | H | H | H | H | H | Rₙ₆₄ | H |
| Lₐ₄₁₀₆ | Rₙ₅₁ | Ar94 | H | H | H | H | H | Rₙ₆₄ | H |
| Lₐ₄₁₀₇ | Rₙ₅₆ | Ar94 | H | H | H | H | H | Rₙ₆₄ | H |
| Lₐ₄₁₀₈ | Rₙ₅₉ | Ar94 | H | H | H | H | H | Rₙ₆₄ | H |
| Lₐ₄₁₀₉ | Rₙ₆₀ | Ar94 | H | H | H | H | H | Rₙ₆₄ | H |
| Lₐ₄₁₁₀ | Rₙ₆₁ | Ar94 | H | H | H | H | H | Rₙ₆₄ | H |
| Lₐ₄₁₁₁ | Rₙ₆₂ | Ar94 | H | H | H | H | H | Rₙ₆₄ | H |
| Lₐ₄₁₁₂ | Rₙ₆₄ | Ar94 | H | H | H | H | H | Rₙ₆₄ | H |
| Lₐ₄₁₁₃ | Rₙ₆₅ | Ar94 | H | H | H | H | H | Rₙ₆₄ | H |
| Lₐ₄₁₁₄ | Rₙ₆₉ | Ar94 | H | H | H | H | H | Rₙ₆₄ | H |
| Lₐ₄₁₁₅ | Rₙ₇₀ | Ar94 | H | H | H | H | H | Rₙ₆₄ | H |
| Lₐ₄₁₁₆ | Rₙ₈₁ | Ar94 | H | H | H | H | H | Rₙ₆₄ | H |
| Lₐ₄₁₁₇ | Rₙ₁ | Ar94 | H | H | H | H | H | Me | H |
| Lₐ₄₁₁₈ | Rₙ₄ | Ar94 | H | H | H | H | H | Me | H |
| Lₐ₄₁₁₉ | Rₙ₅ | Ar94 | H | H | H | H | H | Me | H |
| Lₐ₄₁₂₀ | Rₙ₇ | Ar94 | H | H | H | H | H | Me | H |
| Lₐ₄₁₂₁ | Rₙ₁₁ | Ar94 | H | H | H | H | H | Me | H |
| Lₐ₄₁₂₂ | Rₙ₂₀ | Ar94 | H | H | H | H | H | Me | H |
| Lₐ₄₁₂₃ | Rₙ₂₁ | Ar94 | H | H | H | H | H | Me | H |
| Lₐ₄₁₂₄ | Rₙ₅₁ | Ar94 | H | H | H | H | H | Me | H |
| Lₐ₄₁₂₅ | Rₙ₅₆ | Ar94 | H | H | H | H | H | Me | H |
| Lₐ₄₁₂₆ | Rₙ₅₉ | Ar94 | H | H | H | H | H | Me | H |
| Lₐ₄₁₂₇ | Rₙ₆₀ | Ar94 | H | H | H | H | H | Me | H |
| Lₐ₄₁₂₈ | Rₙ₆₁ | Ar94 | H | H | H | H | H | Me | H |
| Lₐ₄₁₂₉ | Rₙ₆₂ | Ar94 | H | H | H | H | H | Me | H |
| Lₐ₄₁₃₀ | Rₙ₆₄ | Ar94 | H | H | H | H | H | Me | H |
| Lₐ₄₁₃₁ | Rₙ₆₅ | Ar94 | H | H | H | H | H | Me | H |
| Lₐ₄₁₃₂ | Rₙ₆₉ | Ar94 | H | H | H | H | H | Me | H |
| Lₐ₄₁₃₃ | Rₙ₇₀ | Ar94 | H | H | H | H | H | Me | H |
| Lₐ₄₁₃₄ | Rₙ₈₁ | Ar94 | H | H | H | H | H | Me | H |
| Lₐ₄₁₃₅ | Rₙ₁ | Ar94 | H | H | H | H | Rₙ₁₁ | H | H |
| Lₐ₄₁₃₆ | Rₙ₄ | Ar94 | H | H | H | H | Rₙ₁₁ | H | H |
| Lₐ₄₁₃₇ | Rₙ₅ | Ar94 | H | H | H | H | Rₙ₁₁ | H | H |
| Lₐ₄₁₃₈ | Rₙ₇ | Ar94 | H | H | H | H | Rₙ₁₁ | H | H |
| Lₐ₄₁₃₉ | Rₙ₁₁ | Ar94 | H | H | H | H | Rₙ₁₁ | H | H |
| Lₐ₄₁₄₀ | Rₙ₂₀ | Ar94 | H | H | H | H | Rₙ₁₁ | H | H |
| Lₐ₄₁₄₁ | Rₙ₂₁ | Ar94 | H | H | H | H | Rₙ₁₁ | H | H |
| Lₐ₄₁₄₂ | Rₙ₅₁ | Ar94 | H | H | H | H | Rₙ₁₁ | H | H |
| Lₐ₄₁₄₃ | Rₙ₅₆ | Ar94 | H | H | H | H | Rₙ₁₁ | H | H |
| Lₐ₄₁₄₄ | Rₙ₅₉ | Ar94 | H | H | H | H | Rₙ₁₁ | H | H |
| Lₐ₄₁₄₅ | Rₙ₆₀ | Ar94 | H | H | H | H | Rₙ₁₁ | H | H |
| Lₐ₄₁₄₆ | Rₙ₆₁ | Ar94 | H | H | H | H | Rₙ₁₁ | H | H |
| Lₐ₄₁₄₇ | Rₙ₆₂ | Ar94 | H | H | H | H | Rₙ₁₁ | H | H |
| Lₐ₄₁₄₈ | Rₙ₆₄ | Ar94 | H | H | H | H | Rₙ₁₁ | H | H |
| Lₐ₄₁₄₉ | Rₙ₆₅ | Ar94 | H | H | H | H | Rₙ₁₁ | H | H |
| Lₐ₄₁₅₀ | Rₙ₆₉ | Ar94 | H | H | H | H | Rₙ₁₁ | H | H |
| Lₐ₄₁₅₁ | Rₙ₇₀ | Ar94 | H | H | H | H | Rₙ₁₁ | H | H |
| Lₐ₄₁₅₂ | Rₙ₈₁ | Ar94 | H | H | H | H | Rₙ₁₁ | H | H |
| Lₐ₄₁₅₃ | Rₙ₁ | Ar94 | H | H | H | H | Rₙ₅₉ | H | H |
| Lₐ₄₁₅₄ | Rₙ₄ | Ar94 | H | H | H | H | Rₙ₅₉ | H | H |
| Lₐ₄₁₅₅ | Rₙ₅ | Ar94 | H | H | H | H | Rₙ₅₉ | H | H |
| Lₐ₄₁₅₆ | Rₙ₇ | Ar94 | H | H | H | H | Rₙ₅₉ | H | H |
| Lₐ₄₁₅₇ | Rₙ₁₁ | Ar94 | H | H | H | H | Rₙ₅₉ | H | H |
| Lₐ₄₁₅₈ | Rₙ₂₀ | Ar94 | H | H | H | H | Rₙ₅₉ | H | H |
| Lₐ₄₁₅₉ | Rₙ₂₁ | Ar94 | H | H | H | H | Rₙ₅₉ | H | H |
| Lₐ₄₁₆₀ | Rₙ₅₁ | Ar94 | H | H | H | H | Rₙ₅₉ | H | H |
| Lₐ₄₁₆₁ | Rₙ₅₆ | Ar94 | H | H | H | H | Rₙ₅₉ | H | H |
| Lₐ₄₁₆₂ | Rₙ₅₉ | Ar94 | H | H | H | H | Rₙ₅₉ | H | H |
| Lₐ₄₁₆₃ | Rₙ₆₀ | Ar94 | H | H | H | H | Rₙ₅₉ | H | H |
| Lₐ₄₁₆₄ | Rₙ₆₁ | Ar94 | H | H | H | H | Rₙ₅₉ | H | H |
| Lₐ₄₁₆₅ | Rₙ₆₂ | Ar94 | H | H | H | H | Rₙ₅₉ | H | H |
| Lₐ₄₁₆₆ | Rₙ₆₄ | Ar94 | H | H | H | H | Rₙ₅₉ | H | H |
| Lₐ₄₁₆₇ | Rₙ₆₅ | Ar94 | H | H | H | H | Rₙ₅₉ | H | H |
| Lₐ₄₁₆₈ | Rₙ₆₉ | Ar94 | H | H | H | H | Rₙ₅₉ | H | H |
| Lₐ₄₁₆₉ | Rₙ₇₀ | Ar94 | H | H | H | H | Rₙ₅₉ | H | H |
| Lₐ₄₁₇₀ | Rₙ₈₁ | Ar94 | H | H | H | H | Rₙ₅₉ | H | H |
| Lₐ₄₁₇₁ | Rₙ₁ | Ar94 | H | H | H | H | Rₙ₆₀ | H | H |
| Lₐ₄₁₇₂ | Rₙ₄ | Ar94 | H | H | H | H | Rₙ₆₀ | H | H |
| Lₐ₄₁₇₃ | Rₙ₅ | Ar94 | H | H | H | H | Rₙ₆₀ | H | H |
| Lₐ₄₁₇₄ | Rₙ₇ | Ar94 | H | H | H | H | Rₙ₆₀ | H | H |
| Lₐ₄₁₇₅ | Rₙ₁₁ | Ar94 | H | H | H | H | Rₙ₆₀ | H | H |
| Lₐ₄₁₇₆ | Rₙ₂₀ | Ar94 | H | H | H | H | Rₙ₆₀ | H | H |
| Lₐ₄₁₇₇ | Rₙ₂₁ | Ar94 | H | H | H | H | Rₙ₆₀ | H | H |
| Lₐ₄₁₇₈ | Rₙ₅₁ | Ar94 | H | H | H | H | Rₙ₆₀ | H | H |
| Lₐ₄₁₇₉ | Rₙ₅₆ | Ar94 | H | H | H | H | Rₙ₆₀ | H | H |
| Lₐ₄₁₈₀ | Rₙ₅₉ | Ar94 | H | H | H | H | Rₙ₆₀ | H | H |
| Lₐ₄₁₈₁ | Rₙ₆₀ | Ar94 | H | H | H | H | Rₙ₆₀ | H | H |
| Lₐ₄₁₈₂ | Rₙ₆₁ | Ar94 | H | H | H | H | Rₙ₆₀ | H | H |
| Lₐ₄₁₈₃ | Rₙ₆₂ | Ar94 | H | H | H | H | Rₙ₆₀ | H | H |
| Lₐ₄₁₈₄ | Rₙ₆₄ | Ar94 | H | H | H | H | Rₙ₆₀ | H | H |
| Lₐ₄₁₈₅ | Rₙ₆₅ | Ar94 | H | H | H | H | Rₙ₆₀ | H | H |
| Lₐ₄₁₈₆ | Rₙ₆₉ | Ar94 | H | H | H | H | Rₙ₆₀ | H | H |
| Lₐ₄₁₈₇ | Rₙ₇₀ | Ar94 | H | H | H | H | Rₙ₆₀ | H | H |
| Lₐ₄₁₈₈ | Rₙ₈₁ | Ar94 | H | H | H | H | Rₙ₆₀ | H | H |
| Lₐ₄₁₈₉ | Rₙ₁ | Ar94 | H | H | H | H | Rₙ₆₄ | H | H |
| Lₐ₄₁₉₀ | Rₙ₄ | Ar94 | H | H | H | H | Rₙ₆₄ | H | H |
| Lₐ₄₁₉₁ | Rₙ₅ | Ar94 | H | H | H | H | Rₙ₆₄ | H | H |
| Lₐ₄₁₉₂ | Rₙ₇ | Ar94 | H | H | H | H | Rₙ₆₄ | H | H |
| Lₐ₄₁₉₃ | Rₙ₁₁ | Ar94 | H | H | H | H | Rₙ₆₄ | H | H |
| Lₐ₄₁₉₄ | Rₙ₂₀ | Ar94 | H | H | H | H | Rₙ₆₄ | H | H |
| Lₐ₄₁₉₅ | Rₙ₂₁ | Ar94 | H | H | H | H | Rₙ₆₄ | H | H |
| Lₐ₄₁₉₆ | Rₙ₅₁ | Ar94 | H | H | H | H | Rₙ₆₄ | H | H |
| Lₐ₄₁₉₇ | Rₙ₅₆ | Ar94 | H | H | H | H | Rₙ₆₄ | H | H |
| Lₐ₄₁₉₈ | Rₙ₅₉ | Ar94 | H | H | H | H | Rₙ₆₄ | H | H |
| Lₐ₄₁₉₉ | Rₙ₆₀ | Ar94 | H | H | H | H | Rₙ₆₄ | H | H |
| Lₐ₄₂₀₀ | Rₙ₆₁ | Ar94 | H | H | H | H | Rₙ₆₄ | H | H |
| Lₐ₄₂₀₁ | Rₙ₆₂ | Ar94 | H | H | H | H | Rₙ₆₄ | H | H |
| Lₐ₄₂₀₂ | Rₙ₆₄ | Ar94 | H | H | H | H | Rₙ₆₄ | H | H |
| Lₐ₄₂₀₃ | Rₙ₆₅ | Ar94 | H | H | H | H | Rₙ₆₄ | H | H |
| Lₐ₄₂₀₄ | Rₙ₆₉ | Ar94 | H | H | H | H | Rₙ₆₄ | H | H |
| Lₐ₄₂₀₅ | Rₙ₇₀ | Ar94 | H | H | H | H | Rₙ₆₄ | H | H |
| Lₐ₄₂₀₆ | Rₙ₈₁ | Ar94 | H | H | H | H | Rₙ₆₄ | H | H |
| Lₐ₄₂₀₇ | Rₙ₁ | Ar94 | H | H | H | H | Me | H | H |
| Lₐ₄₂₀₈ | Rₙ₄ | Ar94 | H | H | H | H | Me | H | H |
| Lₐ₄₂₀₉ | Rₙ₅ | Ar94 | H | H | H | H | Me | H | H |
| Lₐ₄₂₁₀ | Rₙ₇ | Ar94 | H | H | H | H | Me | H | H |
| Lₐ₄₂₁₁ | Rₙ₁₁ | Ar94 | H | H | H | H | Me | H | H |
| Lₐ₄₂₁₂ | Rₙ₂₀ | Ar94 | H | H | H | H | Me | H | H |
| Lₐ₄₂₁₃ | Rₙ₂₁ | Ar94 | H | H | H | H | Me | H | H |
| Lₐ₄₂₁₄ | Rₙ₅₁ | Ar94 | H | H | H | H | Me | H | H |
| Lₐ₄₂₁₅ | Rₙ₅₆ | Ar94 | H | H | H | H | Me | H | H |
| Lₐ₄₂₁₆ | Rₙ₅₉ | Ar94 | H | H | H | H | Me | H | H |
| Lₐ₄₂₁₇ | Rₙ₆₀ | Ar94 | H | H | H | H | Me | H | H |
| Lₐ₄₂₁₈ | Rₙ₆₁ | Ar94 | H | H | H | H | Me | H | H |
| Lₐ₄₂₁₉ | Rₙ₆₂ | Ar94 | H | H | H | H | Me | H | H |
| Lₐ₄₂₂₀ | Rₙ₆₄ | Ar94 | H | H | H | H | Me | H | H |
| Lₐ₄₂₂₁ | Rₙ₆₅ | Ar94 | H | H | H | H | Me | H | H |
| Lₐ₄₂₂₂ | Rₙ₆₉ | Ar94 | H | H | H | H | Me | H | H |
| Lₐ₄₂₂₃ | Rₙ₇₀ | Ar94 | H | H | H | H | Me | H | H |
| Lₐ₄₂₂₄ | Rₙ₈₁ | Ar94 | H | H | H | H | Me | H | H |
| Lₐ₄₂₂₅ | Rₙ₁ | Ar94 | H | H | F | H | H | H | H |
| Lₐ₄₂₂₆ | Rₙ₄ | Ar94 | H | H | F | H | H | H | H |
| Lₐ₄₂₂₇ | Rₙ₇ | Ar94 | H | H | F | H | H | H | H |
| Lₐ₄₂₂₈ | Rₙ₂₀ | Ar94 | H | H | F | H | H | H | H |
| Lₐ₄₂₂₉ | Rₙ₂₁ | Ar94 | H | H | F | H | H | H | H |
| Lₐ₄₂₃₀ | Rₙ₅₆ | Ar94 | H | D | F | H | H | H | H |
| Lₐ₄₂₃₁ | Rₙ₅₉ | Ar94 | H | H | F | H | H | H | H |
| Lₐ₄₂₃₂ | Rₙ₆₁ | Ar94 | H | H | F | H | H | H | H |
| Lₐ₄₂₃₃ | Rₙ₆₂ | Ar94 | H | H | F | H | H | H | H |
| Lₐ₄₂₃₄ | Rₙ₆₄ | Ar94 | H | H | F | H | H | H | H |
| Lₐ₄₂₃₅ | Rₙ₆₉ | Ar94 | H | H | F | H | H | H | H |
| Lₐ₄₂₃₆ | Rₙ₇₀ | Ar94 | H | H | F | H | H | H | H |
| Lₐ₄₂₃₇ | Rₙ₁ | Ar94 | H | H | F | H | Rₙ₁₁ | H | H |
| Lₐ₄₂₃₈ | Rₙ₄ | Ar94 | H | H | F | H | Rₙ₁₁ | H | H |
| Lₐ₄₂₃₉ | Rₙ₇ | Ar94 | H | H | F | H | Rₙ₁₁ | H | H |
| Lₐ₄₂₄₀ | Rₙ₂₀ | Ar94 | H | H | F | H | Rₙ₁₁ | H | H |
| Lₐ₄₂₄₁ | Rₙ₂₁ | Ar94 | H | H | F | H | Rₙ₁₁ | H | H |
| Lₐ₄₂₄₂ | Rₙ₅₆ | Ar94 | H | H | F | H | Rₙ₁₁ | H | H |
| Lₐ₄₂₄₃ | Rₙ₅₉ | Ar94 | H | H | F | H | Rₙ₁₁ | H | H |
| Lₐ₄₂₄₄ | Rₙ₆₁ | Ar94 | H | H | F | H | Rₙ₁₁ | H | H |
| Lₐ₄₂₄₅ | Rₙ₆₂ | Ar94 | H | H | F | H | Rₙ₁₁ | H | H |
| Lₐ₄₂₄₆ | Rₙ₆₄ | Ar94 | H | H | F | H | Rₙ₁₁ | H | H |
| Lₐ₄₂₄₇ | Rₙ₆₉ | Ar94 | H | H | F | H | Rₙ₁₁ | H | H |
| Lₐ₄₂₄₈ | Rₙ₇₀ | Ar94 | H | H | F | H | Rₙ₁₁ | H | H |
| Lₐ₄₂₄₉ | Rₙ₁ | Ar94 | D | H | F | H | Rₙ₆₀ | H | H |
| Lₐ₄₂₅₀ | Rₙ₄ | Ar94 | H | H | F | H | Rₙ₆₀ | H | H |
| Lₐ₄₂₅₁ | Rₙ₇ | Ar94 | H | H | F | H | Rₙ₆₀ | H | H |
| Lₐ₄₂₅₂ | Rₙ₂₀ | Ar94 | H | H | F | H | Rₙ₆₀ | H | H |
| Lₐ₄₂₅₃ | Rₙ₂₁ | Ar94 | H | H | F | H | Rₙ₆₀ | H | H |
| Lₐ₄₂₅₄ | Rₙ₅₆ | Ar94 | H | H | F | H | Rₙ₆₀ | H | H |
| Lₐ₄₂₅₅ | Rₙ₅₉ | Ar94 | H | H | F | H | Rₙ₆₀ | H | H |
| Lₐ₄₂₅₆ | Rₙ₆₁ | Ar94 | H | H | F | H | Rₙ₆₀ | H | H |
| Lₐ₄₂₅₇ | Rₙ₆₂ | Ar94 | H | H | F | H | Rₙ₆₀ | H | H |
| Lₐ₄₂₅₈ | Rₙ₆₄ | Ar94 | H | H | F | H | Rₙ₆₀ | H | H |
| Lₐ₄₂₅₉ | Rₙ₆₉ | Ar94 | H | H | F | H | Rₙ₆₀ | H | H |
| Lₐ₄₂₆₀ | Rₙ₇₀ | Ar94 | H | H | F | H | Rₙ₆₀ | H | H |
| Lₐ₄₂₆₁ | Rₙ₁ | Ar94 | H | H | F | H | H | Rₙ₁₁ | H |
| Lₐ₄₂₆₂ | Rₙ₄ | Ar94 | H | H | F | H | H | Rₙ₁₁ | H |
| Lₐ₄₂₆₃ | Rₙ₇ | Ar94 | H | H | F | H | H | Rₙ₁₁ | H |
| Lₐ₄₂₆₄ | Rₙ₂₀ | Ar94 | H | H | F | H | H | Rₙ₁₁ | H |
| Lₐ₄₂₆₅ | Rₙ₂₁ | Ar94 | H | H | F | H | H | Rₙ₁₁ | H |
| Lₐ₄₂₆₆ | Rₙ₅₆ | Ar94 | H | H | F | H | H | Rₙ₁₁ | H |
| Lₐ₄₂₆₇ | Rₙ₅₉ | Ar94 | H | H | F | H | H | Rₙ₁₁ | H |
| Lₐ₄₂₆₈ | Rₙ₆₁ | Ar94 | H | H | F | H | H | Rₙ₁₁ | H |
| Lₐ₄₂₆₉ | Rₙ₆₂ | Ar94 | H | H | F | H | H | Rₙ₁₁ | H |
| Lₐ₄₂₇₀ | Rₙ₆₄ | Ar94 | H | H | F | H | H | Rₙ₁₁ | H |
| Lₐ₄₂₇₁ | Rₙ₆₉ | Ar94 | H | H | F | H | H | Rₙ₁₁ | H |
| Lₐ₄₂₇₂ | Rₙ₇₀ | Ar94 | H | H | F | H | H | Rₙ₁₁ | H |
| Lₐ₄₂₇₃ | Rₙ₁ | Ar94 | H | H | F | H | H | Rₙ₆₀ | H |
| Lₐ₄₂₇₄ | Rₙ₄ | Ar94 | H | H | F | H | H | Rₙ₆₀ | H |
| Lₐ₄₂₇₅ | Rₙ₇ | Ar94 | H | D | F | H | H | Rₙ₆₀ | H |
| Lₐ₄₂₇₆ | Rₙ₂₀ | Ar94 | H | H | F | H | H | Rₙ₆₀ | H |
| Lₐ₄₂₇₇ | Rₙ₂₁ | Ar94 | H | H | F | H | H | Rₙ₆₀ | H |
| Lₐ₄₂₇₈ | Rₙ₅₆ | Ar94 | H | H | F | H | H | Rₙ₆₀ | H |
| Lₐ₄₂₇₉ | Rₙ₅₉ | Ar94 | H | H | F | H | H | Rₙ₆₀ | H |
| Lₐ₄₂₈₀ | Rₙ₆₁ | Ar94 | H | H | F | H | H | Rₙ₆₀ | H |
| Lₐ₄₂₈₁ | Rₙ₆₂ | Ar94 | H | H | F | H | H | Rₙ₆₀ | H |
| Lₐ₄₂₈₂ | Rₙ₆₄ | Ar94 | H | H | F | H | H | Rₙ₆₀ | H |
| Lₐ₄₂₈₃ | Rₙ₆₉ | Ar94 | H | H | F | H | H | Rₙ₆₀ | H |
| Lₐ₄₂₈₄ | Rₙ₇₀ | Ar94 | H | H | F | H | H | Rₙ₆₀ | H |
| Lₐ₄₂₈₅ | Rₙ₁ | Ar94 | H | H | CN | H | H | H | H |
| Lₐ₄₂₈₆ | Rₙ₄ | Ar94 | H | H | CN | H | H | H | H |
| Lₐ₄₂₈₇ | Rₙ₇ | Ar94 | H | H | CN | H | H | H | H |
| Lₐ₄₂₈₈ | Rₙ₂₀ | Ar94 | H | H | CN | H | H | H | H |
| Lₐ₄₂₈₉ | Rₙ₂₁ | Ar94 | H | H | CN | H | H | H | H |
| Lₐ₄₂₉₀ | Rₙ₅₆ | Ar94 | H | H | CN | H | H | H | H |
| Lₐ₄₂₉₁ | Rₙ₅₉ | Ar94 | H | H | CN | H | H | H | H |
| Lₐ₄₂₉₂ | Rₙ₆₁ | Ar94 | H | H | CN | H | H | H | H |
| Lₐ₄₂₉₃ | Rₙ₆₂ | Ar94 | H | H | CN | H | H | H | H |
| Lₐ₄₂₉₄ | Rₙ₆₄ | Ar94 | H | H | CN | H | H | H | H |
| Lₐ₄₂₉₅ | Rₙ₆₉ | Ar94 | H | H | CN | H | H | H | H |
| Lₐ₄₂₉₆ | Rₙ₇₀ | Ar94 | H | H | CN | H | H | H | H |
| Lₐ₄₂₉₇ | Rₙ₁ | Ar94 | H | CN | H | H | H | H | H |
| Lₐ₄₂₉₈ | Rₙ₄ | Ar94 | H | CN | H | H | H | H | H |
| Lₐ₄₂₉₉ | Rₙ₇ | Ar94 | H | CN | H | H | H | H | H |
| Lₐ₄₃₀₀ | Rₙ₂₀ | Ar94 | H | CN | H | H | H | H | H |
| Lₐ₄₃₀₁ | Rₙ₂₁ | Ar94 | H | CN | H | H | H | H | H |
| Lₐ₄₃₀₂ | Rₙ₅₆ | Ar94 | H | CN | H | H | H | H | H |
| Lₐ₄₃₀₃ | Rₙ₅₉ | Ar94 | H | CN | H | H | H | H | H |
| Lₐ₄₃₀₄ | Rₙ₆₁ | Ar94 | H | CN | H | H | H | H | H |
| Lₐ₄₃₀₅ | Rₙ₆₂ | Ar94 | H | CN | H | H | H | H | H |
| Lₐ₄₃₀₆ | Rₙ₆₄ | Ar94 | H | CN | H | H | H | H | H |
| Lₐ₄₃₀₇ | Rₙ₆₉ | Ar94 | H | CN | H | H | H | H | H |
| Lₐ₄₃₀₈ | Rₙ₇₀ | Ar94 | H | CN | H | H | H | H | H |
| Lₐ₄₃₀₉ | Rₙ₁ | Ar94 | CN | H | H | H | H | H | H |
| Lₐ₄₃₁₀ | Rₙ₄ | Ar94 | CN | H | H | H | H | H | H |
| Lₐ₄₃₁₁ | Rₙ₇ | Ar94 | CN | D | H | H | H | H | H |
| Lₐ₄₃₁₂ | Rₙ₂₀ | Ar94 | CN | H | H | H | H | H | H |
| Lₐ₄₃₁₃ | Rₙ₂₁ | Ar94 | CN | H | H | H | H | H | H |
| Lₐ₄₃₁₄ | Rₙ₅₆ | Ar94 | CN | H | H | H | H | H | H |
| Lₐ₄₃₁₅ | Rₙ₅₉ | Ar94 | CN | H | H | H | H | H | H |
| Lₐ₄₃₁₆ | Rₙ₆₁ | Ar94 | CN | H | H | H | H | H | H |
| Lₐ₄₃₁₇ | Rₙ₆₂ | Ar94 | CN | H | H | H | H | H | H |
| Lₐ₄₃₁₈ | Rₙ₆₄ | Ar94 | CN | H | H | H | H | H | H |
| Lₐ₄₃₁₉ | Rₙ₆₉ | Ar94 | CN | H | H | H | H | H | H |
| Lₐ₄₃₂₀ | Rₙ₇₀ | Ar94 | CN | H | H | H | H | H | H |
| Lₐ₄₃₂₁ | Rₙ₁ | Ar94 | H | H | CN | H | Rₙ₁₁ | H | H |
| Lₐ₄₃₂₂ | Rₙ₄ | Ar94 | H | H | CN | H | Rₙ₁₁ | H | H |
| Lₐ₄₃₂₃ | Rₙ₇ | Ar94 | H | H | CN | H | Rₙ₁₁ | H | H |
| Lₐ₄₃₂₄ | Rₙ₂₀ | Ar94 | D | H | CN | H | Rₙ₁₁ | H | H |
| Lₐ₄₃₂₅ | Rₙ₂₁ | Ar94 | H | H | CN | H | Rₙ₁₁ | H | H |
| Lₐ₄₃₂₆ | Rₙ₅₆ | Ar94 | H | H | CN | H | Rₙ₁₁ | H | H |
| Lₐ₄₃₂₇ | Rₙ₅₉ | Ar94 | H | H | CN | H | Rₙ₁₁ | H | H |
| Lₐ₄₃₂₈ | Rₙ₆₁ | Ar94 | H | H | CN | H | Rₙ₁₁ | H | H |
| Lₐ₄₃₂₉ | Rₙ₆₂ | Ar94 | H | H | CN | H | Rₙ₁₁ | H | H |
| Lₐ₄₃₃₀ | Rₙ₆₄ | Ar94 | H | H | CN | H | Rₙ₁₁ | H | H |
| Lₐ₄₃₃₁ | Rₙ₆₉ | Ar94 | H | H | CN | H | Rₙ₁₁ | H | H |
| Lₐ₄₃₃₂ | Rₙ₇₀ | Ar94 | H | H | CN | H | Rₙ₁₁ | H | H |
| Lₐ₄₃₃₃ | Rₙ₁ | Ar94 | H | H | CN | H | Rₙ₆₀ | H | H |
| Lₐ₄₃₃₄ | Rₙ₄ | Ar94 | H | H | CN | H | Rₙ₆₀ | H | H |
| Lₐ₄₃₃₅ | Rₙ₇ | Ar94 | H | H | CN | H | Rₙ₆₀ | H | H |
| Lₐ₄₃₃₆ | Rₙ₂₀ | Ar94 | H | H | CN | H | Rₙ₆₀ | H | H |
| Lₐ₄₃₃₇ | Rₙ₂₁ | Ar94 | H | H | CN | H | Rₙ₆₀ | H | H |
| Lₐ₄₃₃₈ | Rₙ₅₆ | Ar94 | H | H | CN | H | Rₙ₆₀ | H | H |
| Lₐ₄₃₃₉ | Rₙ₅₉ | Ar94 | H | H | CN | H | Rₙ₆₀ | H | H |
| Lₐ₄₃₄₀ | Rₙ₆₁ | Ar94 | H | H | CN | H | Rₙ₆₀ | H | H |
| Lₐ₄₃₄₁ | Rₙ₆₂ | Ar94 | H | H | CN | H | Rₙ₆₀ | H | H |
| Lₐ₄₃₄₂ | Rₙ₆₄ | Ar94 | H | H | CN | H | Rₙ₆₀ | H | H |
| Lₐ₄₃₄₃ | Rₙ₆₉ | Ar94 | H | H | CN | H | Rₙ₆₀ | H | D |
| Lₐ₄₃₄₄ | Rₙ₇₀ | Ar94 | H | H | CN | H | Rₙ₆₀ | H | H |
| Lₐ₄₃₄₅ | Rₙ₁ | Ar94 | H | H | CN | H | Rₙ₆₄ | H | H |
| Lₐ₄₃₄₆ | Rₙ₄ | Ar94 | H | H | CN | H | Rₙ₆₄ | H | H |
| Lₐ₄₃₄₇ | Rₙ₇ | Ar94 | H | H | CN | H | Rₙ₆₄ | H | H |
| Lₐ₄₃₄₈ | Rₙ₂₀ | Ar94 | H | H | CN | H | Rₙ₆₄ | H | H |
| Lₐ₄₃₄₉ | Rₙ₂₁ | Ar94 | H | H | CN | H | Rₙ₆₄ | H | H |
| Lₐ₄₃₅₀ | Rₙ₅₆ | Ar94 | H | H | CN | H | Rₙ₆₄ | H | H |
| Lₐ₄₃₅₁ | Rₙ₅₉ | Ar94 | H | H | CN | H | Rₙ₆₄ | H | H |
| Lₐ₄₃₅₂ | Rₙ₆₁ | Ar94 | H | H | CN | H | Rₙ₆₄ | H | H |
| Lₐ₄₃₅₃ | Rₙ₆₂ | Ar94 | H | H | CN | H | Rₙ₆₄ | H | H |
| Lₐ₄₃₅₄ | Rₙ₆₄ | Ar94 | H | H | CN | H | Rₙ₆₄ | H | H |
| Lₐ₄₃₅₅ | Rₙ₆₉ | Ar94 | H | H | CN | H | Rₙ₆₄ | H | H |
| Lₐ₄₃₅₆ | Rₙ₇₀ | Ar94 | H | H | CN | H | Rₙ₆₄ | H | H |
| Lₐ₄₃₅₇ | Rₙ₁ | Ar94 | H | H | CN | H | H | Rₙ₁₁ | H |
| Lₐ₄₃₅₈ | Rₙ₄ | Ar94 | H | H | CN | H | H | Rₙ₁₁ | H |
| Lₐ₄₃₅₉ | Rₙ₇ | Ar94 | H | H | CN | H | H | Rₙ₁₁ | H |
| Lₐ₄₃₆₀ | Rₙ₂₀ | Ar94 | H | H | CN | H | H | Rₙ₁₁ | H |
| Lₐ₄₃₆₁ | Rₙ₂₁ | Ar94 | H | H | CN | H | H | Rₙ₁₁ | H |
| Lₐ₄₃₆₂ | Rₙ₅₆ | Ar94 | H | H | CN | H | H | Rₙ₁₁ | H |
| Lₐ₄₃₆₃ | Rₙ₅₉ | Ar94 | H | H | CN | H | D | Rₙ₁₁ | H |
| Lₐ₄₃₆₄ | Rₙ₆₁ | Ar94 | H | H | CN | H | H | Rₙ₁₁ | H |
| Lₐ₄₃₆₅ | Rₙ₆₂ | Ar94 | H | H | CN | H | H | Rₙ₁₁ | H |
| Lₐ₄₃₆₆ | Rₙ₆₄ | Ar94 | H | H | CN | H | H | Rₙ₁₁ | H |
| Lₐ₄₃₆₇ | Rₙ₆₉ | Ar94 | H | H | CN | H | H | Rₙ₁₁ | H |
| Lₐ₄₃₆₈ | Rₙ₇₀ | Ar94 | H | H | CN | H | H | Rₙ₁₁ | H |
| Lₐ₄₃₆₉ | Rₙ₁ | Ar94 | H | H | CN | H | H | Rₙ₆₀ | H |
| Lₐ₄₃₇₀ | Rₙ₄ | Ar94 | H | H | CN | H | H | Rₙ₆₀ | H |
| Lₐ₄₃₇₁ | Rₙ₇ | Ar94 | H | H | CN | H | H | Rₙ₆₀ | H |
| Lₐ₄₃₇₂ | Rₙ₂₀ | Ar94 | H | H | CN | H | H | Rₙ₆₀ | H |
| Lₐ₄₃₇₃ | Rₙ₂₁ | Ar94 | H | H | CN | H | H | Rₙ₆₀ | H |
| Lₐ₄₃₇₄ | Rₙ₅₆ | Ar94 | H | H | CN | H | H | Rₙ₆₀ | H |
| Lₐ₄₃₇₅ | Rₙ₅₉ | Ar94 | H | D | CN | H | H | Rₙ₆₀ | H |
| Lₐ₄₃₇₆ | Rₙ₆₁ | Ar94 | H | H | CN | H | H | Rₙ₆₀ | H |
| Lₐ₄₃₇₇ | Rₙ₆₂ | Ar94 | H | H | CN | H | H | Rₙ₆₀ | H |
| Lₐ₄₃₇₈ | Rₙ₆₄ | Ar94 | H | H | CN | H | H | Rₙ₆₀ | H |
| Lₐ₄₃₇₉ | Rₙ₆₉ | Ar94 | H | H | CN | H | H | Rₙ₆₀ | H |
| Lₐ₄₃₈₀ | Rₙ₇₀ | Ar94 | H | H | CN | H | H | Rₙ₆₀ | H |
| Lₐ₄₃₈₁ | Rₙ₁ | Ar94 | H | H | CN | H | H | Rₙ₆₄ | H |
| Lₐ₄₃₈₂ | Rₙ₄ | Ar94 | H | H | CN | H | H | Rₙ₆₄ | H |
| Lₐ₄₃₈₃ | Rₙ₇ | Ar94 | H | H | CN | H | H | Rₙ₆₄ | H |
| Lₐ₄₃₈₄ | Rₙ₂₀ | Ar94 | H | H | CN | H | H | Rₙ₆₄ | H |
| Lₐ₄₃₈₅ | Rₙ₂₁ | Ar94 | H | H | CN | H | H | Rₙ₆₄ | H |
| Lₐ₄₃₈₆ | Rₙ₅₆ | Ar94 | H | H | CN | H | H | Rₙ₆₄ | H |
| Lₐ₄₃₈₇ | Rₙ₅₉ | Ar94 | H | H | CN | H | H | Rₙ₆₄ | H |
| Lₐ₄₃₈₈ | Rₙ₆₁ | Ar94 | H | H | CN | H | H | Rₙ₆₄ | H |
| Lₐ₄₃₈₉ | Rₙ₆₂ | Ar94 | H | H | CN | H | H | Rₙ₆₄ | H |
| Lₐ₄₃₉₀ | Rₙ₆₄ | Ar94 | H | H | CN | H | H | Rₙ₆₄ | H |
| Lₐ₄₃₉₁ | Rₙ₆₉ | Ar94 | D | H | CN | H | H | Rₙ₆₄ | H |
| Lₐ₄₃₉₂ | Rₙ₇₀ | Ar94 | H | H | CN | H | H | Rₙ₆₄ | H |
| Lₐ₄₃₉₃ | Rₙ₁ | Ar95 | H | H | H | H | H | H | H |
| Lₐ₄₃₉₄ | Rₙ₄ | Ar95 | H | H | H | H | H | H | H |
| Lₐ₄₃₉₅ | Rₙ₅ | Ar95 | H | H | H | H | H | H | H |
| Lₐ₄₃₉₆ | Rₙ₇ | Ar95 | H | H | H | H | H | H | H |
| Lₐ₄₃₉₇ | Rₙ₁₁ | Ar95 | H | H | H | H | H | H | H |
| Lₐ₄₃₉₈ | Rₙ₂₀ | Ar95 | H | H | H | H | H | H | H |
| Lₐ₄₃₉₉ | Rₙ₂₁ | Ar95 | H | H | H | H | H | H | H |
| Lₐ₄₄₀₀ | Rₙ₅₁ | Ar95 | H | H | H | H | H | H | H |
| Lₐ₄₄₀₁ | Rₙ₅₆ | Ar95 | H | H | H | H | H | H | H |
| Lₐ₄₄₀₂ | Rₙ₅₉ | Ar95 | H | H | H | H | H | H | H |
| Lₐ₄₄₀₃ | Rₙ₆₀ | Ar95 | H | H | H | H | H | H | H |
| Lₐ₄₄₀₄ | Rₙ₆₁ | Ar95 | H | H | H | H | H | H | H |
| Lₐ₄₄₀₅ | Rₙ₆₂ | Ar95 | H | H | H | H | H | H | H |
| Lₐ₄₄₀₆ | Rₙ₆₄ | Ar95 | H | H | H | H | H | H | H |
| Lₐ₄₄₀₇ | Rₙ₆₅ | Ar95 | H | H | H | H | H | H | H |
| Lₐ₄₄₀₈ | Rₙ₆₉ | Ar95 | H | H | H | H | H | H | H |
| Lₐ₄₄₀₉ | Rₙ₇₀ | Ar95 | H | H | H | H | H | H | H |
| Lₐ₄₄₁₀ | Rₙ₈₁ | Ar95 | H | H | H | H | H | H | H |
| Lₐ₄₄₁₁ | Rₙ₁ | Ar95 | H | H | H | H | H | Rₙ₁₁ | H |
| Lₐ₄₄₁₂ | Rₙ₄ | Ar95 | H | H | H | H | H | Rₙ₁₁ | H |
| Lₐ₄₄₁₃ | Rₙ₅ | Ar95 | H | H | H | H | H | Rₙ₁₁ | H |
| Lₐ₄₄₁₄ | Rₙ₇ | Ar95 | H | H | H | H | H | Rₙ₁₁ | H |
| Lₐ₄₄₁₅ | Rₙ₁₁ | Ar95 | H | H | H | H | H | Rₙ₁₁ | H |
| Lₐ₄₄₁₆ | Rₙ₂₀ | Ar95 | H | H | H | H | H | Rₙ₁₁ | H |
| Lₐ₄₄₁₇ | Rₙ₂₁ | Ar95 | H | H | H | H | H | Rₙ₁₁ | H |
| Lₐ₄₄₁₈ | Rₙ₅₁ | Ar95 | H | H | H | H | H | Rₙ₁₁ | H |
| Lₐ₄₄₁₉ | Rₙ₅₆ | Ar95 | H | H | H | H | H | Rₙ₁₁ | H |
| Lₐ₄₄₂₀ | Rₙ₅₉ | Ar95 | H | H | H | H | H | Rₙ₁₁ | H |
| Lₐ₄₄₂₁ | Rₙ₆₀ | Ar95 | H | H | H | H | H | Rₙ₁₁ | H |
| Lₐ₄₄₂₂ | Rₙ₆₁ | Ar95 | H | H | H | H | H | Rₙ₁₁ | H |
| Lₐ₄₄₂₃ | Rₙ₆₂ | Ar95 | H | H | H | H | H | Rₙ₁₁ | H |
| Lₐ₄₄₂₄ | Rₙ₆₄ | Ar95 | H | H | H | H | H | Rₙ₁₁ | H |
| Lₐ₄₄₂₅ | Rₙ₆₅ | Ar95 | H | H | H | H | H | Rₙ₁₁ | H |
| Lₐ₄₄₂₆ | Rₙ₆₉ | Ar95 | H | H | H | H | H | Rₙ₁₁ | H |
| Lₐ₄₄₂₇ | Rₙ₇₀ | Ar95 | H | H | H | H | H | Rₙ₁₁ | H |
| Lₐ₄₄₂₈ | Rₙ₈₁ | Ar95 | H | H | H | H | H | Rₙ₁₁ | H |
| Lₐ₄₄₂₉ | Rₙ₁ | Ar95 | H | H | H | H | H | Rₙ₅₉ | H |
| Lₐ₄₄₃₀ | Rₙ₄ | Ar95 | H | H | H | H | H | Rₙ₅₉ | H |
| Lₐ₄₄₃₁ | Rₙ₅ | Ar95 | H | H | H | H | H | Rₙ₅₉ | H |
| Lₐ₄₄₃₂ | Rₙ₇ | Ar95 | H | H | H | H | H | Rₙ₅₉ | H |
| Lₐ₄₄₃₃ | Rₙ₁₁ | Ar95 | H | H | H | H | H | Rₙ₅₉ | H |
| Lₐ₄₄₃₄ | Rₙ₂₀ | Ar95 | H | H | H | H | H | Rₙ₅₉ | H |
| Lₐ₄₄₃₅ | Rₙ₂₁ | Ar95 | H | H | H | H | H | Rₙ₅₉ | H |
| Lₐ₄₄₃₆ | Rₙ₅₁ | Ar95 | H | H | H | H | H | Rₙ₅₉ | H |
| Lₐ₄₄₃₇ | Rₙ₅₆ | Ar95 | H | H | H | H | H | Rₙ₅₉ | H |
| Lₐ₄₄₃₈ | Rₙ₅₉ | Ar95 | H | H | H | H | H | Rₙ₅₉ | H |
| Lₐ₄₄₃₉ | Rₙ₆₀ | Ar95 | H | H | H | H | H | Rₙ₅₉ | H |
| Lₐ₄₄₄₀ | Rₙ₆₁ | Ar95 | H | H | H | H | H | Rₙ₅₉ | H |
| Lₐ₄₄₄₁ | Rₙ₆₂ | Ar95 | H | H | H | H | H | Rₙ₅₉ | H |
| Lₐ₄₄₄₂ | Rₙ₆₄ | Ar95 | H | H | H | H | H | Rₙ₅₉ | H |
| Lₐ₄₄₄₃ | Rₙ₆₅ | Ar95 | H | H | H | H | H | Rₙ₅₉ | H |
| Lₐ₄₄₄₄ | Rₙ₆₉ | Ar95 | H | H | H | H | H | Rₙ₅₉ | H |
| Lₐ₄₄₄₅ | Rₙ₇₀ | Ar95 | H | H | H | H | H | Rₙ₅₉ | H |
| Lₐ₄₄₄₆ | Rₙ₈₁ | Ar95 | H | H | H | H | H | Rₙ₅₉ | H |
| Lₐ₄₄₄₇ | Rₙ₁ | Ar95 | H | H | H | H | H | Rₙ₆₀ | H |
| Lₐ₄₄₄₈ | Rₙ₄ | Ar95 | H | H | H | H | H | Rₙ₆₀ | H |
| Lₐ₄₄₄₉ | Rₙ₅ | Ar95 | H | H | H | H | H | Rₙ₆₀ | H |
| Lₐ₄₄₅₀ | Rₙ₇ | Ar95 | H | H | H | H | H | Rₙ₆₀ | H |
| Lₐ₄₄₅₁ | Rₙ₁₁ | Ar95 | H | H | H | H | H | Rₙ₆₀ | H |
| Lₐ₄₄₅₂ | Rₙ₂₀ | Ar95 | H | H | H | H | H | Rₙ₆₀ | H |
| Lₐ₄₄₅₃ | Rₙ₂₁ | Ar95 | H | H | H | H | H | Rₙ₆₀ | H |
| Lₐ₄₄₅₄ | Rₙ₅₁ | Ar95 | H | H | H | H | H | Rₙ₆₀ | H |
| Lₐ₄₄₅₅ | Rₙ₅₆ | Ar95 | H | H | H | H | H | Rₙ₆₀ | H |
| Lₐ₄₄₅₆ | Rₙ₅₉ | Ar95 | H | H | H | H | H | Rₙ₆₀ | H |
| Lₐ₄₄₅₇ | Rₙ₆₀ | Ar95 | H | H | H | H | H | Rₙ₆₀ | H |
| Lₐ₄₄₅₈ | Rₙ₆₁ | Ar95 | H | H | H | H | H | Rₙ₆₀ | H |
| Lₐ₄₄₅₉ | Rₙ₆₂ | Ar95 | H | H | H | H | H | Rₙ₆₀ | H |
| Lₐ₄₄₆₀ | Rₙ₆₄ | Ar95 | H | H | H | H | H | Rₙ₆₀ | H |
| Lₐ₄₄₆₁ | Rₙ₆₅ | Ar95 | H | H | H | H | H | Rₙ₆₀ | H |
| Lₐ₄₄₆₂ | Rₙ₆₉ | Ar95 | H | H | H | H | H | Rₙ₆₀ | H |
| Lₐ₄₄₆₃ | Rₙ₇₀ | Ar95 | H | H | H | H | H | Rₙ₆₀ | H |
| Lₐ₄₄₆₄ | Rₙ₈₁ | Ar95 | H | H | H | H | H | Rₙ₆₀ | H |
| Lₐ₄₄₆₅ | Rₙ₁ | Ar95 | H | H | H | H | H | Rₙ₆₄ | H |
| Lₐ₄₄₆₆ | Rₙ₄ | Ar95 | H | H | H | H | H | Rₙ₆₄ | H |
| Lₐ₄₄₆₇ | Rₙ₅ | Ar95 | H | H | H | H | H | Rₙ₆₄ | H |
| Lₐ₄₄₆₈ | Rₙ₇ | Ar95 | H | H | H | H | H | Rₙ₆₄ | H |
| Lₐ₄₄₆₉ | Rₙ₁₁ | Ar95 | H | H | H | H | H | Rₙ₆₄ | H |
| Lₐ₄₄₇₀ | Rₙ₂₀ | Ar95 | H | H | H | H | H | Rₙ₆₄ | H |
| Lₐ₄₄₇₁ | Rₙ₂₁ | Ar95 | H | H | H | H | H | Rₙ₆₄ | H |
| Lₐ₄₄₇₂ | Rₙ₅₁ | Ar95 | H | H | H | H | H | Rₙ₆₄ | H |
| Lₐ₄₄₇₃ | Rₙ₅₆ | Ar95 | H | H | H | H | H | Rₙ₆₄ | H |
| Lₐ₄₄₇₄ | Rₙ₅₉ | Ar95 | H | H | H | H | H | Rₙ₆₄ | H |
| Lₐ₄₄₇₅ | Rₙ₆₀ | Ar95 | H | H | H | H | H | Rₙ₆₄ | H |
| Lₐ₄₄₇₆ | Rₙ₆₁ | Ar95 | H | H | H | H | H | Rₙ₆₄ | H |
| Lₐ₄₄₇₇ | Rₙ₆₂ | Ar95 | H | H | H | H | H | Rₙ₆₄ | H |
| Lₐ₄₄₇₈ | Rₙ₆₄ | Ar95 | H | H | H | H | H | Rₙ₆₄ | H |
| Lₐ₄₄₇₉ | Rₙ₆₅ | Ar95 | H | H | H | H | H | Rₙ₆₄ | H |
| Lₐ₄₄₈₀ | Rₙ₆₉ | Ar95 | H | H | H | H | H | Rₙ₆₄ | H |
| Lₐ₄₄₈₁ | Rₙ₇₀ | Ar95 | H | H | H | H | H | Rₙ₆₄ | H |
| Lₐ₄₄₈₂ | Rₙ₈₁ | Ar95 | H | H | H | H | H | Rₙ₆₄ | H |
| Lₐ₄₄₈₃ | Rₙ₁ | Ar95 | H | H | H | H | H | Me | H |
| Lₐ₄₄₈₄ | Rₙ₄ | Ar95 | H | H | H | H | H | Me | H |
| Lₐ₄₄₈₅ | Rₙ₅ | Ar95 | H | H | H | H | H | Me | H |
| Lₐ₄₄₈₆ | Rₙ₇ | Ar95 | H | H | H | H | H | Me | H |
| Lₐ₄₄₈₇ | Rₙ₁₁ | Ar95 | H | H | H | H | H | Me | H |
| Lₐ₄₄₈₈ | Rₙ₂₀ | Ar95 | H | H | H | H | H | Me | H |
| Lₐ₄₄₈₉ | Rₙ₂₁ | Ar95 | H | H | H | H | H | Me | H |
| Lₐ₄₄₉₀ | Rₙ₅₁ | Ar95 | H | H | H | H | H | Me | H |
| Lₐ₄₄₉₁ | Rₙ₅₆ | Ar95 | H | H | H | H | H | Me | H |
| Lₐ₄₄₉₂ | Rₙ₅₉ | Ar95 | H | H | H | H | H | Me | H |
| Lₐ₄₄₉₃ | Rₙ₆₀ | Ar95 | H | H | H | H | H | Me | H |
| Lₐ₄₄₉₄ | Rₙ₆₁ | Ar95 | H | H | H | H | H | Me | H |
| Lₐ₄₄₉₅ | Rₙ₆₂ | Ar95 | H | H | H | H | H | Me | H |
| Lₐ₄₄₉₆ | Rₙ₆₄ | Ar95 | H | H | H | H | H | Me | H |
| Lₐ₄₄₉₇ | Rₙ₆₅ | Ar95 | H | H | H | H | H | Me | H |
| Lₐ₄₄₉₈ | Rₙ₆₉ | Ar95 | H | H | H | H | H | Me | H |
| Lₐ₄₄₉₉ | Rₙ₇₀ | Ar95 | H | H | H | H | H | Me | H |
| Lₐ₄₅₀₀ | Rₙ₈₁ | Ar95 | H | H | H | H | H | Me | H |
| Lₐ₄₅₀₁ | Rₙ₁ | Ar95 | H | H | H | H | Rₙ₁₁ | H | H |
| Lₐ₄₅₀₂ | Rₙ₄ | Ar95 | H | H | H | H | Rₙ₁₁ | H | H |
| Lₐ₄₅₀₃ | Rₙ₅ | Ar95 | H | H | H | H | Rₙ₁₁ | H | H |
| Lₐ₄₅₀₄ | Rₙ₇ | Ar95 | H | H | H | H | Rₙ₁₁ | H | H |
| Lₐ₄₅₀₅ | Rₙ₁₁ | Ar95 | H | H | H | H | Rₙ₁₁ | H | H |
| Lₐ₄₅₀₆ | Rₙ₂₀ | Ar95 | H | H | H | H | Rₙ₁₁ | H | H |
| Lₐ₄₅₀₇ | Rₙ₂₁ | Ar95 | H | H | H | H | Rₙ₁₁ | H | H |
| Lₐ₄₅₀₈ | Rₙ₅₁ | Ar95 | H | H | H | H | Rₙ₁₁ | H | H |
| Lₐ₄₅₀₉ | Rₙ₅₆ | Ar95 | H | H | H | H | Rₙ₁₁ | H | H |
| Lₐ₄₅₁₀ | Rₙ₅₉ | Ar95 | H | H | H | H | Rₙ₁₁ | H | H |
| Lₐ₄₅₁₁ | Rₙ₆₀ | Ar95 | H | H | H | H | Rₙ₁₁ | H | H |
| Lₐ₄₅₁₂ | Rₙ₆₁ | Ar95 | H | H | H | H | Rₙ₁₁ | H | H |
| Lₐ₄₅₁₃ | Rₙ₆₂ | Ar95 | H | H | H | H | Rₙ₁₁ | H | H |
| Lₐ₄₅₁₄ | Rₙ₆₄ | Ar95 | H | H | H | H | Rₙ₁₁ | H | H |
| Lₐ₄₅₁₅ | Rₙ₆₅ | Ar95 | H | H | H | H | Rₙ₁₁ | H | H |
| Lₐ₄₅₁₆ | Rₙ₆₉ | Ar95 | H | H | H | H | Rₙ₁₁ | H | H |
| Lₐ₄₅₁₇ | Rₙ₇₀ | Ar95 | H | H | H | H | Rₙ₁₁ | H | H |
| Lₐ₄₅₁₈ | Rₙ₈₁ | Ar95 | H | H | H | H | Rₙ₁₁ | H | H |
| Lₐ₄₅₁₉ | Rₙ₁ | Ar95 | H | H | H | H | Rₙ₅₉ | H | H |
| Lₐ₄₅₂₀ | Rₙ₄ | Ar95 | H | H | H | H | Rₙ₅₉ | H | H |
| Lₐ₄₅₂₁ | Rₙ₅ | Ar95 | H | H | H | H | Rₙ₅₉ | H | H |
| Lₐ₄₅₂₂ | Rₙ₇ | Ar95 | H | H | H | H | Rₙ₅₉ | H | H |
| Lₐ₄₅₂₃ | Rₙ₁₁ | Ar95 | H | H | H | H | Rₙ₅₉ | H | H |
| Lₐ₄₅₂₄ | Rₙ₂₀ | Ar95 | H | H | H | H | Rₙ₅₉ | H | H |
| Lₐ₄₅₂₅ | Rₙ₂₁ | Ar95 | H | H | H | H | Rₙ₅₉ | H | H |
| Lₐ₄₅₂₆ | Rₙ₅₁ | Ar95 | H | H | H | H | Rₙ₅₉ | H | H |
| Lₐ₄₅₂₇ | Rₙ₅₆ | Ar95 | H | H | H | H | Rₙ₅₉ | H | H |
| Lₐ₄₅₂₈ | Rₙ₅₉ | Ar95 | H | H | H | H | Rₙ₅₉ | H | H |
| Lₐ₄₅₂₉ | Rₙ₆₀ | Ar95 | H | H | H | H | Rₙ₅₉ | H | H |
| Lₐ₄₅₃₀ | Rₙ₆₁ | Ar95 | H | H | H | H | Rₙ₅₉ | H | H |
| Lₐ₄₅₃₁ | Rₙ₆₂ | Ar95 | H | H | H | H | Rₙ₅₉ | H | H |
| Lₐ₄₅₃₂ | Rₙ₆₄ | Ar95 | H | H | H | H | Rₙ₅₉ | H | H |
| Lₐ₄₅₃₃ | Rₙ₆₅ | Ar95 | H | H | H | H | Rₙ₅₉ | H | H |
| Lₐ₄₅₃₄ | Rₙ₆₉ | Ar95 | H | H | H | H | Rₙ₅₉ | H | H |
| Lₐ₄₅₃₅ | Rₙ₇₀ | Ar95 | H | H | H | H | Rₙ₅₉ | H | H |
| Lₐ₄₅₃₆ | Rₙ₈₁ | Ar95 | H | H | H | H | Rₙ₅₉ | H | H |
| Lₐ₄₅₃₇ | Rₙ₁ | Ar95 | H | H | H | H | Rₙ₆₀ | H | H |
| Lₐ₄₅₃₈ | Rₙ₄ | Ar95 | H | H | H | H | Rₙ₆₀ | H | H |
| Lₐ₄₅₃₉ | Rₙ₅ | Ar95 | H | H | H | H | Rₙ₆₀ | H | H |
| Lₐ₄₅₄₀ | Rₙ₇ | Ar95 | H | H | H | H | Rₙ₆₀ | H | H |
| Lₐ₄₅₄₁ | Rₙ₁₁ | Ar95 | H | H | H | H | Rₙ₆₀ | H | H |
| Lₐ₄₅₄₂ | Rₙ₂₀ | Ar95 | H | H | H | H | Rₙ₆₀ | H | H |
| Lₐ₄₅₄₃ | Rₙ₂₁ | Ar95 | H | H | H | H | Rₙ₆₀ | H | H |
| Lₐ₄₅₄₄ | Rₙ₅₁ | Ar95 | H | H | H | H | Rₙ₆₀ | H | H |
| Lₐ₄₅₄₅ | Rₙ₅₆ | Ar95 | H | H | H | H | Rₙ₆₀ | H | H |
| Lₐ₄₅₄₆ | Rₙ₅₉ | Ar95 | H | H | H | H | Rₙ₆₀ | H | H |
| Lₐ₄₅₄₇ | Rₙ₆₀ | Ar95 | H | H | H | H | Rₙ₆₀ | H | H |
| Lₐ₄₅₄₈ | Rₙ₆₁ | Ar95 | H | H | H | H | Rₙ₆₀ | H | H |
| Lₐ₄₅₄₉ | Rₙ₆₂ | Ar95 | H | H | H | H | Rₙ₆₀ | H | H |
| Lₐ₄₅₅₀ | Rₙ₆₄ | Ar95 | H | H | H | H | Rₙ₆₀ | H | H |
| Lₐ₄₅₅₁ | Rₙ₆₅ | Ar95 | H | H | H | H | Rₙ₆₀ | H | H |
| Lₐ₄₅₅₂ | Rₙ₆₉ | Ar95 | H | H | H | H | Rₙ₆₀ | H | H |
| Lₐ₄₅₅₃ | Rₙ₇₀ | Ar95 | H | H | H | H | Rₙ₆₀ | H | H |
| Lₐ₄₅₅₄ | Rₙ₈₁ | Ar95 | H | H | H | H | Rₙ₆₀ | H | H |
| Lₐ₄₅₅₅ | Rₙ₁ | Ar95 | H | H | H | H | Rₙ₆₄ | H | H |
| Lₐ₄₅₅₆ | Rₙ₄ | Ar95 | H | H | H | H | Rₙ₆₄ | H | H |
| Lₐ₄₅₅₇ | Rₙ₅ | Ar95 | H | H | H | H | Rₙ₆₄ | H | H |
| Lₐ₄₅₅₈ | Rₙ₇ | Ar95 | H | H | H | H | Rₙ₆₄ | H | H |
| Lₐ₄₅₅₉ | Rₙ₁₁ | Ar95 | H | H | H | H | Rₙ₆₄ | H | H |
| Lₐ₄₅₆₀ | Rₙ₂₀ | Ar95 | H | H | H | H | Rₙ₆₄ | H | H |
| Lₐ₄₅₆₁ | Rₙ₂₁ | Ar95 | H | H | H | H | Rₙ₆₄ | H | H |
| Lₐ₄₅₆₂ | Rₙ₅₁ | Ar95 | H | H | H | H | Rₙ₆₄ | H | H |
| Lₐ₄₅₆₃ | Rₙ₅₆ | Ar95 | H | H | H | H | Rₙ₆₄ | H | H |
| Lₐ₄₅₆₄ | Rₙ₅₉ | Ar95 | H | H | H | H | Rₙ₆₄ | H | H |
| Lₐ₄₅₆₅ | Rₙ₆₀ | Ar95 | H | H | H | H | Rₙ₆₄ | H | H |
| Lₐ₄₅₆₆ | Rₙ₆₁ | Ar95 | H | H | H | H | Rₙ₆₄ | H | H |
| Lₐ₄₅₆₇ | Rₙ₆₂ | Ar95 | H | H | H | H | Rₙ₆₄ | H | H |
| Lₐ₄₅₆₈ | Rₙ₆₄ | Ar95 | H | H | H | H | Rₙ₆₄ | H | H |
| Lₐ₄₅₆₉ | Rₙ₆₅ | Ar95 | H | H | H | H | Rₙ₆₄ | H | H |
| Lₐ₄₅₇₀ | Rₙ₆₉ | Ar95 | H | H | H | H | Rₙ₆₄ | H | H |
| Lₐ₄₅₇₁ | Rₙ₇₀ | Ar95 | H | H | H | H | Rₙ₆₄ | H | H |
| Lₐ₄₅₇₂ | Rₙ₈₁ | Ar95 | H | H | H | H | Rₙ₆₄ | H | H |
| Lₐ₄₅₇₃ | Rₙ₁ | Ar95 | H | H | H | H | Me | H | H |
| Lₐ₄₅₇₄ | Rₙ₄ | Ar95 | H | H | H | H | Me | H | H |
| Lₐ₄₅₇₅ | Rₙ₅ | Ar95 | H | H | H | H | Me | H | H |
| Lₐ₄₅₇₆ | Rₙ₇ | Ar95 | H | H | H | H | Me | H | H |
| Lₐ₄₅₇₇ | Rₙ₁₁ | Ar95 | H | H | H | H | Me | H | H |
| Lₐ₄₅₇₈ | Rₙ₂₀ | Ar95 | H | H | H | H | Me | H | H |
| Lₐ₄₅₇₉ | Rₙ₂₁ | Ar95 | H | H | H | H | Me | H | H |
| Lₐ₄₅₈₀ | Rₙ₅₁ | Ar95 | H | H | H | H | Me | H | H |
| Lₐ₄₅₈₁ | Rₙ₅₆ | Ar95 | H | H | H | H | Me | H | H |
| Lₐ₄₅₈₂ | Rₙ₅₉ | Ar95 | H | H | H | H | Me | H | H |
| Lₐ₄₅₈₃ | Rₙ₆₀ | Ar95 | H | H | H | H | Me | H | H |
| Lₐ₄₅₈₄ | Rₙ₆₁ | Ar95 | H | H | H | H | Me | H | H |
| Lₐ₄₅₈₅ | Rₙ₆₂ | Ar95 | H | H | H | H | Me | H | H |
| Lₐ₄₅₈₆ | Rₙ₆₄ | Ar95 | H | H | H | H | Me | H | H |
| Lₐ₄₅₈₇ | Rₙ₆₅ | Ar95 | H | H | H | H | Me | H | H |
| Lₐ₄₅₈₈ | Rₙ₆₉ | Ar95 | H | H | H | H | Me | H | H |
| Lₐ₄₅₈₉ | Rₙ₇₀ | Ar95 | H | H | H | H | Me | H | H |
| Lₐ₄₅₉₀ | Rₙ₈₁ | Ar95 | H | H | H | H | Me | H | H |
| Lₐ₄₅₉₁ | Rₙ₁ | Ar95 | D | H | F | H | H | H | H |
| Lₐ₄₅₉₂ | Rₙ₄ | Ar95 | H | H | F | H | H | H | H |
| Lₐ₄₅₉₃ | Rₙ₇ | Ar95 | H | H | F | H | H | H | H |
| Lₐ₄₅₉₄ | Rₙ₂₀ | Ar95 | H | H | F | H | H | H | H |
| Lₐ₄₅₉₅ | Rₙ₂₁ | Ar95 | H | H | F | H | H | H | H |
| Lₐ₄₅₉₆ | Rₙ₅₆ | Ar95 | H | D | F | H | H | H | H |
| Lₐ₄₅₉₇ | Rₙ₅₉ | Ar95 | H | H | F | H | H | H | H |
| Lₐ₄₅₉₈ | Rₙ₆₁ | Ar95 | H | H | F | H | H | H | H |
| Lₐ₄₅₉₉ | Rₙ₆₂ | Ar95 | H | H | F | H | H | H | H |
| Lₐ₄₆₀₀ | Rₙ₆₄ | Ar95 | H | H | F | H | H | H | H |
| Lₐ₄₆₀₁ | Rₙ₆₉ | Ar95 | H | H | F | H | H | H | H |
| Lₐ₄₆₀₂ | Rₙ₇₀ | Ar95 | H | H | F | H | H | H | H |
| Lₐ₄₆₀₃ | Rₙ₁ | Ar95 | H | H | F | H | Rₙ₁₁ | H | H |
| Lₐ₄₆₀₄ | Rₙ₄ | Ar95 | H | H | F | H | Rₙ₁₁ | H | H |
| Lₐ₄₆₀₅ | Rₙ₇ | Ar95 | H | H | F | H | Rₙ₁₁ | H | H |
| Lₐ₄₆₀₆ | Rₙ₂₀ | Ar95 | H | H | F | H | Rₙ₁₁ | H | H |
| Lₐ₄₆₀₇ | Rₙ₂₁ | Ar95 | H | H | F | H | Rₙ₁₁ | H | H |
| Lₐ₄₆₀₈ | Rₙ₅₆ | Ar95 | H | H | F | H | Rₙ₁₁ | H | H |
| Lₐ₄₆₀₉ | Rₙ₅₉ | Ar95 | H | H | F | H | Rₙ₁₁ | H | H |
| Lₐ₄₆₁₀ | Rₙ₆₁ | Ar95 | H | H | F | H | Rₙ₁₁ | H | H |
| Lₐ₄₆₁₁ | Rₙ₆₂ | Ar95 | H | H | F | H | Rₙ₁₁ | H | H |
| Lₐ₄₆₁₂ | Rₙ₆₄ | Ar95 | H | H | F | H | Rₙ₁₁ | H | H |
| Lₐ₄₆₁₃ | Rₙ₆₉ | Ar95 | H | H | F | H | Rₙ₁₁ | H | H |
| Lₐ₄₆₁₄ | Rₙ₇₀ | Ar95 | H | H | F | H | Rₙ₁₁ | H | H |
| Lₐ₄₆₁₅ | Rₙ₁ | Ar95 | H | H | F | H | Rₙ₆₀ | H | H |
| Lₐ₄₆₁₆ | Rₙ₄ | Ar95 | H | H | F | H | Rₙ₆₀ | H | H |
| Lₐ₄₆₁₇ | Rₙ₇ | Ar95 | H | H | F | H | Rₙ₆₀ | H | H |
| Lₐ₄₆₁₈ | Rₙ₂₀ | Ar95 | H | H | F | H | Rₙ₆₀ | H | H |
| Lₐ₄₆₁₉ | Rₙ₂₁ | Ar95 | H | H | F | H | Rₙ₆₀ | H | H |
| Lₐ₄₆₂₀ | Rₙ₅₆ | Ar95 | H | H | F | H | Rₙ₆₀ | H | H |
| Lₐ₄₆₂₁ | Rₙ₅₉ | Ar95 | H | H | F | H | Rₙ₆₀ | H | H |
| Lₐ₄₆₂₂ | Rₙ₆₁ | Ar95 | H | H | F | H | Rₙ₆₀ | H | H |
| Lₐ₄₆₂₃ | Rₙ₆₂ | Ar95 | H | H | F | H | Rₙ₆₀ | H | H |
| Lₐ₄₆₂₄ | Rₙ₆₄ | Ar95 | H | H | F | H | Rₙ₆₀ | H | H |
| Lₐ₄₆₂₅ | Rₙ₆₉ | Ar95 | H | H | F | H | Rₙ₆₀ | H | H |
| Lₐ₄₆₂₆ | Rₙ₇₀ | Ar95 | H | H | F | H | Rₙ₆₀ | H | H |
| Lₐ₄₆₂₇ | Rₙ₁ | Ar95 | H | H | F | H | H | Rₙ₁₁ | H |
| Lₐ₄₆₂₈ | Rₙ₄ | Ar95 | H | H | F | H | H | Rₙ₁₁ | H |
| Lₐ₄₆₂₉ | Rₙ₇ | Ar95 | H | H | F | H | H | Rₙ₁₁ | H |
| Lₐ₄₆₃₀ | Rₙ₂₀ | Ar95 | H | H | F | H | H | Rₙ₁₁ | H |
| Lₐ₄₆₃₁ | Rₙ₂₁ | Ar95 | H | H | F | H | H | Rₙ₁₁ | H |
| Lₐ₄₆₃₂ | Rₙ₅₆ | Ar95 | H | H | F | H | H | Rₙ₁₁ | H |
| Lₐ₄₆₃₃ | Rₙ₅₉ | Ar95 | H | H | F | H | H | Rₙ₁₁ | H |
| Lₐ₄₆₃₄ | Rₙ₆₁ | Ar95 | H | H | F | H | H | Rₙ₁₁ | H |
| Lₐ₄₆₃₅ | Rₙ₆₂ | Ar95 | H | H | F | H | H | Rₙ₁₁ | H |
| Lₐ₄₆₃₆ | Rₙ₆₄ | Ar95 | H | H | F | H | H | Rₙ₁₁ | H |
| Lₐ₄₆₃₇ | Rₙ₆₉ | Ar95 | H | H | F | H | H | Rₙ₁₁ | H |
| Lₐ₄₆₃₈ | Rₙ₇₀ | Ar95 | H | H | F | H | H | Rₙ₁₁ | H |
| Lₐ₄₆₃₉ | Rₙ₁ | Ar95 | H | H | F | H | H | Rₙ₆₀ | H |
| Lₐ₄₆₄₀ | Rₙ₄ | Ar95 | H | H | F | H | H | Rₙ₆₀ | H |
| Lₐ₄₆₄₁ | Rₙ₇ | Ar95 | H | H | F | H | H | Rₙ₆₀ | H |
| Lₐ₄₆₄₂ | Rₙ₂₀ | Ar95 | H | H | F | H | H | Rₙ₆₀ | H |
| Lₐ₄₆₄₃ | Rₙ₂₁ | Ar95 | H | H | F | H | H | Rₙ₆₀ | H |
| Lₐ₄₆₄₄ | Rₙ₅₆ | Ar95 | H | H | F | H | H | Rₙ₆₀ | H |
| Lₐ₄₆₄₅ | Rₙ₅₉ | Ar95 | H | H | F | H | H | Rₙ₆₀ | H |
| Lₐ₄₆₄₆ | Rₙ₆₁ | Ar95 | H | H | F | H | H | Rₙ₆₀ | H |
| Lₐ₄₆₄₇ | Rₙ₆₂ | Ar95 | H | H | F | H | H | Rₙ₆₀ | H |
| Lₐ₄₆₄₈ | Rₙ₆₄ | Ar95 | H | H | F | H | H | Rₙ₆₀ | H |
| Lₐ₄₆₄₉ | Rₙ₆₉ | Ar95 | H | H | F | H | H | Rₙ₆₀ | H |
| Lₐ₄₆₅₀ | Rₙ₇₀ | Ar95 | H | H | F | H | H | Rₙ₆₀ | H |
| Lₐ₄₆₅₁ | Rₙ₁ | Ar95 | H | D | CN | H | H | H | H |
| Lₐ₄₆₅₂ | Rₙ₄ | Ar95 | H | H | CN | H | H | H | H |
| Lₐ₄₆₅₃ | Rₙ₇ | Ar95 | H | H | CN | H | H | H | H |
| Lₐ₄₆₅₄ | Rₙ₂₀ | Ar95 | H | H | CN | H | H | H | H |
| Lₐ₄₆₅₅ | Rₙ₂₁ | Ar95 | H | H | CN | H | H | H | H |
| Lₐ₄₆₅₆ | Rₙ₅₆ | Ar95 | H | H | CN | H | H | H | H |
| Lₐ₄₆₅₇ | Rₙ₅₉ | Ar95 | H | H | CN | H | H | H | H |
| Lₐ₄₆₅₈ | Rₙ₆₁ | Ar95 | H | H | CN | H | H | H | H |
| Lₐ₄₆₅₉ | Rₙ₆₂ | Ar95 | H | H | CN | H | H | H | H |
| Lₐ₄₆₆₀ | Rₙ₆₄ | Ar95 | H | H | CN | H | H | H | H |
| Lₐ₄₆₆₁ | Rₙ₆₉ | Ar95 | H | H | CN | H | H | H | H |
| Lₐ₄₆₆₂ | Rₙ₇₀ | Ar95 | H | H | CN | H | H | H | H |
| Lₐ₄₆₆₃ | Rₙ₁ | Ar95 | H | CN | H | H | H | H | H |
| Lₐ₄₆₆₄ | Rₙ₄ | Ar95 | H | CN | H | H | H | H | H |
| Lₐ₄₆₆₅ | Rₙ₇ | Ar95 | H | CN | H | H | H | H | H |
| Lₐ₄₆₆₆ | Rₙ₂₀ | Ar95 | H | CN | H | H | H | H | H |
| Lₐ₄₆₆₇ | Rₙ₂₁ | Ar95 | H | CN | H | H | H | H | H |
| Lₐ₄₆₆₈ | Rₙ₅₆ | Ar95 | D | CN | H | H | H | H | H |
| Lₐ₄₆₆₉ | Rₙ₅₉ | Ar95 | H | CN | H | H | H | H | H |
| Lₐ₄₆₇₀ | Rₙ₆₁ | Ar95 | H | CN | H | H | H | H | H |
| Lₐ₄₆₇₁ | Rₙ₆₂ | Ar95 | H | CN | H | H | H | H | H |
| Lₐ₄₆₇₂ | Rₙ₆₄ | Ar95 | H | CN | H | H | H | H | H |
| Lₐ₄₆₇₃ | Rₙ₆₉ | Ar95 | H | CN | H | H | H | H | H |
| Lₐ₄₆₇₄ | Rₙ₇₀ | Ar95 | H | CN | H | H | H | H | H |
| Lₐ₄₆₇₅ | Rₙ₁ | Ar95 | CN | H | H | H | H | H | H |
| Lₐ₄₆₇₆ | Rₙ₄ | Ar95 | CN | H | H | H | H | H | H |
| Lₐ₄₆₇₇ | Rₙ₇ | Ar95 | CN | H | H | H | H | H | H |
| Lₐ₄₆₇₈ | Rₙ₂₀ | Ar95 | CN | H | H | H | H | H | H |
| Lₐ₄₆₇₉ | Rₙ₂₁ | Ar95 | CN | H | H | H | H | H | H |
| Lₐ₄₆₈₀ | Rₙ₅₆ | Ar95 | CN | H | H | H | H | H | H |
| Lₐ₄₆₈₁ | Rₙ₅₉ | Ar95 | CN | H | H | H | H | H | H |
| Lₐ₄₆₈₂ | Rₙ₆₁ | Ar95 | CN | H | H | H | H | H | H |
| Lₐ₄₆₈₃ | Rₙ₆₂ | Ar95 | CN | H | H | H | H | H | H |
| Lₐ₄₆₈₄ | Rₙ₆₄ | Ar95 | CN | H | H | H | H | H | H |
| Lₐ₄₆₈₅ | Rₙ₆₉ | Ar95 | CN | H | H | H | H | H | H |
| Lₐ₄₆₈₆ | Rₙ₇₀ | Ar95 | CN | H | H | H | H | H | H |
| Lₐ₄₆₈₇ | Rₙ₁ | Ar95 | H | H | CN | H | Rₙ₁₁ | H | H |
| Lₐ₄₆₈₈ | Rₙ₄ | Ar95 | H | H | CN | H | Rₙ₁₁ | H | H |
| Lₐ₄₆₈₉ | Rₙ₇ | Ar95 | H | H | CN | H | Rₙ₁₁ | H | H |
| Lₐ₄₆₉₀ | Rₙ₂₀ | Ar95 | H | H | CN | H | Rₙ₁₁ | H | H |
| Lₐ₄₆₉₁ | Rₙ₂₁ | Ar95 | H | H | CN | H | Rₙ₁₁ | H | H |
| Lₐ₄₆₉₂ | Rₙ₅₆ | Ar95 | H | H | CN | H | Rₙ₁₁ | H | H |
| Lₐ₄₆₉₃ | Rₙ₅₉ | Ar95 | H | H | CN | H | Rₙ₁₁ | H | H |
| Lₐ₄₆₉₄ | Rₙ₆₁ | Ar95 | H | H | CN | H | Rₙ₁₁ | H | H |
| Lₐ₄₆₉₅ | Rₙ₆₂ | Ar95 | H | H | CN | H | Rₙ₁₁ | H | H |
| Lₐ₄₆₉₆ | Rₙ₆₄ | Ar95 | H | H | CN | H | Rₙ₁₁ | H | H |
| Lₐ₄₆₉₇ | Rₙ₆₉ | Ar95 | H | H | CN | H | Rₙ₁₁ | H | H |
| Lₐ₄₆₉₈ | Rₙ₇₀ | Ar95 | H | H | CN | H | Rₙ₁₁ | H | H |
| Lₐ₄₆₉₉ | Rₙ₁ | Ar95 | H | H | CN | H | Rₙ₆₀ | H | H |
| Lₐ₄₇₀₀ | Rₙ₄ | Ar95 | H | H | CN | H | Rₙ₆₀ | H | H |
| Lₐ₄₇₀₁ | Rₙ₇ | Ar95 | H | H | CN | H | Rₙ₆₀ | H | H |
| Lₐ₄₇₀₂ | Rₙ₂₀ | Ar95 | H | H | CN | H | Rₙ₆₀ | H | H |
| Lₐ₄₇₀₃ | Rₙ₂₁ | Ar95 | H | H | CN | H | Rₙ₆₀ | H | H |
| Lₐ₄₇₀₄ | Rₙ₅₆ | Ar95 | H | H | CN | H | Rₙ₆₀ | H | H |
| Lₐ₄₇₀₅ | Rₙ₅₉ | Ar95 | H | H | CN | H | Rₙ₆₀ | H | H |
| Lₐ₄₇₀₆ | Rₙ₆₁ | Ar95 | H | H | CN | H | Rₙ₆₀ | H | H |
| Lₐ₄₇₀₇ | Rₙ₆₂ | Ar95 | H | H | CN | H | Rₙ₆₀ | H | H |
| Lₐ₄₇₀₈ | Rₙ₆₄ | Ar95 | H | H | CN | H | Rₙ₆₀ | H | H |
| Lₐ₄₇₀₉ | Rₙ₆₉ | Ar95 | H | H | CN | H | Rₙ₆₀ | H | H |
| Lₐ₄₇₁₀ | Rₙ₇₀ | Ar95 | H | H | CN | H | Rₙ₆₀ | H | H |
| Lₐ₄₇₁₁ | Rₙ₁ | Ar95 | H | H | CN | H | Rₙ₆₄ | H | H |
| Lₐ₄₇₁₂ | Rₙ₄ | Ar95 | H | H | CN | H | Rₙ₆₄ | H | H |
| Lₐ₄₇₁₃ | Rₙ₇ | Ar95 | H | H | CN | H | Rₙ₆₄ | H | H |
| Lₐ₄₇₁₄ | Rₙ₂₀ | Ar95 | H | H | CN | H | Rₙ₆₄ | H | H |
| Lₐ₄₇₁₅ | Rₙ₂₁ | Ar95 | H | H | CN | H | Rₙ₆₄ | H | H |
| Lₐ₄₇₁₆ | Rₙ₅₆ | Ar95 | H | H | CN | H | Rₙ₆₄ | H | H |
| Lₐ₄₇₁₇ | Rₙ₅₉ | Ar95 | H | H | CN | H | Rₙ₆₄ | H | H |
| Lₐ₄₇₁₈ | Rₙ₆₁ | Ar95 | H | H | CN | H | Rₙ₆₄ | H | H |
| Lₐ₄₇₁₉ | Rₙ₆₂ | Ar95 | H | H | CN | H | Rₙ₆₄ | H | H |
| Lₐ₄₇₂₀ | Rₙ₆₄ | Ar95 | H | H | CN | H | Rₙ₆₄ | H | H |
| Lₐ₄₇₂₁ | Rₙ₆₉ | Ar95 | H | H | CN | H | Rₙ₆₄ | H | H |
| Lₐ₄₇₂₂ | Rₙ₇₀ | Ar95 | H | H | CN | H | Rₙ₆₄ | H | H |
| Lₐ₄₇₂₃ | Rₙ₁ | Ar95 | H | H | CN | H | H | Rₙ₁₁ | H |
| Lₐ₄₇₂₄ | Rₙ₄ | Ar95 | H | H | CN | H | H | Rₙ₁₁ | H |
| Lₐ₄₇₂₅ | Rₙ₇ | Ar95 | H | H | CN | H | H | Rₙ₁₁ | H |
| Lₐ₄₇₂₆ | Rₙ₂₀ | Ar95 | H | H | CN | H | H | Rₙ₁₁ | H |
| Lₐ₄₇₂₇ | Rₙ₂₁ | Ar95 | H | H | CN | H | H | Rₙ₁₁ | H |
| Lₐ₄₇₂₈ | Rₙ₅₆ | Ar95 | H | H | CN | H | H | Rₙ₁₁ | H |
| Lₐ₄₇₂₉ | Rₙ₅₉ | Ar95 | H | H | CN | H | H | Rₙ₁₁ | H |
| Lₐ₄₇₃₀ | Rₙ₆₁ | Ar95 | H | H | CN | H | H | Rₙ₁₁ | H |
| Lₐ₄₇₃₁ | Rₙ₆₂ | Ar95 | H | H | CN | H | H | Rₙ₁₁ | H |
| Lₐ₄₇₃₂ | Rₙ₆₄ | Ar95 | H | H | CN | H | H | Rₙ₁₁ | H |
| Lₐ₄₇₃₃ | Rₙ₆₉ | Ar95 | H | H | CN | H | H | Rₙ₁₁ | H |
| Lₐ₄₇₃₄ | Rₙ₇₀ | Ar95 | H | H | CN | H | H | Rₙ₁₁ | H |
| Lₐ₄₇₃₅ | Rₙ₁ | Ar95 | H | H | CN | H | H | Rₙ₆₀ | H |
| Lₐ₄₇₃₆ | Rₙ₄ | Ar95 | H | H | CN | H | H | Rₙ₆₀ | H |
| Lₐ₄₇₃₇ | Rₙ₇ | Ar95 | H | H | CN | H | H | Rₙ₆₀ | H |
| Lₐ₄₇₃₈ | Rₙ₂₀ | Ar95 | H | H | CN | H | H | Rₙ₆₀ | D |
| Lₐ₄₇₃₉ | Rₙ₂₁ | Ar95 | H | H | CN | H | H | Rₙ₆₀ | H |
| Lₐ₄₇₄₀ | Rₙ₅₆ | Ar95 | H | H | CN | H | H | Rₙ₆₀ | H |
| Lₐ₄₇₄₁ | Rₙ₅₉ | Ar95 | H | H | CN | H | H | Rₙ₆₀ | H |
| Lₐ₄₇₄₂ | Rₙ₆₁ | Ar95 | H | H | CN | H | H | Rₙ₆₀ | H |
| Lₐ₄₇₄₃ | Rₙ₆₂ | Ar95 | H | H | CN | H | H | Rₙ₆₀ | H |
| Lₐ₄₇₄₄ | Rₙ₆₄ | Ar95 | H | H | CN | H | H | Rₙ₆₀ | H |
| Lₐ₄₇₄₅ | Rₙ₆₉ | Ar95 | H | H | CN | H | H | Rₙ₆₀ | H |
| Lₐ₄₇₄₆ | Rₙ₇₀ | Ar95 | H | H | CN | H | H | Rₙ₆₀ | H |
| Lₐ₄₇₄₇ | Rₙ₁ | Ar95 | H | H | CN | H | H | Rₙ₆₄ | H |
| Lₐ₄₇₄₈ | Rₙ₄ | Ar95 | H | H | CN | H | H | Rₙ₆₄ | H |
| Lₐ₄₇₄₉ | Rₙ₇ | Ar95 | H | H | CN | H | H | Rₙ₆₄ | H |
| Lₐ₄₇₅₀ | Rₙ₂₀ | Ar95 | H | H | CN | H | H | Rₙ₆₄ | H |
| Lₐ₄₇₅₁ | Rₙ₂₁ | Ar95 | H | H | CN | H | H | Rₙ₆₄ | H |
| Lₐ₄₇₅₂ | Rₙ₅₆ | Ar95 | H | H | CN | H | H | Rₙ₆₄ | H |
| Lₐ₄₇₅₃ | Rₙ₅₉ | Ar95 | H | H | CN | H | H | Rₙ₆₄ | H |
| Lₐ₄₇₅₄ | Rₙ₆₁ | Ar95 | H | H | CN | H | H | Rₙ₆₄ | H |
| Lₐ₄₇₅₅ | Rₙ₆₂ | Ar95 | H | H | CN | H | H | Rₙ₆₄ | H |
| Lₐ₄₇₅₆ | Rₙ₆₄ | Ar95 | H | H | CN | H | H | Rₙ₆₄ | H |
| Lₐ₄₇₅₇ | Rₙ₆₉ | Ar95 | H | H | CN | H | H | Rₙ₆₄ | H |
| Lₐ₄₇₅₈ | Rₙ₇₀ | Ar95 | H | H | CN | H | H | Rₙ₆₄ | H |
| Lₐ₄₇₅₉ | Rₙ₁ | Ar97 | H | H | H | H | H | H | H |
| Lₐ₄₇₆₀ | Rₙ₄ | Ar97 | H | H | H | H | H | H | H |
| Lₐ₄₇₆₁ | Rₙ₅ | Ar97 | H | H | H | H | H | H | H |
| Lₐ₄₇₆₂ | Rₙ₇ | Ar97 | H | H | H | H | H | H | H |
| Lₐ₄₇₆₃ | Rₙ₁₁ | Ar97 | H | H | H | H | H | H | D |
| Lₐ₄₇₆₄ | Rₙ₂₀ | Ar97 | H | H | H | H | H | H | H |
| Lₐ₄₇₆₅ | Rₙ₂₁ | Ar97 | H | H | H | H | H | H | H |
| Lₐ₄₇₆₆ | Rₙ₅₁ | Ar97 | H | H | H | H | H | H | H |
| Lₐ₄₇₆₇ | Rₙ₅₆ | Ar97 | H | H | H | D | H | H | H |
| Lₐ₄₇₆₈ | Rₙ₅₉ | Ar97 | H | H | H | H | H | H | H |
| Lₐ₄₇₆₉ | Rₙ₆₀ | Ar97 | H | H | H | H | H | H | H |
| Lₐ₄₇₇₀ | Rₙ₆₁ | Ar97 | H | H | H | H | H | H | H |
| Lₐ₄₇₇₁ | Rₙ₆₂ | Ar97 | D | H | H | H | H | H | H |
| Lₐ₄₇₇₂ | Rₙ₆₄ | Ar97 | H | H | H | H | H | H | H |
| Lₐ₄₇₇₃ | Rₙ₆₅ | Ar97 | H | H | H | H | H | H | H |
| Lₐ₄₇₇₄ | Rₙ₆₉ | Ar97 | H | H | H | H | H | H | H |
| Lₐ₄₇₇₅ | Rₙ₇₀ | Ar97 | H | H | H | H | H | H | H |
| Lₐ₄₇₇₆ | Rₙ₈₁ | Ar97 | H | H | H | H | H | H | H |
| Lₐ₄₇₇₇ | Rₙ₁ | Ar97 | H | H | H | H | H | Rₙ₁₁ | H |
| Lₐ₄₇₇₈ | Rₙ₄ | Ar97 | H | H | H | H | H | Rₙ₁₁ | H |
| Lₐ₄₇₇₉ | Rₙ₅ | Ar97 | H | H | H | H | H | Rₙ₁₁ | H |
| Lₐ₄₇₈₀ | Rₙ₇ | Ar97 | H | H | H | H | H | Rₙ₁₁ | H |
| Lₐ₄₇₈₁ | Rₙ₁₁ | Ar97 | H | H | H | H | H | Rₙ₁₁ | H |
| Lₐ₄₇₈₂ | Rₙ₂₀ | Ar97 | H | H | H | H | H | Rₙ₁₁ | H |
| Lₐ₄₇₈₃ | Rₙ₂₁ | Ar97 | H | H | H | H | H | Rₙ₁₁ | H |
| Lₐ₄₇₈₄ | Rₙ₅₁ | Ar97 | H | H | H | H | H | Rₙ₁₁ | H |
| Lₐ₄₇₈₅ | Rₙ₅₆ | Ar97 | H | H | H | H | H | Rₙ₁₁ | H |
| Lₐ₄₇₈₆ | Rₙ₅₉ | Ar97 | H | H | H | H | H | Rₙ₁₁ | H |
| Lₐ₄₇₈₇ | Rₙ₆₀ | Ar97 | H | H | H | H | H | Rₙ₁₁ | H |
| Lₐ₄₇₈₈ | Rₙ₆₁ | Ar97 | H | H | H | H | H | Rₙ₁₁ | H |
| Lₐ₄₇₈₉ | Rₙ₆₂ | Ar97 | H | H | H | H | H | Rₙ₁₁ | H |
| Lₐ₄₇₉₀ | Rₙ₆₄ | Ar97 | H | H | H | H | H | Rₙ₁₁ | H |
| Lₐ₄₇₉₁ | Rₙ₆₅ | Ar97 | H | H | H | H | H | Rₙ₁₁ | H |
| Lₐ₄₇₉₂ | Rₙ₆₉ | Ar97 | H | H | H | H | H | Rₙ₁₁ | H |
| Lₐ₄₇₉₃ | Rₙ₇₀ | Ar97 | H | H | H | H | H | Rₙ₁₁ | H |
| Lₐ₄₇₉₄ | Rₙ₈₁ | Ar97 | H | H | H | H | H | Rₙ₁₁ | H |
| Lₐ₄₇₉₅ | Rₙ₁ | Ar97 | H | H | H | H | H | Rₙ₅₉ | H |
| Lₐ₄₇₉₆ | Rₙ₄ | Ar97 | H | H | H | H | H | Rₙ₅₉ | H |
| Lₐ₄₇₉₇ | Rₙ₅ | Ar97 | H | H | H | H | H | Rₙ₅₉ | H |
| Lₐ₄₇₉₈ | Rₙ₇ | Ar97 | H | H | H | H | H | Rₙ₅₉ | H |
| Lₐ₄₇₉₉ | Rₙ₁₁ | Ar97 | H | H | H | H | H | Rₙ₅₉ | H |
| Lₐ₄₈₀₀ | Rₙ₂₀ | Ar97 | H | H | H | H | H | Rₙ₅₉ | H |
| Lₐ₄₈₀₁ | Rₙ₂₁ | Ar97 | H | H | H | H | H | Rₙ₅₉ | H |
| Lₐ₄₈₀₂ | Rₙ₅₁ | Ar97 | H | H | H | H | H | Rₙ₅₉ | H |
| Lₐ₄₈₀₃ | Rₙ₅₆ | Ar97 | H | H | H | H | H | Rₙ₅₉ | H |
| Lₐ₄₈₀₄ | Rₙ₅₉ | Ar97 | H | H | H | H | H | Rₙ₅₉ | H |
| Lₐ₄₈₀₅ | Rₙ₆₀ | Ar97 | H | H | H | H | H | Rₙ₅₉ | H |
| Lₐ₄₈₀₆ | Rₙ₆₁ | Ar97 | H | H | H | H | H | Rₙ₅₉ | H |
| Lₐ₄₈₀₇ | Rₙ₆₂ | Ar97 | H | H | H | H | H | Rₙ₅₉ | H |
| Lₐ₄₈₀₈ | Rₙ₆₄ | Ar97 | H | H | H | H | H | Rₙ₅₉ | H |
| Lₐ₄₈₀₉ | Rₙ₆₅ | Ar97 | H | H | H | H | H | Rₙ₅₉ | H |
| Lₐ₄₈₁₀ | Rₙ₆₉ | Ar97 | H | H | H | H | H | Rₙ₅₉ | H |
| Lₐ₄₈₁₁ | Rₙ₇₀ | Ar97 | H | H | H | H | H | Rₙ₅₉ | H |
| Lₐ₄₈₁₂ | Rₙ₈₁ | Ar97 | H | H | H | H | H | Rₙ₅₉ | H |
| Lₐ₄₈₁₃ | Rₙ₁ | Ar97 | H | H | H | H | H | Rₙ₆₀ | H |
| Lₐ₄₈₁₄ | Rₙ₄ | Ar97 | H | H | H | H | H | Rₙ₆₀ | H |
| Lₐ₄₈₁₅ | Rₙ₅ | Ar97 | H | H | H | H | H | Rₙ₆₀ | H |
| Lₐ₄₈₁₆ | Rₙ₇ | Ar97 | H | H | H | H | H | Rₙ₆₀ | H |
| Lₐ₄₈₁₇ | Rₙ₁₁ | Ar97 | H | H | H | H | H | Rₙ₆₀ | H |
| Lₐ₄₈₁₈ | Rₙ₂₀ | Ar97 | H | H | H | H | H | Rₙ₆₀ | H |
| Lₐ₄₈₁₉ | Rₙ₂₁ | Ar97 | H | H | H | H | H | Rₙ₆₀ | H |
| Lₐ₄₈₂₀ | Rₙ₅₁ | Ar97 | H | H | H | H | H | Rₙ₆₀ | H |
| Lₐ₄₈₂₁ | Rₙ₅₆ | Ar97 | H | H | H | H | H | Rₙ₆₀ | H |
| Lₐ₄₈₂₂ | Rₙ₅₉ | Ar97 | H | H | H | H | H | Rₙ₆₀ | H |
| Lₐ₄₈₂₃ | Rₙ₆₀ | Ar97 | H | H | H | H | H | Rₙ₆₀ | H |
| Lₐ₄₈₂₄ | Rₙ₆₁ | Ar97 | H | H | H | H | H | Rₙ₆₀ | H |
| Lₐ₄₈₂₅ | Rₙ₆₂ | Ar97 | H | H | H | H | H | Rₙ₆₀ | H |
| Lₐ₄₈₂₆ | Rₙ₆₄ | Ar97 | H | H | H | H | H | Rₙ₆₀ | H |
| Lₐ₄₈₂₇ | Rₙ₆₅ | Ar97 | H | H | H | H | H | Rₙ₆₀ | H |
| Lₐ₄₈₂₈ | Rₙ₆₉ | Ar97 | H | H | H | H | H | Rₙ₆₀ | H |
| Lₐ₄₈₂₉ | Rₙ₇₀ | Ar97 | H | H | H | H | H | Rₙ₆₀ | H |
| Lₐ₄₈₃₀ | Rₙ₈₁ | Ar97 | H | H | H | H | H | Rₙ₆₀ | H |
| Lₐ₄₈₃₁ | Rₙ₁ | Ar97 | H | H | H | H | H | Rₙ₆₄ | H |
| Lₐ₄₈₃₂ | Rₙ₄ | Ar97 | H | H | H | H | H | Rₙ₆₄ | H |
| Lₐ₄₈₃₃ | Rₙ₅ | Ar97 | H | H | H | H | H | Rₙ₆₄ | H |
| Lₐ₄₈₃₄ | Rₙ₇ | Ar97 | H | H | H | H | H | Rₙ₆₄ | H |
| Lₐ₄₈₃₅ | Rₙ₁₁ | Ar97 | H | H | H | H | H | Rₙ₆₄ | H |
| Lₐ₄₈₃₆ | Rₙ₂₀ | Ar97 | H | H | H | H | H | Rₙ₆₄ | H |
| Lₐ₄₈₃₇ | Rₙ₂₁ | Ar97 | H | H | H | H | H | Rₙ₆₄ | H |
| Lₐ₄₈₃₈ | Rₙ₅₁ | Ar97 | H | H | H | H | H | Rₙ₆₄ | H |
| Lₐ₄₈₃₉ | Rₙ₅₆ | Ar97 | H | H | H | H | H | Rₙ₆₄ | H |
| Lₐ₄₈₄₀ | Rₙ₅₉ | Ar97 | H | H | H | H | H | Rₙ₆₄ | H |
| Lₐ₄₈₄₁ | Rₙ₆₀ | Ar97 | H | H | H | H | H | Rₙ₆₄ | H |
| Lₐ₄₈₄₂ | Rₙ₆₁ | Ar97 | H | H | H | H | H | Rₙ₆₄ | H |
| Lₐ₄₈₄₃ | Rₙ₆₂ | Ar97 | H | H | H | H | H | Rₙ₆₄ | H |
| Lₐ₄₈₄₄ | Rₙ₆₄ | Ar97 | H | H | H | H | H | Rₙ₆₄ | H |
| Lₐ₄₈₄₅ | Rₙ₆₅ | Ar97 | H | H | H | H | H | Rₙ₆₄ | H |
| Lₐ₄₈₄₆ | Rₙ₆₉ | Ar97 | H | H | H | H | H | Rₙ₆₄ | H |
| Lₐ₄₈₄₇ | Rₙ₇₀ | Ar97 | H | H | H | H | H | Rₙ₆₄ | H |
| Lₐ₄₈₄₈ | Rₙ₈₁ | Ar97 | H | H | H | H | H | Rₙ₆₄ | H |
| Lₐ₄₈₄₉ | Rₙ₁ | Ar97 | H | H | H | H | H | Me | H |
| Lₐ₄₈₅₀ | Rₙ₄ | Ar97 | H | H | H | H | H | Me | H |
| Lₐ₄₈₅₁ | Rₙ₅ | Ar97 | H | H | H | H | H | Me | H |
| Lₐ₄₈₅₂ | Rₙ₇ | Ar97 | H | H | H | H | H | Me | H |
| Lₐ₄₈₅₃ | Rₙ₁₁ | Ar97 | H | H | H | H | H | Me | H |
| Lₐ₄₈₅₄ | Rₙ₂₀ | Ar97 | H | H | H | H | H | Me | H |
| Lₐ₄₈₅₅ | Rₙ₂₁ | Ar97 | H | H | H | H | H | Me | H |
| Lₐ₄₈₅₆ | Rₙ₅₁ | Ar97 | H | H | H | H | H | Me | H |
| Lₐ₄₈₅₇ | Rₙ₅₆ | Ar97 | H | H | H | H | H | Me | H |
| Lₐ₄₈₅₈ | Rₙ₅₉ | Ar97 | H | H | H | H | H | Me | H |
| Lₐ₄₈₅₉ | Rₙ₆₀ | Ar97 | H | H | H | H | H | Me | H |
| Lₐ₄₈₆₀ | Rₙ₆₁ | Ar97 | H | H | H | H | H | Me | H |
| Lₐ₄₈₆₁ | Rₙ₆₂ | Ar97 | H | H | H | H | H | Me | H |
| Lₐ₄₈₆₂ | Rₙ₆₄ | Ar97 | H | H | H | H | H | Me | H |
| Lₐ₄₈₆₃ | Rₙ₆₅ | Ar97 | H | H | H | H | H | Me | H |
| Lₐ₄₈₆₄ | Rₙ₆₉ | Ar97 | H | H | H | H | H | Me | H |
| Lₐ₄₈₆₅ | Rₙ₇₀ | Ar97 | H | H | H | H | H | Me | H |
| Lₐ₄₈₆₆ | Rₙ₈₁ | Ar97 | H | H | H | H | H | Me | H |
| Lₐ₄₈₆₇ | Rₙ₁ | Ar97 | H | H | H | H | Rₙ₁₁ | H | H |
| Lₐ₄₈₆₈ | Rₙ₄ | Ar97 | H | H | H | H | Rₙ₁₁ | H | H |
| Lₐ₄₈₆₉ | Rₙ₅ | Ar97 | H | H | H | H | Rₙ₁₁ | H | H |
| Lₐ₄₈₇₀ | Rₙ₇ | Ar97 | H | H | H | H | Rₙ₁₁ | H | H |
| Lₐ₄₈₇₁ | Rₙ₁₁ | Ar97 | H | H | H | H | Rₙ₁₁ | H | H |
| Lₐ₄₈₇₂ | Rₙ₂₀ | Ar97 | H | H | H | H | Rₙ₁₁ | H | H |
| Lₐ₄₈₇₃ | Rₙ₂₁ | Ar97 | H | H | H | H | Rₙ₁₁ | H | H |
| Lₐ₄₈₇₄ | Rₙ₅₁ | Ar97 | H | H | H | H | Rₙ₁₁ | H | H |
| Lₐ₄₈₇₅ | Rₙ₅₆ | Ar97 | H | H | H | H | Rₙ₁₁ | H | H |
| Lₐ₄₈₇₆ | Rₙ₅₉ | Ar97 | H | H | H | H | Rₙ₁₁ | H | H |
| Lₐ₄₈₇₇ | Rₙ₆₀ | Ar97 | H | H | H | H | Rₙ₁₁ | H | H |
| Lₐ₄₈₇₈ | Rₙ₆₁ | Ar97 | H | H | H | H | Rₙ₁₁ | H | H |
| Lₐ₄₈₇₉ | Rₙ₆₂ | Ar97 | H | H | H | H | Rₙ₁₁ | H | H |
| Lₐ₄₈₈₀ | Rₙ₆₄ | Ar97 | H | H | H | H | Rₙ₁₁ | H | H |
| Lₐ₄₈₈₁ | Rₙ₆₅ | Ar97 | H | H | H | H | Rₙ₁₁ | H | H |
| Lₐ₄₈₈₂ | Rₙ₆₉ | Ar97 | H | H | H | H | Rₙ₁₁ | H | H |
| Lₐ₄₈₈₃ | Rₙ₇₀ | Ar97 | H | H | H | H | Rₙ₁₁ | H | H |
| Lₐ₄₈₈₄ | Rₙ₈₁ | Ar97 | H | H | H | H | Rₙ₁₁ | H | H |
| Lₐ₄₈₈₅ | Rₙ₁ | Ar97 | H | H | H | H | Rₙ₅₉ | H | H |
| Lₐ₄₈₈₆ | Rₙ₄ | Ar97 | H | H | H | H | Rₙ₅₉ | H | H |
| Lₐ₄₈₈₇ | Rₙ₅ | Ar97 | H | H | H | H | Rₙ₅₉ | H | H |
| Lₐ₄₈₈₈ | Rₙ₇ | Ar97 | H | H | H | H | Rₙ₅₉ | H | H |
| Lₐ₄₈₈₉ | Rₙ₁₁ | Ar97 | H | H | H | H | Rₙ₅₉ | H | H |
| Lₐ₄₈₉₀ | Rₙ₂₀ | Ar97 | H | H | H | H | Rₙ₅₉ | H | H |
| Lₐ₄₈₉₁ | Rₙ₂₁ | Ar97 | H | H | H | H | Rₙ₅₉ | H | H |
| Lₐ₄₈₉₂ | Rₙ₅₁ | Ar97 | H | H | H | H | Rₙ₅₉ | H | H |
| Lₐ₄₈₉₃ | Rₙ₅₆ | Ar97 | H | H | H | H | Rₙ₅₉ | H | H |
| Lₐ₄₈₉₄ | Rₙ₅₉ | Ar97 | H | H | H | H | Rₙ₅₉ | H | H |
| Lₐ₄₈₉₅ | Rₙ₆₀ | Ar97 | H | H | H | H | Rₙ₅₉ | H | H |
| Lₐ₄₈₉₆ | Rₙ₆₁ | Ar97 | H | H | H | H | Rₙ₅₉ | H | H |
| Lₐ₄₈₉₇ | Rₙ₆₂ | Ar97 | H | H | H | H | Rₙ₅₉ | H | H |
| Lₐ₄₈₉₈ | Rₙ₆₄ | Ar97 | H | H | H | H | Rₙ₅₉ | H | H |
| Lₐ₄₈₉₉ | Rₙ₆₅ | Ar97 | H | H | H | H | Rₙ₅₉ | H | H |
| Lₐ₄₉₀₀ | Rₙ₆₉ | Ar97 | H | H | H | H | Rₙ₅₉ | H | H |
| Lₐ₄₉₀₁ | Rₙ₇₀ | Ar97 | H | H | H | H | Rₙ₅₉ | H | H |
| Lₐ₄₉₀₂ | Rₙ₈₁ | Ar97 | H | H | H | H | Rₙ₅₉ | H | H |
| Lₐ₄₉₀₃ | Rₙ₁ | Ar97 | H | H | H | H | Rₙ₆₀ | H | H |
| Lₐ₄₉₀₄ | Rₙ₄ | Ar97 | H | H | H | H | Rₙ₆₀ | H | H |
| Lₐ₄₉₀₅ | Rₙ₅ | Ar97 | H | H | H | H | Rₙ₆₀ | H | H |
| Lₐ₄₉₀₆ | Rₙ₇ | Ar97 | H | H | H | H | Rₙ₆₀ | H | H |
| Lₐ₄₉₀₇ | Rₙ₁₁ | Ar97 | H | H | H | H | Rₙ₆₀ | H | H |
| Lₐ₄₉₀₈ | Rₙ₂₀ | Ar97 | H | H | H | H | Rₙ₆₀ | H | H |
| Lₐ₄₉₀₉ | Rₙ₂₁ | Ar97 | H | H | H | H | Rₙ₆₀ | H | H |
| Lₐ₄₉₁₀ | Rₙ₅₁ | Ar97 | H | H | H | H | Rₙ₆₀ | H | H |
| Lₐ₄₉₁₁ | Rₙ₅₆ | Ar97 | H | H | H | H | Rₙ₆₀ | H | H |
| Lₐ₄₉₁₂ | Rₙ₅₉ | Ar97 | H | H | H | H | Rₙ₆₀ | H | H |
| Lₐ₄₉₁₃ | Rₙ₆₀ | Ar97 | H | H | H | H | Rₙ₆₀ | H | H |
| Lₐ₄₉₁₄ | Rₙ₆₁ | Ar97 | H | H | H | H | Rₙ₆₀ | H | H |
| Lₐ₄₉₁₅ | Rₙ₆₂ | Ar97 | H | H | H | H | Rₙ₆₀ | H | H |
| Lₐ₄₉₁₆ | Rₙ₆₄ | Ar97 | H | H | H | H | Rₙ₆₀ | H | H |
| Lₐ₄₉₁₇ | Rₙ₆₅ | Ar97 | H | H | H | H | Rₙ₆₀ | H | H |
| Lₐ₄₉₁₈ | Rₙ₆₉ | Ar97 | H | H | H | H | Rₙ₆₀ | H | H |
| Lₐ₄₉₁₉ | Rₙ₇₀ | Ar97 | H | H | H | H | Rₙ₆₀ | H | H |
| Lₐ₄₉₂₀ | Rₙ₈₁ | Ar97 | H | H | H | H | Rₙ₆₀ | H | H |
| Lₐ₄₉₂₁ | Rₙ₁ | Ar97 | H | H | H | H | Rₙ₆₄ | H | H |
| Lₐ₄₉₂₂ | Rₙ₄ | Ar97 | H | H | H | H | Rₙ₆₄ | H | H |
| Lₐ₄₉₂₃ | Rₙ₅ | Ar97 | H | H | H | H | Rₙ₆₄ | H | H |
| Lₐ₄₉₂₄ | Rₙ₇ | Ar97 | H | H | H | H | Rₙ₆₄ | H | H |
| Lₐ₄₉₂₅ | Rₙ₁ | Ar97 | H | H | H | H | Rₙ₆₄ | H | H |
| Lₐ₄₉₂₆ | Rₙ₂₀ | Ar97 | H | H | H | H | Rₙ₆₄ | H | H |
| Lₐ₄₉₂₇ | Rₙ₂₁ | Ar97 | H | H | H | H | Rₙ₆₄ | H | H |
| Lₐ₄₉₂₈ | Rₙ₅₁ | Ar97 | H | H | H | H | Rₙ₆₄ | H | H |
| Lₐ₄₉₂₉ | Rₙ₅₆ | Ar97 | H | H | H | H | Rₙ₆₄ | H | H |
| Lₐ₄₉₃₀ | Rₙ₅₉ | Ar97 | H | H | H | H | Rₙ₆₄ | H | H |
| Lₐ₄₉₃₁ | Rₙ₆₀ | Ar97 | H | H | H | H | Rₙ₆₄ | H | H |
| Lₐ₄₉₃₂ | Rₙ₆₁ | Ar97 | H | H | H | H | Rₙ₆₄ | H | H |
| Lₐ₄₉₃₃ | Rₙ₆₂ | Ar97 | H | H | H | H | Rₙ₆₄ | H | H |
| Lₐ₄₉₃₄ | Rₙ₆₄ | Ar97 | H | H | H | H | Rₙ₆₄ | H | H |
| Lₐ₄₉₃₅ | Rₙ₆₅ | Ar97 | H | H | H | H | Rₙ₆₄ | H | H |
| Lₐ₄₉₃₆ | Rₙ₆₉ | Ar97 | H | H | H | H | Rₙ₆₄ | H | H |
| Lₐ₄₉₃₇ | Rₙ₇₀ | Ar97 | H | H | H | H | Rₙ₆₄ | H | H |
| Lₐ₄₉₃₈ | Rₙ₈₁ | Ar97 | H | H | H | H | Rₙ₆₄ | H | H |
| Lₐ₄₉₃₉ | Rₙ₁ | Ar97 | H | H | H | H | Me | H | H |
| Lₐ₄₉₄₀ | Rₙ₄ | Ar97 | H | H | H | H | Me | H | H |
| Lₐ₄₉₄₁ | Rₙ₅ | Ar97 | H | H | H | H | Me | H | H |
| Lₐ₄₉₄₂ | Rₙ₇ | Ar97 | H | H | H | H | Me | H | H |
| Lₐ₄₉₄₃ | Rₙ₁₁ | Ar97 | H | H | H | H | Me | H | H |
| Lₐ₄₉₄₄ | Rₙ₂₀ | Ar97 | H | H | H | H | Me | H | H |
| Lₐ₄₉₄₅ | Rₙ₂₁ | Ar97 | H | H | H | H | Me | H | H |
| Lₐ₄₉₄₆ | Rₙ₅₁ | Ar97 | H | H | H | H | Me | H | H |
| Lₐ₄₉₄₇ | Rₙ₅₆ | Ar97 | H | H | H | H | Me | H | H |
| Lₐ₄₉₄₈ | Rₙ₅₉ | Ar97 | H | H | H | H | Me | H | H |
| Lₐ₄₉₄₉ | Rₙ₆₀ | Ar97 | H | H | H | H | Me | H | H |
| Lₐ₄₉₅₀ | Rₙ₆₁ | Ar97 | H | H | H | H | Me | H | H |
| Lₐ₄₉₅₁ | Rₙ₆₂ | Ar97 | H | H | H | H | Me | H | H |
| Lₐ₄₉₅₂ | Rₙ₆₄ | Ar97 | H | H | H | H | Me | H | H |
| Lₐ₄₉₅₃ | Rₙ₆₅ | Ar97 | H | H | H | H | Me | H | H |
| Lₐ₄₉₅₄ | Rₙ₆₉ | Ar97 | H | H | H | H | Me | H | H |
| Lₐ₄₉₅₅ | Rₙ₇₀ | Ar97 | H | H | H | H | Me | H | H |
| Lₐ₄₉₅₆ | Rₙ₈₁ | Ar97 | H | H | H | H | Me | H | H |
| Lₐ₄₉₅₇ | Rₙ₁ | Ar97 | H | H | F | H | H | H | H |
| Lₐ₄₉₅₈ | Rₙ₄ | Ar97 | H | H | F | H | H | H | H |
| Lₐ₄₉₅₉ | Rₙ₇ | Ar97 | H | H | F | H | H | H | H |
| Lₐ₄₉₆₀ | Rₙ₂₀ | Ar97 | H | H | F | H | H | H | H |
| Lₐ₄₉₆₁ | Rₙ₂₁ | Ar97 | D | H | F | H | H | H | H |
| Lₐ₄₉₆₂ | Rₙ₅₆ | Ar97 | H | H | F | H | H | H | H |
| Lₐ₄₉₆₃ | Rₙ₅₉ | Ar97 | H | H | F | H | H | H | H |
| Lₐ₄₉₆₄ | Rₙ₆₁ | Ar97 | H | H | F | H | H | H | H |
| Lₐ₄₉₆₅ | Rₙ₆₂ | Ar97 | H | H | F | H | H | H | H |
| Lₐ₄₉₆₆ | Rₙ₆₄ | Ar97 | H | H | F | H | H | H | H |
| Lₐ₄₉₆₇ | Rₙ₆₉ | Ar97 | H | H | F | H | H | H | H |
| Lₐ₄₉₆₈ | Rₙ₇₀ | Ar97 | H | H | F | H | H | H | H |
| Lₐ₄₉₆₉ | Rₙ₁ | Ar97 | H | H | F | H | Rₙ₁₁ | H | H |
| Lₐ₄₉₇₀ | Rₙ₄ | Ar97 | H | H | F | H | Rₙ₁₁ | H | H |
| Lₐ₄₉₇₁ | Rₙ₇ | Ar97 | H | H | F | H | Rₙ₁₁ | H | H |
| Lₐ₄₉₇₂ | Rₙ₂₀ | Ar97 | H | H | F | H | Rₙ₁₁ | H | H |
| Lₐ₄₉₇₃ | Rₙ₂₁ | Ar97 | H | H | F | H | Rₙ₁₁ | H | H |
| Lₐ₄₉₇₄ | Rₙ₅₆ | Ar97 | H | H | F | H | Rₙ₁₁ | H | H |
| Lₐ₄₉₇₅ | Rₙ₅₉ | Ar97 | H | H | F | H | Rₙ₁₁ | H | H |
| Lₐ₄₉₇₆ | Rₙ₆₁ | Ar97 | H | H | F | H | Rₙ₁₁ | H | H |
| Lₐ₄₉₇₇ | Rₙ₆₂ | Ar97 | H | H | F | H | Rₙ₁₁ | D | H |
| Lₐ₄₉₇₈ | Rₙ₆₄ | Ar97 | H | H | F | H | Rₙ₁₁ | H | H |
| Lₐ₄₉₇₉ | Rₙ₆₉ | Ar97 | H | H | F | H | Rₙ₁₁ | H | H |
| Lₐ₄₉₈₀ | Rₙ₇₀ | Ar97 | H | H | F | H | Rₙ₁₁ | H | H |
| Lₐ₄₉₈₁ | Rₙ₁ | Ar97 | H | H | F | H | Rₙ₆₀ | H | H |
| Lₐ₄₉₈₂ | Rₙ₄ | Ar97 | H | H | F | H | Rₙ₆₀ | H | H |
| Lₐ₄₉₈₃ | Rₙ₇ | Ar97 | H | H | F | H | Rₙ₆₀ | H | H |
| Lₐ₄₉₈₄ | Rₙ₂₀ | Ar97 | H | H | F | H | Rₙ₆₀ | H | D |
| Lₐ₄₉₈₅ | Rₙ₂₁ | Ar97 | H | H | F | H | Rₙ₆₀ | H | H |
| Lₐ₄₉₈₆ | Rₙ₅₆ | Ar97 | H | H | F | H | Rₙ₆₀ | H | H |
| Lₐ₄₉₈₇ | Rₙ₅₉ | Ar97 | H | H | F | H | Rₙ₆₀ | H | H |
| Lₐ₄₉₈₈ | Rₙ₆₁ | Ar97 | H | H | F | H | Rₙ₆₀ | H | H |
| Lₐ₄₉₈₉ | Rₙ₆₂ | Ar97 | H | H | F | H | Rₙ₆₀ | H | H |
| Lₐ₄₉₉₀ | Rₙ₆₄ | Ar97 | H | H | F | H | Rₙ₆₀ | H | H |
| Lₐ₄₉₉₁ | Rₙ₆₉ | Ar97 | H | H | F | H | Rₙ₆₀ | H | H |
| Lₐ₄₉₉₂ | Rₙ₇₀ | Ar97 | H | H | F | H | Rₙ₆₀ | H | H |
| Lₐ₄₉₉₃ | Rₙ₁ | Ar97 | H | H | F | H | H | Rₙ₁₁ | H |
| Lₐ₄₉₉₄ | Rₙ₄ | Ar97 | H | H | F | H | H | Rₙ₁₁ | H |
| Lₐ₄₉₉₅ | Rₙ₇ | Ar97 | H | H | F | H | H | Rₙ₁₁ | H |
| Lₐ₄₉₉₆ | Rₙ₂₀ | Ar97 | H | H | F | H | H | Rₙ₁₁ | H |
| Lₐ₄₉₉₇ | Rₙ₂₁ | Ar97 | H | H | F | H | H | Rₙ₁₁ | H |
| Lₐ₄₉₉₈ | Rₙ₅₆ | Ar97 | H | H | F | H | H | Rₙ₁₁ | H |
| Lₐ₄₉₉₉ | Rₙ₅₉ | Ar97 | H | H | F | H | H | Rₙ₁₁ | H |
| Lₐ₅₀₀₀ | Rₙ₆₁ | Ar97 | H | H | F | H | H | Rₙ₁₁ | H |
| Lₐ₅₀₀₁ | Rₙ₆₂ | Ar97 | H | H | F | H | H | Rₙ₁₁ | H |
| Lₐ₅₀₀₂ | Rₙ₆₄ | Ar97 | H | H | F | H | H | Rₙ₁₁ | H |
| Lₐ₅₀₀₃ | Rₙ₆₉ | Ar97 | H | H | F | H | H | Rₙ₁₁ | H |
| Lₐ₅₀₀₄ | Rₙ₇₀ | Ar97 | H | H | F | H | H | Rₙ₁₁ | H |
| Lₐ₅₀₀₅ | Rₙ₁ | Ar97 | H | H | F | H | H | Rₙ₆₀ | H |
| Lₐ₅₀₀₆ | Rₙ₄ | Ar97 | H | H | F | H | H | Rₙ₆₀ | H |
| Lₐ₅₀₀₇ | Rₙ₇ | Ar97 | H | H | F | H | H | Rₙ₆₀ | H |
| Lₐ₅₀₀₈ | Rₙ₂₀ | Ar97 | H | H | F | H | H | Rₙ₆₀ | H |
| Lₐ₅₀₀₉ | Rₙ₂₁ | Ar97 | H | H | F | H | H | Rₙ₆₀ | H |
| Lₐ₅₀₁₀ | Rₙ₅₆ | Ar97 | H | H | F | H | H | Rₙ₆₀ | H |
| Lₐ₅₀₁₁ | Rₙ₅₉ | Ar97 | H | H | F | H | H | Rₙ₆₀ | H |
| Lₐ₅₀₁₂ | Rₙ₆₁ | Ar97 | H | H | F | H | H | Rₙ₆₀ | H |
| Lₐ₅₀₁₃ | Rₙ₆₂ | Ar97 | H | H | F | H | H | Rₙ₆₀ | H |
| Lₐ₅₀₁₄ | Rₙ₆₄ | Ar97 | H | H | F | H | H | Rₙ₆₀ | H |
| Lₐ₅₀₁₅ | Rₙ₆₉ | Ar97 | H | H | F | H | H | Rₙ₆₀ | H |
| Lₐ₅₀₁₆ | Rₙ₇₀ | Ar97 | H | H | F | H | H | Rₙ₆₀ | H |
| Lₐ₅₀₁₇ | Rₙ₁ | Ar97 | H | H | CN | H | H | H | H |
| Lₐ₅₀₁₈ | Rₙ₄ | Ar97 | D | H | CN | H | H | H | H |
| Lₐ₅₀₁₉ | Rₙ₇ | Ar97 | H | H | CN | H | H | H | H |
| Lₐ₅₀₂₀ | Rₙ₂₀ | Ar97 | H | H | CN | H | H | H | H |
| Lₐ₅₀₂₁ | Rₙ₂₁ | Ar97 | H | H | CN | H | H | H | H |
| Lₐ₅₀₂₂ | Rₙ₅₆ | Ar97 | H | D | CN | H | H | H | H |
| Lₐ₅₀₂₃ | Rₙ₅₉ | Ar97 | H | H | CN | H | H | H | H |
| Lₐ₅₀₂₄ | Rₙ₆₁ | Ar97 | H | H | CN | H | H | H | H |
| Lₐ₅₀₂₅ | Rₙ₆₂ | Ar97 | H | H | CN | H | H | H | H |
| Lₐ₅₀₂₆ | Rₙ₆₄ | Ar97 | H | H | CN | H | H | H | D |
| Lₐ₅₀₂₇ | Rₙ₆₉ | Ar97 | H | H | CN | H | H | H | H |
| Lₐ₅₀₂₈ | Rₙ₇₀ | Ar97 | H | H | CN | H | H | H | H |
| Lₐ₅₀₂₉ | Rₙ₁ | Ar97 | H | CN | H | H | H | H | H |
| Lₐ₅₀₃₀ | Rₙ₄ | Ar97 | H | CN | H | H | H | H | H |
| Lₐ₅₀₃₁ | Rₙ₇ | Ar97 | H | CN | H | H | H | H | H |
| Lₐ₅₀₃₂ | Rₙ₂₀ | Ar97 | H | CN | H | H | H | H | H |
| Lₐ₅₀₃₃ | Rₙ₂₁ | Ar97 | H | CN | H | H | H | H | H |
| Lₐ₅₀₃₄ | Rₙ₅₆ | Ar97 | H | CN | H | H | H | H | H |
| Lₐ₅₀₃₅ | Rₙ₅₉ | Ar97 | H | CN | H | H | H | H | H |
| Lₐ₅₀₃₆ | Rₙ₆₁ | Ar97 | H | CN | H | H | H | H | H |
| Lₐ₅₀₃₇ | Rₙ₆₂ | Ar97 | H | CN | H | H | H | H | H |
| Lₐ₅₀₃₈ | Rₙ₆₄ | Ar97 | H | CN | H | H | H | H | H |
| Lₐ₅₀₃₉ | Rₙ₆₉ | Ar97 | H | CN | H | H | H | H | H |
| Lₐ₅₀₄₀ | Rₙ₇₀ | Ar97 | H | CN | H | H | H | H | H |
| Lₐ₅₀₄₁ | Rₙ₁ | Ar97 | CN | H | H | H | H | H | H |
| Lₐ₅₀₄₂ | Rₙ₄ | Ar97 | CN | H | H | H | H | H | H |
| Lₐ₅₀₄₃ | Rₙ₇ | Ar97 | CN | H | H | H | H | H | H |
| Lₐ₅₀₄₄ | Rₙ₂₀ | Ar97 | CN | H | H | H | H | H | H |
| Lₐ₅₀₄₅ | Rₙ₂₁ | Ar97 | CN | H | H | H | H | H | H |
| Lₐ₅₀₄₆ | Rₙ₅₆ | Ar97 | CN | H | H | H | H | H | H |
| Lₐ₅₀₄₇ | Rₙ₅₉ | Ar97 | CN | H | H | H | H | H | H |
| Lₐ₅₀₄₈ | Rₙ₆₁ | Ar97 | CN | H | H | H | H | H | H |
| Lₐ₅₀₄₉ | Rₙ₆₂ | Ar97 | CN | H | H | H | H | H | H |
| Lₐ₅₀₅₀ | Rₙ₆₄ | Ar97 | CN | H | H | H | H | H | H |
| Lₐ₅₀₅₁ | Rₙ₆₉ | Ar97 | CN | H | H | H | H | H | H |
| Lₐ₅₀₅₂ | Rₙ₇₀ | Ar97 | CN | H | H | H | H | H | H |
| Lₐ₅₀₅₃ | Rₙ₁ | Ar97 | D | H | CN | H | Rₙ₁₁ | H | H |
| Lₐ₅₀₅₄ | Rₙ₄ | Ar97 | H | H | CN | H | Rₙ₁₁ | H | H |
| Lₐ₅₀₅₅ | Rₙ₇ | Ar97 | H | H | CN | H | Rₙ₁₁ | H | H |
| Lₐ₅₀₅₆ | Rₙ₂₀ | Ar97 | H | H | CN | H | Rₙ₁₁ | H | H |
| Lₐ₅₀₅₇ | Rₙ₂₁ | Ar97 | H | D | CN | H | Rₙ₁₁ | H | H |
| Lₐ₅₀₅₈ | Rₙ₅₆ | Ar97 | H | H | CN | H | Rₙ₁₁ | H | H |
| Lₐ₅₀₅₉ | Rₙ₅₉ | Ar97 | H | H | CN | H | Rₙ₁₁ | H | H |
| Lₐ₅₀₆₀ | Rₙ₆₁ | Ar97 | H | H | CN | H | Rₙ₁₁ | H | H |
| Lₐ₅₀₆₁ | Rₙ₆₂ | Ar97 | H | H | CN | H | Rₙ₁₁ | H | H |
| Lₐ₅₀₆₂ | Rₙ₆₄ | Ar97 | H | H | CN | H | Rₙ₁₁ | H | H |
| Lₐ₅₀₆₃ | Rₙ₆₉ | Ar97 | H | H | CN | H | Rₙ₁₁ | H | H |
| Lₐ₅₀₆₄ | Rₙ₇₀ | Ar97 | H | H | CN | H | Rₙ₁₁ | H | H |
| Lₐ₅₀₆₅ | Rₙ₁ | Ar97 | H | H | CN | H | Rₙ₆₀ | H | H |
| Lₐ₅₀₆₆ | Rₙ₄ | Ar97 | H | H | CN | H | Rₙ₆₀ | H | H |
| Lₐ₅₀₆₇ | Rₙ₇ | Ar97 | H | H | CN | H | Rₙ₆₀ | H | H |
| Lₐ₅₀₆₈ | Rₙ₂₀ | Ar97 | H | H | CN | H | Rₙ₆₀ | H | H |
| Lₐ₅₀₆₉ | Rₙ₂₁ | Ar97 | H | H | CN | H | Rₙ₆₀ | D | H |
| Lₐ₅₀₇₀ | Rₙ₅₆ | Ar97 | H | H | CN | H | Rₙ₆₀ | H | H |
| Lₐ₅₀₇₁ | Rₙ₅₉ | Ar97 | H | H | CN | H | Rₙ₆₀ | H | H |
| Lₐ₅₀₇₂ | Rₙ₆₁ | Ar97 | H | H | CN | H | Rₙ₆₀ | H | H |
| Lₐ₅₀₇₃ | Rₙ₆₂ | Ar97 | H | H | CN | H | Rₙ₆₀ | H | D |
| Lₐ₅₀₇₄ | Rₙ₆₄ | Ar97 | H | H | CN | H | Rₙ₆₀ | H | H |
| Lₐ₅₀₇₅ | Rₙ₆₉ | Ar97 | H | H | CN | H | Rₙ₆₀ | H | H |
| Lₐ₅₀₇₆ | Rₙ₇₀ | Ar97 | H | H | CN | H | Rₙ₆₀ | H | H |
| Lₐ₅₀₇₇ | Rₙ₁ | Ar97 | H | H | CN | H | Rₙ₆₄ | H | H |
| Lₐ₅₀₇₈ | Rₙ₄ | Ar97 | H | H | CN | H | Rₙ₆₄ | H | H |
| Lₐ₅₀₇₉ | Rₙ₇ | Ar97 | H | H | CN | H | Rₙ₆₄ | H | H |
| Lₐ₅₀₈₀ | Rₙ₂₀ | Ar97 | H | H | CN | H | Rₙ₆₄ | H | H |
| Lₐ₅₀₈₁ | Rₙ₂₁ | Ar97 | H | H | CN | H | Rₙ₆₄ | H | H |
| Lₐ₅₀₈₂ | Rₙ₅₆ | Ar97 | H | H | CN | H | Rₙ₆₄ | H | H |
| Lₐ₅₀₈₃ | Rₙ₅₉ | Ar97 | H | H | CN | H | Rₙ₆₄ | H | H |
| Lₐ₅₀₈₄ | Rₙ₆₁ | Ar97 | H | H | CN | H | Rₙ₆₄ | H | H |
| Lₐ₅₀₈₅ | Rₙ₆₂ | Ar97 | H | H | CN | H | Rₙ₆₄ | H | H |
| Lₐ₅₀₈₆ | Rₙ₆₄ | Ar97 | H | H | CN | H | Rₙ₆₄ | H | H |
| Lₐ₅₀₈₇ | Rₙ₆₉ | Ar97 | H | H | CN | H | Rₙ₆₄ | H | H |
| Lₐ₅₀₈₈ | Rₙ₇₀ | Ar97 | H | H | CN | H | Rₙ₆₄ | H | H |
| Lₐ₅₀₈₉ | Rₙ₁ | Ar97 | H | H | CN | H | H | Rₙ₁₁ | H |
| Lₐ₅₀₉₀ | Rₙ₄ | Ar97 | H | H | CN | H | H | Rₙ₁₁ | H |
| Lₐ₅₀₉₁ | Rₙ₇ | Ar97 | H | H | CN | H | H | Rₙ₁₁ | H |
| Lₐ₅₀₉₂ | Rₙ₂₀ | Ar97 | H | H | CN | H | H | Rₙ₁₁ | H |
| Lₐ₅₀₉₃ | Rₙ₂₁ | Ar97 | H | H | CN | H | H | Rₙ₁₁ | H |
| Lₐ₅₀₉₄ | Rₙ₅₆ | Ar97 | H | H | CN | H | H | Rₙ₁₁ | H |
| Lₐ₅₀₉₅ | Rₙ₅₉ | Ar97 | H | H | CN | H | H | Rₙ₁₁ | H |
| Lₐ₅₀₉₆ | Rₙ₆₁ | Ar97 | H | H | CN | H | H | Rₙ₁₁ | H |
| Lₐ₅₀₉₇ | Rₙ₆₂ | Ar97 | H | H | CN | H | H | Rₙ₁₁ | H |
| Lₐ₅₀₉₈ | Rₙ₆₄ | Ar97 | H | H | CN | H | H | Rₙ₁₁ | H |
| Lₐ₅₀₉₉ | Rₙ₆₉ | Ar97 | H | H | CN | H | H | Rₙ₁₁ | H |
| Lₐ₅₁₀₀ | Rₙ₇₀ | Ar97 | H | H | CN | H | H | Rₙ₁₁ | H |
| Lₐ₅₁₀₁ | Rₙ₁ | Ar97 | H | H | CN | H | H | Rₙ₆₀ | H |
| Lₐ₅₁₀₂ | Rₙ₄ | Ar97 | H | H | CN | H | H | Rₙ₆₀ | H |
| Lₐ₅₁₀₃ | Rₙ₇ | Ar97 | H | H | CN | H | H | Rₙ₆₀ | H |
| Lₐ₅₁₀₄ | Rₙ₂₀ | Ar97 | H | H | CN | H | H | Rₙ₆₀ | H |
| Lₐ₅₁₀₅ | Rₙ₂₁ | Ar97 | H | H | CN | H | H | Rₙ₆₀ | H |
| Lₐ₅₁₀₆ | Rₙ₅₆ | Ar97 | H | H | CN | H | H | Rₙ₆₀ | H |
| Lₐ₅₁₀₇ | Rₙ₅₉ | Ar97 | H | H | CN | H | H | Rₙ₆₀ | H |
| Lₐ₅₁₀₈ | Rₙ₆₁ | Ar97 | H | H | CN | H | H | Rₙ₆₀ | H |
| Lₐ₅₁₀₉ | Rₙ₆₂ | Ar97 | H | H | CN | H | H | Rₙ₆₀ | H |
| Lₐ₅₁₁₀ | Rₙ₆₄ | Ar97 | H | H | CN | H | H | Rₙ₆₀ | H |
| Lₐ₅₁₁₁ | Rₙ₆₉ | Ar97 | H | H | CN | H | H | Rₙ₆₀ | H |
| Lₐ₅₁₁₂ | Rₙ₇₀ | Ar97 | H | H | CN | H | H | Rₙ₆₀ | H |
| Lₐ₅₁₁₃ | Rₙ₁ | Ar97 | H | H | CN | H | H | Rₙ₆₄ | H |
| Lₐ₅₁₁₄ | Rₙ₄ | Ar97 | H | H | CN | H | H | Rₙ₆₄ | H |
| Lₐ₅₁₁₅ | Rₙ₇ | Ar97 | H | H | CN | H | H | Rₙ₆₄ | H |
| Lₐ₅₁₁₆ | Rₙ₂₀ | Ar97 | H | H | CN | H | H | Rₙ₆₄ | H |
| Lₐ₅₁₁₇ | Rₙ₂₁ | Ar97 | H | H | CN | H | H | Rₙ₆₄ | H |
| Lₐ₅₁₁₈ | Rₙ₅₆ | Ar97 | H | H | CN | H | H | Rₙ₆₄ | H |
| Lₐ₅₁₁₉ | Rₙ₅₉ | Ar97 | H | H | CN | H | H | Rₙ₆₄ | H |
| Lₐ₅₁₂₀ | Rₙ₆₁ | Ar97 | H | H | CN | H | H | Rₙ₆₄ | H |
| Lₐ₅₁₂₁ | Rₙ₆₂ | Ar97 | H | H | CN | H | H | Rₙ₆₄ | H |
| Lₐ₅₁₂₂ | Rₙ₆₄ | Ar97 | H | H | CN | H | H | Rₙ₆₄ | H |
| Lₐ₅₁₂₃ | Rₙ₆₉ | Ar97 | H | H | CN | H | H | Rₙ₆₄ | H |
| Lₐ₅₁₂₄ | Rₙ₇₀ | Ar97 | H | H | CN | H | H | Rₙ₆₄ | H |
| Lₐ₅₁₂₅ | Rₙ₁ | Ar115 | H | H | H | H | H | H | H |
| Lₐ₅₁₂₆ | Rₙ₄ | Ar115 | H | H | H | H | H | H | H |
| Lₐ₅₁₂₇ | Rₙ₅ | Ar115 | H | H | H | H | H | H | H |
| Lₐ₅₁₂₈ | Rₙ₇ | Ar115 | H | H | H | H | H | H | H |
| Lₐ₅₁₂₉ | Rₙ₁₁ | Ar115 | H | H | H | H | H | H | H |
| Lₐ₅₁₃₀ | Rₙ₂₀ | Ar115 | D | H | H | H | H | H | H |
| Lₐ₅₁₃₁ | Rₙ₂₁ | Ar115 | H | H | H | H | H | H | H |
| Lₐ₅₁₃₂ | Rₙ₅₁ | Ar115 | H | H | H | H | H | H | H |
| Lₐ₅₁₃₃ | Rₙ₅₆ | Ar115 | H | H | H | H | H | H | H |
| Lₐ₅₁₃₄ | Rₙ₅₉ | Ar115 | H | H | H | H | H | H | H |
| Lₐ₅₁₃₅ | Rₙ₆₀ | Ar115 | H | H | H | H | H | H | H |
| Lₐ₅₁₃₆ | Rₙ₆₁ | Ar115 | H | H | H | H | H | H | H |
| Lₐ₅₁₃₇ | Rₙ₆₂ | Ar115 | H | H | H | H | H | H | H |
| Lₐ₅₁₃₈ | Rₙ₆₄ | Ar115 | H | H | H | H | H | H | H |
| Lₐ₅₁₃₉ | Rₙ₆₅ | Ar115 | H | H | H | H | H | H | H |
| Lₐ₅₁₄₀ | Rₙ₆₉ | Ar115 | H | H | H | H | H | H | H |
| Lₐ₅₁₄₁ | Rₙ₇₀ | Ar115 | H | H | H | H | H | H | H |
| Lₐ₅₁₄₂ | Rₙ₈₁ | Ar115 | H | H | H | H | H | H | H |
| Lₐ₅₁₄₃ | Rₙ₁ | Ar115 | H | H | H | H | H | Rₙ₁₁ | H |
| Lₐ₅₁₄₄ | Rₙ₄ | Ar115 | H | H | H | H | H | Rₙ₁₁ | H |
| Lₐ₅₁₄₅ | Rₙ₅ | Ar115 | H | H | H | H | H | Rₙ₁₁ | H |
| Lₐ₅₁₄₆ | Rₙ₇ | Ar115 | H | H | H | H | H | Rₙ₁₁ | H |
| Lₐ₅₁₄₇ | Rₙ₁₁ | Ar115 | H | H | H | H | H | Rₙ₁₁ | H |
| Lₐ₅₁₄₈ | Rₙ₂₀ | Ar115 | H | H | H | H | H | Rₙ₁₁ | H |
| Lₐ₅₁₄₉ | Rₙ₂₁ | Ar115 | H | H | H | H | H | Rₙ₁₁ | H |
| Lₐ₅₁₅₀ | Rₙ₅₁ | Ar115 | H | H | H | H | H | Rₙ₁₁ | H |
| Lₐ₅₁₅₁ | Rₙ₅₆ | Ar115 | H | H | H | H | H | Rₙ₁₁ | H |
| Lₐ₅₁₅₂ | Rₙ₅₉ | Ar115 | H | H | H | H | H | Rₙ₁₁ | H |
| Lₐ₅₁₅₃ | Rₙ₆₀ | Ar115 | H | H | H | H | H | Rₙ₁₁ | H |
| Lₐ₅₁₅₄ | Rₙ₆₁ | Ar115 | H | H | H | H | H | Rₙ₁₁ | H |
| Lₐ₅₁₅₅ | Rₙ₆₂ | Ar115 | H | H | H | H | H | Rₙ₁₁ | H |
| Lₐ₅₁₅₆ | Rₙ₆₄ | Ar115 | H | H | H | H | H | Rₙ₁₁ | H |
| Lₐ₅₁₅₇ | Rₙ₆₅ | Ar115 | H | H | H | H | H | Rₙ₁₁ | H |
| Lₐ₅₁₅₈ | Rₙ₆₉ | Ar115 | H | H | H | H | H | Rₙ₁₁ | H |
| Lₐ₅₁₅₉ | Rₙ₇₀ | Ar115 | H | H | H | H | H | Rₙ₁₁ | H |
| Lₐ₅₁₆₀ | Rₙ₈₁ | Ar115 | H | H | H | H | H | Rₙ₁₁ | H |
| Lₐ₅₁₆₁ | Rₙ₁ | Ar115 | H | H | H | H | H | Rₙ₅₉ | H |
| Lₐ₅₁₆₂ | Rₙ₄ | Ar115 | H | H | H | H | H | Rₙ₅₉ | H |
| Lₐ₅₁₆₃ | Rₙ₅ | Ar115 | H | H | H | H | H | Rₙ₅₉ | H |
| Lₐ₅₁₆₄ | Rₙ₇ | Ar115 | H | H | H | H | H | Rₙ₅₉ | H |
| Lₐ₅₁₆₅ | Rₙ₁₁ | Ar115 | H | H | H | H | H | Rₙ₅₉ | H |
| Lₐ₅₁₆₆ | Rₙ₂₀ | Ar115 | H | H | H | H | H | Rₙ₅₉ | H |
| Lₐ₅₁₆₇ | Rₙ₂₁ | Ar115 | H | H | H | H | H | Rₙ₅₉ | H |
| Lₐ₅₁₆₈ | Rₙ₅₁ | Ar115 | H | H | H | H | H | Rₙ₅₉ | H |
| Lₐ₅₁₆₉ | Rₙ₅₆ | Ar115 | H | H | H | H | H | Rₙ₅₉ | H |
| Lₐ₅₁₇₀ | Rₙ₅₉ | Ar115 | H | H | H | H | H | Rₙ₅₉ | H |
| Lₐ₅₁₇₁ | Rₙ₆₀ | Ar115 | H | H | H | H | H | Rₙ₅₉ | H |
| Lₐ₅₁₇₂ | Rₙ₆₁ | Ar115 | H | H | H | H | H | Rₙ₅₉ | H |
| Lₐ₅₁₇₃ | Rₙ₆₂ | Ar115 | H | H | H | H | H | Rₙ₅₉ | H |
| Lₐ₅₁₇₄ | Rₙ₆₄ | Ar115 | H | H | H | H | H | Rₙ₅₉ | H |
| Lₐ₅₁₇₅ | Rₙ₆₅ | Ar115 | H | H | H | H | H | Rₙ₅₉ | H |
| Lₐ₅₁₇₆ | Rₙ₆₉ | Ar115 | H | H | H | H | H | Rₙ₅₉ | H |
| Lₐ₅₁₇₇ | Rₙ₇₀ | Ar115 | H | H | H | H | H | Rₙ₅₉ | H |
| Lₐ₅₁₇₈ | Rₙ₈₁ | Ar115 | H | H | H | H | H | Rₙ₅₉ | H |
| Lₐ₅₁₇₉ | Rₙ₁ | Ar115 | H | H | H | H | H | Rₙ₆₀ | H |
| Lₐ₅₁₈₀ | Rₙ₄ | Ar115 | H | H | H | H | H | Rₙ₆₀ | H |
| Lₐ₅₁₈₁ | Rₙ₅ | Ar115 | H | H | H | H | H | Rₙ₆₀ | H |
| Lₐ₅₁₈₂ | Rₙ₇ | Ar115 | H | H | H | H | H | Rₙ₆₀ | H |
| Lₐ₅₁₈₃ | Rₙ₁₁ | Ar115 | H | H | H | H | H | Rₙ₆₀ | H |
| Lₐ₅₁₈₄ | Rₙ₂₀ | Ar115 | H | H | H | H | H | Rₙ₆₀ | H |
| Lₐ₅₁₈₅ | Rₙ₂₁ | Ar115 | H | H | H | H | H | Rₙ₆₀ | H |
| Lₐ₅₁₈₆ | Rₙ₅₁ | Ar115 | H | H | H | H | H | Rₙ₆₀ | H |
| Lₐ₅₁₈₇ | Rₙ₅₆ | Ar115 | H | H | H | H | H | Rₙ₆₀ | H |
| Lₐ₅₁₈₈ | Rₙ₅₉ | Ar115 | H | H | H | H | H | Rₙ₆₀ | H |
| Lₐ₅₁₈₉ | Rₙ₆₀ | Ar115 | H | H | H | H | H | Rₙ₆₀ | H |
| Lₐ₅₁₉₀ | Rₙ₆₁ | Ar115 | H | H | H | H | H | Rₙ₆₀ | H |
| Lₐ₅₁₉₁ | Rₙ₆₂ | Ar115 | H | H | H | H | H | Rₙ₆₀ | H |
| Lₐ₅₁₉₂ | Rₙ₆₄ | Ar115 | H | H | H | H | H | Rₙ₆₀ | H |
| Lₐ₅₁₉₃ | Rₙ₆₅ | Ar115 | H | H | H | H | H | Rₙ₆₀ | H |
| Lₐ₅₁₉₄ | Rₙ₆₉ | Ar115 | H | H | H | H | H | Rₙ₆₀ | H |
| Lₐ₅₁₉₅ | Rₙ₇₀ | Ar115 | H | H | H | H | H | Rₙ₆₀ | H |
| Lₐ₅₁₉₆ | Rₙ₈₁ | Ar115 | H | H | H | H | H | Rₙ₆₀ | H |
| Lₐ₅₁₉₇ | Rₙ₁ | Ar115 | H | H | H | H | H | Rₙ₆₄ | H |
| Lₐ₅₁₉₈ | Rₙ₄ | Ar115 | H | H | H | H | H | Rₙ₆₄ | H |
| Lₐ₅₁₉₉ | Rₙ₅ | Ar115 | H | H | H | H | H | Rₙ₆₄ | H |
| Lₐ₅₂₀₀ | Rₙ₇ | Ar115 | H | H | H | H | H | Rₙ₆₄ | H |
| Lₐ₅₂₀₁ | Rₙ₁₁ | Ar115 | H | H | H | H | H | Rₙ₆₄ | H |
| Lₐ₅₂₀₂ | Rₙ₂₀ | Ar115 | H | H | H | H | H | Rₙ₆₄ | H |
| Lₐ₅₂₀₃ | Rₙ₂₁ | Ar115 | H | H | H | H | H | Rₙ₆₄ | H |
| Lₐ₅₂₀₄ | Rₙ₅₁ | Ar115 | H | H | H | H | H | Rₙ₆₄ | H |
| Lₐ₅₂₀₅ | Rₙ₅₆ | Ar115 | H | H | H | H | H | Rₙ₆₄ | H |
| Lₐ₅₂₀₆ | Rₙ₅₉ | Ar115 | H | H | H | H | H | Rₙ₆₄ | H |
| Lₐ₅₂₀₇ | Rₙ₆₀ | Ar115 | H | H | H | H | H | Rₙ₆₄ | H |
| Lₐ₅₂₀₈ | Rₙ₆₁ | Ar115 | H | H | H | H | H | Rₙ₆₄ | H |
| Lₐ₅₂₀₉ | Rₙ₆₂ | Ar115 | H | H | H | H | H | Rₙ₆₄ | H |
| Lₐ₅₂₁₀ | Rₙ₆₄ | Ar115 | H | H | H | H | H | Rₙ₆₄ | H |
| Lₐ₅₂₁₁ | Rₙ₆₅ | Ar115 | H | H | H | H | H | Rₙ₆₄ | H |
| Lₐ₅₂₁₂ | Rₙ₆₉ | Ar115 | H | H | H | H | H | Rₙ₆₄ | H |
| Lₐ₅₂₁₃ | Rₙ₇₀ | Ar115 | H | H | H | H | H | Rₙ₆₄ | H |
| Lₐ₅₂₁₄ | Rₙ₈₁ | Ar115 | H | H | H | H | H | Rₙ₆₄ | H |
| Lₐ₅₂₁₅ | Rₙ₁ | Ar115 | H | H | H | H | H | Me | H |
| Lₐ₅₂₁₆ | Rₙ₄ | Ar115 | H | H | H | H | H | Me | H |
| Lₐ₅₂₁₇ | Rₙ₅ | Ar115 | H | H | H | H | H | Me | H |
| Lₐ₅₂₁₈ | Rₙ₇ | Ar115 | H | H | H | H | H | Me | H |
| Lₐ₅₂₁₉ | Rₙ₁₁ | Ar115 | H | H | H | H | H | Me | H |
| Lₐ₅₂₂₀ | Rₙ₂₀ | Ar115 | H | H | H | H | H | Me | H |
| Lₐ₅₂₂₁ | Rₙ₂₁ | Ar115 | H | H | H | H | H | Me | H |
| Lₐ₅₂₂₂ | Rₙ₅₁ | Ar115 | H | H | H | H | H | Me | H |
| Lₐ₅₂₂₃ | Rₙ₅₆ | Ar115 | H | H | H | H | H | Me | H |
| Lₐ₅₂₂₄ | Rₙ₅₉ | Ar115 | H | H | H | H | H | Me | H |
| Lₐ₅₂₂₅ | Rₙ₆₀ | Ar115 | H | H | H | H | H | Me | H |
| Lₐ₅₂₂₆ | Rₙ₆₁ | Ar115 | H | H | H | H | H | Me | H |
| Lₐ₅₂₂₇ | Rₙ₆₂ | Ar115 | H | H | H | H | H | Me | H |
| Lₐ₅₂₂₈ | Rₙ₆₄ | Ar115 | H | H | H | H | H | Me | H |
| Lₐ₅₂₂₉ | Rₙ₆₅ | Ar115 | H | H | H | H | H | Me | H |
| Lₐ₅₂₃₀ | Rₙ₆₉ | Ar115 | H | H | H | H | H | Me | H |
| Lₐ₅₂₃₁ | Rₙ₇₀ | Ar115 | H | H | H | H | H | Me | H |
| Lₐ₅₂₃₂ | Rₙ₈₁ | Ar115 | H | H | H | H | H | Me | H |
| Lₐ₅₂₃₃ | Rₙ₁ | Ar115 | H | H | H | H | Rₙ₁₁ | H | H |
| Lₐ₅₂₃₄ | Rₙ₄ | Ar115 | H | H | H | H | Rₙ₁₁ | H | H |
| Lₐ₅₂₃₅ | Rₙ₅ | Ar115 | H | H | H | H | Rₙ₁₁ | H | H |
| Lₐ₅₂₃₆ | Rₙ₇ | Ar115 | H | H | H | H | Rₙ₁₁ | H | H |
| Lₐ₅₂₃₇ | Rₙ₁₁ | Ar115 | H | H | H | H | Rₙ₁₁ | H | H |
| Lₐ₅₂₃₈ | Rₙ₂₀ | Ar115 | H | H | H | H | Rₙ₁₁ | H | H |
| Lₐ₅₂₃₉ | Rₙ₂₁ | Ar115 | H | H | H | H | Rₙ₁₁ | H | H |
| Lₐ₅₂₄₀ | Rₙ₅₁ | Ar115 | H | H | H | H | Rₙ₁₁ | H | H |
| Lₐ₅₂₄₁ | Rₙ₅₆ | Ar115 | H | H | H | H | Rₙ₁₁ | H | H |
| Lₐ₅₂₄₂ | Rₙ₅₉ | Ar115 | H | H | H | H | Rₙ₁₁ | H | H |
| Lₐ₅₂₄₃ | Rₙ₆₀ | Ar115 | H | H | H | H | Rₙ₁₁ | H | H |
| Lₐ₅₂₄₄ | Rₙ₆₁ | Ar115 | H | H | H | H | Rₙ₁₁ | H | H |
| Lₐ₅₂₄₅ | Rₙ₆₂ | Ar115 | H | H | H | H | Rₙ₁₁ | H | H |
| Lₐ₅₂₄₆ | Rₙ₆₄ | Ar115 | H | H | H | H | Rₙ₁₁ | H | H |
| Lₐ₅₂₄₇ | Rₙ₆₅ | Ar115 | H | H | H | H | Rₙ₁₁ | H | H |
| Lₐ₅₂₄₈ | Rₙ₆₉ | Ar115 | H | H | H | H | Rₙ₁₁ | H | H |
| Lₐ₅₂₄₉ | Rₙ₇₀ | Ar115 | H | H | H | H | Rₙ₁₁ | H | H |
| Lₐ₅₂₅₀ | Rₙ₈₁ | Ar115 | H | H | H | H | Rₙ₁₁ | H | H |
| Lₐ₅₂₅₁ | Rₙ₁ | Ar115 | H | H | H | H | Rₙ₅₉ | H | H |
| Lₐ₅₂₅₂ | Rₙ₄ | Ar115 | H | H | H | H | Rₙ₅₉ | H | H |
| Lₐ₅₂₅₃ | Rₙ₅ | Ar115 | H | H | H | H | Rₙ₅₉ | H | H |
| Lₐ₅₂₅₄ | Rₙ₇ | Ar115 | H | H | H | H | Rₙ₅₉ | H | H |
| Lₐ₅₂₅₅ | Rₙ₁₁ | Ar115 | H | H | H | H | Rₙ₅₉ | H | H |
| Lₐ₅₂₅₆ | Rₙ₂₀ | Ar115 | H | H | H | H | Rₙ₅₉ | H | H |
| Lₐ₅₂₅₇ | Rₙ₂₁ | Ar115 | H | H | H | H | Rₙ₅₉ | H | H |
| Lₐ₅₂₅₈ | Rₙ₅₁ | Ar115 | H | H | H | H | Rₙ₅₉ | H | H |
| Lₐ₅₂₅₉ | Rₙ₅₆ | Ar115 | H | H | H | H | Rₙ₅₉ | H | H |
| Lₐ₅₂₆₀ | Rₙ₅₉ | Ar115 | H | H | H | H | Rₙ₅₉ | H | H |
| Lₐ₅₂₆₁ | Rₙ₆₀ | Ar115 | H | H | H | H | Rₙ₅₉ | H | H |
| Lₐ₅₂₆₂ | Rₙ₆₁ | Ar115 | H | H | H | H | Rₙ₅₉ | H | H |
| Lₐ₅₂₆₃ | Rₙ₆₂ | Ar115 | H | H | H | H | Rₙ₅₉ | H | H |
| Lₐ₅₂₆₄ | Rₙ₆₄ | Ar115 | H | H | H | H | Rₙ₅₉ | H | H |
| Lₐ₅₂₆₅ | Rₙ₆₅ | Ar115 | H | H | H | H | Rₙ₅₉ | H | H |
| Lₐ₅₂₆₆ | Rₙ₆₉ | Ar115 | H | H | H | H | Rₙ₅₉ | H | H |
| Lₐ₅₂₆₇ | Rₙ₇₀ | Ar115 | H | H | H | H | Rₙ₅₉ | H | H |
| Lₐ₅₂₆₈ | Rₙ₈₁ | Ar115 | H | H | H | H | Rₙ₅₉ | H | H |
| Lₐ₅₂₆₉ | Rₙ₁ | Ar115 | H | H | H | H | Rₙ₆₀ | H | H |
| Lₐ₅₂₇₀ | Rₙ₄ | Ar115 | H | H | H | H | Rₙ₆₀ | H | H |
| Lₐ₅₂₇₁ | Rₙ₅ | Ar115 | H | H | H | H | Rₙ₆₀ | H | H |
| Lₐ₅₂₇₂ | Rₙ₇ | Ar115 | H | H | H | H | Rₙ₆₀ | H | H |
| Lₐ₅₂₇₃ | Rₙ₁₁ | Ar115 | H | H | H | H | Rₙ₆₀ | H | H |
| Lₐ₅₂₇₄ | Rₙ₂₀ | Ar115 | H | H | H | H | Rₙ₆₀ | H | H |
| Lₐ₅₂₇₅ | Rₙ₂₁ | Ar115 | H | H | H | H | Rₙ₆₀ | H | H |
| Lₐ₅₂₇₆ | Rₙ₅₁ | Ar115 | H | H | H | H | Rₙ₆₀ | H | H |
| Lₐ₅₂₇₇ | Rₙ₅₆ | Ar115 | H | H | H | H | Rₙ₆₀ | H | H |
| Lₐ₅₂₇₈ | Rₙ₅₉ | Ar115 | H | H | H | H | Rₙ₆₀ | H | H |
| Lₐ₅₂₇₉ | Rₙ₆₀ | Ar115 | H | H | H | H | Rₙ₆₀ | H | H |
| Lₐ₅₂₈₀ | Rₙ₆₁ | Ar115 | H | H | H | H | Rₙ₆₀ | H | H |
| Lₐ₅₂₈₁ | Rₙ₆₂ | Ar115 | H | H | H | H | Rₙ₆₀ | H | H |
| Lₐ₅₂₈₂ | Rₙ₆₄ | Ar115 | H | H | H | H | Rₙ₆₀ | H | H |
| Lₐ₅₂₈₃ | Rₙ₆₅ | Ar115 | H | H | H | H | Rₙ₆₀ | H | H |
| Lₐ₅₂₈₄ | Rₙ₆₉ | Ar115 | H | H | H | H | Rₙ₆₀ | H | H |
| Lₐ₅₂₈₅ | Rₙ₇₀ | Ar115 | H | H | H | H | Rₙ₆₀ | H | H |
| Lₐ₅₂₈₆ | Rₙ₈₁ | Ar115 | H | H | H | H | Rₙ₆₀ | H | H |
| Lₐ₅₂₈₇ | Rₙ₁ | Ar115 | H | H | H | H | Rₙ₆₄ | H | H |
| Lₐ₅₂₈₈ | Rₙ₄ | Ar115 | H | H | H | H | Rₙ₆₄ | H | H |
| Lₐ₅₂₈₉ | Rₙ₅ | Ar115 | H | H | H | H | Rₙ₆₄ | H | H |
| Lₐ₅₂₉₀ | Rₙ₇ | Ar115 | H | H | H | H | Rₙ₆₄ | H | H |
| Lₐ₅₂₉₁ | Rₙ₁₁ | Ar115 | H | H | H | H | Rₙ₆₄ | H | H |
| Lₐ₅₂₉₂ | Rₙ₂₀ | Ar115 | H | H | H | H | Rₙ₆₄ | H | H |
| Lₐ₅₂₉₃ | Rₙ₂₁ | Ar115 | H | H | H | H | Rₙ₆₄ | H | H |
| Lₐ₅₂₉₄ | Rₙ₅₁ | Ar115 | H | H | H | H | Rₙ₆₄ | H | H |
| Lₐ₅₂₉₅ | Rₙ₅₆ | Ar115 | H | H | H | H | Rₙ₆₄ | H | H |
| Lₐ₅₂₉₆ | Rₙ₅₉ | Ar115 | H | H | H | H | Rₙ₆₄ | H | H |
| Lₐ₅₂₉₇ | Rₙ₆₀ | Ar115 | H | H | H | H | Rₙ₆₄ | H | H |
| Lₐ₅₂₉₈ | Rₙ₆₁ | Ar115 | H | H | H | H | Rₙ₆₄ | H | H |
| Lₐ₅₂₉₉ | Rₙ₆₂ | Ar115 | H | H | H | H | Rₙ₆₄ | H | H |
| Lₐ₅₃₀₀ | Rₙ₆₄ | Ar115 | H | H | H | H | Rₙ₆₄ | H | H |
| Lₐ₅₃₀₁ | Rₙ₆₅ | Ar115 | H | H | H | H | Rₙ₆₄ | H | H |
| Lₐ₅₃₀₂ | Rₙ₆₉ | Ar115 | H | H | H | H | Rₙ₆₄ | H | H |
| Lₐ₅₃₀₃ | Rₙ₇₀ | Ar115 | H | H | H | H | Rₙ₆₄ | H | H |
| Lₐ₅₃₀₄ | Rₙ₈₁ | Ar115 | H | H | H | H | Rₙ₆₄ | H | H |
| Lₐ₅₃₀₅ | Rₙ₁ | Ar115 | H | H | H | H | Me | H | H |
| Lₐ₅₃₀₆ | Rₙ₄ | Ar115 | H | H | H | H | Me | H | H |
| Lₐ₅₃₀₇ | Rₙ₅ | Ar115 | H | H | H | H | Me | H | H |
| Lₐ₅₃₀₈ | Rₙ₇ | Ar115 | H | H | H | H | Me | H | H |
| Lₐ₅₃₀₉ | Rₙ₁₁ | Ar115 | H | H | H | H | Me | H | H |
| Lₐ₅₃₁₀ | Rₙ₂₀ | Ar115 | H | H | H | H | Me | H | H |
| Lₐ₅₃₁₁ | Rₙ₂₁ | Ar115 | H | H | H | H | Me | H | H |
| Lₐ₅₃₁₂ | Rₙ₅₁ | Ar115 | H | H | H | H | Me | H | H |
| Lₐ₅₃₁₃ | Rₙ₅₆ | Ar115 | H | H | H | H | Me | H | H |
| Lₐ₅₃₁₄ | Rₙ₅₉ | Ar115 | H | H | H | H | Me | H | H |
| Lₐ₅₃₁₅ | Rₙ₆₀ | Ar115 | H | H | H | H | Me | H | H |
| Lₐ₅₃₁₆ | Rₙ₆₁ | Ar115 | H | H | H | H | Me | H | H |
| Lₐ₅₃₁₇ | Rₙ₆₂ | Ar115 | H | H | H | H | Me | H | H |
| Lₐ₅₃₁₈ | Rₙ₆₄ | Ar115 | H | H | H | H | Me | H | H |
| Lₐ₅₃₁₉ | Rₙ₆₅ | Ar115 | H | H | H | H | Me | H | H |
| Lₐ₅₃₂₀ | Rₙ₆₉ | Ar115 | H | H | H | H | Me | H | H |
| Lₐ₅₃₂₁ | Rₙ₇₀ | Ar115 | H | H | H | H | Me | H | H |
| Lₐ₅₃₂₂ | Rₙ₈₁ | Ar115 | H | H | H | H | Me | H | H |
| Lₐ₅₃₂₃ | Rₙ₁ | Ar115 | H | H | F | H | H | H | H |
| Lₐ₅₃₂₄ | Rₙ₄ | Ar115 | H | H | F | H | H | H | H |
| Lₐ₅₃₂₅ | Rₙ₇ | Ar115 | H | H | F | H | H | H | H |
| Lₐ₅₃₂₆ | Rₙ₂₀ | Ar115 | D | H | F | H | H | H | H |
| Lₐ₅₃₂₇ | Rₙ₂₁ | Ar115 | H | H | F | H | H | H | H |
| Lₐ₅₃₂₈ | Rₙ₅₆ | Ar115 | H | H | F | H | H | H | H |
| Lₐ₅₃₂₉ | Rₙ₅₉ | Ar115 | H | H | F | H | H | H | H |
| Lₐ₅₃₃₀ | Rₙ₆₁ | Ar115 | H | D | F | H | H | H | H |
| Lₐ₅₃₃₁ | Rₙ₆₂ | Ar115 | H | H | F | H | H | H | H |
| Lₐ₅₃₃₂ | Rₙ₆₄ | Ar115 | H | H | F | H | H | H | H |
| Lₐ₅₃₃₃ | Rₙ₆₉ | Ar115 | H | H | F | H | H | H | H |
| Lₐ₅₃₃₄ | Rₙ₇₀ | Ar115 | H | H | F | H | H | H | H |
| Lₐ₅₃₃₅ | Rₙ₁ | Ar115 | H | H | F | H | Rₙ₁₁ | H | H |
| Lₐ₅₃₃₆ | Rₙ₄ | Ar115 | H | H | F | H | Rₙ₁₁ | H | H |
| Lₐ₅₃₃₇ | Rₙ₇ | Ar115 | H | H | F | H | Rₙ₁₁ | H | H |
| Lₐ₅₃₃₈ | Rₙ₂₀ | Ar115 | H | H | F | H | Rₙ₁₁ | H | H |
| Lₐ₅₃₃₉ | Rₙ₂₁ | Ar115 | H | H | F | H | Rₙ₁₁ | H | H |
| Lₐ₅₃₄₀ | Rₙ₅₆ | Ar115 | H | H | F | H | Rₙ₁₁ | H | H |
| Lₐ₅₃₄₁ | Rₙ₅₉ | Ar115 | H | H | F | H | Rₙ₁₁ | H | H |
| Lₐ₅₃₄₂ | Rₙ₆₁ | Ar115 | H | H | F | H | Rₙ₁₁ | H | H |
| Lₐ₅₃₄₃ | Rₙ₆₂ | Ar115 | H | H | F | H | Rₙ₁₁ | H | H |
| Lₐ₅₃₄₄ | Rₙ₆₄ | Ar115 | H | H | F | H | Rₙ₁₁ | H | H |
| Lₐ₅₃₄₅ | Rₙ₆₉ | Ar115 | H | H | F | H | Rₙ₁₁ | H | H |
| Lₐ₅₃₄₆ | Rₙ₇₀ | Ar115 | H | H | F | H | Rₙ₁₁ | H | H |
| Lₐ₅₃₄₇ | Rₙ₁ | Ar115 | H | H | F | D | Rₙ₆₀ | H | H |
| Lₐ₅₃₄₈ | Rₙ₄ | Ar115 | H | H | F | H | Rₙ₆₀ | H | H |
| Lₐ₅₃₄₉ | Rₙ₇ | Ar115 | H | H | F | H | Rₙ₆₀ | H | H |
| Lₐ₅₃₅₀ | Rₙ₂₀ | Ar115 | H | H | F | H | Rₙ₆₀ | H | H |
| Lₐ₅₃₅₁ | Rₙ₂₁ | Ar115 | H | H | F | H | Rₙ₆₀ | D | H |
| Lₐ₅₃₅₂ | Rₙ₅₆ | Ar115 | H | H | F | H | Rₙ₆₀ | H | H |
| Lₐ₅₃₅₃ | Rₙ₅₉ | Ar115 | H | H | F | H | Rₙ₆₀ | H | H |
| Lₐ₅₃₅₄ | Rₙ₆₁ | Ar115 | H | H | F | H | Rₙ₆₀ | H | H |
| Lₐ₅₃₅₅ | Rₙ₆₂ | Ar115 | H | H | F | H | Rₙ₆₀ | H | H |
| Lₐ₅₃₅₆ | Rₙ₆₄ | Ar115 | H | H | F | H | Rₙ₆₀ | H | H |
| Lₐ₅₃₅₇ | Rₙ₆₉ | Ar115 | H | H | F | H | Rₙ₆₀ | H | H |
| Lₐ₅₃₅₈ | Rₙ₇₀ | Ar115 | H | H | F | H | Rₙ₆₀ | H | D |
| Lₐ₅₃₅₉ | Rₙ₁ | Ar115 | H | H | F | H | H | Rₙ₁₁ | H |
| Lₐ₅₃₆₀ | Rₙ₄ | Ar115 | H | H | F | H | H | Rₙ₁₁ | H |
| Lₐ₅₃₆₁ | Rₙ₇ | Ar115 | H | H | F | H | H | Rₙ₁₁ | H |
| Lₐ₅₃₆₂ | Rₙ₂₀ | Ar115 | H | H | F | H | H | Rₙ₁₁ | H |
| Lₐ₅₃₆₃ | Rₙ₂₁ | Ar115 | H | H | F | H | H | Rₙ₁₁ | H |
| Lₐ₅₃₆₄ | Rₙ₅₆ | Ar115 | H | H | F | H | H | Rₙ₁₁ | H |
| Lₐ₅₃₆₅ | Rₙ₅₉ | Ar115 | H | H | F | H | H | Rₙ₁₁ | H |
| Lₐ₅₃₆₆ | Rₙ₆₁ | Ar115 | H | H | F | H | H | Rₙ₁₁ | H |
| Lₐ₅₃₆₇ | Rₙ₆₂ | Ar115 | H | H | F | H | H | Rₙ₁₁ | H |
| Lₐ₅₃₆₈ | Rₙ₆₄ | Ar115 | H | H | F | H | H | Rₙ₁ | H |
| Lₐ₅₃₆₉ | Rₙ₆₉ | Ar115 | H | H | F | H | H | Rₙ₁₁ | H |
| Lₐ₅₃₇₀ | Rₙ₇₀ | Ar115 | H | H | F | H | H | Rₙ₁₁ | H |
| Lₐ₅₃₇₁ | Rₙ₁ | Ar115 | H | H | F | H | H | Rₙ₆₀ | H |
| Lₐ₅₃₇₂ | Rₙ₄ | Ar115 | H | H | F | H | H | Rₙ₆₀ | H |
| Lₐ₅₃₇₃ | Rₙ₇ | Ar115 | H | H | F | H | H | Rₙ₆₀ | H |
| Lₐ₅₃₇₄ | Rₙ₂₀ | Ar115 | H | H | F | H | H | Rₙ₆₀ | H |
| Lₐ₅₃₇₅ | Rₙ₂₁ | Ar115 | H | H | F | H | H | Rₙ₆₀ | H |
| Lₐ₅₃₇₆ | Rₙ₅₆ | Ar115 | H | H | F | H | H | Rₙ₆₀ | H |
| Lₐ₅₃₇₇ | Rₙ₅₉ | Ar115 | H | H | F | H | H | Rₙ₆₀ | H |
| Lₐ₅₃₇₈ | Rₙ₆₁ | Ar115 | H | H | F | H | H | Rₙ₆₀ | H |
| Lₐ₅₃₇₉ | Rₙ₆₂ | Ar115 | H | H | F | H | H | Rₙ₆₀ | H |
| Lₐ₅₃₈₀ | Rₙ₆₄ | Ar115 | H | H | F | H | H | Rₙ₆₀ | H |
| Lₐ₅₃₈₁ | Rₙ₆₉ | Ar115 | H | H | F | H | H | Rₙ₆₀ | H |
| Lₐ₅₃₈₂ | Rₙ₇₀ | Ar115 | H | H | F | H | H | Rₙ₆₀ | H |
| Lₐ₅₃₈₃ | Rₙ₁ | Ar115 | H | H | CN | H | H | H | H |
| Lₐ₅₃₈₄ | Rₙ₄ | Ar115 | H | H | CN | H | H | H | H |
| Lₐ₅₃₈₅ | Rₙ₇ | Ar115 | H | H | CN | H | H | H | H |
| Lₐ₅₃₈₆ | Rₙ₂₀ | Ar115 | H | H | CN | H | H | H | H |
| Lₐ₅₃₈₇ | Rₙ₂₁ | Ar115 | H | H | CN | H | H | H | H |
| Lₐ₅₃₈₈ | Rₙ₅₆ | Ar115 | H | H | CN | H | H | H | H |
| Lₐ₅₃₈₉ | Rₙ₅₉ | Ar115 | H | H | CN | H | H | H | H |
| Lₐ₅₃₉₀ | Rₙ₆₁ | Ar115 | H | H | CN | H | H | H | H |
| Lₐ₅₃₉₁ | Rₙ₆₂ | Ar115 | H | H | CN | H | H | H | H |
| Lₐ₅₃₉₂ | Rₙ₆₄ | Ar115 | H | H | CN | H | H | H | H |
| Lₐ₅₃₉₃ | Rₙ₆₉ | Ar115 | H | H | CN | H | H | H | H |
| Lₐ₅₃₉₄ | Rₙ₇₀ | Ar115 | H | H | CN | H | H | H | H |
| Lₐ₅₃₉₅ | Rₙ₁ | Ar115 | H | CN | H | H | H | H | H |
| Lₐ₅₃₉₆ | Rₙ₄ | Ar115 | H | CN | H | H | H | H | H |
| Lₐ₅₃₉₇ | Rₙ₇ | Ar115 | H | CN | H | H | H | H | H |
| Lₐ₅₃₉₈ | Rₙ₂₀ | Ar115 | H | CN | H | H | H | H | H |
| Lₐ₅₃₉₉ | Rₙ₂₁ | Ar115 | H | CN | H | H | H | H | H |
| Lₐ₅₄₀₀ | Rₙ₅₆ | Ar115 | H | CN | H | H | H | H | H |
| Lₐ₅₄₀₁ | Rₙ₅₉ | Ar115 | H | CN | H | H | H | H | H |
| Lₐ₅₄₀₂ | Rₙ₆₁ | Ar115 | H | CN | H | H | H | H | H |
| Lₐ₅₄₀₃ | Rₙ₆₂ | Ar115 | H | CN | H | H | H | H | H |
| Lₐ₅₄₀₄ | Rₙ₆₄ | Ar115 | H | CN | H | H | H | H | H |
| Lₐ₅₄₀₅ | Rₙ₆₉ | Ar115 | H | CN | H | H | H | H | H |
| Lₐ₅₄₀₆ | Rₙ₇₀ | Ar115 | H | CN | H | H | H | H | H |
| Lₐ₅₄₀₇ | Rₙ₁ | Ar115 | CN | H | H | H | H | H | H |
| Lₐ₅₄₀₈ | Rₙ₄ | Ar115 | CN | H | H | H | H | H | H |
| Lₐ₅₄₀₉ | Rₙ₇ | Ar115 | CN | H | H | H | H | H | H |
| Lₐ₅₄₁₀ | Rₙ₂₀ | Ar115 | CN | H | H | H | H | H | H |
| Lₐ₅₄₁₁ | Rₙ₂₁ | Ar115 | CN | H | H | H | H | H | H |
| Lₐ₅₄₁₂ | Rₙ₅₆ | Ar115 | CN | H | H | H | H | H | H |
| Lₐ₅₄₁₃ | Rₙ₅₉ | Ar115 | CN | H | H | H | H | H | H |
| Lₐ₅₄₁₄ | Rₙ₆₁ | Ar115 | CN | H | H | H | H | H | H |
| Lₐ₅₄₁₅ | Rₙ₆₂ | Ar115 | CN | H | H | H | H | H | H |
| Lₐ₅₄₁₆ | Rₙ₆₄ | Ar115 | CN | H | H | H | H | H | H |
| Lₐ₅₄₁₇ | Rₙ₆₉ | Ar115 | CN | H | H | H | H | H | H |
| Lₐ₅₄₁₈ | Rₙ₇₀ | Ar115 | CN | H | H | H | H | H | H |
| Lₐ₅₄₁₉ | Rₙ₁ | Ar115 | H | D | CN | H | Rₙ₁₁ | H | H |
| Lₐ₅₄₂₀ | Rₙ₄ | Ar115 | H | H | CN | H | Rₙ₁₁ | H | H |
| Lₐ₅₄₂₁ | Rₙ₇ | Ar115 | H | H | CN | H | Rₙ₁₁ | H | H |
| Lₐ₅₄₂₂ | Rₙ₂₀ | Ar115 | H | H | CN | H | Rₙ₁₁ | H | H |
| Lₐ₅₄₂₃ | Rₙ₂₁ | Ar115 | H | H | CN | H | Rₙ₁₁ | H | H |
| Lₐ₅₄₂₄ | Rₙ₅₆ | Ar115 | H | H | CN | H | Rₙ₁₁ | H | H |
| Lₐ₅₄₂₅ | Rₙ₅₉ | Ar115 | H | H | CN | H | Rₙ₁₁ | H | H |
| Lₐ₅₄₂₆ | Rₙ₆₁ | Ar115 | H | H | CN | H | Rₙ₁₁ | H | H |
| Lₐ₅₄₂₇ | Rₙ₆₂ | Ar115 | H | H | CN | H | Rₙ₁₁ | H | H |
| Lₐ₅₄₂₈ | Rₙ₆₄ | Ar115 | H | H | CN | H | Rₙ₁₁ | H | H |
| Lₐ₅₄₂₉ | Rₙ₆₉ | Ar115 | D | H | CN | H | Rₙ₁₁ | H | H |
| Lₐ₅₄₃₀ | Rₙ₇₀ | Ar115 | H | H | CN | H | Rₙ₁₁ | H | H |
| Lₐ₅₄₃₁ | Rₙ₁ | Ar115 | H | H | CN | H | Rₙ₆₀ | H | D |
| Lₐ₅₄₃₂ | Rₙ₄ | Ar115 | H | H | CN | H | Rₙ₆₀ | H | H |
| Lₐ₅₄₃₃ | Rₙ₇ | Ar115 | H | H | CN | H | Rₙ₆₀ | H | H |
| Lₐ₅₄₃₄ | Rₙ₂₀ | Ar115 | H | H | CN | H | Rₙ₆₀ | H | H |
| Lₐ₅₄₃₅ | Rₙ₂₁ | Ar115 | H | H | CN | H | Rₙ₆₀ | H | H |
| Lₐ₅₄₃₆ | Rₙ₅₆ | Ar115 | H | H | CN | H | Rₙ₆₀ | H | H |
| Lₐ₅₄₃₇ | Rₙ₅₉ | Ar115 | H | H | CN | H | Rₙ₆₀ | H | H |
| Lₐ₅₄₃₈ | Rₙ₆₁ | Ar115 | H | H | CN | H | Rₙ₆₀ | H | H |
| Lₐ₅₄₃₉ | Rₙ₆₂ | Ar115 | H | H | CN | H | Rₙ₆₀ | H | H |
| Lₐ₅₄₄₀ | Rₙ₆₄ | Ar115 | H | H | CN | H | Rₙ₆₀ | H | H |
| Lₐ₅₄₄₁ | Rₙ₆₉ | Ar115 | H | H | CN | H | Rₙ₆₀ | H | H |
| Lₐ₅₄₄₂ | Rₙ₇₀ | Ar115 | H | H | CN | H | Rₙ₆₀ | H | H |
| Lₐ₅₄₄₃ | Rₙ₁ | Ar115 | H | H | CN | H | Rₙ₆₄ | H | H |
| Lₐ₅₄₄₄ | Rₙ₄ | Ar115 | H | H | CN | H | Rₙ₆₄ | H | H |
| Lₐ₅₄₄₅ | Rₙ₇ | Ar115 | H | H | CN | H | Rₙ₆₄ | H | H |
| Lₐ₅₄₄₆ | Rₙ₂₀ | Ar115 | H | H | CN | H | Rₙ₆₄ | H | H |
| Lₐ₅₄₄₇ | Rₙ₂₁ | Ar115 | H | H | CN | H | Rₙ₆₄ | H | H |
| Lₐ₅₄₄₈ | Rₙ₅₆ | Ar115 | H | H | CN | H | Rₙ₆₄ | H | H |
| Lₐ₅₄₄₉ | Rₙ₅₉ | Ar115 | H | H | CN | H | Rₙ₆₄ | H | H |
| Lₐ₅₄₅₀ | Rₙ₆₁ | Ar115 | H | H | CN | H | Rₙ₆₄ | H | H |
| Lₐ₅₄₅₁ | Rₙ₆₂ | Ar115 | H | H | CN | H | Rₙ₆₄ | H | H |
| Lₐ₅₄₅₂ | Rₙ₆₄ | Ar115 | H | H | CN | H | Rₙ₆₄ | H | H |
| Lₐ₅₄₅₃ | Rₙ₆₉ | Ar115 | H | H | CN | H | Rₙ₆₄ | H | H |
| Lₐ₅₄₅₄ | Rₙ₇₀ | Ar115 | H | H | CN | H | Rₙ₆₄ | H | H |
| Lₐ₅₄₅₅ | Rₙ₁ | Ar115 | H | H | CN | D | H | Rₙ₁₁ | H |
| Lₐ₅₄₅₆ | Rₙ₄ | Ar115 | H | H | CN | H | H | Rₙ₁₁ | H |
| Lₐ₅₄₅₇ | Rₙ₇ | Ar115 | H | H | CN | H | H | Rₙ₁₁ | H |
| Lₐ₅₄₅₈ | Rₙ₂₀ | Ar115 | H | H | CN | H | H | Rₙ₁₁ | H |
| Lₐ₅₄₅₉ | Rₙ₂₁ | Ar115 | H | H | CN | H | H | Rₙ₁₁ | H |
| Lₐ₅₄₆₀ | Rₙ₅₆ | Ar115 | H | H | CN | H | H | Rₙ₁₁ | H |
| Lₐ₅₄₆₁ | Rₙ₅₉ | Ar115 | H | H | CN | H | H | Rₙ₁₁ | H |
| Lₐ₅₄₆₂ | Rₙ₆₁ | Ar115 | H | H | CN | H | H | Rₙ₁₁ | H |
| Lₐ₅₄₆₃ | Rₙ₆₂ | Ar115 | H | H | CN | H | H | Rₙ₁₁ | H |
| Lₐ₅₄₆₄ | Rₙ₆₄ | Ar115 | H | H | CN | H | H | Rₙ₁₁ | H |
| Lₐ₅₄₆₅ | Rₙ₆₉ | Ar115 | H | H | CN | H | H | Rₙ₁₁ | H |
| Lₐ₅₄₆₆ | Rₙ₇₀ | Ar115 | H | H | CN | H | H | Rₙ₁₁ | H |
| Lₐ₅₄₆₇ | Rₙ₁ | Ar115 | H | H | CN | H | H | Rₙ₆₀ | H |
| Lₐ₅₄₆₈ | Rₙ₄ | Ar115 | H | H | CN | H | H | Rₙ₆₀ | H |
| Lₐ₅₄₆₉ | Rₙ₇ | Ar115 | H | H | CN | H | H | Rₙ₆₀ | D |
| Lₐ₅₄₇₀ | Rₙ₂₀ | Ar115 | H | H | CN | H | H | Rₙ₆₀ | H |
| Lₐ₅₄₇₁ | Rₙ₂₁ | Ar115 | H | H | CN | H | H | Rₙ₆₀ | H |
| Lₐ₅₄₇₂ | Rₙ₅₆ | Ar115 | H | H | CN | H | H | Rₙ₆₀ | H |
| Lₐ₅₄₇₃ | Rₙ₅₉ | Ar115 | H | H | CN | H | H | Rₙ₆₀ | H |
| Lₐ₅₄₇₄ | Rₙ₆₁ | Ar115 | H | H | CN | H | H | Rₙ₆₀ | H |
| Lₐ₅₄₇₅ | Rₙ₆₂ | Ar115 | H | H | CN | H | D | Rₙ₆₀ | H |
| Lₐ₅₄₇₆ | Rₙ₆₄ | Ar115 | H | H | CN | H | H | Rₙ₆₀ | H |
| Lₐ₅₄₇₇ | Rₙ₆₉ | Ar115 | H | H | CN | H | H | Rₙ₆₀ | H |
| Lₐ₅₄₇₈ | Rₙ₇₀ | Ar115 | H | H | CN | H | H | Rₙ₆₀ | H |
| Lₐ₅₄₇₉ | Rₙ₁ | Ar115 | H | H | CN | H | H | Rₙ₆₄ | H |
| Lₐ₅₄₈₀ | Rₙ₄ | Ar115 | H | H | CN | H | H | Rₙ₆₄ | H |
| Lₐ₅₄₈₁ | Rₙ₇ | Ar115 | H | D | CN | H | H | Rₙ₆₄ | H |
| Lₐ₅₄₈₂ | Rₙ₂₀ | Ar115 | H | H | CN | H | H | Rₙ₆₄ | H |
| Lₐ₅₄₈₃ | Rₙ₂₁ | Ar115 | H | H | CN | H | H | Rₙ₆₄ | H |
| Lₐ₅₄₈₄ | Rₙ₅₆ | Ar115 | H | H | CN | H | H | Rₙ₆₄ | H |
| Lₐ₅₄₈₅ | Rₙ₅₉ | Ar115 | H | H | CN | H | H | Rₙ₆₄ | H |
| Lₐ₅₄₈₆ | Rₙ₆₁ | Ar115 | H | H | CN | H | H | Rₙ₆₄ | H |
| Lₐ₅₄₈₇ | Rₙ₆₂ | Ar115 | H | H | CN | H | H | Rₙ₆₄ | H |
| Lₐ₅₄₈₈ | Rₙ₆₄ | Ar115 | H | H | CN | H | H | Rₙ₆₄ | H |
| Lₐ₅₄₈₉ | Rₙ₆₉ | Ar115 | D | H | CN | H | H | Rₙ₆₄ | H |
| Lₐ₅₄₉₀ | Rₙ₇₀ | Ar115 | H | H | CN | H | H | Rₙ₆₄ | H |
| Lₐ₅₄₉₁ | Rₙ₁ | Ar130 | H | H | H | H | H | H | H |
| Lₐ₅₄₉₂ | Rₙ₄ | Ar130 | H | H | H | H | H | H | H |
| Lₐ₅₄₉₃ | Rₙ₅ | Ar130 | H | H | H | H | H | H | H |
| Lₐ₅₄₉₄ | Rₙ₇ | Ar130 | H | H | H | H | H | H | H |
| Lₐ₅₄₉₅ | Rₙ₁₁ | Ar130 | H | H | H | H | H | H | H |
| Lₐ₅₄₉₆ | Rₙ₂₀ | Ar130 | H | H | H | H | H | H | H |
| Lₐ₅₄₉₇ | Rₙ₂₁ | Ar130 | H | H | H | H | H | H | H |
| Lₐ₅₄₉₈ | Rₙ₅₁ | Ar130 | H | H | H | H | H | H | H |
| Lₐ₅₄₉₉ | Rₙ₅₆ | Ar130 | H | H | H | H | H | H | H |
| Lₐ₅₅₀₀ | Rₙ₅₉ | Ar130 | H | H | H | H | H | H | H |
| Lₐ₅₅₀₁ | Rₙ₆₀ | Ar130 | H | H | H | H | H | H | H |
| Lₐ₅₅₀₂ | Rₙ₆₁ | Ar130 | H | H | H | H | H | H | H |
| Lₐ₅₅₀₃ | Rₙ₆₂ | Ar130 | H | H | H | H | H | H | H |
| Lₐ₅₅₀₄ | Rₙ₆₄ | Ar130 | H | H | H | H | H | H | H |
| Lₐ₅₅₀₅ | Rₙ₆₅ | Ar130 | H | H | H | H | H | H | H |
| Lₐ₅₅₀₆ | Rₙ₆₉ | Ar130 | H | H | H | H | H | H | H |
| Lₐ₅₅₀₇ | Rₙ₇₀ | Ar130 | H | H | H | H | H | H | H |
| Lₐ₅₅₀₈ | Rₙ₈₁ | Ar130 | H | H | H | H | H | H | H |
| Lₐ₅₅₀₉ | Rₙ₁ | Ar130 | H | H | H | H | H | Rₙ₁₁ | H |
| Lₐ₅₅₁₀ | Rₙ₄ | Ar130 | H | H | H | H | H | Rₙ₁₁ | H |
| Lₐ₅₅₁₁ | Rₙ₅ | Ar130 | H | H | H | H | H | Rₙ₁₁ | H |
| Lₐ₅₅₁₂ | Rₙ₇ | Ar130 | H | H | H | H | H | Rₙ₁₁ | H |
| Lₐ₅₅₁₃ | Rₙ₁₁ | Ar130 | H | H | H | H | H | Rₙ₁₁ | H |
| Lₐ₅₅₁₄ | Rₙ₂₀ | Ar130 | H | H | H | H | H | Rₙ₁₁ | H |
| Lₐ₅₅₁₅ | Rₙ₂₁ | Ar130 | H | H | H | H | H | Rₙ₁₁ | H |
| Lₐ₅₅₁₆ | Rₙ₅₁ | Ar130 | H | H | H | H | H | Rₙ₁₁ | H |
| Lₐ₅₅₁₇ | Rₙ₅₆ | Ar130 | H | H | H | H | H | Rₙ₁₁ | H |
| Lₐ₅₅₁₈ | Rₙ₅₉ | Ar130 | H | H | H | H | H | Rₙ₁₁ | H |
| Lₐ₅₅₁₉ | Rₙ₆₀ | Ar130 | H | H | H | H | H | Rₙ₁₁ | H |
| Lₐ₅₅₂₀ | Rₙ₆₁ | Ar130 | H | H | H | H | H | Rₙ₁₁ | H |
| Lₐ₅₅₂₁ | Rₙ₆₂ | Ar130 | H | H | H | H | H | Rₙ₁₁ | H |
| Lₐ₅₅₂₂ | Rₙ₆₄ | Ar130 | H | H | H | H | H | Rₙ₁₁ | H |
| Lₐ₅₅₂₃ | Rₙ₆₅ | Ar130 | H | H | H | H | H | Rₙ₁₁ | H |
| Lₐ₅₅₂₄ | Rₙ₆₉ | Ar130 | H | H | H | H | H | Rₙ₁₁ | H |
| Lₐ₅₅₂₅ | Rₙ₇₀ | Ar130 | H | H | H | H | H | Rₙ₁₁ | H |
| Lₐ₅₅₂₆ | Rₙ₈₁ | Ar130 | H | H | H | H | H | Rₙ₁₁ | H |
| Lₐ₅₅₂₇ | Rₙ₁ | Ar130 | H | H | H | H | H | Rₙ₅₉ | H |
| Lₐ₅₅₂₈ | Rₙ₄ | Ar130 | H | H | H | H | H | Rₙ₅₉ | H |
| Lₐ₅₅₂₉ | Rₙ₅ | Ar130 | H | H | H | H | H | Rₙ₅₉ | H |
| Lₐ₅₅₃₀ | Rₙ₇ | Ar130 | H | H | H | H | H | Rₙ₅₉ | H |
| Lₐ₅₅₃₁ | Rₙ₁₁ | Ar130 | H | H | H | H | H | Rₙ₅₉ | H |
| Lₐ₅₅₃₂ | R₁₂₀ | Ar130 | H | H | H | H | H | Rₙ₅₉ | H |
| Lₐ₅₅₃₃ | Rₙ₂₁ | Ar130 | H | H | H | H | H | Rₙ₅₉ | H |
| Lₐ₅₅₃₄ | Rₙ₅₁ | Ar130 | H | H | H | H | H | Rₙ₅₉ | H |
| Lₐ₅₅₃₅ | Rₙ₅₆ | Ar130 | H | H | H | H | H | Rₙ₅₉ | H |
| Lₐ₅₅₃₆ | Rₙ₅₉ | Ar130 | H | H | H | H | H | Rₙ₅₉ | H |
| Lₐ₅₅₃₇ | Rₙ₆₀ | Ar130 | H | H | H | H | H | Rₙ₅₉ | H |
| Lₐ₅₅₃₈ | Rₙ₆₁ | Ar130 | H | H | H | H | H | Rₙ₅₉ | H |
| Lₐ₅₅₃₉ | Rₙ₆₂ | Ar130 | H | H | H | H | H | Rₙ₅₉ | H |
| Lₐ₅₅₄₀ | Rₙ₆₄ | Ar130 | H | H | H | H | H | Rₙ₅₉ | H |
| Lₐ₅₅₄₁ | Rₙ₆₅ | Ar130 | H | H | H | H | H | Rₙ₅₉ | H |
| Lₐ₅₅₄₂ | Rₙ₆₉ | Ar130 | H | H | H | H | H | Rₙ₅₉ | H |
| Lₐ₅₅₄₃ | Rₙ₇₀ | Ar130 | H | H | H | H | H | Rₙ₅₉ | H |
| Lₐ₅₅₄₄ | Rₙ₈₁ | Ar130 | H | H | H | H | H | Rₙ₅₉ | H |
| Lₐ₅₅₄₅ | Rₙ₁ | Ar130 | H | H | H | H | H | Rₙ₆₀ | H |
| Lₐ₅₅₄₆ | Rₙ₄ | Ar130 | H | H | H | H | H | Rₙ₆₀ | H |
| Lₐ₅₅₄₇ | Rₙ₅ | Ar130 | H | H | H | H | H | Rₙ₆₀ | H |
| Lₐ₅₅₄₈ | Rₙ₇ | Ar130 | H | H | H | H | H | Rₙ₆₀ | H |
| Lₐ₅₅₄₉ | Rₙ₁₁ | Ar130 | H | H | H | H | H | Rₙ₆₀ | H |
| Lₐ₅₅₅₀ | Rₙ₂₀ | Ar130 | H | H | H | H | H | Rₙ₆₀ | H |
| Lₐ₅₅₅₁ | Rₙ₂₁ | Ar130 | H | H | H | H | H | Rₙ₆₀ | H |
| Lₐ₅₅₅₂ | Rₙ₅₁ | Ar130 | H | H | H | H | H | Rₙ₆₀ | H |
| Lₐ₅₅₅₃ | Rₙ₅₆ | Ar130 | H | H | H | H | H | Rₙ₆₀ | H |
| Lₐ₅₅₅₄ | Rₙ₅₉ | Ar130 | H | H | H | H | H | Rₙ₆₀ | H |
| Lₐ₅₅₅₅ | Rₙ₆₀ | Ar130 | H | H | H | H | H | Rₙ₆₀ | H |
| Lₐ₅₅₅₆ | Rₙ₆₁ | Ar130 | H | H | H | H | H | Rₙ₆₀ | H |
| Lₐ₅₅₅₇ | Rₙ₆₂ | Ar130 | H | H | H | H | H | Rₙ₆₀ | H |
| Lₐ₅₅₅₈ | Rₙ₆₄ | Ar130 | H | H | H | H | H | Rₙ₆₀ | H |
| Lₐ₅₅₅₉ | Rₙ₆₅ | Ar130 | H | H | H | H | H | Rₙ₆₀ | H |
| Lₐ₅₅₆₀ | Rₙ₆₉ | Ar130 | H | H | H | H | H | Rₙ₆₀ | H |
| Lₐ₅₅₆₁ | Rₙ₇₀ | Ar130 | H | H | H | H | H | Rₙ₆₀ | H |
| Lₐ₅₅₆₂ | Rₙ₈₁ | Ar130 | H | H | H | H | H | Rₙ₆₀ | H |
| Lₐ₅₅₆₃ | Rₙ₁ | Ar130 | H | H | H | H | H | Rₙ₆₄ | H |
| Lₐ₅₅₆₄ | Rₙ₄ | Ar130 | H | H | H | H | H | Rₙ₆₄ | H |
| Lₐ₅₅₆₅ | Rₙ₅ | Ar130 | H | H | H | H | H | Rₙ₆₄ | H |
| Lₐ₅₅₆₆ | Rₙ₇ | Ar130 | H | H | H | H | H | Rₙ₆₄ | H |
| Lₐ₅₅₆₇ | Rₙ₁₁ | Ar130 | H | H | H | H | H | Rₙ₆₄ | H |
| Lₐ₅₅₆₈ | Rₙ₂₀ | Ar130 | H | H | H | H | H | Rₙ₆₄ | H |
| Lₐ₅₅₆₉ | Rₙ₂₁ | Ar130 | H | H | H | H | H | Rₙ₆₄ | H |
| Lₐ₅₅₇₀ | Rₙ₅₁ | Ar130 | H | H | H | H | H | Rₙ₆₄ | H |
| Lₐ₅₅₇₁ | Rₙ₅₆ | Ar130 | H | H | H | H | H | Rₙ₆₄ | H |
| Lₐ₅₅₇₂ | Rₙ₅₉ | Ar130 | H | H | H | H | H | Rₙ₆₄ | H |
| Lₐ₅₅₇₃ | Rₙ₆₀ | Ar130 | H | H | H | H | H | Rₙ₆₄ | H |
| Lₐ₅₅₇₄ | Rₙ₆₁ | Ar130 | H | H | H | H | H | Rₙ₆₄ | H |
| Lₐ₅₅₇₅ | Rₙ₆₂ | Ar130 | H | H | H | H | H | Rₙ₆₄ | H |
| Lₐ₅₅₇₆ | Rₙ₆₄ | Ar130 | H | H | H | H | H | Rₙ₆₄ | H |
| Lₐ₅₅₇₇ | Rₙ₆₅ | Ar130 | H | H | H | H | H | Rₙ₆₄ | H |
| Lₐ₅₅₇₈ | Rₙ₆₉ | Ar130 | H | H | H | H | H | Rₙ₆₄ | H |
| Lₐ₅₅₇₉ | Rₙ₇₀ | Ar130 | H | H | H | H | H | Rₙ₆₄ | H |
| Lₐ₅₅₈₀ | Rₙ₈₁ | Ar130 | H | H | H | H | H | Rₙ₆₄ | H |
| Lₐ₅₅₈₁ | Rₙ₁ | Ar130 | H | H | H | H | H | Me | H |
| Lₐ₅₅₈₂ | Rₙ₄ | Ar130 | H | H | H | H | H | Me | H |
| Lₐ₅₅₈₃ | Rₙ₅ | Ar130 | H | H | H | H | H | Me | H |
| Lₐ₅₅₈₄ | Rₙ₇ | Ar130 | H | H | H | H | H | Me | H |
| Lₐ₅₅₈₅ | Rₙ₁₁ | Ar130 | H | H | H | H | H | Me | H |
| Lₐ₅₅₈₆ | Rₙ₂₀ | Ar130 | H | H | H | H | H | Me | H |
| Lₐ₅₅₈₇ | Rₙ₂₁ | Ar130 | H | H | H | H | H | Me | H |
| Lₐ₅₅₈₈ | Rₙ₅₁ | Ar130 | H | H | H | H | H | Me | H |
| Lₐ₅₅₈₉ | Rₙ₅₆ | Ar130 | H | H | H | H | H | Me | H |
| Lₐ₅₅₉₀ | Rₙ₅₉ | Ar130 | H | H | H | H | H | Me | H |
| Lₐ₅₅₉₁ | Rₙ₆₀ | Ar130 | H | H | H | H | H | Me | H |
| Lₐ₅₅₉₂ | Rₙ₆₁ | Ar130 | H | H | H | H | H | Me | H |
| Lₐ₅₅₉₃ | Rₙ₆₂ | Ar130 | H | H | H | H | H | Me | H |
| Lₐ₅₅₉₄ | Rₙ₆₄ | Ar130 | H | H | H | H | H | Me | H |
| Lₐ₅₅₉₅ | Rₙ₆₅ | Ar130 | H | H | H | H | H | Me | H |
| Lₐ₅₅₉₆ | Rₙ₆ | Ar130 | H | H | H | H | H | Me | H |
| Lₐ₅₅₉₇ | Rₙ₇₀ | Ar130 | H | H | H | H | H | Me | H |
| Lₐ₅₅₉₈ | Rₙ₈₁ | Ar130 | H | H | H | H | H | Me | H |
| Lₐ₅₅₉₉ | Rₙ₁ | Ar130 | H | H | H | H | Rₙ₁₁ | H | H |
| Lₐ₅₆₀₀ | Rₙ₄ | Ar130 | H | H | H | H | Rₙ₁₁ | H | H |
| Lₐ₅₆₀₁ | Rₙ₅ | Ar130 | H | H | H | H | Rₙ₁₁ | H | H |
| Lₐ₅₆₀₂ | Rₙ₇ | Ar130 | H | H | H | H | Rₙ₁₁ | H | H |
| Lₐ₅₆₀₃ | Rₙ₁₁ | Ar130 | H | H | H | H | Rₙ₁₁ | H | H |
| Lₐ₅₆₀₄ | Rₙ₂₀ | Ar130 | H | H | H | H | Rₙ₁₁ | H | H |
| Lₐ₅₆₀₅ | Rₙ₂₁ | Ar130 | H | H | H | H | Rₙ₁₁ | H | H |
| Lₐ₅₆₀₆ | Rₙ₅₁ | Ar130 | H | H | H | H | Rₙ₁₁ | H | H |
| Lₐ₅₆₀₇ | Rₙ₅₆ | Ar130 | H | H | H | H | Rₙ₁₁ | H | H |
| Lₐ₅₆₀₈ | Rₙ₅₉ | Ar130 | H | H | H | H | Rₙ₁₁ | H | H |
| Lₐ₅₆₀₉ | Rₙ₆₀ | Ar130 | H | H | H | H | Rₙ₁₁ | H | H |
| Lₐ₅₆₁₀ | Rₙ₆₁ | Ar130 | H | H | H | H | Rₙ₁₁ | H | H |
| Lₐ₅₆₁₁ | Rₙ₆₂ | Ar130 | H | H | H | H | Rₙ₁₁ | H | H |
| Lₐ₅₆₁₂ | Rₙ₆₄ | Ar130 | H | H | H | H | Rₙ₁₁ | H | H |
| Lₐ₅₆₁₃ | Rₙ₆₅ | Ar130 | H | H | H | H | Rₙ₁₁ | H | H |
| Lₐ₅₆₁₄ | Rₙ₆₉ | Ar130 | H | H | H | H | Rₙ₁₁ | H | H |
| Lₐ₅₆₁₅ | Rₙ₇₀ | Ar130 | H | H | H | H | Rₙ₁₁ | H | H |
| Lₐ₅₆₁₆ | Rₙ₈₁ | Ar130 | H | H | H | H | Rₙ₁₁ | H | H |
| Lₐ₅₆₁₇ | Rₙ₁ | Ar130 | H | H | H | H | Rₙ₅₉ | H | H |
| Lₐ₅₆₁₈ | Rₙ₄ | Ar130 | H | H | H | H | Rₙ₅₉ | H | H |
| Lₐ₅₆₁₉ | Rₙ₅ | Ar130 | H | H | H | H | Rₙ₅₉ | H | H |
| Lₐ₅₆₂₀ | Rₙ₇ | Ar130 | H | H | H | H | Rₙ₅₉ | H | H |
| Lₐ₅₆₂₁ | Rₙ₁₁ | Ar130 | H | H | H | H | Rₙ₅₉ | H | H |
| Lₐ₅₆₂₂ | Rₙ₂₀ | Ar130 | H | H | H | H | Rₙ₅₉ | H | H |
| Lₐ₅₆₂₃ | Rₙ₂₁ | Ar130 | H | H | H | H | Rₙ₅₉ | H | H |
| Lₐ₅₆₂₄ | Rₙ₅₁ | Ar130 | H | H | H | H | Rₙ₅₉ | H | H |
| Lₐ₅₆₂₅ | Rₙ₅₆ | Ar130 | H | H | H | H | Rₙ₅₉ | H | H |
| Lₐ₅₆₂₆ | Rₙ₅₉ | Ar130 | H | H | H | H | Rₙ₅₉ | H | H |
| Lₐ₅₆₂₇ | Rₙ₆₀ | Ar130 | H | H | H | H | Rₙ₅₉ | H | D |
| Lₐ₅₆₂₈ | Rₙ₆₁ | Ar130 | H | H | H | H | Rₙ₅₉ | H | H |
| Lₐ₅₆₂₉ | Rₙ₆₂ | Ar130 | H | H | H | H | Rₙ₅₉ | H | H |
| Lₐ₅₆₃₀ | Rₙ₆₄ | Ar130 | H | H | H | H | Rₙ₅₉ | H | H |
| Lₐ₅₆₃₁ | Rₙ₆₅ | Ar130 | H | H | H | H | Rₙ₅₉ | H | H |
| Lₐ₅₆₃₂ | Rₙ₆₉ | Ar130 | H | H | H | D | Rₙ₅₉ | H | H |
| Lₐ₅₆₃₃ | Rₙ₇₀ | Ar130 | H | H | H | H | Rₙ₅₉ | H | H |
| Lₐ₅₆₃₄ | Rₙ₈₁ | Ar130 | H | H | H | H | Rₙ₅₉ | H | H |
| Lₐ₅₆₃₅ | Rₙ₁ | Ar130 | H | H | H | H | Rₙ₆₀ | H | H |
| Lₐ₅₆₃₆ | Rₙ₄ | Ar130 | H | H | H | H | Rₙ₆₀ | H | H |
| Lₐ₅₆₃₇ | Rₙ₅ | Ar130 | D | H | H | H | Rₙ₆₀ | H | H |
| Lₐ₅₆₃₈ | Rₙ₇ | Ar130 | H | H | H | H | Rₙ₆₀ | H | H |
| Lₐ₅₆₃₉ | Rₙ₁₁ | Ar130 | H | H | H | H | Rₙ₆₀ | H | H |
| Lₐ₅₆₄₀ | Rₙ₂₀ | Ar130 | H | H | H | H | Rₙ₆₀ | H | H |
| Lₐ₅₆₄₁ | Rₙ₂₁ | Ar130 | H | H | H | H | Rₙ₆₀ | H | H |
| Lₐ₅₆₄₂ | Rₙ₅₁ | Ar130 | H | H | H | H | Rₙ₆₀ | H | H |
| Lₐ₅₆₄₃ | Rₙ₅₆ | Ar130 | H | H | H | H | Rₙ₆₀ | H | H |
| Lₐ₅₆₄₄ | Rₙ₅₉ | Ar130 | H | H | H | H | Rₙ₆₀ | H | H |
| Lₐ₅₆₄₅ | Rₙ₆₀ | Ar130 | H | H | H | H | Rₙ₆₀ | H | H |
| Lₐ₅₆₄₆ | Rₙ₆₁ | Ar130 | H | H | H | H | Rₙ₆₀ | H | H |
| Lₐ₅₆₄₇ | Rₙ₆₂ | Ar130 | H | H | H | H | Rₙ₆₀ | H | H |
| Lₐ₅₆₄₈ | Rₙ₆₄ | Ar130 | H | H | H | H | Rₙ₆₀ | H | H |
| Lₐ₅₆₄₉ | Rₙ₆₅ | Ar130 | H | H | H | H | Rₙ₆₀ | H | H |
| Lₐ₅₆₅₀ | Rₙ₆₉ | Ar130 | H | H | H | H | Rₙ₆₀ | H | H |
| Lₐ₅₆₅₁ | Rₙ₇₀ | Ar130 | H | H | H | H | Rₙ₆₀ | H | H |
| Lₐ₅₆₅₂ | Rₙ₈₁ | Ar130 | H | H | H | H | Rₙ₆₀ | H | H |
| Lₐ₅₆₅₃ | Rₙ₁ | Ar130 | H | H | H | H | Rₙ₆₄ | H | H |
| Lₐ₅₆₅₄ | Rₙ₄ | Ar130 | H | H | H | H | Rₙ₆₄ | H | H |
| Lₐ₅₆₅₅ | Rₙ₅ | Ar130 | H | H | H | H | Rₙ₆₄ | H | H |
| Lₐ₅₆₅₆ | Rₙ₇ | Ar130 | H | H | H | H | Rₙ₆₄ | H | H |
| Lₐ₅₆₅₇ | Rₙ₁₁ | Ar130 | H | H | H | H | Rₙ₆₄ | H | H |
| Lₐ₅₆₅₈ | Rₙ₂₀ | Ar130 | H | H | H | H | Rₙ₆₄ | H | H |
| Lₐ₅₆₅₉ | Rₙ₂₁ | Ar130 | H | H | H | H | Rₙ₆₄ | H | H |
| Lₐ₅₆₆₀ | Rₙ₅₁ | Ar130 | H | H | H | H | Rₙ₆₄ | H | H |
| Lₐ₅₆₆₁ | Rₙ₅₆ | Ar130 | H | H | H | H | Rₙ₆₄ | H | H |
| Lₐ₅₆₆₂ | Rₙ₅₉ | Ar130 | H | H | H | H | Rₙ₆₄ | H | H |
| Lₐ₅₆₆₃ | Rₙ₆₀ | Ar130 | H | H | H | H | Rₙ₆₄ | H | H |
| Lₐ₅₆₆₄ | Rₙ₆₁ | Ar130 | H | H | H | H | Rₙ₆₄ | H | H |
| Lₐ₅₆₆₅ | Rₙ₆₂ | Ar130 | H | H | H | H | Rₙ₆₄ | H | H |
| Lₐ₅₆₆₆ | Rₙ₆₄ | Ar130 | H | H | H | H | Rₙ₆₄ | H | H |
| Lₐ₅₆₆₇ | Rₙ₆₅ | Ar130 | H | H | H | H | Rₙ₆₄ | H | H |
| Lₐ₅₆₆₈ | Rₙ₆₉ | Ar130 | H | H | H | H | Rₙ₆₄ | H | H |
| Lₐ₅₆₆₉ | Rₙ₇₀ | Ar130 | H | H | H | H | Rₙ₆₄ | H | H |
| Lₐ₅₆₇₀ | Rₙ₈₁ | Ar130 | H | H | H | H | Rₙ₆₄ | H | H |
| Lₐ₅₆₇₁ | Rₙ₁ | Ar130 | H | H | H | H | Me | H | H |
| Lₐ₅₆₇₂ | Rₙ₄ | Ar130 | H | H | H | H | Me | H | H |
| Lₐ₅₆₇₃ | Rₙ₅ | Ar130 | H | H | H | H | Me | H | H |
| Lₐ₅₆₇₄ | Rₙ₇ | Ar130 | H | H | H | H | Me | H | H |
| Lₐ₅₆₇₅ | Rₙ₁₁ | Ar130 | H | H | H | H | Me | H | H |
| Lₐ₅₆₇₆ | Rₙ₂₀ | Ar130 | H | H | H | H | Me | H | H |
| Lₐ₅₆₇₇ | Rₙ₂₁ | Ar130 | H | H | H | H | Me | H | H |
| Lₐ₅₆₇₈ | Rₙ₅₁ | Ar130 | H | H | H | H | Me | H | H |
| Lₐ₅₆₇₉ | Rₙ₅₆ | Ar130 | H | H | H | H | Me | H | H |
| Lₐ₅₆₈₀ | Rₙ₅₉ | Ar130 | H | H | H | H | Me | H | H |
| Lₐ₅₆₈₁ | Rₙ₆₀ | Ar130 | H | H | H | H | Me | H | H |
| Lₐ₅₆₈₂ | Rₙ₆₁ | Ar130 | H | H | H | H | Me | H | H |
| Lₐ₅₆₈₃ | Rₙ₆₂ | Ar130 | H | H | H | H | Me | H | H |
| Lₐ₅₆₈₄ | Rₙ₆₄ | Ar130 | H | H | H | H | Me | H | H |
| Lₐ₅₆₈₅ | Rₙ₆₅ | Ar130 | H | H | H | H | Me | H | H |
| Lₐ₅₆₈₆ | Rₙ₆₉ | Ar130 | H | H | H | H | Me | H | H |
| Lₐ₅₆₈₇ | Rₙ₇₀ | Ar130 | H | H | H | H | Me | H | H |
| Lₐ₅₆₈₈ | Rₙ₈₁ | Ar130 | H | H | H | H | Me | H | H |
| Lₐ₅₆₈₉ | Rₙ₁ | Ar130 | H | H | F | H | H | H | H |
| Lₐ₅₆₉₀ | Rₙ₄ | Ar130 | H | H | F | H | H | H | H |
| Lₐ₅₆₉₁ | Rₙ₇ | Ar130 | H | H | F | H | H | H | H |
| Lₐ₅₆₉₂ | Rₙ₂₀ | Ar130 | H | H | F | H | H | H | H |
| Lₐ₅₆₉₃ | Rₙ₂₁ | Ar130 | H | H | F | H | H | H | H |
| Lₐ₅₆₉₄ | Rₙ₅₆ | Ar130 | H | H | F | H | H | H | H |
| Lₐ₅₆₉₅ | Rₙ₅₉ | Ar130 | H | H | F | H | H | H | H |
| Lₐ₅₆₉₆ | Rₙ₆₁ | Ar130 | D | H | F | H | H | H | H |
| Lₐ₅₆₉₇ | Rₙ₆₂ | Ar130 | H | H | F | H | H | H | H |
| Lₐ₅₆₉₈ | Rₙ₆₄ | Ar130 | H | H | F | H | H | H | H |
| Lₐ₅₆₉₉ | Rₙ₆₉ | Ar130 | H | H | F | H | H | H | H |
| Lₐ₅₇₀₀ | Rₙ₇₀ | Ar130 | H | H | F | H | H | H | H |
| Lₐ₅₇₀₁ | Rₙ₁ | Ar130 | H | H | F | H | Rₙ₁₁ | H | H |
| Lₐ₅₇₀₂ | Rₙ₄ | Ar130 | H | H | F | H | Rₙ₁₁ | H | H |
| Lₐ₅₇₀₃ | Rₙ₇ | Ar130 | H | D | F | H | Rₙ₁₁ | H | H |
| Lₐ₅₇₀₄ | Rₙ₂₀ | Ar130 | H | H | F | H | Rₙ₁₁ | H | H |
| Lₐ₅₇₀₅ | Rₙ₂₁ | Ar130 | H | H | F | H | Rₙ₁₁ | H | H |
| Lₐ₅₇₀₆ | Rₙ₅₆ | Ar130 | H | H | F | H | Rₙ₁₁ | H | H |
| Lₐ₅₇₀₇ | Rₙ₅₉ | Ar130 | H | H | F | H | Rₙ₁₁ | H | H |
| Lₐ₅₇₀₈ | Rₙ₆₁ | Ar130 | H | H | F | H | Rₙ₁₁ | H | H |
| Lₐ₅₇₀₉ | Rₙ₆₂ | Ar130 | H | H | F | H | Rₙ₁₁ | H | H |
| Lₐ₅₇₁₀ | Rₙ₆₄ | Ar130 | H | H | F | H | Rₙ₁₁ | H | H |
| Lₐ₅₇₁₁ | Rₙ₆₉ | Ar130 | H | H | F | H | Rₙ₁₁ | H | H |
| Lₐ₅₇₁₂ | Rₙ₇₀ | Ar130 | H | H | F | H | Rₙ₁₁ | H | H |
| Lₐ₅₇₁₃ | Rₙ₁ | Ar130 | H | H | F | H | Rₙ₆₀ | H | H |
| Lₐ₅₇₁₄ | Rₙ₄ | Ar130 | H | H | F | H | Rₙ₆₀ | H | H |
| Lₐ₅₇₁₅ | Rₙ₇ | Ar130 | H | H | F | H | Rₙ₆₀ | H | H |
| Lₐ₅₇₁₆ | Rₙ₂₀ | Ar130 | H | H | F | H | Rₙ₆₀ | H | H |
| Lₐ₅₇₁₇ | Rₙ₂₁ | Ar130 | H | H | F | H | Rₙ₆₀ | H | H |
| Lₐ₅₇₁₈ | Rₙ₅₆ | Ar130 | H | H | F | H | Rₙ₆₀ | H | H |
| Lₐ₅₇₁₉ | Rₙ₅₉ | Ar130 | H | H | F | H | Rₙ₆₀ | H | H |
| Lₐ₅₇₂₀ | Rₙ₆₁ | Ar130 | H | H | F | H | Rₙ₆₀ | H | H |
| Lₐ₅₇₂₁ | Rₙ₆₂ | Ar130 | H | H | F | H | Rₙ₆₀ | H | H |
| Lₐ₅₇₂₂ | Rₙ₆₄ | Ar130 | H | H | F | H | Rₙ₆₀ | H | H |
| Lₐ₅₇₂₃ | Rₙ₆₉ | Ar130 | H | H | F | H | Rₙ₆₀ | H | H |
| Lₐ₅₇₂₄ | Rₙ₇₀ | Ar130 | H | H | F | H | Rₙ₆₀ | H | H |
| Lₐ₅₇₂₅ | Rₙ₁ | Ar130 | H | H | F | H | H | Rₙ₁₁ | H |
| Lₐ₅₇₂₆ | Rₙ₄ | Ar130 | H | H | F | H | H | Rₙ₁₁ | H |
| Lₐ₅₇₂₇ | Rₙ₇ | Ar130 | H | H | F | H | H | Rₙ₁₁ | H |
| Lₐ₅₇₂₈ | Rₙ₂₀ | Ar130 | H | H | F | H | H | Rₙ₁₁ | H |
| Lₐ₅₇₂₉ | Rₙ₂₁ | Ar130 | H | H | F | H | H | Rₙ₁₁ | H |
| Lₐ₅₇₃₀ | Rₙ₅₆ | Ar130 | H | H | F | H | H | Rₙ₁₁ | H |
| Lₐ₅₇₃₁ | Rₙ₅₉ | Ar130 | H | H | F | H | H | Rₙ₁₁ | H |
| Lₐ₅₇₃₂ | Rₙ₆₁ | Ar130 | H | H | F | H | H | Rₙ₁₁ | H |
| Lₐ₅₇₃₃ | Rₙ₆₂ | Ar130 | H | H | F | H | H | Rₙ₁₁ | H |
| Lₐ₅₇₃₄ | Rₙ₆₄ | Ar130 | H | H | F | H | H | Rₙ₁₁ | H |
| Lₐ₅₇₃₅ | Rₙ₆₉ | Ar130 | H | H | F | H | H | Rₙ₁₁ | H |
| Lₐ₅₇₃₆ | Rₙ₇₀ | Ar130 | H | H | F | H | H | Rₙ₁₁ | H |
| Lₐ₅₇₃₇ | Rₙ₁ | Ar130 | H | H | F | H | H | Rₙ₆₀ | D |
| Lₐ₅₇₃₈ | Rₙ₄ | Ar130 | H | H | F | H | H | Rₙ₆₀ | H |
| Lₐ₅₇₃₉ | Rₙ₇ | Ar130 | H | H | F | H | H | Rₙ₆₀ | H |
| Lₐ₅₇₄₀ | Rₙ₂₀ | Ar130 | H | H | F | H | H | Rₙ₆₀ | H |
| Lₐ₅₇₄₁ | Rₙ₂₁ | Ar130 | H | H | F | H | H | Rₙ₆₀ | H |
| Lₐ₅₇₄₂ | Rₙ₅₆ | Ar130 | H | H | F | H | H | Rₙ₆₀ | H |
| Lₐ₅₇₄₃ | Rₙ₅₉ | Ar130 | H | H | F | H | H | Rₙ₆₀ | H |
| Lₐ₅₇₄₄ | Rₙ₆₁ | Ar130 | H | H | F | H | H | Rₙ₆₀ | H |
| Lₐ₅₇₄₅ | Rₙ₆₂ | Ar130 | H | H | F | H | H | Rₙ₆₀ | H |
| Lₐ₅₇₄₆ | Rₙ₆₄ | Ar130 | H | H | F | H | H | Rₙ₆₀ | H |
| Lₐ₅₇₄₇ | Rₙ₆₉ | Ar130 | H | H | F | H | H | Rₙ₆₀ | H |
| Lₐ₅₇₄₈ | Rₙ₇₀ | Ar130 | H | H | F | H | H | Rₙ₆₀ | H |
| Lₐ₅₇₄₉ | Rₙ₁ | Ar130 | H | H | CN | H | H | H | H |
| Lₐ₅₇₅₀ | Rₙ₄ | Ar130 | H | H | CN | H | H | H | H |
| Lₐ₅₇₅₁ | Rₙ₇ | Ar130 | H | H | CN | H | H | H | H |
| Lₐ₅₇₅₂ | Rₙ₂₀ | Ar130 | H | H | CN | H | H | H | H |
| Lₐ₅₇₅₃ | Rₙ₂₁ | Ar130 | H | H | CN | H | H | H | H |
| Lₐ₅₇₅₄ | Rₙ₅₆ | Ar130 | H | H | CN | H | H | H | H |
| Lₐ₅₇₅₅ | Rₙ₅₉ | Ar130 | H | H | CN | H | H | H | H |
| Lₐ₅₇₅₆ | Rₙ₆₁ | Ar130 | D | H | CN | H | H | H | H |
| Lₐ₅₇₅₇ | Rₙ₆₂ | Ar130 | H | H | CN | H | H | H | H |
| Lₐ₅₇₅₈ | Rₙ₆₄ | Ar130 | H | H | CN | H | H | H | H |
| Lₐ₅₇₅₉ | Rₙ₆₉ | Ar130 | H | H | CN | H | H | H | H |
| Lₐ₅₇₆₀ | Rₙ₇₀ | Ar130 | H | H | CN | H | H | H | H |
| Lₐ₅₇₆₁ | Rₙ₁ | Ar130 | H | CN | H | H | H | H | H |
| Lₐ₅₇₆₂ | Rₙ₄ | Ar130 | H | CN | H | H | H | H | H |
| Lₐ₅₇₆₃ | Rₙ₇ | Ar130 | H | CN | H | D | H | H | H |
| Lₐ₅₇₆₄ | Rₙ₂₀ | Ar130 | H | CN | H | H | H | H | H |
| Lₐ₅₇₆₅ | Rₙ₂₁ | Ar130 | H | CN | H | H | H | H | H |
| Lₐ₅₇₆₆ | Rₙ₅₆ | Ar130 | H | CN | H | H | H | H | H |
| Lₐ₅₇₆₇ | Rₙ₅₉ | Ar130 | H | CN | H | H | H | H | H |
| Lₐ₅₇₆₈ | Rₙ₆₁ | Ar130 | H | CN | H | H | H | H | H |
| Lₐ₅₇₆₉ | Rₙ₆₂ | Ar130 | H | CN | H | H | H | H | H |
| Lₐ₅₇₇₀ | Rₙ₆₄ | Ar130 | H | CN | H | H | H | H | H |
| Lₐ₅₇₇₁ | Rₙ₆₉ | Ar130 | H | CN | H | H | H | H | H |
| Lₐ₅₇₇₂ | Rₙ₇₀ | Ar130 | H | CN | H | H | H | H | H |
| Lₐ₅₇₇₃ | Rₙ₁ | Ar130 | CN | H | H | H | H | H | H |
| Lₐ₅₇₇₄ | Rₙ₄ | Ar130 | CN | H | H | H | H | H | H |
| Lₐ₅₇₇₅ | Rₙ₇ | Ar130 | CN | D | H | H | H | H | H |
| Lₐ₅₇₇₆ | Rₙ₂₀ | Ar130 | CN | H | H | H | H | H | H |
| Lₐ₅₇₇₇ | Rₙ₂₁ | Ar130 | CN | H | H | H | H | H | H |
| Lₐ₅₇₇₈ | Rₙ₅₆ | Ar130 | CN | H | H | H | H | H | H |
| Lₐ₅₇₇₉ | Rₙ₅₉ | Ar130 | CN | H | H | H | H | H | H |
| Lₐ₅₇₈₀ | Rₙ₆₁ | Ar130 | CN | H | H | H | H | H | H |
| Lₐ₅₇₈₁ | Rₙ₆₂ | Ar130 | CN | H | H | H | H | H | H |
| Lₐ₅₇₈₂ | Rₙ₆₄ | Ar130 | CN | H | H | H | H | H | H |
| Lₐ₅₇₈₃ | Rₙ₆₉ | Ar130 | CN | H | H | H | H | H | H |
| Lₐ₅₇₈₄ | Rₙ₇₀ | Ar130 | CN | H | H | H | H | H | H |
| Lₐ₅₇₈₅ | Rₙ₁ | Ar130 | H | H | CN | H | Rₙ₁₁ | H | H |
| Lₐ₅₇₈₆ | Rₙ₄ | Ar130 | H | H | CN | H | Rₙ₁₁ | H | H |
| Lₐ₅₇₈₇ | Rₙ₇ | Ar130 | H | H | CN | H | Rₙ₁₁ | H | H |
| Lₐ₅₇₈₈ | Rₙ₂₀ | Ar130 | H | H | CN | H | Rₙ₁₁ | H | H |
| Lₐ₅₇₈₉ | Rₙ₂₁ | Ar130 | H | H | CN | H | Rₙ₁₁ | H | H |
| Lₐ₅₇₉₀ | Rₙ₅₆ | Ar130 | H | H | CN | H | Rₙ₁₁ | H | H |
| Lₐ₅₇₉₁ | Rₙ₅₉ | Ar130 | H | H | CN | H | Rₙ₁₁ | H | H |
| Lₐ₅₇₉₂ | Rₙ₆₁ | Ar130 | H | H | CN | H | Rₙ₁₁ | H | H |
| Lₐ₅₇₉₃ | Rₙ₆₂ | Ar130 | H | H | CN | H | Rₙ₁₁ | H | H |
| Lₐ₅₇₉₄ | Rₙ₆₄ | Ar130 | H | H | CN | H | Rₙ₁₁ | H | H |
| Lₐ₅₇₉₅ | Rₙ₆₉ | Ar130 | H | H | CN | H | Rₙ₁₁ | H | H |
| Lₐ₅₇₉₆ | Rₙ₇₀ | Ar130 | H | H | CN | H | Rₙ₁₁ | H | H |
| Lₐ₅₇₉₇ | Rₙ₁ | Ar130 | D | H | CN | H | Rₙ₆₀ | H | H |
| Lₐ₅₇₉₈ | Rₙ₄ | Ar130 | H | H | CN | H | Rₙ₆₀ | H | H |
| Lₐ₅₇₉₉ | Rₙ₇ | Ar130 | H | H | CN | H | Rₙ₆₀ | H | H |
| Lₐ₅₈₀₀ | Rₙ₂₀ | Ar130 | H | H | CN | H | Rₙ₆₀ | H | H |
| Lₐ₅₈₀₁ | Rₙ₂₁ | Ar130 | H | D | CN | H | Rₙ₆₀ | H | H |
| Lₐ₅₈₀₂ | Rₙ₅₆ | Ar130 | H | H | CN | H | Rₙ₆₀ | H | H |
| Lₐ₅₈₀₃ | Rₙ₅₉ | Ar130 | H | H | CN | H | Rₙ₆₀ | H | D |
| Lₐ₅₈₀₄ | Rₙ₆₁ | Ar130 | H | H | CN | H | Rₙ₆₀ | H | H |
| Lₐ₅₈₀₅ | Rₙ₆₂ | Ar130 | H | H | CN | H | Rₙ₆₀ | H | H |
| Lₐ₅₈₀₆ | Rₙ₆₄ | Ar130 | H | H | CN | H | Rₙ₆₀ | H | H |
| Lₐ₅₈₀₇ | Rₙ₆₉ | Ar130 | H | H | CN | H | Rₙ₆₀ | H | H |
| Lₐ₅₈₀₈ | Rₙ₇₀ | Ar130 | H | H | CN | H | Rₙ₆₀ | D | H |
| Lₐ₅₈₀₉ | Rₙ₁ | Ar130 | H | H | CN | H | Rₙ₆₄ | H | H |
| Lₐ₅₈₁₀ | Rₙ₄ | Ar130 | H | H | CN | H | Rₙ₆₄ | H | H |
| Lₐ₅₈₁₁ | Rₙ₇ | Ar130 | H | H | CN | H | Rₙ₆₄ | H | H |
| Lₐ₅₈₁₂ | Rₙ₂₀ | Ar130 | H | H | CN | H | Rₙ₆₄ | H | H |
| Lₐ₅₈₁₃ | Rₙ₂₁ | Ar130 | H | H | CN | H | Rₙ₆₄ | H | H |
| Lₐ₅₈₁₄ | Rₙ₅₆ | Ar130 | H | H | CN | H | Rₙ₆₄ | H | H |
| Lₐ₅₈₁₅ | Rₙ₅₉ | Ar130 | H | H | CN | H | Rₙ₆₄ | H | H |
| Lₐ₅₈₁₆ | Rₙ₆₁ | Ar130 | H | H | CN | H | Rₙ₆₄ | H | H |
| Lₐ₅₈₁₇ | Rₙ₆₂ | Ar130 | H | H | CN | H | Rₙ₆₄ | H | H |
| Lₐ₅₈₁₈ | Rₙ₆₄ | Ar130 | H | H | CN | H | Rₙ₆₄ | H | H |
| Lₐ₅₈₁₉ | Rₙ₆₉ | Ar130 | H | H | CN | H | Rₙ₆₄ | H | H |
| Lₐ₅₈₂₀ | Rₙ₇₀ | Ar130 | H | H | CN | H | Rₙ₆₄ | H | H |
| Lₐ₅₈₂₁ | Rₙ₁ | Ar130 | H | H | CN | H | H | Rₙ₁₁ | H |
| Lₐ₅₈₂₂ | Rₙ₄ | Ar130 | H | H | CN | H | H | Rₙ₁₁ | H |
| Lₐ₅₈₂₃ | Rₙ₇ | Ar130 | H | H | CN | H | H | Rₙ₁₁ | H |
| Lₐ₅₈₂₄ | Rₙ₂₀ | Ar130 | H | H | CN | H | H | Rₙ₁₁ | H |
| Lₐ₅₈₂₅ | Rₙ₂₁ | Ar130 | H | H | CN | H | H | Rₙ₁₁ | H |
| Lₐ₅₈₂₆ | Rₙ₅₆ | Ar130 | H | H | CN | H | H | Rₙ₁₁ | H |
| Lₐ₅₈₂₇ | Rₙ₅₉ | Ar130 | H | H | CN | H | H | Rₙ₁₁ | H |
| Lₐ₅₈₂₈ | Rₙ₆₁ | Ar130 | H | H | CN | H | H | Rₙ₁₁ | H |
| Lₐ₅₈₂₉ | Rₙ₆₂ | Ar130 | H | H | CN | H | H | Rₙ₁₁ | H |
| Lₐ₅₈₃₀ | Rₙ₆₄ | Ar130 | H | H | CN | H | H | Rₙ₁₁ | H |
| Lₐ₅₈₃₁ | Rₙ₆₉ | Ar130 | H | H | CN | H | H | Rₙ₁₁ | H |
| Lₐ₅₈₃₂ | Rₙ₇₀ | Ar130 | H | H | CN | H | H | Rₙ₁₁ | D |
| Lₐ₅₈₃₃ | Rₙ₁ | Ar130 | H | H | CN | H | H | Rₙ₆₀ | H |
| Lₐ₅₈₃₄ | Rₙ₄ | Ar130 | H | H | CN | H | H | Rₙ₆₀ | H |
| Lₐ₅₈₃₅ | Rₙ₇ | Ar130 | H | H | CN | H | D | Rₙ₆₀ | H |
| Lₐ₅₈₃₆ | Rₙ₂₀ | Ar130 | H | H | CN | H | H | Rₙ₆₀ | H |
| Lₐ₅₈₃₇ | Rₙ₂₁ | Ar130 | H | H | CN | H | H | Rₙ₆₀ | H |
| Lₐ₅₈₃₈ | Rₙ₅₆ | Ar130 | H | H | CN | H | H | Rₙ₆₀ | H |
| Lₐ₅₈₃₉ | Rₙ₅₉ | Ar130 | H | H | CN | H | H | Rₙ₆₀ | H |
| Lₐ₅₈₄₀ | Rₙ₆₁ | Ar130 | H | H | CN | D | H | Rₙ₆₀ | H |
| Lₐ₅₈₄₁ | Rₙ₆₂ | Ar130 | H | H | CN | H | H | Rₙ₆₀ | H |
| Lₐ₅₈₄₂ | Rₙ₆₄ | Ar130 | H | H | CN | H | H | Rₙ₆₀ | H |
| Lₐ₅₈₄₃ | Rₙ₆₉ | Ar130 | H | H | CN | H | H | Rₙ₆₀ | H |
| Lₐ₅₈₄₄ | Rₙ₇₀ | Ar130 | H | D | CN | H | H | Rₙ₆₀ | H |
| Lₐ₅₈₄₅ | Rₙ₁ | Ar130 | H | H | CN | H | H | Rₙ₆₄ | H |
| Lₐ₅₈₄₆ | Rₙ₄ | Ar130 | H | H | CN | H | H | Rₙ₆₄ | H |
| Lₐ₅₈₄₇ | Rₙ₇ | Ar130 | H | H | CN | H | H | Rₙ₆₄ | H |
| Lₐ₅₈₄₈ | Rₙ₂₀ | Ar130 | H | H | CN | H | H | Rₙ₆₄ | H |
| Lₐ₅₈₄₉ | Rₙ₂₁ | Ar130 | H | H | CN | H | H | Rₙ₆₄ | H |
| Lₐ₅₈₅₀ | Rₙ₅₆ | Ar130 | H | H | CN | H | H | Rₙ₆₄ | H |
| Lₐ₅₈₅₁ | Rₙ₅₉ | Ar130 | H | H | CN | H | H | Rₙ₆₄ | H |
| Lₐ₅₈₅₂ | Rₙ₆₁ | Ar130 | H | H | CN | H | H | Rₙ₆₄ | H |
| Lₐ₅₈₅₃ | Rₙ₆₂ | Ar130 | D | H | CN | H | H | Rₙ₆₄ | H |
| Lₐ₅₈₅₄ | Rₙ₆₄ | Ar130 | H | H | CN | H | H | Rₙ₆₄ | H |
| Lₐ₅₈₅₅ | Rₙ₆₉ | Ar130 | H | H | CN | H | H | Rₙ₆₄ | H |
| Lₐ₅₈₅₆ | Rₙ₇₀ | Ar130 | H | H | CN | H | H | Rₙ₆₄ | H |
| Lₐ₅₈₅₇ | Rₙ₁ | Ar137 | H | H | H | H | H | H | H |
| Lₐ₅₈₅₈ | Rₙ₄ | Ar137 | H | H | H | H | H | H | H |
| Lₐ₅₈₅₉ | Rₙ₅ | Ar137 | H | H | H | H | H | H | H |
| Lₐ₅₈₆₀ | Rₙ₇ | Ar137 | H | H | H | H | H | H | H |
| Lₐ₅₈₆₁ | Rₙ₁₁ | Ar137 | H | H | H | H | H | H | H |
| Lₐ₅₈₆₂ | Rₙ₂₀ | Ar137 | H | H | H | H | H | H | H |
| Lₐ₅₈₆₃ | Rₙ₂₁ | Ar137 | H | H | H | H | H | H | H |
| Lₐ₅₈₆₄ | Rₙ₅₁ | Ar137 | H | H | H | H | H | H | H |
| Lₐ₅₈₆₅ | Rₙ₅₆ | Ar137 | H | H | H | H | H | H | H |
| Lₐ₅₈₆₆ | Rₙ₅₉ | Ar137 | H | H | H | H | H | H | H |
| Lₐ₅₈₆₇ | Rₙ₆₀ | Ar137 | H | H | H | H | H | H | H |
| Lₐ₅₈₆₈ | Rₙ₆₁ | Ar137 | H | H | H | H | H | H | H |
| Lₐ₅₈₆₉ | Rₙ₆₂ | Ar137 | H | H | H | H | H | H | H |
| Lₐ₅₈₇₀ | Rₙ₆₄ | Ar137 | H | H | H | H | H | H | H |
| Lₐ₅₈₇₁ | Rₙ₆₅ | Ar137 | H | H | H | H | H | H | H |
| Lₐ₅₈₇₂ | Rₙ₆₉ | Ar137 | H | H | H | H | H | H | H |
| Lₐ₅₈₇₃ | Rₙ₇₀ | Ar137 | H | H | H | H | H | H | H |
| Lₐ₅₈₇₄ | Rₙ₈₁ | Ar137 | H | H | H | H | H | H | H |
| Lₐ₅₈₇₅ | Rₙ₁ | Ar137 | H | H | H | H | H | Rₙ₁₁ | H |
| Lₐ₅₈₇₆ | Rₙ₄ | Ar137 | H | H | H | H | H | Rₙ₁₁ | H |
| Lₐ₅₈₇₇ | Rₙ₅ | Ar137 | H | H | H | H | H | Rₙ₁₁ | H |
| Lₐ₅₈₇₈ | Rₙ₇ | Ar137 | H | H | H | H | H | Rₙ₁₁ | H |
| Lₐ₅₈₇₉ | Rₙ₁₁ | Ar137 | H | H | H | H | H | Rₙ₁₁ | H |
| Lₐ₅₈₈₀ | Rₙ₂₀ | Ar137 | H | H | H | H | H | Rₙ₁₁ | H |
| Lₐ₅₈₈₁ | Rₙ₂₁ | Ar137 | H | H | H | H | H | Rₙ₁₁ | H |
| Lₐ₅₈₈₂ | Rₙ₅₁ | Ar137 | H | H | H | H | H | Rₙ₁₁ | H |
| Lₐ₅₈₈₃ | Rₙ₅₆ | Ar137 | H | H | H | H | H | Rₙ₁₁ | H |
| Lₐ₅₈₈₄ | Rₙ₅₉ | Ar137 | H | H | H | H | H | Rₙ₁₁ | H |
| Lₐ₅₈₈₅ | Rₙ₆₀ | Ar137 | H | H | H | H | H | Rₙ₁₁ | H |
| Lₐ₅₈₈₆ | Rₙ₆₁ | Ar137 | H | H | H | H | H | Rₙ₁₁ | H |
| Lₐ₅₈₈₇ | Rₙ₆₂ | Ar137 | H | H | H | H | H | Rₙ₁₁ | H |
| Lₐ₅₈₈₈ | Rₙ₆₄ | Ar137 | H | H | H | H | H | Rₙ₁₁ | H |
| Lₐ₅₈₈₉ | Rₙ₆₅ | Ar137 | H | H | H | H | H | Rₙ₁₁ | H |
| Lₐ₅₈₉₀ | Rₙ₆₉ | Ar137 | H | H | H | H | H | Rₙ₁₁ | H |
| Lₐ₅₈₉₁ | Rₙ₇₀ | Ar137 | H | H | H | H | H | Rₙ₁₁ | H |
| Lₐ₅₈₉₂ | Rₙ₈₁ | Ar137 | H | H | H | H | H | Rₙ₁₁ | H |
| Lₐ₅₈₉₃ | Rₙ₁ | Ar137 | H | H | H | H | H | Rₙ₅₉ | H |
| Lₐ₅₈₉₄ | Rₙ₄ | Ar137 | H | H | H | H | H | Rₙ₅₉ | H |
| Lₐ₅₈₉₅ | Rₙ₅ | Ar137 | H | H | H | H | H | Rₙ₅₉ | H |
| Lₐ₅₈₉₆ | Rₙ₇ | Ar137 | H | H | H | H | H | Rₙ₅₉ | H |
| Lₐ₅₈₉₇ | Rₙ₁₁ | Ar137 | H | H | H | H | H | Rₙ₅₉ | H |
| Lₐ₅₈₉₈ | Rₙ₂₀ | Ar137 | H | H | H | H | H | Rₙ₅₉ | H |
| Lₐ₅₈₉₉ | Rₙ₂₁ | Ar137 | H | H | H | H | H | Rₙ₅₉ | H |
| Lₐ₅₉₀₀ | Rₙ₅₁ | Ar137 | H | H | H | H | H | Rₙ₅₉ | H |
| Lₐ₅₉₀₁ | Rₙ₅₆ | Ar137 | H | H | H | H | H | Rₙ₅₉ | H |
| Lₐ₅₉₀₂ | Rₙ₅₉ | Ar137 | H | H | H | H | H | Rₙ₅₉ | H |
| Lₐ₅₉₀₃ | Rₙ₆₀ | Ar137 | H | H | H | H | H | Rₙ₅₉ | H |
| Lₐ₅₉₀₄ | Rₙ₆₁ | Ar137 | H | H | H | H | H | Rₙ₅₉ | H |
| Lₐ₅₉₀₅ | Rₙ₆₂ | Ar137 | H | H | H | H | H | Rₙ₅₉ | H |
| Lₐ₅₉₀₆ | Rₙ₆₄ | Ar137 | H | H | H | H | H | Rₙ₅₉ | H |
| Lₐ₅₉₀₇ | Rₙ₆₅ | Ar137 | H | H | H | H | H | Rₙ₅₉ | H |
| Lₐ₅₉₀₈ | Rₙ₆₉ | Ar137 | H | H | H | H | H | Rₙ₅₉ | H |
| Lₐ₅₉₀₉ | Rₙ₇₀ | Ar137 | H | H | H | H | H | Rₙ₅₉ | H |
| Lₐ₅₉₁₀ | Rₙ₈₁ | Ar137 | H | H | H | H | H | Rₙ₅₉ | H |
| Lₐ₅₉₁₁ | Rₙ₁ | Ar137 | H | H | H | H | H | Rₙ₆₀ | H |
| Lₐ₅₉₁₂ | Rₙ₄ | Ar137 | H | H | H | H | H | Rₙ₆₀ | H |
| Lₐ₅₉₁₃ | Rₙ₅ | Ar137 | H | H | H | H | H | Rₙ₆₀ | H |
| Lₐ₅₉₁₄ | Rₙ₇ | Ar137 | H | H | H | H | H | Rₙ₆₀ | H |
| Lₐ₅₉₁₅ | Rₙ₁₁ | Ar137 | H | H | H | H | H | Rₙ₆₀ | H |
| Lₐ₅₉₁₆ | Rₙ₂₀ | Ar137 | H | H | H | H | H | Rₙ₆₀ | H |
| Lₐ₅₉₁₇ | Rₙ₂₁ | Ar137 | H | H | H | H | H | Rₙ₆₀ | H |
| Lₐ₅₉₁₈ | Rₙ₅₁ | Ar137 | H | H | H | H | H | Rₙ₆₀ | H |
| Lₐ₅₉₁₉ | Rₙ₅₆ | Ar137 | H | H | H | H | H | Rₙ₆₀ | H |
| Lₐ₅₉₂₀ | Rₙ₅₉ | Ar137 | H | H | H | H | H | Rₙ₆₀ | H |
| Lₐ₅₉₂₁ | Rₙ₆₀ | Ar137 | H | H | H | H | H | Rₙ₆₀ | H |
| Lₐ₅₉₂₂ | Rₙ₆₁ | Ar137 | H | H | H | H | H | Rₙ₆₀ | H |
| Lₐ₅₉₂₃ | Rₙ₆₂ | Ar137 | H | H | H | H | H | Rₙ₆₀ | H |
| Lₐ₅₉₂₄ | Rₙ₆₄ | Ar137 | H | H | H | H | H | Rₙ₆₀ | H |
| Lₐ₅₉₂₅ | Rₙ₆₅ | Ar137 | H | H | H | H | H | Rₙ₆₀ | H |
| Lₐ₅₉₂₆ | Rₙ₆₉ | Ar137 | H | H | H | H | H | Rₙ₆₀ | H |
| Lₐ₅₉₂₇ | Rₙ₇₀ | Ar137 | H | H | H | H | H | Rₙ₆₀ | H |
| Lₐ₅₉₂₈ | Rₙ₈₁ | Ar137 | H | H | H | H | H | Rₙ₆₀ | H |
| Lₐ₅₉₂₉ | Rₙ₁ | Ar137 | H | H | H | H | H | Rₙ₆₄ | H |
| Lₐ₅₉₃₀ | Rₙ₄ | Ar137 | H | H | H | H | H | Rₙ₆₄ | H |
| Lₐ₅₉₃₁ | Rₙ₅ | Ar137 | H | H | H | H | H | Rₙ₆₄ | H |
| Lₐ₅₉₃₂ | Rₙ₇ | Ar137 | H | H | H | H | H | Rₙ₆₄ | H |
| Lₐ₅₉₃₃ | Rₙ₁₁ | Ar137 | H | H | H | H | H | Rₙ₆₄ | H |
| Lₐ₅₉₃₄ | Rₙ₂₀ | Ar137 | H | H | H | H | H | Rₙ₆₄ | H |
| Lₐ₅₉₃₅ | Rₙ₂₁ | Ar137 | H | H | H | H | H | Rₙ₆₄ | H |
| Lₐ₅₉₃₆ | Rₙ₅₁ | Ar137 | H | H | H | H | H | Rₙ₆₄ | H |
| Lₐ₅₉₃₇ | Rₙ₅₆ | Ar137 | H | H | H | H | H | Rₙ₆₄ | H |
| Lₐ₅₉₃₈ | Rₙ₅₉ | Ar137 | H | H | H | H | H | Rₙ₆₄ | H |
| Lₐ₅₉₃₉ | Rₙ₆₀ | Ar137 | H | H | H | H | H | Rₙ₆₄ | H |
| Lₐ₅₉₄₀ | Rₙ₆₁ | Ar137 | H | H | H | H | H | Rₙ₆₄ | H |
| Lₐ₅₉₄₁ | Rₙ₆₂ | Ar137 | H | H | H | H | H | Rₙ₆₄ | H |
| Lₐ₅₉₄₂ | Rₙ₆₄ | Ar137 | H | H | H | H | H | Rₙ₆₄ | H |
| Lₐ₅₉₄₃ | Rₙ₆₅ | Ar137 | H | H | H | H | H | Rₙ₆₄ | H |
| Lₐ₅₉₄₄ | Rₙ₆₉ | Ar137 | H | H | H | H | H | Rₙ₆₄ | H |
| Lₐ₅₉₄₅ | Rₙ₇₀ | Ar137 | H | H | H | H | H | Rₙ₆₄ | H |
| Lₐ₅₉₄₆ | Rₙ₈₁ | Ar137 | H | H | H | H | H | Rₙ₆₄ | H |
| Lₐ₅₉₄₇ | Rₙ₁ | Ar137 | H | H | H | H | H | Me | H |
| Lₐ₅₉₄₈ | Rₙ₄ | Ar137 | H | H | H | H | H | Me | H |
| Lₐ₅₉₄₉ | Rₙ₅ | Ar137 | H | H | H | H | H | Me | H |
| Lₐ₅₉₅₀ | Rₙ₇ | Ar137 | H | H | H | H | H | Me | H |
| Lₐ₅₉₅₁ | Rₙ₁₁ | Ar137 | H | H | H | H | H | Me | H |
| Lₐ₅₉₅₂ | Rₙ₂₀ | Ar137 | H | H | H | H | H | Me | H |
| Lₐ₅₉₅₃ | Rₙ₂₁ | Ar137 | H | H | H | H | H | Me | H |
| Lₐ₅₉₅₄ | Rₙ₅₁ | Ar137 | H | H | H | H | H | Me | H |
| Lₐ₅₉₅₅ | Rₙ₅₆ | Ar137 | H | H | H | H | H | Me | H |
| Lₐ₅₉₅₆ | Rₙ₅₉ | Ar137 | H | H | H | H | H | Me | H |
| Lₐ₅₉₅₇ | Rₙ₆₀ | Ar137 | H | H | H | H | H | Me | H |
| Lₐ₅₉₅₈ | Rₙ₆₁ | Ar137 | H | H | H | H | H | Me | H |
| Lₐ₅₉₅₉ | Rₙ₆₂ | Ar137 | H | H | H | H | H | Me | H |
| Lₐ₅₉₆₀ | Rₙ₆₄ | Ar137 | H | H | H | H | H | Me | H |
| Lₐ₅₉₆₁ | Rₙ₆₅ | Ar137 | H | H | H | H | H | Me | H |
| Lₐ₅₉₆₂ | Rₙ₆₉ | Ar137 | H | H | H | H | H | Me | H |
| Lₐ₅₉₆₃ | Rₙ₇₀ | Ar137 | H | H | H | H | H | Me | H |
| Lₐ₅₉₆₄ | Rₙ₈₁ | Ar137 | H | H | H | H | H | Me | H |
| Lₐ₅₉₆₅ | Rₙ₁ | Ar137 | H | H | H | H | Rₙ₁₁ | H | H |
| Lₐ₅₉₆₆ | Rₙ₄ | Ar137 | H | H | H | H | Rₙ₁₁ | H | H |
| Lₐ₅₉₆₇ | Rₙ₅ | Ar137 | H | H | H | H | Rₙ₁₁ | H | H |
| Lₐ₅₉₆₈ | Rₙ₇ | Ar137 | H | H | H | H | Rₙ₁₁ | H | H |
| Lₐ₅₉₆₉ | Rₙ₁₁ | Ar137 | H | H | H | H | Rₙ₁₁ | H | H |
| Lₐ₅₉₇₀ | Rₙ₂₀ | Ar137 | H | H | H | H | Rₙ₁₁ | H | H |
| Lₐ₅₉₇₁ | Rₙ₂₁ | Ar137 | H | H | H | H | Rₙ₁₁ | H | H |
| Lₐ₅₉₇₂ | Rₙ₅₁ | Ar137 | H | H | H | H | Rₙ₁₁ | H | H |
| Lₐ₅₉₇₃ | Rₙ₅₆ | Ar137 | H | H | H | H | Rₙ₁₁ | H | H |
| Lₐ₅₉₇₄ | Rₙ₅₉ | Ar137 | H | H | H | H | Rₙ₁₁ | H | H |
| Lₐ₅₉₇₅ | Rₙ₆₀ | Ar137 | H | H | H | H | Rₙ₁₁ | H | H |
| Lₐ₅₉₇₆ | Rₙ₆₁ | Ar137 | H | H | H | H | Rₙ₁₁ | H | H |
| Lₐ₅₉₇₇ | Rₙ₆₂ | Ar137 | H | H | H | H | Rₙ₁₁ | H | H |
| Lₐ₅₉₇₈ | Rₙ₆₄ | Ar137 | H | H | H | H | Rₙ₁₁ | H | H |
| Lₐ₅₉₇₉ | Rₙ₆₅ | Ar137 | H | H | H | H | Rₙ₁₁ | H | H |
| Lₐ₅₉₈₀ | Rₙ₆₉ | Ar137 | H | H | H | H | Rₙ₁₁ | H | H |
| Lₐ₅₉₈₁ | Rₙ₇₀ | Ar137 | H | H | H | H | Rₙ₁₁ | H | H |
| Lₐ₅₉₈₂ | Rₙ₈₁ | Ar137 | H | H | H | H | Rₙ₁₁ | H | H |
| Lₐ₅₉₈₃ | Rₙ₁ | Ar137 | H | H | H | H | Rₙ₅₉ | H | H |
| Lₐ₅₉₈₄ | Rₙ₄ | Ar137 | H | H | H | H | Rₙ₅₉ | H | H |
| Lₐ₅₉₈₅ | Rₙ₅ | Ar137 | H | H | H | H | Rₙ₅₉ | H | H |
| Lₐ₅₉₈₆ | Rₙ₇ | Ar137 | H | H | H | H | Rₙ₅₉ | H | H |
| Lₐ₅₉₈₇ | Rₙ₁₁ | Ar137 | H | H | H | H | Rₙ₅₉ | H | H |
| Lₐ₅₉₈₈ | Rₙ₂₀ | Ar137 | H | H | H | H | Rₙ₅₉ | H | H |
| Lₐ₅₉₈₉ | Rₙ₂₁ | Ar137 | H | H | H | H | Rₙ₅₉ | H | H |
| Lₐ₅₉₉₀ | Rₙ₅₁ | Ar137 | H | H | H | H | Rₙ₅₉ | H | H |
| Lₐ₅₉₉₁ | Rₙ₅₆ | Ar137 | H | H | H | H | Rₙ₅₉ | H | H |
| Lₐ₅₉₉₂ | Rₙ₅₉ | Ar137 | H | H | H | H | Rₙ₅₉ | H | H |
| Lₐ₅₉₉₃ | Rₙ₆₀ | Ar137 | H | H | H | H | Rₙ₅₉ | H | H |
| Lₐ₅₉₉₄ | Rₙ₆₁ | Ar137 | H | H | H | H | Rₙ₅₉ | H | H |
| Lₐ₅₉₉₅ | Rₙ₆₂ | Ar137 | H | H | H | H | Rₙ₅₉ | H | H |
| Lₐ₅₉₉₆ | Rₙ₆₄ | Ar137 | H | H | H | H | Rₙ₅₉ | H | H |
| Lₐ₅₉₉₇ | Rₙ₆₅ | Ar137 | H | H | H | H | Rₙ₅₉ | H | H |
| Lₐ₅₉₉₈ | Rₙ₆₉ | Ar137 | H | H | H | H | Rₙ₅₉ | H | H |
| Lₐ₅₉₉₉ | Rₙ₇₀ | Ar137 | H | H | H | H | Rₙ₅₉ | H | H |
| Lₐ₆₀₀₀ | Rₙ₈₁ | Ar137 | H | H | H | H | Rₙ₅₉ | H | H |
| Lₐ₆₀₀₁ | Rₙ₁ | Ar137 | H | H | H | H | Rₙ₆₀ | H | H |
| Lₐ₆₀₀₂ | Rₙ₄ | Ar137 | H | H | H | H | Rₙ₆₀ | H | H |
| Lₐ₆₀₀₃ | Rₙ₅ | Ar137 | H | H | H | H | Rₙ₆₀ | H | H |
| Lₐ₆₀₀₄ | Rₙ₇ | Ar137 | H | H | H | H | Rₙ₆₀ | H | H |
| Lₐ₆₀₀₅ | Rₙ₁₁ | Ar137 | H | H | H | H | Rₙ₆₀ | H | H |
| Lₐ₆₀₀₆ | Rₙ₂₀ | Ar137 | H | H | H | H | Rₙ₆₀ | H | H |
| Lₐ₆₀₀₇ | Rₙ₂₁ | Ar137 | H | H | H | H | Rₙ₆₀ | H | H |
| Lₐ₆₀₀₈ | Rₙ₅₁ | Ar137 | H | H | H | H | Rₙ₆₀ | H | H |
| Lₐ₆₀₀₉ | Rₙ₅₆ | Ar137 | H | H | H | H | Rₙ₆₀ | H | H |
| Lₐ₆₀₁₀ | Rₙ₅₉ | Ar137 | H | H | H | H | Rₙ₆₀ | H | H |
| Lₐ₆₀₁₁ | Rₙ₆₀ | Ar137 | H | H | H | H | Rₙ₆₀ | H | H |
| Lₐ₆₀₁₂ | Rₙ₆₁ | Ar137 | H | H | H | H | Rₙ₆₀ | H | H |
| Lₐ₆₀₁₃ | Rₙ₆₂ | Ar137 | H | H | H | H | Rₙ₆₀ | H | H |
| Lₐ₆₀₁₄ | Rₙ₆₄ | Ar137 | H | H | H | H | Rₙ₆₀ | H | H |
| Lₐ₆₀₁₅ | Rₙ₆₅ | Ar137 | H | H | H | H | Rₙ₆₀ | H | H |
| Lₐ₆₀₁₆ | Rₙ₆₉ | Ar137 | H | H | H | H | Rₙ₆₀ | H | H |
| Lₐ₆₀₁₇ | Rₙ₇₀ | Ar137 | H | H | H | H | Rₙ₆₀ | H | H |
| Lₐ₆₀₁₈ | Rₙ₈₁ | Ar137 | H | H | H | H | Rₙ₆₀ | H | H |
| Lₐ₆₀₁₉ | Rₙ₁ | Ar137 | H | H | H | H | Rₙ₆₄ | H | H |
| Lₐ₆₀₂₀ | Rₙ₄ | Ar137 | H | H | H | H | Rₙ₆₄ | H | H |
| Lₐ₆₀₂₁ | Rₙ₅ | Ar137 | H | H | H | H | Rₙ₆₄ | H | H |
| Lₐ₆₀₂₂ | Rₙ₇ | Ar137 | H | H | H | H | Rₙ₆₄ | H | H |
| Lₐ₆₀₂₃ | Rₙ₁₁ | Ar137 | H | H | H | H | Rₙ₆₄ | H | H |
| Lₐ₆₀₂₄ | Rₙ₂₀ | Ar137 | H | H | H | H | Rₙ₆₄ | H | H |
| Lₐ₆₀₂₅ | Rₙ₂₁ | Ar137 | H | H | H | H | Rₙ₆₄ | H | H |
| Lₐ₆₀₂₆ | Rₙ₅₁ | Ar137 | H | H | H | H | Rₙ₆₄ | H | H |
| Lₐ₆₀₂₇ | Rₙ₅₆ | Ar137 | H | H | H | H | Rₙ₆₄ | H | H |
| Lₐ₆₀₂₈ | Rₙ₅₉ | Ar137 | H | H | H | H | Rₙ₆₄ | H | H |
| Lₐ₆₀₂₉ | Rₙ₆₀ | Ar137 | H | H | H | H | Rₙ₆₄ | H | H |
| Lₐ₆₀₃₀ | Rₙ₆₁ | Ar137 | H | H | H | H | Rₙ₆₄ | H | H |
| Lₐ₆₀₃₁ | Rₙ₆₂ | Ar137 | H | H | H | H | Rₙ₆₄ | H | H |
| Lₐ₆₀₃₂ | Rₙ₆₄ | Ar137 | H | H | H | H | Rₙ₆₄ | H | H |
| Lₐ₆₀₃₃ | Rₙ₆₅ | Ar137 | H | H | H | H | Rₙ₆₄ | H | H |
| Lₐ₆₀₃₄ | Rₙ₆₉ | Ar137 | H | H | H | H | Rₙ₆₄ | H | H |
| Lₐ₆₀₃₅ | Rₙ₇₀ | Ar137 | H | H | H | H | Rₙ₆₄ | H | H |
| Lₐ₆₀₃₆ | Rₙ₈₁ | Ar137 | H | H | H | H | Rₙ₆₄ | H | H |
| Lₐ₆₀₃₇ | Rₙ₁ | Ar137 | H | H | H | H | Me | H | H |
| Lₐ₆₀₃₈ | Rₙ₄ | Ar137 | H | H | H | H | Me | H | H |
| Lₐ₆₀₃₉ | Rₙ₅ | Ar137 | H | H | H | H | Me | H | H |
| Lₐ₆₀₄₀ | Rₙ₇ | Ar137 | H | H | H | H | Me | H | H |
| Lₐ₆₀₄₁ | Rₙ₁₁ | Ar137 | H | H | H | H | Me | H | H |
| Lₐ₆₀₄₂ | Rₙ₂₀ | Ar137 | H | H | H | H | Me | H | H |
| Lₐ₆₀₄₃ | Rₙ₂₁ | Ar137 | H | H | H | H | Me | H | H |
| Lₐ₆₀₄₄ | Rₙ₅₁ | Ar137 | H | H | H | H | Me | H | H |
| Lₐ₆₀₄₅ | Rₙ₅₆ | Ar137 | H | H | H | H | Me | H | H |
| Lₐ₆₀₄₆ | Rₙ₅₉ | Ar137 | H | H | H | H | Me | H | H |
| Lₐ₆₀₄₇ | Rₙ₆₀ | Ar137 | H | H | H | H | Me | H | H |
| Lₐ₆₀₄₈ | Rₙ₆₁ | Ar137 | H | H | H | H | Me | H | H |
| Lₐ₆₀₄₉ | Rₙ₆₂ | Ar137 | H | H | H | H | Me | H | H |
| Lₐ₆₀₅₀ | Rₙ₆₄ | Ar137 | H | H | H | H | Me | H | H |
| Lₐ₆₀₅₁ | Rₙ₆₅ | Ar137 | H | H | H | H | Me | H | H |
| Lₐ₆₀₅₂ | Rₙ₆₉ | Ar137 | H | H | H | H | Me | H | H |
| Lₐ₆₀₅₃ | Rₙ₇₀ | Ar137 | H | H | H | H | Me | H | H |
| Lₐ₆₀₅₄ | Rₙ₈₁ | Ar137 | H | H | H | H | Me | H | H |
| Lₐ₆₀₅₅ | Rₙ₁ | Ar137 | H | H | F | H | H | H | H |
| Lₐ₆₀₅₆ | Rₙ₄ | Ar137 | H | H | F | H | H | H | H |
| Lₐ₆₀₅₇ | Rₙ₇ | Ar137 | H | H | F | H | H | H | H |
| Lₐ₆₀₅₈ | Rₙ₂₀ | Ar137 | H | H | F | H | H | H | H |
| Lₐ₆₀₅₉ | Rₙ₂₁ | Ar137 | D | H | F | H | H | H | H |
| Lₐ₆₀₆₀ | Rₙ₅₆ | Ar137 | H | H | F | H | H | H | H |
| Lₐ₆₀₆₁ | Rₙ₅₉ | Ar137 | H | D | F | H | H | H | H |
| Lₐ₆₀₆₂ | Rₙ₆₁ | Ar137 | H | H | F | H | H | H | H |
| Lₐ₆₀₆₃ | Rₙ₆₂ | Ar137 | H | H | F | H | H | H | H |
| Lₐ₆₀₆₄ | Rₙ₆₄ | Ar137 | H | H | F | H | H | H | H |
| Lₐ₆₀₆₅ | Rₙ₆₉ | Ar137 | H | H | F | H | H | H | H |
| Lₐ₆₀₆₆ | Rₙ₇₀ | Ar137 | H | H | F | H | H | H | H |
| Lₐ₆₀₆₇ | Rₙ₁ | Ar137 | H | H | F | H | Rₙ₁₁ | H | H |
| Lₐ₆₀₆₈ | Rₙ₄ | Ar137 | H | H | F | H | Rₙ₁₁ | H | H |
| Lₐ₆₀₆₉ | Rₙ₇ | Ar137 | H | H | F | H | Rₙ₁₁ | H | H |
| Lₐ₆₀₇₀ | Rₙ₂₀ | Ar137 | H | H | F | H | Rₙ₁₁ | H | H |
| Lₐ₆₀₇₁ | Rₙ₂₁ | Ar137 | H | H | F | H | Rₙ₁₁ | H | H |
| Lₐ₆₀₇₂ | Rₙ₅₆ | Ar137 | H | H | F | H | Rₙ₁₁ | H | H |
| Lₐ₆₀₇₃ | Rₙ₅₉ | Ar137 | H | H | F | H | Rₙ₁₁ | H | H |
| Lₐ₆₀₇₄ | Rₙ₆₁ | Ar137 | H | H | F | H | Rₙ₁₁ | H | H |
| Lₐ₆₀₇₅ | Rₙ₆₂ | Ar137 | H | H | F | H | Rₙ₁₁ | H | H |
| Lₐ₆₀₇₆ | Rₙ₆₄ | Ar137 | H | H | F | H | Rₙ₁₁ | H | H |
| Lₐ₆₀₇₇ | Rₙ₆₉ | Ar137 | H | H | F | H | Rₙ₁₁ | H | H |
| Lₐ₆₀₇₈ | Rₙ₇₀ | Ar137 | H | H | F | H | Rₙ₁₁ | H | H |
| Lₐ₆₀₇₉ | Rₙ₁ | Ar137 | H | H | F | H | Rₙ₆₀ | H | H |
| Lₐ₆₀₈₀ | Rₙ₄ | Ar137 | H | H | F | H | Rₙ₆₀ | H | H |
| Lₐ₆₀₈₁ | Rₙ₇ | Ar137 | H | H | F | H | Rₙ₆₀ | H | H |
| Lₐ₆₀₈₂ | Rₙ₂₀ | Ar137 | H | H | F | H | Rₙ₆₀ | H | H |
| Lₐ₆₀₈₃ | Rₙ₂₁ | Ar137 | H | H | F | H | Rₙ₆₀ | H | H |
| Lₐ₆₀₈₄ | Rₙ₅₆ | Ar137 | H | H | F | H | Rₙ₆₀ | H | H |
| Lₐ₆₀₈₅ | Rₙ₅₉ | Ar137 | H | H | F | H | Rₙ₆₀ | H | H |
| Lₐ₆₀₈₆ | Rₙ₆₁ | Ar137 | H | H | F | H | Rₙ₆₀ | H | H |
| Lₐ₆₀₈₇ | Rₙ₆₂ | Ar137 | H | H | F | H | Rₙ₆₀ | H | H |
| Lₐ₆₀₈₈ | Rₙ₆₄ | Ar137 | H | H | F | H | Rₙ₆₀ | H | H |
| Lₐ₆₀₈₉ | Rₙ₆₉ | Ar137 | H | H | F | H | Rₙ₆₀ | H | H |
| Lₐ₆₀₉₀ | Rₙ₇₀ | Ar137 | H | H | F | H | Rₙ₆₀ | H | H |
| Lₐ₆₀₉₁ | Rₙ₁ | Ar137 | H | H | F | H | D | Rₙ₁₁ | H |
| Lₐ₆₀₉₂ | Rₙ₄ | Ar137 | H | H | F | H | H | Rₙ₁₁ | H |
| Lₐ₆₀₉₃ | Rₙ₇ | Ar137 | H | H | F | H | H | Rₙ₁₁ | H |
| Lₐ₆₀₉₄ | Rₙ₂₀ | Ar137 | H | H | F | H | H | Rₙ₁₁ | H |
| Lₐ₆₀₉₅ | Rₙ₂₁ | Ar137 | H | H | F | H | H | Rₙ₁₁ | H |
| Lₐ₆₀₉₆ | Rₙ₅₆ | Ar137 | H | H | F | H | H | Rₙ₁₁ | H |
| Lₐ₆₀₉₇ | Rₙ₅₉ | Ar137 | H | H | F | H | H | Rₙ₁₁ | H |
| Lₐ₆₀₉₈ | Rₙ₆₁ | Ar137 | H | H | F | H | H | Rₙ₁₁ | H |
| Lₐ₆₀₉₉ | Rₙ₆₂ | Ar137 | H | H | F | H | H | Rₙ₁₁ | D |
| Lₐ₆₁₀₀ | Rₙ₆₄ | Ar137 | H | H | F | H | H | Rₙ₁₁ | H |
| Lₐ₆₁₀₁ | Rₙ₆₉ | Ar137 | H | H | F | H | H | Rₙ₁₁ | H |
| Lₐ₆₁₀₂ | Rₙ₇₀ | Ar137 | H | H | F | H | H | Rₙ₁₁ | H |
| Lₐ₆₁₀₃ | Rₙ₁ | Ar137 | H | H | F | H | H | Rₙ₆₀ | H |
| Lₐ₆₁₀₄ | Rₙ₄ | Ar137 | H | D | F | H | H | Rₙ₆₀ | H |
| Lₐ₆₁₀₅ | Rₙ₇ | Ar137 | H | H | F | H | H | Rₙ₆₀ | H |
| Lₐ₆₁₀₆ | Rₙ₂₀ | Ar137 | H | H | F | H | H | Rₙ₆₀ | H |
| Lₐ₆₁₀₇ | Rₙ₂₁ | Ar137 | D | H | F | H | H | Rₙ₆₀ | H |
| Lₐ₆₁₀₈ | Rₙ₅₆ | Ar137 | H | H | F | H | H | Rₙ₆₀ | H |
| Lₐ₆₁₀₉ | Rₙ₅₉ | Ar137 | H | H | F | H | H | Rₙ₆₀ | H |
| Lₐ₆₁₁₀ | Rₙ₆₁ | Ar137 | H | H | F | H | H | Rₙ₆₀ | H |
| Lₐ₆₁₁₁ | Rₙ₆₂ | Ar137 | H | H | F | H | H | Rₙ₆₀ | H |
| Lₐ₆₁₁₂ | Rₙ₆₄ | Ar137 | H | H | F | H | H | Rₙ₆₀ | H |
| Lₐ₆₁₁₃ | Rₙ₆₉ | Ar137 | H | H | F | H | H | Rₙ₆₀ | H |
| Lₐ₆₁₁₄ | Rₙ₇₀ | Ar137 | H | H | F | H | H | Rₙ₆₀ | H |
| Lₐ₆₁₁₅ | Rₙ₁ | Ar137 | H | D | CN | H | H | H | H |
| Lₐ₆₁₁₆ | Rₙ₄ | Ar137 | H | H | CN | H | H | H | H |
| Lₐ₆₁₁₇ | Rₙ₇ | Ar137 | H | H | CN | H | H | H | H |
| Lₐ₆₁₁₈ | Rₙ₂₀ | Ar137 | H | H | CN | H | H | H | H |
| Lₐ₆₁₁₉ | Rₙ₂₁ | Ar137 | H | H | CN | H | H | H | H |
| Lₐ₆₁₂₀ | Rₙ₅₆ | Ar137 | H | H | CN | H | H | H | H |
| Lₐ₆₁₂₁ | Rₙ₅₉ | Ar137 | H | H | CN | H | H | H | H |
| Lₐ₆₁₂₂ | Rₙ₆₁ | Ar137 | D | H | CN | H | H | H | H |
| Lₐ₆₁₂₃ | Rₙ₆₂ | Ar137 | H | H | CN | H | H | H | H |
| Lₐ₆₁₂₄ | Rₙ₆₄ | Ar137 | H | H | CN | H | H | H | H |
| Lₐ₆₁₂₅ | Rₙ₆₉ | Ar137 | H | H | CN | H | H | H | H |
| Lₐ₆₁₂₆ | Rₙ₇₀ | Ar137 | H | H | CN | H | H | H | H |
| Lₐ₆₁₂₇ | Rₙ₁ | Ar137 | H | CN | H | H | H | H | H |
| Lₐ₆₁₂₈ | Rₙ₄ | Ar137 | H | CN | H | H | H | H | H |
| Lₐ₆₁₂₉ | Rₙ₇ | Ar137 | H | CN | H | H | H | H | D |
| Lₐ₆₁₃₀ | Rₙ₂₀ | Ar137 | H | CN | H | H | H | H | H |
| Lₐ₆₁₃₁ | Rₙ₂₁ | Ar137 | H | CN | H | H | H | H | H |
| Lₐ₆₁₃₂ | Rₙ₅₆ | Ar137 | H | CN | H | H | H | H | H |
| Lₐ₆₁₃₃ | Rₙ₅₉ | Ar137 | H | CN | H | H | H | H | H |
| Lₐ₆₁₃₄ | Rₙ₆₁ | Ar137 | H | CN | H | H | H | H | H |
| Lₐ₆₁₃₅ | Rₙ₆₂ | Ar137 | H | CN | H | H | H | D | H |
| Lₐ₆₁₃₆ | Rₙ₆₄ | Ar137 | H | CN | H | H | H | H | H |
| Lₐ₆₁₃₇ | Rₙ₆₉ | Ar137 | H | CN | H | H | H | H | H |
| Lₐ₆₁₃₈ | Rₙ₇₀ | Ar137 | H | CN | H | H | H | H | H |
| Lₐ₆₁₃₉ | Rₙ₁ | Ar137 | CN | H | H | H | H | H | H |
| Lₐ₆₁₄₀ | Rₙ₄ | Ar137 | CN | H | H | H | H | H | H |
| Lₐ₆₁₄₁ | Rₙ₇ | Ar137 | CN | H | H | H | H | H | H |
| Lₐ₆₁₄₂ | Rₙ₂₀ | Ar137 | CN | H | H | H | H | H | H |
| Lₐ₆₁₄₃ | Rₙ₂₁ | Ar137 | CN | H | H | H | H | H | H |
| Lₐ₆₁₄₄ | Rₙ₅₆ | Ar137 | CN | H | D | H | H | H | H |
| Lₐ₆₁₄₅ | Rₙ₅₉ | Ar137 | CN | H | H | H | H | H | H |
| Lₐ₆₁₄₆ | Rₙ₆₁ | Ar137 | CN | H | H | H | H | H | H |
| Lₐ₆₁₄₇ | Rₙ₆₂ | Ar137 | CN | H | H | H | H | H | H |
| Lₐ₆₁₄₈ | Rₙ₆₄ | Ar137 | CN | D | H | H | H | H | H |
| Lₐ₆₁₄₉ | Rₙ₆₉ | Ar137 | CN | H | H | H | H | H | H |
| Lₐ₆₁₅₀ | Rₙ₇₀ | Ar137 | CN | H | H | H | H | H | H |
| Lₐ₆₁₅₁ | Rₙ₁ | Ar137 | H | H | CN | H | Rₙ₁₁ | H | H |
| Lₐ₆₁₅₂ | Rₙ₄ | Ar137 | H | H | CN | H | Rₙ₁₁ | H | H |
| Lₐ₆₁₅₃ | Rₙ₇ | Ar137 | H | H | CN | H | Rₙ₁₁ | H | H |
| Lₐ₆₁₅₄ | Rₙ₂₀ | Ar137 | H | H | CN | H | Rₙ₁₁ | H | H |
| Lₐ₆₁₅₅ | Rₙ₂₁ | Ar137 | H | H | CN | D | Rₙ₁₁ | H | H |
| Lₐ₆₁₅₆ | Rₙ₅₆ | Ar137 | H | H | CN | H | Rₙ₁₁ | H | H |
| Lₐ₆₁₅₇ | Rₙ₅₉ | Ar137 | H | H | CN | H | Rₙ₁₁ | H | H |
| Lₐ₆₁₅₈ | Rₙ₆₁ | Ar137 | H | H | CN | H | Rₙ₁₁ | D | H |
| Lₐ₆₁₅₉ | Rₙ₆₂ | Ar137 | H | H | CN | H | Rₙ₁₁ | H | H |
| Lₐ₆₁₆₀ | Rₙ₆₄ | Ar137 | H | H | CN | H | Rₙ₁₁ | H | H |
| Lₐ₆₁₆₁ | Rₙ₆₉ | Ar137 | H | H | CN | H | Rₙ₁₁ | H | H |
| Lₐ₆₁₆₂ | Rₙ₇₀ | Ar137 | H | H | CN | H | Rₙ₁₁ | H | H |
| Lₐ₆₁₆₃ | Rₙ₁ | Ar137 | H | H | CN | H | Rₙ₆₀ | H | D |
| Lₐ₆₁₆₄ | Rₙ₄ | Ar137 | H | H | CN | H | Rₙ₆₀ | H | H |
| Lₐ₆₁₆₅ | Rₙ₇ | Ar137 | H | H | CN | H | Rₙ₆₀ | H | H |
| Lₐ₆₁₆₆ | Rₙ₂₀ | Ar137 | H | H | CN | H | Rₙ₆₀ | H | H |
| Lₐ₆₁₆₇ | Rₙ₂₁ | Ar137 | H | H | CN | H | Rₙ₆₀ | H | H |
| Lₐ₆₁₆₈ | Rₙ₅₆ | Ar137 | H | H | CN | H | Rₙ₆₀ | H | H |
| Lₐ₆₁₆₉ | Rₙ₅₉ | Ar137 | H | D | CN | H | Rₙ₆₀ | H | H |
| Lₐ₆₁₇₀ | Rₙ₆₁ | Ar137 | H | H | CN | H | Rₙ₆₀ | H | H |
| Lₐ₆₁₇₁ | Rₙ₆₂ | Ar137 | H | H | CN | H | Rₙ₆₀ | H | H |
| Lₐ₆₁₇₂ | Rₙ₆₄ | Ar137 | H | H | CN | H | Rₙ₆₀ | H | H |
| Lₐ₆₁₇₃ | Rₙ₆₉ | Ar137 | H | H | CN | H | Rₙ₆₀ | H | H |
| Lₐ₆₁₇₄ | Rₙ₇₀ | Ar137 | H | H | CN | H | Rₙ₆₀ | H | H |
| Lₐ₆₁₇₅ | Rₙ₁ | Ar137 | H | H | CN | H | Rₙ₆₄ | H | H |
| Lₐ₆₁₇₆ | Rₙ₄ | Ar137 | H | H | CN | H | Rₙ₆₄ | H | H |
| Lₐ₆₁₇₇ | Rₙ₇ | Ar137 | H | H | CN | H | Rₙ₆₄ | H | H |
| Lₐ₆₁₇₈ | Rₙ₂₀ | Ar137 | H | H | CN | H | Rₙ₆₄ | H | H |
| Lₐ₆₁₇₉ | Rₙ₂₁ | Ar137 | H | H | CN | H | Rₙ₆₄ | H | H |
| Lₐ₆₁₈₀ | Rₙ₅₆ | Ar137 | H | H | CN | H | Rₙ₆₄ | H | H |
| Lₐ₆₁₈₁ | Rₙ₅₉ | Ar137 | H | H | CN | H | Rₙ₆₄ | H | H |
| Lₐ₆₁₈₂ | Rₙ₆₁ | Ar137 | H | H | CN | H | Rₙ₆₄ | H | H |
| Lₐ₆₁₈₃ | Rₙ₆₂ | Ar137 | H | H | CN | H | Rₙ₆₄ | H | H |
| Lₐ₆₁₈₄ | Rₙ₆₄ | Ar137 | H | H | CN | H | Rₙ₆₄ | H | H |
| Lₐ₆₁₈₅ | Rₙ₆₉ | Ar137 | H | H | CN | H | Rₙ₆₄ | H | H |
| Lₐ₆₁₈₆ | Rₙ₇₀ | Ar137 | H | H | CN | H | Rₙ₆₄ | H | H |
| Lₐ₆₁₈₇ | Rₙ₁ | Ar137 | H | H | CN | H | H | Rₙ₁₁ | H |
| Lₐ₆₁₈₈ | Rₙ₄ | Ar137 | H | H | CN | H | H | Rₙ₁₁ | H |
| Lₐ₆₁₈₉ | Rₙ₇ | Ar137 | H | H | CN | H | H | Rₙ₁₁ | H |
| Lₐ₆₁₉₀ | Rₙ₂₀ | Ar137 | H | H | CN | H | H | Rₙ₁₁ | H |
| Lₐ₆₁₉₁ | Rₙ₂₁ | Ar137 | H | H | CN | H | H | Rₙ₁₁ | H |
| Lₐ₆₁₉₂ | Rₙ₅₆ | Ar137 | H | H | CN | H | H | Rₙ₁₁ | H |
| Lₐ₆₁₉₃ | Rₙ₅₉ | Ar137 | H | H | CN | H | H | Rₙ₁₁ | H |
| Lₐ₆₁₉₄ | Rₙ₆₁ | Ar137 | D | H | CN | H | H | Rₙ₁₁ | H |
| Lₐ₆₁₉₅ | Rₙ₆₂ | Ar137 | H | H | CN | H | H | Rₙ₁₁ | H |
| Lₐ₆₁₉₆ | Rₙ₆₄ | Ar137 | H | H | CN | H | H | Rₙ₁₁ | H |
| Lₐ₆₁₉₇ | Rₙ₆₉ | Ar137 | H | H | CN | H | H | Rₙ₁₁ | H |
| Lₐ₆₁₉₈ | Rₙ₇₀ | Ar137 | H | H | CN | H | H | Rₙ₁₁ | H |
| Lₐ₆₁₉₉ | Rₙ₁ | Ar137 | H | H | CN | H | H | Rₙ₆₀ | H |
| Lₐ₆₂₀₀ | Rₙ₄ | Ar137 | H | H | CN | H | H | Rₙ₆₀ | D |
| Lₐ₆₂₀₁ | Rₙ₇ | Ar137 | H | H | CN | H | H | Rₙ₆₀ | H |
| Lₐ₆₂₀₂ | Rₙ₂₀ | Ar137 | H | H | CN | H | H | Rₙ₆₀ | H |
| Lₐ₆₂₀₃ | Rₙ₂₁ | Ar137 | H | H | CN | H | D | Rₙ₆₀ | H |
| Lₐ₆₂₀₄ | Rₙ₅₆ | Ar137 | H | H | CN | H | H | Rₙ₆₀ | H |
| Lₐ₆₂₀₅ | Rₙ₅₉ | Ar137 | H | H | CN | H | H | Rₙ₆₀ | H |
| Lₐ₆₂₀₆ | Rₙ₆₁ | Ar137 | H | H | CN | H | H | Rₙ₆₀ | H |
| Lₐ₆₂₀₇ | Rₙ₆₂ | Ar137 | H | H | CN | H | H | Rₙ₆₀ | H |
| Lₐ₆₂₀₈ | Rₙ₆₄ | Ar137 | H | H | CN | H | H | Rₙ₆₀ | H |
| Lₐ₆₂₀₉ | Rₙ₆₉ | Ar137 | H | H | CN | H | H | Rₙ₆₀ | H |
| Lₐ₆₂₁₀ | Rₙ₇₀ | Ar137 | H | D | CN | H | H | Rₙ₆₀ | H |
| Lₐ₆₂₁₁ | Rₙ₁ | Ar137 | H | H | CN | H | H | Rₙ₆₄ | H |
| Lₐ₆₂₁₂ | Rₙ₄ | Ar137 | H | H | CN | H | H | Rₙ₆₄ | H |
| Lₐ₆₂₁₃ | Rₙ₇ | Ar137 | H | H | CN | H | H | Rₙ₆₄ | H |
| Lₐ₆₂₁₄ | Rₙ₂₀ | Ar137 | H | H | CN | H | H | Rₙ₆₄ | H |
| Lₐ₆₂₁₅ | Rₙ₂₁ | Ar137 | H | H | CN | H | H | Rₙ₆₄ | H |
| Lₐ₆₂₁₆ | Rₙ₅₆ | Ar137 | H | H | CN | H | H | Rₙ₆₄ | H |
| Lₐ₆₂₁₇ | Rₙ₅₉ | Ar137 | H | H | CN | H | H | Rₙ₆₄ | H |
| Lₐ₆₂₁₈ | Rₙ₆₁ | Ar137 | H | H | CN | H | H | Rₙ₆₄ | H |
| Lₐ₆₂₁₉ | Rₙ₆₂ | Ar137 | H | H | CN | H | H | Rₙ₆₄ | H |
| Lₐ₆₂₂₀ | Rₙ₆₄ | Ar137 | D | H | CN | H | H | Rₙ₆₄ | H |
| Lₐ₆₂₂₁ | Rₙ₆₉ | Ar137 | H | H | CN | H | H | Rₙ₆₄ | H |
| Lₐ₆₂₂₂ | Rₙ₇₀ | Ar137 | H | H | CN | H | H | Rₙ₆₄ | H |
| Lₐ₆₂₂₃ | Rₙ₁ | Ar142 | H | H | H | H | H | H | H |
| Lₐ₆₂₂₄ | Rₙ₄ | Ar142 | H | H | H | H | H | H | H |
| Lₐ₆₂₂₅ | Rₙ₅ | Ar142 | H | H | H | H | H | H | H |
| Lₐ₆₂₂₆ | Rₙ₇ | Ar142 | H | H | H | H | H | H | H |
| Lₐ₆₂₂₇ | Rₙ₁₁ | Ar142 | H | H | H | H | H | H | H |
| Lₐ₆₂₂₈ | Rₙ₂₀ | Ar142 | H | H | H | H | H | H | H |
| Lₐ₆₂₂₉ | Rₙ₂₁ | Ar142 | H | H | H | H | H | H | H |
| Lₐ₆₂₃₀ | Rₙ₅₁ | Ar142 | H | H | H | H | H | H | H |
| Lₐ₆₂₃₁ | Rₙ₅₆ | Ar142 | H | H | H | H | H | H | H |
| Lₐ₆₂₃₂ | Rₙ₅₉ | Ar142 | H | H | H | H | H | H | H |
| Lₐ₆₂₃₃ | Rₙ₆₀ | Ar142 | H | H | H | H | H | H | H |
| Lₐ₆₂₃₄ | Rₙ₆₁ | Ar142 | H | H | H | H | H | H | H |
| Lₐ₆₂₃₅ | Rₙ₆₂ | Ar142 | H | H | H | H | H | H | H |
| Lₐ₆₂₃₆ | Rₙ₆₄ | Ar142 | H | H | H | H | H | H | H |
| Lₐ₆₂₃₇ | Rₙ₆₅ | Ar142 | H | H | H | H | H | H | H |
| Lₐ₆₂₃₈ | Rₙ₆₉ | Ar142 | H | H | H | H | H | H | H |
| Lₐ₆₂₃₉ | Rₙ₇₀ | Ar142 | H | H | H | H | H | H | H |
| Lₐ₆₂₄₀ | Rₙ₈₁ | Ar142 | H | H | H | H | H | H | H |
| Lₐ₆₂₄₁ | Rₙ₁ | Ar142 | H | H | H | H | H | Rₙ₁₁ | H |
| Lₐ₆₂₄₂ | Rₙ₄ | Ar142 | H | H | H | H | H | Rₙ₁₁ | H |
| Lₐ₆₂₄₃ | Rₙ₅ | Ar142 | H | H | H | H | H | Rₙ₁₁ | H |
| Lₐ₆₂₄₄ | Rₙ₇ | Ar142 | H | H | H | H | H | Rₙ₁₁ | H |
| Lₐ₆₂₄₅ | Rₙ₁₁ | Ar142 | H | H | H | H | H | Rₙ₁₁ | H |
| Lₐ₆₂₄₆ | Rₙ₂₀ | Ar142 | H | H | H | H | H | Rₙ₁₁ | H |
| Lₐ₆₂₄₇ | Rₙ₂₁ | Ar142 | H | H | H | H | H | Rₙ₁₁ | H |
| Lₐ₆₂₄₈ | Rₙ₅₁ | Ar142 | H | H | H | H | H | Rₙ₁₁ | H |
| Lₐ₆₂₄₉ | Rₙ₅₆ | Ar142 | H | H | H | H | H | Rₙ₁₁ | H |
| Lₐ₆₂₅₀ | Rₙ₅₉ | Ar142 | H | H | H | H | H | Rₙ₁₁ | H |
| Lₐ₆₂₅₁ | Rₙ₆₀ | Ar142 | H | H | H | H | H | Rₙ₁₁ | H |
| Lₐ₆₂₅₂ | Rₙ₆₁ | Ar142 | H | H | H | H | H | Rₙ₁₁ | H |
| Lₐ₆₂₅₃ | Rₙ₆₂ | Ar142 | H | H | H | H | H | Rₙ₁₁ | H |
| Lₐ₆₂₅₄ | Rₙ₆₄ | Ar142 | H | H | H | H | H | Rₙ₁₁ | H |
| Lₐ₆₂₅₅ | Rₙ₆₅ | Ar142 | H | H | H | H | H | Rₙ₁₁ | H |
| Lₐ₆₂₅₆ | Rₙ₆₉ | Ar142 | H | H | H | H | H | Rₙ₁₁ | H |
| Lₐ₆₂₅₇ | Rₙ₇₀ | Ar142 | H | H | H | H | H | Rₙ₁₁ | H |
| Lₐ₆₂₅₈ | Rₙ₈₁ | Ar142 | H | H | H | H | H | Rₙ₁₁ | H |
| Lₐ₆₂₅₉ | Rₙ₁ | Ar142 | H | H | H | H | H | Rₙ₅₉ | H |
| Lₐ₆₂₆₀ | Rₙ₄ | Ar142 | H | H | H | H | H | Rₙ₅₉ | H |
| Lₐ₆₂₆₁ | Rₙ₅ | Ar142 | H | H | H | H | H | Rₙ₅₉ | H |
| Lₐ₆₂₆₂ | Rₙ₇ | Ar142 | H | H | H | H | H | Rₙ₅₉ | H |
| Lₐ₆₂₆₃ | Rₙ₁₁ | Ar142 | H | H | H | H | H | Rₙ₅₉ | H |
| Lₐ₆₂₆₄ | Rₙ₂₀ | Ar142 | H | H | H | H | H | Rₙ₅₉ | H |
| Lₐ₆₂₆₅ | Rₙ₂₁ | Ar142 | H | H | H | H | H | Rₙ₅₉ | H |
| Lₐ₆₂₆₆ | Rₙ₅₁ | Ar142 | H | H | H | H | H | Rₙ₅₉ | H |
| Lₐ₆₂₆₇ | Rₙ₅₆ | Ar142 | H | H | H | H | H | Rₙ₅₉ | H |
| Lₐ₆₂₆₈ | Rₙ₅₉ | Ar142 | H | H | H | H | H | Rₙ₅₉ | H |
| Lₐ₆₂₆₉ | Rₙ₆₀ | Ar142 | H | H | H | H | H | Rₙ₅₉ | H |
| Lₐ₆₂₇₀ | Rₙ₆₁ | Ar142 | H | H | H | H | H | Rₙ₅₉ | H |
| Lₐ₆₂₇₁ | Rₙ₆₂ | Ar142 | H | H | H | H | H | Rₙ₅₉ | H |
| Lₐ₆₂₇₂ | Rₙ₆₄ | Ar142 | H | H | H | H | H | Rₙ₅₉ | H |
| Lₐ₆₂₇₃ | Rₙ₆₅ | Ar142 | H | H | H | H | H | Rₙ₅₉ | H |
| Lₐ₆₂₇₄ | Rₙ₆₉ | Ar142 | H | H | H | H | H | Rₙ₅₉ | H |
| Lₐ₆₂₇₅ | Rₙ₇₀ | Ar142 | H | H | H | H | H | Rₙ₅₉ | H |
| Lₐ₆₂₇₆ | Rₙ₈₁ | Ar142 | H | H | H | H | H | Rₙ₅₉ | H |
| Lₐ₆₂₇₇ | Rₙ₁ | Ar142 | H | H | H | H | H | Rₙ₆₀ | H |
| Lₐ₆₂₇₈ | Rₙ₄ | Ar142 | H | H | H | H | H | Rₙ₆₀ | H |
| Lₐ₆₂₇₉ | Rₙ₅ | Ar142 | D | H | H | H | H | Rₙ₆₀ | H |
| Lₐ₆₂₈₀ | Rₙ₇ | Ar142 | H | H | H | H | H | Rₙ₆₀ | H |
| Lₐ₆₂₈₁ | Rₙ₁₁ | Ar142 | H | D | H | H | H | Rₙ₆₀ | H |
| Lₐ₆₂₈₂ | Rₙ₂₀ | Ar142 | H | H | H | H | H | Rₙ₆₀ | H |
| Lₐ₆₂₈₃ | Rₙ₂₁ | Ar142 | H | H | D | H | H | Rₙ₆₀ | H |
| Lₐ₆₂₈₄ | Rₙ₅₁ | Ar142 | H | H | H | H | H | Rₙ₆₀ | H |
| Lₐ₆₂₈₅ | Rₙ₅₆ | Ar142 | H | H | H | D | H | Rₙ₆₀ | H |
| Lₐ₆₂₈₆ | Rₙ₅₉ | Ar142 | H | H | H | H | H | Rₙ₆₀ | H |
| Lₐ₆₂₈₇ | Rₙ₆₀ | Ar142 | H | H | H | H | D | Rₙ₆₀ | H |
| Lₐ₆₂₈₈ | Rₙ₆₁ | Ar142 | H | H | H | H | H | Rₙ₆₀ | H |
| Lₐ₆₂₈₉ | Rₙ₆₂ | Ar142 | H | H | H | H | H | Rₙ₆₀ | H |
| Lₐ₆₂₉₀ | Rₙ₆₄ | Ar142 | H | H | H | H | H | Rₙ₆₀ | D |
| Lₐ₆₂₉₁ | Rₙ₆₅ | Ar142 | H | H | H | H | H | Rₙ₆₀ | H |
| Lₐ₆₂₉₂ | Rₙ₆₉ | Ar142 | H | H | H | H | H | Rₙ₆₀ | H |
| Lₐ₆₂₉₃ | Rₙ₇₀ | Ar142 | H | H | H | H | H | Rₙ₆₀ | H |
| Lₐ₆₂₉₄ | Rₙ₈₁ | Ar142 | H | H | H | H | H | Rₙ₆₀ | H |
| Lₐ₆₂₉₅ | Rₙ₁ | Ar142 | H | H | H | H | H | Rₙ₆₄ | H |
| Lₐ₆₂₉₆ | Rₙ₄ | Ar142 | H | H | H | H | H | Rₙ₆₄ | H |
| Lₐ₆₂₉₇ | Rₙ₅ | Ar142 | H | H | H | H | H | Rₙ₆₄ | H |
| Lₐ₆₂₉₈ | Rₙ₇ | Ar142 | H | H | H | H | H | Rₙ₆₄ | H |
| Lₐ₆₂₉₉ | Rₙ₁₁ | Ar142 | H | H | H | H | H | Rₙ₆₄ | H |
| Lₐ₆₃₀₀ | Rₙ₂₀ | Ar142 | H | H | H | H | H | Rₙ₆₄ | H |
| Lₐ₆₃₀₁ | Rₙ₂₁ | Ar142 | H | H | H | H | H | Rₙ₆₄ | H |
| Lₐ₆₃₀₂ | Rₙ₅₁ | Ar142 | H | H | H | H | H | Rₙ₆₄ | H |
| Lₐ₆₃₀₃ | Rₙ₅₆ | Ar142 | H | H | H | H | H | Rₙ₆₄ | H |
| Lₐ₆₃₀₄ | Rₙ₅₉ | Ar142 | H | H | H | H | H | Rₙ₆₄ | H |
| Lₐ₆₃₀₅ | Rₙ₆₀ | Ar142 | H | H | H | H | H | Rₙ₆₄ | H |
| Lₐ₆₃₀₆ | Rₙ₆₁ | Ar142 | H | H | H | H | H | Rₙ₆₄ | H |
| Lₐ₆₃₀₇ | Rₙ₆₂ | Ar142 | H | H | H | H | H | Rₙ₆₄ | H |
| Lₐ₆₃₀₈ | Rₙ₆₄ | Ar142 | H | H | H | H | H | Rₙ₆₄ | H |
| Lₐ₆₃₀₉ | Rₙ₆₅ | Ar142 | H | H | H | H | H | Rₙ₆₄ | H |
| Lₐ₆₃₁₀ | Rₙ₆₉ | Ar142 | H | H | H | H | H | Rₙ₆₄ | H |
| Lₐ₆₃₁₁ | Rₙ₇₀ | Ar142 | H | H | H | H | H | Rₙ₆₄ | H |
| Lₐ₆₃₁₂ | Rₙ₈₁ | Ar142 | H | H | H | H | H | Rₙ₆₄ | H |
| Lₐ₆₃₁₃ | Rₙ₁ | Ar142 | H | H | H | H | H | Me | H |
| Lₐ₆₃₁₄ | Rₙ₄ | Ar142 | H | H | H | H | H | Me | H |
| Lₐ₆₃₁₅ | Rₙ₅ | Ar142 | H | H | H | H | H | Me | H |
| Lₐ₆₃₁₆ | Rₙ₇ | Ar142 | H | H | H | H | H | Me | H |
| Lₐ₆₃₁₇ | Rₙ₁₁ | Ar142 | H | H | H | H | H | Me | H |
| Lₐ₆₃₁₈ | Rₙ₂₀ | Ar142 | H | H | H | H | H | Me | H |
| Lₐ₆₃₁₉ | Rₙ₂₁ | Ar142 | H | H | H | H | H | Me | H |
| Lₐ₆₃₂₀ | Rₙ₅₁ | Ar142 | H | H | H | H | H | Me | H |
| Lₐ₆₃₂₁ | Rₙ₅₆ | Ar142 | H | H | H | H | H | Me | H |
| Lₐ₆₃₂₂ | Rₙ₅₉ | Ar142 | H | H | H | H | H | Me | H |
| Lₐ₆₃₂₃ | Rₙ₆₀ | Ar142 | H | H | H | H | H | Me | H |
| Lₐ₆₃₂₄ | Rₙ₆₁ | Ar142 | H | H | H | H | H | Me | H |
| Lₐ₆₃₂₅ | Rₙ₆₂ | Ar142 | H | H | H | H | H | Me | H |
| Lₐ₆₃₂₆ | Rₙ₆₄ | Ar142 | H | H | H | H | H | Me | H |
| Lₐ₆₃₂₇ | Rₙ₆₅ | Ar142 | H | H | H | H | H | Me | H |
| Lₐ₆₃₂₈ | Rₙ₆₉ | Ar142 | H | H | H | H | H | Me | H |
| Lₐ₆₃₂₉ | Rₙ₇₀ | Ar142 | H | H | H | H | H | Me | H |
| Lₐ₆₃₃₀ | Rₙ₈₁ | Ar142 | H | H | H | H | H | Me | H |
| Lₐ₆₃₃₁ | Rₙ₁ | Ar142 | H | H | H | H | Rₙ₁₁ | H | H |
| Lₐ₆₃₃₂ | Rₙ₄ | Ar142 | H | H | H | H | Rₙ₁₁ | H | H |
| Lₐ₆₃₃₃ | Rₙ₅ | Ar142 | H | H | H | H | Rₙ₁₁ | H | H |
| Lₐ₆₃₃₄ | Rₙ₇ | Ar142 | H | H | H | H | Rₙ₁₁ | H | H |
| Lₐ₆₃₃₅ | Rₙ₁₁ | Ar142 | H | H | H | H | Rₙ₁₁ | H | H |
| Lₐ₆₃₃₆ | Rₙ₂₀ | Ar142 | H | H | H | H | Rₙ₁₁ | H | H |
| Lₐ₆₃₃₇ | Rₙ₂₁ | Ar142 | H | H | H | H | Rₙ₁₁ | H | H |
| Lₐ₆₃₃₈ | Rₙ₅₁ | Ar142 | H | H | H | H | Rₙ₁₁ | H | H |
| Lₐ₆₃₃₉ | Rₙ₅₆ | Ar142 | H | H | H | H | Rₙ₁₁ | H | H |
| Lₐ₆₃₄₀ | Rₙ₅₉ | Ar142 | H | H | H | H | Rₙ₁₁ | H | H |
| Lₐ₆₃₄₁ | Rₙ₆₀ | Ar142 | H | H | H | H | Rₙ₁₁ | H | H |
| Lₐ₆₃₄₂ | Rₙ₆₁ | Ar142 | H | H | H | H | Rₙ₁₁ | H | H |
| Lₐ₆₃₄₃ | Rₙ₆₂ | Ar142 | H | H | H | H | Rₙ₁₁ | H | H |
| Lₐ₆₃₄₄ | Rₙ₆₄ | Ar142 | H | H | H | H | Rₙ₁₁ | H | H |
| Lₐ₆₃₄₅ | Rₙ₆₅ | Ar142 | H | H | H | H | Rₙ₁₁ | H | H |
| Lₐ₆₃₄₆ | Rₙ₆₉ | Ar142 | H | H | H | H | Rₙ₁₁ | H | H |
| Lₐ₆₃₄₇ | Rₙ₇₀ | Ar142 | H | H | H | H | Rₙ₁₁ | H | H |
| Lₐ₆₃₄₈ | Rₙ₈₁ | Ar142 | H | H | H | H | Rₙ₁₁ | H | H |
| Lₐ₆₃₄₉ | Rₙ₁ | Ar142 | H | H | H | H | Rₙ₅₉ | H | H |
| Lₐ₆₃₅₀ | Rₙ₄ | Ar142 | H | H | H | H | Rₙ₅₉ | H | H |
| Lₐ₆₃₅₁ | Rₙ₅ | Ar142 | H | H | H | H | Rₙ₅₉ | H | H |
| Lₐ₆₃₅₂ | Rₙ₇ | Ar142 | H | H | H | H | Rₙ₅₉ | H | H |
| Lₐ₆₃₅₃ | Rₙ₁₁ | Ar142 | H | H | H | H | Rₙ₅₉ | H | H |
| Lₐ₆₃₅₄ | Rₙ₂₀ | Ar142 | H | H | H | H | Rₙ₅₉ | H | D |
| Lₐ₆₃₅₅ | Rₙ₂₁ | Ar142 | H | H | H | H | Rₙ₅₉ | H | H |
| Lₐ₆₃₅₆ | Rₙ₅₁ | Ar142 | H | H | H | H | Rₙ₅₉ | H | H |
| Lₐ₆₃₅₇ | Rₙ₅₆ | Ar142 | H | H | H | H | Rₙ₅₉ | H | H |
| Lₐ₆₃₅₈ | Rₙ₅₉ | Ar142 | H | H | H | H | Rₙ₅₉ | H | H |
| Lₐ₆₃₅₉ | Rₙ₆₀ | Ar142 | H | H | H | H | Rₙ₅₉ | H | H |
| Lₐ₆₃₆₀ | Rₙ₆₁ | Ar142 | H | H | H | H | Rₙ₅₉ | H | H |
| Lₐ₆₃₆₁ | Rₙ₆₂ | Ar142 | H | H | H | H | Rₙ₅₉ | H | H |
| Lₐ₆₃₆₂ | Rₙ₆₄ | Ar142 | H | H | H | H | Rₙ₅₉ | H | H |
| Lₐ₆₃₆₃ | Rₙ₆₅ | Ar142 | H | H | H | H | Rₙ₅₉ | H | H |
| Lₐ₆₃₆₄ | Rₙ₆₉ | Ar142 | H | H | H | H | Rₙ₅₉ | H | H |
| Lₐ₆₃₆₅ | Rₙ₇₀ | Ar142 | H | H | H | D | Rₙ₅₉ | H | H |
| Lₐ₆₃₆₆ | Rₙ₈₁ | Ar142 | H | H | H | H | Rₙ₅₉ | H | H |
| Lₐ₆₃₆₇ | Rₙ₁ | Ar142 | H | H | H | H | Rₙ₆₀ | H | H |
| Lₐ₆₃₆₈ | Rₙ₄ | Ar142 | H | D | H | H | Rₙ₆₀ | H | H |
| Lₐ₆₃₆₉ | Rₙ₅ | Ar142 | H | H | H | H | Rₙ₆₀ | H | H |
| Lₐ₆₃₇₀ | Rₙ₇ | Ar142 | H | H | H | H | Rₙ₆₀ | H | H |
| Lₐ₆₃₇₁ | Rₙ₁₁ | Ar142 | H | H | H | H | Rₙ₆₀ | H | H |
| Lₐ₆₃₇₂ | Rₙ₂₀ | Ar142 | H | H | H | H | Rₙ₆₀ | H | H |
| Lₐ₆₃₇₃ | Rₙ₂₁ | Ar142 | D | H | H | H | Rₙ₆₀ | H | H |
| Lₐ₆₃₇₄ | Rₙ₅₁ | Ar142 | H | H | H | H | Rₙ₆₀ | H | H |
| Lₐ₆₃₇₅ | Rₙ₅₆ | Ar142 | H | H | H | H | Rₙ₆₀ | H | H |
| Lₐ₆₃₇₆ | Rₙ₅₉ | Ar142 | H | H | H | H | Rₙ₆₀ | H | H |
| Lₐ₆₃₇₇ | Rₙ₆₀ | Ar142 | H | H | H | H | Rₙ₆₀ | H | H |
| Lₐ₆₃₇₈ | Rₙ₆₁ | Ar142 | H | H | H | H | Rₙ₆₀ | H | H |
| Lₐ₆₃₇₉ | Rₙ₆₂ | Ar142 | H | H | H | H | Rₙ₆₀ | H | H |
| Lₐ₆₃₈₀ | Rₙ₆₄ | Ar142 | H | H | H | H | Rₙ₆₀ | H | H |
| Lₐ₆₃₈₁ | Rₙ₆₅ | Ar142 | H | H | H | H | Rₙ₆₀ | H | H |
| Lₐ₆₃₈₂ | Rₙ₆₉ | Ar142 | H | H | H | H | Rₙ₆₀ | H | H |
| Lₐ₆₃₈₃ | Rₙ₇₀ | Ar142 | H | H | H | H | Rₙ₆₀ | H | H |
| Lₐ₆₃₈₄ | Rₙ₈₁ | Ar142 | H | H | H | H | Rₙ₆₀ | H | H |
| Lₐ₆₃₈₅ | Rₙ₁ | Ar142 | H | H | H | H | Rₙ₆₄ | H | H |
| Lₐ₆₃₈₆ | Rₙ₄ | Ar142 | H | H | H | H | Rₙ₆₄ | H | H |
| Lₐ₆₃₈₇ | Rₙ₅ | Ar142 | H | H | H | H | Rₙ₆₄ | H | H |
| Lₐ₆₃₈₈ | Rₙ₇ | Ar142 | H | H | H | H | Rₙ₆₄ | H | H |
| Lₐ₆₃₈₉ | Rₙ₁₁ | Ar142 | H | H | H | H | Rₙ₆₄ | H | H |
| Lₐ₆₃₉₀ | Rₙ₂₀ | Ar142 | H | H | H | H | Rₙ₆₄ | H | H |
| Lₐ₆₃₉₁ | Rₙ₂₁ | Ar142 | H | H | H | H | Rₙ₆₄ | H | H |
| Lₐ₆₃₉₂ | Rₙ₅₁ | Ar142 | H | H | H | H | Rₙ₆₄ | H | H |
| Lₐ₆₃₉₃ | Rₙ₅₆ | Ar142 | H | H | H | H | Rₙ₆₄ | H | H |
| Lₐ₆₃₉₄ | Rₙ₅₉ | Ar142 | H | H | H | H | Rₙ₆₄ | H | H |
| Lₐ₆₃₉₅ | Rₙ₆₀ | Ar142 | H | H | H | H | Rₙ₆₄ | H | H |
| Lₐ₆₃₉₆ | Rₙ₆₁ | Ar142 | H | H | H | H | Rₙ₆₄ | H | H |
| Lₐ₆₃₉₇ | Rₙ₆₂ | Ar142 | H | H | H | H | Rₙ₆₄ | H | H |
| Lₐ₆₃₉₈ | Rₙ₆₄ | Ar142 | H | H | H | H | Rₙ₆₄ | H | H |
| Lₐ₆₃₉₉ | Rₙ₆₅ | Ar142 | H | H | H | H | Rₙ₆₄ | H | H |
| Lₐ₆₄₀₀ | Rₙ₆₉ | Ar142 | H | H | H | H | Rₙ₆₄ | H | H |
| Lₐ₆₄₀₁ | Rₙ₇₀ | Ar142 | H | H | H | H | Rₙ₆₄ | H | H |
| Lₐ₆₄₀₂ | Rₙ₈₁ | Ar142 | H | H | H | H | Rₙ₆₄ | H | H |
| Lₐ₆₄₀₃ | Rₙ₁ | Ar142 | H | H | H | H | Me | H | H |
| Lₐ₆₄₀₄ | Rₙ₄ | Ar142 | H | H | H | H | Me | H | H |
| Lₐ₆₄₀₅ | Rₙ₅ | Ar142 | H | H | H | H | Me | H | H |
| Lₐ₆₄₀₆ | Rₙ₇ | Ar142 | H | H | H | H | Me | H | H |
| Lₐ₆₄₀₇ | Rₙ₁₁ | Ar142 | H | H | H | H | Me | H | H |
| Lₐ₆₄₀₈ | Rₙ₂₀ | Ar142 | H | H | H | H | Me | H | H |
| Lₐ₆₄₀₉ | Rₙ₂₁ | Ar142 | H | H | H | H | Me | H | H |
| Lₐ₆₄₁₀ | Rₙ₅₁ | Ar142 | H | H | H | H | Me | H | H |
| Lₐ₆₄₁₁ | Rₙ₅₆ | Ar142 | H | H | H | H | Me | H | H |
| Lₐ₆₄₁₂ | Rₙ₅₉ | Ar142 | H | H | H | H | Me | H | H |
| Lₐ₆₄₁₃ | Rₙ₆₀ | Ar142 | H | H | H | H | Me | H | H |
| Lₐ₆₄₁₄ | Rₙ₆₁ | Ar142 | H | H | H | H | Me | H | H |
| Lₐ₆₄₁₅ | Rₙ₆₂ | Ar142 | H | H | H | H | Me | H | H |
| Lₐ₆₄₁₆ | Rₙ₆₄ | Ar142 | H | H | H | H | Me | H | H |
| Lₐ₆₄₁₇ | Rₙ₆₅ | Ar142 | H | H | H | H | Me | H | H |
| Lₐ₆₄₁₈ | Rₙ₆₉ | Ar142 | H | H | H | H | Me | H | H |
| Lₐ₆₄₁₉ | Rₙ₇₀ | Ar142 | H | H | H | H | Me | H | H |
| Lₐ₆₄₂₀ | Rₙ₈₁ | Ar142 | H | H | H | H | Me | H | H |
| Lₐ₆₄₂₁ | Rₙ₁ | Ar142 | H | H | F | H | H | H | H |
| Lₐ₆₄₂₂ | Rₙ₄ | Ar142 | H | H | F | H | H | H | H |
| Lₐ₆₄₂₃ | Rₙ₇ | Ar142 | H | H | F | H | H | H | H |
| Lₐ₆₄₂₄ | Rₙ₂₀ | Ar142 | H | H | F | H | H | H | H |
| Lₐ₆₄₂₅ | Rₙ₂₁ | Ar142 | H | H | F | H | H | H | H |
| Lₐ₆₄₂₆ | Rₙ₅₆ | Ar142 | H | H | F | H | H | H | H |
| Lₐ₆₄₂₇ | Rₙ₅₉ | Ar142 | H | H | F | H | H | H | H |
| Lₐ₆₄₂₈ | Rₙ₆₁ | Ar142 | H | H | F | H | H | H | H |
| Lₐ₆₄₂₉ | Rₙ₆₂ | Ar142 | H | H | F | H | H | H | H |
| Lₐ₆₄₃₀ | Rₙ₆₄ | Ar142 | H | H | F | H | H | H | H |
| Lₐ₆₄₃₁ | Rₙ₆₉ | Ar142 | H | H | F | H | H | H | H |
| Lₐ₆₄₃₂ | Rₙ₇₀ | Ar142 | H | H | F | H | H | H | H |
| Lₐ₆₄₃₃ | Rₙ₁ | Ar142 | H | H | F | D | Rₙ₁₁ | H | H |
| Lₐ₆₄₃₄ | Rₙ₄ | Ar142 | H | H | F | H | Rₙ₁₁ | H | H |
| Lₐ₆₄₃₅ | Rₙ₇ | Ar142 | H | H | F | H | Rₙ₁₁ | H | H |
| Lₐ₆₄₃₆ | Rₙ₂₀ | Ar142 | H | H | F | H | Rₙ₁₁ | H | H |
| Lₐ₆₄₃₇ | Rₙ₂₁ | Ar142 | H | H | F | H | Rₙ₁₁ | H | H |
| Lₐ₆₄₃₈ | Rₙ₅₆ | Ar142 | H | H | F | H | Rₙ₁₁ | H | H |
| Lₐ₆₄₃₉ | Rₙ₅₉ | Ar142 | D | H | F | H | Rₙ₁₁ | H | H |
| Lₐ₆₄₄₀ | Rₙ₆₁ | Ar142 | H | H | F | H | Rₙ₁₁ | H | H |
| Lₐ₆₄₄₁ | Rₙ₆₂ | Ar142 | H | H | F | H | Rₙ₁₁ | H | H |
| Lₐ₆₄₄₂ | Rₙ₆₄ | Ar142 | H | H | F | H | Rₙ₁₁ | H | H |
| Lₐ₆₄₄₃ | Rₙ₆₉ | Ar142 | H | H | F | H | Rₙ₁₁ | H | H |
| Lₐ₆₄₄₄ | Rₙ₇₀ | Ar142 | H | H | F | H | Rₙ₁₁ | H | H |
| Lₐ₆₄₄₅ | Rₙ₁ | Ar142 | H | H | F | H | Rₙ₆₀ | H | D |
| Lₐ₆₄₄₆ | Rₙ₄ | Ar142 | H | H | F | H | Rₙ₆₀ | H | D |
| Lₐ₆₄₄₇ | Rₙ₇ | Ar142 | H | H | F | H | Rₙ₆₀ | H | D |
| Lₐ₆₄₄₈ | Rₙ₂₀ | Ar142 | H | H | F | H | Rₙ₆₀ | H | D |
| Lₐ₆₄₄₉ | Rₙ₂₁ | Ar142 | H | H | F | H | Rₙ₆₀ | H | D |
| Lₐ₆₄₅₀ | Rₙ₅₆ | Ar142 | H | H | F | H | Rₙ₆₀ | H | D |
| Lₐ₆₄₅₁ | Rₙ₅₉ | Ar142 | H | H | F | H | Rₙ₆₀ | H | D |
| Lₐ₆₄₅₂ | Rₙ₆₁ | Ar142 | H | H | F | H | Rₙ₆₀ | H | D |
| Lₐ₆₄₅₃ | Rₙ₆₂ | Ar142 | H | H | F | H | Rₙ₆₀ | H | D |
| Lₐ₆₄₅₄ | Rₙ₆₄ | Ar142 | H | H | F | H | Rₙ₆₀ | H | D |
| Lₐ₆₄₅₅ | Rₙ₆₉ | Ar142 | H | H | F | H | Rₙ₆₀ | H | D |
| Lₐ₆₄₅₆ | Rₙ₇₀ | Ar142 | H | H | F | H | Rₙ₆₀ | H | D |
| Lₐ₆₄₅₇ | Rₙ₁ | Ar142 | H | H | F | H | H | Rₙ₁₁ | H |
| Lₐ₆₄₅₈ | Rₙ₄ | Ar142 | H | H | F | H | H | Rₙ₁₁ | H |
| Lₐ₆₄₅₉ | Rₙ₇ | Ar142 | H | H | F | H | H | Rₙ₁₁ | H |
| Lₐ₆₄₆₀ | Rₙ₂₀ | Ar142 | H | H | F | H | H | Rₙ₁₁ | H |
| Lₐ₆₄₆₁ | Rₙ₂₁ | Ar142 | H | D | F | H | H | Rₙ₁₁ | H |
| Lₐ₆₄₆₂ | Rₙ₅₆ | Ar142 | H | H | F | H | H | Rₙ₁₁ | H |
| Lₐ₆₄₆₃ | Rₙ₅₉ | Ar142 | H | H | F | H | H | Rₙ₁₁ | H |
| Lₐ₆₄₆₄ | Rₙ₆₁ | Ar142 | D | H | F | H | H | Rₙ₁₁ | H |
| Lₐ₆₄₆₅ | Rₙ₆₂ | Ar142 | H | H | F | H | H | Rₙ₁₁ | H |
| Lₐ₆₄₆₆ | Rₙ₆₄ | Ar142 | H | H | F | H | H | Rₙ₁₁ | H |
| Lₐ₆₄₆₇ | Rₙ₆₉ | Ar142 | H | H | F | H | H | Rₙ₁₁ | H |
| Lₐ₆₄₆₈ | Rₙ₇₀ | Ar142 | H | H | F | H | H | Rₙ₁₁ | H |
| Lₐ₆₄₆₉ | Rₙ₁ | Ar142 | H | H | F | H | D | Rₙ₆₀ | H |
| Lₐ₆₄₇₀ | Rₙ₄ | Ar142 | H | H | F | H | D | Rₙ₆₀ | H |
| Lₐ₆₄₇₁ | Rₙ₇ | Ar142 | H | H | F | H | D | Rₙ₆₀ | H |
| Lₐ₆₄₇₂ | Rₙ₂₀ | Ar142 | H | H | F | H | D | Rₙ₆₀ | H |
| Lₐ₆₄₇₃ | Rₙ₂₁ | Ar142 | H | H | F | H | D | Rₙ₆₀ | H |
| Lₐ₆₄₇₄ | Rₙ₅₆ | Ar142 | H | H | F | H | D | Rₙ₆₀ | H |
| Lₐ₆₄₇₅ | Rₙ₅₉ | Ar142 | H | H | F | H | D | Rₙ₆₀ | H |
| Lₐ₆₄₇₆ | Rₙ₆₁ | Ar142 | H | H | F | H | D | Rₙ₆₀ | H |
| Lₐ₆₄₇₇ | Rₙ₆₂ | Ar142 | H | H | F | H | D | Rₙ₆₀ | H |
| Lₐ₆₄₇₈ | Rₙ₆₄ | Ar142 | H | H | F | H | D | Rₙ₆₀ | H |
| Lₐ₆₄₇₉ | Rₙ₆₉ | Ar142 | H | H | F | H | D | Rₙ₆₀ | H |
| Lₐ₆₄₈₀ | Rₙ₇₀ | Ar142 | H | H | F | H | D | Rₙ₆₀ | H |
| Lₐ₆₄₈₁ | Rₙ₁ | Ar142 | H | H | CN | H | H | H | H |
| Lₐ₆₄₈₂ | Rₙ₄ | Ar142 | H | H | CN | H | H | H | H |
| Lₐ₆₄₈₃ | Rₙ₇ | Ar142 | H | H | CN | H | H | H | H |
| Lₐ₆₄₈₄ | Rₙ₂₀ | Ar142 | H | H | CN | H | H | H | H |
| Lₐ₆₄₈₅ | Rₙ₂₁ | Ar142 | H | H | CN | H | H | H | H |
| Lₐ₆₄₈₆ | Rₙ₅₆ | Ar142 | H | H | CN | H | H | H | H |
| Lₐ₆₄₈₇ | Rₙ₅₉ | Ar142 | H | H | CN | H | H | H | H |
| Lₐ₆₄₈₈ | Rₙ₆₁ | Ar142 | H | H | CN | H | H | H | H |
| Lₐ₆₄₈₉ | Rₙ₆₂ | Ar142 | H | H | CN | H | H | H | H |
| Lₐ₆₄₉₀ | Rₙ₆₄ | Ar142 | H | H | CN | H | H | H | H |
| Lₐ₆₄₉₁ | Rₙ₆₉ | Ar142 | H | H | CN | H | H | H | H |
| Lₐ₆₄₉₂ | Rₙ₇₀ | Ar142 | H | H | CN | H | H | H | H |
| Lₐ₆₄₉₃ | Rₙ₁ | Ar142 | H | CN | H | H | H | H | H |
| Lₐ₆₄₉₄ | Rₙ₄ | Ar142 | H | CN | H | H | H | H | H |
| Lₐ₆₄₉₅ | Rₙ₇ | Ar142 | H | CN | H | H | H | H | H |
| Lₐ₆₄₉₆ | Rₙ₂₀ | Ar142 | H | CN | H | H | H | H | H |
| Lₐ₆₄₉₇ | Rₙ₂₁ | Ar142 | H | CN | H | H | H | H | H |
| Lₐ₆₄₉₈ | Rₙ₅₆ | Ar142 | H | CN | H | H | H | H | H |
| Lₐ₆₄₉₉ | Rₙ₅₉ | Ar142 | H | CN | H | H | H | H | H |
| Lₐ₆₅₀₀ | Rₙ₆₁ | Ar142 | H | CN | H | H | H | H | H |
| Lₐ₆₅₀₁ | Rₙ₆₂ | Ar142 | H | CN | H | H | H | H | H |
| Lₐ₆₅₀₂ | Rₙ₆₄ | Ar142 | H | CN | H | H | H | H | H |
| Lₐ₆₅₀₃ | Rₙ₆₉ | Ar142 | H | CN | H | H | H | H | H |
| Lₐ₆₅₀₄ | Rₙ₇₀ | Ar142 | H | CN | H | H | H | H | H |
| Lₐ₆₅₀₅ | Rₙ₁ | Ar142 | CN | H | H | H | H | H | H |
| Lₐ₆₅₀₆ | Rₙ₄ | Ar142 | CN | H | H | H | H | H | H |
| Lₐ₆₅₀₇ | Rₙ₇ | Ar142 | CN | H | H | H | H | H | D |
| Lₐ₆₅₀₈ | Rₙ₂₀ | Ar142 | CN | H | H | H | H | H | H |
| Lₐ₆₅₀₉ | Rₙ₂₁ | Ar142 | CN | H | H | D | H | H | H |
| Lₐ₆₅₁₀ | Rₙ₅₆ | Ar142 | CN | H | H | H | H | H | H |
| Lₐ₆₅₁₁ | Rₙ₅₉ | Ar142 | CN | H | H | H | H | H | H |
| Lₐ₆₅₁₂ | Rₙ₆₁ | Ar142 | CN | H | D | H | H | H | H |
| Lₐ₆₅₁₃ | Rₙ₆₂ | Ar142 | CN | H | H | H | H | H | H |
| Lₐ₆₅₁₄ | Rₙ₆₄ | Ar142 | CN | H | H | H | H | H | H |
| Lₐ₆₅₁₅ | Rₙ₆₉ | Ar142 | CN | H | H | H | H | H | H |
| Lₐ₆₅₁₆ | Rₙ₇₀ | Ar142 | CN | H | H | H | H | H | H |
| Lₐ₆₅₁₇ | Rₙ₁ | Ar142 | H | H | CN | H | Rₙ₁₁ | H | H |
| Lₐ₆₅₁₈ | Rₙ₄ | Ar142 | H | H | CN | H | Rₙ₁₁ | H | H |
| Lₐ₆₅₁₉ | Rₙ₇ | Ar142 | H | H | CN | H | Rₙ₁₁ | H | H |
| Lₐ₆₅₂₀ | Rₙ₂₀ | Ar142 | H | H | CN | H | Rₙ₁₁ | H | H |
| Lₐ₆₅₂₁ | Rₙ₂₁ | Ar142 | H | H | CN | H | Rₙ₁₁ | H | H |
| Lₐ₆₅₂₂ | Rₙ₅₆ | Ar142 | H | H | CN | H | Rₙ₁₁ | H | H |
| Lₐ₆₅₂₃ | Rₙ₅₉ | Ar142 | H | H | CN | H | Rₙ₁₁ | H | H |
| Lₐ₆₅₂₄ | Rₙ₆₁ | Ar142 | H | H | CN | H | Rₙ₁₁ | H | H |
| Lₐ₆₅₂₅ | Rₙ₆₂ | Ar142 | H | H | CN | H | Rₙ₁₁ | H | H |
| Lₐ₆₅₂₆ | Rₙ₆₄ | Ar142 | H | H | CN | H | Rₙ₁₁ | H | H |
| Lₐ₆₅₂₇ | Rₙ₆₉ | Ar142 | H | H | CN | H | Rₙ₁₁ | H | H |
| Lₐ₆₅₂₈ | Rₙ₇₀ | Ar142 | H | H | CN | H | Rₙ₁₁ | H | H |
| Lₐ₆₅₂₉ | Rₙ₁ | Ar142 | H | H | CN | H | Rₙ₆₀ | H | D |
| Lₐ₆₅₃₀ | Rₙ₄ | Ar142 | H | H | CN | H | Rₙ₆₀ | H | D |
| Lₐ₆₅₃₁ | Rₙ₇ | Ar142 | H | H | CN | H | Rₙ₆₀ | H | D |
| Lₐ₆₅₃₂ | Rₙ₂₀ | Ar142 | H | H | CN | H | Rₙ₆₀ | H | D |
| Lₐ₆₅₃₃ | Rₙ₂₁ | Ar142 | H | H | CN | H | Rₙ₆₀ | H | D |
| Lₐ₆₅₃₄ | Rₙ₅₆ | Ar142 | H | H | CN | H | Rₙ₆₀ | H | D |
| Lₐ₆₅₃₅ | Rₙ₅₉ | Ar142 | H | H | CN | H | Rₙ₆₀ | H | D |
| Lₐ₆₅₃₆ | Rₙ₆₁ | Ar142 | H | H | CN | H | Rₙ₆₀ | H | D |
| Lₐ₆₅₃₇ | Rₙ₆₂ | Ar142 | H | H | CN | H | Rₙ₆₀ | H | D |
| Lₐ₆₅₃₈ | Rₙ₆₄ | Ar142 | H | H | CN | H | Rₙ₆₀ | H | D |
| Lₐ₆₅₃₉ | Rₙ₆₉ | Ar142 | H | H | CN | H | Rₙ₆₀ | H | D |
| Lₐ₆₅₄₀ | Rₙ₇₀ | Ar142 | H | H | CN | H | Rₙ₆₀ | H | D |
| Lₐ₆₅₄₁ | Rₙ₁ | Ar142 | H | H | CN | H | Rₙ₆₄ | H | H |
| Lₐ₆₅₄₂ | Rₙ₄ | Ar142 | H | H | CN | H | Rₙ₆₄ | H | H |
| Lₐ₆₅₄₃ | Rₙ₇ | Ar142 | H | H | CN | H | Rₙ₆₄ | H | H |
| Lₐ₆₅₄₄ | Rₙ₂₀ | Ar142 | H | H | CN | H | Rₙ₆₄ | H | H |
| Lₐ₆₅₄₅ | Rₙ₂₁ | Ar142 | H | H | CN | H | Rₙ₆₄ | H | H |
| Lₐ₆₅₄₆ | Rₙ₅₆ | Ar142 | H | H | CN | H | Rₙ₆₄ | H | H |
| Lₐ₆₅₄₇ | Rₙ₅₉ | Ar142 | H | H | CN | H | Rₙ₆₄ | H | H |
| Lₐ₆₅₄₈ | Rₙ₆₁ | Ar142 | H | H | CN | H | Rₙ₆₄ | H | H |
| Lₐ₆₅₄₉ | Rₙ₆₂ | Ar142 | H | H | CN | H | Rₙ₆₄ | H | H |
| Lₐ₆₅₅₀ | Rₙ₆₄ | Ar142 | H | H | CN | H | Rₙ₆₄ | H | H |
| Lₐ₆₅₅₁ | Rₙ₆₉ | Ar142 | H | H | CN | H | Rₙ₆₄ | H | H |
| Lₐ₆₅₅₂ | Rₙ₇₀ | Ar142 | H | H | CN | H | Rₙ₆₄ | H | H |
| Lₐ₆₅₅₃ | Rₙ₁ | Ar142 | H | H | CN | H | H | Rₙ₁₁ | H |
| Lₐ₆₅₅₄ | Rₙ₄ | Ar142 | H | H | CN | H | H | Rₙ₁₁ | H |
| Lₐ₆₅₅₅ | Rₙ₇ | Ar142 | H | H | CN | H | D | Rₙ₁₁ | H |
| Lₐ₆₅₅₆ | Rₙ₂₀ | Ar142 | H | D | CN | H | H | Rₙ₁₁ | H |
| Lₐ₆₅₅₇ | Rₙ₂₁ | Ar142 | H | H | CN | H | H | Rₙ₁₁ | H |
| Lₐ₆₅₅₈ | Rₙ₅₆ | Ar142 | D | H | CN | H | H | Rₙ₁₁ | H |
| Lₐ₆₅₅₉ | Rₙ₅₉ | Ar142 | H | H | CN | H | H | Rₙ₁₁ | H |
| Lₐ₆₅₆₀ | Rₙ₆₁ | Ar142 | H | H | CN | H | H | Rₙ₁₁ | H |
| Lₐ₆₅₆₁ | Rₙ₆₂ | Ar142 | H | H | CN | H | H | Rₙ₁₁ | H |
| Lₐ₆₅₆₂ | Rₙ₆₄ | Ar142 | H | H | CN | H | H | Rₙ₁₁ | H |
| Lₐ₆₅₆₃ | Rₙ₆₉ | Ar142 | H | H | CN | H | H | Rₙ₁₁ | H |
| Lₐ₆₅₆₄ | Rₙ₇₀ | Ar142 | H | H | CN | H | H | Rₙ₁₁ | H |
| Lₐ₆₅₆₅ | Rₙ₁ | Ar142 | H | H | CN | H | H | Rₙ₆₀ | D |
| Lₐ₆₅₆₆ | Rₙ₄ | Ar142 | H | H | CN | H | H | Rₙ₆₀ | D |
| Lₐ₆₅₆₇ | Rₙ₇ | Ar142 | H | H | CN | H | H | Rₙ₆₀ | D |
| Lₐ₆₅₆₈ | Rₙ₂₀ | Ar142 | H | H | CN | H | H | Rₙ₆₀ | D |
| Lₐ₆₅₆₉ | Rₙ₂₁ | Ar142 | H | H | CN | H | H | Rₙ₆₀ | D |
| Lₐ₆₅₇₀ | Rₙ₅₆ | Ar142 | H | H | CN | H | H | Rₙ₆₀ | D |
| Lₐ₆₅₇₁ | Rₙ₅₉ | Ar142 | H | H | CN | H | H | Rₙ₆₀ | D |
| Lₐ₆₅₇₂ | Rₙ₆₁ | Ar142 | H | H | CN | H | H | Rₙ₆₀ | D |
| Lₐ₆₅₇₃ | Rₙ₆₂ | Ar142 | H | H | CN | H | H | Rₙ₆₀ | D |
| Lₐ₆₅₇₄ | Rₙ₆₄ | Ar142 | H | H | CN | H | H | Rₙ₆₀ | D |
| Lₐ₆₅₇₅ | Rₙ₆₉ | Ar142 | H | H | CN | H | H | Rₙ₆₀ | D |
| Lₐ₆₅₇₆ | Rₙ₇₀ | Ar142 | H | H | CN | H | H | Rₙ₆₀ | D |
| Lₐ₆₅₇₇ | Rₙ₁ | Ar142 | H | H | CN | H | H | Rₙ₆₄ | H |
| Lₐ₆₅₇₈ | Rₙ₄ | Ar142 | H | H | CN | H | H | Rₙ₆₄ | H |
| Lₐ₆₅₇₉ | Rₙ₇ | Ar142 | H | H | CN | H | H | Rₙ₆₄ | H |
| Lₐ₆₅₈₀ | Rₙ₂₀ | Ar142 | H | H | CN | H | H | Rₙ₆₄ | H |
| Lₐ₆₅₈₁ | Rₙ₂₁ | Ar142 | H | H | CN | H | H | Rₙ₆₄ | H |
| Lₐ₆₅₈₂ | Rₙ₅₆ | Ar142 | H | H | CN | H | H | Rₙ₆₄ | H |
| Lₐ₆₅₈₃ | Rₙ₅₉ | Ar142 | H | H | CN | H | H | Rₙ₆₄ | H |
| Lₐ₆₅₈₄ | Rₙ₆₁ | Ar142 | H | H | CN | H | H | Rₙ₆₄ | H |
| Lₐ₆₅₈₅ | Rₙ₆₂ | Ar142 | H | H | CN | H | H | Rₙ₆₄ | H |
| Lₐ₆₅₈₆ | Rₙ₆₄ | Ar142 | H | H | CN | H | H | Rₙ₆₄ | H |
| Lₐ₆₅₈₇ | Rₙ₆₉ | Ar142 | H | H | CN | H | H | Rₙ₆₄ | H |
| Lₐ₆₅₈₈ | Rₙ₇₀ | Ar142 | H | H | CN | H | H | Rₙ₆₄ | H |
| Lₐ₆₅₈₉ | Rₙ₁ | Ar143 | H | H | H | H | H | H | H |
| Lₐ₆₅₉₀ | Rₙ₄ | Ar143 | H | H | H | H | H | H | H |
| Lₐ₆₅₉₁ | Rₙ₅ | Ar143 | H | H | H | H | H | H | H |
| Lₐ₆₅₉₂ | Rₙ₇ | Ar143 | H | H | H | H | H | H | H |
| Lₐ₆₅₉₃ | Rₙ₁₁ | Ar143 | H | H | H | H | H | H | H |
| Lₐ₆₅₉₄ | Rₙ₂₀ | Ar143 | H | H | H | H | H | H | H |
| Lₐ₆₅₉₅ | Rₙ₂₁ | Ar143 | H | H | H | H | H | H | H |
| Lₐ₆₅₉₆ | Rₙ₅₁ | Ar143 | H | H | H | H | H | H | H |
| Lₐ₆₅₉₇ | Rₙ₅₆ | Ar143 | H | H | H | H | H | H | H |
| Lₐ₆₅₉₈ | Rₙ₅₉ | Ar143 | H | H | H | H | H | H | H |
| Lₐ₆₅₉₉ | Rₙ₆₀ | Ar143 | H | H | H | H | H | H | H |
| Lₐ₆₆₀₀ | Rₙ₆₁ | Ar143 | H | H | H | H | H | H | H |
| Lₐ₆₆₀₁ | Rₙ₆₂ | Ar143 | H | H | H | H | H | H | H |
| Lₐ₆₆₀₂ | Rₙ₆₄ | Ar143 | H | H | H | H | H | H | H |
| Lₐ₆₆₀₃ | Rₙ₆₅ | Ar143 | H | H | H | H | H | H | H |
| Lₐ₆₆₀₄ | Rₙ₆₉ | Ar143 | H | H | H | H | H | H | H |
| Lₐ₆₆₀₅ | Rₙ₇₀ | Ar143 | H | H | H | H | H | H | H |
| Lₐ₆₆₀₆ | Rₙ₈₁ | Ar143 | H | H | H | H | H | H | H |
| Lₐ₆₆₀₇ | Rₙ₁ | Ar143 | H | H | H | H | H | Rₙ₁₁ | H |
| Lₐ₆₆₀₈ | Rₙ₄ | Ar143 | H | H | H | H | H | Rₙ₁₁ | H |
| Lₐ₆₆₀₉ | Rₙ₅ | Ar143 | H | H | H | H | H | Rₙ₁₁ | H |
| Lₐ₆₆₁₀ | Rₙ₇ | Ar143 | H | H | H | H | H | Rₙ₁₁ | H |
| Lₐ₆₆₁₁ | Rₙ₁₁ | Ar143 | H | H | H | H | H | Rₙ₁₁ | H |
| Lₐ₆₆₁₂ | Rₙ₂₀ | Ar143 | H | H | H | H | H | Rₙ₁₁ | H |
| Lₐ₆₆₁₃ | Rₙ₂₁ | Ar143 | H | H | H | H | H | Rₙ₁₁ | H |
| Lₐ₆₆₁₄ | Rₙ₅₁ | Ar143 | H | H | H | H | H | Rₙ₁₁ | H |
| Lₐ₆₆₁₅ | Rₙ₅₆ | Ar143 | H | H | H | H | H | Rₙ₁₁ | H |
| Lₐ₆₆₁₆ | Rₙ₅₉ | Ar143 | H | H | H | H | H | Rₙ₁₁ | H |
| Lₐ₆₆₁₇ | Rₙ₆₀ | Ar143 | H | H | H | H | H | Rₙ₁₁ | H |
| Lₐ₆₆₁₈ | Rₙ₆₁ | Ar143 | H | H | H | H | H | Rₙ₁₁ | H |
| Lₐ₆₆₁₉ | Rₙ₆₂ | Ar143 | H | H | H | H | H | Rₙ₁₁ | H |
| Lₐ₆₆₂₀ | Rₙ₆₄ | Ar143 | H | H | H | H | H | Rₙ₁₁ | H |
| Lₐ₆₆₂₁ | Rₙ₆₅ | Ar143 | H | H | H | H | H | Rₙ₁₁ | H |
| Lₐ₆₆₂₂ | Rₙ₆₉ | Ar143 | H | H | H | H | H | Rₙ₁₁ | H |
| Lₐ₆₆₂₃ | Rₙ₇₀ | Ar143 | H | H | H | H | H | Rₙ₁₁ | H |
| Lₐ₆₆₂₄ | Rₙ₈₁ | Ar143 | H | H | H | H | H | Rₙ₁₁ | H |
| Lₐ₆₆₂₅ | Rₙ₁ | Ar143 | H | H | H | H | H | Rₙ₅₉ | H |
| Lₐ₆₆₂₆ | Rₙ₄ | Ar143 | H | H | H | H | H | Rₙ₅₉ | H |
| Lₐ₆₆₂₇ | Rₙ₅ | Ar143 | H | H | H | H | H | Rₙ₅₉ | H |
| Lₐ₆₆₂₈ | Rₙ₇ | Ar143 | H | H | H | H | H | Rₙ₅₉ | H |
| Lₐ₆₆₂₉ | Rₙ₁₁ | Ar143 | H | H | H | H | H | Rₙ₅₉ | H |
| Lₐ₆₆₃₀ | Rₙ₂₀ | Ar143 | H | H | H | H | H | Rₙ₅₉ | H |
| Lₐ₆₆₃₁ | Rₙ₂₁ | Ar143 | H | H | H | H | H | Rₙ₅₉ | H |
| Lₐ₆₆₃₂ | Rₙ₅₁ | Ar143 | H | H | H | H | H | Rₙ₅₉ | H |
| Lₐ₆₆₃₃ | Rₙ₅₆ | Ar143 | H | H | H | H | H | Rₙ₅₉ | H |
| Lₐ₆₆₃₄ | Rₙ₅₉ | Ar143 | H | H | H | H | H | Rₙ₅₉ | H |
| Lₐ₆₆₃₅ | Rₙ₆₀ | Ar143 | H | H | H | H | H | Rₙ₅₉ | H |
| Lₐ₆₆₃₆ | Rₙ₆₁ | Ar143 | H | H | H | H | H | Rₙ₅₉ | H |
| Lₐ₆₆₃₇ | Rₙ₆₂ | Ar143 | H | H | H | H | H | Rₙ₅₉ | H |
| Lₐ₆₆₃₈ | Rₙ₆₄ | Ar143 | H | H | H | H | H | Rₙ₅₉ | H |
| Lₐ₆₆₃₉ | Rₙ₆₅ | Ar143 | H | H | H | H | H | Rₙ₅₉ | H |
| Lₐ₆₆₄₀ | Rₙ₆₉ | Ar143 | H | H | H | H | H | Rₙ₅₉ | H |
| Lₐ₆₆₄₁ | Rₙ₇₀ | Ar143 | H | H | H | H | H | Rₙ₅₉ | H |
| Lₐ₆₆₄₂ | Rₙ₈₁ | Ar143 | H | H | H | H | H | Rₙ₅₉ | H |
| Lₐ₆₆₄₃ | Rₙ₁ | Ar143 | H | H | H | H | H | Rₙ₆₀ | H |
| Lₐ₆₆₄₄ | Rₙ₄ | Ar143 | H | H | H | H | H | Rₙ₆₀ | H |
| Lₐ₆₆₄₅ | Rₙ₅ | Ar143 | H | H | H | H | H | Rₙ₆₀ | H |
| Lₐ₆₆₄₆ | Rₙ₇ | Ar143 | H | H | H | H | H | Rₙ₆₀ | H |
| Lₐ₆₆₄₇ | Rₙ₁₁ | Ar143 | H | H | H | H | H | Rₙ₆₀ | H |
| Lₐ₆₆₄₈ | Rₙ₂₀ | Ar143 | H | H | H | H | H | Rₙ₆₀ | H |
| Lₐ₆₆₄₉ | Rₙ₂₁ | Ar143 | H | H | H | H | H | Rₙ₆₀ | H |
| Lₐ₆₆₅₀ | Rₙ₅₁ | Ar143 | H | H | H | H | H | Rₙ₆₀ | H |
| Lₐ₆₆₅₁ | Rₙ₅₆ | Ar143 | H | H | H | H | H | Rₙ₆₀ | H |
| Lₐ₆₆₅₂ | Rₙ₅₉ | Ar143 | H | H | H | H | H | Rₙ₆₀ | H |
| Lₐ₆₆₅₃ | Rₙ₆₀ | Ar143 | H | H | H | H | H | Rₙ₆₀ | H |
| Lₐ₆₆₅₄ | Rₙ₆₁ | Ar143 | H | H | H | H | H | Rₙ₆₀ | H |
| Lₐ₆₆₅₅ | Rₙ₆₂ | Ar143 | H | H | H | H | H | Rₙ₆₀ | H |
| Lₐ₆₆₅₆ | Rₙ₆₄ | Ar143 | H | H | H | H | H | Rₙ₆₀ | H |
| Lₐ₆₆₅₇ | Rₙ₆₅ | Ar143 | H | H | H | H | H | Rₙ₆₀ | H |
| Lₐ₆₆₅₈ | Rₙ₆₉ | Ar143 | H | H | H | H | H | Rₙ₆₀ | H |
| Lₐ₆₆₅₉ | Rₙ₇₀ | Ar143 | H | H | H | H | H | Rₙ₆₀ | H |
| Lₐ₆₆₆₀ | Rₙ₈₁ | Ar143 | H | H | H | H | H | Rₙ₆₀ | H |
| Lₐ₆₆₆₁ | Rₙ₁ | Ar143 | H | H | H | H | H | Rₙ₆₄ | H |
| Lₐ₆₆₆₂ | Rₙ₄ | Ar143 | H | H | H | H | H | Rₙ₆₄ | H |
| Lₐ₆₆₆₃ | Rₙ₅ | Ar143 | H | H | H | H | H | Rₙ₆₄ | H |
| Lₐ₆₆₆₄ | Rₙ₇ | Ar143 | H | H | H | H | H | Rₙ₆₄ | H |
| Lₐ₆₆₆₅ | Rₙ₁₁ | Ar143 | H | H | H | H | H | Rₙ₆₄ | H |
| Lₐ₆₆₆₆ | Rₙ₂₀ | Ar143 | H | H | H | H | H | Rₙ₆₄ | H |
| Lₐ₆₆₆₇ | Rₙ₂₁ | Ar143 | H | H | H | H | H | Rₙ₆₄ | H |
| Lₐ₆₆₆₈ | Rₙ₅₁ | Ar143 | H | H | H | H | H | Rₙ₆₄ | H |
| Lₐ₆₆₆₉ | Rₙ₅₆ | Ar143 | H | H | H | H | H | Rₙ₆₄ | H |
| Lₐ₆₆₇₀ | Rₙ₅₉ | Ar143 | H | H | H | H | H | Rₙ₆₄ | H |
| Lₐ₆₆₇₁ | Rₙ₆₀ | Ar143 | H | H | H | H | H | Rₙ₆₄ | H |
| Lₐ₆₆₇₂ | Rₙ₆₁ | Ar143 | H | H | H | H | H | Rₙ₆₄ | H |
| Lₐ₆₆₇₃ | Rₙ₆₂ | Ar143 | H | H | H | H | H | Rₙ₆₄ | H |
| Lₐ₆₆₇₄ | Rₙ₆₄ | Ar143 | H | H | H | H | H | Rₙ₆₄ | H |
| Lₐ₆₆₇₅ | Rₙ₆₅ | Ar143 | H | H | H | H | H | Rₙ₆₄ | H |
| Lₐ₆₆₇₆ | Rₙ₆₉ | Ar143 | H | H | H | H | H | Rₙ₆₄ | H |
| Lₐ₆₆₇₇ | Rₙ₇₀ | Ar143 | H | H | H | H | H | Rₙ₆₄ | H |
| Lₐ₆₆₇₈ | Rₙ₈₁ | Ar143 | H | H | H | H | H | Rₙ₆₄ | H |
| Lₐ₆₆₇₉ | Rₙ₁ | Ar143 | H | H | H | H | H | Me | H |
| Lₐ₆₆₈₀ | Rₙ₄ | Ar143 | H | H | H | H | H | Me | H |
| Lₐ₆₆₈₁ | Rₙ₅ | Ar143 | H | H | H | H | H | Me | H |
| Lₐ₆₆₈₂ | Rₙ₇ | Ar143 | H | H | H | H | H | Me | H |
| Lₐ₆₆₈₃ | Rₙ₁₁ | Ar143 | H | H | H | H | H | Me | H |
| Lₐ₆₆₈₄ | Rₙ₂₀ | Ar143 | H | H | H | H | H | Me | H |
| Lₐ₆₆₈₅ | Rₙ₂₁ | Ar143 | H | H | H | H | H | Me | H |
| Lₐ₆₆₈₆ | Rₙ₅₁ | Ar143 | H | H | H | H | H | Me | H |
| Lₐ₆₆₈₇ | Rₙ₅₆ | Ar143 | H | H | H | H | H | Me | H |
| Lₐ₆₆₈₈ | Rₙ₅₉ | Ar143 | H | H | H | H | H | Me | H |
| Lₐ₆₆₈₉ | Rₙ₆₀ | Ar143 | H | H | H | H | H | Me | H |
| Lₐ₆₆₉₀ | Rₙ₆₁ | Ar143 | H | H | H | H | H | Me | H |
| Lₐ₆₆₉₁ | Rₙ₆₂ | Ar143 | H | H | H | H | H | Me | H |
| Lₐ₆₆₉₂ | Rₙ₆₄ | Ar143 | H | H | H | H | H | Me | H |
| Lₐ₆₆₉₃ | Rₙ₆₅ | Ar143 | H | H | H | H | H | Me | H |
| Lₐ₆₆₉₄ | Rₙ₆₉ | Ar143 | H | H | H | H | H | Me | H |
| Lₐ₆₆₉₅ | Rₙ₇₀ | Ar143 | H | H | H | H | H | Me | H |
| Lₐ₆₆₉₆ | Rₙ₈₁ | Ar143 | H | H | H | H | H | Me | H |
| Lₐ₆₆₉₇ | Rₙ₁ | Ar143 | H | H | H | H | Rₙ₁₁ | H | H |
| Lₐ₆₆₉₈ | Rₙ₄ | Ar143 | H | H | H | H | Rₙ₁₁ | H | H |
| Lₐ₆₆₉₉ | Rₙ₅ | Ar143 | H | H | H | H | Rₙ₁₁ | H | H |
| Lₐ₆₇₀₀ | Rₙ₇ | Ar143 | H | H | H | H | Rₙ₁₁ | H | H |
| Lₐ₆₇₀₁ | Rₙ₁₁ | Ar143 | H | H | H | H | Rₙ₁₁ | H | H |
| Lₐ₆₇₀₂ | Rₙ₂₀ | Ar143 | H | H | H | H | Rₙ₁₁ | H | H |
| Lₐ₆₇₀₃ | Rₙ₂₁ | Ar143 | H | H | H | H | Rₙ₁₁ | H | H |
| Lₐ₆₇₀₄ | Rₙ₅₁ | Ar143 | H | H | H | H | Rₙ₁₁ | H | H |
| Lₐ₆₇₀₅ | Rₙ₅₆ | Ar143 | H | H | H | H | Rₙ₁₁ | H | H |
| Lₐ₆₇₀₆ | Rₙ₅₉ | Ar143 | H | H | H | H | Rₙ₁₁ | H | H |
| Lₐ₆₇₀₇ | Rₙ₆₀ | Ar143 | H | H | H | H | Rₙ₁₁ | H | H |
| Lₐ₆₇₀₈ | Rₙ₆₁ | Ar143 | H | H | H | H | Rₙ₁₁ | H | H |
| Lₐ₆₇₀₉ | Rₙ₆₂ | Ar143 | H | H | H | H | Rₙ₁₁ | H | H |
| Lₐ₆₇₁₀ | Rₙ₆₄ | Ar143 | H | H | H | H | Rₙ₁₁ | H | H |
| Lₐ₆₇₁₁ | Rₙ₆₅ | Ar143 | H | H | H | H | Rₙ₁₁ | H | H |
| Lₐ₆₇₁₂ | Rₙ₆₉ | Ar143 | H | H | H | H | Rₙ₁₁ | H | H |
| Lₐ₆₇₁₃ | Rₙ₇₀ | Ar143 | H | H | H | H | Rₙ₁₁ | H | H |
| Lₐ₆₇₁₄ | Rₙ₈₁ | Ar143 | H | H | H | H | Rₙ₁₁ | H | H |
| Lₐ₆₇₁₅ | Rₙ₁ | Ar143 | H | H | H | H | Rₙ₅₉ | H | H |
| Lₐ₆₇₁₆ | Rₙ₄ | Ar143 | H | H | H | H | Rₙ₅₉ | H | H |
| Lₐ₆₇₁₇ | Rₙ₅ | Ar143 | H | H | H | H | Rₙ₅₉ | H | H |
| Lₐ₆₇₁₈ | Rₙ₇ | Ar143 | H | H | H | H | Rₙ₅₉ | H | H |
| Lₐ₆₇₁₉ | Rₙ₁₁ | Ar143 | H | H | H | H | Rₙ₅₉ | H | H |
| Lₐ₆₇₂₀ | Rₙ₂₀ | Ar143 | H | H | H | H | Rₙ₅₉ | H | H |
| Lₐ₆₇₂₁ | Rₙ₂₁ | Ar143 | H | H | H | H | Rₙ₅₉ | H | H |
| Lₐ₆₇₂₂ | Rₙ₅₁ | Ar143 | H | H | H | H | Rₙ₅₉ | H | H |
| Lₐ₆₇₂₃ | Rₙ₅₆ | Ar143 | H | H | H | H | Rₙ₅₉ | H | H |
| Lₐ₆₇₂₄ | Rₙ₅₉ | Ar143 | H | H | H | H | Rₙ₅₉ | H | H |
| Lₐ₆₇₂₅ | Rₙ₆₀ | Ar143 | H | H | H | H | Rₙ₅₉ | H | H |
| Lₐ₆₇₂₆ | Rₙ₆₁ | Ar143 | H | H | H | H | Rₙ₅₉ | H | H |
| Lₐ₆₇₂₇ | Rₙ₆₂ | Ar143 | H | H | H | H | Rₙ₅₉ | H | H |
| Lₐ₆₇₂₈ | Rₙ₆₄ | Ar143 | H | H | H | H | Rₙ₅₉ | H | H |
| Lₐ₆₇₂₉ | Rₙ₆₅ | Ar143 | H | H | H | H | Rₙ₅₉ | H | H |
| Lₐ₆₇₃₀ | Rₙ₆₉ | Ar143 | H | H | H | H | Rₙ₅₉ | H | H |
| Lₐ₆₇₃₁ | Rₙ₇₀ | Ar143 | H | H | H | H | Rₙ₅₉ | H | H |
| Lₐ₆₇₃₂ | Rₙ₈₁ | Ar143 | H | H | H | H | Rₙ₅₉ | H | H |
| Lₐ₆₇₃₃ | Rₙ₁ | Ar143 | H | H | H | H | Rₙ₆₀ | H | H |
| Lₐ₆₇₃₄ | Rₙ₄ | Ar143 | H | H | H | H | Rₙ₆₀ | H | H |
| Lₐ₆₇₃₅ | Rₙ₅ | Ar143 | H | H | H | H | Rₙ₆₀ | H | H |
| Lₐ₆₇₃₆ | Rₙ₇ | Ar143 | H | H | H | H | Rₙ₆₀ | H | H |
| Lₐ₆₇₃₇ | Rₙ₁₁ | Ar143 | H | H | H | H | Rₙ₆₀ | H | H |
| Lₐ₆₇₃₈ | Rₙ₂₀ | Ar143 | H | H | H | H | Rₙ₆₀ | H | H |
| Lₐ₆₇₃₉ | Rₙ₂₁ | Ar143 | H | H | H | H | Rₙ₆₀ | H | H |
| Lₐ₆₇₄₀ | Rₙ₅₁ | Ar143 | H | H | H | H | Rₙ₆₀ | H | H |
| Lₐ₆₇₄₁ | Rₙ₅₆ | Ar143 | H | H | H | H | Rₙ₆₀ | H | H |
| Lₐ₆₇₄₂ | Rₙ₅₉ | Ar143 | H | H | H | H | Rₙ₆₀ | H | H |
| Lₐ₆₇₄₃ | Rₙ₆₀ | Ar143 | H | H | H | H | Rₙ₆₀ | H | H |
| Lₐ₆₇₄₄ | Rₙ₆₁ | Ar143 | H | H | H | H | Rₙ₆₀ | H | H |
| Lₐ₆₇₄₅ | Rₙ₆₂ | Ar143 | H | H | H | H | Rₙ₆₀ | H | H |
| Lₐ₆₇₄₆ | Rₙ₆₄ | Ar143 | H | H | H | H | Rₙ₆₀ | H | H |
| Lₐ₆₇₄₇ | Rₙ₆₅ | Ar143 | H | H | H | H | Rₙ₆₀ | H | H |
| Lₐ₆₇₄₈ | Rₙ₆₉ | Ar143 | H | H | H | H | Rₙ₆₀ | H | D |
| Lₐ₆₇₄₉ | Rₙ₇₀ | Ar143 | H | H | H | H | Rₙ₆₀ | H | H |
| Lₐ₆₇₅₀ | Rₙ₈₁ | Ar143 | H | H | H | H | Rₙ₆₀ | H | H |
| Lₐ₆₇₅₁ | Rₙ₁ | Ar143 | H | H | H | H | Rₙ₆₄ | H | H |
| Lₐ₆₇₅₂ | Rₙ₄ | Ar143 | H | H | H | H | Rₙ₆₄ | H | H |
| Lₐ₆₇₅₃ | Rₙ₅ | Ar143 | H | H | H | H | Rₙ₆₄ | H | H |
| Lₐ₆₇₅₄ | Rₙ₇ | Ar143 | H | H | H | H | Rₙ₆₄ | H | H |
| Lₐ₆₇₅₅ | Rₙ₁₁ | Ar143 | H | H | H | H | Rₙ₆₄ | H | H |
| Lₐ₆₇₅₆ | Rₙ₂₀ | Ar143 | H | H | H | H | Rₙ₆₄ | D | H |
| Lₐ₆₇₅₇ | Rₙ₂₁ | Ar143 | D | H | H | H | Rₙ₆₄ | H | H |
| Lₐ₆₇₅₈ | Rₙ₅₁ | Ar143 | H | H | H | H | Rₙ₆₄ | H | H |
| Lₐ₆₇₅₉ | Rₙ₅₆ | Ar143 | H | H | H | H | Rₙ₆₄ | H | H |
| Lₐ₆₇₆₀ | Rₙ₅₉ | Ar143 | H | H | H | H | Rₙ₆₄ | H | H |
| Lₐ₆₇₆₁ | Rₙ₆₀ | Ar143 | H | H | H | H | Rₙ₆₄ | H | H |
| Lₐ₆₇₆₂ | Rₙ₆₁ | Ar143 | H | H | H | H | Rₙ₆₄ | H | H |
| Lₐ₆₇₆₃ | Rₙ₆₂ | Ar143 | H | H | H | H | Rₙ₆₄ | H | H |
| Lₐ₆₇₆₄ | Rₙ₆₄ | Ar143 | H | H | H | H | Rₙ₆₄ | H | H |
| Lₐ₆₇₆₅ | Rₙ₆₅ | Ar143 | H | H | H | H | Rₙ₆₄ | H | H |
| Lₐ₆₇₆₆ | Rₙ₆₉ | Ar143 | H | H | H | H | Rₙ₆₄ | H | H |
| Lₐ₆₇₆₇ | Rₙ₇₀ | Ar143 | H | H | H | H | Rₙ₆₄ | H | H |
| Lₐ₆₇₆₈ | Rₙ₈₁ | Ar143 | H | H | H | H | Rₙ₆₄ | H | H |
| Lₐ₆₇₆₉ | Rₙ₁ | Ar143 | H | H | H | H | Me | H | H |
| Lₐ₆₇₇₀ | Rₙ₄ | Ar143 | H | H | H | H | Me | H | H |
| Lₐ₆₇₇₁ | Rₙ₅ | Ar143 | H | H | H | H | Me | H | H |
| Lₐ₆₇₇₂ | Rₙ₇ | Ar143 | H | H | H | H | Me | H | H |
| Lₐ₆₇₇₃ | Rₙ₁₁ | Ar143 | H | H | H | H | CD₃ | H | H |
| Lₐ₆₇₇₄ | Rₙ₂₀ | Ar143 | H | H | H | H | Me | H | H |
| Lₐ₆₇₇₅ | Rₙ₂₁ | Ar143 | H | H | H | H | Me | H | H |
| Lₐ₆₇₇₆ | Rₙ₅₁ | Ar143 | H | H | H | H | Me | H | H |
| Lₐ₆₇₇₇ | Rₙ₅₆ | Ar143 | H | H | H | H | Me | H | H |
| Lₐ₆₇₇₈ | Rₙ₅₉ | Ar143 | H | H | H | H | Me | H | H |
| Lₐ₆₇₇₉ | Rₙ₆₀ | Ar143 | H | H | H | H | Me | H | H |
| Lₐ₆₇₈₀ | Rₙ₆₁ | Ar143 | H | H | H | H | Me | H | H |
| Lₐ₆₇₈₁ | Rₙ₆₂ | Ar143 | H | H | H | H | Me | H | H |
| Lₐ₆₇₈₂ | Rₙ₆₄ | Ar143 | H | H | H | H | Me | H | H |
| Lₐ₆₇₈₃ | Rₙ₆₅ | Ar143 | H | H | H | H | Me | H | H |
| Lₐ₆₇₈₄ | Rₙ₆₉ | Ar143 | H | H | H | H | Me | H | H |
| Lₐ₆₇₈₅ | Rₙ₇₀ | Ar143 | H | H | H | H | Me | H | H |
| Lₐ₆₇₈₆ | Rₙ₈₁ | Ar143 | H | H | H | H | Me | H | H |
| Lₐ₆₇₈₇ | Rₙ₁ | Ar143 | H | H | F | H | H | H | H |
| Lₐ₆₇₈₈ | Rₙ₄ | Ar143 | H | H | F | H | H | H | H |
| Lₐ₆₇₈₉ | Rₙ₇ | Ar143 | H | H | F | H | H | H | H |
| Lₐ₆₇₉₀ | Rₙ₂₀ | Ar143 | H | H | F | H | H | H | H |
| Lₐ₆₇₉₁ | Rₙ₂₁ | Ar143 | H | H | F | H | H | H | H |
| Lₐ₆₇₉₂ | Rₙ₅₆ | Ar143 | H | H | F | H | H | H | H |
| Lₐ₆₇₉₃ | Rₙ₅₉ | Ar143 | H | H | F | H | H | H | H |
| Lₐ₆₇₉₄ | Rₙ₆₁ | Ar143 | H | H | F | H | H | H | H |
| Lₐ₆₇₉₅ | Rₙ₆₂ | Ar143 | H | H | F | H | H | H | H |
| Lₐ₆₇₉₆ | Rₙ₆₄ | Ar143 | H | H | F | H | H | H | H |
| Lₐ₆₇₉₇ | Rₙ₆₉ | Ar143 | H | H | F | H | H | H | H |
| Lₐ₆₇₉₈ | Rₙ₇₀ | Ar143 | H | H | F | H | H | H | H |
| Lₐ₆₇₉₉ | Rₙ₁ | Ar143 | H | H | F | H | Rₙ₁₁ | H | H |
| Lₐ₆₈₀₀ | Rₙ₄ | Ar143 | H | H | F | H | Rₙ₁₁ | H | H |
| Lₐ₆₈₀₁ | Rₙ₇ | Ar143 | H | H | F | H | Rₙ₁₁ | H | H |
| Lₐ₆₈₀₂ | Rₙ₂₀ | Ar143 | H | H | F | H | Rₙ₁₁ | H | H |
| Lₐ₆₈₀₃ | Rₙ₂₁ | Ar143 | H | H | F | H | Rₙ₁₁ | H | H |
| Lₐ₆₈₀₄ | Rₙ₅₆ | Ar143 | H | H | F | H | Rₙ₁₁ | H | H |
| Lₐ₆₈₀₅ | Rₙ₅₉ | Ar143 | H | H | F | H | Rₙ₁₁ | H | H |
| Lₐ₆₈₀₆ | Rₙ₆₁ | Ar143 | H | H | F | H | Rₙ₁₁ | H | H |
| Lₐ₆₈₀₇ | Rₙ₆₂ | Ar143 | H | H | F | H | Rₙ₁₁ | H | H |
| Lₐ₆₈₀₈ | Rₙ₆₄ | Ar143 | H | H | F | H | Rₙ₁₁ | H | H |
| Lₐ₆₈₀₉ | Rₙ₆₉ | Ar143 | H | H | F | H | Rₙ₁₁ | H | H |
| Lₐ₆₈₁₀ | Rₙ₇₀ | Ar143 | H | H | F | H | Rₙ₁₁ | H | H |
| Lₐ₆₈₁₁ | Rₙ₁ | Ar143 | H | H | F | H | Rₙ₆₀ | H | D |
| Lₐ₆₈₁₂ | Rₙ₄ | Ar143 | H | H | F | H | Rₙ₆₀ | H | H |
| Lₐ₆₈₁₃ | Rₙ₇ | Ar143 | H | H | F | H | Rₙ₆₀ | H | H |
| Lₐ₆₈₁₄ | Rₙ₂₀ | Ar143 | H | H | F | H | Rₙ₆₀ | H | H |
| Lₐ₆₈₁₅ | Rₙ₂₁ | Ar143 | H | H | F | H | Rₙ₆₀ | H | H |
| Lₐ₆₈₁₆ | Rₙ₅₆ | Ar143 | H | H | F | D | Rₙ₆₀ | H | H |
| Lₐ₆₈₁₇ | Rₙ₅₉ | Ar143 | H | H | F | H | Rₙ₆₀ | H | H |
| Lₐ₆₈₁₈ | Rₙ₆₁ | Ar143 | H | H | F | H | Rₙ₆₀ | H | H |
| Lₐ₆₈₁₉ | Rₙ₆₂ | Ar143 | D | H | F | H | Rₙ₆₀ | H | H |
| Lₐ₆₈₂₀ | Rₙ₆₄ | Ar143 | H | H | F | H | Rₙ₆₀ | H | H |
| Lₐ₆₈₂₁ | Rₙ₆₉ | Ar143 | H | H | F | H | Rₙ₆₀ | H | H |
| Lₐ₆₈₂₂ | Rₙ₇₀ | Ar143 | H | H | F | H | Rₙ₆₀ | H | H |
| Lₐ₆₈₂₃ | Rₙ₁ | Ar143 | H | H | F | H | H | Rₙ₁₁ | H |
| Lₐ₆₈₂₄ | Rₙ₄ | Ar143 | H | H | F | H | H | Rₙ₁₁ | H |
| Lₐ₆₈₂₅ | Rₙ₇ | Ar143 | H | H | F | H | H | Rₙ₁₁ | H |
| Lₐ₆₈₂₆ | Rₙ₂₀ | Ar143 | H | H | F | H | H | Rₙ₁₁ | H |
| Lₐ₆₈₂₇ | Rₙ₂₁ | Ar143 | H | H | F | H | H | Rₙ₁₁ | H |
| Lₐ₆₈₂₈ | Rₙ₅₆ | Ar143 | H | H | F | H | H | Rₙ₁₁ | H |
| Lₐ₆₈₂₉ | Rₙ₅₉ | Ar143 | H | H | F | H | H | Rₙ₁₁ | H |
| Lₐ₆₈₃₀ | Rₙ₆₁ | Ar143 | H | H | F | H | H | Rₙ₁₁ | H |
| Lₐ₆₈₃₁ | Rₙ₆₂ | Ar143 | H | H | F | H | H | Rₙ₁₁ | H |
| Lₐ₆₈₃₂ | Rₙ₆₄ | Ar143 | H | H | F | H | H | Rₙ₁₁ | H |
| Lₐ₆₈₃₃ | Rₙ₆₉ | Ar143 | H | H | F | H | H | Rₙ₁₁ | H |
| Lₐ₆₈₃₄ | Rₙ₇₀ | Ar143 | H | H | F | H | H | Rₙ₁₁ | H |
| Lₐ₆₈₃₅ | Rₙ₁ | Ar143 | H | H | F | H | D | Rₙ₆₀ | H |
| Lₐ₆₈₃₆ | Rₙ₄ | Ar143 | H | H | F | D | H | Rₙ₆₀ | H |
| Lₐ₆₈₃₇ | Rₙ₇ | Ar143 | H | H | F | H | H | Rₙ₆₀ | H |
| Lₐ₆₈₃₈ | Rₙ₂₀ | Ar143 | H | H | F | H | H | Rₙ₆₀ | H |
| Lₐ₆₈₃₉ | Rₙ₂₁ | Ar143 | H | H | F | H | H | Rₙ₆₀ | D |
| Lₐ₆₈₄₀ | Rₙ₅₆ | Ar143 | H | H | F | H | H | Rₙ₆₀ | H |
| Lₐ₆₈₄₁ | Rₙ₅₉ | Ar143 | D | H | F | H | H | Rₙ₆₀ | H |
| Lₐ₆₈₄₂ | Rₙ₆₁ | Ar143 | H | H | F | H | H | Rₙ₆₀ | H |
| Lₐ₆₈₄₃ | Rₙ₆₂ | Ar143 | H | H | F | H | H | Rₙ₆₀ | H |
| Lₐ₆₈₄₄ | Rₙ₆₄ | Ar143 | H | D | F | H | H | Rₙ₆₀ | H |
| Lₐ₆₈₄₅ | Rₙ₆₉ | Ar143 | H | H | F | H | H | Rₙ₆₀ | H |
| Lₐ₆₈₄₆ | Rₙ₇₀ | Ar143 | H | H | F | H | H | Rₙ₆₀ | H |
| Lₐ₆₈₄₇ | Rₙ₁ | Ar143 | D | H | CN | H | H | H | H |
| Lₐ₆₈₄₈ | Rₙ₄ | Ar143 | H | H | CN | H | H | H | H |
| Lₐ₆₈₄₉ | Rₙ₇ | Ar143 | H | H | CN | H | H | H | H |
| Lₐ₆₈₅₀ | Rₙ₂₀ | Ar143 | H | H | CN | H | H | H | H |
| Lₐ₆₈₅₁ | Rₙ₂₁ | Ar143 | H | H | CN | H | H | H | H |
| Lₐ₆₈₅₂ | Rₙ₅₆ | Ar143 | H | H | CN | H | H | H | H |
| Lₐ₆₈₅₃ | Rₙ₅₉ | Ar143 | H | H | CN | H | H | H | H |
| Lₐ₆₈₅₄ | Rₙ₆₁ | Ar143 | H | H | CN | H | H | H | H |
| Lₐ₆₈₅₅ | Rₙ₆₂ | Ar143 | H | H | CN | H | H | H | H |
| Lₐ₆₈₅₆ | Rₙ₆₄ | Ar143 | H | H | CN | H | H | H | H |
| Lₐ₆₈₅₇ | Rₙ₆₉ | Ar143 | H | H | CN | H | H | H | H |
| Lₐ₆₈₅₈ | Rₙ₇₀ | Ar143 | H | H | CN | H | H | H | H |
| Lₐ₆₈₅₉ | Rₙ₁ | Ar143 | H | CN | H | H | H | H | H |
| Lₐ₆₈₆₀ | Rₙ₄ | Ar143 | H | CN | H | H | H | H | D |
| Lₐ₆₈₆₁ | Rₙ₇ | Ar143 | H | CN | H | H | H | H | H |
| Lₐ₆₈₆₂ | Rₙ₂₀ | Ar143 | H | CN | H | H | H | H | H |
| Lₐ₆₈₆₃ | Rₙ₂₁ | Ar143 | H | CN | H | H | H | D | H |
| Lₐ₆₈₆₄ | Rₙ₅₆ | Ar143 | H | CN | H | H | H | H | H |
| Lₐ₆₈₆₅ | Rₙ₅₉ | Ar143 | H | CN | H | H | H | H | H |
| Lₐ₆₈₆₆ | Rₙ₆₁ | Ar143 | H | CN | H | H | D | H | H |
| Lₐ₆₈₆₇ | Rₙ₆₂ | Ar143 | H | CN | H | H | H | H | H |
| Lₐ₆₈₆₈ | Rₙ₆₄ | Ar143 | H | CN | D | H | H | H | H |
| Lₐ₆₈₆₉ | Rₙ₆₉ | Ar143 | H | CN | H | H | H | H | H |
| Lₐ₆₈₇₀ | Rₙ₇₀ | Ar143 | D | CN | H | H | H | H | H |
| Lₐ₆₈₇₁ | Rₙ₁ | Ar143 | CN | H | H | H | H | H | H |
| Lₐ₆₈₇₂ | Rₙ₄ | Ar143 | CN | H | H | H | H | D | H |
| Lₐ₆₈₇₃ | Rₙ₇ | Ar143 | CN | H | H | H | H | H | H |
| Lₐ₆₈₇₄ | Rₙ₂₀ | Ar143 | CN | H | H | D | H | H | H |
| Lₐ₆₈₇₅ | Rₙ₂₁ | Ar143 | CN | H | D | H | H | H | H |
| Lₐ₆₈₇₆ | Rₙ₅₆ | Ar143 | CN | H | H | H | H | H | H |
| Lₐ₆₈₇₇ | Rₙ₅₉ | Ar143 | CN | D | H | H | H | H | H |
| Lₐ₆₈₇₈ | Rₙ₆₁ | Ar143 | CN | H | H | H | H | H | H |
| Lₐ₆₈₇₉ | Rₙ₆₂ | Ar143 | CN | H | H | H | H | H | H |
| Lₐ₆₈₈₀ | Rₙ₆₄ | Ar143 | CN | H | H | H | H | H | H |
| Lₐ₆₈₈₁ | Rₙ₆₉ | Ar143 | CN | H | H | H | H | H | H |
| Lₐ₆₈₈₂ | Rₙ₇₀ | Ar143 | CN | H | H | H | H | H | H |
| Lₐ₆₈₈₃ | Rₙ₁ | Ar143 | H | H | CN | H | Rₙ₁₁ | H | H |
| Lₐ₆₈₈₄ | Rₙ₄ | Ar143 | H | H | CN | H | Rₙ₁₁ | H | H |
| Lₐ₆₈₈₅ | Rₙ₇ | Ar143 | H | H | CN | H | Rₙ₁₁ | D | H |
| Lₐ₆₈₈₆ | Rₙ₂₀ | Ar143 | H | H | CN | H | Rₙ₁₁ | H | H |
| Lₐ₆₈₈₇ | Rₙ₂₁ | Ar143 | H | H | CN | H | Rₙ₁₁ | H | H |
| Lₐ₆₈₈₈ | Rₙ₅₆ | Ar143 | D | H | CN | H | Rₙ₁₁ | H | H |
| Lₐ₆₈₈₉ | Rₙ₅₉ | Ar143 | H | H | CN | H | Rₙ₁₁ | H | H |
| Lₐ₆₈₉₀ | Rₙ₆₁ | Ar143 | H | D | CN | H | Rₙ₁₁ | H | H |
| Lₐ₆₈₉₁ | Rₙ₆₂ | Ar143 | H | H | CN | H | Rₙ₁₁ | H | H |
| Lₐ₆₈₉₂ | Rₙ₆₄ | Ar143 | H | H | CN | H | Rₙ₁₁ | H | H |
| Lₐ₆₈₉₃ | Rₙ₆₉ | Ar143 | H | H | CN | H | Rₙ₁₁ | H | H |
| Lₐ₆₈₉₄ | Rₙ₇₀ | Ar143 | H | H | CN | H | Rₙ₁₁ | H | H |
| Lₐ₆₈₉₅ | Rₙ₁ | Ar143 | H | H | CN | H | Rₙ₆₀ | D | H |
| Lₐ₆₈₉₆ | Rₙ₄ | Ar143 | H | H | CN | H | Rₙ₆₀ | D | H |
| Lₐ₆₈₉₇ | Rₙ₇ | Ar143 | H | H | CN | H | Rₙ₆₀ | D | H |
| Lₐ₆₈₉₈ | Rₙ₂₀ | Ar143 | H | H | CN | H | Rₙ₆₀ | D | H |
| Lₐ₆₈₉₉ | Rₙ₂₁ | Ar143 | H | H | CN | H | Rₙ₆₀ | D | H |
| Lₐ₆₉₀₀ | Rₙ₅₆ | Ar143 | H | H | CN | H | Rₙ₆₀ | D | H |
| Lₐ₆₉₀₁ | Rₙ₅₉ | Ar143 | H | H | CN | H | Rₙ₆₀ | D | H |
| Lₐ₆₉₀₂ | Rₙ₆₁ | Ar143 | H | H | CN | H | Rₙ₆₀ | D | H |
| Lₐ₆₉₀₃ | Rₙ₆₂ | Ar143 | H | H | CN | H | Rₙ₆₀ | D | H |
| Lₐ₆₉₀₄ | Rₙ₆₄ | Ar143 | H | H | CN | H | Rₙ₆₀ | D | H |
| Lₐ₆₉₀₅ | Rₙ₆₉ | Ar143 | H | H | CN | H | Rₙ₆₀ | D | H |
| Lₐ₆₉₀₆ | Rₙ₇₀ | Ar143 | H | H | CN | H | Rₙ₆₀ | D | H |
| Lₐ₆₉₀₇ | Rₙ₁ | Ar143 | H | H | CN | H | Rₙ₆₄ | H | H |
| Lₐ₆₉₀₈ | Rₙ₄ | Ar143 | H | H | CN | H | Rₙ₆₄ | H | H |
| Lₐ₆₉₀₉ | Rₙ₇ | Ar143 | H | H | CN | H | Rₙ₆₄ | H | H |
| Lₐ₆₉₁₀ | Rₙ₂₀ | Ar143 | H | H | CN | H | Rₙ₆₄ | H | H |
| Lₐ₆₉₁₁ | Rₙ₂₁ | Ar143 | H | H | CN | H | Rₙ₆₄ | H | H |
| Lₐ₆₉₁₂ | Rₙ₅₆ | Ar143 | H | H | CN | H | Rₙ₆₄ | H | H |
| Lₐ₆₉₁₃ | Rₙ₅₉ | Ar143 | H | H | CN | H | Rₙ₆₄ | H | H |
| Lₐ₆₉₁₄ | Rₙ₆₁ | Ar143 | H | H | CN | H | Rₙ₆₄ | H | H |
| Lₐ₆₉₁₅ | Rₙ₆₂ | Ar143 | H | H | CN | H | Rₙ₆₄ | H | H |
| Lₐ₆₉₁₆ | Rₙ₆₄ | Ar143 | H | H | CN | H | Rₙ₆₄ | H | H |
| Lₐ₆₉₁₇ | Rₙ₆₉ | Ar143 | H | H | CN | H | Rₙ₆₄ | H | H |
| Lₐ₆₉₁₈ | Rₙ₇₀ | Ar143 | H | H | CN | H | Rₙ₆₄ | H | H |
| Lₐ₆₉₁₉ | Rₙ₁ | Ar143 | H | H | CN | H | H | Rₙ₁₁ | H |
| Lₐ₆₉₂₀ | Rₙ₄ | Ar143 | H | H | CN | H | H | Rₙ₁₁ | H |
| Lₐ₆₉₂₁ | Rₙ₇ | Ar143 | H | H | CN | H | H | Rₙ₁₁ | D |
| Lₐ₆₉₂₂ | Rₙ₂₀ | Ar143 | H | H | CN | H | H | Rₙ₁₁ | H |
| Lₐ₆₉₂₃ | Rₙ₂₁ | Ar143 | H | H | CN | H | H | Rₙ₁₁ | H |
| Lₐ₆₉₂₄ | Rₙ₅₆ | Ar143 | H | H | CN | H | H | Rₙ₁₁ | H |
| Lₐ₆₉₂₅ | Rₙ₅₉ | Ar143 | H | H | CN | H | H | Rₙ₁₁ | H |
| Lₐ₆₉₂₆ | Rₙ₆₁ | Ar143 | H | H | CN | H | H | Rₙ₁₁ | H |
| Lₐ₆₉₂₇ | Rₙ₆₂ | Ar143 | H | H | CN | H | H | Rₙ₁₁ | H |
| Lₐ₆₉₂₈ | Rₙ₆₄ | Ar143 | D | H | CN | H | H | Rₙ₁₁ | H |
| Lₐ₆₉₂₉ | Rₙ₆₉ | Ar143 | H | H | CN | H | H | Rₙ₁₁ | H |
| Lₐ₆₉₃₀ | Rₙ₇₀ | Ar143 | H | D | CN | H | H | Rₙ₁₁ | H |
| Lₐ₆₉₃₁ | Rₙ₁ | Ar143 | H | H | CN | H | H | Rₙ₆₀ | D |
| Lₐ₆₉₃₂ | Rₙ₄ | Ar143 | H | H | CN | H | H | Rₙ₆₀ | D |
| Lₐ₆₉₃₃ | Rₙ₇ | Ar143 | H | H | CN | H | H | Rₙ₆₀ | D |
| Lₐ₆₉₃₄ | Rₙ₂₀ | Ar143 | H | H | CN | H | H | Rₙ₆₀ | D |
| Lₐ₆₉₃₅ | Rₙ₂₁ | Ar143 | H | H | CN | H | H | Rₙ₆₀ | D |
| Lₐ₆₉₃₆ | Rₙ₅₆ | Ar143 | H | H | CN | H | H | Rₙ₆₀ | D |
| Lₐ₆₉₃₇ | Rₙ₅₉ | Ar143 | H | H | CN | H | H | Rₙ₆₀ | D |
| Lₐ₆₉₃₈ | Rₙ₆₁ | Ar143 | H | H | CN | H | H | Rₙ₆₀ | D |
| Lₐ₆₉₃₉ | Rₙ₆₂ | Ar143 | H | H | CN | H | H | Rₙ₆₀ | D |
| Lₐ₆₉₄₀ | Rₙ₆₄ | Ar143 | H | H | CN | H | H | Rₙ₆₀ | D |
| Lₐ₆₉₄₁ | Rₙ₆₉ | Ar143 | H | H | CN | H | H | Rₙ₆₀ | D |
| Lₐ₆₉₄₂ | Rₙ₇₀ | Ar143 | H | H | CN | H | H | Rₙ₆₀ | D |
| Lₐ₆₉₄₃ | Rₙ₁ | Ar143 | H | H | CN | H | H | Rₙ₆₄ | H |
| Lₐ₆₉₄₄ | Rₙ₄ | Ar143 | H | H | CN | H | H | Rₙ₆₄ | H |
| Lₐ₆₉₄₅ | Rₙ₇ | Ar143 | H | H | CN | H | H | Rₙ₆₄ | H |
| Lₐ₆₉₄₆ | Rₙ₂₀ | Ar143 | H | H | CN | H | H | Rₙ₆₄ | H |
| Lₐ₆₉₄₇ | Rₙ₂₁ | Ar143 | H | H | CN | H | H | Rₙ₆₄ | H |
| Lₐ₆₉₄₈ | Rₙ₅₆ | Ar143 | H | H | CN | H | H | Rₙ₆₄ | H |
| Lₐ₆₉₄₉ | Rₙ₅₉ | Ar143 | H | H | CN | H | H | Rₙ₆₄ | H |
| Lₐ₆₉₅₀ | Rₙ₆₁ | Ar143 | H | H | CN | H | H | Rₙ₆₄ | H |
| Lₐ₆₉₅₁ | Rₙ₆₂ | Ar143 | H | H | CN | H | H | Rₙ₆₄ | H |
| Lₐ₆₉₅₂ | Rₙ₆₄ | Ar143 | H | H | CN | H | H | Rₙ₆₄ | H |
| Lₐ₆₉₅₃ | Rₙ₆₉ | Ar143 | H | H | CN | H | H | Rₙ₆₄ | H |
| Lₐ₆₉₅₄ | Rₙ₇₀ | Ar143 | H | H | CN | H | H | Rₙ₆₄ | H; |

wherein optionally, hydrogen in the ligands Lₐ₁ to Lₐ₆₉₅₄ can be optionally partially or fully substituted with deuterium.

17. The metal complex according to claim 16, wherein L_{b} is, at each occurrence identically or differently, selected from the group consisting of the following: 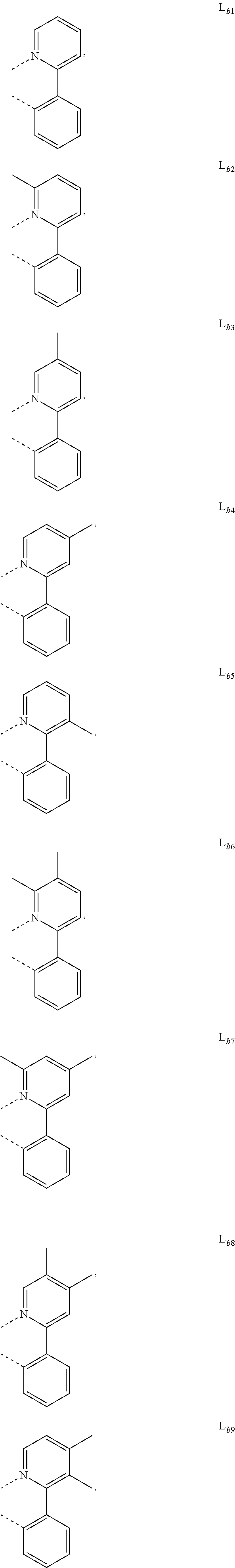 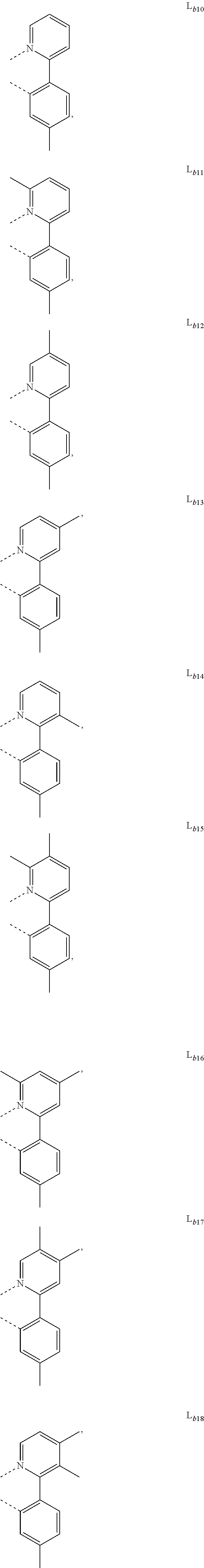 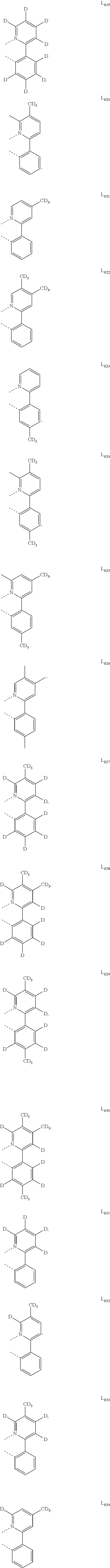 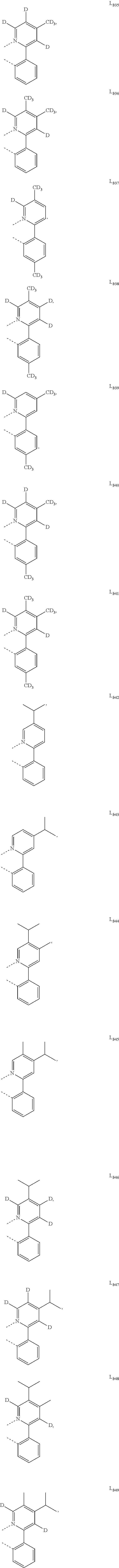 [chemical structure] 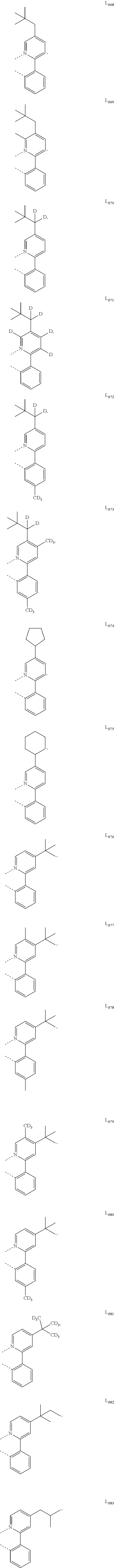 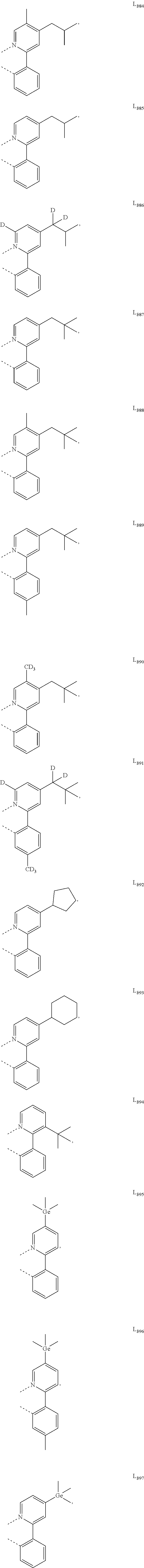 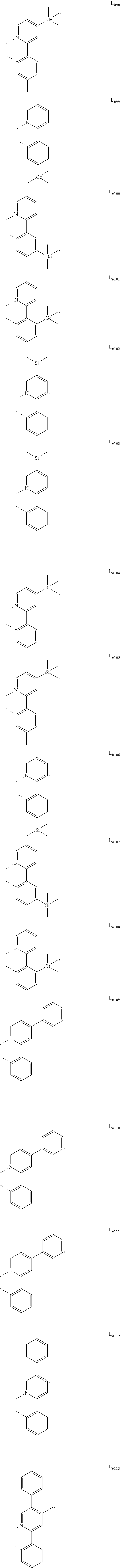 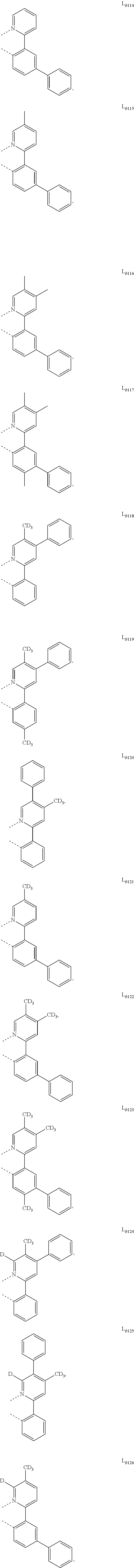 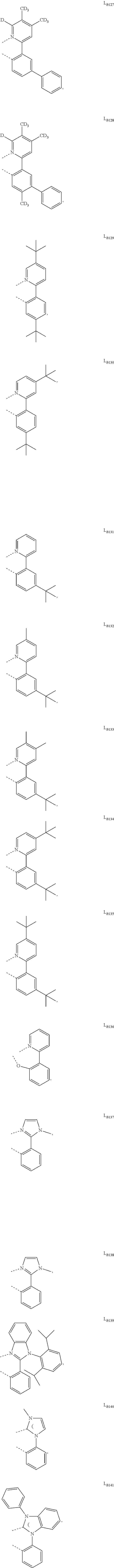 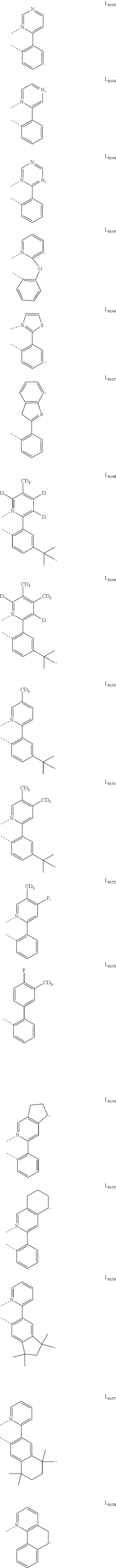
wherein optionally, hydrogen in L_{b1} to L_{b18}, L_{b20} to L_{b26} and L_{b31} to L_{b158} can be partially or fully substituted with deuterium.

18. The metal complex according to claim 17, wherein the metal complex has a structure of Ir(Lₐ)(L_{b})₂, wherein the two L_{b} are identical or different, Lₐ is, at each occurrence identically or differently, selected from the group consisting of Lₐ₁ to Lₐ₆₉₅₄, and L_{b} is, at each occurrence identically or differently, selected from one or two of the group consisting of L_{b1} to L_{b158},
preferably, the metal complex is selected from the group consisting of Metal Complex 1 to Metal Complex 6728, wherein Metal Complex 1 to Metal Complex 6728 each have a structure of Ir(Lₐ)(L_{b})₂, wherein the two L_{b} are identical, and Lₐ and L_{b} respectively correspond to the structures in the following table:

| Metal | | | Metal | | |
|---|---|---|---|---|---|
| Complex | Lₐ | L_{b} | Complex | Lₐ | L_{b} |
| 1 | Lₐ₅ | L_{b1} | 2 | Lₐ₇ | L_{b1} |
| 3 | Lₐ₁₀ | L_{b1} | 4 | Lₐ₁₁ | L_{b1} |
| 5 | Lₐ₁₃ | L_{b1} | 6 | Lₐ₁₄ | L_{b1} |
| 7 | Lₐ₁₇ | L_{b1} | 8 | Lₐ₂₃ | L_{b1} |
| 9 | Lₐ₂₈ | L_{b1} | 10 | Lₐ₂₉ | L_{b1} |
| 11 | Lₐ₃₁ | L_{b1} | 12 | Lₐ₃₅ | L_{b1} |
| 13 | Lₐ₅₉ | L_{b1} | 14 | Lₐ₆₄ | L_{b1} |
| 15 | Lₐ₆₅ | L_{b1} | 16 | Lₐ₆₇ | L_{b1} |
| 17 | Lₐ₇₁ | L_{b1} | 18 | Lₐ₁₁₃ | L_{b1} |
| 19 | Lₐ₁₁₈ | L_{b1} | 20 | Lₐ₁₁₉ | L_{b1} |
| 21 | Lₐ₁₂₁ | L_{b1} | 22 | Lₐ₁₂₅ | L_{b1} |
| 23 | Lₐ₁₄₉ | L_{b1} | 24 | Lₐ₁₅₄ | L_{b1} |
| 25 | Lₐ₁₅₅ | L_{b1} | 26 | Lₐ₁₅₇ | L_{b1} |
| 27 | Lₐ₁₆₁ | L_{b1} | 28 | Lₐ₂₀₅ | L_{b1} |
| 29 | Lₐ₂₀₇ | L_{b1} | 30 | Lₐ₂₁₀ | L_{b1} |
| 31 | Lₐ₂₁₇ | L_{b1} | 32 | Lₐ₂₁₉ | L_{b1} |
| 33 | Lₐ₂₂₂ | L_{b1} | 34 | Lₐ₂₂₉ | L_{b1} |
| 35 | Lₐ₂₃₁ | L_{b1} | 36 | Lₐ₂₃₄ | L_{b1} |
| 37 | Lₐ₂₄₁ | L_{b1} | 38 | Lₐ₂₄₃ | L_{b1} |
| 39 | Lₐ₂₄₆ | L_{b1} | 40 | Lₐ₂₅₃ | L_{b1} |
| 41 | Lₐ₂₅₅ | L_{b1} | 42 | Lₐ₂₅₈ | L_{b1} |
| 43 | Lₐ₂₆₁ | L_{b1} | 44 | Lₐ₂₆₃ | L_{b1} |
| 45 | Lₐ₂₆₅ | L_{b1} | 46 | Lₐ₂₆₇ | L_{b1} |
| 47 | Lₐ₂₇₀ | L_{b1} | 48 | Lₐ₂₇₇ | L_{b1} |
| 49 | Lₐ₂₇₉ | L_{b1} | 50 | Lₐ₂₈₂ | L_{b1} |
| 51 | Lₐ₂₈₉ | L_{b1} | 52 | Lₐ₂₉₁ | L_{b1} |
| 53 | Lₐ₂₉₄ | L_{b1} | 54 | Lₐ₃₀₁ | L_{b1} |
| 55 | Lₐ₃₀₃ | L_{b1} | 56 | Lₐ₃₀₆ | L_{b1} |
| 57 | Lₐ₃₁₃ | L_{b1} | 58 | Lₐ₃₁₅ | L_{b1} |
| 59 | Lₐ₃₁₈ | L_{b1} | 60 | Lₐ₃₂₅ | L_{b1} |
| 61 | Lₐ₃₂₇ | L_{b1} | 62 | Lₐ₃₃₀ | L_{b1} |
| 63 | Lₐ₃₃₇ | L_{b1} | 64 | Lₐ₃₃₉ | L_{b1} |
| 65 | Lₐ₃₄₂ | L_{b1} | 66 | Lₐ₃₄₉ | L_{b1} |
| 67 | Lₐ₃₅₁ | L_{b1} | 68 | Lₐ₃₅₄ | L_{b1} |
| 69 | Lₐ₃₆₁ | L_{b1} | 70 | Lₐ₃₆₃ | L_{b1} |
| 71 | Lₐ₃₆₆ | L_{b1} | 72 | Lₐ₃₇₁ | L_{b1} |
| 73 | Lₐ₅₇₁ | L_{b1} | 74 | Lₐ₅₇₃ | L_{b1} |
| 75 | Lₐ₆₃₁ | L_{b1} | 76 | Lₐ₆₃₃ | L_{b1} |
| 77 | Lₐ₇₃₇ | L_{b1} | 78 | Lₐ₉₃₇ | L_{b1} |
| 79 | Lₐ₉₃₉ | L_{b1} | 80 | Lₐ₉₉₇ | L_{b1} |
| 81 | Lₐ₉₉₉ | L_{b1} | 82 | Lₐ₁₀₀₉ | L_{b1} |
| 83 | Lₐ₁₀₁₁ | L_{b1} | 84 | Lₐ₁₀₂₁ | L_{b1} |
| 85 | Lₐ₁₀₂₃ | L_{b1} | 86 | Lₐ₁₁₀₃ | L_{b1} |
| 87 | Lₐ₁₁₀₅ | L_{b1} | 88 | Lₐ₁₁₀₈ | L_{b1} |
| 89 | Lₐ₁₁₀₉ | L_{b1} | 90 | Lₐ₁₁₁₁ | L_{b1} |
| 91 | Lₐ₁₁₁₂ | L_{b1} | 92 | Lₐ₁₁₁₅ | L_{b1} |
| 93 | Lₐ₁₁₂₁ | L_{b1} | 94 | Lₐ₁₁₂₆ | L_{b1} |
| 95 | Lₐ₁₁₂₇ | L_{b1} | 96 | Lₐ₁₁₂₉ | L_{b1} |
| 97 | Lₐ₁₁₃₃ | L_{b1} | 98 | Lₐ₁₁₅₇ | L_{b1} |
| 99 | Lₐ₁₁₆₂ | L_{b1} | 100 | Lₐ₁₁₆₃ | L_{b1} |
| 101 | Lₐ₁₁₆₅ | L_{b1} | 102 | Lₐ₁₁₆₉ | L_{b1} |
| 103 | Lₐ₁₂₁₁ | L_{b1} | 104 | Lₐ₁₂₁₆ | L_{b1} |
| 105 | Lₐ₁₂₁₇ | L_{b1} | 106 | Lₐ₁₂₁₉ | L_{b1} |
| 107 | Lₐ₁₂₂₃ | L_{b1} | 108 | Lₐ₁₂₄₇ | L_{b1} |
| 109 | Lₐ₁₂₅₂ | L_{b1} | 110 | Lₐ₁₂₅₃ | L_{b1} |
| 111 | Lₐ₁₂₅₅ | L_{b1} | 112 | Lₐ₁₂₅₉ | L_{b1} |
| 113 | Lₐ₁₃₀₃ | L_{b1} | 114 | Lₐ₁₃₀₅ | L_{b1} |
| 115 | Lₐ₁₃₀₈ | L_{b1} | 116 | Lₐ₁₃₁₅ | L_{b1} |
| 117 | Lₐ₁₃₁₇ | L_{b1} | 118 | Lₐ₁₃₂₀ | L_{b1} |
| 119 | Lₐ₁₃₂₇ | L_{b1} | 120 | Lₐ₁₃₂₉ | L_{b1} |
| 121 | Lₐ₁₃₃₂ | L_{b1} | 122 | Lₐ₁₃₃₉ | L_{b1} |
| 123 | Lₐ₁₃₄₁ | L_{b1} | 124 | Lₐ₁₃₄₄ | L_{b1} |
| 125 | Lₐ₁₃₅₁ | L_{b1} | 126 | Lₐ₁₃₅₃ | L_{b1} |
| 127 | Lₐ₁₃₅₆ | L_{b1} | 128 | Lₐ₁₃₅₉ | L_{b1} |
| 129 | Lₐ₁₃₆₁ | L_{b1} | 130 | Lₐ₁₃₆₃ | L_{b1} |
| 131 | Lₐ₁₃₆₅ | L_{b1} | 132 | Lₐ₁₃₆₈ | L_{b1} |
| 133 | Lₐ₁₃₇₅ | L_{b1} | 134 | Lₐ₁₃₇₇ | L_{b1} |
| 135 | Lₐ₁₃₈₇ | L_{b1} | 136 | Lₐ₁₃₈₉ | L_{b1} |
| 137 | Lₐ₁₄₆₉ | L_{b1} | 138 | Lₐ₁₆₆₉ | L_{b1} |
| 139 | Lₐ₁₆₇₁ | L_{b1} | 140 | Lₐ₁₇₂₉ | L_{b1} |
| 141 | Lₐ₁₇₃₁ | L_{b1} | 142 | Lₐ₁₇₄₁ | L_{b1} |
| 143 | Lₐ₁₇₄₃ | L_{b1} | 144 | Lₐ₁₇₅₃ | L_{b1} |
| 145 | Lₐ₁₇₅₅ | L_{b1} | 146 | Lₐ₁₈₃₅ | L_{b1} |
| 147 | Lₐ₂₀₃₅ | L_{b1} | 148 | Lₐ₂₀₃₇ | L_{b1} |
| 149 | Lₐ₂₀₉₅ | L_{b1} | 150 | Lₐ₂₀₉₇ | L_{b1} |
| 151 | Lₐ₂₁₀₇ | L_{b1} | 152 | Lₐ₂₁₀₉ | L_{b1} |
| 153 | Lₐ₂₁₁₉ | L_{b1} | 154 | Lₐ₂₁₂₁ | L_{b1} |
| 155 | Lₐ₂₂₀₁ | L_{b1} | 156 | Lₐ₂₄₀₁ | L_{b1} |
| 157 | Lₐ₂₄₀₃ | L_{b1} | 158 | Lₐ₂₄₆₁ | L_{b1} |
| 159 | Lₐ₂₄₆₃ | L_{b1} | 160 | Lₐ₂₄₇₃ | L_{b1} |
| 161 | Lₐ₂₄₇₅ | L_{b1} | 162 | Lₐ₂₄₈₅ | L_{b1} |
| 163 | Lₐ₂₄₈₇ | L_{b1} | 164 | Lₐ₂₅₆₇ | L_{b1} |
| 165 | Lₐ₂₇₆₇ | L_{b1} | 166 | Lₐ₂₇₆₉ | L_{b1} |
| 167 | Lₐ₂₈₂₇ | L_{b1} | 168 | Lₐ₂₈₂₉ | L_{b1} |
| 169 | Lₐ₂₈₅₁ | L_{b1} | 170 | Lₐ₂₈₅₃ | L_{b1} |
| 171 | Lₐ₂₉₃₃ | L_{b1} | 172 | Lₐ₂₉₃₅ | L_{b1} |
| 173 | Lₐ₂₉₃₈ | L_{b1} | 174 | Lₐ₂₉₃₉ | L_{b1} |
| 175 | Lₐ₂₉₄₁ | L_{b1} | 176 | Lₐ₂₉₄₂ | L_{b1} |
| 177 | Lₐ₂₉₄₅ | L_{b1} | 178 | Lₐ₂₉₅₁ | L_{b1} |
| 179 | Lₐ₂₉₅₆ | L_{b1} | 180 | Lₐ₂₉₅₇ | L_{b1} |
| 181 | Lₐ₂₉₅₉ | L_{b1} | 182 | Lₐ₂₉₆₃ | L_{b1} |
| 183 | Lₐ₂₉₈₇ | L_{b1} | 184 | Lₐ₂₉₉₂ | L_{b1} |
| 185 | Lₐ₂₉₉₃ | L_{b1} | 186 | Lₐ₂₉₉₅ | L_{b1} |
| 187 | Lₐ₂₉₉₉ | L_{b1} | 188 | Lₐ₃₀₄₁ | L_{b1} |
| 189 | Lₐ₃₀₄₆ | L_{b1} | 190 | Lₐ₃₀₄₇ | L_{b1} |
| 191 | Lₐ₃₀₄₉ | L_{b1} | 192 | Lₐ₃₀₅₃ | L_{b1} |
| 193 | Lₐ₃₀₇₇ | L_{b1} | 194 | Lₐ₃₀₈₂ | L_{b1} |
| 195 | Lₐ₃₀₈₃ | L_{b1} | 196 | Lₐ₃₀₈₅ | L_{b1} |
| 197 | Lₐ₃₀₈₉ | L_{b1} | 198 | Lₐ₃₁₃₃ | L_{b1} |
| 199 | Lₐ₃₁₃₅ | L_{b1} | 200 | Lₐ₃₁₃₈ | L_{b1} |
| 201 | Lₐ₃₁₄₅ | L_{b1} | 202 | Lₐ₃₁₄₇ | L_{b1} |
| 203 | Lₐ₃₁₅₀ | L_{b1} | 204 | Lₐ₃₁₆₉ | L_{b1} |
| 205 | Lₐ₃₁₇₁ | L_{b1} | 206 | Lₐ₃₁₇₄ | L_{b1} |
| 207 | Lₐ₃₁₈₁ | L_{b1} | 208 | Lₐ₃₁₈₃ | L_{b1} |
| 209 | Lₐ₃₁₈₆ | L_{b1} | 210 | Lₐ₃₁₈₉ | L_{b1} |
| 211 | Lₐ₃₁₉₁ | L_{b1} | 212 | Lₐ₃₁₉₃ | L_{b1} |
| 213 | Lₐ₃₁₉₅ | L_{b1} | 214 | Lₐ₃₁₉₈ | L_{b1} |
| 215 | Lₐ₃₂₀₅ | L_{b1} | 216 | Lₐ₃₂₀₇ | L_{b1} |
| 217 | Lₐ₃₂₁₇ | L_{b1} | 218 | Lₐ₃₂₁₉ | L_{b1} |
| 219 | Lₐ₃₂₂₉ | L_{b1} | 220 | Lₐ₃₂₃₁ | L_{b1} |
| 221 | Lₐ₃₂₃₄ | L_{b1} | 222 | Lₐ₃₂₄₁ | L_{b1} |
| 223 | Lₐ₃₂₄₃ | L_{b1} | 224 | Lₐ₃₂₄₆ | L_{b1} |
| 225 | Lₐ₃₂₅₃ | L_{b1} | 226 | Lₐ₃₂₅₅ | L_{b1} |
| 227 | Lₐ₃₂₅₈ | L_{b1} | 228 | Lₐ₃₂₆₅ | L_{b1} |
| 229 | Lₐ₃₂₆₇ | L_{b1} | 230 | Lₐ₃₂₇₀ | L_{b1} |
| 231 | Lₐ₃₂₇₇ | L_{b1} | 232 | Lₐ₃₂₇₉ | L_{b1} |
| 233 | Lₐ₃₂₈₂ | L_{b1} | 234 | Lₐ₃₂₈₉ | L_{b1} |
| 235 | Lₐ₃₂₉₁ | L_{b1} | 236 | Lₐ₃₂₉₄ | L_{b1} |
| 237 | Lₐ₃₂₉₉ | L_{b1} | 238 | Lₐ₃₄₉₉ | L_{b1} |
| 239 | Lₐ₃₅₀₁ | L_{b1} | 240 | Lₐ₃₅₅₉ | L_{b1} |
| 241 | Lₐ₃₅₆₁ | L_{b1} | 242 | Lₐ₃₅₇₁ | L_{b1} |
| 243 | Lₐ₃₅₇₃ | L_{b1} | 244 | Lₐ₃₅₈₃ | L_{b1} |
| 245 | Lₐ₃₅₈₅ | L_{b1} | 246 | Lₐ₃₆₆₅ | L_{b1} |
| 247 | Lₐ₃₆₆₇ | L_{b1} | 248 | Lₐ₃₆₇₀ | L_{b1} |
| 249 | Lₐ₃₆₇₁ | L_{b1} | 250 | Lₐ₃₆₇₃ | L_{b1} |
| 251 | Lₐ₃₆₇₄ | L_{b1} | 252 | Lₐ₃₆₇₇ | L_{b1} |
| 253 | Lₐ₃₆₈₃ | L_{b1} | 254 | Lₐ₃₆₈₈ | L_{b1} |
| 255 | Lₐ₃₆₈₉ | L_{b1} | 256 | Lₐ₃₆₉₁ | L_{b1} |
| 257 | Lₐ₃₆₉₅ | L_{b1} | 258 | Lₐ₃₇₁₉ | L_{b1} |
| 259 | Lₐ₃₇₂₄ | L_{b1} | 260 | Lₐ₃₇₂₅ | L_{b1} |
| 261 | Lₐ₃₇₂₇ | L_{b1} | 262 | Lₐ₃₇₃₁ | L_{b1} |
| 263 | Lₐ₃₇₇₃ | L_{b1} | 264 | Lₐ₃₇₇₈ | L_{b1} |
| 265 | Lₐ₃₇₇₉ | L_{b1} | 266 | Lₐ₃₇₈₁ | L_{b1} |
| 267 | Lₐ₃₇₈₅ | L_{b1} | 268 | Lₐ₃₈₀₉ | L_{b1} |
| 269 | Lₐ₃₈₁₄ | L_{b1} | 270 | Lₐ₃₈₁₅ | L_{b1} |
| 271 | Lₐ₃₈₁₇ | L_{b1} | 272 | Lₐ₃₈₂₁ | L_{b1} |
| 273 | Lₐ₃₈₆₅ | L_{b1} | 274 | Lₐ₃₈₆₇ | L_{b1} |
| 275 | Lₐ₃₈₇₀ | L_{b1} | 276 | Lₐ₃₈₇₇ | L_{b1} |
| 277 | Lₐ₃₈₇₉ | L_{b1} | 278 | Lₐ₃₈₈₂ | L_{b1} |
| 279 | Lₐ₃₈₈₉ | L_{b1} | 280 | Lₐ₃₈₉₁ | L_{b1} |
| 281 | Lₐ₃₈₉₄ | L_{b1} | 282 | Lₐ₃₉₀₁ | L_{b1} |
| 283 | Lₐ₃₉₀₃ | L_{b1} | 284 | Lₐ₃₉₀₆ | L_{b1} |
| 285 | Lₐ₃₉₁₃ | L_{b1} | 286 | Lₐ₃₉₁₅ | L_{b1} |
| 287 | Lₐ₃₉₁₈ | L_{b1} | 288 | Lₐ₃₉₂₁ | L_{b1} |
| 289 | Lₐ₃₉₂₃ | L_{b1} | 290 | Lₐ₃₉₂₄ | L_{b1} |
| 291 | Lₐ₃₉₂₅ | L_{b1} | 292 | Lₐ₃₉₂₇ | L_{b1} |
| 293 | Lₐ₃₉₂₈ | L_{b1} | 294 | Lₐ₃₉₃₀ | L_{b1} |
| 295 | Lₐ₃₉₃₇ | L_{b1} | 296 | Lₐ₃₉₃₉ | L_{b1} |
| 297 | Lₐ₃₉₄₉ | L_{b1} | 298 | Lₐ₃₉₅₁ | L_{b1} |
| 299 | Lₐ₃₉₆₁ | L_{b1} | 300 | Lₐ₃₉₆₃ | L_{b1} |
| 301 | Lₐ₃₉₆₆ | L_{b1} | 302 | Lₐ₃₉₇₃ | L_{b1} |
| 303 | Lₐ₃₉₇₅ | L_{b1} | 304 | Lₐ₃₉₇₈ | L_{b1} |
| 305 | Lₐ₃₉₈₅ | L_{b1} | 306 | Lₐ₃₉₈₇ | L_{b1} |
| 307 | Lₐ₃₉₉₀ | L_{b1} | 308 | Lₐ₃₉₉₇ | L_{b1} |
| 309 | Lₐ₃₉₉₉ | L_{b1} | 310 | Lₐ₄₀₀₂ | L_{b1} |
| 311 | Lₐ₄₀₀₉ | L_{b1} | 312 | Lₐ₄₀₁₁ | L_{b1} |
| 313 | Lₐ₄₀₁₄ | L_{b1} | 314 | Lₐ₄₀₂₁ | L_{b1} |
| 315 | Lₐ₄₀₂₃ | L_{b1} | 316 | Lₐ₄₀₂₆ | L_{b1} |
| 317 | Lₐ₄₀₃₁ | L_{b1} | 318 | Lₐ₄₀₃₆ | L_{b1} |
| 319 | Lₐ₄₀₃₇ | L_{b1} | 320 | Lₐ₄₀₃₉ | L_{b1} |
| 321 | Lₐ₄₀₄₃ | L_{b1} | 322 | Lₐ₄₀₄₉ | L_{b1} |
| 323 | Lₐ₄₀₅₄ | L_{b1} | 324 | Lₐ₄₀₅₅ | L_{b1} |
| 325 | Lₐ₄₀₅₇ | L_{b1} | 326 | Lₐ₄₀₆₁ | L_{b1} |
| 327 | Lₐ₄₁₃₉ | L_{b1} | 328 | Lₐ₄₁₄₄ | L_{b1} |
| 329 | Lₐ₄₁₄₅ | L_{b1} | 330 | Lₐ₄₁₄₇ | L_{b1} |
| 331 | Lₐ₄₁₅₁ | L_{b1} | 332 | Lₐ₄₂₃₁ | L_{b1} |
| 333 | Lₐ₄₂₃₃ | L_{b1} | 334 | Lₐ₄₂₃₆ | L_{b1} |
| 335 | Lₐ₄₂₄₃ | L_{b1} | 336 | Lₐ₄₂₄₅ | L_{b1} |
| 337 | Lₐ₄₂₄₈ | L_{b1} | 338 | Lₐ₄₂₆₇ | L_{b1} |
| 339 | Lₐ₄₂₆₉ | L_{b1} | 340 | Lₐ₄₂₇₂ | L_{b1} |
| 341 | Lₐ₄₂₈₇ | L_{b1} | 342 | Lₐ₄₂₈₉ | L_{b1} |
| 343 | Lₐ₄₂₉₁ | L_{b1} | 344 | Lₐ₄₂₉₃ | L_{b1} |
| 345 | Lₐ₄₂₉₄ | L_{b1} | 346 | Lₐ₄₂₉₆ | L_{b1} |
| 347 | Lₐ₄₃₀₃ | L_{b1} | 348 | Lₐ₄₃₀₅ | L_{b1} |
| 349 | Lₐ₄₃₁₅ | L_{b1} | 350 | Lₐ₄₃₁₇ | L_{b1} |
| 351 | Lₐ₄₃₂₇ | L_{b1} | 352 | Lₐ₄₃₂₉ | L_{b1} |
| 353 | Lₐ₄₃₃₂ | L_{b1} | 354 | Lₐ₄₃₃₉ | L_{b1} |
| 355 | Lₐ₄₃₄₁ | L_{b1} | 356 | Lₐ₄₃₄₄ | L_{b1} |
| 357 | Lₐ₄₃₆₃ | L_{b1} | 358 | Lₐ₄₃₆₅ | L_{b1} |
| 359 | Lₐ₄₃₆₈ | L_{b1} | 360 | Lₐ₄₃₇₅ | L_{b1} |
| 361 | Lₐ₄₃₇₇ | L_{b1} | 362 | Lₐ₄₃₈₀ | L_{b1} |
| 363 | Lₐ₄₃₉₇ | L_{b1} | 364 | Lₐ₄₃₉₉ | L_{b1} |
| 365 | Lₐ₄₄₀₂ | L_{b1} | 366 | Lₐ₄₄₀₃ | L_{b1} |
| 367 | Lₐ₄₄₀₅ | L_{b1} | 368 | Lₐ₄₄₀₆ | L_{b1} |
| 369 | Lₐ₄₄₀₉ | L_{b1} | 370 | Lₐ₄₄₁₅ | L_{b1} |
| 371 | Lₐ₄₄₂₀ | L_{b1} | 372 | Lₐ₄₄₂₃ | L_{b1} |
| 373 | Lₐ₄₄₂₇ | L_{b1} | 374 | Lₐ₄₄₅₁ | L_{b1} |
| 375 | Lₐ₄₄₅₆ | L_{b1} | 376 | Lₐ₄₄₅₇ | L_{b1} |
| 377 | Lₐ₄₄₅₉ | L_{b1} | 378 | Lₐ₄₄₆₃ | L_{b1} |
| 379 | Lₐ₄₅₉₇ | L_{b1} | 380 | Lₐ₄₅₉₉ | L_{b1} |
| 381 | Lₐ₄₆₀₂ | L_{b1} | 382 | Lₐ₄₆₀₉ | L_{b1} |
| 383 | Lₐ₄₆₁₁ | L_{b1} | 384 | Lₐ₄₆₂₁ | L_{b1} |
| 385 | Lₐ₄₆₂₃ | L_{b1} | 386 | Lₐ₄₆₃₃ | L_{b1} |
| 387 | Lₐ₄₆₃₅ | L_{b1} | 388 | Lₐ₄₆₄₅ | L_{b1} |
| 389 | Lₐ₄₆₄₇ | L_{b1} | 390 | Lₐ₄₆₅₃ | L_{b1} |
| 391 | Lₐ₄₆₅₅ | L_{b1} | 392 | Lₐ₄₆₅₇ | L_{b1} |
| 393 | Lₐ₄₆₅₉ | L_{b1} | 394 | Lₐ₄₆₆₂ | L_{b1} |
| 395 | Lₐ₄₆₆₉ | L_{b1} | 396 | Lₐ₄₆₇₁ | L_{b1} |
| 397 | Lₐ₄₆₈₁ | L_{b1} | 398 | Lₐ₄₆₈₃ | L_{b1} |
| 399 | Lₐ₄₆₉₃ | L_{b1} | 400 | Lₐ₄₆₉₅ | L_{b1} |
| 401 | Lₐ₄₆₉₈ | L_{b1} | 402 | Lₐ₄₇₀₅ | L_{b1} |
| 403 | Lₐ₄₇₀₇ | L_{b1} | 404 | Lₐ₄₇₁₀ | L_{b1} |
| 405 | Lₐ₄₇₂₉ | L_{b1} | 406 | Lₐ₄₇₃₁ | L_{b1} |
| 407 | Lₐ₄₇₃₄ | L_{b1} | 408 | Lₐ₄₇₆₃ | L_{b1} |
| 409 | Lₐ₄₉₆₃ | L_{b1} | 410 | Lₐ₄₉₆₅ | L_{b1} |
| 411 | Lₐ₄₉₆₈ | L_{b1} | 412 | Lₐ₅₀₂₃ | L_{b1} |
| 413 | Lₐ₅₀₂₅ | L_{b1} | 414 | Lₐ₅₀₃₅ | L_{b1} |
| 415 | Lₐ₅₀₃₇ | L_{b1} | 416 | Lₐ₅₀₄₇ | L_{b1} |
| 417 | Lₐ₅₀₄₉ | L_{b1} | 418 | Lₐ₅₁₂₉ | L_{b1} |
| 419 | Lₐ₅₁₃₄ | L_{b1} | 420 | Lₐ₅₁₃₅ | L_{b1} |
| 421 | Lₐ₅₁₃₇ | L_{b1} | 422 | Lₐ₅₁₄₁ | L_{b1} |
| 423 | Lₐ₅₁₄₇ | L_{b1} | 424 | Lₐ₅₁₅₂ | L_{b1} |
| 425 | Lₐ₅₁₅₃ | L_{b1} | 426 | Lₐ₅₁₅₅ | L_{b1} |
| 427 | Lₐ₅₁₅₉ | L_{b1} | 428 | Lₐ₅₂₃₇ | L_{b1} |
| 429 | Lₐ₅₂₄₂ | L_{b1} | 430 | Lₐ₅₂₄₃ | L_{b1} |
| 431 | Lₐ₅₂₄₅ | L_{b1} | 432 | Lₐ₅₂₄₉ | L_{b1} |
| 433 | Lₐ₅₃₂₉ | L_{b1} | 434 | Lₐ₅₃₃₁ | L_{b1} |
| 435 | Lₐ₅₃₃₄ | L_{b1} | 436 | Lₐ₅₃₄₁ | L_{b1} |
| 437 | Lₐ₅₃₄₃ | L_{b1} | 438 | Lₐ₅₃₄₆ | L_{b1} |
| 439 | Lₐ₅₃₆₅ | L_{b1} | 440 | Lₐ₅₃₆₇ | L_{b1} |
| 441 | Lₐ₅₃₇₀ | L_{b1} | 442 | Lₐ₅₃₈₅ | L_{b1} |
| 443 | Lₐ₅₃₈₇ | L_{b1} | 444 | Lₐ₅₃₈₉ | L_{b1} |
| 445 | Lₐ₅₃₉₁ | L_{b1} | 446 | Lₐ₅₃₉₂ | L_{b1} |
| 447 | Lₐ₅₃₉₄ | L_{b1} | 448 | Lₐ₅₄₀₁ | L_{b1} |
| 449 | Lₐ₅₄₀₃ | L_{b1} | 450 | Lₐ₅₄₁₃ | L_{b1} |
| 451 | Lₐ₅₄₁₅ | L_{b1} | 452 | Lₐ₅₄₂₅ | L_{b1} |
| 453 | Lₐ₅₄₂₇ | L_{b1} | 454 | Lₐ₅₄₃₀ | L_{b1} |
| 455 | Lₐ₅₄₆₁ | L_{b1} | 456 | Lₐ₅₄₆₃ | L_{b1} |
| 457 | Lₐ₅₄₆₆ | L_{b1} | 458 | Lₐ₅₄₉₅ | L_{b1} |
| 459 | Lₐ₅₆₉₅ | L_{b1} | 460 | Lₐ₅₆₉₇ | L_{b1} |
| 461 | Lₐ₅₇₅₅ | L_{b1} | 462 | Lₐ₅₇₅₇ | L_{b1} |
| 463 | Lₐ₅₇₆₀ | L_{b1} | 464 | Lₐ₅₇₆₇ | L_{b1} |
| 465 | Lₐ₅₇₆₉ | L_{b1} | 466 | Lₐ₅₇₇₉ | L_{b1} |
| 467 | Lₐ₅₇₈₁ | L_{b1} | 468 | Lₐ₅₈₆₁ | L_{b1} |
| 469 | Lₐ₅₈₆₆ | L_{b1} | 470 | Lₐ₅₈₆₇ | L_{b1} |
| 471 | Lₐ₅₈₆₉ | L_{b1} | 472 | Lₐ₅₈₇₃ | L_{b1} |
| 473 | Lₐ₅₈₇₉ | L_{b1} | 474 | Lₐ₅₈₈₄ | L_{b1} |
| 475 | Lₐ₅₈₈₅ | L_{b1} | 476 | Lₐ₅₈₈₇ | L_{b1} |
| 477 | Lₐ₅₈₉₁ | L_{b1} | 478 | Lₐ₅₉₆₉ | L_{b1} |
| 479 | Lₐ₅₉₇₄ | L_{b1} | 480 | Lₐ₅₉₇₅ | L_{b1} |
| 481 | Lₐ₅₉₇₇ | L_{b1} | 482 | Lₐ₅₉₈₁ | L_{b1} |
| 483 | Lₐ₆₀₅₇ | L_{b1} | 484 | Lₐ₆₀₅₉ | L_{b1} |
| 485 | Lₐ₆₀₆₁ | L_{b1} | 486 | Lₐ₆₀₆₃ | L_{b1} |
| 487 | Lₐ₆₀₆₆ | L_{b1} | 488 | Lₐ₆₀₇₃ | L_{b1} |
| 489 | Lₐ₆₀₇₅ | L_{b1} | 490 | Lₐ₆₀₇₈ | L_{b1} |
| 491 | Lₐ₆₀₈₅ | L_{b1} | 492 | Lₐ₆₀₈₇ | L_{b1} |
| 493 | Lₐ₆₀₉₇ | L_{b1} | 494 | Lₐ₆₀₉₉ | L_{b1} |
| 495 | Lₐ₆₁₁₇ | L_{b1} | 496 | Lₐ₆₁₁₉ | L_{b1} |
| 497 | Lₐ₆₁₂₁ | L_{b1} | 498 | Lₐ₆₁₂₃ | L_{b1} |
| 499 | Lₐ₆₁₂₆ | L_{b1} | 500 | Lₐ₆₁₃₃ | L_{b1} |
| 501 | Lₐ₆₁₃₅ | L_{b1} | 502 | Lₐ₆₁₄₅ | L_{b1} |
| 503 | Lₐ₆₁₄₇ | L_{b1} | 504 | Lₐ₆₁₅₇ | L_{b1} |
| 505 | Lₐ₆₁₅₉ | L_{b1} | 506 | Lₐ₆₁₆₂ | L_{b1} |
| 507 | Lₐ₆₁₆₉ | L_{b1} | 508 | Lₐ₆₁₇₁ | L_{b1} |
| 509 | Lₐ₆₁₇₄ | L_{b1} | 510 | Lₐ₆₁₉₃ | L_{b1} |
| 511 | Lₐ₆₁₉₅ | L_{b1} | 512 | Lₐ₆₁₉₈ | L_{b1} |
| 513 | Lₐ₆₂₀₅ | L_{b1} | 514 | Lₐ₆₂₀₇ | L_{b1} |
| 515 | Lₐ₆₂₂₇ | L_{b1} | 516 | Lₐ₆₂₃₂ | L_{b1} |
| 517 | Lₐ₆₂₃₃ | L_{b1} | 518 | Lₐ₆₂₃₅ | L_{b1} |
| 519 | Lₐ₆₂₃₉ | L_{b1} | 520 | Lₐ₆₂₄₅ | L_{b1} |
| 521 | Lₐ₆₂₅₀ | L_{b1} | 522 | Lₐ₆₂₅₁ | L_{b1} |
| 523 | Lₐ₆₂₅₃ | L_{b1} | 524 | Lₐ₆₂₅₇ | L_{b1} |
| 525 | Lₐ₆₃₃₅ | L_{b1} | 526 | Lₐ₆₃₄₀ | L_{b1} |
| 527 | Lₐ₆₃₄₁ | L_{b1} | 528 | Lₐ₆₃₄₃ | L_{b1} |
| 529 | Lₐ₆₃₄₇ | L_{b1} | 530 | Lₐ₆₄₂₃ | L_{b1} |
| 531 | Lₐ₆₄₂₅ | L_{b1} | 532 | Lₐ₆₄₂₇ | L_{b1} |
| 533 | Lₐ₆₄₂₉ | L_{b1} | 534 | Lₐ₆₄₃₂ | L_{b1} |
| 535 | Lₐ₆₄₃₉ | L_{b1} | 536 | Lₐ₆₄₄₁ | L_{b1} |
| 537 | Lₐ₆₄₄₄ | L_{b1} | 538 | Lₐ₆₄₆₃ | L_{b1} |
| 539 | Lₐ₆₄₆₅ | L_{b1} | 540 | Lₐ₆₄₆₈ | L_{b1} |
| 541 | Lₐ₆₄₈₃ | L_{b1} | 542 | Lₐ₆₄₈₅ | L_{b1} |
| 543 | Lₐ₆₄₈₇ | L_{b1} | 544 | Lₐ₆₄₈₉ | L_{b1} |
| 545 | Lₐ₆₄₉₂ | L_{b1} | 546 | Lₐ₆₄₉₉ | L_{b1} |
| 547 | Lₐ₆₅₀₁ | L_{b1} | 548 | Lₐ₆₅₁₁ | L_{b1} |
| 549 | Lₐ₆₅₁₃ | L_{b1} | 550 | Lₐ₆₅₂₃ | L_{b1} |
| 551 | Lₐ₆₅₂₅ | L_{b1} | 552 | Lₐ₆₅₂₈ | L_{b1} |
| 553 | Lₐ₆₅₃₅ | L_{b1} | 554 | Lₐ₆₅₃₇ | L_{b1} |
| 555 | Lₐ₆₅₄₀ | L_{b1} | 556 | Lₐ₆₅₅₉ | L_{b1} |
| 557 | Lₐ₆₅₆₁ | L_{b1} | 558 | Lₐ₆₅₆₄ | L_{b1} |
| 559 | Lₐ₆₅₇₁ | L_{b1} | 560 | Lₐ₆₅₇₃ | L_{b1} |
| 561 | Lₐ₆₅₉₃ | L_{b1} | 562 | Lₐ₆₅₉₈ | L_{b1} |
| 563 | Lₐ₆₅₉₉ | L_{b1} | 564 | Lₐ₆₆₀₁ | L_{b1} |
| 565 | Lₐ₆₆₀₅ | L_{b1} | 566 | Lₐ₆₆₁₁ | L_{b1} |
| 567 | Lₐ₆₆₁₆ | L_{b1} | 568 | Lₐ₆₆₁₉ | L_{b1} |
| 569 | Lₐ₆₆₂₃ | L_{b1} | 570 | Lₐ₆₇₀₀ | L_{b1} |
| 571 | Lₐ₆₇₀₁ | L_{b1} | 572 | Lₐ₆₇₀₃ | L_{b1} |
| 573 | Lₐ₆₇₀₆ | L_{b1} | 574 | Lₐ₆₇₀₇ | L_{b1} |
| 575 | Lₐ₆₇₀₉ | L_{b1} | 576 | Lₐ₆₇₁₃ | L_{b1} |
| 577 | Lₐ₆₇₄₂ | L_{b1} | 578 | Lₐ₆₇₄₅ | L_{b1} |
| 579 | Lₐ₆₇₉₃ | L_{b1} | 580 | Lₐ₆₇₉₅ | L_{b1} |
| 581 | Lₐ₆₇₉₈ | L_{b1} | 582 | Lₐ₆₈₀₅ | L_{b1} |
| 583 | Lₐ₆₈₀₇ | L_{b1} | 584 | Lₐ₆₈₁₀ | L_{b1} |
| 585 | Lₐ₆₈₂₉ | L_{b1} | 586 | Lₐ₆₈₃₁ | L_{b1} |
| 587 | Lₐ₆₈₃₄ | L_{b1} | 588 | Lₐ₆₈₄₉ | L_{b1} |
| 589 | Lₐ₆₈₅₁ | L_{b1} | 590 | Lₐ₆₈₅₃ | L_{b1} |
| 591 | Lₐ₆₈₅₅ | L_{b1} | 592 | Lₐ₆₈₅₈ | L_{b1} |
| 593 | Lₐ₆₈₆₅ | L_{b1} | 594 | Lₐ₆₈₆₇ | L_{b1} |
| 595 | Lₐ₆₈₇₇ | L_{b1} | 596 | Lₐ₆₈₇₉ | L_{b1} |
| 597 | Lₐ₆₈₈₉ | L_{b1} | 598 | Lₐ₆₈₉₁ | L_{b1} |
| 599 | Lₐ₆₈₉₄ | L_{b1} | 600 | Lₐ₆₉₀₁ | L_{b1} |
| 601 | Lₐ₆₉₀₃ | L_{b1} | 602 | Lₐ₆₉₂₅ | L_{b1} |
| 603 | Lₐ₆₉₂₇ | L_{b1} | 604 | Lₐ₆₉₃₀ | L_{b1} |
| 605 | Lₐ₆₉₃₇ | L_{b1} | 606 | Lₐ₆₉₃₉ | L_{b1} |
| 607 | Lₐ₅ | L_{b3} | 608 | Lₐ₇ | L_{b3} |
| 609 | Lₐ₁₀ | L_{b3} | 610 | Lₐ₁₁ | L_{b3} |
| 611 | Lₐ₁₃ | L_{b3} | 612 | Lₐ₁₄ | L_{b3} |
| 613 | Lₐ₁₇ | L_{b3} | 614 | Lₐ₂₃ | L_{b3} |
| 615 | Lₐ₂₈ | L_{b3} | 616 | Lₐ₂₉ | L_{b3} |
| 617 | Lₐ₃₁ | L_{b3} | 618 | Lₐ₃₅ | L_{b3} |
| 619 | Lₐ₅₉ | L_{b3} | 620 | Lₐ₆₄ | L_{b3} |
| 621 | Lₐ₆₅ | L_{b3} | 622 | Lₐ₆₇ | L_{b3} |
| 623 | Lₐ₇₁ | L_{b3} | 624 | Lₐ₁₁₃ | L_{b3} |
| 625 | Lₐ₁₁₈ | L_{b3} | 626 | Lₐ₁₁₉ | L_{b3} |
| 627 | Lₐ₁₂₁ | L_{b3} | 628 | Lₐ₁₂₅ | L_{b3} |
| 629 | Lₐ₁₄₉ | L_{b3} | 630 | Lₐ₁₅₄ | L_{b3} |
| 631 | Lₐ₁₅₅ | L_{b3} | 632 | Lₐ₁₅₇ | L_{b3} |
| 633 | Lₐ₁₆₁ | L_{b3} | 634 | Lₐ₂₀₅ | L_{b3} |
| 635 | Lₐ₂₀₇ | L_{b3} | 636 | Lₐ₂₁₀ | L_{b3} |
| 637 | Lₐ₂₁₇ | L_{b3} | 638 | Lₐ₂₁₉ | L_{b3} |
| 639 | Lₐ₂₂₂ | L_{b3} | 640 | Lₐ₂₂₉ | L_{b3} |
| 641 | Lₐ₂₃₁ | L_{b3} | 642 | Lₐ₂₃₄ | L_{b3} |
| 643 | Lₐ₂₄₁ | L_{b3} | 644 | Lₐ₂₄₃ | L_{b3} |
| 645 | Lₐ₂₄₆ | L_{b3} | 646 | Lₐ₂₅₃ | L_{b3} |
| 647 | Lₐ₂₅₅ | L_{b3} | 648 | Lₐ₂₅₈ | L_{b3} |
| 649 | Lₐ₂₆₁ | L_{b3} | 650 | Lₐ₂₆₃ | L_{b3} |
| 651 | Lₐ₂₆₅ | L_{b3} | 652 | Lₐ₂₆₇ | L_{b3} |
| 653 | Lₐ₂₇₀ | L_{b3} | 654 | Lₐ₂₇₇ | L_{b3} |
| 655 | Lₐ₂₇₉ | L_{b3} | 656 | Lₐ₂₈₂ | L_{b3} |
| 657 | Lₐ₂₈₉ | L_{b3} | 658 | Lₐ₂₉₁ | L_{b3} |
| 659 | Lₐ₂₉₄ | L_{b3} | 660 | Lₐ₃₀₁ | L_{b3} |
| 661 | Lₐ₃₀₃ | L_{b3} | 662 | Lₐ₃₀₆ | L_{b3} |
| 663 | Lₐ₃₁₃ | L_{b3} | 664 | Lₐ₃₁₅ | L_{b3} |
| 665 | Lₐ₃₁₈ | L_{b3} | 666 | Lₐ₃₂₅ | L_{b3} |
| 667 | Lₐ₃₂₇ | L_{b3} | 668 | Lₐ₃₃₀ | L_{b3} |
| 669 | Lₐ₃₃₇ | L_{b3} | 670 | Lₐ₃₃₉ | L_{b3} |
| 671 | Lₐ₃₄₂ | L_{b3} | 672 | Lₐ₃₄₉ | L_{b3} |
| 673 | Lₐ₃₅₁ | L_{b3} | 674 | Lₐ₃₅₄ | L_{b3} |
| 675 | Lₐ₃₆₁ | L_{b3} | 676 | Lₐ₃₆₃ | L_{b3} |
| 677 | Lₐ₃₆₆ | L_{b3} | 678 | Lₐ₃₇₁ | L_{b3} |
| 679 | Lₐ₅₇₁ | L_{b3} | 680 | Lₐ₅₇₃ | L_{b3} |
| 681 | Lₐ₆₃₁ | L_{b3} | 682 | Lₐ₆₃₃ | L_{b3} |
| 683 | Lₐ₇₃₇ | L_{b3} | 684 | Lₐ₉₃₇ | L_{b3} |
| 685 | Lₐ₉₃₉ | L_{b3} | 686 | Lₐ₉₉₇ | L_{b3} |
| 687 | Lₐ₉₉₉ | L_{b3} | 688 | Lₐ₁₀₀₉ | L_{b3} |
| 689 | Lₐ₁₀₁₁ | L_{b3} | 690 | Lₐ₁₀₂₁ | L_{b3} |
| 691 | Lₐ₁₀₂₃ | L_{b3} | 692 | Lₐ₁₁₀₃ | L_{b3} |
| 693 | Lₐ₁₁₀₅ | L_{b3} | 694 | Lₐ₁₁₀₈ | L_{b3} |
| 695 | Lₐ₁₁₀₉ | L_{b3} | 696 | Lₐ₁₁₁₁ | L_{b3} |
| 697 | Lₐ₁₁₁₂ | L_{b3} | 698 | Lₐ₁₁₁₅ | L_{b3} |
| 699 | Lₐ₁₁₂₁ | L_{b3} | 700 | Lₐ₁₁₂₆ | L_{b3} |
| 701 | Lₐ₁₁₂₇ | L_{b3} | 702 | Lₐ₁₁₂₉ | L_{b3} |
| 703 | Lₐ₁₁₃₃ | L_{b3} | 704 | Lₐ₁₁₅₇ | L_{b3} |
| 705 | Lₐ₁₁₆₂ | L_{b3} | 706 | Lₐ₁₁₆₃ | L_{b3} |
| 707 | Lₐ₁₁₆₅ | L_{b3} | 708 | Lₐ₁₁₆₉ | L_{b3} |
| 709 | Lₐ₁₂₁₁ | L_{b3} | 710 | Lₐ₁₂₁₆ | L_{b3} |
| 711 | Lₐ₁₂₁₇ | L_{b3} | 712 | Lₐ₁₂₁₉ | L_{b3} |
| 713 | Lₐ₁₂₂₃ | L_{b3} | 714 | Lₐ₁₂₄₇ | L_{b3} |
| 715 | Lₐ₁₂₅₂ | L_{b3} | 716 | Lₐ₁₂₅₃ | L_{b3} |
| 717 | Lₐ₁₂₅₅ | L_{b3} | 718 | Lₐ₁₂₅₉ | L_{b3} |
| 719 | Lₐ₁₃₀₃ | L_{b3} | 720 | Lₐ₁₃₀₅ | L_{b3} |
| 721 | Lₐ₁₃₀₈ | L_{b3} | 722 | Lₐ₁₃₁₅ | L_{b3} |
| 723 | Lₐ₁₃₁₇ | L_{b3} | 724 | Lₐ₁₃₂₀ | L_{b3} |
| 725 | Lₐ₁₃₂₇ | L_{b3} | 726 | Lₐ₁₃₂₉ | L_{b3} |
| 727 | Lₐ₁₃₃₂ | L_{b3} | 728 | Lₐ₁₃₃₉ | L_{b3} |
| 729 | Lₐ₁₃₄₁ | L_{b3} | 730 | Lₐ₁₃₄₄ | L_{b3} |
| 731 | Lₐ₁₃₅₁ | L_{b3} | 732 | Lₐ₁₃₅₃ | L_{b3} |
| 733 | Lₐ₁₃₅₆ | L_{b3} | 734 | Lₐ₁₃₅₉ | L_{b3} |
| 735 | Lₐ₁₃₆₁ | L_{b3} | 736 | Lₐ₁₃₆₃ | L_{b3} |
| 737 | Lₐ₁₃₆₅ | L_{b3} | 738 | Lₐ₁₃₆₈ | L_{b3} |
| 739 | Lₐ₁₃₇₅ | L_{b3} | 740 | Lₐ₁₃₇₇ | L_{b3} |
| 741 | Lₐ₁₃₈₇ | L_{b3} | 742 | Lₐ₁₃₈₉ | L_{b3} |
| 743 | Lₐ₁₄₆₉ | L_{b3} | 744 | Lₐ₁₆₆₉ | L_{b3} |
| 745 | Lₐ₁₆₇₁ | L_{b3} | 746 | Lₐ₁₇₂₉ | L_{b3} |
| 747 | Lₐ₁₇₃₁ | L_{b3} | 748 | Lₐ₁₇₄₁ | L_{b3} |
| 749 | Lₐ₁₇₄₃ | L_{b3} | 750 | Lₐ₁₇₅₃ | L_{b3} |
| 751 | Lₐ₁₇₅₅ | L_{b3} | 752 | Lₐ₁₈₃₅ | L_{b3} |
| 753 | Lₐ₂₀₃₅ | L_{b3} | 754 | Lₐ₂₀₃₇ | L_{b3} |
| 755 | Lₐ₂₀₉₅ | L_{b3} | 756 | Lₐ₂₀₉₇ | L_{b3} |
| 757 | Lₐ₂₁₀₇ | L_{b3} | 758 | Lₐ₂₁₀₉ | L_{b3} |
| 759 | Lₐ₂₁₁₉ | L_{b3} | 760 | Lₐ₂₁₂₁ | L_{b3} |
| 761 | Lₐ₂₂₀₁ | L_{b3} | 762 | Lₐ₂₄₀₁ | L_{b3} |
| 763 | Lₐ₂₄₀₃ | L_{b3} | 764 | Lₐ₂₄₆₁ | L_{b3} |
| 765 | Lₐ₂₄₆₃ | L_{b3} | 766 | Lₐ₂₄₇₃ | L_{b3} |
| 767 | Lₐ₂₄₇₅ | L_{b3} | 768 | Lₐ₂₄₈₅ | L_{b3} |
| 769 | Lₐ₂₄₈₇ | L_{b3} | 770 | Lₐ₂₅₆₇ | L_{b3} |
| 771 | Lₐ₂₇₆₇ | L_{b3} | 772 | Lₐ₂₇₆₉ | L_{b3} |
| 773 | Lₐ₂₈₂₇ | L_{b3} | 774 | Lₐ₂₈₂₉ | L_{b3} |
| 775 | Lₐ₂₈₅₁ | L_{b3} | 776 | Lₐ₂₈₅₃ | L_{b3} |
| 777 | Lₐ₂₉₃₃ | L_{b3} | 778 | Lₐ₂₉₃₅ | L_{b3} |
| 779 | Lₐ₂₉₃₈ | L_{b3} | 780 | Lₐ₂₉₃₉ | L_{b3} |
| 781 | Lₐ₂₉₄₁ | L_{b3} | 782 | Lₐ₂₉₄₂ | L_{b3} |
| 783 | Lₐ₂₉₄₅ | L_{b3} | 784 | Lₐ₂₉₅₁ | L_{b3} |
| 785 | Lₐ₂₉₅₆ | L_{b3} | 786 | Lₐ₂₉₅₇ | L_{b3} |
| 787 | Lₐ₂₉₅₉ | L_{b3} | 788 | Lₐ₂₉₆₃ | L_{b3} |
| 789 | Lₐ₂₉₈₇ | L_{b3} | 790 | Lₐ₂₉₉₂ | L_{b3} |
| 791 | Lₐ₂₉₉₃ | L_{b3} | 792 | Lₐ₂₉₉₅ | L_{b3} |
| 793 | Lₐ₂₉₉₉ | L_{b3} | 794 | Lₐ₃₀₄₁ | L_{b3} |
| 795 | Lₐ₃₀₄₆ | L_{b3} | 796 | Lₐ₃₀₄₇ | L_{b3} |
| 797 | Lₐ₃₀₄₉ | L_{b3} | 798 | Lₐ₃₀₅₃ | L_{b3} |
| 799 | Lₐ₃₀₇₇ | L_{b3} | 800 | Lₐ₃₀₈₂ | L_{b3} |
| 801 | Lₐ₃₀₈₃ | L_{b3} | 802 | Lₐ₃₀₈₅ | L_{b3} |
| 803 | Lₐ₃₀₈₉ | L_{b3} | 804 | Lₐ₃₁₃₃ | L_{b3} |
| 805 | Lₐ₃₁₃₅ | L_{b3} | 806 | Lₐ₃₁₃₈ | L_{b3} |
| 807 | Lₐ₃₁₄₅ | L_{b3} | 808 | Lₐ₃₁₄₇ | L_{b3} |
| 809 | Lₐ₃₁₅₀ | L_{b3} | 810 | Lₐ₃₁₆₉ | L_{b3} |
| 811 | Lₐ₃₁₇₁ | L_{b3} | 812 | Lₐ₃₁₇₄ | L_{b3} |
| 813 | Lₐ₃₁₈₁ | L_{b3} | 814 | Lₐ₃₁₈₃ | L_{b3} |
| 815 | Lₐ₃₁₈₆ | L_{b3} | 816 | Lₐ₃₁₈₉ | L_{b3} |
| 817 | Lₐ₃₁₉₁ | L_{b3} | 818 | Lₐ₃₁₉₃ | L_{b3} |
| 819 | Lₐ₃₁₉₅ | L_{b3} | 820 | Lₐ₃₁₉₈ | L_{b3} |
| 821 | Lₐ₃₂₀₅ | L_{b3} | 822 | Lₐ₃₂₀₇ | L_{b3} |
| 823 | Lₐ₃₂₁₇ | L_{b3} | 824 | Lₐ₃₂₁₉ | L_{b3} |
| 825 | Lₐ₃₂₂₉ | L_{b3} | 826 | Lₐ₃₂₃₁ | L_{b3} |
| 827 | Lₐ₃₂₃₄ | L_{b3} | 828 | Lₐ₃₂₄₁ | L_{b3} |
| 829 | Lₐ₃₂₄₃ | L_{b3} | 830 | Lₐ₃₂₄₆ | L_{b3} |
| 831 | Lₐ₃₂₅₃ | L_{b3} | 832 | Lₐ₃₂₅₅ | L_{b3} |
| 833 | Lₐ₃₂₅₈ | L_{b3} | 834 | Lₐ₃₂₆₅ | L_{b3} |
| 835 | Lₐ₃₂₆₇ | L_{b3} | 836 | Lₐ₃₂₇₀ | L_{b3} |
| 837 | Lₐ₃₂₇₇ | L_{b3} | 838 | Lₐ₃₂₇₉ | L_{b3} |
| 839 | Lₐ₃₂₈₂ | L_{b3} | 840 | Lₐ₃₂₈₉ | L_{b3} |
| 841 | Lₐ₃₂₉₁ | L_{b3} | 842 | Lₐ₃₂₉₄ | L_{b3} |
| 843 | Lₐ₃₂₉₉ | L_{b3} | 844 | Lₐ₃₄₉₉ | L_{b3} |
| 845 | Lₐ₃₅₀₁ | L_{b3} | 846 | Lₐ₃₅₅₉ | L_{b3} |
| 847 | Lₐ₃₅₆₁ | L_{b3} | 848 | Lₐ₃₅₇₁ | L_{b3} |
| 849 | Lₐ₃₅₇₃ | L_{b3} | 850 | Lₐ₃₅₈₃ | L_{b3} |
| 851 | Lₐ₃₅₈₅ | L_{b3} | 852 | Lₐ₃₆₆₅ | L_{b3} |
| 853 | Lₐ₃₆₆₇ | L_{b3} | 854 | Lₐ₃₆₇₀ | L_{b3} |
| 855 | Lₐ₃₆₇₁ | L_{b3} | 856 | Lₐ₃₆₇₃ | L_{b3} |
| 857 | Lₐ₃₆₇₄ | L_{b3} | 858 | Lₐ₃₆₇₇ | L_{b3} |
| 859 | Lₐ₃₆₈₃ | L_{b3} | 860 | Lₐ₃₆₈₈ | L_{b3} |
| 861 | Lₐ₃₆₈₉ | L_{b3} | 862 | Lₐ₃₆₉₁ | L_{b3} |
| 863 | Lₐ₃₆₉₅ | L_{b3} | 864 | Lₐ₃₇₁₉ | L_{b3} |
| 865 | Lₐ₃₇₂₄ | L_{b3} | 866 | Lₐ₃₇₂₅ | L_{b3} |
| 867 | Lₐ₃₇₂₇ | L_{b3} | 868 | Lₐ₃₇₃₁ | L_{b3} |
| 869 | Lₐ₃₇₇₃ | L_{b3} | 870 | Lₐ₃₇₇₈ | L_{b3} |
| 871 | Lₐ₃₇₇₉ | L_{b3} | 872 | Lₐ₃₇₈₁ | L_{b3} |
| 873 | Lₐ₃₇₈₅ | L_{b3} | 874 | Lₐ₃₈₀₉ | L_{b3} |
| 875 | Lₐ₃₈₁₄ | L_{b3} | 876 | Lₐ₃₈₁₅ | L_{b3} |
| 877 | Lₐ₃₈₁₇ | L_{b3} | 878 | Lₐ₃₈₂₁ | L_{b3} |
| 879 | Lₐ₃₈₆₅ | L_{b3} | 880 | Lₐ₃₈₆₇ | L_{b3} |
| 881 | Lₐ₃₈₇₀ | L_{b3} | 882 | Lₐ₃₈₇₇ | L_{b3} |
| 883 | Lₐ₃₈₇₉ | L_{b3} | 884 | Lₐ₃₈₈₂ | L_{b3} |
| 885 | Lₐ₃₈₈₉ | L_{b3} | 886 | Lₐ₃₈₉₁ | L_{b3} |
| 887 | Lₐ₃₈₉₄ | L_{b3} | 888 | Lₐ₃₉₀₁ | L_{b3} |
| 889 | Lₐ₃₉₀₃ | L_{b3} | 890 | Lₐ₃₉₀₆ | L_{b3} |
| 891 | Lₐ₃₉₁₃ | L_{b3} | 892 | Lₐ₃₉₁₅ | L_{b3} |
| 893 | Lₐ₃₉₁₈ | L_{b3} | 894 | Lₐ₃₉₂₁ | L_{b3} |
| 895 | Lₐ₃₉₂₃ | L_{b3} | 896 | Lₐ₃₉₂₄ | L_{b3} |
| 897 | Lₐ₃₉₂₅ | L_{b3} | 898 | Lₐ₃₉₂₇ | L_{b3} |
| 899 | Lₐ₃₉₂₈ | L_{b3} | 900 | Lₐ₃₉₃₀ | L_{b3} |
| 901 | Lₐ₃₉₃₇ | L_{b3} | 902 | Lₐ₃₉₃₉ | L_{b3} |
| 903 | Lₐ₃₉₄₉ | L_{b3} | 904 | Lₐ₃₉₅₁ | L_{b3} |
| 905 | Lₐ₃₉₆₁ | L_{b3} | 906 | Lₐ₃₉₆₃ | L_{b3} |
| 907 | Lₐ₃₉₆₆ | L_{b3} | 908 | Lₐ₃₉₇₃ | L_{b3} |
| 909 | Lₐ₃₉₇₅ | L_{b3} | 910 | Lₐ₃₉₇₈ | L_{b3} |
| 911 | Lₐ₃₉₈₅ | L_{b3} | 912 | Lₐ₃₉₈₇ | L_{b3} |
| 913 | Lₐ₃₉₉₀ | L_{b3} | 914 | Lₐ₃₉₉₇ | L_{b3} |
| 915 | Lₐ₃₉₉₉ | L_{b3} | 916 | Lₐ₄₀₀₂ | L_{b3} |
| 917 | Lₐ₄₀₀₉ | L_{b3} | 918 | Lₐ₄₀₁₁ | L_{b3} |
| 919 | Lₐ₄₀₁₄ | L_{b3} | 920 | Lₐ₄₀₂₁ | L_{b3} |
| 921 | Lₐ₄₀₂₃ | L_{b3} | 922 | Lₐ₄₀₂₆ | L_{b3} |
| 923 | Lₐ₄₀₃₁ | L_{b3} | 924 | Lₐ₄₀₃₆ | L_{b3} |
| 925 | Lₐ₄₀₃₇ | L_{b3} | 926 | Lₐ₄₀₃₉ | L_{b3} |
| 927 | Lₐ₄₀₄₃ | L_{b3} | 928 | Lₐ₄₀₄₉ | L_{b3} |
| 929 | Lₐ₄₀₅₄ | L_{b3} | 930 | Lₐ₄₀₅₅ | L_{b3} |
| 931 | Lₐ₄₀₅₇ | L_{b3} | 932 | Lₐ₄₀₆₁ | L_{b3} |
| 933 | Lₐ₄₁₃₉ | L_{b3} | 934 | Lₐ₄₁₄₄ | L_{b3} |
| 935 | Lₐ₄₁₄₅ | L_{b3} | 936 | Lₐ₄₁₄₇ | L_{b3} |
| 937 | Lₐ₄₁₅₁ | L_{b3} | 938 | Lₐ₄₂₃₁ | L_{b3} |
| 939 | Lₐ₄₂₃₃ | L_{b3} | 940 | Lₐ₄₂₃₆ | L_{b3} |
| 941 | Lₐ₄₂₄₃ | L_{b3} | 942 | Lₐ₄₂₄₅ | L_{b3} |
| 943 | Lₐ₄₂₄₈ | L_{b3} | 944 | Lₐ₄₂₆₇ | L_{b3} |
| 945 | Lₐ₄₂₆₉ | L_{b3} | 946 | Lₐ₄₂₇₂ | L_{b3} |
| 947 | Lₐ₄₂₈₇ | L_{b3} | 948 | Lₐ₄₂₈₉ | L_{b3} |
| 949 | Lₐ₄₂₉₁ | L_{b3} | 950 | Lₐ₄₂₉₃ | L_{b3} |
| 951 | Lₐ₄₂₉₄ | L_{b3} | 952 | Lₐ₄₂₉₆ | L_{b3} |
| 953 | Lₐ₄₃₀₃ | L_{b3} | 954 | Lₐ₄₃₀₅ | L_{b3} |
| 955 | Lₐ₄₃₁₅ | L_{b3} | 956 | Lₐ₄₃₁₇ | L_{b3} |
| 957 | Lₐ₄₃₂₇ | L_{b3} | 958 | Lₐ₄₃₂₉ | L_{b3} |
| 959 | Lₐ₄₃₃₂ | L_{b3} | 960 | Lₐ₄₃₃₉ | L_{b3} |
| 961 | Lₐ₄₃₄₁ | L_{b3} | 962 | Lₐ₄₃₄₄ | L_{b3} |
| 963 | Lₐ₄₃₆₃ | L_{b3} | 964 | Lₐ₄₃₆₅ | L_{b3} |
| 965 | Lₐ₄₃₆₈ | L_{b3} | 966 | Lₐ₄₃₇₅ | L_{b3} |
| 967 | Lₐ₄₃₇₇ | L_{b3} | 968 | Lₐ₄₃₈₀ | L_{b3} |
| 969 | Lₐ₄₃₉₇ | L_{b3} | 970 | Lₐ₄₃₉₉ | L_{b3} |
| 971 | Lₐ₄₄₀₂ | L_{b3} | 972 | Lₐ₄₄₀₃ | L_{b3} |
| 973 | Lₐ₄₄₀₅ | L_{b3} | 974 | Lₐ₄₄₀₆ | L_{b3} |
| 975 | Lₐ₄₄₀₉ | L_{b3} | 976 | Lₐ₄₄₁₅ | L_{b3} |
| 977 | Lₐ₄₄₂₀ | L_{b3} | 978 | Lₐ₄₄₂₃ | L_{b3} |
| 979 | Lₐ₄₄₂₇ | L_{b3} | 980 | Lₐ₄₄₅₁ | L_{b3} |
| 981 | Lₐ₄₄₅₆ | L_{b3} | 982 | Lₐ₄₄₅₇ | L_{b3} |
| 983 | Lₐ₄₄₅₉ | L_{b3} | 984 | Lₐ₄₄₆₃ | L_{b3} |
| 985 | Lₐ₄₅₉₇ | L_{b3} | 986 | Lₐ₄₅₉₉ | L_{b3} |
| 987 | Lₐ₄₆₀₂ | L_{b3} | 988 | Lₐ₄₆₀₉ | L_{b3} |
| 989 | Lₐ₄₆₁₁ | L_{b3} | 990 | Lₐ₄₆₂₁ | L_{b3} |
| 991 | Lₐ₄₆₂₃ | L_{b3} | 992 | Lₐ₄₆₃₃ | L_{b3} |
| 993 | Lₐ₄₆₃₅ | L_{b3} | 994 | Lₐ₄₆₄₅ | L_{b3} |
| 995 | Lₐ₄₆₄₇ | L_{b3} | 996 | Lₐ₄₆₅₃ | L_{b3} |
| 997 | Lₐ₄₆₅₅ | L_{b3} | 998 | Lₐ₄₆₅₇ | L_{b3} |
| 999 | Lₐ₄₆₅₉ | L_{b3} | 1000 | Lₐ₄₆₆₂ | L_{b3} |
| 1001 | Lₐ₄₆₆₉ | L_{b3} | 1002 | Lₐ₄₆₇₁ | L_{b3} |
| 1003 | Lₐ₄₆₈₁ | L_{b3} | 1004 | Lₐ₄₆₈₃ | L_{b3} |
| 1005 | Lₐ₄₆₉₃ | L_{b3} | 1006 | Lₐ₄₆₉₅ | L_{b3} |
| 1007 | Lₐ₄₆₉₈ | L_{b3} | 1008 | Lₐ₄₇₀₅ | L_{b3} |
| 1009 | Lₐ₄₇₀₇ | L_{b3} | 1010 | Lₐ₄₇₁₀ | L_{b3} |
| 1011 | Lₐ₄₇₂₉ | L_{b3} | 1012 | Lₐ₄₇₃₁ | L_{b3} |
| 1013 | Lₐ₄₇₃₄ | L_{b3} | 1014 | Lₐ₄₇₆₃ | L_{b3} |
| 1015 | Lₐ₄₉₆₃ | L_{b3} | 1016 | Lₐ₄₉₆₅ | L_{b3} |
| 1017 | Lₐ₄₉₆₈ | L_{b3} | 1018 | Lₐ₅₀₂₃ | L_{b3} |
| 1019 | Lₐ₅₀₂₅ | L_{b3} | 1020 | Lₐ₅₀₃₅ | L_{b3} |
| 1021 | Lₐ₅₀₃₇ | L_{b3} | 1022 | Lₐ₅₀₄₇ | L_{b3} |
| 1023 | Lₐ₅₀₄₉ | L_{b3} | 1024 | Lₐ₅₁₂₉ | L_{b3} |
| 1025 | Lₐ₅₁₃₄ | L_{b3} | 1026 | Lₐ₅₁₃₅ | L_{b3} |
| 1027 | Lₐ₅₁₃₇ | L_{b3} | 1028 | Lₐ₅₁₄₁ | L_{b3} |
| 1029 | Lₐ₅₁₄₇ | L_{b3} | 1030 | Lₐ₅₁₅₂ | L_{b3} |
| 1031 | Lₐ₅₁₅₃ | L_{b3} | 1032 | Lₐ₅₁₅₅ | L_{b3} |
| 1033 | Lₐ₅₁₅₉ | L_{b3} | 1034 | Lₐ₅₂₃₇ | L_{b3} |
| 1035 | Lₐ₅₂₄₂ | L_{b3} | 1036 | Lₐ₅₂₄₃ | L_{b3} |
| 1037 | Lₐ₅₂₄₅ | L_{b3} | 1038 | Lₐ₅₂₄₉ | L_{b3} |
| 1039 | Lₐ₅₃₂₉ | L_{b3} | 1040 | Lₐ₅₃₃₁ | L_{b3} |
| 1041 | Lₐ₅₃₃₄ | L_{b3} | 1042 | Lₐ₅₃₄₁ | L_{b3} |
| 1043 | Lₐ₅₃₄₃ | L_{b3} | 1044 | Lₐ₅₃₄₆ | L_{b3} |
| 1045 | Lₐ₅₃₆₅ | L_{b3} | 1046 | Lₐ₅₃₆₇ | L_{b3} |
| 1047 | Lₐ₅₃₇₀ | L_{b3} | 1048 | Lₐ₅₃₈₅ | L_{b3} |
| 1049 | Lₐ₅₃₈₇ | L_{b3} | 1050 | Lₐ₅₃₈₉ | L_{b3} |
| 1051 | Lₐ₅₃₉₁ | L_{b3} | 1052 | Lₐ₅₃₉₂ | L_{b3} |
| 1053 | Lₐ₅₃₉₄ | L_{b3} | 1054 | Lₐ₅₄₀₁ | L_{b3} |
| 1055 | Lₐ₅₄₀₃ | L_{b3} | 1056 | Lₐ₅₄₁₃ | L_{b3} |
| 1057 | Lₐ₅₄₁₅ | L_{b3} | 1058 | Lₐ₅₄₂₅ | L_{b3} |
| 1059 | Lₐ₅₄₂₇ | L_{b3} | 1060 | Lₐ₅₄₃₀ | L_{b3} |
| 1061 | Lₐ₅₄₆₁ | L_{b3} | 1062 | Lₐ₅₄₆₃ | L_{b3} |
| 1063 | Lₐ₅₄₆₆ | L_{b3} | 1064 | Lₐ₅₄₉₅ | L_{b3} |
| 1065 | Lₐ₅₆₉₅ | L_{b3} | 1066 | Lₐ₅₆₉₇ | L_{b3} |
| 1067 | Lₐ₅₇₅₅ | L_{b3} | 1068 | Lₐ₅₇₅₇ | L_{b3} |
| 1069 | Lₐ₅₇₆₀ | L_{b3} | 1070 | Lₐ₅₇₆₇ | L_{b3} |
| 1071 | Lₐ₅₇₆₉ | L_{b3} | 1072 | Lₐ₅₇₇₉ | L_{b3} |
| 1073 | Lₐ₅₇₈₁ | L_{b3} | 1074 | Lₐ₅₈₆₁ | L_{b3} |
| 1075 | Lₐ₅₈₆₆ | L_{b3} | 1076 | Lₐ₅₈₆₇ | L_{b3} |
| 1077 | Lₐ₅₈₆₉ | L_{b3} | 1078 | Lₐ₅₈₇₃ | L_{b3} |
| 1079 | Lₐ₅₈₇₉ | L_{b3} | 1080 | Lₐ₅₈₈₄ | L_{b3} |
| 1081 | Lₐ₅₈₈₅ | L_{b3} | 1082 | Lₐ₅₈₈₇ | L_{b3} |
| 1083 | Lₐ₅₈₉₁ | L_{b3} | 1084 | Lₐ₅₉₆₉ | L_{b3} |
| 1085 | Lₐ₅₉₇₄ | L_{b3} | 1086 | Lₐ₅₉₇₅ | L_{b3} |
| 1087 | Lₐ₅₉₇₇ | L_{b3} | 1088 | Lₐ₅₉₈₁ | L_{b3} |
| 1089 | Lₐ₆₀₅₇ | L_{b3} | 1090 | Lₐ₆₀₅₉ | L_{b3} |
| 1091 | Lₐ₆₀₆₁ | L_{b3} | 1092 | Lₐ₆₀₆₃ | L_{b3} |
| 1093 | Lₐ₆₀₆₆ | L_{b3} | 1094 | Lₐ₆₀₇₃ | L_{b3} |
| 1095 | Lₐ₆₀₇₅ | L_{b3} | 1096 | Lₐ₆₀₇₈ | L_{b3} |
| 1097 | Lₐ₆₀₈₅ | L_{b3} | 1098 | Lₐ₆₀₈₇ | L_{b3} |
| 1099 | Lₐ₆₀₉₇ | L_{b3} | 1100 | Lₐ₆₀₉₉ | L_{b3} |
| 1101 | Lₐ₆₁₁₇ | L_{b3} | 1102 | Lₐ₆₁₁₉ | L_{b3} |
| 1103 | Lₐ₆₁₂₁ | L_{b3} | 1104 | Lₐ₆₁₂₃ | L_{b3} |
| 1105 | Lₐ₆₁₂₆ | L_{b3} | 1106 | Lₐ₆₁₃₃ | L_{b3} |
| 1107 | Lₐ₆₁₃₅ | L_{b3} | 1108 | Lₐ₆₁₄₅ | L_{b3} |
| 1109 | Lₐ₆₁₄₇ | L_{b3} | 1110 | Lₐ₆₁₅₇ | L_{b3} |
| 1111 | Lₐ₆₁₅₉ | L_{b3} | 1112 | Lₐ₆₁₆₂ | L_{b3} |
| 1113 | Lₐ₆₁₆₉ | L_{b3} | 1114 | Lₐ₆₁₇₁ | L_{b3} |
| 1115 | Lₐ₆₁₇₄ | L_{b3} | 1116 | Lₐ₆₁₉₃ | L_{b3} |
| 1117 | Lₐ₆₁₉₅ | L_{b3} | 1118 | Lₐ₆₁₉₈ | L_{b3} |
| 1119 | Lₐ₆₂₀₅ | L_{b3} | 1120 | Lₐ₆₂₀₇ | L_{b3} |
| 1121 | Lₐ₆₂₂₇ | L_{b3} | 1122 | Lₐ₆₂₃₂ | L_{b3} |
| 1123 | Lₐ₆₂₃₃ | L_{b3} | 1124 | Lₐ₆₂₃₅ | L_{b3} |
| 1125 | Lₐ₆₂₃₉ | L_{b3} | 1126 | Lₐ₆₂₄₅ | L_{b3} |
| 1127 | Lₐ₆₂₅₀ | L_{b3} | 1128 | Lₐ₆₂₅₁ | L_{b3} |
| 1129 | Lₐ₆₂₅₃ | L_{b3} | 1130 | Lₐ₆₂₅₇ | L_{b3} |
| 1131 | Lₐ₆₃₃₅ | L_{b3} | 1132 | Lₐ₆₃₄₀ | L_{b3} |
| 1133 | Lₐ₆₃₄₁ | L_{b3} | 1134 | Lₐ₆₃₄₃ | L_{b3} |
| 1135 | Lₐ₆₃₄₇ | L_{b3} | 1136 | Lₐ₆₄₂₃ | L_{b3} |
| 1137 | Lₐ₆₄₂₅ | L_{b3} | 1138 | Lₐ₆₄₂₇ | L_{b3} |
| 1139 | Lₐ₆₄₂₉ | L_{b3} | 1140 | Lₐ₆₄₃₂ | L_{b3} |
| 1141 | Lₐ₆₄₃₉ | L_{b3} | 1142 | Lₐ₆₄₄₁ | L_{b3} |
| 1143 | Lₐ₆₄₄₄ | L_{b3} | 1144 | Lₐ₆₄₆₃ | L_{b3} |
| 1145 | Lₐ₆₄₆₅ | L_{b3} | 1146 | Lₐ₆₄₆₈ | L_{b3} |
| 1147 | Lₐ₆₄₈₃ | L_{b3} | 1148 | Lₐ₆₄₈₅ | L_{b3} |
| 1149 | Lₐ₆₄₈₇ | L_{b3} | 1150 | Lₐ₆₄₈₉ | L_{b3} |
| 1151 | Lₐ₆₄₉₂ | L_{b3} | 1152 | Lₐ₆₄₉₉ | L_{b3} |
| 1153 | Lₐ₆₅₀₁ | L_{b3} | 1154 | Lₐ₆₅₁₁ | L_{b3} |
| 1155 | Lₐ₆₅₁₃ | L_{b3} | 1156 | Lₐ₆₅₂₃ | L_{b3} |
| 1157 | Lₐ₆₅₂₅ | L_{b3} | 1158 | Lₐ₆₅₂₈ | L_{b3} |
| 1159 | Lₐ₆₅₃₅ | L_{b3} | 1160 | Lₐ₆₅₃₇ | L_{b3} |
| 1161 | Lₐ₆₅₄₀ | L_{b3} | 1162 | Lₐ₆₅₅₉ | L_{b3} |
| 1163 | Lₐ₆₅₆₁ | L_{b3} | 1164 | Lₐ₆₅₆₄ | L_{b3} |
| 1165 | Lₐ₆₅₇₁ | L_{b3} | 1166 | Lₐ₆₅₇₃ | L_{b3} |
| 1167 | Lₐ₆₅₉₃ | L_{b3} | 1168 | Lₐ₆₅₉₈ | L_{b3} |
| 1169 | Lₐ₆₅₉₉ | L_{b3} | 1170 | Lₐ₆₆₀₁ | L_{b3} |
| 1171 | Lₐ₆₆₀₅ | L_{b3} | 1172 | Lₐ₆₆₁₁ | L_{b3} |
| 1173 | Lₐ₆₆₁₆ | L_{b3} | 1174 | Lₐ₆₆₁₉ | L_{b3} |
| 1175 | Lₐ₆₆₂₃ | L_{b3} | 1176 | Lₐ₆₇₀₀ | L_{b3} |
| 1177 | Lₐ₆₇₀₁ | L_{b3} | 1178 | Lₐ₆₇₀₃ | L_{b3} |
| 1179 | Lₐ₆₇₀₆ | L_{b3} | 1180 | Lₐ₆₇₀₇ | L_{b3} |
| 1181 | Lₐ₆₇₀₉ | L_{b3} | 1182 | Lₐ₆₇₁₃ | L_{b3} |
| 1183 | Lₐ₆₇₄₂ | L_{b3} | 1184 | Lₐ₆₇₄₅ | L_{b3} |
| 1185 | Lₐ₆₇₉₃ | L_{b3} | 1186 | Lₐ₆₇₉₅ | L_{b3} |
| 1187 | Lₐ₆₇₉₈ | L_{b3} | 1188 | Lₐ₆₈₀₅ | L_{b3} |
| 1189 | Lₐ₆₈₀₇ | L_{b3} | 1190 | Lₐ₆₈₁₀ | L_{b3} |
| 1191 | Lₐ₆₈₂₉ | L_{b3} | 1192 | Lₐ₆₈₃₁ | L_{b3} |
| 1193 | Lₐ₆₈₃₄ | L_{b3} | 1194 | Lₐ₆₈₄₉ | L_{b3} |
| 1195 | Lₐ₆₈₅₁ | L_{b3} | 1196 | Lₐ₆₈₅₃ | L_{b3} |
| 1197 | Lₐ₆₈₅₅ | L_{b3} | 1198 | Lₐ₆₈₅₈ | L_{b3} |
| 1199 | Lₐ₆₈₆₅ | L_{b3} | 1200 | Lₐ₆₈₆₇ | L_{b3} |
| 1201 | Lₐ₆₈₇₇ | L_{b3} | 1202 | Lₐ₆₈₇₉ | L_{b3} |
| 1203 | Lₐ₆₈₈₉ | L_{b3} | 1204 | Lₐ₆₈₉₁ | L_{b3} |
| 1205 | Lₐ₆₈₉₄ | L_{b3} | 1206 | Lₐ₆₉₀₁ | L_{b3} |
| 1207 | Lₐ₆₉₀₃ | L_{b3} | 1208 | Lₐ₆₉₂₅ | L_{b3} |
| 1209 | Lₐ₆₉₂₇ | L_{b3} | 1210 | Lₐ₆₉₃₀ | L_{b3} |
| 1211 | Lₐ₆₉₃₇ | L_{b3} | 1212 | Lₐ₆₉₃₉ | L_{b3} |
| 1213 | Lₐ₅ | L_{b8} | 1214 | Lₐ₇ | L_{b8} |
| 1215 | Lₐ₁₀ | L_{b8} | 1216 | Lₐ₁₁ | L_{b8} |
| 1217 | Lₐ₁₃ | L_{b8} | 1218 | Lₐ₁₄ | L_{b8} |
| 1219 | Lₐ₁₇ | L_{b8} | 1220 | Lₐ₂₃ | L_{b8} |
| 1221 | Lₐ₂₈ | L_{b8} | 1222 | Lₐ₂₉ | L_{b8} |
| 1223 | Lₐ₃₁ | L_{b8} | 1224 | Lₐ₃₅ | L_{b8} |
| 1225 | Lₐ₅₉ | L_{b8} | 1226 | Lₐ₆₄ | L_{b8} |
| 1227 | Lₐ₆₅ | L_{b8} | 1228 | Lₐ₆₇ | L_{b8} |
| 1229 | Lₐ₇₁ | L_{b8} | 1230 | Lₐ₁₁₃ | L_{b8} |
| 1231 | Lₐ₁₁₈ | L_{b8} | 1232 | Lₐ₁₁₉ | L_{b8} |
| 1233 | Lₐ₁₂₁ | L_{b8} | 1234 | Lₐ₁₂₅ | L_{b8} |
| 1235 | Lₐ₁₄₉ | L_{b8} | 1236 | Lₐ₁₅₄ | L_{b8} |
| 1237 | Lₐ₁₅₅ | L_{b8} | 1238 | Lₐ₁₅₇ | L_{b8} |
| 1239 | Lₐ₁₆₁ | L_{b8} | 1240 | Lₐ₂₀₅ | L_{b8} |
| 1241 | Lₐ₂₀₇ | L_{b8} | 1242 | Lₐ₂₁₀ | L_{b8} |
| 1243 | Lₐ₂₁₇ | L_{b8} | 1244 | Lₐ₂₁₉ | L_{b8} |
| 1245 | Lₐ₂₂₂ | L_{b8} | 1246 | Lₐ₂₂₉ | L_{b8} |
| 1247 | Lₐ₂₃₁ | L_{b8} | 1248 | Lₐ₂₃₄ | L_{b8} |
| 1249 | Lₐ₂₄₁ | L_{b8} | 1250 | Lₐ₂₄₃ | L_{b8} |
| 1251 | Lₐ₂₄₆ | L_{b8} | 1252 | Lₐ₂₅₃ | L_{b8} |
| 1253 | Lₐ₂₅₅ | L_{b8} | 1254 | Lₐ₂₅₈ | L_{b8} |
| 1255 | Lₐ₂₆₁ | L_{b8} | 1256 | Lₐ₂₆₃ | L_{b8} |
| 1257 | Lₐ₂₆₅ | L_{b8} | 1258 | Lₐ₂₆₇ | L_{b8} |
| 1259 | Lₐ₂₇₀ | L_{b8} | 1260 | Lₐ₂₇₇ | L_{b8} |
| 1261 | Lₐ₂₇₉ | L_{b8} | 1262 | Lₐ₂₈₂ | L_{b8} |
| 1263 | Lₐ₂₈₉ | L_{b8} | 1264 | Lₐ₂₉₁ | L_{b8} |
| 1265 | Lₐ₂₉₄ | L_{b8} | 1266 | Lₐ₃₀₁ | L_{b8} |
| 1267 | Lₐ₃₀₃ | L_{b8} | 1268 | Lₐ₃₀₆ | L_{b8} |
| 1269 | Lₐ₃₁₃ | L_{b8} | 1270 | Lₐ₃₁₅ | L_{b8} |
| 1271 | Lₐ₃₁₈ | L_{b8} | 1272 | Lₐ₃₂₅ | L_{b8} |
| 1273 | Lₐ₃₂₇ | L_{b8} | 1274 | Lₐ₃₃₀ | L_{b8} |
| 1275 | Lₐ₃₃₇ | L_{b8} | 1276 | Lₐ₃₃₉ | L_{b8} |
| 1277 | Lₐ₃₄₂ | L_{b8} | 1278 | Lₐ₃₄₉ | L_{b8} |
| 1279 | Lₐ₃₅₁ | L_{b8} | 1280 | Lₐ₃₅₄ | L_{b8} |
| 1281 | Lₐ₃₆₁ | L_{b8} | 1282 | Lₐ₃₆₃ | L_{b8} |
| 1283 | Lₐ₃₆₆ | L_{b8} | 1284 | Lₐ₃₇₁ | L_{b8} |
| 1285 | Lₐ₅₇₁ | L_{b8} | 1286 | Lₐ₅₇₃ | L_{b8} |
| 1287 | Lₐ₆₃₁ | L_{b8} | 1288 | Lₐ₆₃₃ | L_{b8} |
| 1289 | Lₐ₇₃₇ | L_{b8} | 1290 | Lₐ₉₃₇ | L_{b8} |
| 1291 | Lₐ₉₃₉ | L_{b8} | 1292 | Lₐ₉₉₇ | L_{b8} |
| 1293 | Lₐ₉₉₉ | L_{b8} | 1294 | Lₐ₁₀₀₉ | L_{b8} |
| 1295 | Lₐ₁₀₁₁ | L_{b8} | 1296 | Lₐ₁₀₂₁ | L_{b8} |
| 1297 | Lₐ₁₀₂₃ | L_{b8} | 1298 | Lₐ₁₁₀₃ | L_{b8} |
| 1299 | Lₐ₁₁₀₅ | L_{b8} | 1300 | Lₐ₁₁₀₈ | L_{b8} |
| 1301 | Lₐ₁₁₀₉ | L_{b8} | 1302 | Lₐ₁₁₁₁ | L_{b8} |
| 1303 | Lₐ₁₁₁₂ | L_{b8} | 1304 | Lₐ₁₁₁₅ | L_{b8} |
| 1305 | Lₐ₁₁₂₁ | L_{b8} | 1306 | Lₐ₁₁₂₆ | L_{b8} |
| 1307 | Lₐ₁₁₂₇ | L_{b8} | 1308 | Lₐ₁₁₂₉ | L_{b8} |
| 1309 | Lₐ₁₁₃₃ | L_{b8} | 1310 | Lₐ₁₁₅₇ | L_{b8} |
| 1311 | Lₐ₁₁₆₂ | L_{b8} | 1312 | Lₐ₁₁₆₃ | L_{b8} |
| 1313 | Lₐ₁₁₆₅ | L_{b8} | 1314 | Lₐ₁₁₆₉ | L_{b8} |
| 1315 | Lₐ₁₂₁₁ | L_{b8} | 1316 | Lₐ₁₂₁₆ | L_{b8} |
| 1317 | Lₐ₁₂₁₇ | L_{b8} | 1318 | Lₐ₁₂₁₉ | L_{b8} |
| 1319 | Lₐ₁₂₂₃ | L_{b8} | 1320 | Lₐ₁₂₄₇ | L_{b8} |
| 1321 | Lₐ₁₂₅₂ | L_{b8} | 1322 | Lₐ₁₂₅₃ | L_{b8} |
| 1323 | Lₐ₁₂₅₅ | L_{b8} | 1324 | Lₐ₁₂₅₉ | L_{b8} |
| 1325 | Lₐ₁₃₀₃ | L_{b8} | 1326 | Lₐ₁₃₀₅ | L_{b8} |
| 1327 | Lₐ₁₃₀₈ | L_{b8} | 1328 | Lₐ₁₃₁₅ | L_{b8} |
| 1329 | Lₐ₁₃₁₇ | L_{b8} | 1330 | Lₐ₁₃₂₀ | L_{b8} |
| 1331 | Lₐ₁₃₂₇ | L_{b8} | 1332 | Lₐ₁₃₂₉ | L_{b8} |
| 1333 | Lₐ₁₃₃₂ | L_{b8} | 1334 | Lₐ₁₃₃₉ | L_{b8} |
| 1335 | Lₐ₁₃₄₁ | L_{b8} | 1336 | Lₐ₁₃₄₄ | L_{b8} |
| 1337 | Lₐ₁₃₅₁ | L_{b8} | 1338 | Lₐ₁₃₅₃ | L_{b8} |
| 1339 | Lₐ₁₃₅₆ | L_{b8} | 1340 | Lₐ₁₃₅₉ | L_{b8} |
| 1341 | Lₐ₁₃₆₁ | L_{b8} | 1342 | Lₐ₁₃₆₃ | L_{b8} |
| 1343 | Lₐ₁₃₆₅ | L_{b8} | 1344 | Lₐ₁₃₆₈ | L_{b8} |
| 1345 | Lₐ₁₃₇₅ | L_{b8} | 1346 | Lₐ₁₃₇₇ | L_{b8} |
| 1347 | Lₐ₁₃₈₇ | L_{b8} | 1348 | Lₐ₁₃₈₉ | L_{b8} |
| 1349 | Lₐ₁₄₆₉ | L_{b8} | 1350 | Lₐ₁₆₆₉ | L_{b8} |
| 1351 | Lₐ₁₆₇₁ | L_{b8} | 1352 | Lₐ₁₇₂₉ | L_{b8} |
| 1353 | Lₐ₁₇₃₁ | L_{b8} | 1354 | Lₐ₁₇₄₁ | L_{b8} |
| 1355 | Lₐ₁₇₄₃ | L_{b8} | 1356 | Lₐ₁₇₅₃ | L_{b8} |
| 1357 | Lₐ₁₇₅₅ | L_{b8} | 1358 | Lₐ₁₈₃₅ | L_{b8} |
| 1359 | Lₐ₂₀₃₅ | L_{b8} | 1360 | Lₐ₂₀₃₇ | L_{b8} |
| 1361 | Lₐ₂₀₉₅ | L_{b8} | 1362 | Lₐ₂₀₉₇ | L_{b8} |
| 1363 | Lₐ₂₁₀₇ | L_{b8} | 1364 | Lₐ₂₁₀₉ | L_{b8} |
| 1365 | Lₐ₂₁₁₉ | L_{b8} | 1366 | Lₐ₂₁₂₁ | L_{b8} |
| 1367 | Lₐ₂₂₀₁ | L_{b8} | 1368 | Lₐ₂₄₀₁ | L_{b8} |
| 1369 | Lₐ₂₄₀₃ | L_{b8} | 1370 | Lₐ₂₄₆₁ | L_{b8} |
| 1371 | Lₐ₂₄₆₃ | L_{b8} | 1372 | Lₐ₂₄₇₃ | L_{b8} |
| 1373 | Lₐ₂₄₇₅ | L_{b8} | 1374 | Lₐ₂₄₈₅ | L_{b8} |
| 1375 | Lₐ₂₄₈₇ | L_{b8} | 1376 | Lₐ₂₅₆₇ | L_{b8} |
| 1377 | Lₐ₂₇₆₇ | L_{b8} | 1378 | Lₐ₂₇₆₉ | L_{b8} |
| 1379 | Lₐ₂₈₂₇ | L_{b8} | 1380 | Lₐ₂₈₂₉ | L_{b8} |
| 1381 | Lₐ₂₈₅₁ | L_{b8} | 1382 | Lₐ₂₈₅₃ | L_{b8} |
| 1383 | Lₐ₂₉₃₃ | L_{b8} | 1384 | Lₐ₂₉₃₅ | L_{b8} |
| 1385 | Lₐ₂₉₃₈ | L_{b8} | 1386 | Lₐ₂₉₃₉ | L_{b8} |
| 1387 | Lₐ₂₉₄₁ | L_{b8} | 1388 | Lₐ₂₉₄₂ | L_{b8} |
| 1389 | Lₐ₂₉₄₅ | L_{b8} | 1390 | Lₐ₂₉₅₁ | L_{b8} |
| 1391 | Lₐ₂₉₅₆ | L_{b8} | 1392 | Lₐ₂₉₅₇ | L_{b8} |
| 1393 | Lₐ₂₉₅₉ | L_{b8} | 1394 | Lₐ₂₉₆₃ | L_{b8} |
| 1395 | Lₐ₂₉₈₇ | L_{b8} | 1396 | Lₐ₂₉₉₂ | L_{b8} |
| 1397 | Lₐ₂₉₉₃ | L_{b8} | 1398 | Lₐ₂₉₉₅ | L_{b8} |
| 1399 | Lₐ₂₉₉₉ | L_{b8} | 1400 | Lₐ₃₀₄₁ | L_{b8} |
| 1401 | Lₐ₃₀₄₆ | L_{b8} | 1402 | Lₐ₃₀₄₇ | L_{b8} |
| 1403 | Lₐ₃₀₄₉ | L_{b8} | 1404 | Lₐ₃₀₅₃ | L_{b8} |
| 1405 | Lₐ₃₀₇₇ | L_{b8} | 1406 | Lₐ₃₀₈₂ | L_{b8} |
| 1407 | Lₐ₃₀₈₃ | L_{b8} | 1408 | Lₐ₃₀₈₅ | L_{b8} |
| 1409 | Lₐ₃₀₈₉ | L_{b8} | 1410 | Lₐ₃₁₃₃ | L_{b8} |
| 1411 | Lₐ₃₁₃₅ | L_{b8} | 1412 | Lₐ₃₁₃₈ | L_{b8} |
| 1413 | Lₐ₃₁₄₅ | L_{b8} | 1414 | Lₐ₃₁₄₇ | L_{b8} |
| 1415 | Lₐ₃₁₅₀ | L_{b8} | 1416 | Lₐ₃₁₆₉ | L_{b8} |
| 1417 | Lₐ₃₁₇₁ | L_{b8} | 1418 | Lₐ₃₁₇₄ | L_{b8} |
| 1419 | Lₐ₃₁₈₁ | L_{b8} | 1420 | Lₐ₃₁₈₃ | L_{b8} |
| 1421 | Lₐ₃₁₈₆ | L_{b8} | 1422 | Lₐ₃₁₈₉ | L_{b8} |
| 1423 | Lₐ₃₁₉₁ | L_{b8} | 1424 | Lₐ₃₁₉₃ | L_{b8} |
| 1425 | Lₐ₃₁₉₅ | L_{b8} | 1426 | Lₐ₃₁₉₈ | L_{b8} |
| 1427 | Lₐ₃₂₀₅ | L_{b8} | 1428 | Lₐ₃₂₀₇ | L_{b8} |
| 1429 | Lₐ₃₂₁₇ | L_{b8} | 1430 | Lₐ₃₂₁₉ | L_{b8} |
| 1431 | Lₐ₃₂₂₉ | L_{b8} | 1432 | Lₐ₃₂₃₁ | L_{b8} |
| 1433 | Lₐ₃₂₃₄ | L_{b8} | 1434 | Lₐ₃₂₄₁ | L_{b8} |
| 1435 | Lₐ₃₂₄₃ | L_{b8} | 1436 | Lₐ₃₂₄₆ | L_{b8} |
| 1437 | Lₐ₃₂₅₃ | L_{b8} | 1438 | Lₐ₃₂₅₅ | L_{b8} |
| 1439 | Lₐ₃₂₅₈ | L_{b8} | 1440 | Lₐ₃₂₆₅ | L_{b8} |
| 1441 | Lₐ₃₂₆₇ | L_{b8} | 1442 | Lₐ₃₂₇₀ | L_{b8} |
| 1443 | Lₐ₃₂₇₇ | L_{b8} | 1444 | Lₐ₃₂₇₉ | L_{b8} |
| 1445 | Lₐ₃₂₈₂ | L_{b8} | 1446 | Lₐ₃₂₈₉ | L_{b8} |
| 1447 | Lₐ₃₂₉₁ | L_{b8} | 1448 | Lₐ₃₂₉₄ | L_{b8} |
| 1449 | Lₐ₃₂₉₉ | L_{b8} | 1450 | Lₐ₃₄₉₉ | L_{b8} |
| 1451 | Lₐ₃₅₀₁ | L_{b8} | 1452 | Lₐ₃₅₅₉ | L_{b8} |
| 1453 | Lₐ₃₅₆₁ | L_{b8} | 1454 | Lₐ₃₅₇₁ | L_{b8} |
| 1455 | Lₐ₃₅₇₃ | L_{b8} | 1456 | Lₐ₃₅₈₃ | L_{b8} |
| 1457 | Lₐ₃₅₈₅ | L_{b8} | 1458 | Lₐ₃₆₆₅ | L_{b8} |
| 1459 | Lₐ₃₆₆₇ | L_{b8} | 1460 | Lₐ₃₆₇₀ | L_{b8} |
| 1461 | Lₐ₃₆₇₁ | L_{b8} | 1462 | Lₐ₃₆₇₃ | L_{b8} |
| 1463 | Lₐ₃₆₇₄ | L_{b8} | 1464 | Lₐ₃₆₇₇ | L_{b8} |
| 1465 | Lₐ₃₆₈₃ | L_{b8} | 1466 | Lₐ₃₆₈₈ | L_{b8} |
| 1467 | Lₐ₃₆₈₉ | L_{b8} | 1468 | Lₐ₃₆₉₁ | L_{b8} |
| 1469 | Lₐ₃₆₉₅ | L_{b8} | 1470 | Lₐ₃₇₁₉ | L_{b8} |
| 1471 | Lₐ₃₇₂₄ | L_{b8} | 1472 | Lₐ₃₇₂₅ | L_{b8} |
| 1473 | Lₐ₃₇₂₇ | L_{b8} | 1474 | Lₐ₃₇₃₁ | L_{b8} |
| 1475 | Lₐ₃₇₇₃ | L_{b8} | 1476 | Lₐ₃₇₇₈ | L_{b8} |
| 1477 | Lₐ₃₇₇₉ | L_{b8} | 1478 | Lₐ₃₇₈₁ | L_{b8} |
| 1479 | Lₐ₃₇₈₅ | L_{b8} | 1480 | Lₐ₃₈₀₉ | L_{b8} |
| 1481 | Lₐ₃₈₁₄ | L_{b8} | 1482 | Lₐ₃₈₁₅ | L_{b8} |
| 1483 | Lₐ₃₈₁₇ | L_{b8} | 1484 | Lₐ₃₈₂₁ | L_{b8} |
| 1485 | Lₐ₃₈₆₅ | L_{b8} | 1486 | Lₐ₃₈₆₇ | L_{b8} |
| 1487 | Lₐ₃₈₇₀ | L_{b8} | 1488 | Lₐ₃₈₇₇ | L_{b8} |
| 1489 | Lₐ₃₈₇₉ | L_{b8} | 1490 | Lₐ₃₈₈₂ | L_{b8} |
| 1491 | Lₐ₃₈₈₉ | L_{b8} | 1492 | Lₐ₃₈₉₁ | L_{b8} |
| 1493 | Lₐ₃₈₉₄ | L_{b8} | 1494 | Lₐ₃₉₀₁ | L_{b8} |
| 1495 | Lₐ₃₉₀₃ | L_{b8} | 1496 | Lₐ₃₉₀₆ | L_{b8} |
| 1497 | Lₐ₃₉₁₃ | L_{b8} | 1498 | Lₐ₃₉₁₅ | L_{b8} |
| 1499 | Lₐ₃₉₁₈ | L_{b8} | 1500 | Lₐ₃₉₂₁ | L_{b8} |
| 1501 | Lₐ₃₉₂₃ | L_{b8} | 1502 | Lₐ₃₉₂₄ | L_{b8} |
| 1503 | Lₐ₃₉₂₅ | L_{b8} | 1504 | Lₐ₃₉₂₇ | L_{b8} |
| 1505 | Lₐ₃₉₂₈ | L_{b8} | 1506 | Lₐ₃₉₃₀ | L_{b8} |
| 1507 | Lₐ₃₉₃₇ | L_{b8} | 1508 | Lₐ₃₉₃₉ | L_{b8} |
| 1509 | Lₐ₃₉₄₉ | L_{b8} | 1510 | Lₐ₃₉₅₁ | L_{b8} |
| 1511 | Lₐ₃₉₆₁ | L_{b8} | 1512 | Lₐ₃₉₆₃ | L_{b8} |
| 1513 | Lₐ₃₉₆₆ | L_{b8} | 1514 | Lₐ₃₉₇₃ | L_{b8} |
| 1515 | Lₐ₃₉₇₅ | L_{b8} | 1516 | Lₐ₃₉₇₈ | L_{b8} |
| 1517 | Lₐ₃₉₈₅ | L_{b8} | 1518 | Lₐ₃₉₈₇ | L_{b8} |
| 1519 | Lₐ₃₉₉₀ | L_{b8} | 1520 | Lₐ₃₉₉₇ | L_{b8} |
| 1521 | Lₐ₃₉₉₉ | L_{b8} | 1522 | Lₐ₄₀₀₂ | L_{b8} |
| 1523 | Lₐ₄₀₀₉ | L_{b8} | 1524 | Lₐ₄₀₁₁ | L_{b8} |
| 1525 | Lₐ₄₀₁₄ | L_{b8} | 1526 | Lₐ₄₀₂₁ | L_{b8} |
| 1527 | Lₐ₄₀₂₃ | L_{b8} | 1528 | Lₐ₄₀₂₆ | L_{b8} |
| 1529 | Lₐ₄₀₃₁ | L_{b8} | 1530 | Lₐ₄₀₃₆ | L_{b8} |
| 1531 | Lₐ₄₀₃₇ | L_{b8} | 1532 | Lₐ₄₀₃₉ | L_{b8} |
| 1533 | Lₐ₄₀₄₃ | L_{b8} | 1534 | Lₐ₄₀₄₉ | L_{b8} |
| 1535 | Lₐ₄₀₅₄ | L_{b8} | 1536 | Lₐ₄₀₅₅ | L_{b8} |
| 1537 | Lₐ₄₀₅₇ | L_{b8} | 1538 | Lₐ₄₀₆₁ | L_{b8} |
| 1539 | Lₐ₄₁₃₉ | L_{b8} | 1540 | Lₐ₄₁₄₄ | L_{b8} |
| 1541 | Lₐ₄₁₄₅ | L_{b8} | 1542 | Lₐ₄₁₄₇ | L_{b8} |
| 1543 | Lₐ₄₁₅₁ | L_{b8} | 1544 | Lₐ₄₂₃₁ | L_{b8} |
| 1545 | Lₐ₄₂₃₃ | L_{b8} | 1546 | Lₐ₄₂₃₆ | L_{b8} |
| 1547 | Lₐ₄₂₄₃ | L_{b8} | 1548 | Lₐ₄₂₄₅ | L_{b8} |
| 1549 | Lₐ₄₂₄₈ | L_{b8} | 1550 | Lₐ₄₂₆₇ | L_{b8} |
| 1551 | Lₐ₄₂₆₉ | L_{b8} | 1552 | Lₐ₄₂₇₂ | L_{b8} |
| 1553 | Lₐ₄₂₈₇ | L_{b8} | 1554 | Lₐ₄₂₈₉ | L_{b8} |
| 1555 | Lₐ₄₂₉₁ | L_{b8} | 1556 | Lₐ₄₂₉₃ | L_{b8} |
| 1557 | Lₐ₄₂₉₄ | L_{b8} | 1558 | Lₐ₄₂₉₆ | L_{b8} |
| 1559 | Lₐ₄₃₀₃ | L_{b8} | 1560 | Lₐ₄₃₀₅ | L_{b8} |
| 1561 | Lₐ₄₃₁₅ | L_{b8} | 1562 | Lₐ₄₃₁₇ | L_{b8} |
| 1563 | Lₐ₄₃₂₇ | L_{b8} | 1564 | Lₐ₄₃₂₉ | L_{b8} |
| 1565 | Lₐ₄₃₃₂ | L_{b8} | 1566 | Lₐ₄₃₃₉ | L_{b8} |
| 1567 | Lₐ₄₃₄₁ | L_{b8} | 1568 | Lₐ₄₃₄₄ | L_{b8} |
| 1569 | Lₐ₄₃₆₃ | L_{b8} | 1570 | Lₐ₄₃₆₅ | L_{b8} |
| 1571 | Lₐ₄₃₆₈ | L_{b8} | 1572 | Lₐ₄₃₇₅ | L_{b8} |
| 1573 | Lₐ₄₃₇₇ | L_{b8} | 1574 | Lₐ₄₃₈₀ | L_{b8} |
| 1575 | Lₐ₄₃₉₇ | L_{b8} | 1576 | Lₐ₄₃₉₉ | L_{b8} |
| 1577 | Lₐ₄₄₀₂ | L_{b8} | 1578 | Lₐ₄₄₀₃ | L_{b8} |
| 1579 | Lₐ₄₄₀₅ | L_{b8} | 1580 | Lₐ₄₄₀₆ | L_{b8} |
| 1581 | Lₐ₄₄₀₉ | L_{b8} | 1582 | Lₐ₄₄₁₅ | L_{b8} |
| 1583 | Lₐ₄₄₂₀ | L_{b8} | 1584 | Lₐ₄₄₂₃ | L_{b8} |
| 1585 | Lₐ₄₄₂₇ | L_{b8} | 1586 | Lₐ₄₄₅₁ | L_{b8} |
| 1587 | Lₐ₄₄₅₆ | L_{b8} | 1588 | Lₐ₄₄₅₇ | L_{b8} |
| 1589 | Lₐ₄₄₅₉ | L_{b8} | 1590 | Lₐ₄₄₆₃ | L_{b8} |
| 1591 | Lₐ₄₅₉₇ | L_{b8} | 1592 | Lₐ₄₅₉₉ | L_{b8} |
| 1593 | Lₐ₄₆₀₂ | L_{b8} | 1594 | Lₐ₄₆₀₉ | L_{b8} |
| 1595 | Lₐ₄₆₁₁ | L_{b8} | 1596 | Lₐ₄₆₂₁ | L_{b8} |
| 1597 | Lₐ₄₆₂₃ | L_{b8} | 1598 | Lₐ₄₆₃₃ | L_{b8} |
| 1599 | Lₐ₄₆₃₅ | L_{b8} | 1600 | Lₐ₄₆₄₅ | L_{b8} |
| 1601 | Lₐ₄₆₄₇ | L_{b8} | 1602 | Lₐ₄₆₅₃ | L_{b8} |
| 1603 | Lₐ₄₆₅₅ | L_{b8} | 1604 | Lₐ₄₆₅₇ | L_{b8} |
| 1605 | Lₐ₄₆₅₉ | L_{b8} | 1606 | Lₐ₄₆₆₂ | L_{b8} |
| 1607 | Lₐ₄₆₆₉ | L_{b8} | 1608 | Lₐ₄₆₇₁ | L_{b8} |
| 1609 | Lₐ₄₆₈₁ | L_{b8} | 1610 | Lₐ₄₆₈₃ | L_{b8} |
| 1611 | Lₐ₄₆₉₃ | L_{b8} | 1612 | Lₐ₄₆₉₅ | L_{b8} |
| 1613 | Lₐ₄₆₉₈ | L_{b8} | 1614 | Lₐ₄₇₀₅ | L_{b8} |
| 1615 | Lₐ₄₇₀₇ | L_{b8} | 1616 | Lₐ₄₇₁₀ | L_{b8} |
| 1617 | Lₐ₄₇₂₉ | L_{b8} | 1618 | Lₐ₄₇₃₁ | L_{b8} |
| 1619 | Lₐ₄₇₃₄ | L_{b8} | 1620 | Lₐ₄₇₆₃ | L_{b8} |
| 1621 | Lₐ₄₉₆₃ | L_{b8} | 1622 | Lₐ₄₉₆₅ | L_{b8} |
| 1623 | Lₐ₄₉₆₈ | L_{b8} | 1624 | Lₐ₅₀₂₃ | L_{b8} |
| 1625 | Lₐ₅₀₂₅ | L_{b8} | 1626 | Lₐ₅₀₃₅ | L_{b8} |
| 1627 | Lₐ₅₀₃₇ | L_{b8} | 1628 | Lₐ₅₀₄₇ | L_{b8} |
| 1629 | Lₐ₅₀₄₉ | L_{b8} | 1630 | Lₐ₅₁₂₉ | L_{b8} |
| 1631 | Lₐ₅₁₃₄ | L_{b8} | 1632 | Lₐ₅₁₃₅ | L_{b8} |
| 1633 | Lₐ₅₁₃₇ | L_{b8} | 1634 | Lₐ₅₁₄₁ | L_{b8} |
| 1635 | Lₐ₅₁₄₇ | L_{b8} | 1636 | Lₐ₅₁₅₂ | L_{b8} |
| 1637 | Lₐ₅₁₅₃ | L_{b8} | 1638 | Lₐ₅₁₅₅ | L_{b8} |
| 1639 | Lₐ₅₁₅₉ | L_{b8} | 1640 | Lₐ₅₂₃₇ | L_{b8} |
| 1641 | Lₐ₅₂₄₂ | L_{b8} | 1642 | Lₐ₅₂₄₃ | L_{b8} |
| 1643 | Lₐ₅₂₄₅ | L_{b8} | 1644 | Lₐ₅₂₄₉ | L_{b8} |
| 1645 | Lₐ₅₃₂₉ | L_{b8} | 1646 | Lₐ₅₃₃₁ | L_{b8} |
| 1647 | Lₐ₅₃₃₄ | L_{b8} | 1648 | Lₐ₅₃₄₁ | L_{b8} |
| 1649 | Lₐ₅₃₄₃ | L_{b8} | 1650 | Lₐ₅₃₄₆ | L_{b8} |
| 1651 | Lₐ₅₃₆₅ | L_{b8} | 1652 | Lₐ₅₃₆₇ | L_{b8} |
| 1653 | Lₐ₅₃₇₀ | L_{b8} | 1654 | Lₐ₅₃₈₅ | L_{b8} |
| 1655 | Lₐ₅₃₈₇ | L_{b8} | 1656 | Lₐ₅₃₈₉ | L_{b8} |
| 1657 | Lₐ₅₃₉₁ | L_{b8} | 1658 | Lₐ₅₃₉₂ | L_{b8} |
| 1659 | Lₐ₅₃₉₄ | L_{b8} | 1660 | Lₐ₅₄₀₁ | L_{b8} |
| 1661 | Lₐ₅₄₀₃ | L_{b8} | 1662 | Lₐ₅₄₁₃ | L_{b8} |
| 1663 | Lₐ₅₄₁₅ | L_{b8} | 1664 | Lₐ₅₄₂₅ | L_{b8} |
| 1665 | Lₐ₅₄₂₇ | L_{b8} | 1666 | Lₐ₅₄₃₀ | L_{b8} |
| 1667 | Lₐ₅₄₆₁ | L_{b8} | 1668 | Lₐ₅₄₆₃ | L_{b8} |
| 1669 | Lₐ₅₄₆₆ | L_{b8} | 1670 | Lₐ₅₄₉₅ | L_{b8} |
| 1671 | Lₐ₅₆₉₅ | L_{b8} | 1672 | Lₐ₅₆₉₇ | L_{b8} |
| 1673 | Lₐ₅₇₅₅ | L_{b8} | 1674 | Lₐ₅₇₅₇ | L_{b8} |
| 1675 | Lₐ₅₇₆₀ | L_{b8} | 1676 | Lₐ₅₇₆₇ | L_{b8} |
| 1677 | Lₐ₅₇₆₉ | L_{b8} | 1678 | Lₐ₅₇₇₉ | L_{b8} |
| 1679 | Lₐ₅₇₈₁ | L_{b8} | 1680 | Lₐ₅₈₆₁ | L_{b8} |
| 1681 | Lₐ₅₈₆₆ | L_{b8} | 1682 | Lₐ₅₈₆₇ | L_{b8} |
| 1683 | Lₐ₅₈₆₉ | L_{b8} | 1684 | Lₐ₅₈₇₃ | L_{b8} |
| 1685 | Lₐ₅₈₇₉ | L_{b8} | 1686 | Lₐ₅₈₈₄ | L_{b8} |
| 1687 | Lₐ₅₈₈₅ | L_{b8} | 1688 | Lₐ₅₈₈₇ | L_{b8} |
| 1689 | Lₐ₅₈₉₁ | L_{b8} | 1690 | Lₐ₅₉₆₉ | L_{b8} |
| 1691 | Lₐ₅₉₇₄ | L_{b8} | 1692 | Lₐ₅₉₇₅ | L_{b8} |
| 1693 | Lₐ₅₉₇₇ | L_{b8} | 1694 | Lₐ₅₉₈₁ | L_{b8} |
| 1695 | Lₐ₆₀₅₇ | L_{b8} | 1696 | Lₐ₆₀₅₉ | L_{b8} |
| 1697 | Lₐ₆₀₆₁ | L_{b8} | 1698 | Lₐ₆₀₆₃ | L_{b8} |
| 1699 | Lₐ₆₀₆₆ | L_{b8} | 1700 | Lₐ₆₀₇₃ | L_{b8} |
| 1701 | Lₐ₆₀₇₅ | L_{b8} | 1702 | Lₐ₆₀₇₈ | L_{b8} |
| 1703 | Lₐ₆₀₈₅ | L_{b8} | 1704 | Lₐ₆₀₈₇ | L_{b8} |
| 1705 | Lₐ₆₀₉₇ | L_{b8} | 1706 | Lₐ₆₀₉₉ | L_{b8} |
| 1707 | Lₐ₆₁₁₇ | L_{b8} | 1708 | Lₐ₆₁₁₉ | L_{b8} |
| 1709 | Lₐ₆₁₂₁ | L_{b8} | 1710 | Lₐ₆₁₂₃ | L_{b8} |
| 1711 | Lₐ₆₁₂₆ | L_{b8} | 1712 | Lₐ₆₁₃₃ | L_{b8} |
| 1713 | Lₐ₆₁₃₅ | L_{b8} | 1714 | Lₐ₆₁₄₅ | L_{b8} |
| 1715 | Lₐ₆₁₄₇ | L_{b8} | 1716 | Lₐ₆₁₅₇ | L_{b8} |
| 1717 | Lₐ₆₁₅₉ | L_{b8} | 1718 | Lₐ₆₁₆₂ | L_{b8} |
| 1719 | Lₐ₆₁₆₉ | L_{b8} | 1720 | Lₐ₆₁₇₁ | L_{b8} |
| 1721 | Lₐ₆₁₇₄ | L_{b8} | 1722 | Lₐ₆₁₉₃ | L_{b8} |
| 1723 | Lₐ₆₁₉₅ | L_{b8} | 1724 | Lₐ₆₁₉₈ | L_{b8} |
| 1725 | Lₐ₆₂₀₅ | L_{b8} | 1726 | Lₐ₆₂₀₇ | L_{b8} |
| 1727 | Lₐ₆₂₂₇ | L_{b8} | 1728 | Lₐ₆₂₃₂ | L_{b8} |
| 1729 | Lₐ₆₂₃₃ | L_{b8} | 1730 | Lₐ₆₂₃₅ | L_{b8} |
| 1731 | Lₐ₆₂₃₉ | L_{b8} | 1732 | Lₐ₆₂₄₅ | L_{b8} |
| 1733 | Lₐ₆₂₅₀ | L_{b8} | 1734 | Lₐ₆₂₅₁ | L_{b8} |
| 1735 | Lₐ₆₂₅₃ | L_{b8} | 1736 | Lₐ₆₂₅₇ | L_{b8} |
| 1737 | Lₐ₆₃₃₅ | L_{b8} | 1738 | Lₐ₆₃₄₀ | L_{b8} |
| 1739 | Lₐ₆₃₄₁ | L_{b8} | 1740 | Lₐ₆₃₄₃ | L_{b8} |
| 1741 | Lₐ₆₃₄₇ | L_{b8} | 1742 | Lₐ₆₄₂₃ | L_{b8} |
| 1743 | Lₐ₆₄₂₅ | L_{b8} | 1744 | Lₐ₆₄₂₇ | L_{b8} |
| 1745 | Lₐ₆₄₂₉ | L_{b8} | 1746 | Lₐ₆₄₃₂ | L_{b8} |
| 1747 | Lₐ₆₄₃₉ | L_{b8} | 1748 | Lₐ₆₄₄₁ | L_{b8} |
| 1749 | Lₐ₆₄₄₄ | L_{b8} | 1750 | Lₐ₆₄₆₃ | L_{b8} |
| 1751 | Lₐ₆₄₆₅ | L_{b8} | 1752 | Lₐ₆₄₆₈ | L_{b8} |
| 1753 | Lₐ₆₄₈₃ | L_{b8} | 1754 | Lₐ₆₄₈₅ | L_{b8} |
| 1755 | Lₐ₆₄₈₇ | L_{b8} | 1756 | Lₐ₆₄₈₉ | L_{b8} |
| 1757 | Lₐ₆₄₉₂ | L_{b8} | 1758 | Lₐ₆₄₉₉ | L_{b8} |
| 1759 | Lₐ₆₅₀₁ | L_{b8} | 1760 | Lₐ₆₅₁₁ | L_{b8} |
| 1761 | Lₐ₆₅₁₃ | L_{b8} | 1762 | Lₐ₆₅₂₃ | L_{b8} |
| 1763 | Lₐ₆₅₂₅ | L_{b8} | 1764 | Lₐ₆₅₂₈ | L_{b8} |
| 1765 | Lₐ₆₅₃₅ | L_{b8} | 1766 | Lₐ₆₅₃₇ | L_{b8} |
| 1767 | Lₐ₆₅₄₀ | L_{b8} | 1768 | Lₐ₆₅₅₉ | L_{b8} |
| 1769 | Lₐ₆₅₆₁ | L_{b8} | 1770 | Lₐ₆₅₆₄ | L_{b8} |
| 1771 | Lₐ₆₅₇₁ | L_{b8} | 1772 | Lₐ₆₅₇₃ | L_{b8} |
| 1773 | Lₐ₆₅₉₃ | L_{b8} | 1774 | Lₐ₆₅₉₈ | L_{b8} |
| 1775 | Lₐ₆₅₉₉ | L_{b8} | 1776 | Lₐ₆₆₀₁ | L_{b8} |
| 1777 | Lₐ₆₆₀₅ | L_{b8} | 1778 | Lₐ₆₆₁₁ | L_{b8} |
| 1779 | Lₐ₆₆₁₆ | L_{b8} | 1780 | Lₐ₆₆₁₉ | L_{b8} |
| 1781 | Lₐ₆₆₂₃ | L_{b8} | 1782 | Lₐ₆₇₀₀ | L_{b8} |
| 1783 | Lₐ₆₇₀₁ | L_{b8} | 1784 | Lₐ₆₇₀₃ | L_{b8} |
| 1785 | Lₐ₆₇₀₆ | L_{b8} | 1786 | Lₐ₆₇₀₇ | L_{b8} |
| 1787 | Lₐ₆₇₀₉ | L_{b8} | 1788 | Lₐ₆₇₁₃ | L_{b8} |
| 1789 | Lₐ₆₇₄₂ | L_{b8} | 1790 | Lₐ₆₇₄₅ | L_{b8} |
| 1791 | Lₐ₆₇₉₃ | L_{b8} | 1792 | Lₐ₆₇₉₅ | L_{b8} |
| 1793 | Lₐ₆₇₉₈ | L_{b8} | 1794 | Lₐ₆₈₀₅ | L_{b8} |
| 1795 | Lₐ₆₈₀₇ | L_{b8} | 1796 | Lₐ₆₈₁₀ | L_{b8} |
| 1797 | Lₐ₆₈₂₉ | L_{b8} | 1798 | Lₐ₆₈₃₁ | L_{b8} |
| 1799 | Lₐ₆₈₃₄ | L_{b8} | 1800 | Lₐ₆₈₄₉ | L_{b8} |
| 1801 | Lₐ₆₈₅₁ | L_{b8} | 1802 | Lₐ₆₈₅₃ | L_{b8} |
| 1803 | Lₐ₆₈₅₅ | L_{b8} | 1804 | Lₐ₆₈₅₈ | L_{b8} |
| 1805 | Lₐ₆₈₆₅ | L_{b8} | 1806 | Lₐ₆₈₆₇ | L_{b8} |
| 1807 | Lₐ₆₈₇₇ | L_{b8} | 1808 | Lₐ₆₈₇₉ | L_{b8} |
| 1809 | Lₐ₆₈₈₉ | L_{b8} | 1810 | Lₐ₆₈₉₁ | L_{b8} |
| 1811 | Lₐ₆₈₉₄ | L_{b8} | 1812 | Lₐ₆₉₀₁ | L_{b8} |
| 1813 | Lₐ₆₉₀₃ | L_{b8} | 1814 | Lₐ₆₉₂₅ | L_{b8} |
| 1815 | Lₐ₆₉₂₇ | L_{b8} | 1816 | Lₐ₆₉₃₀ | L_{b8} |
| 1817 | Lₐ₆₉₃₇ | L_{b8} | 1818 | Lₐ₆₉₃₉ | L_{b8} |
| 1819 | Lₐ₅ | L_{b20} | 1820 | Lₐ₇ | L_{b20} |
| 1821 | Lₐ₁₀ | L_{b20} | 1822 | Lₐ₁₁ | L_{b20} |
| 1823 | Lₐ₁₃ | L_{b20} | 1824 | Lₐ₁₄ | L_{b20} |
| 1825 | Lₐ₁₇ | L_{b20} | 1826 | Lₐ₂₃ | L_{b20} |
| 1827 | Lₐ₂₈ | L_{b20} | 1828 | Lₐ₂₉ | L_{b20} |
| 1829 | Lₐ₃₁ | L_{b20} | 1830 | Lₐ₃₅ | L_{b20} |
| 1831 | Lₐ₅₉ | L_{b20} | 1832 | Lₐ₆₄ | L_{b20} |
| 1833 | Lₐ₆₅ | L_{b20} | 1834 | Lₐ₆₇ | L_{b20} |
| 1835 | Lₐ₇₁ | L_{b20} | 1836 | Lₐ₁₁₃ | L_{b20} |
| 1837 | Lₐ₁₁₈ | L_{b20} | 1838 | Lₐ₁₁₉ | L_{b20} |
| 1839 | Lₐ₁₂₁ | L_{b20} | 1840 | Lₐ₁₂₅ | L_{b20} |
| 1841 | Lₐ₁₄₉ | L_{b20} | 1842 | Lₐ₁₅₄ | L_{b20} |
| 1843 | Lₐ₁₅₅ | L_{b20} | 1844 | Lₐ₁₅₇ | L_{b20} |
| 1845 | Lₐ₁₆₁ | L_{b20} | 1846 | Lₐ₂₀₅ | L_{b20} |
| 1847 | Lₐ₂₀₇ | L_{b20} | 1848 | Lₐ₂₁₀ | L_{b20} |
| 1849 | Lₐ₂₁₇ | L_{b20} | 1850 | Lₐ₂₁₉ | L_{b20} |
| 1851 | Lₐ₂₂₂ | L_{b20} | 1852 | Lₐ₂₂₉ | L_{b20} |
| 1853 | Lₐ₂₃₁ | L_{b20} | 1854 | Lₐ₂₃₄ | L_{b20} |
| 1855 | Lₐ₂₄₁ | L_{b20} | 1856 | Lₐ₂₄₃ | L_{b20} |
| 1857 | Lₐ₂₄₆ | L_{b20} | 1858 | Lₐ₂₅₃ | L_{b20} |
| 1859 | Lₐ₂₅₅ | L_{b20} | 1860 | Lₐ₂₅₈ | L_{b20} |
| 1861 | Lₐ₂₆₁ | L_{b20} | 1862 | Lₐ₂₆₃ | L_{b20} |
| 1863 | Lₐ₂₆₅ | L_{b20} | 1864 | Lₐ₂₆₇ | L_{b20} |
| 1865 | Lₐ₂₇₀ | L_{b20} | 1866 | Lₐ₂₇₇ | L_{b20} |
| 1867 | Lₐ₂₇₉ | L_{b20} | 1868 | Lₐ₂₈₂ | L_{b20} |
| 1869 | Lₐ₂₈₉ | L_{b20} | 1870 | Lₐ₂₉₁ | L_{b20} |
| 1871 | Lₐ₂₉₄ | L_{b20} | 1872 | Lₐ₃₀₁ | L_{b20} |
| 1873 | Lₐ₃₀₃ | L_{b20} | 1874 | Lₐ₃₀₆ | L_{b20} |
| 1875 | Lₐ₃₁₃ | L_{b20} | 1876 | Lₐ₃₁₅ | L_{b20} |
| 1877 | Lₐ₃₁₈ | L_{b20} | 1878 | Lₐ₃₂₅ | L_{b20} |
| 1879 | Lₐ₃₂₇ | L_{b20} | 1880 | Lₐ₃₃₀ | L_{b20} |
| 1881 | Lₐ₃₃₇ | L_{b20} | 1882 | Lₐ₃₃₉ | L_{b20} |
| 1883 | Lₐ₃₄₂ | L_{b20} | 1884 | Lₐ₃₄₉ | L_{b20} |
| 1885 | Lₐ₃₅₁ | L_{b20} | 1886 | Lₐ₃₅₄ | L_{b20} |
| 1887 | Lₐ₃₆₁ | L_{b20} | 1888 | Lₐ₃₆₃ | L_{b20} |
| 1889 | Lₐ₃₆₆ | L_{b20} | 1890 | Lₐ₃₇₁ | L_{b20} |
| 1891 | Lₐ₅₇₁ | L_{b20} | 1892 | Lₐ₅₇₃ | L_{b20} |
| 1893 | Lₐ₆₃₁ | L_{b20} | 1894 | Lₐ₆₃₃ | L_{b20} |
| 1895 | Lₐ₇₃₇ | L_{b20} | 1896 | Lₐ₉₃₇ | L_{b20} |
| 1897 | Lₐ₉₃₉ | L_{b20} | 1898 | Lₐ₉₉₇ | L_{b20} |
| 1899 | Lₐ₉₉₉ | L_{b20} | 1900 | Lₐ₁₀₀₉ | L_{b20} |
| 1901 | Lₐ₁₀₁₁ | L_{b20} | 1902 | Lₐ₁₀₂₁ | L_{b20} |
| 1903 | Lₐ₁₀₂₃ | L_{b20} | 1904 | Lₐ₁₁₀₃ | L_{b20} |
| 1905 | Lₐ₁₁₀₅ | L_{b20} | 1906 | Lₐ₁₁₀₈ | L_{b20} |
| 1907 | Lₐ₁₁₀₉ | L_{b20} | 1908 | Lₐ₁₁₁₁ | L_{b20} |
| 1909 | Lₐ₁₁₁₂ | L_{b20} | 1910 | Lₐ₁₁₁₅ | L_{b20} |
| 1911 | Lₐ₁₁₂₁ | L_{b20} | 1912 | Lₐ₁₁₂₆ | L_{b20} |
| 1913 | Lₐ₁₁₂₇ | L_{b20} | 1914 | Lₐ₁₁₂₉ | L_{b20} |
| 1915 | Lₐ₁₁₃₃ | L_{b20} | 1916 | Lₐ₁₁₅₇ | L_{b20} |
| 1917 | Lₐ₁₁₆₂ | L_{b20} | 1918 | Lₐ₁₁₆₃ | L_{b20} |
| 1919 | Lₐ₁₁₆₅ | L_{b20} | 1920 | Lₐ₁₁₆₉ | L_{b20} |
| 1921 | Lₐ₁₂₁₁ | L_{b20} | 1922 | Lₐ₁₂₁₆ | L_{b20} |
| 1923 | Lₐ₁₂₁₇ | L_{b20} | 1924 | Lₐ₁₂₁₉ | L_{b20} |
| 1925 | Lₐ₁₂₂₃ | L_{b20} | 1926 | Lₐ₁₂₄₇ | L_{b20} |
| 1927 | Lₐ₁₂₅₂ | L_{b20} | 1928 | Lₐ₁₂₅₃ | L_{b20} |
| 1929 | Lₐ₁₂₅₅ | L_{b20} | 1930 | Lₐ₁₂₅₉ | L_{b20} |
| 1931 | Lₐ₁₃₀₃ | L_{b20} | 1932 | Lₐ₁₃₀₅ | L_{b20} |
| 1933 | Lₐ₁₃₀₈ | L_{b20} | 1934 | Lₐ₁₃₁₅ | L_{b20} |
| 1935 | Lₐ₁₃₁₇ | L_{b20} | 1936 | Lₐ₁₃₂₀ | L_{b20} |
| 1937 | Lₐ₁₃₂₇ | L_{b20} | 1938 | Lₐ₁₃₂₉ | L_{b20} |
| 1939 | Lₐ₁₃₃₂ | L_{b20} | 1940 | Lₐ₁₃₃₉ | L_{b20} |
| 1941 | Lₐ₁₃₄₁ | L_{b20} | 1942 | Lₐ₁₃₄₄ | L_{b20} |
| 1943 | Lₐ₁₃₅₁ | L_{b20} | 1944 | Lₐ₁₃₅₃ | L_{b20} |
| 1945 | Lₐ₁₃₅₆ | L_{b20} | 1946 | Lₐ₁₃₅₉ | L_{b20} |
| 1947 | Lₐ₁₃₆₁ | L_{b20} | 1948 | Lₐ₁₃₆₃ | L_{b20} |
| 1949 | Lₐ₁₃₆₅ | L_{b20} | 1950 | Lₐ₁₃₆₈ | L_{b20} |
| 1951 | Lₐ₁₃₇₅ | L_{b20} | 1952 | Lₐ₁₃₇₇ | L_{b20} |
| 1953 | Lₐ₁₃₈₇ | L_{b20} | 1954 | Lₐ₁₃₈₉ | L_{b20} |
| 1955 | Lₐ₁₄₆₉ | L_{b20} | 1956 | Lₐ₁₆₆₉ | L_{b20} |
| 1957 | Lₐ₁₆₇₁ | L_{b20} | 1958 | Lₐ₁₇₂₉ | L_{b20} |
| 1959 | Lₐ₁₇₃₁ | L_{b20} | 1960 | Lₐ₁₇₄₁ | L_{b20} |
| 1961 | Lₐ₁₇₄₃ | L_{b20} | 1962 | Lₐ₁₇₅₃ | L_{b20} |
| 1963 | Lₐ₁₇₅₅ | L_{b20} | 1964 | Lₐ₁₈₃₅ | L_{b20} |
| 1965 | Lₐ₂₀₃₅ | L_{b20} | 1966 | Lₐ₂₀₃₇ | L_{b20} |
| 1967 | Lₐ₂₀₉₅ | L_{b20} | 1968 | Lₐ₂₀₉₇ | L_{b20} |
| 1969 | Lₐ₂₁₀₇ | L_{b20} | 1970 | Lₐ₂₁₀₉ | L_{b20} |
| 1971 | Lₐ₂₁₁₉ | L_{b20} | 1972 | Lₐ₂₁₂₁ | L_{b20} |
| 1973 | Lₐ₂₂₀₁ | L_{b20} | 1974 | Lₐ₂₄₀₁ | L_{b20} |
| 1975 | Lₐ₂₄₀₃ | L_{b20} | 1976 | Lₐ₂₄₆₁ | L_{b20} |
| 1977 | Lₐ₂₄₆₃ | L_{b20} | 1978 | Lₐ₂₄₇₃ | L_{b20} |
| 1979 | Lₐ₂₄₇₅ | L_{b20} | 1980 | Lₐ₂₄₈₅ | L_{b20} |
| 1981 | Lₐ₂₄₈₇ | L_{b20} | 1982 | Lₐ₂₅₆₇ | L_{b20} |
| 1983 | Lₐ₂₇₆₇ | L_{b20} | 1984 | Lₐ₂₇₆₉ | L_{b20} |
| 1985 | Lₐ₂₈₂₇ | L_{b20} | 1986 | Lₐ₂₈₂₉ | L_{b20} |
| 1987 | Lₐ₂₈₅₁ | L_{b20} | 1988 | Lₐ₂₈₅₃ | L_{b20} |
| 1989 | Lₐ₂₉₃₃ | L_{b20} | 1990 | Lₐ₂₉₃₅ | L_{b20} |
| 1991 | Lₐ₂₉₃₈ | L_{b20} | 1992 | Lₐ₂₉₃₉ | L_{b20} |
| 1993 | Lₐ₂₉₄₁ | L_{b20} | 1994 | Lₐ₂₉₄₂ | L_{b20} |
| 1995 | Lₐ₂₉₄₅ | L_{b20} | 1996 | Lₐ₂₉₅₁ | L_{b20} |
| 1997 | Lₐ₂₉₅₆ | L_{b20} | 1998 | Lₐ₂₉₅₇ | L_{b20} |
| 1999 | Lₐ₂₉₅₉ | L_{b20} | 2000 | Lₐ₂₉₆₃ | L_{b20} |
| 2001 | Lₐ₂₉₈₇ | L_{b20} | 2002 | Lₐ₂₉₉₂ | L_{b20} |
| 2003 | Lₐ₂₉₉₃ | L_{b20} | 2004 | Lₐ₂₉₉₅ | L_{b20} |
| 2005 | Lₐ₂₉₉₉ | L_{b20} | 2006 | Lₐ₃₀₄₁ | L_{b20} |
| 2007 | Lₐ₃₀₄₆ | L_{b20} | 2008 | Lₐ₃₀₄₇ | L_{b20} |
| 2009 | Lₐ₃₀₄₉ | L_{b20} | 2010 | Lₐ₃₀₅₃ | L_{b20} |
| 2011 | Lₐ₃₀₇₇ | L_{b20} | 2012 | Lₐ₃₀₈₂ | L_{b20} |
| 2013 | Lₐ₃₀₈₃ | L_{b20} | 2014 | Lₐ₃₀₈₅ | L_{b20} |
| 2015 | Lₐ₃₀₈₉ | L_{b20} | 2016 | Lₐ₃₁₃₃ | L_{b20} |
| 2017 | Lₐ₃₁₃₅ | L_{b20} | 2018 | Lₐ₃₁₃₈ | L_{b20} |
| 2019 | Lₐ₃₁₄₅ | L_{b20} | 2020 | Lₐ₃₁₄₇ | L_{b20} |
| 2021 | Lₐ₃₁₅₀ | L_{b20} | 2022 | Lₐ₃₁₆₉ | L_{b20} |
| 2023 | Lₐ₃₁₇₁ | L_{b20} | 2024 | Lₐ₃₁₇₄ | L_{b20} |
| 2025 | Lₐ₃₁₈₁ | L_{b20} | 2026 | Lₐ₃₁₈₃ | L_{b20} |
| 2027 | Lₐ₃₁₈₆ | L_{b20} | 2028 | Lₐ₃₁₈₉ | L_{b20} |
| 2029 | Lₐ₃₁₉₁ | L_{b20} | 2030 | Lₐ₃₁₉₃ | L_{b20} |
| 2031 | Lₐ₃₁₉₅ | L_{b20} | 2032 | Lₐ₃₁₉₈ | L_{b20} |
| 2033 | Lₐ₃₂₀₅ | L_{b20} | 2034 | Lₐ₃₂₀₇ | L_{b20} |
| 2035 | Lₐ₃₂₁₇ | L_{b20} | 2036 | Lₐ₃₂₁₉ | L_{b20} |
| 2037 | Lₐ₃₂₂₉ | L_{b20} | 2038 | Lₐ₃₂₃₁ | L_{b20} |
| 2039 | Lₐ₃₂₃₄ | L_{b20} | 2040 | Lₐ₃₂₄₁ | L_{b20} |
| 2041 | Lₐ₃₂₄₃ | L_{b20} | 2042 | Lₐ₃₂₄₆ | L_{b20} |
| 2043 | Lₐ₃₂₅₃ | L_{b20} | 2044 | Lₐ₃₂₅₅ | L_{b20} |
| 2045 | Lₐ₃₂₅₈ | L_{b20} | 2046 | Lₐ₃₂₆₅ | L_{b20} |
| 2047 | Lₐ₃₂₆₇ | L_{b20} | 2048 | Lₐ₃₂₇₀ | L_{b20} |
| 2049 | Lₐ₃₂₇₇ | L_{b20} | 2050 | Lₐ₃₂₇₉ | L_{b20} |
| 2051 | Lₐ₃₂₈₂ | L_{b20} | 2052 | Lₐ₃₂₈₉ | L_{b20} |
| 2053 | Lₐ₃₂₉₁ | L_{b20} | 2054 | Lₐ₃₂₉₄ | L_{b20} |
| 2055 | Lₐ₃₂₉₉ | L_{b20} | 2056 | Lₐ₃₄₉₉ | L_{b20} |
| 2057 | Lₐ₃₅₀₁ | L_{b20} | 2058 | Lₐ₃₅₅₉ | L_{b20} |
| 2059 | Lₐ₃₅₆₁ | L_{b20} | 2060 | Lₐ₃₅₇₁ | L_{b20} |
| 2061 | Lₐ₃₅₇₃ | L_{b20} | 2062 | Lₐ₃₅₈₃ | L_{b20} |
| 2063 | Lₐ₃₅₈₅ | L_{b20} | 2064 | Lₐ₃₆₆₅ | L_{b20} |
| 2065 | Lₐ₃₆₆₇ | L_{b20} | 2066 | Lₐ₃₆₇₀ | L_{b20} |
| 2067 | Lₐ₃₆₇₁ | L_{b20} | 2068 | Lₐ₃₆₇₃ | L_{b20} |
| 2069 | Lₐ₃₆₇₄ | L_{b20} | 2070 | Lₐ₃₆₇₇ | L_{b20} |
| 2071 | Lₐ₃₆₈₃ | L_{b20} | 2072 | Lₐ₃₆₈₈ | L_{b20} |
| 2073 | Lₐ₃₆₈₉ | L_{b20} | 2074 | Lₐ₃₆₉₁ | L_{b20} |
| 2075 | Lₐ₃₆₉₅ | L_{b20} | 2076 | Lₐ₃₇₁₉ | L_{b20} |
| 2077 | Lₐ₃₇₂₄ | L_{b20} | 2078 | Lₐ₃₇₂₅ | L_{b20} |
| 2079 | Lₐ₃₇₂₇ | L_{b20} | 2080 | Lₐ₃₇₃₁ | L_{b20} |
| 2081 | Lₐ₃₇₇₃ | L_{b20} | 2082 | Lₐ₃₇₇₈ | L_{b20} |
| 2083 | Lₐ₃₇₇₉ | L_{b20} | 2084 | Lₐ₃₇₈₁ | L_{b20} |
| 2085 | Lₐ₃₇₈₅ | L_{b20} | 2086 | Lₐ₃₈₀₉ | L_{b20} |
| 2087 | Lₐ₃₈₁₄ | L_{b20} | 2088 | Lₐ₃₈₁₅ | L_{b20} |
| 2089 | Lₐ₃₈₁₇ | L_{b20} | 2090 | Lₐ₃₈₂₁ | L_{b20} |
| 2091 | Lₐ₃₈₆₅ | L_{b20} | 2092 | Lₐ₃₈₆₇ | L_{b20} |
| 2093 | Lₐ₃₈₇₀ | L_{b20} | 2094 | Lₐ₃₈₇₇ | L_{b20} |
| 2095 | Lₐ₃₈₇₉ | L_{b20} | 2096 | Lₐ₃₈₈₂ | L_{b20} |
| 2097 | Lₐ₃₈₈₉ | L_{b20} | 2098 | Lₐ₃₈₉₁ | L_{b20} |
| 2099 | Lₐ₃₈₉₄ | L_{b20} | 2100 | Lₐ₃₉₀₁ | L_{b20} |
| 2101 | Lₐ₃₉₀₃ | L_{b20} | 2102 | Lₐ₃₉₀₆ | L_{b20} |
| 2103 | Lₐ₃₉₁₃ | L_{b20} | 2104 | Lₐ₃₉₁₅ | L_{b20} |
| 2105 | Lₐ₃₉₁₈ | L_{b20} | 2106 | Lₐ₃₉₂₁ | L_{b20} |
| 2107 | Lₐ₃₉₂₃ | L_{b20} | 2108 | Lₐ₃₉₂₄ | L_{b20} |
| 2109 | Lₐ₃₉₂₅ | L_{b20} | 2110 | Lₐ₃₉₂₇ | L_{b20} |
| 2111 | Lₐ₃₉₂₈ | L_{b20} | 2112 | Lₐ₃₉₃₀ | L_{b20} |
| 2113 | Lₐ₃₉₃₇ | L_{b20} | 2114 | Lₐ₃₉₃₉ | L_{b20} |
| 2115 | Lₐ₃₉₄₉ | L_{b20} | 2116 | Lₐ₃₉₅₁ | L_{b20} |
| 2117 | Lₐ₃₉₆₁ | L_{b20} | 2118 | Lₐ₃₉₆₃ | L_{b20} |
| 2119 | Lₐ₃₉₆₆ | L_{b20} | 2120 | Lₐ₃₉₇₃ | L_{b20} |
| 2121 | Lₐ₃₉₇₅ | L_{b20} | 2122 | Lₐ₃₉₇₈ | L_{b20} |
| 2123 | Lₐ₃₉₈₅ | L_{b20} | 2124 | Lₐ₃₉₈₇ | L_{b20} |
| 2125 | Lₐ₃₉₉₀ | L_{b20} | 2126 | Lₐ₃₉₉₇ | L_{b20} |
| 2127 | Lₐ₃₉₉₉ | L_{b20} | 2128 | Lₐ₄₀₀₂ | L_{b20} |
| 2129 | Lₐ₄₀₀₉ | L_{b20} | 2130 | Lₐ₄₀₁₁ | L_{b20} |
| 2131 | Lₐ₄₀₁₄ | L_{b20} | 2132 | Lₐ₄₀₂₁ | L_{b20} |
| 2133 | Lₐ₄₀₂₃ | L_{b20} | 2134 | Lₐ₄₀₂₆ | L_{b20} |
| 2135 | Lₐ₄₀₃₁ | L_{b20} | 2136 | Lₐ₄₀₃₆ | L_{b20} |
| 2137 | Lₐ₄₀₃₇ | L_{b20} | 2138 | Lₐ₄₀₃₉ | L_{b20} |
| 2139 | Lₐ₄₀₄₃ | L_{b20} | 2140 | Lₐ₄₀₄₉ | L_{b20} |
| 2141 | Lₐ₄₀₅₄ | L_{b20} | 2142 | Lₐ₄₀₅₅ | L_{b20} |
| 2143 | Lₐ₄₀₅₇ | L_{b20} | 2144 | Lₐ₄₀₆₁ | L_{b20} |
| 2145 | Lₐ₄₁₃₉ | L_{b20} | 2146 | Lₐ₄₁₄₄ | L_{b20} |
| 2147 | Lₐ₄₁₄₅ | L_{b20} | 2148 | Lₐ₄₁₄₇ | L_{b20} |
| 2149 | Lₐ₄₁₅₁ | L_{b20} | 2150 | Lₐ₄₂₃₁ | L_{b20} |
| 2151 | Lₐ₄₂₃₃ | L_{b20} | 2152 | Lₐ₄₂₃₆ | L_{b20} |
| 2153 | Lₐ₄₂₄₃ | L_{b20} | 2154 | Lₐ₄₂₄₅ | L_{b20} |
| 2155 | Lₐ₄₂₄₈ | L_{b20} | 2156 | Lₐ₄₂₆₇ | L_{b20} |
| 2157 | Lₐ₄₂₆₉ | L_{b20} | 2158 | Lₐ₄₂₇₂ | L_{b20} |
| 2159 | Lₐ₄₂₈₇ | L_{b20} | 2160 | Lₐ₄₂₈₉ | L_{b20} |
| 2161 | Lₐ₄₂₉₁ | L_{b20} | 2162 | Lₐ₄₂₉₃ | L_{b20} |
| 2163 | Lₐ₄₂₉₄ | L_{b20} | 2164 | Lₐ₄₂₉₆ | L_{b20} |
| 2165 | Lₐ₄₃₀₃ | L_{b20} | 2166 | Lₐ₄₃₀₅ | L_{b20} |
| 2167 | Lₐ₄₃₁₅ | L_{b20} | 2168 | Lₐ₄₃₁₇ | L_{b20} |
| 2169 | Lₐ₄₃₂₇ | L_{b20} | 2170 | Lₐ₄₃₂₉ | L_{b20} |
| 2171 | Lₐ₄₃₃₂ | L_{b20} | 2172 | Lₐ₄₃₃₉ | L_{b20} |
| 2173 | Lₐ₄₃₄₁ | L_{b20} | 2174 | Lₐ₄₃₄₄ | L_{b20} |
| 2175 | Lₐ₄₃₆₃ | L_{b20} | 2176 | Lₐ₄₃₆₅ | L_{b20} |
| 2177 | Lₐ₄₃₆₈ | L_{b20} | 2178 | Lₐ₄₃₇₅ | L_{b20} |
| 2179 | Lₐ₄₃₇₇ | L_{b20} | 2180 | Lₐ₄₃₈₀ | L_{b20} |
| 2181 | Lₐ₄₃₉₇ | L_{b20} | 2182 | Lₐ₄₃₉₉ | L_{b20} |
| 2183 | Lₐ₄₄₀₂ | L_{b20} | 2184 | Lₐ₄₄₀₃ | L_{b20} |
| 2185 | Lₐ₄₄₀₅ | L_{b20} | 2186 | Lₐ₄₄₀₆ | L_{b20} |
| 2187 | Lₐ₄₄₀₉ | L_{b20} | 2188 | Lₐ₄₄₁₅ | L_{b20} |
| 2189 | Lₐ₄₄₂₀ | L_{b20} | 2190 | Lₐ₄₄₂₃ | L_{b20} |
| 2191 | Lₐ₄₄₂₇ | L_{b20} | 2192 | Lₐ₄₄₅₁ | L_{b20} |
| 2193 | Lₐ₄₄₅₆ | L_{b20} | 2194 | Lₐ₄₄₅₇ | L_{b20} |
| 2195 | Lₐ₄₄₅₉ | L_{b20} | 2196 | Lₐ₄₄₆₃ | L_{b20} |
| 2197 | Lₐ₄₅₉₇ | L_{b20} | 2198 | Lₐ₄₅₉₉ | L_{b20} |
| 2199 | Lₐ₄₆₀₂ | L_{b20} | 2200 | Lₐ₄₆₀₉ | L_{b20} |
| 2201 | Lₐ₄₆₁₁ | L_{b20} | 2202 | Lₐ₄₆₂₁ | L_{b20} |
| 2203 | Lₐ₄₆₂₃ | L_{b20} | 2204 | Lₐ₄₆₃₃ | L_{b20} |
| 2205 | Lₐ₄₆₃₅ | L_{b20} | 2206 | Lₐ₄₆₄₅ | L_{b20} |
| 2207 | Lₐ₄₆₄₇ | L_{b20} | 2208 | Lₐ₄₆₅₃ | L_{b20} |
| 2209 | Lₐ₄₆₅₅ | L_{b20} | 2210 | Lₐ₄₆₅₇ | L_{b20} |
| 2211 | Lₐ₄₆₅₉ | L_{b20} | 2212 | Lₐ₄₆₆₂ | L_{b20} |
| 2213 | Lₐ₄₆₆₉ | L_{b20} | 2214 | Lₐ₄₆₇₁ | L_{b20} |
| 2215 | Lₐ₄₆₈₁ | L_{b20} | 2216 | Lₐ₄₆₈₃ | L_{b20} |
| 2217 | Lₐ₄₆₉₃ | L_{b20} | 2218 | Lₐ₄₆₉₅ | L_{b20} |
| 2219 | Lₐ₄₆₉₈ | L_{b20} | 2220 | Lₐ₄₇₀₅ | L_{b20} |
| 2221 | Lₐ₄₇₀₇ | L_{b20} | 2222 | Lₐ₄₇₁₀ | L_{b20} |
| 2223 | Lₐ₄₇₂₉ | L_{b20} | 2224 | Lₐ₄₇₃₁ | L_{b20} |
| 2225 | Lₐ₄₇₃₄ | L_{b20} | 2226 | Lₐ₄₇₆₃ | L_{b20} |
| 2227 | Lₐ₄₉₆₃ | L_{b20} | 2228 | Lₐ₄₉₆₅ | L_{b20} |
| 2229 | Lₐ₄₉₆₈ | L_{b20} | 2230 | Lₐ₅₀₂₃ | L_{b20} |
| 2231 | Lₐ₅₀₂₅ | L_{b20} | 2232 | Lₐ₅₀₃₅ | L_{b20} |
| 2233 | Lₐ₅₀₃₇ | L_{b20} | 2234 | Lₐ₅₀₄₇ | L_{b20} |
| 2235 | Lₐ₅₀₄₉ | L_{b20} | 2236 | Lₐ₅₁₂₉ | L_{b20} |
| 2237 | Lₐ₅₁₃₄ | L_{b20} | 2238 | Lₐ₅₁₃₅ | L_{b20} |
| 2239 | Lₐ₅₁₃₇ | L_{b20} | 2240 | Lₐ₅₁₄₁ | L_{b20} |
| 2241 | Lₐ₅₁₄₇ | L_{b20} | 2242 | Lₐ₅₁₅₂ | L_{b20} |
| 2243 | Lₐ₅₁₅₃ | L_{b20} | 2244 | Lₐ₅₁₅₅ | L_{b20} |
| 2245 | Lₐ₅₁₅₉ | L_{b20} | 2246 | Lₐ₅₂₃₇ | L_{b20} |
| 2247 | Lₐ₅₂₄₂ | L_{b20} | 2248 | Lₐ₅₂₄₃ | L_{b20} |
| 2249 | Lₐ₅₂₄₅ | L_{b20} | 2250 | Lₐ₅₂₄₉ | L_{b20} |
| 2251 | Lₐ₅₃₂₉ | L_{b20} | 2252 | Lₐ₅₃₃₁ | L_{b20} |
| 2253 | Lₐ₅₃₃₄ | L_{b20} | 2254 | Lₐ₅₃₄₁ | L_{b20} |
| 2255 | Lₐ₅₃₄₃ | L_{b20} | 2256 | Lₐ₅₃₄₆ | L_{b20} |
| 2257 | Lₐ₅₃₆₅ | L_{b20} | 2258 | Lₐ₅₃₆₇ | L_{b20} |
| 2259 | Lₐ₅₃₇₀ | L_{b20} | 2260 | Lₐ₅₃₈₅ | L_{b20} |
| 2261 | Lₐ₅₃₈₇ | L_{b20} | 2262 | Lₐ₅₃₈₉ | L_{b20} |
| 2263 | Lₐ₅₃₉₁ | L_{b20} | 2264 | Lₐ₅₃₉₂ | L_{b20} |
| 2265 | Lₐ₅₃₉₄ | L_{b20} | 2266 | Lₐ₅₄₀₁ | L_{b20} |
| 2267 | Lₐ₅₄₀₃ | L_{b20} | 2268 | Lₐ₅₄₁₃ | L_{b20} |
| 2269 | Lₐ₅₄₁₅ | L_{b20} | 2270 | Lₐ₅₄₂₅ | L_{b20} |
| 2271 | Lₐ₅₄₂₇ | L_{b20} | 2272 | Lₐ₅₄₃₀ | L_{b20} |
| 2273 | Lₐ₅₄₆₁ | L_{b20} | 2274 | Lₐ₅₄₆₃ | L_{b20} |
| 2275 | Lₐ₅₄₆₆ | L_{b20} | 2276 | Lₐ₅₄₉₅ | L_{b20} |
| 2277 | Lₐ₅₆₉₅ | L_{b20} | 2278 | Lₐ₅₆₉₇ | L_{b20} |
| 2279 | Lₐ₅₇₅₅ | L_{b20} | 2280 | Lₐ₅₇₅₇ | L_{b20} |
| 2281 | Lₐ₅₇₆₀ | L_{b20} | 2282 | Lₐ₅₇₆₇ | L_{b20} |
| 2283 | Lₐ₅₇₆₉ | L_{b20} | 2284 | Lₐ₅₇₇₉ | L_{b20} |
| 2285 | Lₐ₅₇₈₁ | L_{b20} | 2286 | Lₐ₅₈₆₁ | L_{b20} |
| 2287 | Lₐ₅₈₆₆ | L_{b20} | 2288 | Lₐ₅₈₆₇ | L_{b20} |
| 2289 | Lₐ₅₈₆₉ | L_{b20} | 2290 | Lₐ₅₈₇₃ | L_{b20} |
| 2291 | Lₐ₅₈₇₉ | L_{b20} | 2292 | Lₐ₅₈₈₄ | L_{b20} |
| 2293 | Lₐ₅₈₈₅ | L_{b20} | 2294 | Lₐ₅₈₈₇ | L_{b20} |
| 2295 | Lₐ₅₈₉₁ | L_{b20} | 2296 | Lₐ₅₉₆₉ | L_{b20} |
| 2297 | Lₐ₅₉₇₄ | L_{b20} | 2298 | Lₐ₅₉₇₅ | L_{b20} |
| 2299 | Lₐ₅₉₇₇ | L_{b20} | 2300 | Lₐ₅₉₈₁ | L_{b20} |
| 2301 | Lₐ₆₀₅₇ | L_{b20} | 2302 | Lₐ₆₀₅₉ | L_{b20} |
| 2303 | Lₐ₆₀₆₁ | L_{b20} | 2304 | Lₐ₆₀₆₃ | L_{b20} |
| 2305 | Lₐ₆₀₆₆ | L_{b20} | 2306 | Lₐ₆₀₇₃ | L_{b20} |
| 2307 | Lₐ₆₀₇₅ | L_{b20} | 2308 | Lₐ₆₀₇₈ | L_{b20} |
| 2309 | Lₐ₆₀₈₅ | L_{b20} | 2310 | Lₐ₆₀₈₇ | L_{b20} |
| 2311 | Lₐ₆₀₉₇ | L_{b20} | 2312 | Lₐ₆₀₉₉ | L_{b20} |
| 2313 | Lₐ₆₁₁₇ | L_{b20} | 2314 | Lₐ₆₁₁₉ | L_{b20} |
| 2315 | Lₐ₆₁₂₁ | L_{b20} | 2316 | Lₐ₆₁₂₃ | L_{b20} |
| 2317 | Lₐ₆₁₂₆ | L_{b20} | 2318 | Lₐ₆₁₃₃ | L_{b20} |
| 2319 | Lₐ₆₁₃₅ | L_{b20} | 2320 | Lₐ₆₁₄₅ | L_{b20} |
| 2321 | Lₐ₆₁₄₇ | L_{b20} | 2322 | Lₐ₆₁₅₇ | L_{b20} |
| 2323 | Lₐ₆₁₅₉ | L_{b20} | 2324 | Lₐ₆₁₆₂ | L_{b20} |
| 2325 | Lₐ₆₁₆₉ | L_{b20} | 2326 | Lₐ₆₁₇₁ | L_{b20} |
| 2327 | Lₐ₆₁₇₄ | L_{b20} | 2328 | Lₐ₆₁₉₃ | L_{b20} |
| 2329 | Lₐ₆₁₉₅ | L_{b20} | 2330 | Lₐ₆₁₉₈ | L_{b20} |
| 2331 | Lₐ₆₂₀₅ | L_{b20} | 2332 | Lₐ₆₂₀₇ | L_{b20} |
| 2333 | Lₐ₆₂₂₇ | L_{b20} | 2334 | Lₐ₆₂₃₂ | L_{b20} |
| 2335 | Lₐ₆₂₃₃ | L_{b20} | 2336 | Lₐ₆₂₃₅ | L_{b20} |
| 2337 | Lₐ₆₂₃₉ | L_{b20} | 2338 | Lₐ₆₂₄₅ | L_{b20} |
| 2339 | Lₐ₆₂₅₀ | L_{b20} | 2340 | Lₐ₆₂₅₁ | L_{b20} |
| 2341 | Lₐ₆₂₅₃ | L_{b20} | 2342 | Lₐ₆₂₅₇ | L_{b20} |
| 2343 | Lₐ₆₃₃₅ | L_{b20} | 2344 | Lₐ₆₃₄₀ | L_{b20} |
| 2345 | Lₐ₆₃₄₁ | L_{b20} | 2346 | Lₐ₆₃₄₃ | L_{b20} |
| 2347 | Lₐ₆₃₄₇ | L_{b20} | 2348 | Lₐ₆₄₂₃ | L_{b20} |
| 2349 | Lₐ₆₄₂₅ | L_{b20} | 2350 | Lₐ₆₄₂₇ | L_{b20} |
| 2351 | Lₐ₆₄₂₉ | L_{b20} | 2352 | Lₐ₆₄₃₂ | L_{b20} |
| 2353 | Lₐ₆₄₃₉ | L_{b20} | 2354 | Lₐ₆₄₄₁ | L_{b20} |
| 2355 | Lₐ₆₄₄₄ | L_{b20} | 2356 | Lₐ₆₄₆₃ | L_{b20} |
| 2357 | Lₐ₆₄₆₅ | L_{b20} | 2358 | Lₐ₆₄₆₈ | L_{b20} |
| 2359 | Lₐ₆₄₈₃ | L_{b20} | 2360 | Lₐ₆₄₈₅ | L_{b20} |
| 2361 | Lₐ₆₄₈₇ | L_{b20} | 2362 | Lₐ₆₄₈₉ | L_{b20} |
| 2363 | Lₐ₆₄₉₂ | L_{b20} | 2364 | Lₐ₆₄₉₉ | L_{b20} |
| 2365 | Lₐ₆₅₀₁ | L_{b20} | 2366 | Lₐ₆₅₁₁ | L_{b20} |
| 2367 | Lₐ₆₅₁₃ | L_{b20} | 2368 | Lₐ₆₅₂₃ | L_{b20} |
| 2369 | Lₐ₆₅₂₅ | L_{b20} | 2370 | Lₐ₆₅₂₈ | L_{b20} |
| 2371 | Lₐ₆₅₃₅ | L_{b20} | 2372 | Lₐ₆₅₃₇ | L_{b20} |
| 2373 | Lₐ₆₅₄₀ | L_{b20} | 2374 | Lₐ₆₅₅₉ | L_{b20} |
| 2375 | Lₐ₆₅₆₁ | L_{b20} | 2376 | Lₐ₆₅₆₄ | L_{b20} |
| 2377 | Lₐ₆₅₇₁ | L_{b20} | 2378 | Lₐ₆₅₇₃ | L_{b20} |
| 2379 | Lₐ₆₅₉₃ | L_{b20} | 2380 | Lₐ₆₅₉₈ | L_{b20} |
| 2381 | Lₐ₆₅₉₉ | L_{b20} | 2382 | Lₐ₆₆₀₁ | L_{b20} |
| 2383 | Lₐ₆₆₀₅ | L_{b20} | 2384 | Lₐ₆₆₁₁ | L_{b20} |
| 2385 | Lₐ₆₆₁₆ | L_{b20} | 2386 | Lₐ₆₆₁₉ | L_{b20} |
| 2387 | Lₐ₆₆₂₃ | L_{b20} | 2388 | Lₐ₆₇₀₀ | L_{b20} |
| 2389 | Lₐ₆₇₀₁ | L_{b20} | 2390 | Lₐ₆₇₀₃ | L_{b20} |
| 2391 | Lₐ₆₇₀₆ | L_{b20} | 2392 | Lₐ₆₇₀₇ | L_{b20} |
| 2393 | Lₐ₆₇₀₉ | L_{b20} | 2394 | Lₐ₆₇₁₃ | L_{b20} |
| 2395 | Lₐ₆₇₄₂ | L_{b20} | 2396 | Lₐ₆₇₄₅ | L_{b20} |
| 2397 | Lₐ₆₇₉₃ | L_{b20} | 2398 | Lₐ₆₇₉₅ | L_{b20} |
| 2399 | Lₐ₆₇₉₈ | L_{b20} | 2400 | Lₐ₆₈₀₅ | L_{b20} |
| 2401 | Lₐ₆₈₀₇ | L_{b20} | 2402 | Lₐ₆₈₁₀ | L_{b20} |
| 2403 | Lₐ₆₈₂₉ | L_{b20} | 2404 | Lₐ₆₈₃₁ | L_{b20} |
| 2405 | Lₐ₆₈₃₄ | L_{b20} | 2406 | Lₐ₆₈₄₉ | L_{b20} |
| 2407 | Lₐ₆₈₅₁ | L_{b20} | 2408 | Lₐ₆₈₅₃ | L_{b20} |
| 2409 | Lₐ₆₈₅₅ | L_{b20} | 2410 | Lₐ₆₈₅₈ | L_{b20} |
| 2411 | Lₐ₆₈₆₅ | L_{b20} | 2412 | Lₐ₆₈₆₇ | L_{b20} |
| 2413 | Lₐ₆₈₇₇ | L_{b20} | 2414 | Lₐ₆₈₇₉ | L_{b20} |
| 2415 | Lₐ₆₈₈₉ | L_{b20} | 2416 | Lₐ₆₈₉₁ | L_{b20} |
| 2417 | Lₐ₆₈₉₄ | L_{b20} | 2418 | Lₐ₆₉₀₁ | L_{b20} |
| 2419 | Lₐ₆₉₀₃ | L_{b20} | 2420 | Lₐ₆₉₂₅ | L_{b20} |
| 2421 | Lₐ₆₉₂₇ | L_{b20} | 2422 | Lₐ₆₉₃₀ | L_{b20} |
| 2423 | Lₐ₆₉₃₇ | L_{b20} | 2424 | Lₐ₆₉₃₉ | L_{b20} |
| 2425 | Lₐ₅ | L_{b22} | 2426 | Lₐ₇ | L_{b22} |
| 2427 | Lₐ₁₀ | L_{b22} | 2428 | Lₐ₁₁ | L_{b22} |
| 2429 | Lₐ₁₃ | L_{b22} | 2430 | Lₐ₁₄ | L_{b22} |
| 2431 | Lₐ₁₇ | L_{b22} | 2432 | Lₐ₂₃ | L_{b22} |
| 2433 | Lₐ₂₈ | L_{b22} | 2434 | Lₐ₂₉ | L_{b22} |
| 2435 | Lₐ₃₁ | L_{b22} | 2436 | Lₐ₃₅ | L_{b22} |
| 2437 | Lₐ₅₉ | L_{b22} | 2438 | Lₐ₆₄ | L_{b22} |
| 2439 | Lₐ₆₅ | L_{b22} | 2440 | Lₐ₆₇ | L_{b22} |
| 2441 | Lₐ₇₁ | L_{b22} | 2442 | Lₐ₁₁₃ | L_{b22} |
| 2443 | Lₐ₁₁₈ | L_{b22} | 2444 | Lₐ₁₁₉ | L_{b22} |
| 2445 | Lₐ₁₂₁ | L_{b22} | 2446 | Lₐ₁₂₅ | L_{b22} |
| 2447 | Lₐ₁₄₉ | L_{b22} | 2448 | Lₐ₁₅₄ | L_{b22} |
| 2449 | Lₐ₁₅₅ | L_{b22} | 2450 | Lₐ₁₅₇ | L_{b22} |
| 2451 | Lₐ₁₆₁ | L_{b22} | 2452 | Lₐ₂₀₅ | L_{b22} |
| 2453 | Lₐ₂₀₇ | L_{b22} | 2454 | Lₐ₂₁₀ | L_{b22} |
| 2455 | Lₐ₂₁₇ | L_{b22} | 2456 | Lₐ₂₁₉ | L_{b22} |
| 2457 | Lₐ₂₂₂ | L_{b22} | 2458 | Lₐ₂₂₉ | L_{b22} |
| 2459 | Lₐ₂₃₁ | L_{b22} | 2460 | Lₐ₂₃₄ | L_{b22} |
| 2461 | Lₐ₂₄₁ | L_{b22} | 2462 | Lₐ₂₄₃ | L_{b22} |
| 2463 | Lₐ₂₄₆ | L_{b22} | 2464 | Lₐ₂₅₃ | L_{b22} |
| 2465 | Lₐ₂₅₅ | L_{b22} | 2466 | Lₐ₂₅₈ | L_{b22} |
| 2467 | Lₐ₂₆₁ | L_{b22} | 2468 | Lₐ₂₆₃ | L_{b22} |
| 2469 | Lₐ₂₆₅ | L_{b22} | 2470 | Lₐ₂₆₇ | L_{b22} |
| 2471 | Lₐ₂₇₀ | L_{b22} | 2472 | Lₐ₂₇₇ | L_{b22} |
| 2473 | Lₐ₂₇₉ | L_{b22} | 2474 | Lₐ₂₈₂ | L_{b22} |
| 2475 | Lₐ₂₈₉ | L_{b22} | 2476 | Lₐ₂₉₁ | L_{b22} |
| 2477 | Lₐ₂₉₄ | L_{b22} | 2478 | Lₐ₃₀₁ | L_{b22} |
| 2479 | Lₐ₃₀₃ | L_{b22} | 2480 | Lₐ₃₀₆ | L_{b22} |
| 2481 | Lₐ₃₁₃ | L_{b22} | 2482 | Lₐ₃₁₅ | L_{b22} |
| 2483 | Lₐ₃₁₈ | L_{b22} | 2484 | Lₐ₃₂₅ | L_{b22} |
| 2485 | Lₐ₃₂₇ | L_{b22} | 2486 | Lₐ₃₃₀ | L_{b22} |
| 2487 | Lₐ₃₃₇ | L_{b22} | 2488 | Lₐ₃₃₉ | L_{b22} |
| 2489 | Lₐ₃₄₂ | L_{b22} | 2490 | Lₐ₃₄₉ | L_{b22} |
| 2491 | Lₐ₃₅₁ | L_{b22} | 2492 | Lₐ₃₅₄ | L_{b22} |
| 2493 | Lₐ₃₆₁ | L_{b22} | 2494 | Lₐ₃₆₃ | L_{b22} |
| 2495 | Lₐ₃₆₆ | L_{b22} | 2496 | Lₐ₃₇₁ | L_{b22} |
| 2497 | Lₐ₅₇₁ | L_{b22} | 2498 | Lₐ₅₇₃ | L_{b22} |
| 2499 | Lₐ₆₃₁ | L_{b22} | 2500 | Lₐ₆₃₃ | L_{b22} |
| 2501 | Lₐ₇₃₇ | L_{b22} | 2502 | Lₐ₉₃₇ | L_{b22} |
| 2503 | Lₐ₉₃₉ | L_{b22} | 2504 | Lₐ₉₉₇ | L_{b22} |
| 2505 | Lₐ₉₉₉ | L_{b22} | 2506 | Lₐ₁₀₀₉ | L_{b22} |
| 2507 | Lₐ₁₀₁₁ | L_{b22} | 2508 | Lₐ₁₀₂₁ | L_{b22} |
| 2509 | Lₐ₁₀₂₃ | L_{b22} | 2510 | Lₐ₁₁₀₃ | L_{b22} |
| 2511 | Lₐ₁₁₀₅ | L_{b22} | 2512 | Lₐ₁₁₀₈ | L_{b22} |
| 2513 | Lₐ₁₁₀₉ | L_{b22} | 2514 | Lₐ₁₁₁₁ | L_{b22} |
| 2515 | Lₐ₁₁₁₂ | L_{b22} | 2516 | Lₐ₁₁₁₅ | L_{b22} |
| 2517 | Lₐ₁₁₂₁ | L_{b22} | 2518 | Lₐ₁₁₂₆ | L_{b22} |
| 2519 | Lₐ₁₁₂₇ | L_{b22} | 2520 | Lₐ₁₁₂₉ | L_{b22} |
| 2521 | Lₐ₁₁₃₃ | L_{b22} | 2522 | Lₐ₁₁₅₇ | L_{b22} |
| 2523 | Lₐ₁₁₆₂ | L_{b22} | 2524 | Lₐ₁₁₆₃ | L_{b22} |
| 2525 | Lₐ₁₁₆₅ | L_{b22} | 2526 | Lₐ₁₁₆₉ | L_{b22} |
| 2527 | Lₐ₁₂₁₁ | L_{b22} | 2528 | Lₐ₁₂₁₆ | L_{b22} |
| 2529 | Lₐ₁₂₁₇ | L_{b22} | 2530 | Lₐ₁₂₁₉ | L_{b22} |
| 2531 | Lₐ₁₂₂₃ | L_{b22} | 2532 | Lₐ₁₂₄₇ | L_{b22} |
| 2533 | Lₐ₁₂₅₂ | L_{b22} | 2534 | Lₐ₁₂₅₃ | L_{b22} |
| 2535 | Lₐ₁₂₅₅ | L_{b22} | 2536 | Lₐ₁₂₅₉ | L_{b22} |
| 2537 | Lₐ₁₃₀₃ | L_{b22} | 2538 | Lₐ₁₃₀₅ | L_{b22} |
| 2539 | Lₐ₁₃₀₈ | L_{b22} | 2540 | Lₐ₁₃₁₅ | L_{b22} |
| 2541 | Lₐ₁₃₁₇ | L_{b22} | 2542 | Lₐ₁₃₂₀ | L_{b22} |
| 2543 | Lₐ₁₃₂₇ | L_{b22} | 2544 | Lₐ₁₃₂₉ | L_{b22} |
| 2545 | Lₐ₁₃₃₂ | L_{b22} | 2546 | Lₐ₁₃₃₉ | L_{b22} |
| 2547 | Lₐ₁₃₄₁ | L_{b22} | 2548 | Lₐ₁₃₄₄ | L_{b22} |
| 2549 | Lₐ₁₃₅₁ | L_{b22} | 2550 | Lₐ₁₃₅₃ | L_{b22} |
| 2551 | Lₐ₁₃₅₆ | L_{b22} | 2552 | Lₐ₁₃₅₉ | L_{b22} |
| 2553 | Lₐ₁₃₆₁ | L_{b22} | 2554 | Lₐ₁₃₆₃ | L_{b22} |
| 2555 | Lₐ₁₃₆₅ | L_{b22} | 2556 | Lₐ₁₃₆₈ | L_{b22} |
| 2557 | Lₐ₁₃₇₅ | L_{b22} | 2558 | Lₐ₁₃₇₇ | L_{b22} |
| 2559 | Lₐ₁₃₈₇ | L_{b22} | 2560 | Lₐ₁₃₈₉ | L_{b22} |
| 2561 | Lₐ₁₄₆₉ | L_{b22} | 2562 | Lₐ₁₆₆₉ | L_{b22} |
| 2563 | Lₐ₁₆₇₁ | L_{b22} | 2564 | Lₐ₁₇₂₉ | L_{b22} |
| 2565 | Lₐ₁₇₃₁ | L_{b22} | 2566 | Lₐ₁₇₄₁ | L_{b22} |
| 2567 | Lₐ₁₇₄₃ | L_{b22} | 2568 | Lₐ₁₇₅₃ | L_{b22} |
| 2569 | Lₐ₁₇₅₅ | L_{b22} | 2570 | Lₐ₁₈₃₅ | L_{b22} |
| 2571 | Lₐ₂₀₃₅ | L_{b22} | 2572 | Lₐ₂₀₃₇ | L_{b22} |
| 2573 | Lₐ₂₀₉₅ | L_{b22} | 2574 | Lₐ₂₀₉₇ | L_{b22} |
| 2575 | Lₐ₂₁₀₇ | L_{b22} | 2576 | Lₐ₂₁₀₉ | L_{b22} |
| 2577 | Lₐ₂₁₁₉ | L_{b22} | 2578 | Lₐ₂₁₂₁ | L_{b22} |
| 2579 | Lₐ₂₂₀₁ | L_{b22} | 2580 | Lₐ₂₄₀₁ | L_{b22} |
| 2581 | Lₐ₂₄₀₃ | L_{b22} | 2582 | Lₐ₂₄₆₁ | L_{b22} |
| 2583 | Lₐ₂₄₆₃ | L_{b22} | 2584 | Lₐ₂₄₇₃ | L_{b22} |
| 2585 | Lₐ₂₄₇₅ | L_{b22} | 2586 | Lₐ₂₄₈₅ | L_{b22} |
| 2587 | Lₐ₂₄₈₇ | L_{b22} | 2588 | Lₐ₂₅₆₇ | L_{b22} |
| 2589 | Lₐ₂₇₆₇ | L_{b22} | 2590 | Lₐ₂₇₆₉ | L_{b22} |
| 2591 | Lₐ₂₈₂₇ | L_{b22} | 2592 | Lₐ₂₈₂₉ | L_{b22} |
| 2593 | Lₐ₂₈₅₁ | L_{b22} | 2594 | Lₐ₂₈₅₃ | L_{b22} |
| 2595 | Lₐ₂₉₃₃ | L_{b22} | 2596 | Lₐ₂₉₃₅ | L_{b22} |
| 2597 | Lₐ₂₉₃₈ | L_{b22} | 2598 | Lₐ₂₉₃₉ | L_{b22} |
| 2599 | Lₐ₂₉₄₁ | L_{b22} | 2600 | Lₐ₂₉₄₂ | L_{b22} |
| 2601 | Lₐ₂₉₄₅ | L_{b22} | 2602 | Lₐ₂₉₅₁ | L_{b22} |
| 2603 | Lₐ₂₉₅₆ | L_{b22} | 2604 | Lₐ₂₉₅₇ | L_{b22} |
| 2605 | Lₐ₂₉₅₉ | L_{b22} | 2606 | Lₐ₂₉₆₃ | L_{b22} |
| 2607 | Lₐ₂₉₈₇ | L_{b22} | 2608 | Lₐ₂₉₉₂ | L_{b22} |
| 2609 | Lₐ₂₉₉₃ | L_{b22} | 2610 | Lₐ₂₉₉₅ | L_{b22} |
| 2611 | Lₐ₂₉₉₉ | L_{b22} | 2612 | Lₐ₃₀₄₁ | L_{b22} |
| 2613 | Lₐ₃₀₄₆ | L_{b22} | 2614 | Lₐ₃₀₄₇ | L_{b22} |
| 2615 | Lₐ₃₀₄₉ | L_{b22} | 2616 | Lₐ₃₀₅₃ | L_{b22} |
| 2617 | Lₐ₃₀₇₇ | L_{b22} | 2618 | Lₐ₃₀₈₂ | L_{b22} |
| 2619 | Lₐ₃₀₈₃ | L_{b22} | 2620 | Lₐ₃₀₈₅ | L_{b22} |
| 2621 | Lₐ₃₀₈₉ | L_{b22} | 2622 | Lₐ₃₁₃₃ | L_{b22} |
| 2623 | Lₐ₃₁₃₅ | L_{b22} | 2624 | Lₐ₃₁₃₈ | L_{b22} |
| 2625 | Lₐ₃₁₄₅ | L_{b22} | 2626 | Lₐ₃₁₄₇ | L_{b22} |
| 2627 | Lₐ₃₁₅₀ | L_{b22} | 2628 | Lₐ₃₁₆₉ | L_{b22} |
| 2629 | Lₐ₃₁₇₁ | L_{b22} | 2630 | Lₐ₃₁₇₄ | L_{b22} |
| 2631 | Lₐ₃₁₈₁ | L_{b22} | 2632 | Lₐ₃₁₈₃ | L_{b22} |
| 2633 | Lₐ₃₁₈₆ | L_{b22} | 2634 | Lₐ₃₁₈₉ | L_{b22} |
| 2635 | Lₐ₃₁₉₁ | L_{b22} | 2636 | Lₐ₃₁₉₃ | L_{b22} |
| 2637 | Lₐ₃₁₉₅ | L_{b22} | 2638 | Lₐ₃₁₉₈ | L_{b22} |
| 2639 | Lₐ₃₂₀₅ | L_{b22} | 2640 | Lₐ₃₂₀₇ | L_{b22} |
| 2641 | Lₐ₃₂₁₇ | L_{b22} | 2642 | Lₐ₃₂₁₉ | L_{b22} |
| 2643 | Lₐ₃₂₂₉ | L_{b22} | 2644 | Lₐ₃₂₃₁ | L_{b22} |
| 2645 | Lₐ₃₂₃₄ | L_{b22} | 2646 | Lₐ₃₂₄₁ | L_{b22} |
| 2647 | Lₐ₃₂₄₃ | L_{b22} | 2648 | Lₐ₃₂₄₆ | L_{b22} |
| 2649 | Lₐ₃₂₅₃ | L_{b22} | 2650 | Lₐ₃₂₅₅ | L_{b22} |
| 2651 | Lₐ₃₂₅₈ | L_{b22} | 2652 | Lₐ₃₂₆₅ | L_{b22} |
| 2653 | Lₐ₃₂₆₇ | L_{b22} | 2654 | Lₐ₃₂₇₀ | L_{b22} |
| 2655 | Lₐ₃₂₇₇ | L_{b22} | 2656 | Lₐ₃₂₇₉ | L_{b22} |
| 2657 | Lₐ₃₂₈₂ | L_{b22} | 2658 | Lₐ₃₂₈₉ | L_{b22} |
| 2659 | Lₐ₃₂₉₁ | L_{b22} | 2660 | Lₐ₃₂₉₄ | L_{b22} |
| 2661 | Lₐ₃₂₉₉ | L_{b22} | 2662 | Lₐ₃₄₉₉ | L_{b22} |
| 2663 | Lₐ₃₅₀₁ | L_{b22} | 2664 | Lₐ₃₅₅₉ | L_{b22} |
| 2665 | Lₐ₃₅₆₁ | L_{b22} | 2666 | Lₐ₃₅₇₁ | L_{b22} |
| 2667 | Lₐ₃₅₇₃ | L_{b22} | 2668 | Lₐ₃₅₈₃ | L_{b22} |
| 2669 | Lₐ₃₅₈₅ | L_{b22} | 2670 | Lₐ₃₆₆₅ | L_{b22} |
| 2671 | Lₐ₃₆₆₇ | L_{b22} | 2672 | Lₐ₃₆₇₀ | L_{b22} |
| 2673 | Lₐ₃₆₇₁ | L_{b22} | 2674 | Lₐ₃₆₇₃ | L_{b22} |
| 2675 | Lₐ₃₆₇₄ | L_{b22} | 2676 | Lₐ₃₆₇₇ | L_{b22} |
| 2677 | Lₐ₃₆₈₃ | L_{b22} | 2678 | Lₐ₃₆₈₈ | L_{b22} |
| 2679 | Lₐ₃₆₈₉ | L_{b22} | 2680 | Lₐ₃₆₉₁ | L_{b22} |
| 2681 | Lₐ₃₆₉₅ | L_{b22} | 2682 | Lₐ₃₇₁₉ | L_{b22} |
| 2683 | Lₐ₃₇₂₄ | L_{b22} | 2684 | Lₐ₃₇₂₅ | L_{b22} |
| 2685 | Lₐ₃₇₂₇ | L_{b22} | 2686 | Lₐ₃₇₃₁ | L_{b22} |
| 2687 | Lₐ₃₇₇₃ | L_{b22} | 2688 | Lₐ₃₇₇₈ | L_{b22} |
| 2689 | Lₐ₃₇₇₉ | L_{b22} | 2690 | Lₐ₃₇₈₁ | L_{b22} |
| 2691 | Lₐ₃₇₈₅ | L_{b22} | 2692 | Lₐ₃₈₀₉ | L_{b22} |
| 2693 | Lₐ₃₈₁₄ | L_{b22} | 2694 | Lₐ₃₈₁₅ | L_{b22} |
| 2695 | Lₐ₃₈₁₇ | L_{b22} | 2696 | Lₐ₃₈₂₁ | L_{b22} |
| 2697 | Lₐ₃₈₆₅ | L_{b22} | 2698 | Lₐ₃₈₆₇ | L_{b22} |
| 2699 | Lₐ₃₈₇₀ | L_{b22} | 2700 | Lₐ₃₈₇₇ | L_{b22} |
| 2701 | Lₐ₃₈₇₉ | L_{b22} | 2702 | Lₐ₃₈₈₂ | L_{b22} |
| 2703 | Lₐ₃₈₈₉ | L_{b22} | 2704 | Lₐ₃₈₉₁ | L_{b22} |
| 2705 | Lₐ₃₈₉₄ | L_{b22} | 2706 | Lₐ₃₉₀₁ | L_{b22} |
| 2707 | Lₐ₃₉₀₃ | L_{b22} | 2708 | Lₐ₃₉₀₆ | L_{b22} |
| 2709 | Lₐ₃₉₁₃ | L_{b22} | 2710 | Lₐ₃₉₁₅ | L_{b22} |
| 2711 | Lₐ₃₉₁₈ | L_{b22} | 2712 | Lₐ₃₉₂₁ | L_{b22} |
| 2713 | Lₐ₃₉₂₃ | L_{b22} | 2714 | Lₐ₃₉₂₄ | L_{b22} |
| 2715 | Lₐ₃₉₂₅ | L_{b22} | 2716 | Lₐ₃₉₂₇ | L_{b22} |
| 2717 | Lₐ₃₉₂₈ | L_{b22} | 2718 | Lₐ₃₉₃₀ | L_{b22} |
| 2719 | Lₐ₃₉₃₇ | L_{b22} | 2720 | Lₐ₃₉₃₉ | L_{b22} |
| 2721 | Lₐ₃₉₄₉ | L_{b22} | 2722 | Lₐ₃₉₅₁ | L_{b22} |
| 2723 | Lₐ₃₉₆₁ | L_{b22} | 2724 | Lₐ₃₉₆₃ | L_{b22} |
| 2725 | Lₐ₃₉₆₆ | L_{b22} | 2726 | Lₐ₃₉₇₃ | L_{b22} |
| 2727 | Lₐ₃₉₇₅ | L_{b22} | 2728 | Lₐ₃₉₇₈ | L_{b22} |
| 2729 | Lₐ₃₉₈₅ | L_{b22} | 2730 | Lₐ₃₉₈₇ | L_{b22} |
| 2731 | Lₐ₃₉₉₀ | L_{b22} | 2732 | Lₐ₃₉₉₇ | L_{b22} |
| 2733 | Lₐ₃₉₉₉ | L_{b22} | 2734 | Lₐ₄₀₀₂ | L_{b22} |
| 2735 | Lₐ₄₀₀₉ | L_{b22} | 2736 | Lₐ₄₀₁₁ | L_{b22} |
| 2737 | Lₐ₄₀₁₄ | L_{b22} | 2738 | Lₐ₄₀₂₁ | L_{b22} |
| 2739 | Lₐ₄₀₂₃ | L_{b22} | 2740 | Lₐ₄₀₂₆ | L_{b22} |
| 2741 | Lₐ₄₀₃₁ | L_{b22} | 2742 | Lₐ₄₀₃₆ | L_{b22} |
| 2743 | Lₐ₄₀₃₇ | L_{b22} | 2744 | Lₐ₄₀₃₉ | L_{b22} |
| 2745 | Lₐ₄₀₄₃ | L_{b22} | 2746 | Lₐ₄₀₄₉ | L_{b22} |
| 2747 | Lₐ₄₀₅₄ | L_{b22} | 2748 | Lₐ₄₀₅₅ | L_{b22} |
| 2749 | Lₐ₄₀₅₇ | L_{b22} | 2750 | Lₐ₄₀₆₁ | L_{b22} |
| 2751 | Lₐ₄₁₃₉ | L_{b22} | 2752 | Lₐ₄₁₄₄ | L_{b22} |
| 2753 | Lₐ₄₁₄₅ | L_{b22} | 2754 | Lₐ₄₁₄₇ | L_{b22} |
| 2755 | Lₐ₄₁₅₁ | L_{b22} | 2756 | Lₐ₄₂₃₁ | L_{b22} |
| 2757 | Lₐ₄₂₃₃ | L_{b22} | 2758 | Lₐ₄₂₃₆ | L_{b22} |
| 2759 | Lₐ₄₂₄₃ | L_{b22} | 2760 | Lₐ₄₂₄₅ | L_{b22} |
| 2761 | Lₐ₄₂₄₈ | L_{b22} | 2762 | Lₐ₄₂₆₇ | L_{b22} |
| 2763 | Lₐ₄₂₆₉ | L_{b22} | 2764 | Lₐ₄₂₇₂ | L_{b22} |
| 2765 | Lₐ₄₂₈₇ | L_{b22} | 2766 | Lₐ₄₂₈₉ | L_{b22} |
| 2767 | Lₐ₄₂₉₁ | L_{b22} | 2768 | Lₐ₄₂₉₃ | L_{b22} |
| 2769 | Lₐ₄₂₉₄ | L_{b22} | 2770 | Lₐ₄₂₉₆ | L_{b22} |
| 2771 | Lₐ₄₃₀₃ | L_{b22} | 2772 | Lₐ₄₃₀₅ | L_{b22} |
| 2773 | Lₐ₄₃₁₅ | L_{b22} | 2774 | Lₐ₄₃₁₇ | L_{b22} |
| 2775 | Lₐ₄₃₂₇ | L_{b22} | 2776 | Lₐ₄₃₂₉ | L_{b22} |
| 2777 | Lₐ₄₃₃₂ | L_{b22} | 2778 | Lₐ₄₃₃₉ | L_{b22} |
| 2779 | Lₐ₄₃₄₁ | L_{b22} | 2780 | Lₐ₄₃₄₄ | L_{b22} |
| 2781 | Lₐ₄₃₆₃ | L_{b22} | 2782 | Lₐ₄₃₆₅ | L_{b22} |
| 2783 | Lₐ₄₃₆₈ | L_{b22} | 2784 | Lₐ₄₃₇₅ | L_{b22} |
| 2785 | Lₐ₄₃₇₇ | L_{b22} | 2786 | Lₐ₄₃₈₀ | L_{b22} |
| 2787 | Lₐ₄₃₉₇ | L_{b22} | 2788 | Lₐ₄₃₉₉ | L_{b22} |
| 2789 | Lₐ₄₄₀₂ | L_{b22} | 2790 | Lₐ₄₄₀₃ | L_{b22} |
| 2791 | Lₐ₄₄₀₅ | L_{b22} | 2792 | Lₐ₄₄₀₆ | L_{b22} |
| 2793 | Lₐ₄₄₀₉ | L_{b22} | 2794 | Lₐ₄₄₁₅ | L_{b22} |
| 2795 | Lₐ₄₄₂₀ | L_{b22} | 2796 | Lₐ₄₄₂₃ | L_{b22} |
| 2797 | Lₐ₄₄₂₇ | L_{b22} | 2798 | Lₐ₄₄₅₁ | L_{b22} |
| 2799 | Lₐ₄₄₅₆ | L_{b22} | 2800 | Lₐ₄₄₅₇ | L_{b22} |
| 2801 | Lₐ₄₄₅₉ | L_{b22} | 2802 | Lₐ₄₄₆₃ | L_{b22} |
| 2803 | Lₐ₄₅₉₇ | L_{b22} | 2804 | Lₐ₄₅₉₉ | L_{b22} |
| 2805 | Lₐ₄₆₀₂ | L_{b22} | 2806 | Lₐ₄₆₀₉ | L_{b22} |
| 2807 | Lₐ₄₆₁₁ | L_{b22} | 2808 | Lₐ₄₆₂₁ | L_{b22} |
| 2809 | Lₐ₄₆₂₃ | L_{b22} | 2810 | Lₐ₄₆₃₃ | L_{b22} |
| 2811 | Lₐ₄₆₃₅ | L_{b22} | 2812 | Lₐ₄₆₄₅ | L_{b22} |
| 2813 | Lₐ₄₆₄₇ | L_{b22} | 2814 | Lₐ₄₆₅₃ | L_{b22} |
| 2815 | Lₐ₄₆₅₅ | L_{b22} | 2816 | Lₐ₄₆₅₇ | L_{b22} |
| 2817 | Lₐ₄₆₅₉ | L_{b22} | 2818 | Lₐ₄₆₆₂ | L_{b22} |
| 2819 | Lₐ₄₆₆₉ | L_{b22} | 2820 | Lₐ₄₆₇₁ | L_{b22} |
| 2821 | Lₐ₄₆₈₁ | L_{b22} | 2822 | Lₐ₄₆₈₃ | L_{b22} |
| 2823 | Lₐ₄₆₉₃ | L_{b22} | 2824 | Lₐ₄₆₉₅ | L_{b22} |
| 2825 | Lₐ₄₆₉₈ | L_{b22} | 2826 | Lₐ₄₇₀₅ | L_{b22} |
| 2827 | Lₐ₄₇₀₇ | L_{b22} | 2828 | Lₐ₄₇₁₀ | L_{b22} |
| 2829 | Lₐ₄₇₂₉ | L_{b22} | 2830 | Lₐ₄₇₃₁ | L_{b22} |
| 2831 | Lₐ₄₇₃₄ | L_{b22} | 2832 | Lₐ₄₇₆₃ | L_{b22} |
| 2833 | Lₐ₄₉₆₃ | L_{b22} | 2834 | Lₐ₄₉₆₅ | L_{b22} |
| 2835 | Lₐ₄₉₆₈ | L_{b22} | 2836 | Lₐ₅₀₂₃ | L_{b22} |
| 2837 | Lₐ₅₀₂₅ | L_{b22} | 2838 | Lₐ₅₀₃₅ | L_{b22} |
| 2839 | Lₐ₅₀₃₇ | L_{b22} | 2840 | Lₐ₅₀₄₇ | L_{b22} |
| 2841 | Lₐ₅₀₄₉ | L_{b22} | 2842 | Lₐ₅₁₂₉ | L_{b22} |
| 2843 | Lₐ₅₁₃₄ | L_{b22} | 2844 | Lₐ₅₁₃₅ | L_{b22} |
| 2845 | Lₐ₅₁₃₇ | L_{b22} | 2846 | Lₐ₅₁₄₁ | L_{b22} |
| 2847 | Lₐ₅₁₄₇ | L_{b22} | 2848 | Lₐ₅₁₅₂ | L_{b22} |
| 2849 | Lₐ₅₁₅₃ | L_{b22} | 2850 | Lₐ₅₁₅₅ | L_{b22} |
| 2851 | Lₐ₅₁₅₉ | L_{b22} | 2852 | Lₐ₅₂₃₇ | L_{b22} |
| 2853 | Lₐ₅₂₄₂ | L_{b22} | 2854 | Lₐ₅₂₄₃ | L_{b22} |
| 2855 | Lₐ₅₂₄₅ | L_{b22} | 2856 | Lₐ₅₂₄₉ | L_{b22} |
| 2857 | Lₐ₅₃₂₉ | L_{b22} | 2858 | Lₐ₅₃₃₁ | L_{b22} |
| 2859 | Lₐ₅₃₃₄ | L_{b22} | 2860 | Lₐ₅₃₄₁ | L_{b22} |
| 2861 | Lₐ₅₃₄₃ | L_{b22} | 2862 | Lₐ₅₃₄₆ | L_{b22} |
| 2863 | Lₐ₅₃₆₅ | L_{b22} | 2864 | Lₐ₅₃₆₇ | L_{b22} |
| 2865 | Lₐ₅₃₇₀ | L_{b22} | 2866 | Lₐ₅₃₈₅ | L_{b22} |
| 2867 | Lₐ₅₃₈₇ | L_{b22} | 2868 | Lₐ₅₃₈₉ | L_{b22} |
| 2869 | Lₐ₅₃₉₁ | L_{b22} | 2870 | Lₐ₅₃₉₂ | L_{b22} |
| 2871 | Lₐ₅₃₉₄ | L_{b22} | 2872 | Lₐ₅₄₀₁ | L_{b22} |
| 2873 | Lₐ₅₄₀₃ | L_{b22} | 2874 | Lₐ₅₄₁₃ | L_{b22} |
| 2875 | Lₐ₅₄₁₅ | L_{b22} | 2876 | Lₐ₅₄₂₅ | L_{b22} |
| 2877 | Lₐ₅₄₂₇ | L_{b22} | 2878 | Lₐ₅₄₃₀ | L_{b22} |
| 2879 | Lₐ₅₄₆₁ | L_{b22} | 2880 | Lₐ₅₄₆₃ | L_{b22} |
| 2881 | Lₐ₅₄₆₆ | L_{b22} | 2882 | Lₐ₅₄₉₅ | L_{b22} |
| 2883 | Lₐ₅₆₉₅ | L_{b22} | 2884 | Lₐ₅₆₉₇ | L_{b22} |
| 2885 | Lₐ₅₇₅₅ | L_{b22} | 2886 | Lₐ₅₇₅₇ | L_{b22} |
| 2887 | Lₐ₅₇₆₀ | L_{b22} | 2888 | Lₐ₅₇₆₇ | L_{b22} |
| 2889 | Lₐ₅₇₆₉ | L_{b22} | 2890 | Lₐ₅₇₇₉ | L_{b22} |
| 2891 | Lₐ₅₇₈₁ | L_{b22} | 2892 | Lₐ₅₈₆₁ | L_{b22} |
| 2893 | Lₐ₅₈₆₆ | L_{b22} | 2894 | Lₐ₅₈₆₇ | L_{b22} |
| 2895 | Lₐ₅₈₆₉ | L_{b22} | 2896 | Lₐ₅₈₇₃ | L_{b22} |
| 2897 | Lₐ₅₈₇₉ | L_{b22} | 2898 | Lₐ₅₈₈₄ | L_{b22} |
| 2899 | Lₐ₅₈₈₅ | L_{b22} | 2900 | Lₐ₅₈₈₇ | L_{b22} |
| 2901 | Lₐ₅₈₉₁ | L_{b22} | 2902 | Lₐ₅₉₆₉ | L_{b22} |
| 2903 | Lₐ₅₉₇₄ | L_{b22} | 2904 | Lₐ₅₉₇₅ | L_{b22} |
| 2905 | Lₐ₅₉₇₇ | L_{b22} | 2906 | Lₐ₅₉₈₁ | L_{b22} |
| 2907 | Lₐ₆₀₅₇ | L_{b22} | 2908 | Lₐ₆₀₅₉ | L_{b22} |
| 2909 | Lₐ₆₀₆₁ | L_{b22} | 2910 | Lₐ₆₀₆₃ | L_{b22} |
| 2911 | Lₐ₆₀₆₆ | L_{b22} | 2912 | Lₐ₆₀₇₃ | L_{b22} |
| 2913 | Lₐ₆₀₇₅ | L_{b22} | 2914 | Lₐ₆₀₇₈ | L_{b22} |
| 2915 | Lₐ₆₀₈₅ | L_{b22} | 2916 | Lₐ₆₀₈₇ | L_{b22} |
| 2917 | Lₐ₆₀₉₇ | L_{b22} | 2918 | Lₐ₆₀₉₉ | L_{b22} |
| 2919 | Lₐ₆₁₁₇ | L_{b22} | 2920 | Lₐ₆₁₁₉ | L_{b22} |
| 2921 | Lₐ₆₁₂₁ | L_{b22} | 2922 | Lₐ₆₁₂₃ | L_{b22} |
| 2923 | Lₐ₆₁₂₆ | L_{b22} | 2924 | Lₐ₆₁₃₃ | L_{b22} |
| 2925 | Lₐ₆₁₃₅ | L_{b22} | 2926 | Lₐ₆₁₄₅ | L_{b22} |
| 2927 | Lₐ₆₁₄₇ | L_{b22} | 2928 | Lₐ₆₁₅₇ | L_{b22} |
| 2929 | Lₐ₆₁₅₉ | L_{b22} | 2930 | Lₐ₆₁₆₂ | L_{b22} |
| 2931 | Lₐ₆₁₆₉ | L_{b22} | 2932 | Lₐ₆₁₇₁ | L_{b22} |
| 2933 | Lₐ₆₁₇₄ | L_{b22} | 2934 | Lₐ₆₁₉₃ | L_{b22} |
| 2935 | Lₐ₆₁₉₅ | L_{b22} | 2936 | Lₐ₆₁₉₈ | L_{b22} |
| 2937 | Lₐ₆₂₀₅ | L_{b22} | 2938 | Lₐ₆₂₀₇ | L_{b22} |
| 2939 | Lₐ₆₂₂₇ | L_{b22} | 2940 | Lₐ₆₂₃₂ | L_{b22} |
| 2941 | Lₐ₆₂₃₃ | L_{b22} | 2942 | Lₐ₆₂₃₅ | L_{b22} |
| 2943 | Lₐ₆₂₃₉ | L_{b22} | 2944 | Lₐ₆₂₄₅ | L_{b22} |
| 2945 | Lₐ₆₂₅₀ | L_{b22} | 2946 | Lₐ₆₂₅₁ | L_{b22} |
| 2947 | Lₐ₆₂₅₃ | L_{b22} | 2948 | Lₐ₆₂₅₇ | L_{b22} |
| 2949 | Lₐ₆₃₃₅ | L_{b22} | 2950 | Lₐ₆₃₄₀ | L_{b22} |
| 2951 | Lₐ₆₃₄₁ | L_{b22} | 2952 | Lₐ₆₃₄₃ | L_{b22} |
| 2953 | Lₐ₆₃₄₇ | L_{b22} | 2954 | Lₐ₆₄₂₃ | L_{b22} |
| 2955 | Lₐ₆₄₂₅ | L_{b22} | 2956 | Lₐ₆₄₂₇ | L_{b22} |
| 2957 | Lₐ₆₄₂₉ | L_{b22} | 2958 | Lₐ₆₄₃₂ | L_{b22} |
| 2959 | Lₐ₆₄₃₉ | L_{b22} | 2960 | Lₐ₆₄₄₁ | L_{b22} |
| 2961 | Lₐ₆₄₄₄ | L_{b22} | 2962 | Lₐ₆₄₆₃ | L_{b22} |
| 2963 | Lₐ₆₄₆₅ | L_{b22} | 2964 | Lₐ₆₄₆₈ | L_{b22} |
| 2965 | Lₐ₆₄₈₃ | L_{b22} | 2966 | Lₐ₆₄₈₅ | L_{b22} |
| 2967 | Lₐ₆₄₈₇ | L_{b22} | 2968 | Lₐ₆₄₈₉ | L_{b22} |
| 2969 | Lₐ₆₄₉₂ | L_{b22} | 2970 | Lₐ₆₄₉₉ | L_{b22} |
| 2971 | Lₐ₆₅₀₁ | L_{b22} | 2972 | Lₐ₆₅₁₁ | L_{b22} |
| 2973 | Lₐ₆₅₁₃ | L_{b22} | 2974 | Lₐ₆₅₂₃ | L_{b22} |
| 2975 | Lₐ₆₅₂₅ | L_{b22} | 2976 | Lₐ₆₅₂₈ | L_{b22} |
| 2977 | Lₐ₆₅₃₅ | L_{b22} | 2978 | Lₐ₆₅₃₇ | L_{b22} |
| 2979 | Lₐ₆₅₄₀ | L_{b22} | 2980 | Lₐ₆₅₅₉ | L_{b22} |
| 2981 | Lₐ₆₅₆₁ | L_{b22} | 2982 | Lₐ₆₅₆₄ | L_{b22} |
| 2983 | Lₐ₆₅₇₁ | L_{b22} | 2984 | Lₐ₆₅₇₃ | L_{b22} |
| 2985 | Lₐ₆₅₉₃ | L_{b22} | 2986 | Lₐ₆₅₉₈ | L_{b22} |
| 2987 | Lₐ₆₅₉₉ | L_{b22} | 2988 | Lₐ₆₆₀₁ | L_{b22} |
| 2989 | Lₐ₆₆₀₅ | L_{b22} | 2990 | Lₐ₆₆₁₁ | L_{b22} |
| 2991 | Lₐ₆₆₁₆ | L_{b22} | 2992 | Lₐ₆₆₁₉ | L_{b22} |
| 2993 | Lₐ₆₆₂₃ | L_{b22} | 2994 | Lₐ₆₇₀₀ | L_{b22} |
| 2995 | Lₐ₆₇₀₁ | L_{b22} | 2996 | Lₐ₆₇₀₃ | L_{b22} |
| 2997 | Lₐ₆₇₀₆ | L_{b22} | 2998 | Lₐ₆₇₀₇ | L_{b22} |
| 2999 | Lₐ₆₇₀₉ | L_{b22} | 3000 | Lₐ₆₇₁₃ | L_{b22} |
| 3001 | Lₐ₆₇₄₂ | L_{b22} | 3002 | Lₐ₆₇₄₅ | L_{b22} |
| 3003 | Lₐ₆₇₉₃ | L_{b22} | 3004 | Lₐ₆₇₉₅ | L_{b22} |
| 3005 | Lₐ₆₇₉₈ | L_{b22} | 3006 | Lₐ₆₈₀₅ | L_{b22} |
| 3007 | Lₐ₆₈₀₇ | L_{b22} | 3008 | Lₐ₆₈₁₀ | L_{b22} |
| 3009 | Lₐ₆₈₂₉ | L_{b22} | 3010 | Lₐ₆₈₃₁ | L_{b22} |
| 3011 | Lₐ₆₈₃₄ | L_{b22} | 3012 | Lₐ₆₈₄₉ | L_{b22} |
| 3013 | Lₐ₆₈₅₁ | L_{b22} | 3014 | Lₐ₆₈₅₃ | L_{b22} |
| 3015 | Lₐ₆₈₅₅ | L_{b22} | 3016 | Lₐ₆₈₅₈ | L_{b22} |
| 3017 | Lₐ₆₈₆₅ | L_{b22} | 3018 | Lₐ₆₈₆₇ | L_{b22} |
| 3019 | Lₐ₆₈₇₇ | L_{b22} | 3020 | Lₐ₆₈₇₉ | L_{b22} |
| 3021 | Lₐ₆₈₈₉ | L_{b22} | 3022 | Lₐ₆₈₉₁ | L_{b22} |
| 3023 | Lₐ₆₈₉₄ | L_{b22} | 3024 | Lₐ₆₉₀₁ | L_{b22} |
| 3025 | Lₐ₆₉₀₃ | L_{b22} | 3026 | Lₐ₆₉₂₅ | L_{b22} |
| 3027 | Lₐ₆₉₂₇ | L_{b22} | 3028 | Lₐ₆₉₃₀ | L_{b22} |
| 3029 | Lₐ₆₉₃₇ | L_{b22} | 3030 | Lₐ₆₉₃₉ | L_{b22} |
| 3031 | Lₐ₅ | L_{b52} | 3032 | Lₐ₇ | L_{b52} |
| 3033 | Lₐ₁₀ | L_{b52} | 3034 | Lₐ₁₁ | L_{b52} |
| 3035 | Lₐ₁₃ | L_{b52} | 3036 | Lₐ₁₄ | L_{b52} |
| 3037 | Lₐ₁₇ | L_{b52} | 3038 | Lₐ₂₃ | L_{b52} |
| 3039 | Lₐ₂₈ | L_{b52} | 3040 | Lₐ₂₉ | L_{b52} |
| 3041 | Lₐ₃₁ | L_{b52} | 3042 | Lₐ₃₅ | L_{b52} |
| 3043 | Lₐ₅₉ | L_{b52} | 3044 | Lₐ₆₄ | L_{b52} |
| 3045 | Lₐ₆₅ | L_{b52} | 3046 | Lₐ₆₇ | L_{b52} |
| 3047 | Lₐ₇₁ | L_{b52} | 3048 | Lₐ₁₁₃ | L_{b52} |
| 3049 | Lₐ₁₁₈ | L_{b52} | 3050 | Lₐ₁₁₉ | L_{b52} |
| 3051 | Lₐ₁₂₁ | L_{b52} | 3052 | Lₐ₁₂₅ | L_{b52} |
| 3053 | Lₐ₁₄₉ | L_{b52} | 3054 | Lₐ₁₅₄ | L_{b52} |
| 3055 | Lₐ₁₅₅ | L_{b52} | 3056 | Lₐ₁₅₇ | L_{b52} |
| 3057 | Lₐ₁₆₁ | L_{b52} | 3058 | Lₐ₂₀₅ | L_{b52} |
| 3059 | Lₐ₂₀₇ | L_{b52} | 3060 | Lₐ₂₁₀ | L_{b52} |
| 3061 | Lₐ₂₁₇ | L_{b52} | 3062 | Lₐ₂₁₉ | L_{b52} |
| 3063 | Lₐ₂₂₂ | L_{b52} | 3064 | Lₐ₂₂₉ | L_{b52} |
| 3065 | Lₐ₂₃₁ | L_{b52} | 3066 | Lₐ₂₃₄ | L_{b52} |
| 3067 | Lₐ₂₄₁ | L_{b52} | 3068 | Lₐ₂₄₃ | L_{b52} |
| 3069 | Lₐ₂₄₆ | L_{b52} | 3070 | Lₐ₂₅₃ | L_{b52} |
| 3071 | Lₐ₂₅₅ | L_{b52} | 3072 | Lₐ₂₅₈ | L_{b52} |
| 3073 | Lₐ₂₆₁ | L_{b52} | 3074 | Lₐ₂₆₃ | L_{b52} |
| 3075 | Lₐ₂₆₅ | L_{b52} | 3076 | Lₐ₂₆₇ | L_{b52} |
| 3077 | Lₐ₂₇₀ | L_{b52} | 3078 | Lₐ₂₇₇ | L_{b52} |
| 3079 | Lₐ₂₇₉ | L_{b52} | 3080 | Lₐ₂₈₂ | L_{b52} |
| 3081 | Lₐ₂₈₉ | L_{b52} | 3082 | Lₐ₂₉₁ | L_{b52} |
| 3083 | Lₐ₂₉₄ | L_{b52} | 3084 | Lₐ₃₀₁ | L_{b52} |
| 3085 | Lₐ₃₀₃ | L_{b52} | 3086 | Lₐ₃₀₆ | L_{b52} |
| 3087 | Lₐ₃₁₃ | L_{b52} | 3088 | Lₐ₃₁₅ | L_{b52} |
| 3089 | Lₐ₃₁₈ | L_{b52} | 3090 | Lₐ₃₂₅ | L_{b52} |
| 3091 | Lₐ₃₂₇ | L_{b52} | 3092 | Lₐ₃₃₀ | L_{b52} |
| 3093 | Lₐ₃₃₇ | L_{b52} | 3094 | Lₐ₃₃₉ | L_{b52} |
| 3095 | Lₐ₃₄₂ | L_{b52} | 3096 | Lₐ₃₄₉ | L_{b52} |
| 3097 | Lₐ₃₅₁ | L_{b52} | 3098 | Lₐ₃₅₄ | L_{b52} |
| 3099 | Lₐ₃₆₁ | L_{b52} | 3100 | Lₐ₃₆₃ | L_{b52} |
| 3101 | Lₐ₃₆₆ | L_{b52} | 3102 | Lₐ₃₇₁ | L_{b52} |
| 3103 | Lₐ₅₇₁ | L_{b52} | 3104 | Lₐ₅₇₃ | L_{b52} |
| 3105 | Lₐ₆₃₁ | L_{b52} | 3106 | Lₐ₆₃₃ | L_{b52} |
| 3107 | Lₐ₇₃₇ | L_{b52} | 3108 | Lₐ₉₃₇ | L_{b52} |
| 3109 | Lₐ₉₃₉ | L_{b52} | 3110 | Lₐ₉₉₇ | L_{b52} |
| 3111 | Lₐ₉₉₉ | L_{b52} | 3112 | Lₐ₁₀₀₉ | L_{b52} |
| 3113 | Lₐ₁₀₁₁ | L_{b52} | 3114 | Lₐ₁₀₂₁ | L_{b52} |
| 3115 | Lₐ₁₀₂₃ | L_{b52} | 3116 | Lₐ₁₁₀₃ | L_{b52} |
| 3117 | Lₐ₁₁₀₅ | L_{b52} | 3118 | Lₐ₁₁₀₈ | L_{b52} |
| 3119 | Lₐ₁₁₀₉ | L_{b52} | 3120 | Lₐ₁₁₁₁ | L_{b52} |
| 3121 | Lₐ₁₁₁₂ | L_{b52} | 3122 | Lₐ₁₁₁₅ | L_{b52} |
| 3123 | Lₐ₁₁₂₁ | L_{b52} | 3124 | Lₐ₁₁₂₆ | L_{b52} |
| 3125 | Lₐ₁₁₂₇ | L_{b52} | 3126 | Lₐ₁₁₂₉ | L_{b52} |
| 3127 | Lₐ₁₁₃₃ | L_{b52} | 3128 | Lₐ₁₁₅₇ | L_{b52} |
| 3129 | Lₐ₁₁₆₂ | L_{b52} | 3130 | Lₐ₁₁₆₃ | L_{b52} |
| 3131 | Lₐ₁₁₆₅ | L_{b52} | 3132 | Lₐ₁₁₆₉ | L_{b52} |
| 3133 | Lₐ₁₂₁₁ | L_{b52} | 3134 | Lₐ₁₂₁₆ | L_{b52} |
| 3135 | Lₐ₁₂₁₇ | L_{b52} | 3136 | Lₐ₁₂₁₉ | L_{b52} |
| 3137 | Lₐ₁₂₂₃ | L_{b52} | 3138 | Lₐ₁₂₄₇ | L_{b52} |
| 3139 | Lₐ₁₂₅₂ | L_{b52} | 3140 | Lₐ₁₂₅₃ | L_{b52} |
| 3141 | Lₐ₁₂₅₅ | L_{b52} | 3142 | Lₐ₁₂₅₉ | L_{b52} |
| 3143 | Lₐ₁₃₀₃ | L_{b52} | 3144 | Lₐ₁₃₀₅ | L_{b52} |
| 3145 | Lₐ₁₃₀₈ | L_{b52} | 3146 | Lₐ₁₃₁₅ | L_{b52} |
| 3147 | Lₐ₁₃₁₇ | L_{b52} | 3148 | Lₐ₁₃₂₀ | L_{b52} |
| 3149 | Lₐ₁₃₂₇ | L_{b52} | 3150 | Lₐ₁₃₂₉ | L_{b52} |
| 3151 | Lₐ₁₃₃₂ | L_{b52} | 3152 | Lₐ₁₃₃₉ | L_{b52} |
| 3153 | Lₐ₁₃₄₁ | L_{b52} | 3154 | Lₐ₁₃₄₄ | L_{b52} |
| 3155 | Lₐ₁₃₅₁ | L_{b52} | 3156 | Lₐ₁₃₅₃ | L_{b52} |
| 3157 | Lₐ₁₃₅₆ | L_{b52} | 3158 | Lₐ₁₃₅₉ | L_{b52} |
| 3159 | Lₐ₁₃₆₁ | L_{b52} | 3160 | Lₐ₁₃₆₃ | L_{b52} |
| 3161 | Lₐ₁₃₆₅ | L_{b52} | 3162 | Lₐ₁₃₆₈ | L_{b52} |
| 3163 | Lₐ₁₃₇₅ | L_{b52} | 3164 | Lₐ₁₃₇₇ | L_{b52} |
| 3165 | Lₐ₁₃₈₇ | L_{b52} | 3166 | Lₐ₁₃₈₉ | L_{b52} |
| 3167 | Lₐ₁₄₆₉ | L_{b52} | 3168 | Lₐ₁₆₆₉ | L_{b52} |
| 3169 | Lₐ₁₆₇₁ | L_{b52} | 3170 | Lₐ₁₇₂₉ | L_{b52} |
| 3171 | Lₐ₁₇₃₁ | L_{b52} | 3172 | Lₐ₁₇₄₁ | L_{b52} |
| 3173 | Lₐ₁₇₄₃ | L_{b52} | 3174 | Lₐ₁₇₅₃ | L_{b52} |
| 3175 | Lₐ₁₇₅₅ | L_{b52} | 3176 | Lₐ₁₈₃₅ | L_{b52} |
| 3177 | Lₐ₂₀₃₅ | L_{b52} | 3178 | Lₐ₂₀₃₇ | L_{b52} |
| 3179 | Lₐ₂₀₉₅ | L_{b52} | 3180 | Lₐ₂₀₉₇ | L_{b52} |
| 3181 | Lₐ₂₁₀₇ | L_{b52} | 3182 | Lₐ₂₁₀₉ | L_{b52} |
| 3183 | Lₐ₂₁₁₉ | L_{b52} | 3184 | Lₐ₂₁₂₁ | L_{b52} |
| 3185 | Lₐ₂₂₀₁ | L_{b52} | 3186 | Lₐ₂₄₀₁ | L_{b52} |
| 3187 | Lₐ₂₄₀₃ | L_{b52} | 3188 | Lₐ₂₄₆₁ | L_{b52} |
| 3189 | Lₐ₂₄₆₃ | L_{b52} | 3190 | Lₐ₂₄₇₃ | L_{b52} |
| 3191 | Lₐ₂₄₇₅ | L_{b52} | 3192 | Lₐ₂₄₈₅ | L_{b52} |
| 3193 | Lₐ₂₄₈₇ | L_{b52} | 3194 | Lₐ₂₅₆₇ | L_{b52} |
| 3195 | Lₐ₂₇₆₇ | L_{b52} | 3196 | Lₐ₂₇₆₉ | L_{b52} |
| 3197 | Lₐ₂₈₂₇ | L_{b52} | 3198 | Lₐ₂₈₂₉ | L_{b52} |
| 3199 | Lₐ₂₈₅₁ | L_{b52} | 3200 | Lₐ₂₈₅₃ | L_{b52} |
| 3201 | Lₐ₂₉₃₃ | L_{b52} | 3202 | Lₐ₂₉₃₅ | L_{b52} |
| 3203 | Lₐ₂₉₃₈ | L_{b52} | 3204 | Lₐ₂₉₃₉ | L_{b52} |
| 3205 | Lₐ₂₉₄₁ | L_{b52} | 3206 | Lₐ₂₉₄₂ | L_{b52} |
| 3207 | Lₐ₂₉₄₅ | L_{b52} | 3208 | Lₐ₂₉₅₁ | L_{b52} |
| 3209 | Lₐ₂₉₅₆ | L_{b52} | 3210 | Lₐ₂₉₅₇ | L_{b52} |
| 3211 | Lₐ₂₉₅₉ | L_{b52} | 3212 | Lₐ₂₉₆₃ | L_{b52} |
| 3213 | Lₐ₂₉₈₇ | L_{b52} | 3214 | Lₐ₂₉₉₂ | L_{b52} |
| 3215 | Lₐ₂₉₉₃ | L_{b52} | 3216 | Lₐ₂₉₉₅ | L_{b52} |
| 3217 | Lₐ₂₉₉₉ | L_{b52} | 3218 | Lₐ₃₀₄₁ | L_{b52} |
| 3219 | Lₐ₃₀₄₆ | L_{b52} | 3220 | Lₐ₃₀₄₇ | L_{b52} |
| 3221 | Lₐ₃₀₄₉ | L_{b52} | 3222 | Lₐ₃₀₅₃ | L_{b52} |
| 3223 | Lₐ₃₀₇₇ | L_{b52} | 3224 | Lₐ₃₀₈₂ | L_{b52} |
| 3225 | Lₐ₃₀₈₃ | L_{b52} | 3226 | Lₐ₃₀₈₅ | L_{b52} |
| 3227 | Lₐ₃₀₈₉ | L_{b52} | 3228 | Lₐ₃₁₃₃ | L_{b52} |
| 3229 | Lₐ₃₁₃₅ | L_{b52} | 3230 | Lₐ₃₁₃₈ | L_{b52} |
| 3231 | Lₐ₃₁₄₅ | L_{b52} | 3232 | Lₐ₃₁₄₇ | L_{b52} |
| 3233 | Lₐ₃₁₅₀ | L_{b52} | 3234 | Lₐ₃₁₆₉ | L_{b52} |
| 3235 | Lₐ₃₁₇₁ | L_{b52} | 3236 | Lₐ₃₁₇₄ | L_{b52} |
| 3237 | Lₐ₃₁₈₁ | L_{b52} | 3238 | Lₐ₃₁₈₃ | L_{b52} |
| 3239 | Lₐ₃₁₈₆ | L_{b52} | 3240 | Lₐ₃₁₈₉ | L_{b52} |
| 3241 | Lₐ₃₁₉₁ | L_{b52} | 3242 | Lₐ₃₁₉₃ | L_{b52} |
| 3243 | Lₐ₃₁₉₅ | L_{b52} | 3244 | Lₐ₃₁₉₈ | L_{b52} |
| 3245 | Lₐ₃₂₀₅ | L_{b52} | 3246 | Lₐ₃₂₀₇ | L_{b52} |
| 3247 | Lₐ₃₂₁₇ | L_{b52} | 3248 | Lₐ₃₂₁₉ | L_{b52} |
| 3249 | Lₐ₃₂₂₉ | L_{b52} | 3250 | Lₐ₃₂₃₁ | L_{b52} |
| 3251 | Lₐ₃₂₃₄ | L_{b52} | 3252 | Lₐ₃₂₄₁ | L_{b52} |
| 3253 | Lₐ₃₂₄₃ | L_{b52} | 3254 | Lₐ₃₂₄₆ | L_{b52} |
| 3255 | Lₐ₃₂₅₃ | L_{b52} | 3256 | Lₐ₃₂₅₅ | L_{b52} |
| 3257 | Lₐ₃₂₅₈ | L_{b52} | 3258 | Lₐ₃₂₆₅ | L_{b52} |
| 3259 | Lₐ₃₂₆₇ | L_{b52} | 3260 | Lₐ₃₂₇₀ | L_{b52} |
| 3261 | Lₐ₃₂₇₇ | L_{b52} | 3262 | Lₐ₃₂₇₉ | L_{b52} |
| 3263 | Lₐ₃₂₈₂ | L_{b52} | 3264 | Lₐ₃₂₈₉ | L_{b52} |
| 3265 | Lₐ₃₂₉₁ | L_{b52} | 3266 | Lₐ₃₂₉₄ | L_{b52} |
| 3267 | Lₐ₃₂₉₉ | L_{b52} | 3268 | Lₐ₃₄₉₉ | L_{b52} |
| 3269 | Lₐ₃₅₀₁ | L_{b52} | 3270 | Lₐ₃₅₅₉ | L_{b52} |
| 3271 | Lₐ₃₅₆₁ | L_{b52} | 3272 | Lₐ₃₅₇₁ | L_{b52} |
| 3273 | Lₐ₃₅₇₃ | L_{b52} | 3274 | Lₐ₃₅₈₃ | L_{b52} |
| 3275 | Lₐ₃₅₈₅ | L_{b52} | 3276 | Lₐ₃₆₆₅ | L_{b52} |
| 3277 | Lₐ₃₆₆₇ | L_{b52} | 3278 | Lₐ₃₆₇₀ | L_{b52} |
| 3279 | Lₐ₃₆₇₁ | L_{b52} | 3280 | Lₐ₃₆₇₃ | L_{b52} |
| 3281 | Lₐ₃₆₇₄ | L_{b52} | 3282 | Lₐ₃₆₇₇ | L_{b52} |
| 3283 | Lₐ₃₆₈₃ | L_{b52} | 3284 | Lₐ₃₆₈₈ | L_{b52} |
| 3285 | Lₐ₃₆₈₉ | L_{b52} | 3286 | Lₐ₃₆₉₁ | L_{b52} |
| 3287 | Lₐ₃₆₉₅ | L_{b52} | 3288 | Lₐ₃₇₁₉ | L_{b52} |
| 3289 | Lₐ₃₇₂₄ | L_{b52} | 3290 | Lₐ₃₇₂₅ | L_{b52} |
| 3291 | Lₐ₃₇₂₇ | L_{b52} | 3292 | Lₐ₃₇₃₁ | L_{b52} |
| 3293 | Lₐ₃₇₇₃ | L_{b52} | 3294 | Lₐ₃₇₇₈ | L_{b52} |
| 3295 | Lₐ₃₇₇₉ | L_{b52} | 3296 | Lₐ₃₇₈₁ | L_{b52} |
| 3297 | Lₐ₃₇₈₅ | L_{b52} | 3298 | Lₐ₃₈₀₉ | L_{b52} |
| 3299 | Lₐ₃₈₁₄ | L_{b52} | 3300 | Lₐ₃₈₁₅ | L_{b52} |
| 3301 | Lₐ₃₈₁₇ | L_{b52} | 3302 | Lₐ₃₈₂₁ | L_{b52} |
| 3303 | Lₐ₃₈₆₅ | L_{b52} | 3304 | Lₐ₃₈₆₇ | L_{b52} |
| 3305 | Lₐ₃₈₇₀ | L_{b52} | 3306 | Lₐ₃₈₇₇ | L_{b52} |
| 3307 | Lₐ₃₈₇₉ | L_{b52} | 3308 | Lₐ₃₈₈₂ | L_{b52} |
| 3309 | Lₐ₃₈₈₉ | L_{b52} | 3310 | Lₐ₃₈₉₁ | L_{b52} |
| 3311 | Lₐ₃₈₉₄ | L_{b52} | 3312 | Lₐ₃₉₀₁ | L_{b52} |
| 3313 | Lₐ₃₉₀₃ | L_{b52} | 3314 | Lₐ₃₉₀₆ | L_{b52} |
| 3315 | Lₐ₃₉₁₃ | L_{b52} | 3316 | Lₐ₃₉₁₅ | L_{b52} |
| 3317 | Lₐ₃₉₁₈ | L_{b52} | 3318 | Lₐ₃₉₂₁ | L_{b52} |
| 3319 | Lₐ₃₉₂₃ | L_{b52} | 3320 | Lₐ₃₉₂₄ | L_{b52} |
| 3321 | Lₐ₃₉₂₅ | L_{b52} | 3322 | Lₐ₃₉₂₇ | L_{b52} |
| 3323 | Lₐ₃₉₂₈ | L_{b52} | 3324 | Lₐ₃₉₃₀ | L_{b52} |
| 3325 | Lₐ₃₉₃₇ | L_{b52} | 3326 | Lₐ₃₉₃₉ | L_{b52} |
| 3327 | Lₐ₃₉₄₉ | L_{b52} | 3328 | Lₐ₃₉₅₁ | L_{b52} |
| 3329 | Lₐ₃₉₆₁ | L_{b52} | 3330 | Lₐ₃₉₆₃ | L_{b52} |
| 3331 | Lₐ₃₉₆₆ | L_{b52} | 3332 | Lₐ₃₉₇₃ | L_{b52} |
| 3333 | Lₐ₃₉₇₅ | L_{b52} | 3334 | Lₐ₃₉₇₈ | L_{b52} |
| 3335 | Lₐ₃₉₈₅ | L_{b52} | 3336 | Lₐ₃₉₈₇ | L_{b52} |
| 3337 | Lₐ₃₉₉₀ | L_{b52} | 3338 | Lₐ₃₉₉₇ | L_{b52} |
| 3339 | Lₐ₃₉₉₉ | L_{b52} | 3340 | Lₐ₄₀₀₂ | L_{b52} |
| 3341 | Lₐ₄₀₀₉ | L_{b52} | 3342 | Lₐ₄₀₁₁ | L_{b52} |
| 3343 | Lₐ₄₀₁₄ | L_{b52} | 3344 | Lₐ₄₀₂₁ | L_{b52} |
| 3345 | Lₐ₄₀₂₃ | L_{b52} | 3346 | Lₐ₄₀₂₆ | L_{b52} |
| 3347 | Lₐ₄₀₃₁ | L_{b52} | 3348 | Lₐ₄₀₃₆ | L_{b52} |
| 3349 | Lₐ₄₀₃₇ | L_{b52} | 3350 | Lₐ₄₀₃₉ | L_{b52} |
| 3351 | Lₐ₄₀₄₃ | L_{b52} | 3352 | Lₐ₄₀₄₉ | L_{b52} |
| 3353 | Lₐ₄₀₅₄ | L_{b52} | 3354 | Lₐ₄₀₅₅ | L_{b52} |
| 3355 | Lₐ₄₀₅₇ | L_{b52} | 3356 | Lₐ₄₀₆₁ | L_{b52} |
| 3357 | Lₐ₄₁₃₉ | L_{b52} | 3358 | Lₐ₄₁₄₄ | L_{b52} |
| 3359 | Lₐ₄₁₄₅ | L_{b52} | 3360 | Lₐ₄₁₄₇ | L_{b52} |
| 3361 | Lₐ₄₁₅₁ | L_{b52} | 3362 | Lₐ₄₂₃₁ | L_{b52} |
| 3363 | Lₐ₄₂₃₃ | L_{b52} | 3364 | Lₐ₄₂₃₆ | L_{b52} |
| 3365 | Lₐ₄₂₄₃ | L_{b52} | 3366 | Lₐ₄₂₄₅ | L_{b52} |
| 3367 | Lₐ₄₂₄₈ | L_{b52} | 3368 | Lₐ₄₂₆₇ | L_{b52} |
| 3369 | Lₐ₄₂₆₉ | L_{b52} | 3370 | Lₐ₄₂₇₂ | L_{b52} |
| 3371 | Lₐ₄₂₈₇ | L_{b52} | 3372 | Lₐ₄₂₈₉ | L_{b52} |
| 3373 | Lₐ₄₂₉₁ | L_{b52} | 3374 | Lₐ₄₂₉₃ | L_{b52} |
| 3375 | Lₐ₄₂₉₄ | L_{b52} | 3376 | Lₐ₄₂₉₆ | L_{b52} |
| 3377 | Lₐ₄₃₀₃ | L_{b52} | 3378 | Lₐ₄₃₀₅ | L_{b52} |
| 3379 | Lₐ₄₃₁₅ | L_{b52} | 3380 | Lₐ₄₃₁₇ | L_{b52} |
| 3381 | Lₐ₄₃₂₇ | L_{b52} | 3382 | Lₐ₄₃₂₉ | L_{b52} |
| 3383 | Lₐ₄₃₃₂ | L_{b52} | 3384 | Lₐ₄₃₃₉ | L_{b52} |
| 3385 | Lₐ₄₃₄₁ | L_{b52} | 3386 | Lₐ₄₃₄₄ | L_{b52} |
| 3387 | Lₐ₄₃₆₃ | L_{b52} | 3388 | Lₐ₄₃₆₅ | L_{b52} |
| 3389 | Lₐ₄₃₆₈ | L_{b52} | 3390 | Lₐ₄₃₇₅ | L_{b52} |
| 3391 | Lₐ₄₃₇₇ | L_{b52} | 3392 | Lₐ₄₃₈₀ | L_{b52} |
| 3393 | Lₐ₄₃₉₇ | L_{b52} | 3394 | Lₐ₄₃₉₉ | L_{b52} |
| 3395 | Lₐ₄₄₀₂ | L_{b52} | 3396 | Lₐ₄₄₀₃ | L_{b52} |
| 3397 | Lₐ₄₄₀₅ | L_{b52} | 3398 | Lₐ₄₄₀₆ | L_{b52} |
| 3399 | Lₐ₄₄₀₉ | L_{b52} | 3400 | Lₐ₄₄₁₅ | L_{b52} |
| 3401 | Lₐ₄₄₂₀ | L_{b52} | 3402 | Lₐ₄₄₂₃ | L_{b52} |
| 3403 | Lₐ₄₄₂₇ | L_{b52} | 3404 | Lₐ₄₄₅₁ | L_{b52} |
| 3405 | Lₐ₄₄₅₆ | L_{b52} | 3406 | Lₐ₄₄₅₇ | L_{b52} |
| 3407 | Lₐ₄₄₅₉ | L_{b52} | 3408 | Lₐ₄₄₆₃ | L_{b52} |
| 3409 | Lₐ₄₅₉₇ | L_{b52} | 3410 | Lₐ₄₅₉₉ | L_{b52} |
| 3411 | Lₐ₄₆₀₂ | L_{b52} | 3412 | Lₐ₄₆₀₉ | L_{b52} |
| 3413 | Lₐ₄₆₁₁ | L_{b52} | 3414 | Lₐ₄₆₂₁ | L_{b52} |
| 3415 | Lₐ₄₆₂₃ | L_{b52} | 3416 | Lₐ₄₆₃₃ | L_{b52} |
| 3417 | Lₐ₄₆₃₅ | L_{b52} | 3418 | Lₐ₄₆₄₅ | L_{b52} |
| 3419 | Lₐ₄₆₄₇ | L_{b52} | 3420 | Lₐ₄₆₅₃ | L_{b52} |
| 3421 | Lₐ₄₆₅₅ | L_{b52} | 3422 | Lₐ₄₆₅₇ | L_{b52} |
| 3423 | Lₐ₄₆₅₉ | L_{b52} | 3424 | Lₐ₄₆₆₂ | L_{b52} |
| 3425 | Lₐ₄₆₆₉ | L_{b52} | 3426 | Lₐ₄₆₇₁ | L_{b52} |
| 3427 | Lₐ₄₆₈₁ | L_{b52} | 3428 | Lₐ₄₆₈₃ | L_{b52} |
| 3429 | Lₐ₄₆₉₃ | L_{b52} | 3430 | Lₐ₄₆₉₅ | L_{b52} |
| 3431 | Lₐ₄₆₉₈ | L_{b52} | 3432 | Lₐ₄₇₀₅ | L_{b52} |
| 3433 | Lₐ₄₇₀₇ | L_{b52} | 3434 | Lₐ₄₇₁₀ | L_{b52} |
| 3435 | Lₐ₄₇₂₉ | L_{b52} | 3436 | Lₐ₄₇₃₁ | L_{b52} |
| 3437 | Lₐ₄₇₃₄ | L_{b52} | 3438 | Lₐ₄₇₆₃ | L_{b52} |
| 3439 | Lₐ₄₉₆₃ | L_{b52} | 3440 | Lₐ₄₉₆₅ | L_{b52} |
| 3441 | Lₐ₄₉₆₈ | L_{b52} | 3442 | Lₐ₅₀₂₃ | L_{b52} |
| 3443 | Lₐ₅₀₂₅ | L_{b52} | 3444 | Lₐ₅₀₃₅ | L_{b52} |
| 3445 | Lₐ₅₀₃₇ | L_{b52} | 3446 | Lₐ₅₀₄₇ | L_{b52} |
| 3447 | Lₐ₅₀₄₉ | L_{b52} | 3448 | Lₐ₅₁₂₉ | L_{b52} |
| 3449 | Lₐ₅₁₃₄ | L_{b52} | 3450 | Lₐ₅₁₃₅ | L_{b52} |
| 3451 | Lₐ₅₁₃₇ | L_{b52} | 3452 | Lₐ₅₁₄₁ | L_{b52} |
| 3453 | Lₐ₅₁₄₇ | L_{b52} | 3454 | Lₐ₅₁₅₂ | L_{b52} |
| 3455 | Lₐ₅₁₅₃ | L_{b52} | 3456 | Lₐ₅₁₅₅ | L_{b52} |
| 3457 | Lₐ₅₁₅₉ | L_{b52} | 3458 | Lₐ₅₂₃₇ | L_{b52} |
| 3459 | Lₐ₅₂₄₂ | L_{b52} | 3460 | Lₐ₅₂₄₃ | L_{b52} |
| 3461 | Lₐ₅₂₄₅ | L_{b52} | 3462 | Lₐ₅₂₄₉ | L_{b52} |
| 3463 | Lₐ₅₃₂₉ | L_{b52} | 3464 | Lₐ₅₃₃₁ | L_{b52} |
| 3465 | Lₐ₅₃₃₄ | L_{b52} | 3466 | Lₐ₅₃₄₁ | L_{b52} |
| 3467 | Lₐ₅₃₄₃ | L_{b52} | 3468 | Lₐ₅₃₄₆ | L_{b52} |
| 3469 | Lₐ₅₃₆₅ | L_{b52} | 3470 | Lₐ₅₃₆₇ | L_{b52} |
| 3471 | Lₐ₅₃₇₀ | L_{b52} | 3472 | Lₐ₅₃₈₅ | L_{b52} |
| 3473 | Lₐ₅₃₈₇ | L_{b52} | 3474 | Lₐ₅₃₈₉ | L_{b52} |
| 3475 | Lₐ₅₃₉₁ | L_{b52} | 3476 | Lₐ₅₃₉₂ | L_{b52} |
| 3477 | Lₐ₅₃₉₄ | L_{b52} | 3478 | Lₐ₅₄₀₁ | L_{b52} |
| 3479 | Lₐ₅₄₀₃ | L_{b52} | 3480 | Lₐ₅₄₁₃ | L_{b52} |
| 3481 | Lₐ₅₄₁₅ | L_{b52} | 3482 | Lₐ₅₄₂₅ | L_{b52} |
| 3483 | Lₐ₅₄₂₇ | L_{b52} | 3484 | Lₐ₅₄₃₀ | L_{b52} |
| 3485 | Lₐ₅₄₆₁ | L_{b52} | 3486 | Lₐ₅₄₆₃ | L_{b52} |
| 3487 | Lₐ₅₄₆₆ | L_{b52} | 3488 | Lₐ₅₄₉₅ | L_{b52} |
| 3489 | Lₐ₅₆₉₅ | L_{b52} | 3490 | Lₐ₅₆₉₇ | L_{b52} |
| 3491 | Lₐ₅₇₅₅ | L_{b52} | 3492 | Lₐ₅₇₅₇ | L_{b52} |
| 3493 | Lₐ₅₇₆₀ | L_{b52} | 3494 | Lₐ₅₇₆₇ | L_{b52} |
| 3495 | Lₐ₅₇₆₉ | L_{b52} | 3496 | Lₐ₅₇₇₉ | L_{b52} |
| 3497 | Lₐ₅₇₈₁ | L_{b52} | 3498 | Lₐ₅₈₆₁ | L_{b52} |
| 3499 | Lₐ₅₈₆₆ | L_{b52} | 3500 | Lₐ₅₈₆₇ | L_{b52} |
| 3501 | Lₐ₅₈₆₉ | L_{b52} | 3502 | Lₐ₅₈₇₃ | L_{b52} |
| 3503 | Lₐ₅₈₇₉ | L_{b52} | 3504 | Lₐ₅₈₈₄ | L_{b52} |
| 3505 | Lₐ₅₈₈₅ | L_{b52} | 3506 | Lₐ₅₈₈₇ | L_{b52} |
| 3507 | Lₐ₅₈₉₁ | L_{b52} | 3508 | Lₐ₅₉₆₉ | L_{b52} |
| 3509 | Lₐ₅₉₇₄ | L_{b52} | 3510 | Lₐ₅₉₇₅ | L_{b52} |
| 3511 | Lₐ₅₉₇₇ | L_{b52} | 3512 | Lₐ₅₉₈₁ | L_{b52} |
| 3513 | Lₐ₆₀₅₇ | L_{b52} | 3514 | Lₐ₆₀₅₉ | L_{b52} |
| 3515 | Lₐ₆₀₆₁ | L_{b52} | 3516 | Lₐ₆₀₆₃ | L_{b52} |
| 3517 | Lₐ₆₀₆₆ | L_{b52} | 3518 | Lₐ₆₀₇₃ | L_{b52} |
| 3519 | Lₐ₆₀₇₅ | L_{b52} | 3520 | Lₐ₆₀₇₈ | L_{b52} |
| 3521 | Lₐ₆₀₈₅ | L_{b52} | 3522 | Lₐ₆₀₈₇ | L_{b52} |
| 3523 | Lₐ₆₀₉₇ | L_{b52} | 3524 | Lₐ₆₀₉₉ | L_{b52} |
| 3525 | Lₐ₆₁₁₇ | L_{b52} | 3526 | Lₐ₆₁₁₉ | L_{b52} |
| 3527 | Lₐ₆₁₂₁ | L_{b52} | 3528 | Lₐ₆₁₂₃ | L_{b52} |
| 3529 | Lₐ₆₁₂₆ | L_{b52} | 3530 | Lₐ₆₁₃₃ | L_{b52} |
| 3531 | Lₐ₆₁₃₅ | L_{b52} | 3532 | Lₐ₆₁₄₅ | L_{b52} |
| 3533 | Lₐ₆₁₄₇ | L_{b52} | 3534 | Lₐ₆₁₅₇ | L_{b52} |
| 3535 | Lₐ₆₁₅₉ | L_{b52} | 3536 | Lₐ₆₁₆₂ | L_{b52} |
| 3537 | Lₐ₆₁₆₉ | L_{b52} | 3538 | Lₐ₆₁₇₁ | L_{b52} |
| 3539 | Lₐ₆₁₇₄ | L_{b52} | 3540 | Lₐ₆₁₉₃ | L_{b52} |
| 3541 | Lₐ₆₁₉₅ | L_{b52} | 3542 | Lₐ₆₁₉₈ | L_{b52} |
| 3543 | Lₐ₆₂₀₅ | L_{b52} | 3544 | Lₐ₆₂₀₇ | L_{b52} |
| 3545 | Lₐ₆₂₂₇ | L_{b52} | 3546 | Lₐ₆₂₃₂ | L_{b52} |
| 3547 | Lₐ₆₂₃₃ | L_{b52} | 3548 | Lₐ₆₂₃₅ | L_{b52} |
| 3549 | Lₐ₆₂₃₉ | L_{b52} | 3550 | Lₐ₆₂₄₅ | L_{b52} |
| 3551 | Lₐ₆₂₅₀ | L_{b52} | 3552 | Lₐ₆₂₅₁ | L_{b52} |
| 3553 | Lₐ₆₂₅₃ | L_{b52} | 3554 | Lₐ₆₂₅₇ | L_{b52} |
| 3555 | Lₐ₆₃₃₅ | L_{b52} | 3556 | Lₐ₆₃₄₀ | L_{b52} |
| 3557 | Lₐ₆₃₄₁ | L_{b52} | 3558 | Lₐ₆₃₄₃ | L_{b52} |
| 3559 | Lₐ₆₃₄₇ | L_{b52} | 3560 | Lₐ₆₄₂₃ | L_{b52} |
| 3561 | Lₐ₆₄₂₅ | L_{b52} | 3562 | Lₐ₆₄₂₇ | L_{b52} |
| 3563 | Lₐ₆₄₂₉ | L_{b52} | 3564 | Lₐ₆₄₃₂ | L_{b52} |
| 3565 | Lₐ₆₄₃₉ | L_{b52} | 3566 | Lₐ₆₄₄₁ | L_{b52} |
| 3567 | Lₐ₆₄₄₄ | L_{b52} | 3568 | Lₐ₆₄₆₃ | L_{b52} |
| 3569 | Lₐ₆₄₆₅ | L_{b52} | 3570 | Lₐ₆₄₆₈ | L_{b52} |
| 3571 | Lₐ₆₄₈₃ | L_{b52} | 3572 | Lₐ₆₄₈₅ | L_{b52} |
| 3573 | Lₐ₆₄₈₇ | L_{b52} | 3574 | Lₐ₆₄₈₉ | L_{b52} |
| 3575 | Lₐ₆₄₉₂ | L_{b52} | 3576 | Lₐ₆₄₉₉ | L_{b52} |
| 3577 | Lₐ₆₅₀₁ | L_{b52} | 3578 | Lₐ₆₅₁₁ | L_{b52} |
| 3579 | Lₐ₆₅₁₃ | L_{b52} | 3580 | Lₐ₆₅₂₃ | L_{b52} |
| 3581 | Lₐ₆₅₂₅ | L_{b52} | 3582 | Lₐ₆₅₂₈ | L_{b52} |
| 3583 | Lₐ₆₅₃₅ | L_{b52} | 3584 | Lₐ₆₅₃₇ | L_{b52} |
| 3585 | Lₐ₆₅₄₀ | L_{b52} | 3586 | Lₐ₆₅₅₉ | L_{b52} |
| 3587 | Lₐ₆₅₆₁ | L_{b52} | 3588 | Lₐ₆₅₆₄ | L_{b52} |
| 3589 | Lₐ₆₅₇₁ | L_{b52} | 3590 | Lₐ₆₅₇₃ | L_{b52} |
| 3591 | Lₐ₆₅₉₃ | L_{b52} | 3592 | Lₐ₆₅₉₈ | L_{b52} |
| 3593 | Lₐ₆₅₉₉ | L_{b52} | 3594 | Lₐ₆₆₀₁ | L_{b52} |
| 3595 | Lₐ₆₆₀₅ | L_{b52} | 3596 | Lₐ₆₆₁₁ | L_{b52} |
| 3597 | Lₐ₆₆₁₆ | L_{b52} | 3598 | Lₐ₆₆₁₉ | L_{b52} |
| 3599 | Lₐ₆₆₂₃ | L_{b52} | 3600 | Lₐ₆₇₀₀ | L_{b52} |
| 3601 | Lₐ₆₇₀₁ | L_{b52} | 3602 | Lₐ₆₇₀₃ | L_{b52} |
| 3603 | Lₐ₆₇₀₆ | L_{b52} | 3604 | Lₐ₆₇₀₇ | L_{b52} |
| 3605 | Lₐ₆₇₀₉ | L_{b52} | 3606 | Lₐ₆₇₁₃ | L_{b52} |
| 3607 | Lₐ₆₇₄₂ | L_{b52} | 3608 | Lₐ₆₇₄₅ | L_{b52} |
| 3609 | Lₐ₆₇₉₃ | L_{b52} | 3610 | Lₐ₆₇₉₅ | L_{b52} |
| 3611 | Lₐ₆₇₉₈ | L_{b52} | 3612 | Lₐ₆₈₀₅ | L_{b52} |
| 3613 | Lₐ₆₈₀₇ | L_{b52} | 3614 | Lₐ₆₈₁₀ | L_{b52} |
| 3615 | Lₐ₆₈₂₉ | L_{b52} | 3616 | Lₐ₆₈₃₁ | L_{b52} |
| 3617 | Lₐ₆₈₃₄ | L_{b52} | 3618 | Lₐ₆₈₄₉ | L_{b52} |
| 3619 | Lₐ₆₈₅₁ | L_{b52} | 3620 | Lₐ₆₈₅₃ | L_{b52} |
| 3621 | Lₐ₆₈₅₅ | L_{b52} | 3622 | Lₐ₆₈₅₈ | L_{b52} |
| 3623 | Lₐ₆₈₆₅ | L_{b52} | 3624 | Lₐ₆₈₆₇ | L_{b52} |
| 3625 | Lₐ₆₈₇₇ | L_{b52} | 3626 | Lₐ₆₈₇₉ | L_{b52} |
| 3627 | Lₐ₆₈₈₉ | L_{b52} | 3628 | Lₐ₆₈₉₁ | L_{b52} |
| 3629 | Lₐ₆₈₉₄ | L_{b52} | 3630 | Lₐ₆₉₀₁ | L_{b52} |
| 3631 | Lₐ₆₉₀₃ | L_{b52} | 3632 | Lₐ₆₉₂₅ | L_{b52} |
| 3633 | Lₐ₆₉₂₇ | L_{b52} | 3634 | Lₐ₆₉₃₀ | L_{b52} |
| 3635 | Lₐ₆₉₃₇ | L_{b52} | 3636 | Lₐ₆₉₃₉ | L_{b52} |
| 3637 | Lₐ₅ | L_{b132} | 3638 | Lₐ₇ | L_{b132} |
| 3639 | Lₐ₁₀ | L_{b132} | 3640 | Lₐ₁₁ | L_{b132} |
| 3641 | Lₐ₁₃ | L_{b132} | 3642 | Lₐ₁₄ | L_{b132} |
| 3643 | Lₐ₁₇ | L_{b132} | 3644 | Lₐ₂₃ | L_{b132} |
| 3645 | Lₐ₂₈ | L_{b132} | 3646 | Lₐ₂₉ | L_{b132} |
| 3647 | Lₐ₃₁ | L_{b132} | 3648 | Lₐ₃₅ | L_{b132} |
| 3649 | Lₐ₅₉ | L_{b132} | 3650 | Lₐ₆₄ | L_{b132} |
| 3651 | Lₐ₆₅ | L_{b132} | 3652 | Lₐ₆₇ | L_{b132} |
| 3653 | Lₐ₇₁ | L_{b132} | 3654 | Lₐ₁₁₃ | L_{b132} |
| 3655 | Lₐ₁₁₈ | L_{b132} | 3656 | Lₐ₁₁₉ | L_{b132} |
| 3657 | Lₐ₁₂₁ | L_{b132} | 3658 | Lₐ₁₂₅ | L_{b132} |
| 3659 | Lₐ₁₄₉ | L_{b132} | 3660 | Lₐ₁₅₄ | L_{b132} |
| 3661 | Lₐ₁₅₅ | L_{b132} | 3662 | Lₐ₁₅₇ | L_{b132} |
| 3663 | Lₐ₁₆₁ | L_{b132} | 3664 | Lₐ₂₀₅ | L_{b132} |
| 3665 | Lₐ₂₀₇ | L_{b132} | 3666 | Lₐ₂₁₀ | L_{b132} |
| 3667 | Lₐ₂₁₇ | L_{b132} | 3668 | Lₐ₂₁₉ | L_{b132} |
| 3669 | Lₐ₂₂₂ | L_{b132} | 3670 | Lₐ₂₂₉ | L_{b132} |
| 3671 | Lₐ₂₃₁ | L_{b132} | 3672 | Lₐ₂₃₄ | L_{b132} |
| 3673 | Lₐ₂₄₁ | L_{b132} | 3674 | Lₐ₂₄₃ | L_{b132} |
| 3675 | Lₐ₂₄₆ | L_{b132} | 3676 | Lₐ₂₅₃ | L_{b132} |
| 3677 | Lₐ₂₅₅ | L_{b132} | 3678 | Lₐ₂₅₈ | L_{b132} |
| 3679 | Lₐ₂₆₁ | L_{b132} | 3680 | Lₐ₂₆₃ | L_{b132} |
| 3681 | Lₐ₂₆₅ | L_{b132} | 3682 | Lₐ₂₆₇ | L_{b132} |
| 3683 | Lₐ₂₇₀ | L_{b132} | 3684 | Lₐ₂₇₇ | L_{b132} |
| 3685 | Lₐ₂₇₉ | L_{b132} | 3686 | Lₐ₂₈₂ | L_{b132} |
| 3687 | Lₐ₂₈₉ | L_{b132} | 3688 | Lₐ₂₉₁ | L_{b132} |
| 3689 | Lₐ₂₉₄ | L_{b132} | 3690 | Lₐ₃₀₁ | L_{b132} |
| 3691 | Lₐ₃₀₃ | L_{b132} | 3692 | Lₐ₃₀₆ | L_{b132} |
| 3693 | Lₐ₃₁₃ | L_{b132} | 3694 | Lₐ₃₁₅ | L_{b132} |
| 3695 | Lₐ₃₁₈ | L_{b132} | 3696 | Lₐ₃₂₅ | L_{b132} |
| 3697 | Lₐ₃₂₇ | L_{b132} | 3698 | Lₐ₃₃₀ | L_{b132} |
| 3699 | Lₐ₃₃₇ | L_{b132} | 3700 | Lₐ₃₃₉ | L_{b132} |
| 3701 | Lₐ₃₄₂ | L_{b132} | 3702 | Lₐ₃₄₉ | L_{b132} |
| 3703 | Lₐ₃₅₁ | L_{b132} | 3704 | Lₐ₃₅₄ | L_{b132} |
| 3705 | Lₐ₃₆₁ | L_{b132} | 3706 | Lₐ₃₆₃ | L_{b132} |
| 3707 | Lₐ₃₆₆ | L_{b132} | 3708 | Lₐ₃₇₁ | L_{b132} |
| 3709 | Lₐ₅₇₁ | L_{b132} | 3710 | Lₐ₅₇₃ | L_{b132} |
| 3711 | Lₐ₆₃₁ | L_{b132} | 3712 | Lₐ₆₃₃ | L_{b132} |
| 3713 | Lₐ₇₃₇ | L_{b132} | 3714 | Lₐ₉₃₇ | L_{b132} |
| 3715 | Lₐ₉₃₉ | L_{b132} | 3716 | Lₐ₉₉₇ | L_{b132} |
| 3717 | Lₐ₉₉₉ | L_{b132} | 3718 | Lₐ₁₀₀₉ | L_{b132} |
| 3719 | Lₐ₁₀₁₁ | L_{b132} | 3720 | Lₐ₁₀₂₁ | L_{b132} |
| 3721 | Lₐ₁₀₂₃ | L_{b132} | 3722 | Lₐ₁₁₀₃ | L_{b132} |
| 3723 | Lₐ₁₁₀₅ | L_{b132} | 3724 | Lₐ₁₁₀₈ | L_{b132} |
| 3725 | Lₐ₁₁₀₉ | L_{b132} | 3726 | Lₐ₁₁₁₁ | L_{b132} |
| 3727 | Lₐ₁₁₁₂ | L_{b132} | 3728 | Lₐ₁₁₁₅ | L_{b132} |
| 3729 | Lₐ₁₁₂₁ | L_{b132} | 3730 | Lₐ₁₁₂₆ | L_{b132} |
| 3731 | Lₐ₁₁₂₇ | L_{b132} | 3732 | Lₐ₁₁₂₉ | L_{b132} |
| 3733 | Lₐ₁₁₃₃ | L_{b132} | 3734 | Lₐ₁₁₅₇ | L_{b132} |
| 3735 | Lₐ₁₁₆₂ | L_{b132} | 3736 | Lₐ₁₁₆₃ | L_{b132} |
| 3737 | Lₐ₁₁₆₅ | L_{b132} | 3738 | Lₐ₁₁₆₉ | L_{b132} |
| 3739 | Lₐ₁₂₁₁ | L_{b132} | 3740 | Lₐ₁₂₁₆ | L_{b132} |
| 3741 | Lₐ₁₂₁₇ | L_{b132} | 3742 | Lₐ₁₂₁₉ | L_{b132} |
| 3743 | Lₐ₁₂₂₃ | L_{b132} | 3744 | Lₐ₁₂₄₇ | L_{b132} |
| 3745 | Lₐ₁₂₅₂ | L_{b132} | 3746 | Lₐ₁₂₅₃ | L_{b132} |
| 3747 | Lₐ₁₂₅₅ | L_{b132} | 3748 | Lₐ₁₂₅₉ | L_{b132} |
| 3749 | Lₐ₁₃₀₃ | L_{b132} | 3750 | Lₐ₁₃₀₅ | L_{b132} |
| 3751 | Lₐ₁₃₀₈ | L_{b132} | 3752 | Lₐ₁₃₁₅ | L_{b132} |
| 3753 | Lₐ₁₃₁₇ | L_{b132} | 3754 | Lₐ₁₃₂₀ | L_{b132} |
| 3755 | Lₐ₁₃₂₇ | L_{b132} | 3756 | Lₐ₁₃₂₉ | L_{b132} |
| 3757 | Lₐ₁₃₃₂ | L_{b132} | 3758 | Lₐ₁₃₃₉ | L_{b132} |
| 3759 | Lₐ₁₃₄₁ | L_{b132} | 3760 | Lₐ₁₃₄₄ | L_{b132} |
| 3761 | Lₐ₁₃₅₁ | L_{b132} | 3762 | Lₐ₁₃₅₃ | L_{b132} |
| 3763 | Lₐ₁₃₅₆ | L_{b132} | 3764 | Lₐ₁₃₅₉ | L_{b132} |
| 3765 | Lₐ₁₃₆₁ | L_{b132} | 3766 | Lₐ₁₃₆₃ | L_{b132} |
| 3767 | Lₐ₁₃₆₅ | L_{b132} | 3768 | Lₐ₁₃₆₈ | L_{b132} |
| 3769 | Lₐ₁₃₇₅ | L_{b132} | 3770 | Lₐ₁₃₇₇ | L_{b132} |
| 3771 | Lₐ₁₃₈₇ | L_{b132} | 3772 | Lₐ₁₃₈₉ | L_{b132} |
| 3773 | Lₐ₁₄₆₉ | L_{b132} | 3774 | Lₐ₁₆₆₉ | L_{b132} |
| 3775 | Lₐ₁₆₇₁ | L_{b132} | 3776 | Lₐ₁₇₂₉ | L_{b132} |
| 3777 | Lₐ₁₇₃₁ | L_{b132} | 3778 | Lₐ₁₇₄₁ | L_{b132} |
| 3779 | Lₐ₁₇₄₃ | L_{b132} | 3780 | Lₐ₁₇₅₃ | L_{b132} |
| 3781 | Lₐ₁₇₅₅ | L_{b132} | 3782 | Lₐ₁₈₃₅ | L_{b132} |
| 3783 | Lₐ₂₀₃₅ | L_{b132} | 3784 | Lₐ₂₀₃₇ | L_{b132} |
| 3785 | Lₐ₂₀₉₅ | L_{b132} | 3786 | Lₐ₂₀₉₇ | L_{b132} |
| 3787 | Lₐ₂₁₀₇ | L_{b132} | 3788 | Lₐ₂₁₀₉ | L_{b132} |
| 3789 | Lₐ₂₁₁₉ | L_{b132} | 3790 | Lₐ₂₁₂₁ | L_{b132} |
| 3791 | Lₐ₂₂₀₁ | L_{b132} | 3792 | Lₐ₂₄₀₁ | L_{b132} |
| 3793 | Lₐ₂₄₀₃ | L_{b132} | 3794 | Lₐ₂₄₆₁ | L_{b132} |
| 3795 | Lₐ₂₄₆₃ | L_{b132} | 3796 | Lₐ₂₄₇₃ | L_{b132} |
| 3797 | Lₐ₂₄₇₅ | L_{b132} | 3798 | Lₐ₂₄₈₅ | L_{b132} |
| 3799 | Lₐ₂₄₈₇ | L_{b132} | 3800 | Lₐ₂₅₆₇ | L_{b132} |
| 3801 | Lₐ₂₇₆₇ | L_{b132} | 3802 | Lₐ₂₇₆₉ | L_{b132} |
| 3803 | Lₐ₂₈₂₇ | L_{b132} | 3804 | Lₐ₂₈₂₉ | L_{b132} |
| 3805 | Lₐ₂₈₅₁ | L_{b132} | 3806 | Lₐ₂₈₅₃ | L_{b132} |
| 3807 | Lₐ₂₉₃₃ | L_{b132} | 3808 | Lₐ₂₉₃₅ | L_{b132} |
| 3809 | Lₐ₂₉₃₈ | L_{b132} | 3810 | Lₐ₂₉₃₉ | L_{b132} |
| 3811 | Lₐ₂₉₄₁ | L_{b132} | 3812 | Lₐ₂₉₄₂ | L_{b132} |
| 3813 | Lₐ₂₉₄₅ | L_{b132} | 3814 | Lₐ₂₉₅₁ | L_{b132} |
| 3815 | Lₐ₂₉₅₆ | L_{b132} | 3816 | Lₐ₂₉₅₇ | L_{b132} |
| 3817 | Lₐ₂₉₅₉ | L_{b132} | 3818 | Lₐ₂₉₆₃ | L_{b132} |
| 3819 | Lₐ₂₉₈₇ | L_{b132} | 3820 | Lₐ₂₉₉₂ | L_{b132} |
| 3821 | Lₐ₂₉₉₃ | L_{b132} | 3822 | Lₐ₂₉₉₅ | L_{b132} |
| 3823 | Lₐ₂₉₉₉ | L_{b132} | 3824 | Lₐ₃₀₄₁ | L_{b132} |
| 3825 | Lₐ₃₀₄₆ | L_{b132} | 3826 | Lₐ₃₀₄₇ | L_{b132} |
| 3827 | Lₐ₃₀₄₉ | L_{b132} | 3828 | Lₐ₃₀₅₃ | L_{b132} |
| 3829 | Lₐ₃₀₇₇ | L_{b132} | 3830 | Lₐ₃₀₈₂ | L_{b132} |
| 3831 | Lₐ₃₀₈₃ | L_{b132} | 3832 | Lₐ₃₀₈₅ | L_{b132} |
| 3833 | Lₐ₃₀₈₉ | L_{b132} | 3834 | Lₐ₃₁₃₃ | L_{b132} |
| 3835 | Lₐ₃₁₃₅ | L_{b132} | 3836 | Lₐ₃₁₃₈ | L_{b132} |
| 3837 | Lₐ₃₁₄₅ | L_{b132} | 3838 | Lₐ₃₁₄₇ | L_{b132} |
| 3839 | Lₐ₃₁₅₀ | L_{b132} | 3840 | Lₐ₃₁₆₉ | L_{b132} |
| 3841 | Lₐ₃₁₇₁ | L_{b132} | 3842 | Lₐ₃₁₇₄ | L_{b132} |
| 3843 | Lₐ₃₁₈₁ | L_{b132} | 3844 | Lₐ₃₁₈₃ | L_{b132} |
| 3845 | Lₐ₃₁₈₆ | L_{b132} | 3846 | Lₐ₃₁₈₉ | L_{b132} |
| 3847 | Lₐ₃₁₉₁ | L_{b132} | 3848 | Lₐ₃₁₉₃ | L_{b132} |
| 3849 | Lₐ₃₁₉₅ | L_{b132} | 3850 | Lₐ₃₁₉₈ | L_{b132} |
| 3851 | Lₐ₃₂₀₅ | L_{b132} | 3852 | Lₐ₃₂₀₇ | L_{b132} |
| 3853 | Lₐ₃₂₁₇ | L_{b132} | 3854 | Lₐ₃₂₁₉ | L_{b132} |
| 3855 | Lₐ₃₂₂₉ | L_{b132} | 3856 | Lₐ₃₂₃₁ | L_{b132} |
| 3857 | Lₐ₃₂₃₄ | L_{b132} | 3858 | Lₐ₃₂₄₁ | L_{b132} |
| 3859 | Lₐ₃₂₄₃ | L_{b132} | 3860 | Lₐ₃₂₄₆ | L_{b132} |
| 3861 | Lₐ₃₂₅₃ | L_{b132} | 3862 | Lₐ₃₂₅₅ | L_{b132} |
| 3863 | Lₐ₃₂₅₈ | L_{b132} | 3864 | Lₐ₃₂₆₅ | L_{b132} |
| 3865 | Lₐ₃₂₆₇ | L_{b132} | 3866 | Lₐ₃₂₇₀ | L_{b132} |
| 3867 | Lₐ₃₂₇₇ | L_{b132} | 3868 | Lₐ₃₂₇₉ | L_{b132} |
| 3869 | Lₐ₃₂₈₂ | L_{b132} | 3870 | Lₐ₃₂₈₉ | L_{b132} |
| 3871 | Lₐ₃₂₉₁ | L_{b132} | 3872 | Lₐ₃₂₉₄ | L_{b132} |
| 3873 | Lₐ₃₂₉₉ | L_{b132} | 3874 | Lₐ₃₄₉₉ | L_{b132} |
| 3875 | Lₐ₃₅₀₁ | L_{b132} | 3876 | Lₐ₃₅₅₉ | L_{b132} |
| 3877 | Lₐ₃₅₆₁ | L_{b132} | 3878 | Lₐ₃₅₇₁ | L_{b132} |
| 3879 | Lₐ₃₅₇₃ | L_{b132} | 3880 | Lₐ₃₅₈₃ | L_{b132} |
| 3881 | Lₐ₃₅₈₅ | L_{b132} | 3882 | Lₐ₃₆₆₅ | L_{b132} |
| 3883 | Lₐ₃₆₆₇ | L_{b132} | 3884 | Lₐ₃₆₇₀ | L_{b132} |
| 3885 | Lₐ₃₆₇₁ | L_{b132} | 3886 | Lₐ₃₆₇₃ | L_{b132} |
| 3887 | Lₐ₃₆₇₄ | L_{b132} | 3888 | Lₐ₃₆₇₇ | L_{b132} |
| 3889 | Lₐ₃₆₈₃ | L_{b132} | 3890 | Lₐ₃₆₈₈ | L_{b132} |
| 3891 | Lₐ₃₆₈₉ | L_{b132} | 3892 | Lₐ₃₆₉₁ | L_{b132} |
| 3893 | Lₐ₃₆₉₅ | L_{b132} | 3894 | Lₐ₃₇₁₉ | L_{b132} |
| 3895 | Lₐ₃₇₂₄ | L_{b132} | 3896 | Lₐ₃₇₂₅ | L_{b132} |
| 3897 | Lₐ₃₇₂₇ | L_{b132} | 3898 | Lₐ₃₇₃₁ | L_{b132} |
| 3899 | Lₐ₃₇₇₃ | L_{b132} | 3900 | Lₐ₃₇₇₈ | L_{b132} |
| 3901 | Lₐ₃₇₇₉ | L_{b132} | 3902 | Lₐ₃₇₈₁ | L_{b132} |
| 3903 | Lₐ₃₇₈₅ | L_{b132} | 3904 | Lₐ₃₈₀₉ | L_{b132} |
| 3905 | Lₐ₃₈₁₄ | L_{b132} | 3906 | Lₐ₃₈₁₅ | L_{b132} |
| 3907 | Lₐ₃₈₁₇ | L_{b132} | 3908 | Lₐ₃₈₂₁ | L_{b132} |
| 3909 | Lₐ₃₈₆₅ | L_{b132} | 3910 | Lₐ₃₈₆₇ | L_{b132} |
| 3911 | Lₐ₃₈₇₀ | L_{b132} | 3912 | Lₐ₃₈₇₇ | L_{b132} |
| 3913 | Lₐ₃₈₇₉ | L_{b132} | 3914 | Lₐ₃₈₈₂ | L_{b132} |
| 3915 | Lₐ₃₈₈₉ | L_{b132} | 3916 | Lₐ₃₈₉₁ | L_{b132} |
| 3917 | Lₐ₃₈₉₄ | L_{b132} | 3918 | Lₐ₃₉₀₁ | L_{b132} |
| 3919 | Lₐ₃₉₀₃ | L_{b132} | 3920 | Lₐ₃₉₀₆ | L_{b132} |
| 3921 | Lₐ₃₉₁₃ | L_{b132} | 3922 | Lₐ₃₉₁₅ | L_{b132} |
| 3923 | Lₐ₃₉₁₈ | L_{b132} | 3924 | Lₐ₃₉₂₁ | L_{b132} |
| 3925 | Lₐ₃₉₂₃ | L_{b132} | 3926 | Lₐ₃₉₂₄ | L_{b132} |
| 3927 | Lₐ₃₉₂₅ | L_{b132} | 3928 | Lₐ₃₉₂₇ | L_{b132} |
| 3929 | Lₐ₃₉₂₈ | L_{b132} | 3930 | Lₐ₃₉₃₀ | L_{b132} |
| 3931 | Lₐ₃₉₃₇ | L_{b132} | 3932 | Lₐ₃₉₃₉ | L_{b132} |
| 3933 | Lₐ₃₉₄₉ | L_{b132} | 3934 | Lₐ₃₉₅₁ | L_{b132} |
| 3935 | Lₐ₃₉₆₁ | L_{b132} | 3936 | Lₐ₃₉₆₃ | L_{b132} |
| 3937 | Lₐ₃₉₆₆ | L_{b132} | 3938 | Lₐ₃₉₇₃ | L_{b132} |
| 3939 | Lₐ₃₉₇₅ | L_{b132} | 3940 | Lₐ₃₉₇₈ | L_{b132} |
| 3941 | Lₐ₃₉₈₅ | L_{b132} | 3942 | Lₐ₃₉₈₇ | L_{b132} |
| 3943 | Lₐ₃₉₉₀ | L_{b132} | 3944 | Lₐ₃₉₉₇ | L_{b132} |
| 3945 | Lₐ₃₉₉₉ | L_{b132} | 3946 | Lₐ₄₀₀₂ | L_{b132} |
| 3947 | Lₐ₄₀₀₉ | L_{b132} | 3948 | Lₐ₄₀₁₁ | L_{b132} |
| 3949 | Lₐ₄₀₁₄ | L_{b132} | 3950 | Lₐ₄₀₂₁ | L_{b132} |
| 3951 | Lₐ₄₀₂₃ | L_{b132} | 3952 | Lₐ₄₀₂₆ | L_{b132} |
| 3953 | Lₐ₄₀₃₁ | L_{b132} | 3954 | Lₐ₄₀₃₆ | L_{b132} |
| 3955 | Lₐ₄₀₃₇ | L_{b132} | 3956 | Lₐ₄₀₃₉ | L_{b132} |
| 3957 | Lₐ₄₀₄₃ | L_{b132} | 3958 | Lₐ₄₀₄₉ | L_{b132} |
| 3959 | Lₐ₄₀₅₄ | L_{b132} | 3960 | Lₐ₄₀₅₅ | L_{b132} |
| 3961 | Lₐ₄₀₅₇ | L_{b132} | 3962 | Lₐ₄₀₆₁ | L_{b132} |
| 3963 | Lₐ₄₁₃₉ | L_{b132} | 3964 | Lₐ₄₁₄₄ | L_{b132} |
| 3965 | Lₐ₄₁₄₅ | L_{b132} | 3966 | Lₐ₄₁₄₇ | L_{b132} |
| 3967 | Lₐ₄₁₅₁ | L_{b132} | 3968 | Lₐ₄₂₃₁ | L_{b132} |
| 3969 | Lₐ₄₂₃₃ | L_{b132} | 3970 | Lₐ₄₂₃₆ | L_{b132} |
| 3971 | Lₐ₄₂₄₃ | L_{b132} | 3972 | Lₐ₄₂₄₅ | L_{b132} |
| 3973 | Lₐ₄₂₄₈ | L_{b132} | 3974 | Lₐ₄₂₆₇ | L_{b132} |
| 3975 | Lₐ₄₂₆₉ | L_{b132} | 3976 | Lₐ₄₂₇₂ | L_{b132} |
| 3977 | Lₐ₄₂₈₇ | L_{b132} | 3978 | Lₐ₄₂₈₉ | L_{b132} |
| 3979 | Lₐ₄₂₉₁ | L_{b132} | 3980 | Lₐ₄₂₉₃ | L_{b132} |
| 3981 | Lₐ₄₂₉₄ | L_{b132} | 3982 | Lₐ₄₂₉₆ | L_{b132} |
| 3983 | Lₐ₄₃₀₃ | L_{b132} | 3984 | Lₐ₄₃₀₅ | L_{b132} |
| 3985 | Lₐ₄₃₁₅ | L_{b132} | 3986 | Lₐ₄₃₁₇ | L_{b132} |
| 3987 | Lₐ₄₃₂₇ | L_{b132} | 3988 | Lₐ₄₃₂₉ | L_{b132} |
| 3989 | Lₐ₄₃₃₂ | L_{b132} | 3990 | Lₐ₄₃₃₉ | L_{b132} |
| 3991 | Lₐ₄₃₄₁ | L_{b132} | 3992 | Lₐ₄₃₄₄ | L_{b132} |
| 3993 | Lₐ₄₃₆₃ | L_{b132} | 3994 | Lₐ₄₃₆₅ | L_{b132} |
| 3995 | Lₐ₄₃₆₈ | L_{b132} | 3996 | Lₐ₄₃₇₅ | L_{b132} |
| 3997 | Lₐ₄₃₇₇ | L_{b132} | 3998 | Lₐ₄₃₈₀ | L_{b132} |
| 3999 | Lₐ₄₃₉₇ | L_{b132} | 4000 | Lₐ₄₃₉₉ | L_{b132} |
| 4001 | Lₐ₄₄₀₂ | L_{b132} | 4002 | Lₐ₄₄₀₃ | L_{b132} |
| 4003 | Lₐ₄₄₀₅ | L_{b132} | 4004 | Lₐ₄₄₀₆ | L_{b132} |
| 4005 | Lₐ₄₄₀₉ | L_{b132} | 4006 | Lₐ₄₄₁₅ | L_{b132} |
| 4007 | Lₐ₄₄₂₀ | L_{b132} | 4008 | Lₐ₄₄₂₃ | L_{b132} |
| 4009 | Lₐ₄₄₂₇ | L_{b132} | 4010 | Lₐ₄₄₅₁ | L_{b132} |
| 4011 | Lₐ₄₄₅₆ | L_{b132} | 4012 | Lₐ₄₄₅₇ | L_{b132} |
| 4013 | Lₐ₄₄₅₉ | L_{b132} | 4014 | Lₐ₄₄₆₃ | L_{b132} |
| 4015 | Lₐ₄₅₉₇ | L_{b132} | 4016 | Lₐ₄₅₉₉ | L_{b132} |
| 4017 | Lₐ₄₆₀₂ | L_{b132} | 4018 | Lₐ₄₆₀₉ | L_{b132} |
| 4019 | Lₐ₄₆₁₁ | L_{b132} | 4020 | Lₐ₄₆₂₁ | L_{b132} |
| 4021 | Lₐ₄₆₂₃ | L_{b132} | 4022 | Lₐ₄₆₃₃ | L_{b132} |
| 4023 | Lₐ₄₆₃₅ | L_{b132} | 4024 | Lₐ₄₆₄₅ | L_{b132} |
| 4025 | Lₐ₄₆₄₇ | L_{b132} | 4026 | Lₐ₄₆₅₃ | L_{b132} |
| 4027 | Lₐ₄₆₅₅ | L_{b132} | 4028 | Lₐ₄₆₅₇ | L_{b132} |
| 4029 | Lₐ₄₆₅₉ | L_{b132} | 4030 | Lₐ₄₆₆₂ | L_{b132} |
| 4031 | Lₐ₄₆₆₉ | L_{b132} | 4032 | Lₐ₄₆₇₁ | L_{b132} |
| 4033 | Lₐ₄₆₈₁ | L_{b132} | 4034 | Lₐ₄₆₈₃ | L_{b132} |
| 4035 | Lₐ₄₆₉₃ | L_{b132} | 4036 | Lₐ₄₆₉₅ | L_{b132} |
| 4037 | Lₐ₄₆₉₈ | L_{b132} | 4038 | Lₐ₄₇₀₅ | L_{b132} |
| 4039 | Lₐ₄₇₀₇ | L_{b132} | 4040 | Lₐ₄₇₁₀ | L_{b132} |
| 4041 | Lₐ₄₇₂₉ | L_{b132} | 4042 | Lₐ₄₇₃₁ | L_{b132} |
| 4043 | Lₐ₄₇₃₄ | L_{b132} | 4044 | Lₐ₄₇₆₃ | L_{b132} |
| 4045 | Lₐ₄₉₆₃ | L_{b132} | 4046 | Lₐ₄₉₆₅ | L_{b132} |
| 4047 | Lₐ₄₉₆₈ | L_{b132} | 4048 | Lₐ₅₀₂₃ | L_{b132} |
| 4049 | Lₐ₅₀₂₅ | L_{b132} | 4050 | Lₐ₅₀₃₅ | L_{b132} |
| 4051 | Lₐ₅₀₃₇ | L_{b132} | 4052 | Lₐ₅₀₄₇ | L_{b132} |
| 4053 | Lₐ₅₀₄₉ | L_{b132} | 4054 | Lₐ₅₁₂₉ | L_{b132} |
| 4055 | Lₐ₅₁₃₄ | L_{b132} | 4056 | Lₐ₅₁₃₅ | L_{b132} |
| 4057 | Lₐ₅₁₃₇ | L_{b132} | 4058 | Lₐ₅₁₄₁ | L_{b132} |
| 4059 | Lₐ₅₁₄₇ | L_{b132} | 4060 | Lₐ₅₁₅₂ | L_{b132} |
| 4061 | Lₐ₅₁₅₃ | L_{b132} | 4062 | Lₐ₅₁₅₅ | L_{b132} |
| 4063 | Lₐ₅₁₅₉ | L_{b132} | 4064 | Lₐ₅₂₃₇ | L_{b132} |
| 4065 | Lₐ₅₂₄₂ | L_{b132} | 4066 | Lₐ₅₂₄₃ | L_{b132} |
| 4067 | Lₐ₅₂₄₅ | L_{b132} | 4068 | Lₐ₅₂₄₉ | L_{b132} |
| 4069 | Lₐ₅₃₂₉ | L_{b132} | 4070 | Lₐ₅₃₃₁ | L_{b132} |
| 4071 | Lₐ₅₃₃₄ | L_{b132} | 4072 | Lₐ₅₃₄₁ | L_{b132} |
| 4073 | Lₐ₅₃₄₃ | L_{b132} | 4074 | Lₐ₅₃₄₆ | L_{b132} |
| 4075 | Lₐ₅₃₆₅ | L_{b132} | 4076 | Lₐ₅₃₆₇ | L_{b132} |
| 4077 | Lₐ₅₃₇₀ | L_{b132} | 4078 | Lₐ₅₃₈₅ | L_{b132} |
| 4079 | Lₐ₅₃₈₇ | L_{b132} | 4080 | Lₐ₅₃₈₉ | L_{b132} |
| 4081 | Lₐ₅₃₉₁ | L_{b132} | 4082 | Lₐ₅₃₉₂ | L_{b132} |
| 4083 | Lₐ₅₃₉₄ | L_{b132} | 4084 | Lₐ₅₄₀₁ | L_{b132} |
| 4085 | Lₐ₅₄₀₃ | L_{b132} | 4086 | Lₐ₅₄₁₃ | L_{b132} |
| 4087 | Lₐ₅₄₁₅ | L_{b132} | 4088 | Lₐ₅₄₂₅ | L_{b132} |
| 4089 | Lₐ₅₄₂₇ | L_{b132} | 4090 | Lₐ₅₄₃₀ | L_{b132} |
| 4091 | Lₐ₅₄₆₁ | L_{b132} | 4092 | Lₐ₅₄₆₃ | L_{b132} |
| 4093 | Lₐ₅₄₆₆ | L_{b132} | 4094 | Lₐ₅₄₉₅ | L_{b132} |
| 4095 | Lₐ₅₆₉₅ | L_{b132} | 4096 | Lₐ₅₆₉₇ | L_{b132} |
| 4097 | Lₐ₅₇₅₅ | L_{b132} | 4098 | Lₐ₅₇₅₇ | L_{b132} |
| 4099 | Lₐ₅₇₆₀ | L_{b132} | 4100 | Lₐ₅₇₆₇ | L_{b132} |
| 4101 | Lₐ₅₇₆₉ | L_{b132} | 4102 | Lₐ₅₇₇₉ | L_{b132} |
| 4103 | Lₐ₅₇₈₁ | L_{b132} | 4104 | Lₐ₅₈₆₁ | L_{b132} |
| 4105 | Lₐ₅₈₆₆ | L_{b132} | 4106 | Lₐ₅₈₆₇ | L_{b132} |
| 4107 | Lₐ₅₈₆₉ | L_{b132} | 4108 | Lₐ₅₈₇₃ | L_{b132} |
| 4109 | Lₐ₅₈₇₉ | L_{b132} | 4110 | Lₐ₅₈₈₄ | L_{b132} |
| 4111 | Lₐ₅₈₈₅ | L_{b132} | 4112 | Lₐ₅₈₈₇ | L_{b132} |
| 4113 | Lₐ₅₈₉₁ | L_{b132} | 4114 | Lₐ₅₉₆₉ | L_{b132} |
| 4115 | Lₐ₅₉₇₄ | L_{b132} | 4116 | Lₐ₅₉₇₅ | L_{b132} |
| 4117 | Lₐ₅₉₇₇ | L_{b132} | 4118 | Lₐ₅₉₈₁ | L_{b132} |
| 4119 | Lₐ₆₀₅₇ | L_{b132} | 4120 | Lₐ₆₀₅₉ | L_{b132} |
| 4121 | Lₐ₆₀₆₁ | L_{b132} | 4122 | Lₐ₆₀₆₃ | L_{b132} |
| 4123 | Lₐ₆₀₆₆ | L_{b132} | 4124 | Lₐ₆₀₇₃ | L_{b132} |
| 4125 | Lₐ₆₀₇₅ | L_{b132} | 4126 | Lₐ₆₀₇₈ | L_{b132} |
| 4127 | Lₐ₆₀₈₅ | L_{b132} | 4128 | Lₐ₆₀₈₇ | L_{b132} |
| 4129 | Lₐ₆₀₉₇ | L_{b132} | 4130 | Lₐ₆₀₉₉ | L_{b132} |
| 4131 | Lₐ₆₁₁₇ | L_{b132} | 4132 | Lₐ₆₁₁₉ | L_{b132} |
| 4133 | Lₐ₆₁₂₁ | L_{b132} | 4134 | Lₐ₆₁₂₃ | L_{b132} |
| 4135 | Lₐ₆₁₂₆ | L_{b132} | 4136 | Lₐ₆₁₃₃ | L_{b132} |
| 4137 | Lₐ₆₁₃₅ | L_{b132} | 4138 | Lₐ₆₁₄₅ | L_{b132} |
| 4139 | Lₐ₆₁₄₇ | L_{b132} | 4140 | Lₐ₆₁₅₇ | L_{b132} |
| 4141 | Lₐ₆₁₅₉ | L_{b132} | 4142 | Lₐ₆₁₆₂ | L_{b132} |
| 4143 | Lₐ₆₁₆₉ | L_{b132} | 4144 | Lₐ₆₁₇₁ | L_{b132} |
| 4145 | Lₐ₆₁₇₄ | L_{b132} | 4146 | Lₐ₆₁₉₃ | L_{b132} |
| 4147 | Lₐ₆₁₉₅ | L_{b132} | 4148 | Lₐ₆₁₉₈ | L_{b132} |
| 4149 | Lₐ₆₂₀₅ | L_{b132} | 4150 | Lₐ₆₂₀₇ | L_{b132} |
| 4151 | Lₐ₆₂₂₇ | L_{b132} | 4152 | Lₐ₆₂₃₂ | L_{b132} |
| 4153 | Lₐ₆₂₃₃ | L_{b132} | 4154 | Lₐ₆₂₃₅ | L_{b132} |
| 4155 | Lₐ₆₂₃₉ | L_{b132} | 4156 | Lₐ₆₂₄₅ | L_{b132} |
| 4157 | Lₐ₆₂₅₀ | L_{b132} | 4158 | Lₐ₆₂₅₁ | L_{b132} |
| 4159 | Lₐ₆₂₅₃ | L_{b132} | 4160 | Lₐ₆₂₅₇ | L_{b132} |
| 4161 | Lₐ₆₃₃₅ | L_{b132} | 4162 | Lₐ₆₃₄₀ | L_{b132} |
| 4163 | Lₐ₆₃₄₁ | L_{b132} | 4164 | Lₐ₆₃₄₃ | L_{b132} |
| 4165 | Lₐ₆₃₄₇ | L_{b132} | 4166 | Lₐ₆₄₂₃ | L_{b132} |
| 4167 | Lₐ₆₄₂₅ | L_{b132} | 4168 | Lₐ₆₄₂₇ | L_{b132} |
| 4169 | Lₐ₆₄₂₉ | L_{b132} | 4170 | Lₐ₆₄₃₂ | L_{b132} |
| 4171 | Lₐ₆₄₃₉ | L_{b132} | 4172 | Lₐ₆₄₄₁ | L_{b132} |
| 4173 | Lₐ₆₄₄₄ | L_{b132} | 4174 | Lₐ₆₄₆₃ | L_{b132} |
| 4175 | Lₐ₆₄₆₅ | L_{b132} | 4176 | Lₐ₆₄₆₈ | L_{b132} |
| 4177 | Lₐ₆₄₈₃ | L_{b132} | 4178 | Lₐ₆₄₈₅ | L_{b132} |
| 4179 | Lₐ₆₄₈₇ | L_{b132} | 4180 | Lₐ₆₄₈₉ | L_{b132} |
| 4181 | Lₐ₆₄₉₂ | L_{b132} | 4182 | Lₐ₆₄₉₉ | L_{b132} |
| 4183 | Lₐ₆₅₀₁ | L_{b132} | 4184 | Lₐ₆₅₁₁ | L_{b132} |
| 4185 | Lₐ₆₅₁₃ | L_{b132} | 4186 | Lₐ₆₅₂₃ | L_{b132} |
| 4187 | Lₐ₆₅₂₅ | L_{b132} | 4188 | Lₐ₆₅₂₈ | L_{b132} |
| 4189 | Lₐ₆₅₃₅ | L_{b132} | 4190 | Lₐ₆₅₃₇ | L_{b132} |
| 4191 | Lₐ₆₅₄₀ | L_{b132} | 4192 | Lₐ₆₅₅₉ | L_{b132} |
| 4193 | Lₐ₆₅₆₁ | L_{b132} | 4194 | Lₐ₆₅₆₄ | L_{b132} |
| 4195 | Lₐ₆₅₇₁ | L_{b132} | 4196 | Lₐ₆₅₇₃ | L_{b132} |
| 4197 | Lₐ₆₅₉₃ | L_{b132} | 4198 | Lₐ₆₅₉₈ | L_{b132} |
| 4199 | Lₐ₆₅₉₉ | L_{b132} | 4200 | Lₐ₆₆₀₁ | L_{b132} |
| 4201 | Lₐ₆₆₀₅ | L_{b132} | 4202 | Lₐ₆₆₁₁ | L_{b132} |
| 4203 | Lₐ₆₆₁₆ | L_{b132} | 4204 | Lₐ₆₆₁₉ | L_{b132} |
| 4205 | Lₐ₆₆₂₃ | L_{b132} | 4206 | Lₐ₆₇₀₀ | L_{b132} |
| 4207 | Lₐ₆₇₀₁ | L_{b132} | 4208 | Lₐ₆₇₀₃ | L_{b132} |
| 4209 | Lₐ₆₇₀₆ | L_{b132} | 4210 | Lₐ₆₇₀₇ | L_{b132} |
| 4211 | Lₐ₆₇₀₉ | L_{b132} | 4212 | Lₐ₆₇₁₃ | L_{b132} |
| 4213 | Lₐ₆₇₄₂ | L_{b132} | 4214 | Lₐ₆₇₄₅ | L_{b132} |
| 4215 | Lₐ₆₇₉₃ | L_{b132} | 4216 | Lₐ₆₇₉₅ | L_{b132} |
| 4217 | Lₐ₆₇₉₈ | L_{b132} | 4218 | Lₐ₆₈₀₅ | L_{b132} |
| 4219 | Lₐ₆₈₀₇ | L_{b132} | 4220 | Lₐ₆₈₁₀ | L_{b132} |
| 4221 | Lₐ₆₈₂₉ | L_{b132} | 4222 | Lₐ₆₈₃₁ | L_{b132} |
| 4223 | Lₐ₆₈₃₄ | L_{b132} | 4224 | Lₐ₆₈₄₉ | L_{b132} |
| 4225 | Lₐ₆₈₅₁ | L_{b132} | 4226 | Lₐ₆₈₅₃ | L_{b132} |
| 4227 | Lₐ₆₈₅₅ | L_{b132} | 4228 | Lₐ₆₈₅₈ | L_{b132} |
| 4229 | Lₐ₆₈₆₅ | L_{b132} | 4230 | Lₐ₆₈₆₇ | L_{b132} |
| 4231 | Lₐ₆₈₇₇ | L_{b132} | 4232 | Lₐ₆₈₇₉ | L_{b132} |
| 4233 | Lₐ₆₈₈₉ | L_{b132} | 4234 | Lₐ₆₈₉₁ | L_{b132} |
| 4235 | Lₐ₆₈₉₄ | L_{b132} | 4236 | Lₐ₆₉₀₁ | L_{b132} |
| 4237 | Lₐ₆₉₀₃ | L_{b132} | 4238 | Lₐ₆₉₂₅ | L_{b132} |
| 4239 | Lₐ₆₉₂₇ | L_{b132} | 4240 | Lₐ₆₉₃₀ | L_{b132} |
| 4241 | Lₐ₆₉₃₇ | L_{b132} | 4242 | Lₐ₆₉₃₉ | L_{b132} |
| 4243 | Lₐ₅ | L_{b133} | 4244 | Lₐ₇ | L_{b133} |
| 4245 | Lₐ₁₀ | L_{b133} | 4246 | Lₐ₁₁ | L_{b133} |
| 4247 | Lₐ₁₃ | L_{b133} | 4248 | Lₐ₁₄ | L_{b133} |
| 4249 | Lₐ₁₇ | L_{b133} | 4250 | Lₐ₂₃ | L_{b133} |
| 4251 | Lₐ₂₈ | L_{b133} | 4252 | Lₐ₂₉ | L_{b133} |
| 4253 | Lₐ₃₁ | L_{b133} | 4254 | Lₐ₃₅ | L_{b133} |
| 4255 | Lₐ₅₉ | L_{b133} | 4256 | Lₐ₆₄ | L_{b133} |
| 4257 | Lₐ₆₅ | L_{b133} | 4258 | Lₐ₆₇ | L_{b133} |
| 4259 | Lₐ₇₁ | L_{b133} | 4260 | Lₐ₁₁₃ | L_{b133} |
| 4261 | Lₐ₁₁₈ | L_{b133} | 4262 | Lₐ₁₁₉ | L_{b133} |
| 4263 | Lₐ₁₂₁ | L_{b133} | 4264 | Lₐ₁₂₅ | L_{b133} |
| 4265 | Lₐ₁₄₉ | L_{b133} | 4266 | Lₐ₁₅₄ | L_{b133} |
| 4267 | Lₐ₁₅₅ | L_{b133} | 4268 | Lₐ₁₅₇ | L_{b133} |
| 4269 | Lₐ₁₆₁ | L_{b133} | 4270 | Lₐ₂₀₅ | L_{b133} |
| 4271 | Lₐ₂₀₇ | L_{b133} | 4272 | Lₐ₂₁₀ | L_{b133} |
| 4273 | Lₐ₂₁₇ | L_{b133} | 4274 | Lₐ₂₁₉ | L_{b133} |
| 4275 | Lₐ₂₂₂ | L_{b133} | 4276 | Lₐ₂₂₉ | L_{b133} |
| 4277 | Lₐ₂₃₁ | L_{b133} | 4278 | Lₐ₂₃₄ | L_{b133} |
| 4279 | Lₐ₂₄₁ | L_{b133} | 4280 | Lₐ₂₄₃ | L_{b133} |
| 4281 | Lₐ₂₄₆ | L_{b133} | 4282 | Lₐ₂₅₃ | L_{b133} |
| 4283 | Lₐ₂₅₅ | L_{b133} | 4284 | Lₐ₂₅₈ | L_{b133} |
| 4285 | Lₐ₂₆₁ | L_{b133} | 4286 | Lₐ₂₆₃ | L_{b133} |
| 4287 | Lₐ₂₆₅ | L_{b133} | 4288 | Lₐ₂₆₇ | L_{b133} |
| 4289 | Lₐ₂₇₀ | L_{b133} | 4290 | Lₐ₂₇₇ | L_{b133} |
| 4291 | Lₐ₂₇₉ | L_{b133} | 4292 | Lₐ₂₈₂ | L_{b133} |
| 4293 | Lₐ₂₈₉ | L_{b133} | 4294 | Lₐ₂₉₁ | L_{b133} |
| 4295 | Lₐ₂₉₄ | L_{b133} | 4296 | Lₐ₃₀₁ | L_{b133} |
| 4297 | Lₐ₃₀₃ | L_{b133} | 4298 | Lₐ₃₀₆ | L_{b133} |
| 4299 | Lₐ₃₁₃ | L_{b133} | 4300 | Lₐ₃₁₅ | L_{b133} |
| 4301 | Lₐ₃₁₈ | L_{b133} | 4302 | Lₐ₃₂₅ | L_{b133} |
| 4303 | Lₐ₃₂₇ | L_{b133} | 4304 | Lₐ₃₃₀ | L_{b133} |
| 4305 | Lₐ₃₃₇ | L_{b133} | 4306 | Lₐ₃₃₉ | L_{b133} |
| 4307 | Lₐ₃₄₂ | L_{b133} | 4308 | Lₐ₃₄₉ | L_{b133} |
| 4309 | Lₐ₃₅₁ | L_{b133} | 4310 | Lₐ₃₅₄ | L_{b133} |
| 4311 | Lₐ₃₆₁ | L_{b133} | 4312 | Lₐ₃₆₃ | L_{b133} |
| 4313 | Lₐ₃₆₆ | L_{b133} | 4314 | Lₐ₃₇₁ | L_{b133} |
| 4315 | Lₐ₅₇₁ | L_{b133} | 4316 | Lₐ₅₇₃ | L_{b133} |
| 4317 | Lₐ₆₃₁ | L_{b133} | 4318 | Lₐ₆₃₃ | L_{b133} |
| 4319 | Lₐ₇₃₇ | L_{b133} | 4320 | Lₐ₉₃₇ | L_{b133} |
| 4321 | Lₐ₉₃₉ | L_{b133} | 4322 | Lₐ₉₉₇ | L_{b133} |
| 4323 | Lₐ₉₉₉ | L_{b133} | 4324 | Lₐ₁₀₀₉ | L_{b133} |
| 4325 | Lₐ₁₀₁₁ | L_{b133} | 4326 | Lₐ₁₀₂₁ | L_{b133} |
| 4327 | Lₐ₁₀₂₃ | L_{b133} | 4328 | Lₐ₁₁₀₃ | L_{b133} |
| 4329 | Lₐ₁₁₀₅ | L_{b133} | 4330 | Lₐ₁₁₀₈ | L_{b133} |
| 4331 | Lₐ₁₁₀₉ | L_{b133} | 4332 | Lₐ₁₁₁₁ | L_{b133} |
| 4333 | Lₐ₁₁₁₂ | L_{b133} | 4334 | Lₐ₁₁₁₅ | L_{b133} |
| 4335 | Lₐ₁₁₂₁ | L_{b133} | 4336 | Lₐ₁₁₂₆ | L_{b133} |
| 4337 | Lₐ₁₁₂₇ | L_{b133} | 4338 | Lₐ₁₁₂₉ | L_{b133} |
| 4339 | Lₐ₁₁₃₃ | L_{b133} | 4340 | Lₐ₁₁₅₇ | L_{b133} |
| 4341 | Lₐ₁₁₆₂ | L_{b133} | 4342 | Lₐ₁₁₆₃ | L_{b133} |
| 4343 | Lₐ₁₁₆₅ | L_{b133} | 4344 | Lₐ₁₁₆₉ | L_{b133} |
| 4345 | Lₐ₁₂₁₁ | L_{b133} | 4346 | Lₐ₁₂₁₆ | L_{b133} |
| 4347 | Lₐ₁₂₁₇ | L_{b133} | 4348 | Lₐ₁₂₁₉ | L_{b133} |
| 4349 | Lₐ₁₂₂₃ | L_{b133} | 4350 | Lₐ₁₂₄₇ | L_{b133} |
| 4351 | Lₐ₁₂₅₂ | L_{b133} | 4352 | Lₐ₁₂₅₃ | L_{b133} |
| 4353 | Lₐ₁₂₅₅ | L_{b133} | 4354 | Lₐ₁₂₅₉ | L_{b133} |
| 4355 | Lₐ₁₃₀₃ | L_{b133} | 4356 | Lₐ₁₃₀₅ | L_{b133} |
| 4357 | Lₐ₁₃₀₈ | L_{b133} | 4358 | Lₐ₁₃₁₅ | L_{b133} |
| 4359 | Lₐ₁₃₁₇ | L_{b133} | 4360 | Lₐ₁₃₂₀ | L_{b133} |
| 4361 | Lₐ₁₃₂₇ | L_{b133} | 4362 | Lₐ₁₃₂₉ | L_{b133} |
| 4363 | Lₐ₁₃₃₂ | L_{b133} | 4364 | Lₐ₁₃₃₉ | L_{b133} |
| 4365 | Lₐ₁₃₄₁ | L_{b133} | 4366 | Lₐ₁₃₄₄ | L_{b133} |
| 4367 | Lₐ₁₃₅₁ | L_{b133} | 4368 | Lₐ₁₃₅₃ | L_{b133} |
| 4369 | Lₐ₁₃₅₆ | L_{b133} | 4370 | Lₐ₁₃₅₉ | L_{b133} |
| 4371 | Lₐ₁₃₆₁ | L_{b133} | 4372 | Lₐ₁₃₆₃ | L_{b133} |
| 4373 | Lₐ₁₃₆₅ | L_{b133} | 4374 | Lₐ₁₃₆₈ | L_{b133} |
| 4375 | Lₐ₁₃₇₅ | L_{b133} | 4376 | Lₐ₁₃₇₇ | L_{b133} |
| 4377 | Lₐ₁₃₈₇ | L_{b133} | 4378 | Lₐ₁₃₈₉ | L_{b133} |
| 4379 | Lₐ₁₄₆₉ | L_{b133} | 4380 | Lₐ₁₆₆₉ | L_{b133} |
| 4381 | Lₐ₁₆₇₁ | L_{b133} | 4382 | Lₐ₁₇₂₉ | L_{b133} |
| 4383 | Lₐ₁₇₃₁ | L_{b133} | 4384 | Lₐ₁₇₄₁ | L_{b133} |
| 4385 | Lₐ₁₇₄₃ | L_{b133} | 4386 | Lₐ₁₇₅₃ | L_{b133} |
| 4387 | Lₐ₁₇₅₅ | L_{b133} | 4388 | Lₐ₁₈₃₅ | L_{b133} |
| 4389 | Lₐ₂₀₃₅ | L_{b133} | 4390 | Lₐ₂₀₃₇ | L_{b133} |
| 4391 | Lₐ₂₀₉₅ | L_{b133} | 4392 | Lₐ₂₀₉₇ | L_{b133} |
| 4393 | Lₐ₂₁₀₇ | L_{b133} | 4394 | Lₐ₂₁₀₉ | L_{b133} |
| 4395 | Lₐ₂₁₁₉ | L_{b133} | 4396 | Lₐ₂₁₂₁ | L_{b133} |
| 4397 | Lₐ₂₂₀₁ | L_{b133} | 4398 | Lₐ₂₄₀₁ | L_{b133} |
| 4399 | Lₐ₂₄₀₃ | L_{b133} | 4400 | Lₐ₂₄₆₁ | L_{b133} |
| 4401 | Lₐ₂₄₆₃ | L_{b133} | 4402 | Lₐ₂₄₇₃ | L_{b133} |
| 4403 | Lₐ₂₄₇₅ | L_{b133} | 4404 | Lₐ₂₄₈₅ | L_{b133} |
| 4405 | Lₐ₂₄₈₇ | L_{b133} | 4406 | Lₐ₂₅₆₇ | L_{b133} |
| 4407 | Lₐ₂₇₆₇ | L_{b133} | 4408 | Lₐ₂₇₆₉ | L_{b133} |
| 4409 | Lₐ₂₈₂₇ | L_{b133} | 4410 | Lₐ₂₈₂₉ | L_{b133} |
| 4411 | Lₐ₂₈₅₁ | L_{b133} | 4412 | Lₐ₂₈₅₃ | L_{b133} |
| 4413 | Lₐ₂₉₃₃ | L_{b133} | 4414 | Lₐ₂₉₃₅ | L_{b133} |
| 4415 | Lₐ₂₉₃₈ | L_{b133} | 4416 | Lₐ₂₉₃₉ | L_{b133} |
| 4417 | Lₐ₂₉₄₁ | L_{b133} | 4418 | Lₐ₂₉₄₂ | L_{b133} |
| 4419 | Lₐ₂₉₄₅ | L_{b133} | 4420 | Lₐ₂₉₅₁ | L_{b133} |
| 4421 | Lₐ₂₉₅₆ | L_{b133} | 4422 | Lₐ₂₉₅₇ | L_{b133} |
| 4423 | Lₐ₂₉₅₉ | L_{b133} | 4424 | Lₐ₂₉₆₃ | L_{b133} |
| 4425 | Lₐ₂₉₈₇ | L_{b133} | 4426 | Lₐ₂₉₉₂ | L_{b133} |
| 4427 | Lₐ₂₉₉₃ | L_{b133} | 4428 | Lₐ₂₉₉₅ | L_{b133} |
| 4429 | Lₐ₂₉₉₉ | L_{b133} | 4430 | Lₐ₃₀₄₁ | L_{b133} |
| 4431 | Lₐ₃₀₄₆ | L_{b133} | 4432 | Lₐ₃₀₄₇ | L_{b133} |
| 4433 | Lₐ₃₀₄₉ | L_{b133} | 4434 | Lₐ₃₀₅₃ | L_{b133} |
| 4435 | Lₐ₃₀₇₇ | L_{b133} | 4436 | Lₐ₃₀₈₂ | L_{b133} |
| 4437 | Lₐ₃₀₈₃ | L_{b133} | 4438 | Lₐ₃₀₈₅ | L_{b133} |
| 4439 | Lₐ₃₀₈₉ | L_{b133} | 4440 | Lₐ₃₁₃₃ | L_{b133} |
| 4441 | Lₐ₃₁₃₅ | L_{b133} | 4442 | Lₐ₃₁₃₈ | L_{b133} |
| 4443 | Lₐ₃₁₄₅ | L_{b133} | 4444 | Lₐ₃₁₄₇ | L_{b133} |
| 4445 | Lₐ₃₁₅₀ | L_{b133} | 4446 | Lₐ₃₁₆₉ | L_{b133} |
| 4447 | Lₐ₃₁₇₁ | L_{b133} | 4448 | Lₐ₃₁₇₄ | L_{b133} |
| 4449 | Lₐ₃₁₈₁ | L_{b133} | 4450 | Lₐ₃₁₈₃ | L_{b133} |
| 4451 | Lₐ₃₁₈₆ | L_{b133} | 4452 | Lₐ₃₁₈₉ | L_{b133} |
| 4453 | Lₐ₃₁₉₁ | L_{b133} | 4454 | Lₐ₃₁₉₃ | L_{b133} |
| 4455 | Lₐ₃₁₉₅ | L_{b133} | 4456 | Lₐ₃₁₉₈ | L_{b133} |
| 4457 | Lₐ₃₂₀₅ | L_{b133} | 4458 | Lₐ₃₂₀₇ | L_{b133} |
| 4459 | Lₐ₃₂₁₇ | L_{b133} | 4460 | Lₐ₃₂₁₉ | L_{b133} |
| 4461 | Lₐ₃₂₂₉ | L_{b133} | 4462 | Lₐ₃₂₃₁ | L_{b133} |
| 4463 | Lₐ₃₂₃₄ | L_{b133} | 4464 | Lₐ₃₂₄₁ | L_{b133} |
| 4465 | Lₐ₃₂₄₃ | L_{b133} | 4466 | Lₐ₃₂₄₆ | L_{b133} |
| 4467 | Lₐ₃₂₅₃ | L_{b133} | 4468 | Lₐ₃₂₅₅ | L_{b133} |
| 4469 | Lₐ₃₂₅₈ | L_{b133} | 4470 | Lₐ₃₂₆₅ | L_{b133} |
| 4471 | Lₐ₃₂₆₇ | L_{b133} | 4472 | Lₐ₃₂₇₀ | L_{b133} |
| 4473 | Lₐ₃₂₇₇ | L_{b133} | 4474 | Lₐ₃₂₇₉ | L_{b133} |
| 4475 | Lₐ₃₂₈₂ | L_{b133} | 4476 | Lₐ₃₂₈₉ | L_{b133} |
| 4477 | Lₐ₃₂₉₁ | L_{b133} | 4478 | Lₐ₃₂₉₄ | L_{b133} |
| 4479 | Lₐ₃₂₉₉ | L_{b133} | 4480 | Lₐ₃₄₉₉ | L_{b133} |
| 4481 | Lₐ₃₅₀₁ | L_{b133} | 4482 | Lₐ₃₅₅₉ | L_{b133} |
| 4483 | Lₐ₃₅₆₁ | L_{b133} | 4484 | Lₐ₃₅₇₁ | L_{b133} |
| 4485 | Lₐ₃₅₇₃ | L_{b133} | 4486 | Lₐ₃₅₈₃ | L_{b133} |
| 4487 | Lₐ₃₅₈₅ | L_{b133} | 4488 | Lₐ₃₆₆₅ | L_{b133} |
| 4489 | Lₐ₃₆₆₇ | L_{b133} | 4490 | Lₐ₃₆₇₀ | L_{b133} |
| 4491 | Lₐ₃₆₇₁ | L_{b133} | 4492 | Lₐ₃₆₇₃ | L_{b133} |
| 4493 | Lₐ₃₆₇₄ | L_{b133} | 4494 | Lₐ₃₆₇₇ | L_{b133} |
| 4495 | Lₐ₃₆₈₃ | L_{b133} | 4496 | Lₐ₃₆₈₈ | L_{b133} |
| 4497 | Lₐ₃₆₈₉ | L_{b133} | 4498 | Lₐ₃₆₉₁ | L_{b133} |
| 4499 | Lₐ₃₆₉₅ | L_{b133} | 4500 | Lₐ₃₇₁₉ | L_{b133} |
| 4501 | Lₐ₃₇₂₄ | L_{b133} | 4502 | Lₐ₃₇₂₅ | L_{b133} |
| 4503 | Lₐ₃₇₂₇ | L_{b133} | 4504 | Lₐ₃₇₃₁ | L_{b133} |
| 4505 | Lₐ₃₇₇₃ | L_{b133} | 4506 | Lₐ₃₇₇₈ | L_{b133} |
| 4507 | Lₐ₃₇₇₉ | L_{b133} | 4508 | Lₐ₃₇₈₁ | L_{b133} |
| 4509 | Lₐ₃₇₈₅ | L_{b133} | 4510 | Lₐ₃₈₀₉ | L_{b133} |
| 4511 | Lₐ₃₈₁₄ | L_{b133} | 4512 | Lₐ₃₈₁₅ | L_{b133} |
| 4513 | Lₐ₃₈₁₇ | L_{b133} | 4514 | Lₐ₃₈₂₁ | L_{b133} |
| 4515 | Lₐ₃₈₆₅ | L_{b133} | 4516 | Lₐ₃₈₆₇ | L_{b133} |
| 4517 | Lₐ₃₈₇₀ | L_{b133} | 4518 | Lₐ₃₈₇₇ | L_{b133} |
| 4519 | Lₐ₃₈₇₉ | L_{b133} | 4520 | Lₐ₃₈₈₂ | L_{b133} |
| 4521 | Lₐ₃₈₈₉ | L_{b133} | 4522 | Lₐ₃₈₉₁ | L_{b133} |
| 4523 | Lₐ₃₈₉₄ | L_{b133} | 4524 | Lₐ₃₉₀₁ | L_{b133} |
| 4525 | Lₐ₃₉₀₃ | L_{b133} | 4526 | Lₐ₃₉₀₆ | L_{b133} |
| 4527 | Lₐ₃₉₁₃ | L_{b133} | 4528 | Lₐ₃₉₁₅ | L_{b133} |
| 4529 | Lₐ₃₉₁₈ | L_{b133} | 4530 | Lₐ₃₉₂₁ | L_{b133} |
| 4531 | Lₐ₃₉₂₃ | L_{b133} | 4532 | Lₐ₃₉₂₄ | L_{b133} |
| 4533 | Lₐ₃₉₂₅ | L_{b133} | 4534 | Lₐ₃₉₂₇ | L_{b133} |
| 4535 | Lₐ₃₉₂₈ | L_{b133} | 4536 | Lₐ₃₉₃₀ | L_{b133} |
| 4537 | Lₐ₃₉₃₇ | L_{b133} | 4538 | Lₐ₃₉₃₉ | L_{b133} |
| 4539 | Lₐ₃₉₄₉ | L_{b133} | 4540 | Lₐ₃₉₅₁ | L_{b133} |
| 4541 | Lₐ₃₉₆₁ | L_{b133} | 4542 | Lₐ₃₉₆₃ | L_{b133} |
| 4543 | Lₐ₃₉₆₆ | L_{b133} | 4544 | Lₐ₃₉₇₃ | L_{b133} |
| 4545 | Lₐ₃₉₇₅ | L_{b133} | 4546 | Lₐ₃₉₇₈ | L_{b133} |
| 4547 | Lₐ₃₉₈₅ | L_{b133} | 4548 | Lₐ₃₉₈₇ | L_{b133} |
| 4549 | Lₐ₃₉₉₀ | L_{b133} | 4550 | Lₐ₃₉₉₇ | L_{b133} |
| 4551 | Lₐ₃₉₉₉ | L_{b133} | 4552 | Lₐ₄₀₀₂ | L_{b133} |
| 4553 | Lₐ₄₀₀₉ | L_{b133} | 4554 | Lₐ₄₀₁₁ | L_{b133} |
| 4555 | Lₐ₄₀₁₄ | L_{b133} | 4556 | Lₐ₄₀₂₁ | L_{b133} |
| 4557 | Lₐ₄₀₂₃ | L_{b133} | 4558 | Lₐ₄₀₂₆ | L_{b133} |
| 4559 | Lₐ₄₀₃₁ | L_{b133} | 4560 | Lₐ₄₀₃₆ | L_{b133} |
| 4561 | Lₐ₄₀₃₇ | L_{b133} | 4562 | Lₐ₄₀₃₉ | L_{b133} |
| 4563 | Lₐ₄₀₄₃ | L_{b133} | 4564 | Lₐ₄₀₄₉ | L_{b133} |
| 4565 | Lₐ₄₀₅₄ | L_{b133} | 4566 | Lₐ₄₀₅₅ | L_{b133} |
| 4567 | Lₐ₄₀₅₇ | L_{b133} | 4568 | Lₐ₄₀₆₁ | L_{b133} |
| 4569 | Lₐ₄₁₃₉ | L_{b133} | 4570 | Lₐ₄₁₄₄ | L_{b133} |
| 4571 | Lₐ₄₁₄₅ | L_{b133} | 4572 | Lₐ₄₁₄₇ | L_{b133} |
| 4573 | Lₐ₄₁₅₁ | L_{b133} | 4574 | Lₐ₄₂₃₁ | L_{b133} |
| 4575 | Lₐ₄₂₃₃ | L_{b133} | 4576 | Lₐ₄₂₃₆ | L_{b133} |
| 4577 | Lₐ₄₂₄₃ | L_{b133} | 4578 | Lₐ₄₂₄₅ | L_{b133} |
| 4579 | Lₐ₄₂₄₈ | L_{b133} | 4580 | Lₐ₄₂₆₇ | L_{b133} |
| 4581 | Lₐ₄₂₆₉ | L_{b133} | 4582 | Lₐ₄₂₇₂ | L_{b133} |
| 4583 | Lₐ₄₂₈₇ | L_{b133} | 4584 | Lₐ₄₂₈₉ | L_{b133} |
| 4585 | Lₐ₄₂₉₁ | L_{b133} | 4586 | Lₐ₄₂₉₃ | L_{b133} |
| 4587 | Lₐ₄₂₉₄ | L_{b133} | 4588 | Lₐ₄₂₉₆ | L_{b133} |
| 4589 | Lₐ₄₃₀₃ | L_{b133} | 4590 | Lₐ₄₃₀₅ | L_{b133} |
| 4591 | Lₐ₄₃₁₅ | L_{b133} | 4592 | Lₐ₄₃₁₇ | L_{b133} |
| 4593 | Lₐ₄₃₂₇ | L_{b133} | 4594 | Lₐ₄₃₂₉ | L_{b133} |
| 4595 | Lₐ₄₃₃₂ | L_{b133} | 4596 | Lₐ₄₃₃₉ | L_{b133} |
| 4597 | Lₐ₄₃₄₁ | L_{b133} | 4598 | Lₐ₄₃₄₄ | L_{b133} |
| 4599 | Lₐ₄₃₆₃ | L_{b133} | 4600 | Lₐ₄₃₆₅ | L_{b133} |
| 4601 | Lₐ₄₃₆₈ | L_{b133} | 4602 | Lₐ₄₃₇₅ | L_{b133} |
| 4603 | Lₐ₄₃₇₇ | L_{b133} | 4604 | Lₐ₄₃₈₀ | L_{b133} |
| 4605 | Lₐ₄₃₉₇ | L_{b133} | 4606 | Lₐ₄₃₉₉ | L_{b133} |
| 4607 | Lₐ₄₄₀₂ | L_{b133} | 4608 | Lₐ₄₄₀₃ | L_{b133} |
| 4609 | Lₐ₄₄₀₅ | L_{b133} | 4610 | Lₐ₄₄₀₆ | L_{b133} |
| 4611 | Lₐ₄₄₀₉ | L_{b133} | 4612 | Lₐ₄₄₁₅ | L_{b133} |
| 4613 | Lₐ₄₄₂₀ | L_{b133} | 4614 | Lₐ₄₄₂₃ | L_{b133} |
| 4615 | Lₐ₄₄₂₇ | L_{b133} | 4616 | Lₐ₄₄₅₁ | L_{b133} |
| 4617 | Lₐ₄₄₅₆ | L_{b133} | 4618 | Lₐ₄₄₅₇ | L_{b133} |
| 4619 | Lₐ₄₄₅₉ | L_{b133} | 4620 | Lₐ₄₄₆₃ | L_{b133} |
| 4621 | Lₐ₄₅₉₇ | L_{b133} | 4622 | Lₐ₄₅₉₉ | L_{b133} |
| 4623 | Lₐ₄₆₀₂ | L_{b133} | 4624 | Lₐ₄₆₀₉ | L_{b133} |
| 4625 | Lₐ₄₆₁₁ | L_{b133} | 4626 | Lₐ₄₆₂₁ | L_{b133} |
| 4627 | Lₐ₄₆₂₃ | L_{b133} | 4628 | Lₐ₄₆₃₃ | L_{b133} |
| 4629 | Lₐ₄₆₃₅ | L_{b133} | 4630 | Lₐ₄₆₄₅ | L_{b133} |
| 4631 | Lₐ₄₆₄₇ | L_{b133} | 4632 | Lₐ₄₆₅₃ | L_{b133} |
| 4633 | Lₐ₄₆₅₅ | L_{b133} | 4634 | Lₐ₄₆₅₇ | L_{b133} |
| 4635 | Lₐ₄₆₅₉ | L_{b133} | 4636 | Lₐ₄₆₆₂ | L_{b133} |
| 4637 | Lₐ₄₆₆₉ | L_{b133} | 4638 | Lₐ₄₆₇₁ | L_{b133} |
| 4639 | Lₐ₄₆₈₁ | L_{b133} | 4640 | Lₐ₄₆₈₃ | L_{b133} |
| 4641 | Lₐ₄₆₉₃ | L_{b133} | 4642 | Lₐ₄₆₉₅ | L_{b133} |
| 4643 | Lₐ₄₆₉₈ | L_{b133} | 4644 | Lₐ₄₇₀₅ | L_{b133} |
| 4645 | Lₐ₄₇₀₇ | L_{b133} | 4646 | Lₐ₄₇₁₀ | L_{b133} |
| 4647 | Lₐ₄₇₂₉ | L_{b133} | 4648 | Lₐ₄₇₃₁ | L_{b133} |
| 4649 | Lₐ₄₇₃₄ | L_{b133} | 4650 | Lₐ₄₇₆₃ | L_{b133} |
| 4651 | Lₐ₄₉₆₃ | L_{b133} | 4652 | Lₐ₄₉₆₅ | L_{b133} |
| 4653 | Lₐ₄₉₆₈ | L_{b133} | 4654 | Lₐ₅₀₂₃ | L_{b133} |
| 4655 | Lₐ₅₀₂₅ | L_{b133} | 4656 | Lₐ₅₀₃₅ | L_{b133} |
| 4657 | Lₐ₅₀₃₇ | L_{b133} | 4658 | Lₐ₅₀₄₇ | L_{b133} |
| 4659 | Lₐ₅₀₄₉ | L_{b133} | 4660 | Lₐ₅₁₂₉ | L_{b133} |
| 4661 | Lₐ₅₁₃₄ | L_{b133} | 4662 | Lₐ₅₁₃₅ | L_{b133} |
| 4663 | Lₐ₅₁₃₇ | L_{b133} | 4664 | Lₐ₅₁₄₁ | L_{b133} |
| 4665 | Lₐ₅₁₄₇ | L_{b133} | 4666 | Lₐ₅₁₅₂ | L_{b133} |
| 4667 | Lₐ₅₁₅₃ | L_{b133} | 4668 | Lₐ₅₁₅₅ | L_{b133} |
| 4669 | Lₐ₅₁₅₉ | L_{b133} | 4670 | Lₐ₅₂₃₇ | L_{b133} |
| 4671 | Lₐ₅₂₄₂ | L_{b133} | 4672 | Lₐ₅₂₄₃ | L_{b133} |
| 4673 | Lₐ₅₂₄₅ | L_{b133} | 4674 | Lₐ₅₂₄₉ | L_{b133} |
| 4675 | Lₐ₅₃₂₉ | L_{b133} | 4676 | Lₐ₅₃₃₁ | L_{b133} |
| 4677 | Lₐ₅₃₃₄ | L_{b133} | 4678 | Lₐ₅₃₄₁ | L_{b133} |
| 4679 | Lₐ₅₃₄₃ | L_{b133} | 4680 | Lₐ₅₃₄₆ | L_{b133} |
| 4681 | Lₐ₅₃₆₅ | L_{b133} | 4682 | Lₐ₅₃₆₇ | L_{b133} |
| 4683 | Lₐ₅₃₇₀ | L_{b133} | 4684 | Lₐ₅₃₈₅ | L_{b133} |
| 4685 | Lₐ₅₃₈₇ | L_{b133} | 4686 | Lₐ₅₃₈₉ | L_{b133} |
| 4687 | Lₐ₅₃₉₁ | L_{b133} | 4688 | Lₐ₅₃₉₂ | L_{b133} |
| 4689 | Lₐ₅₃₉₄ | L_{b133} | 4690 | Lₐ₅₄₀₁ | L_{b133} |
| 4691 | Lₐ₅₄₀₃ | L_{b133} | 4692 | Lₐ₅₄₁₃ | L_{b133} |
| 4693 | Lₐ₅₄₁₅ | L_{b133} | 4694 | Lₐ₅₄₂₅ | L_{b133} |
| 4695 | Lₐ₅₄₂₇ | L_{b133} | 4696 | Lₐ₅₄₃₀ | L_{b133} |
| 4697 | Lₐ₅₄₆₁ | L_{b133} | 4698 | Lₐ₅₄₆₃ | L_{b133} |
| 4699 | Lₐ₅₄₆₆ | L_{b133} | 4700 | Lₐ₅₄₉₅ | L_{b133} |
| 4701 | Lₐ₅₆₉₅ | L_{b133} | 4702 | Lₐ₅₆₉₇ | L_{b133} |
| 4703 | Lₐ₅₇₅₅ | L_{b133} | 4704 | Lₐ₅₇₅₇ | L_{b133} |
| 4705 | Lₐ₅₇₆₀ | L_{b133} | 4706 | Lₐ₅₇₆₇ | L_{b133} |
| 4707 | Lₐ₅₇₆₉ | L_{b133} | 4708 | Lₐ₅₇₇₉ | L_{b133} |
| 4709 | Lₐ₅₇₈₁ | L_{b133} | 4710 | Lₐ₅₈₆₁ | L_{b133} |
| 4711 | Lₐ₅₈₆₆ | L_{b133} | 4712 | Lₐ₅₈₆₇ | L_{b133} |
| 4713 | Lₐ₅₈₆₉ | L_{b133} | 4714 | Lₐ₅₈₇₃ | L_{b133} |
| 4715 | Lₐ₅₈₇₉ | L_{b133} | 4716 | Lₐ₅₈₈₄ | L_{b133} |
| 4717 | Lₐ₅₈₈₅ | L_{b133} | 4718 | Lₐ₅₈₈₇ | L_{b133} |
| 4719 | Lₐ₅₈₉₁ | L_{b133} | 4720 | Lₐ₅₉₆₉ | L_{b133} |
| 4721 | Lₐ₅₉₇₄ | L_{b133} | 4722 | Lₐ₅₉₇₅ | L_{b133} |
| 4723 | Lₐ₅₉₇₇ | L_{b133} | 4724 | Lₐ₅₉₈₁ | L_{b133} |
| 4725 | Lₐ₆₀₅₇ | L_{b133} | 4726 | Lₐ₆₀₅₉ | L_{b133} |
| 4727 | Lₐ₆₀₆₁ | L_{b133} | 4728 | Lₐ₆₀₆₃ | L_{b133} |
| 4729 | Lₐ₆₀₆₆ | L_{b133} | 4730 | Lₐ₆₀₇₃ | L_{b133} |
| 4731 | Lₐ₆₀₇₅ | L_{b133} | 4732 | Lₐ₆₀₇₈ | L_{b133} |
| 4733 | Lₐ₆₀₈₅ | L_{b133} | 4734 | Lₐ₆₀₈₇ | L_{b133} |
| 4735 | Lₐ₆₀₉₇ | L_{b133} | 4736 | Lₐ₆₀₉₉ | L_{b133} |
| 4737 | Lₐ₆₁₁₇ | L_{b133} | 4738 | Lₐ₆₁₁₉ | L_{b133} |
| 4739 | Lₐ₆₁₂₁ | L_{b133} | 4740 | Lₐ₆₁₂₃ | L_{b133} |
| 4741 | Lₐ₆₁₂₆ | L_{b133} | 4742 | Lₐ₆₁₃₃ | L_{b133} |
| 4743 | Lₐ₆₁₃₅ | L_{b133} | 4744 | Lₐ₆₁₄₅ | L_{b133} |
| 4745 | Lₐ₆₁₄₇ | L_{b133} | 4746 | Lₐ₆₁₅₇ | L_{b133} |
| 4747 | Lₐ₆₁₅₉ | L_{b133} | 4748 | Lₐ₆₁₆₂ | L_{b133} |
| 4749 | Lₐ₆₁₆₉ | L_{b133} | 4750 | Lₐ₆₁₇₁ | L_{b133} |
| 4751 | Lₐ₆₁₇₄ | L_{b133} | 4752 | Lₐ₆₁₉₃ | L_{b133} |
| 4753 | Lₐ₆₁₉₅ | L_{b133} | 4754 | Lₐ₆₁₉₈ | L_{b133} |
| 4755 | Lₐ₆₂₀₅ | L_{b133} | 4756 | Lₐ₆₂₀₇ | L_{b133} |
| 4757 | Lₐ₆₂₂₇ | L_{b133} | 4758 | Lₐ₆₂₃₂ | L_{b133} |
| 4759 | Lₐ₆₂₃₃ | L_{b133} | 4760 | Lₐ₆₂₃₅ | L_{b133} |
| 4761 | Lₐ₆₂₃₉ | L_{b133} | 4762 | Lₐ₆₂₄₅ | L_{b133} |
| 4763 | Lₐ₆₂₅₀ | L_{b133} | 4764 | Lₐ₆₂₅₁ | L_{b133} |
| 4765 | Lₐ₆₂₅₃ | L_{b133} | 4766 | Lₐ₆₂₅₇ | L_{b133} |
| 4767 | Lₐ₆₃₃₅ | L_{b133} | 4768 | Lₐ₆₃₄₀ | L_{b133} |
| 4769 | Lₐ₆₃₄₁ | L_{b133} | 4770 | Lₐ₆₃₄₃ | L_{b133} |
| 4771 | Lₐ₆₃₄₇ | L_{b133} | 4772 | Lₐ₆₄₂₃ | L_{b133} |
| 4773 | Lₐ₆₄₂₅ | L_{b133} | 4774 | Lₐ₆₄₂₇ | L_{b133} |
| 4775 | Lₐ₆₄₂₉ | L_{b133} | 4776 | Lₐ₆₄₃₂ | L_{b133} |
| 4777 | Lₐ₆₄₃₉ | L_{b133} | 4778 | Lₐ₆₄₄₁ | L_{b133} |
| 4779 | Lₐ₆₄₄₄ | L_{b133} | 4780 | Lₐ₆₄₆₃ | L_{b133} |
| 4781 | Lₐ₆₄₆₅ | L_{b133} | 4782 | Lₐ₆₄₆₈ | L_{b133} |
| 4783 | Lₐ₆₄₈₃ | L_{b133} | 4784 | Lₐ₆₄₈₅ | L_{b133} |
| 4785 | Lₐ₆₄₈₇ | L_{b133} | 4786 | Lₐ₆₄₈₉ | L_{b133} |
| 4787 | Lₐ₆₄₉₂ | L_{b133} | 4788 | Lₐ₆₄₉₉ | L_{b133} |
| 4789 | Lₐ₆₅₀₁ | L_{b133} | 4790 | Lₐ₆₅₁₁ | L_{b133} |
| 4791 | Lₐ₆₅₁₃ | L_{b133} | 4792 | Lₐ₆₅₂₃ | L_{b133} |
| 4793 | Lₐ₆₅₂₅ | L_{b133} | 4794 | Lₐ₆₅₂₈ | L_{b133} |
| 4795 | Lₐ₆₅₃₅ | L_{b133} | 4796 | Lₐ₆₅₃₇ | L_{b133} |
| 4797 | Lₐ₆₅₄₀ | L_{b133} | 4798 | Lₐ₆₅₅₉ | L_{b133} |
| 4799 | Lₐ₆₅₆₁ | L_{b133} | 4800 | Lₐ₆₅₆₄ | L_{b133} |
| 4801 | Lₐ₆₅₇₁ | L_{b133} | 4802 | Lₐ₆₅₇₃ | L_{b133} |
| 4803 | Lₐ₆₅₉₃ | L_{b133} | 4804 | Lₐ₆₅₉₈ | L_{b133} |
| 4805 | Lₐ₆₅₉₉ | L_{b133} | 4806 | Lₐ₆₆₀₁ | L_{b133} |
| 4807 | Lₐ₆₆₀₅ | L_{b133} | 4808 | Lₐ₆₆₁₁ | L_{b133} |
| 4809 | Lₐ₆₆₁₆ | L_{b133} | 4810 | Lₐ₆₆₁₉ | L_{b133} |
| 4811 | Lₐ₆₆₂₃ | L_{b133} | 4812 | Lₐ₆₇₀₀ | L_{b133} |
| 4813 | Lₐ₆₇₀₁ | L_{b133} | 4814 | Lₐ₆₇₀₃ | L_{b133} |
| 4815 | Lₐ₆₇₀₆ | L_{b133} | 4816 | Lₐ₆₇₀₇ | L_{b133} |
| 4817 | Lₐ₆₇₀₉ | L_{b133} | 4818 | Lₐ₆₇₁₃ | L_{b133} |
| 4819 | Lₐ₆₇₄₂ | L_{b133} | 4820 | Lₐ₆₇₄₅ | L_{b133} |
| 4821 | Lₐ₆₇₉₃ | L_{b133} | 4822 | Lₐ₆₇₉₅ | L_{b133} |
| 4823 | Lₐ₆₇₉₈ | L_{b133} | 4824 | Lₐ₆₈₀₅ | L_{b133} |
| 4825 | Lₐ₆₈₀₇ | L_{b133} | 4826 | Lₐ₆₈₁₀ | L_{b133} |
| 4827 | Lₐ₆₈₂₉ | L_{b133} | 4828 | Lₐ₆₈₃₁ | L_{b133} |
| 4829 | Lₐ₆₈₃₄ | L_{b133} | 4830 | Lₐ₆₈₄₉ | L_{b133} |
| 4831 | Lₐ₆₈₅₁ | L_{b133} | 4832 | Lₐ₆₈₅₃ | L_{b133} |
| 4833 | Lₐ₆₈₅₅ | L_{b133} | 4834 | Lₐ₆₈₅₈ | L_{b133} |
| 4835 | Lₐ₆₈₆₅ | L_{b133} | 4836 | Lₐ₆₈₆₇ | L_{b133} |
| 4837 | Lₐ₆₈₇₇ | L_{b133} | 4838 | Lₐ₆₈₇₉ | L_{b133} |
| 4839 | Lₐ₆₈₈₉ | L_{b133} | 4840 | Lₐ₆₈₉₁ | L_{b133} |
| 4841 | Lₐ₆₈₉₄ | L_{b133} | 4842 | Lₐ₆₉₀₁ | L_{b133} |
| 4843 | Lₐ₆₉₀₃ | L_{b133} | 4844 | Lₐ₆₉₂₅ | L_{b133} |
| 4845 | Lₐ₆₉₂₇ | L_{b133} | 4846 | Lₐ₆₉₃₀ | L_{b133} |
| 4847 | Lₐ₆₉₃₇ | L_{b133} | 4848 | Lₐ₆₉₃₉ | L_{b133} |
| 4849 | Lₐ₅ | L_{b135} | 4850 | Lₐ₇ | L_{b135} |
| 4851 | Lₐ₁₀ | L_{b135} | 4852 | Lₐ₁₁ | L_{b135} |
| 4853 | Lₐ₁₃ | L_{b135} | 4854 | Lₐ₁₄ | L_{b135} |
| 4855 | Lₐ₁₇ | L_{b135} | 4856 | Lₐ₂₃ | L_{b135} |
| 4857 | Lₐ₂₈ | L_{b135} | 4858 | Lₐ₂₉ | L_{b135} |
| 4859 | Lₐ₃₁ | L_{b135} | 4860 | Lₐ₃₅ | L_{b135} |
| 4861 | Lₐ₅₉ | L_{b135} | 4862 | Lₐ₆₄ | L_{b135} |
| 4863 | Lₐ₆₅ | L_{b135} | 4864 | Lₐ₆₇ | L_{b135} |
| 4865 | Lₐ₇₁ | L_{b135} | 4866 | Lₐ₁₁₃ | L_{b135} |
| 4867 | Lₐ₁₁₈ | L_{b135} | 4868 | Lₐ₁₁₉ | L_{b135} |
| 4869 | Lₐ₁₂₁ | L_{b135} | 4870 | Lₐ₁₂₅ | L_{b135} |
| 4871 | Lₐ₁₄₉ | L_{b135} | 4872 | Lₐ₁₅₄ | L_{b135} |
| 4873 | Lₐ₁₅₅ | L_{b135} | 4874 | Lₐ₁₅₇ | L_{b135} |
| 4875 | Lₐ₁₆₁ | L_{b135} | 4876 | Lₐ₂₀₅ | L_{b135} |
| 4877 | Lₐ₂₀₇ | L_{b135} | 4878 | Lₐ₂₁₀ | L_{b135} |
| 4879 | Lₐ₂₁₇ | L_{b135} | 4880 | Lₐ₂₁₉ | L_{b135} |
| 4881 | Lₐ₂₂₂ | L_{b135} | 4882 | Lₐ₂₂₉ | L_{b135} |
| 4883 | Lₐ₂₃₁ | L_{b135} | 4884 | Lₐ₂₃₄ | L_{b135} |
| 4885 | Lₐ₂₄₁ | L_{b135} | 4886 | Lₐ₂₄₃ | L_{b135} |
| 4887 | Lₐ₂₄₆ | L_{b135} | 4888 | Lₐ₂₅₃ | L_{b135} |
| 4889 | Lₐ₂₅₅ | L_{b135} | 4890 | Lₐ₂₅₈ | L_{b135} |
| 4891 | Lₐ₂₆₁ | L_{b135} | 4892 | Lₐ₂₆₃ | L_{b135} |
| 4893 | Lₐ₂₆₅ | L_{b135} | 4894 | Lₐ₂₆₇ | L_{b135} |
| 4895 | Lₐ₂₇₀ | L_{b135} | 4896 | Lₐ₂₇₇ | L_{b135} |
| 4897 | Lₐ₂₇₉ | L_{b135} | 4898 | Lₐ₂₈₂ | L_{b135} |
| 4899 | Lₐ₂₈₉ | L_{b135} | 4900 | Lₐ₂₉₁ | L_{b135} |
| 4901 | Lₐ₂₉₄ | L_{b135} | 4902 | Lₐ₃₀₁ | L_{b135} |
| 4903 | Lₐ₃₀₃ | L_{b135} | 4904 | Lₐ₃₀₆ | L_{b135} |
| 4905 | Lₐ₃₁₃ | L_{b135} | 4906 | Lₐ₃₁₅ | L_{b135} |
| 4907 | Lₐ₃₁₈ | L_{b135} | 4908 | Lₐ₃₂₅ | L_{b135} |
| 4909 | Lₐ₃₂₇ | L_{b135} | 4910 | Lₐ₃₃₀ | L_{b135} |
| 4911 | Lₐ₃₃₇ | L_{b135} | 4912 | Lₐ₃₃₉ | L_{b135} |
| 4913 | Lₐ₃₄₂ | L_{b135} | 4914 | Lₐ₃₄₉ | L_{b135} |
| 4915 | Lₐ₃₅₁ | L_{b135} | 4916 | Lₐ₃₅₄ | L_{b135} |
| 4917 | Lₐ₃₆₁ | L_{b135} | 4918 | Lₐ₃₆₃ | L_{b135} |
| 4919 | Lₐ₃₆₆ | L_{b135} | 4920 | Lₐ₃₇₁ | L_{b135} |
| 4921 | Lₐ₅₇₁ | L_{b135} | 4922 | Lₐ₅₇₃ | L_{b135} |
| 4923 | Lₐ₆₃₁ | L_{b135} | 4924 | Lₐ₆₃₃ | L_{b135} |
| 4925 | Lₐ₇₃₇ | L_{b135} | 4926 | Lₐ₉₃₇ | L_{b135} |
| 4927 | Lₐ₉₃₉ | L_{b135} | 4928 | Lₐ₉₉₇ | L_{b135} |
| 4929 | Lₐ₉₉₉ | L_{b135} | 4930 | Lₐ₁₀₀₉ | L_{b135} |
| 4931 | Lₐ₁₀₁₁ | L_{b135} | 4932 | Lₐ₁₀₂₁ | L_{b135} |
| 4933 | Lₐ₁₀₂₃ | L_{b135} | 4934 | Lₐ₁₁₀₃ | L_{b135} |
| 4935 | Lₐ₁₁₀₅ | L_{b135} | 4936 | Lₐ₁₁₀₈ | L_{b135} |
| 4937 | Lₐ₁₁₀₉ | L_{b135} | 4938 | Lₐ₁₁₁₁ | L_{b135} |
| 4939 | Lₐ₁₁₁₂ | L_{b135} | 4940 | Lₐ₁₁₁₅ | L_{b135} |
| 4941 | Lₐ₁₁₂₁ | L_{b135} | 4942 | Lₐ₁₁₂₆ | L_{b135} |
| 4943 | Lₐ₁₁₂₇ | L_{b135} | 4944 | Lₐ₁₁₂₉ | L_{b135} |
| 4945 | Lₐ₁₁₃₃ | L_{b135} | 4946 | Lₐ₁₁₅₇ | L_{b135} |
| 4947 | Lₐ₁₁₆₂ | L_{b135} | 4948 | Lₐ₁₁₆₃ | L_{b135} |
| 4949 | Lₐ₁₁₆₅ | L_{b135} | 4950 | Lₐ₁₁₆₉ | L_{b135} |
| 4951 | Lₐ₁₂₁₁ | L_{b135} | 4952 | Lₐ₁₂₁₆ | L_{b135} |
| 4953 | Lₐ₁₂₁₇ | L_{b135} | 4954 | Lₐ₁₂₁₉ | L_{b135} |
| 4955 | Lₐ₁₂₂₃ | L_{b135} | 4956 | Lₐ₁₂₄₇ | L_{b135} |
| 4957 | Lₐ₁₂₅₂ | L_{b135} | 4958 | Lₐ₁₂₅₃ | L_{b135} |
| 4959 | Lₐ₁₂₅₅ | L_{b135} | 4960 | Lₐ₁₂₅₉ | L_{b135} |
| 4961 | Lₐ₁₃₀₃ | L_{b135} | 4962 | Lₐ₁₃₀₅ | L_{b135} |
| 4963 | Lₐ₁₃₀₈ | L_{b135} | 4964 | Lₐ₁₃₁₅ | L_{b135} |
| 4965 | Lₐ₁₃₁₇ | L_{b135} | 4966 | Lₐ₁₃₂₀ | L_{b135} |
| 4967 | Lₐ₁₃₂₇ | L_{b135} | 4968 | Lₐ₁₃₂₉ | L_{b135} |
| 4969 | Lₐ₁₃₃₂ | L_{b135} | 4970 | Lₐ₁₃₃₉ | L_{b135} |
| 4971 | Lₐ₁₃₄₁ | L_{b135} | 4972 | Lₐ₁₃₄₄ | L_{b135} |
| 4973 | Lₐ₁₃₅₁ | L_{b135} | 4974 | Lₐ₁₃₅₃ | L_{b135} |
| 4975 | Lₐ₁₃₅₆ | L_{b135} | 4976 | Lₐ₁₃₅₉ | L_{b135} |
| 4977 | Lₐ₁₃₆₁ | L_{b135} | 4978 | Lₐ₁₃₆₃ | L_{b135} |
| 4979 | Lₐ₁₃₆₅ | L_{b135} | 4980 | Lₐ₁₃₆₈ | L_{b135} |
| 4981 | Lₐ₁₃₇₅ | L_{b135} | 4982 | Lₐ₁₃₇₇ | L_{b135} |
| 4983 | Lₐ₁₃₈₇ | L_{b135} | 4984 | Lₐ₁₃₈₉ | L_{b135} |
| 4985 | Lₐ₁₄₆₉ | L_{b135} | 4986 | Lₐ₁₆₆₉ | L_{b135} |
| 4987 | Lₐ₁₆₇₁ | L_{b135} | 4988 | Lₐ₁₇₂₉ | L_{b135} |
| 4989 | Lₐ₁₇₃₁ | L_{b135} | 4990 | Lₐ₁₇₄₁ | L_{b135} |
| 4991 | Lₐ₁₇₄₃ | L_{b135} | 4992 | Lₐ₁₇₅₃ | L_{b135} |
| 4993 | Lₐ₁₇₅₅ | L_{b135} | 4994 | Lₐ₁₈₃₅ | L_{b135} |
| 4995 | Lₐ₂₀₃₅ | L_{b135} | 4996 | Lₐ₂₀₃₇ | L_{b135} |
| 4997 | Lₐ₂₀₉₅ | L_{b135} | 4998 | Lₐ₂₀₉₇ | L_{b135} |
| 4999 | Lₐ₂₁₀₇ | L_{b135} | 5000 | Lₐ₂₁₀₉ | L_{b135} |
| 5001 | Lₐ₂₁₁₉ | L_{b135} | 5002 | Lₐ₂₁₂₁ | L_{b135} |
| 5003 | Lₐ₂₂₀₁ | L_{b135} | 5004 | Lₐ₂₄₀₁ | L_{b135} |
| 5005 | Lₐ₂₄₀₃ | L_{b135} | 5006 | Lₐ₂₄₆₁ | L_{b135} |
| 5007 | Lₐ₂₄₆₃ | L_{b135} | 5008 | Lₐ₂₄₇₃ | L_{b135} |
| 5009 | Lₐ₂₄₇₅ | L_{b135} | 5010 | Lₐ₂₄₈₅ | L_{b135} |
| 5011 | Lₐ₂₄₈₇ | L_{b135} | 5012 | Lₐ₂₅₆₇ | L_{b135} |
| 5013 | Lₐ₂₇₆₇ | L_{b135} | 5014 | Lₐ₂₇₆₉ | L_{b135} |
| 5015 | Lₐ₂₈₂₇ | L_{b135} | 5016 | Lₐ₂₈₂₉ | L_{b135} |
| 5017 | Lₐ₂₈₅₁ | L_{b135} | 5018 | Lₐ₂₈₅₃ | L_{b135} |
| 5019 | Lₐ₂₉₃₃ | L_{b135} | 5020 | Lₐ₂₉₃₅ | L_{b135} |
| 5021 | Lₐ₂₉₃₈ | L_{b135} | 5022 | Lₐ₂₉₃₉ | L_{b135} |
| 5023 | Lₐ₂₉₄₁ | L_{b135} | 5024 | Lₐ₂₉₄₂ | L_{b135} |
| 5025 | Lₐ₂₉₄₅ | L_{b135} | 5026 | Lₐ₂₉₅₁ | L_{b135} |
| 5027 | Lₐ₂₉₅₆ | L_{b135} | 5028 | Lₐ₂₉₅₇ | L_{b135} |
| 5029 | Lₐ₂₉₅₉ | L_{b135} | 5030 | Lₐ₂₉₆₃ | L_{b135} |
| 5031 | Lₐ₂₉₈₇ | L_{b135} | 5032 | Lₐ₂₉₉₂ | L_{b135} |
| 5033 | Lₐ₂₉₉₃ | L_{b135} | 5034 | Lₐ₂₉₉₅ | L_{b135} |
| 5035 | Lₐ₂₉₉₉ | L_{b135} | 5036 | Lₐ₃₀₄₁ | L_{b135} |
| 5037 | Lₐ₃₀₄₆ | L_{b135} | 5038 | Lₐ₃₀₄₇ | L_{b135} |
| 5039 | Lₐ₃₀₄₉ | L_{b135} | 5040 | Lₐ₃₀₅₃ | L_{b135} |
| 5041 | Lₐ₃₀₇₇ | L_{b135} | 5042 | Lₐ₃₀₈₂ | L_{b135} |
| 5043 | Lₐ₃₀₈₃ | L_{b135} | 5044 | Lₐ₃₀₈₅ | L_{b135} |
| 5045 | Lₐ₃₀₈₉ | L_{b135} | 5046 | Lₐ₃₁₃₃ | L_{b135} |
| 5047 | Lₐ₃₁₃₅ | L_{b135} | 5048 | Lₐ₃₁₃₈ | L_{b135} |
| 5049 | Lₐ₃₁₄₅ | L_{b135} | 5050 | Lₐ₃₁₄₇ | L_{b135} |
| 5051 | Lₐ₃₁₅₀ | L_{b135} | 5052 | Lₐ₃₁₆₉ | L_{b135} |
| 5053 | Lₐ₃₁₇₁ | L_{b135} | 5054 | Lₐ₃₁₇₄ | L_{b135} |
| 5055 | Lₐ₃₁₈₁ | L_{b135} | 5056 | Lₐ₃₁₈₃ | L_{b135} |
| 5057 | Lₐ₃₁₈₆ | L_{b135} | 5058 | Lₐ₃₁₈₉ | L_{b135} |
| 5059 | Lₐ₃₁₉₁ | L_{b135} | 5060 | Lₐ₃₁₉₃ | L_{b135} |
| 5061 | Lₐ₃₁₉₅ | L_{b135} | 5062 | Lₐ₃₁₉₈ | L_{b135} |
| 5063 | Lₐ₃₂₀₅ | L_{b135} | 5064 | Lₐ₃₂₀₇ | L_{b135} |
| 5065 | Lₐ₃₂₁₇ | L_{b135} | 5066 | Lₐ₃₂₁₉ | L_{b135} |
| 5067 | Lₐ₃₂₂₉ | L_{b135} | 5068 | Lₐ₃₂₃₁ | L_{b135} |
| 5069 | Lₐ₃₂₃₄ | L_{b135} | 5070 | Lₐ₃₂₄₁ | L_{b135} |
| 5071 | Lₐ₃₂₄₃ | L_{b135} | 5072 | Lₐ₃₂₄₆ | L_{b135} |
| 5073 | Lₐ₃₂₅₃ | L_{b135} | 5074 | Lₐ₃₂₅₅ | L_{b135} |
| 5075 | Lₐ₃₂₅₈ | L_{b135} | 5076 | Lₐ₃₂₆₅ | L_{b135} |
| 5077 | Lₐ₃₂₆₇ | L_{b135} | 5078 | Lₐ₃₂₇₀ | L_{b135} |
| 5079 | Lₐ₃₂₇₇ | L_{b135} | 5080 | Lₐ₃₂₇₉ | L_{b135} |
| 5081 | Lₐ₃₂₈₂ | L_{b135} | 5082 | Lₐ₃₂₈₉ | L_{b135} |
| 5083 | Lₐ₃₂₉₁ | L_{b135} | 5084 | Lₐ₃₂₉₄ | L_{b135} |
| 5085 | Lₐ₃₂₉₉ | L_{b135} | 5086 | Lₐ₃₄₉₉ | L_{b135} |
| 5087 | Lₐ₃₅₀₁ | L_{b135} | 5088 | Lₐ₃₅₅₉ | L_{b135} |
| 5089 | Lₐ₃₅₆₁ | L_{b135} | 5090 | Lₐ₃₅₇₁ | L_{b135} |
| 5091 | Lₐ₃₅₇₃ | L_{b135} | 5092 | Lₐ₃₅₈₃ | L_{b135} |
| 5093 | Lₐ₃₅₈₅ | L_{b135} | 5094 | Lₐ₃₆₆₅ | L_{b135} |
| 5095 | Lₐ₃₆₆₇ | L_{b135} | 5096 | Lₐ₃₆₇₀ | L_{b135} |
| 5097 | Lₐ₃₆₇₁ | L_{b135} | 5098 | Lₐ₃₆₇₃ | L_{b135} |
| 5099 | Lₐ₃₆₇₄ | L_{b135} | 5100 | Lₐ₃₆₇₇ | L_{b135} |
| 5101 | Lₐ₃₆₈₃ | L_{b135} | 5102 | Lₐ₃₆₈₈ | L_{b135} |
| 5103 | Lₐ₃₆₈₉ | L_{b135} | 5104 | Lₐ₃₆₉₁ | L_{b135} |
| 5105 | Lₐ₃₆₉₅ | L_{b135} | 5106 | Lₐ₃₇₁₉ | L_{b135} |
| 5107 | Lₐ₃₇₂₄ | L_{b135} | 5108 | Lₐ₃₇₂₅ | L_{b135} |
| 5109 | Lₐ₃₇₂₇ | L_{b135} | 5110 | Lₐ₃₇₃₁ | L_{b135} |
| 5111 | Lₐ₃₇₇₃ | L_{b135} | 5112 | Lₐ₃₇₇₈ | L_{b135} |
| 5113 | Lₐ₃₇₇₉ | L_{b135} | 5114 | Lₐ₃₇₈₁ | L_{b135} |
| 5115 | Lₐ₃₇₈₅ | L_{b135} | 5116 | Lₐ₃₈₀₉ | L_{b135} |
| 5117 | Lₐ₃₈₁₄ | L_{b135} | 5118 | Lₐ₃₈₁₅ | L_{b135} |
| 5119 | Lₐ₃₈₁₇ | L_{b135} | 5120 | Lₐ₃₈₂₁ | L_{b135} |
| 5121 | Lₐ₃₈₆₅ | L_{b135} | 5122 | Lₐ₃₈₆₇ | L_{b135} |
| 5123 | Lₐ₃₈₇₀ | L_{b135} | 5124 | Lₐ₃₈₇₇ | L_{b135} |
| 5125 | Lₐ₃₈₇₉ | L_{b135} | 5126 | Lₐ₃₈₈₂ | L_{b135} |
| 5127 | Lₐ₃₈₈₉ | L_{b135} | 5128 | Lₐ₃₈₉₁ | L_{b135} |
| 5129 | Lₐ₃₈₉₄ | L_{b135} | 5130 | Lₐ₃₉₀₁ | L_{b135} |
| 5131 | Lₐ₃₉₀₃ | L_{b135} | 5132 | Lₐ₃₉₀₆ | L_{b135} |
| 5133 | Lₐ₃₉₁₃ | L_{b135} | 5134 | Lₐ₃₉₁₅ | L_{b135} |
| 5135 | Lₐ₃₉₁₈ | L_{b135} | 5136 | Lₐ₃₉₂₁ | L_{b135} |
| 5137 | Lₐ₃₉₂₃ | L_{b135} | 5138 | Lₐ₃₉₂₄ | L_{b135} |
| 5139 | Lₐ₃₉₂₅ | L_{b135} | 5140 | Lₐ₃₉₂₇ | L_{b135} |
| 5141 | Lₐ₃₉₂₈ | L_{b135} | 5142 | Lₐ₃₉₃₀ | L_{b135} |
| 5143 | Lₐ₃₉₃₇ | L_{b135} | 5144 | Lₐ₃₉₃₉ | L_{b135} |
| 5145 | Lₐ₃₉₄₉ | L_{b135} | 5146 | Lₐ₃₉₅₁ | L_{b135} |
| 5147 | Lₐ₃₉₆₁ | L_{b135} | 5148 | Lₐ₃₉₆₃ | L_{b135} |
| 5149 | Lₐ₃₉₆₆ | L_{b135} | 5150 | Lₐ₃₉₇₃ | L_{b135} |
| 5151 | Lₐ₃₉₇₅ | L_{b135} | 5152 | Lₐ₃₉₇₈ | L_{b135} |
| 5153 | Lₐ₃₉₈₅ | L_{b135} | 5154 | Lₐ₃₉₈₇ | L_{b135} |
| 5155 | Lₐ₃₉₉₀ | L_{b135} | 5156 | Lₐ₃₉₉₇ | L_{b135} |
| 5157 | Lₐ₃₉₉₉ | L_{b135} | 5158 | Lₐ₄₀₀₂ | L_{b135} |
| 5159 | Lₐ₄₀₀₉ | L_{b135} | 5160 | Lₐ₄₀₁₁ | L_{b135} |
| 5161 | Lₐ₄₀₁₄ | L_{b135} | 5162 | Lₐ₄₀₂₁ | L_{b135} |
| 5163 | Lₐ₄₀₂₃ | L_{b135} | 5164 | Lₐ₄₀₂₆ | L_{b135} |
| 5165 | Lₐ₄₀₃₁ | L_{b135} | 5166 | Lₐ₄₀₃₆ | L_{b135} |
| 5167 | Lₐ₄₀₃₇ | L_{b135} | 5168 | Lₐ₄₀₃₉ | L_{b135} |
| 5169 | Lₐ₄₀₄₃ | L_{b135} | 5170 | Lₐ₄₀₄₉ | L_{b135} |
| 5171 | Lₐ₄₀₅₄ | L_{b135} | 5172 | Lₐ₄₀₅₅ | L_{b135} |
| 5173 | Lₐ₄₀₅₇ | L_{b135} | 5174 | Lₐ₄₀₆₁ | L_{b135} |
| 5175 | Lₐ₄₁₃₉ | L_{b135} | 5176 | Lₐ₄₁₄₄ | L_{b135} |
| 5177 | Lₐ₄₁₄₅ | L_{b135} | 5178 | Lₐ₄₁₄₇ | L_{b135} |
| 5179 | Lₐ₄₁₅₁ | L_{b135} | 5180 | Lₐ₄₂₃₁ | L_{b135} |
| 5181 | Lₐ₄₂₃₃ | L_{b135} | 5182 | Lₐ₄₂₃₆ | L_{b135} |
| 5183 | Lₐ₄₂₄₃ | L_{b135} | 5184 | Lₐ₄₂₄₅ | L_{b135} |
| 5185 | Lₐ₄₂₄₈ | L_{b135} | 5186 | Lₐ₄₂₆₇ | L_{b135} |
| 5187 | Lₐ₄₂₆₉ | L_{b135} | 5188 | Lₐ₄₂₇₂ | L_{b135} |
| 5189 | Lₐ₄₂₈₇ | L_{b135} | 5190 | Lₐ₄₂₈₉ | L_{b135} |
| 5191 | Lₐ₄₂₉₁ | L_{b135} | 5192 | Lₐ₄₂₉₃ | L_{b135} |
| 5193 | Lₐ₄₂₉₄ | L_{b135} | 5194 | Lₐ₄₂₉₆ | L_{b135} |
| 5195 | Lₐ₄₃₀₃ | L_{b135} | 5196 | Lₐ₄₃₀₅ | L_{b135} |
| 5197 | Lₐ₄₃₁₅ | L_{b135} | 5198 | Lₐ₄₃₁₇ | L_{b135} |
| 5199 | Lₐ₄₃₂₇ | L_{b135} | 5200 | Lₐ₄₃₂₉ | L_{b135} |
| 5201 | Lₐ₄₃₃₂ | L_{b135} | 5202 | Lₐ₄₃₃₉ | L_{b135} |
| 5203 | Lₐ₄₃₄₁ | L_{b135} | 5204 | Lₐ₄₃₄₄ | L_{b135} |
| 5205 | Lₐ₄₃₆₃ | L_{b135} | 5206 | Lₐ₄₃₆₅ | L_{b135} |
| 5207 | Lₐ₄₃₆₈ | L_{b135} | 5208 | Lₐ₄₃₇₅ | L_{b135} |
| 5209 | Lₐ₄₃₇₇ | L_{b135} | 5210 | Lₐ₄₃₈₀ | L_{b135} |
| 5211 | Lₐ₄₃₉₇ | L_{b135} | 5212 | Lₐ₄₃₉₉ | L_{b135} |
| 5213 | Lₐ₄₄₀₂ | L_{b135} | 5214 | Lₐ₄₄₀₃ | L_{b135} |
| 5215 | Lₐ₄₄₀₅ | L_{b135} | 5216 | Lₐ₄₄₀₆ | L_{b135} |
| 5217 | Lₐ₄₄₀₉ | L_{b135} | 5218 | Lₐ₄₄₁₅ | L_{b135} |
| 5219 | Lₐ₄₄₂₀ | L_{b135} | 5220 | Lₐ₄₄₂₃ | L_{b135} |
| 5221 | Lₐ₄₄₂₇ | L_{b135} | 5222 | Lₐ₄₄₅₁ | L_{b135} |
| 5223 | Lₐ₄₄₅₆ | L_{b135} | 5224 | Lₐ₄₄₅₇ | L_{b135} |
| 5225 | Lₐ₄₄₅₉ | L_{b135} | 5226 | Lₐ₄₄₆₃ | L_{b135} |
| 5227 | Lₐ₄₅₉₇ | L_{b135} | 5228 | Lₐ₄₅₉₉ | L_{b135} |
| 5229 | Lₐ₄₆₀₂ | L_{b135} | 5230 | Lₐ₄₆₀₉ | L_{b135} |
| 5231 | Lₐ₄₆₁₁ | L_{b135} | 5232 | Lₐ₄₆₂₁ | L_{b135} |
| 5233 | Lₐ₄₆₂₃ | L_{b135} | 5234 | Lₐ₄₆₃₃ | L_{b135} |
| 5235 | Lₐ₄₆₃₅ | L_{b135} | 5236 | Lₐ₄₆₄₅ | L_{b135} |
| 5237 | Lₐ₄₆₄₇ | L_{b135} | 5238 | Lₐ₄₆₅₃ | L_{b135} |
| 5239 | Lₐ₄₆₅₅ | L_{b135} | 5240 | Lₐ₄₆₅₇ | L_{b135} |
| 5241 | Lₐ₄₆₅₉ | L_{b135} | 5242 | Lₐ₄₆₆₂ | L_{b135} |
| 5243 | Lₐ₄₆₆₉ | L_{b135} | 5244 | Lₐ₄₆₇₁ | L_{b135} |
| 5245 | Lₐ₄₆₈₁ | L_{b135} | 5246 | Lₐ₄₆₈₃ | L_{b135} |
| 5247 | Lₐ₄₆₉₃ | L_{b135} | 5248 | Lₐ₄₆₉₅ | L_{b135} |
| 5249 | Lₐ₄₆₉₈ | L_{b135} | 5250 | Lₐ₄₇₀₅ | L_{b135} |
| 5251 | Lₐ₄₇₀₇ | L_{b135} | 5252 | Lₐ₄₇₁₀ | L_{b135} |
| 5253 | Lₐ₄₇₂₉ | L_{b135} | 5254 | Lₐ₄₇₃₁ | L_{b135} |
| 5255 | Lₐ₄₇₃₄ | L_{b135} | 5256 | Lₐ₄₇₆₃ | L_{b135} |
| 5257 | Lₐ₄₉₆₃ | L_{b135} | 5258 | Lₐ₄₉₆₅ | L_{b135} |
| 5259 | Lₐ₄₉₆₈ | L_{b135} | 5260 | Lₐ₅₀₂₃ | L_{b135} |
| 5261 | Lₐ₅₀₂₅ | L_{b135} | 5262 | Lₐ₅₀₃₅ | L_{b135} |
| 5263 | Lₐ₅₀₃₇ | L_{b135} | 5264 | Lₐ₅₀₄₇ | L_{b135} |
| 5265 | Lₐ₅₀₄₉ | L_{b135} | 5266 | Lₐ₅₁₂₉ | L_{b135} |
| 5267 | Lₐ₅₁₃₄ | L_{b135} | 5268 | Lₐ₅₁₃₅ | L_{b135} |
| 5269 | Lₐ₅₁₃₇ | L_{b135} | 5270 | Lₐ₅₁₄₁ | L_{b135} |
| 5271 | Lₐ₅₁₄₇ | L_{b135} | 5272 | Lₐ₅₁₅₂ | L_{b135} |
| 5273 | Lₐ₅₁₅₃ | L_{b135} | 5274 | Lₐ₅₁₅₅ | L_{b135} |
| 5275 | Lₐ₅₁₅₉ | L_{b135} | 5276 | Lₐ₅₂₃₇ | L_{b135} |
| 5277 | Lₐ₅₂₄₂ | L_{b135} | 5278 | Lₐ₅₂₄₃ | L_{b135} |
| 5279 | Lₐ₅₂₄₅ | L_{b135} | 5280 | Lₐ₅₂₄₉ | L_{b135} |
| 5281 | Lₐ₅₃₂₉ | L_{b135} | 5282 | Lₐ₅₃₃₁ | L_{b135} |
| 5283 | Lₐ₅₃₃₄ | L_{b135} | 5284 | Lₐ₅₃₄₁ | L_{b135} |
| 5285 | Lₐ₅₃₄₃ | L_{b135} | 5286 | Lₐ₅₃₄₆ | L_{b135} |
| 5287 | Lₐ₅₃₆₅ | L_{b135} | 5288 | Lₐ₅₃₆₇ | L_{b135} |
| 5289 | Lₐ₅₃₇₀ | L_{b135} | 5290 | Lₐ₅₃₈₅ | L_{b135} |
| 5291 | Lₐ₅₃₈₇ | L_{b135} | 5292 | Lₐ₅₃₈₉ | L_{b135} |
| 5293 | Lₐ₅₃₉₁ | L_{b135} | 5294 | Lₐ₅₃₉₂ | L_{b135} |
| 5295 | Lₐ₅₃₉₄ | L_{b135} | 5296 | Lₐ₅₄₀₁ | L_{b135} |
| 5297 | Lₐ₅₄₀₃ | L_{b135} | 5298 | Lₐ₅₄₁₃ | L_{b135} |
| 5299 | Lₐ₅₄₁₅ | L_{b135} | 5300 | Lₐ₅₄₂₅ | L_{b135} |
| 5301 | Lₐ₅₄₂₇ | L_{b135} | 5302 | Lₐ₅₄₃₀ | L_{b135} |
| 5303 | Lₐ₅₄₆₁ | L_{b135} | 5304 | Lₐ₅₄₆₃ | L_{b135} |
| 5305 | Lₐ₅₄₆₆ | L_{b135} | 5306 | Lₐ₅₄₉₅ | L_{b135} |
| 5307 | Lₐ₅₆₉₅ | L_{b135} | 5308 | Lₐ₅₆₉₇ | L_{b135} |
| 5309 | Lₐ₅₇₅₅ | L_{b135} | 5310 | Lₐ₅₇₅₇ | L_{b135} |
| 5311 | Lₐ₅₇₆₀ | L_{b135} | 5312 | Lₐ₅₇₆₇ | L_{b135} |
| 5313 | Lₐ₅₇₆₉ | L_{b135} | 5314 | Lₐ₅₇₇₉ | L_{b135} |
| 5315 | Lₐ₅₇₈₁ | L_{b135} | 5316 | Lₐ₅₈₆₁ | L_{b135} |
| 5317 | Lₐ₅₈₆₆ | L_{b135} | 5318 | Lₐ₅₈₆₇ | L_{b135} |
| 5319 | Lₐ₅₈₆₉ | L_{b135} | 5320 | Lₐ₅₈₇₃ | L_{b135} |
| 5321 | Lₐ₅₈₇₉ | L_{b135} | 5322 | Lₐ₅₈₈₄ | L_{b135} |
| 5323 | Lₐ₅₈₈₅ | L_{b135} | 5324 | Lₐ₅₈₈₇ | L_{b135} |
| 5325 | Lₐ₅₈₉₁ | L_{b135} | 5326 | Lₐ₅₉₆₉ | L_{b135} |
| 5327 | Lₐ₅₉₇₄ | L_{b135} | 5328 | Lₐ₅₉₇₅ | L_{b135} |
| 5329 | Lₐ₅₉₇₇ | L_{b135} | 5330 | Lₐ₅₉₈₁ | L_{b135} |
| 5331 | Lₐ₆₀₅₇ | L_{b135} | 5332 | Lₐ₆₀₅₉ | L_{b135} |
| 5333 | Lₐ₆₀₆₁ | L_{b135} | 5334 | Lₐ₆₀₆₃ | L_{b135} |
| 5335 | Lₐ₆₀₆₆ | L_{b135} | 5336 | Lₐ₆₀₇₃ | L_{b135} |
| 5337 | Lₐ₆₀₇₅ | L_{b135} | 5338 | Lₐ₆₀₇₈ | L_{b135} |
| 5339 | Lₐ₆₀₈₅ | L_{b135} | 5340 | Lₐ₆₀₈₇ | L_{b135} |
| 5341 | Lₐ₆₀₉₇ | L_{b135} | 5342 | Lₐ₆₀₉₉ | L_{b135} |
| 5343 | Lₐ₆₁₁₇ | L_{b135} | 5344 | Lₐ₆₁₁₉ | L_{b135} |
| 5345 | Lₐ₆₁₂₁ | L_{b135} | 5346 | Lₐ₆₁₂₃ | L_{b135} |
| 5347 | Lₐ₆₁₂₆ | L_{b135} | 5348 | Lₐ₆₁₃₃ | L_{b135} |
| 5349 | Lₐ₆₁₃₅ | L_{b135} | 5350 | Lₐ₆₁₄₅ | L_{b135} |
| 5351 | Lₐ₆₁₄₇ | L_{b135} | 5352 | Lₐ₆₁₅₇ | L_{b135} |
| 5353 | Lₐ₆₁₅₉ | L_{b135} | 5354 | Lₐ₆₁₆₂ | L_{b135} |
| 5355 | Lₐ₆₁₆₉ | L_{b135} | 5356 | Lₐ₆₁₇₁ | L_{b135} |
| 5357 | Lₐ₆₁₇₄ | L_{b135} | 5358 | Lₐ₆₁₉₃ | L_{b135} |
| 5359 | Lₐ₆₁₉₅ | L_{b135} | 5360 | Lₐ₆₁₉₈ | L_{b135} |
| 5361 | Lₐ₆₂₀₅ | L_{b135} | 5362 | Lₐ₆₂₀₇ | L_{b135} |
| 5363 | Lₐ₆₂₂₇ | L_{b135} | 5364 | Lₐ₆₂₃₂ | L_{b135} |
| 5365 | Lₐ₆₂₃₃ | L_{b135} | 5366 | Lₐ₆₂₃₅ | L_{b135} |
| 5367 | Lₐ₆₂₃₉ | L_{b135} | 5368 | Lₐ₆₂₄₅ | L_{b135} |
| 5369 | Lₐ₆₂₅₀ | L_{b135} | 5370 | Lₐ₆₂₅₁ | L_{b135} |
| 5371 | Lₐ₆₂₅₃ | L_{b135} | 5372 | Lₐ₆₂₅₇ | L_{b135} |
| 5373 | Lₐ₆₃₃₅ | L_{b135} | 5374 | Lₐ₆₃₄₀ | L_{b135} |
| 5375 | Lₐ₆₃₄₁ | L_{b135} | 5376 | Lₐ₆₃₄₃ | L_{b135} |
| 5377 | Lₐ₆₃₄₇ | L_{b135} | 5378 | Lₐ₆₄₂₃ | L_{b135} |
| 5379 | Lₐ₆₄₂₅ | L_{b135} | 5380 | Lₐ₆₄₂₇ | L_{b135} |
| 5381 | Lₐ₆₄₂₉ | L_{b135} | 5382 | Lₐ₆₄₃₂ | L_{b135} |
| 5383 | Lₐ₆₄₃₉ | L_{b135} | 5384 | Lₐ₆₄₄₁ | L_{b135} |
| 5385 | Lₐ₆₄₄₄ | L_{b135} | 5386 | Lₐ₆₄₆₃ | L_{b135} |
| 5387 | Lₐ₆₄₆₅ | L_{b135} | 5388 | Lₐ₆₄₆₈ | L_{b135} |
| 5389 | Lₐ₆₄₈₃ | L_{b135} | 5390 | Lₐ₆₄₈₅ | L_{b135} |
| 5391 | Lₐ₆₄₈₇ | L_{b135} | 5392 | Lₐ₆₄₈₉ | L_{b135} |
| 5393 | Lₐ₆₄₉₂ | L_{b135} | 5394 | Lₐ₆₄₉₉ | L_{b135} |
| 5395 | Lₐ₆₅₀₁ | L_{b135} | 5396 | Lₐ₆₅₁₁ | L_{b135} |
| 5397 | Lₐ₆₅₁₃ | L_{b135} | 5398 | Lₐ₆₅₂₃ | L_{b135} |
| 5399 | Lₐ₆₅₂₅ | L_{b135} | 5400 | Lₐ₆₅₂₈ | L_{b135} |
| 5401 | Lₐ₆₅₃₅ | L_{b135} | 5402 | Lₐ₆₅₃₇ | L_{b135} |
| 5403 | Lₐ₆₅₄₀ | L_{b135} | 5404 | Lₐ₆₅₅₉ | L_{b135} |
| 5405 | Lₐ₆₅₆₁ | L_{b135} | 5406 | Lₐ₆₅₆₄ | L_{b135} |
| 5407 | Lₐ₆₅₇₁ | L_{b135} | 5408 | Lₐ₆₅₇₃ | L_{b135} |
| 5409 | Lₐ₆₅₉₃ | L_{b135} | 5410 | Lₐ₆₅₉₈ | L_{b135} |
| 5411 | Lₐ₆₅₉₉ | L_{b135} | 5412 | Lₐ₆₆₀₁ | L_{b135} |
| 5413 | Lₐ₆₆₀₅ | L_{b135} | 5414 | Lₐ₆₆₁₁ | L_{b135} |
| 5415 | Lₐ₆₆₁₆ | L_{b135} | 5416 | Lₐ₆₆₁₉ | L_{b135} |
| 5417 | Lₐ₆₆₂₃ | L_{b135} | 5418 | Lₐ₆₇₀₀ | L_{b135} |
| 5419 | Lₐ₆₇₀₁ | L_{b135} | 5420 | Lₐ₆₇₀₃ | L_{b135} |
| 5421 | Lₐ₆₇₀₆ | L_{b135} | 5422 | Lₐ₆₇₀₇ | L_{b135} |
| 5423 | Lₐ₆₇₀₉ | L_{b135} | 5424 | Lₐ₆₇₁₃ | L_{b135} |
| 5425 | Lₐ₆₇₄₂ | L_{b135} | 5426 | Lₐ₆₇₄₅ | L_{b135} |
| 5427 | Lₐ₆₇₉₃ | L_{b135} | 5428 | Lₐ₆₇₉₅ | L_{b135} |
| 5429 | Lₐ₆₇₉₈ | L_{b135} | 5430 | Lₐ₆₈₀₅ | L_{b135} |
| 5431 | Lₐ₆₈₀₇ | L_{b135} | 5432 | Lₐ₆₈₁₀ | L_{b135} |
| 5433 | Lₐ₆₈₂₉ | L_{b135} | 5434 | Lₐ₆₈₃₁ | L_{b135} |
| 5435 | Lₐ₆₈₃₄ | L_{b135} | 5436 | Lₐ₆₈₄₉ | L_{b135} |
| 5437 | Lₐ₆₈₅₁ | L_{b135} | 5438 | Lₐ₆₈₅₃ | L_{b135} |
| 5439 | Lₐ₆₈₅₅ | L_{b135} | 5440 | Lₐ₆₈₅₈ | L_{b135} |
| 5441 | Lₐ₆₈₆₅ | L_{b135} | 5442 | Lₐ₆₈₆₇ | L_{b135} |
| 5443 | Lₐ₆₈₇₇ | L_{b135} | 5444 | Lₐ₆₈₇₉ | L_{b135} |
| 5445 | Lₐ₆₈₈₉ | L_{b135} | 5446 | Lₐ₆₈₉₁ | L_{b135} |
| 5447 | Lₐ₆₈₉₄ | L_{b135} | 5448 | Lₐ₆₉₀₁ | L_{b135} |
| 5449 | Lₐ₆₉₀₃ | L_{b135} | 5450 | Lₐ₆₉₂₅ | L_{b135} |
| 5451 | Lₐ₆₉₂₇ | L_{b135} | 5452 | Lₐ₆₉₃₀ | L_{b135} |
| 5453 | Lₐ₆₉₃₇ | L_{b135} | 5454 | Lₐ₆₉₃₉ | L_{b135} |
| 5455 | Lₐ₅ | L_{b12} | 5456 | Lₐ₂₀₅ | L_{b12} |
| 5457 | Lₐ₂₀₇ | L_{b12} | 5458 | Lₐ₂₆₅ | L_{b12} |
| 5459 | Lₐ₂₆₇ | L_{b12} | 5460 | Lₐ₁₁₀₃ | L_{b12} |
| 5461 | Lₐ₂₉₃₃ | L_{b12} | 5462 | Lₐ₃₁₃₃ | L_{b12} |
| 5463 | Lₐ₃₁₃₅ | L_{b12} | 5464 | Lₐ₃₁₉₃ | L_{b12} |
| 5465 | Lₐ₃₁₉₅ | L_{b12} | 5466 | Lₐ₃₆₆₅ | L_{b12} |
| 5467 | Lₐ₃₈₆₅ | L_{b12} | 5468 | Lₐ₃₈₆₇ | L_{b12} |
| 5469 | Lₐ₃₉₂₅ | L_{b12} | 5470 | Lₐ₃₉₂₇ | L_{b12} |
| 5471 | Lₐ₄₀₃₁ | L_{b12} | 5472 | Lₐ₄₂₃₁ | L_{b12} |
| 5473 | Lₐ₄₂₃₃ | L_{b12} | 5474 | Lₐ₄₂₉₁ | L_{b12} |
| 5475 | Lₐ₄₂₉₃ | L_{b12} | 5476 | Lₐ₄₃₉₇ | L_{b12} |
| 5477 | Lₐ₄₅₉₇ | L_{b12} | 5478 | Lₐ₄₅₉₉ | L_{b12} |
| 5479 | Lₐ₄₆₅₇ | L_{b12} | 5480 | Lₐ₄₆₅₉ | L_{b12} |
| 5481 | Lₐ₅ | L_{b17} | 5482 | Lₐ₂₀₅ | L_{b17} |
| 5483 | Lₐ₂₀₇ | L_{b17} | 5484 | Lₐ₂₆₅ | L_{b17} |
| 5485 | Lₐ₂₆₇ | L_{b17} | 5486 | Lₐ₁₁₀₃ | L_{b17} |
| 5487 | Lₐ₂₉₃₃ | L_{b17} | 5488 | Lₐ₃₁₃₃ | L_{b17} |
| 5489 | Lₐ₃₁₃₅ | L_{b17} | 5490 | Lₐ₃₁₉₃ | L_{b17} |
| 5491 | Lₐ₃₁₉₅ | L_{b17} | 5492 | Lₐ₃₆₆₅ | L_{b17} |
| 5493 | Lₐ₃₈₆₅ | L_{b17} | 5494 | Lₐ₃₈₆₇ | L_{b17} |
| 5495 | Lₐ₃₉₂₅ | L_{b17} | 5496 | Lₐ₃₉₂₇ | L_{b17} |
| 5497 | Lₐ₄₀₃₁ | L_{b17} | 5498 | Lₐ₄₂₃₁ | L_{b17} |
| 5499 | Lₐ₄₂₃₃ | L_{b17} | 5500 | Lₐ₄₂₉₁ | L_{b17} |
| 5501 | Lₐ₄₂₉₃ | L_{b17} | 5502 | Lₐ₄₃₉₇ | L_{b17} |
| 5503 | Lₐ₄₅₉₇ | L_{b17} | 5504 | Lₐ₄₅₉₉ | L_{b17} |
| 5505 | Lₐ₄₆₅₇ | L_{b17} | 5506 | Lₐ₄₆₅₉ | L_{b17} |
| 5507 | Lₐ₅ | L_{b19} | 5508 | Lₐ₂₀₅ | L_{b19} |
| 5509 | Lₐ₂₀₇ | L_{b19} | 5510 | Lₐ₂₆₅ | L_{b19} |
| 5511 | Lₐ₂₆₇ | L_{b19} | 5512 | Lₐ₁₁₀₃ | L_{b19} |
| 5513 | Lₐ₂₉₃₃ | L_{b19} | 5514 | Lₐ₃₁₃₃ | L_{b19} |
| 5515 | Lₐ₃₁₃₅ | L_{b19} | 5516 | Lₐ₃₁₉₃ | L_{b19} |
| 5517 | Lₐ₃₁₉₅ | L_{b19} | 5518 | Lₐ₃₆₆₅ | L_{b19} |
| 5519 | Lₐ₃₈₆₅ | L_{b19} | 5520 | Lₐ₃₈₆₇ | L_{b19} |
| 5521 | Lₐ₃₉₂₅ | L_{b19} | 5522 | Lₐ₃₉₂₇ | L_{b19} |
| 5523 | Lₐ₄₀₃₁ | L_{b19} | 5524 | Lₐ₄₂₃₁ | L_{b19} |
| 5525 | Lₐ₄₂₃₃ | L_{b19} | 5526 | Lₐ₄₂₉₁ | L_{b19} |
| 5527 | Lₐ₄₂₉₃ | L_{b19} | 5528 | Lₐ₄₃₉₇ | L_{b19} |
| 5529 | Lₐ₄₅₉₇ | L_{b19} | 5530 | Lₐ₄₅₉₉ | L_{b19} |
| 5531 | Lₐ₄₆₅₇ | L_{b19} | 5532 | Lₐ₄₆₅₉ | L_{b19} |
| 5533 | Lₐ₅ | L_{b24} | 5534 | Lₐ₂₀₅ | L_{b24} |
| 5535 | Lₐ₂₀₇ | L_{b24} | 5536 | Lₐ₂₆₅ | L_{b24} |
| 5537 | Lₐ₂₆₇ | L_{b24} | 5538 | Lₐ₁₁₀₃ | L_{b24} |
| 5539 | Lₐ₂₉₃₃ | L_{b24} | 5540 | Lₐ₃₁₃₃ | L_{b24} |
| 5541 | Lₐ₃₁₃₅ | L_{b24} | 5542 | Lₐ₃₁₉₃ | L_{b24} |
| 5543 | Lₐ₃₁₉₅ | L_{b24} | 5544 | Lₐ₃₆₆₅ | L_{b24} |
| 5545 | Lₐ₃₈₆₅ | L_{b24} | 5546 | Lₐ₃₈₆₇ | L_{b24} |
| 5547 | Lₐ₃₉₂₅ | L_{b24} | 5548 | Lₐ₃₉₂₇ | L_{b24} |
| 5549 | Lₐ₄₀₃₁ | L_{b24} | 5550 | Lₐ₄₂₃₁ | L_{b24} |
| 5551 | Lₐ₄₂₃₃ | L_{b24} | 5552 | Lₐ₄₂₉₁ | L_{b24} |
| 5553 | Lₐ₄₂₉₃ | L_{b24} | 5554 | Lₐ₄₃₉₇ | L_{b24} |
| 5555 | Lₐ₄₅₉₇ | L_{b24} | 5556 | Lₐ₄₅₉₉ | L_{b24} |
| 5557 | Lₐ₄₆₅₇ | L_{b24} | 5558 | Lₐ₄₆₅₉ | L_{b24} |
| 5559 | Lₐ₅ | L_{b26} | 5560 | Lₐ₂₀₅ | L_{b26} |
| 5561 | Lₐ₂₀₇ | L_{b26} | 5562 | Lₐ₂₆₅ | L_{b26} |
| 5563 | Lₐ₂₆₇ | L_{b26} | 5564 | Lₐ₁₁₀₃ | L_{b26} |
| 5565 | Lₐ₂₉₃₃ | L_{b26} | 5566 | Lₐ₃₁₃₃ | L_{b26} |
| 5567 | Lₐ₃₁₃₅ | L_{b26} | 5568 | Lₐ₃₁₉₃ | L_{b26} |
| 5569 | Lₐ₃₁₉₅ | L_{b26} | 5570 | Lₐ₃₆₆₅ | L_{b26} |
| 5571 | Lₐ₃₈₆₅ | L_{b26} | 5572 | Lₐ₃₈₆₇ | L_{b26} |
| 5573 | Lₐ₃₉₂₅ | L_{b26} | 5574 | Lₐ₃₉₂₇ | L_{b26} |
| 5575 | Lₐ₄₀₃₁ | L_{b26} | 5576 | Lₐ₄₂₃₁ | L_{b26} |
| 5577 | Lₐ₄₂₃₃ | L_{b26} | 5578 | Lₐ₄₂₉₁ | L_{b26} |
| 5579 | Lₐ₄₂₉₃ | L_{b26} | 5580 | Lₐ₄₃₉₇ | L_{b26} |
| 5581 | Lₐ₄₅₉₇ | L_{b26} | 5582 | Lₐ₄₅₉₉ | L_{b26} |
| 5583 | Lₐ₄₆₅₇ | L_{b26} | 5584 | Lₐ₄₆₅₉ | L_{b26} |
| 5585 | Lₐ₅ | L_{b27} | 5586 | Lₐ₂₀₅ | L_{b27} |
| 5587 | Lₐ₂₀₇ | L_{b27} | 5588 | Lₐ₂₆₅ | L_{b27} |
| 5589 | Lₐ₂₆₇ | L_{b27} | 5590 | Lₐ₁₁₀₃ | L_{b27} |
| 5591 | Lₐ₂₉₃₃ | L_{b27} | 5592 | Lₐ₃₁₃₃ | L_{b27} |
| 5593 | Lₐ₃₁₃₅ | L_{b27} | 5594 | Lₐ₃₁₉₃ | L_{b27} |
| 5595 | Lₐ₃₁₉₅ | L_{b27} | 5596 | Lₐ₃₆₆₅ | L_{b27} |
| 5597 | Lₐ₃₈₆₅ | L_{b27} | 5598 | Lₐ₃₈₆₇ | L_{b27} |
| 5599 | Lₐ₃₉₂₅ | L_{b27} | 5600 | Lₐ₃₉₂₇ | L_{b27} |
| 5601 | Lₐ₄₀₃₁ | L_{b27} | 5602 | Lₐ₄₂₃₁ | L_{b27} |
| 5603 | Lₐ₄₂₃₃ | L_{b27} | 5604 | Lₐ₄₂₉₁ | L_{b27} |
| 5605 | Lₐ₄₂₉₃ | L_{b27} | 5606 | Lₐ₄₃₉₇ | L_{b27} |
| 5607 | Lₐ₄₅₉₇ | L_{b27} | 5608 | Lₐ₄₅₉₉ | L_{b27} |
| 5609 | Lₐ₄₆₅₇ | L_{b27} | 5610 | Lₐ₄₆₅₉ | L_{b27} |
| 5611 | Lₐ₅ | L_{b28} | 5612 | Lₐ₂₀₅ | L_{b28} |
| 5613 | Lₐ₂₀₇ | L_{b28} | 5614 | Lₐ₂₆₅ | L_{b28} |
| 5615 | Lₐ₂₆₇ | L_{b28} | 5616 | Lₐ₁₁₀₃ | L_{b28} |
| 5617 | Lₐ₂₉₃₃ | L_{b28} | 5618 | Lₐ₃₁₃₃ | L_{b28} |
| 5619 | Lₐ₃₁₃₅ | L_{b28} | 5620 | Lₐ₃₁₉₃ | L_{b28} |
| 5621 | Lₐ₃₁₉₅ | L_{b28} | 5622 | Lₐ₃₆₆₅ | L_{b28} |
| 5623 | Lₐ₃₈₆₅ | L_{b28} | 5624 | Lₐ₃₈₆₇ | L_{b28} |
| 5625 | Lₐ₃₉₂₅ | L_{b28} | 5626 | Lₐ₃₉₂₇ | L_{b28} |
| 5627 | Lₐ₄₀₃₁ | L_{b28} | 5628 | Lₐ₄₂₃₁ | L_{b28} |
| 5629 | Lₐ₄₂₃₃ | L_{b28} | 5630 | Lₐ₄₂₉₁ | L_{b28} |
| 5631 | Lₐ₄₂₉₃ | L_{b28} | 5632 | Lₐ₄₃₉₇ | L_{b28} |
| 5633 | Lₐ₄₅₉₇ | L_{b28} | 5634 | Lₐ₄₅₉₉ | L_{b28} |
| 5635 | Lₐ₄₆₅₇ | L_{b28} | 5636 | Lₐ₄₆₅₉ | L_{b28} |
| 5637 | Lₐ₅ | L_{b29} | 5638 | Lₐ₂₀₅ | L_{b29} |
| 5639 | Lₐ₂₀₇ | L_{b29} | 5640 | Lₐ₂₆₅ | L_{b29} |
| 5641 | Lₐ₂₆₇ | L_{b29} | 5642 | Lₐ₁₁₀₃ | L_{b29} |
| 5643 | Lₐ₂₉₃₃ | L_{b29} | 5644 | Lₐ₃₁₃₃ | L_{b29} |
| 5645 | Lₐ₃₁₃₅ | L_{b29} | 5646 | Lₐ₃₁₉₃ | L_{b29} |
| 5647 | Lₐ₃₁₉₅ | L_{b29} | 5648 | Lₐ₃₆₆₅ | L_{b29} |
| 5649 | Lₐ₃₈₆₅ | L_{b29} | 5650 | Lₐ₃₈₆₇ | L_{b29} |
| 5651 | Lₐ₃₉₂₅ | L_{b29} | 5652 | Lₐ₃₉₂₇ | L_{b29} |
| 5653 | Lₐ₄₀₃₁ | L_{b29} | 5654 | Lₐ₄₂₃₁ | L_{b29} |
| 5655 | Lₐ₄₂₃₃ | L_{b29} | 5656 | Lₐ₄₂₉₁ | L_{b29} |
| 5657 | Lₐ₄₂₉₃ | L_{b29} | 5658 | Lₐ₄₃₉₇ | L_{b29} |
| 5659 | Lₐ₄₅₉₇ | L_{b29} | 5660 | Lₐ₄₅₉₉ | L_{b29} |
| 5661 | Lₐ₄₆₅₇ | L_{b29} | 5662 | Lₐ₄₆₅₉ | L_{b29} |
| 5663 | Lₐ₅ | L_{b30} | 5664 | Lₐ₂₀₅ | L_{b30} |
| 5665 | Lₐ₂₀₇ | L_{b30} | 5666 | Lₐ₂₆₅ | L_{b30} |
| 5667 | Lₐ₂₆₇ | L_{b30} | 5668 | Lₐ₁₁₀₃ | L_{b30} |
| 5669 | Lₐ₂₉₃₃ | L_{b30} | 5670 | Lₐ₃₁₃₃ | L_{b30} |
| 5671 | Lₐ₃₁₃₅ | L_{b30} | 5672 | Lₐ₃₁₉₃ | L_{b30} |
| 5673 | Lₐ₃₁₉₅ | L_{b30} | 5674 | Lₐ₃₆₆₅ | L_{b30} |
| 5675 | Lₐ₃₈₆₅ | L_{b30} | 5676 | Lₐ₃₈₆₇ | L_{b30} |
| 5677 | Lₐ₃₉₂₅ | L_{b30} | 5678 | Lₐ₃₉₂₇ | L_{b30} |
| 5679 | Lₐ₄₀₃₁ | L_{b30} | 5680 | Lₐ₄₂₃₁ | L_{b30} |
| 5681 | Lₐ₄₂₃₃ | L_{b30} | 5682 | Lₐ₄₂₉₁ | L_{b30} |
| 5683 | Lₐ₄₂₉₃ | L_{b30} | 5684 | Lₐ₄₃₉₇ | L_{b30} |
| 5685 | Lₐ₄₅₉₇ | L_{b30} | 5686 | Lₐ₄₅₉₉ | L_{b30} |
| 5687 | Lₐ₄₆₅₇ | L_{b30} | 5688 | Lₐ₄₆₅₉ | L_{b30} |
| 5689 | Lₐ₅ | L_{b31} | 5690 | Lₐ₂₀₅ | L_{b31} |
| 5691 | Lₐ₂₀₇ | L_{b31} | 5692 | Lₐ₂₆₅ | L_{b31} |
| 5693 | Lₐ₂₆₇ | L_{b31} | 5694 | Lₐ₁₁₀₃ | L_{b31} |
| 5695 | Lₐ₂₉₃₃ | L_{b31} | 5696 | Lₐ₃₁₃₃ | L_{b31} |
| 5697 | Lₐ₃₁₃₅ | L_{b31} | 5698 | Lₐ₃₁₉₃ | L_{b31} |
| 5699 | Lₐ₃₁₉₅ | L_{b31} | 5700 | Lₐ₃₆₆₅ | L_{b31} |
| 5701 | Lₐ₃₈₆₅ | L_{b31} | 5702 | Lₐ₃₈₆₇ | L_{b31} |
| 5703 | Lₐ₃₉₂₅ | L_{b31} | 5704 | Lₐ₃₉₂₇ | L_{b31} |
| 5705 | Lₐ₄₀₃₁ | L_{b31} | 5706 | Lₐ₄₂₃₁ | L_{b31} |
| 5707 | Lₐ₄₂₃₃ | L_{b31} | 5708 | Lₐ₄₂₉₁ | L_{b31} |
| 5709 | Lₐ₄₂₉₃ | L_{b31} | 5710 | Lₐ₄₃₉₇ | L_{b31} |
| 5711 | Lₐ₄₅₉₇ | L_{b31} | 5712 | Lₐ₄₅₉₉ | L_{b31} |
| 5713 | Lₐ₄₆₅₇ | L_{b31} | 5714 | Lₐ₄₆₅₉ | L_{b31} |
| 5715 | Lₐ₅ | L_{b32} | 5716 | Lₐ₂₀₅ | L_{b32} |
| 5717 | Lₐ₂₀₇ | L_{b32} | 5718 | Lₐ₂₆₅ | L_{b32} |
| 5719 | Lₐ₂₆₇ | L_{b32} | 5720 | Lₐ₁₁₀₃ | L_{b32} |
| 5721 | Lₐ₂₉₃₃ | L_{b32} | 5722 | Lₐ₃₁₃₃ | L_{b32} |
| 5723 | Lₐ₃₁₃₅ | L_{b32} | 5724 | Lₐ₃₁₉₃ | L_{b32} |
| 5725 | Lₐ₃₁₉₅ | L_{b32} | 5726 | Lₐ₃₆₆₅ | L_{b32} |
| 5727 | Lₐ₃₈₆₅ | L_{b32} | 5728 | Lₐ₃₈₆₇ | L_{b32} |
| 5729 | Lₐ₃₉₂₅ | L_{b32} | 5730 | Lₐ₃₉₂₇ | L_{b32} |
| 5731 | Lₐ₄₀₃₁ | L_{b32} | 5732 | Lₐ₄₂₃₁ | L_{b32} |
| 5733 | Lₐ₄₂₃₃ | L_{b32} | 5734 | Lₐ₄₂₉₁ | L_{b32} |
| 5735 | Lₐ₄₂₉₃ | L_{b32} | 5736 | Lₐ₄₃₉₇ | L_{b32} |
| 5737 | Lₐ₄₅₉₇ | L_{b32} | 5738 | Lₐ₄₅₉₉ | L_{b32} |
| 5739 | Lₐ₄₆₅₇ | L_{b32} | 5740 | Lₐ₄₆₅₉ | L_{b32} |
| 5741 | Lₐ₅ | L_{b33} | 5742 | Lₐ₂₀₅ | L_{b33} |
| 5743 | Lₐ₂₀₇ | L_{b33} | 5744 | Lₐ₂₆₅ | L_{b33} |
| 5745 | Lₐ₂₆₇ | L_{b33} | 5746 | Lₐ₁₁₀₃ | L_{b33} |
| 5747 | Lₐ₂₉₃₃ | L_{b33} | 5748 | Lₐ₃₁₃₃ | L_{b33} |
| 5749 | Lₐ₃₁₃₅ | L_{b33} | 5750 | Lₐ₃₁₉₃ | L_{b33} |
| 5751 | Lₐ₃₁₉₅ | L_{b33} | 5752 | Lₐ₃₆₆₅ | L_{b33} |
| 5753 | Lₐ₃₈₆₅ | L_{b33} | 5754 | Lₐ₃₈₆₇ | L_{b33} |
| 5755 | Lₐ₃₉₂₅ | L_{b33} | 5756 | Lₐ₃₉₂₇ | L_{b33} |
| 5757 | Lₐ₄₀₃₁ | L_{b33} | 5758 | Lₐ₄₂₃₁ | L_{b33} |
| 5759 | Lₐ₄₂₃₃ | L_{b33} | 5760 | Lₐ₄₂₉₁ | L_{b33} |
| 5761 | Lₐ₄₂₉₃ | L_{b33} | 5762 | Lₐ₄₃₉₇ | L_{b33} |
| 5763 | Lₐ₄₅₉₇ | L_{b33} | 5764 | Lₐ₄₅₉₉ | L_{b33} |
| 5765 | Lₐ₄₆₅₇ | L_{b33} | 5766 | Lₐ₄₆₅₉ | L_{b33} |
| 5767 | Lₐ₅ | L_{b36} | 5768 | Lₐ₂₀₅ | L_{b36} |
| 5769 | Lₐ₂₀₇ | L_{b36} | 5770 | Lₐ₂₆₅ | L_{b36} |
| 5771 | Lₐ₂₆₇ | L_{b36} | 5772 | Lₐ₁₁₀₃ | L_{b36} |
| 5773 | Lₐ₂₉₃₃ | L_{b36} | 5774 | Lₐ₃₁₃₃ | L_{b36} |
| 5775 | Lₐ₃₁₃₅ | L_{b36} | 5776 | Lₐ₃₁₉₃ | L_{b36} |
| 5777 | Lₐ₃₁₉₅ | L_{b36} | 5778 | Lₐ₃₆₆₅ | L_{b36} |
| 5779 | Lₐ₃₈₆₅ | L_{b36} | 5780 | Lₐ₃₈₆₇ | L_{b36} |
| 5781 | Lₐ₃₉₂₅ | L_{b36} | 5782 | Lₐ₃₉₂₇ | L_{b36} |
| 5783 | Lₐ₄₀₃₁ | L_{b36} | 5784 | Lₐ₄₂₃₁ | L_{b36} |
| 5785 | Lₐ₄₂₃₃ | L_{b36} | 5786 | Lₐ₄₂₉₁ | L_{b36} |
| 5787 | Lₐ₄₂₉₃ | L_{b36} | 5788 | Lₐ₄₃₉₇ | L_{b36} |
| 5789 | Lₐ₄₅₉₇ | L_{b36} | 5790 | Lₐ₄₅₉₉ | L_{b36} |
| 5791 | Lₐ₄₆₅₇ | L_{b36} | 5792 | Lₐ₄₆₅₉ | L_{b36} |
| 5793 | Lₐ₅ | L_{b37} | 5794 | Lₐ₂₀₅ | L_{b37} |
| 5795 | Lₐ₂₀₇ | L_{b37} | 5796 | Lₐ₂₆₅ | L_{b37} |
| 5797 | Lₐ₂₆₇ | L_{b37} | 5798 | Lₐ₁₁₀₃ | L_{b37} |
| 5799 | Lₐ₂₉₃₃ | L_{b37} | 5800 | Lₐ₃₁₃₃ | L_{b37} |
| 5801 | Lₐ₃₁₃₅ | L_{b37} | 5802 | Lₐ₃₁₉₃ | L_{b37} |
| 5803 | Lₐ₃₁₉₅ | L_{b37} | 5804 | Lₐ₃₆₆₅ | L_{b37} |
| 5805 | Lₐ₃₈₆₅ | L_{b37} | 5806 | Lₐ₃₈₆₇ | L_{b37} |
| 5807 | Lₐ₃₉₂₅ | L_{b37} | 5808 | Lₐ₃₉₂₇ | L_{b37} |
| 5809 | Lₐ₄₀₃₁ | L_{b37} | 5810 | Lₐ₄₂₃₁ | L_{b37} |
| 5811 | Lₐ₄₂₃₃ | L_{b37} | 5812 | Lₐ₄₂₉₁ | L_{b37} |
| 5813 | Lₐ₄₂₉₃ | L_{b37} | 5814 | Lₐ₄₃₉₇ | L_{b37} |
| 5815 | Lₐ₄₅₉₇ | L_{b37} | 5816 | Lₐ₄₅₉₉ | L_{b37} |
| 5817 | Lₐ₄₆₅₇ | L_{b37} | 5818 | Lₐ₄₆₅₉ | L_{b37} |
| 5819 | Lₐ₅ | L_{b38} | 5820 | Lₐ₂₀₅ | L_{b38} |
| 5821 | Lₐ₂₀₇ | L_{b38} | 5822 | Lₐ₂₆₅ | L_{b38} |
| 5823 | Lₐ₂₆₇ | L_{b38} | 5824 | Lₐ₁₁₀₃ | L_{b38} |
| 5825 | Lₐ₂₉₃₃ | L_{b38} | 5826 | Lₐ₃₁₃₃ | L_{b38} |
| 5827 | Lₐ₃₁₃₅ | L_{b38} | 5828 | Lₐ₃₁₉₃ | L_{b38} |
| 5829 | Lₐ₃₁₉₅ | L_{b38} | 5830 | Lₐ₃₆₆₅ | L_{b38} |
| 5831 | Lₐ₃₈₆₅ | L_{b38} | 5832 | Lₐ₃₈₆₇ | L_{b38} |
| 5833 | Lₐ₃₉₂₅ | L_{b38} | 5834 | Lₐ₃₉₂₇ | L_{b38} |
| 5835 | Lₐ₄₀₃₁ | L_{b38} | 5836 | Lₐ₄₂₃₁ | L_{b38} |
| 5837 | Lₐ₄₂₃₃ | L_{b38} | 5838 | Lₐ₄₂₉₁ | L_{b38} |
| 5839 | Lₐ₄₂₉₃ | L_{b38} | 5840 | Lₐ₄₃₉₇ | L_{b38} |
| 5841 | Lₐ₄₅₉₇ | L_{b38} | 5842 | Lₐ₄₅₉₉ | L_{b38} |
| 5843 | Lₐ₄₆₅₇ | L_{b38} | 5844 | Lₐ₄₆₅₉ | L_{b38} |
| 5845 | Lₐ₅ | L_{b41} | 5846 | Lₐ₂₀₅ | L_{b41} |
| 5847 | Lₐ₂₀₇ | L_{b41} | 5848 | Lₐ₂₆₅ | L_{b41} |
| 5849 | Lₐ₂₆₇ | L_{b41} | 5850 | Lₐ₁₁₀₃ | L_{b41} |
| 5851 | Lₐ₂₉₃₃ | L_{b41} | 5852 | Lₐ₃₁₃₃ | L_{b41} |
| 5853 | Lₐ₃₁₃₅ | L_{b41} | 5854 | Lₐ₃₁₉₃ | L_{b41} |
| 5855 | Lₐ₃₁₉₅ | L_{b41} | 5856 | Lₐ₃₆₆₅ | L_{b41} |
| 5857 | Lₐ₃₈₆₅ | L_{b41} | 5858 | Lₐ₃₈₆₇ | L_{b41} |
| 5859 | Lₐ₃₉₂₅ | L_{b41} | 5860 | Lₐ₃₉₂₇ | L_{b41} |
| 5861 | Lₐ₄₀₃₁ | L_{b41} | 5862 | Lₐ₄₂₃₁ | L_{b41} |
| 5863 | Lₐ₄₂₃₃ | L_{b41} | 5864 | Lₐ₄₂₉₁ | L_{b41} |
| 5865 | Lₐ₄₂₉₃ | L_{b41} | 5866 | Lₐ₄₃₉₇ | L_{b41} |
| 5867 | Lₐ₄₅₉₇ | L_{b41} | 5868 | Lₐ₄₅₉₉ | L_{b41} |
| 5869 | Lₐ₄₆₅₇ | L_{b41} | 5870 | Lₐ₄₆₅₉ | L_{b41} |
| 5871 | Lₐ₅ | L_{b42} | 5872 | Lₐ₂₀₅ | L_{b42} |
| 5873 | Lₐ₂₀₇ | L_{b42} | 5874 | Lₐ₂₆₅ | L_{b42} |
| 5875 | Lₐ₂₆₇ | L_{b42} | 5876 | Lₐ₁₁₀₃ | L_{b42} |
| 5877 | Lₐ₂₉₃₃ | L_{b42} | 5878 | Lₐ₃₁₃₃ | L_{b42} |
| 5879 | Lₐ₃₁₃₅ | L_{b42} | 5880 | Lₐ₃₁₉₃ | L_{b42} |
| 5881 | Lₐ₃₁₉₅ | L_{b42} | 5882 | Lₐ₃₆₆₅ | L_{b42} |
| 5883 | Lₐ₃₈₆₅ | L_{b42} | 5884 | Lₐ₃₈₆₇ | L_{b42} |
| 5885 | Lₐ₃₉₂₅ | L_{b42} | 5886 | Lₐ₃₉₂₇ | L_{b42} |
| 5887 | Lₐ₄₀₃₁ | L_{b42} | 5888 | Lₐ₄₂₃₁ | L_{b42} |
| 5889 | Lₐ₄₂₃₃ | L_{b42} | 5890 | Lₐ₄₂₉₁ | L_{b42} |
| 5891 | Lₐ₄₂₉₃ | L_{b42} | 5892 | Lₐ₄₃₉₇ | L_{b42} |
| 5893 | Lₐ₄₅₉₇ | L_{b42} | 5894 | Lₐ₄₅₉₉ | L_{b42} |
| 5895 | Lₐ₄₆₅₇ | L_{b42} | 5896 | Lₐ₄₆₅₉ | L_{b42} |
| 5897 | Lₐ₅ | L_{b50} | 5898 | Lₐ₂₀₅ | L_{b50} |
| 5899 | Lₐ₂₀₇ | L_{b50} | 5900 | Lₐ₂₆₅ | L_{b50} |
| 5901 | Lₐ₂₆₇ | L_{b50} | 5902 | Lₐ₁₁₀₃ | L_{b50} |
| 5903 | Lₐ₂₉₃₃ | L_{b50} | 5904 | Lₐ₃₁₃₃ | L_{b50} |
| 5905 | Lₐ₃₁₃₅ | L_{b50} | 5906 | Lₐ₃₁₉₃ | L_{b50} |
| 5907 | Lₐ₃₁₉₅ | L_{b50} | 5908 | Lₐ₃₆₆₅ | L_{b50} |
| 5909 | Lₐ₃₈₆₅ | L_{b50} | 5910 | Lₐ₃₈₆₇ | L_{b50} |
| 5911 | Lₐ₃₉₂₅ | L_{b50} | 5912 | Lₐ₃₉₂₇ | L_{b50} |
| 5913 | Lₐ₄₀₃₁ | L_{b50} | 5914 | Lₐ₄₂₃₁ | L_{b50} |
| 5915 | Lₐ₄₂₃₃ | L_{b50} | 5916 | Lₐ₄₂₉₁ | L_{b50} |
| 5917 | Lₐ₄₂₉₃ | L_{b50} | 5918 | Lₐ₄₃₉₇ | L_{b50} |
| 5919 | Lₐ₄₅₉₇ | L_{b50} | 5920 | Lₐ₄₅₉₉ | L_{b50} |
| 5921 | Lₐ₄₆₅₇ | L_{b50} | 5922 | Lₐ₄₆₅₉ | L_{b50} |
| 5923 | Lₐ₅ | L_{b58} | 5924 | Lₐ₂₀₅ | L_{b58} |
| 5925 | Lₐ₂₀₇ | L_{b58} | 5926 | Lₐ₂₆₅ | L_{b58} |
| 5927 | Lₐ₂₆₇ | L_{b58} | 5928 | Lₐ₁₁₀₃ | L_{b58} |
| 5929 | Lₐ₂₉₃₃ | L_{b58} | 5930 | Lₐ₃₁₃₃ | L_{b58} |
| 5931 | Lₐ₃₁₃₅ | L_{b58} | 5932 | Lₐ₃₁₉₃ | L_{b58} |
| 5933 | Lₐ₃₁₉₅ | L_{b58} | 5934 | Lₐ₃₆₆₅ | L_{b58} |
| 5935 | Lₐ₃₈₆₅ | L_{b58} | 5936 | Lₐ₃₈₆₇ | L_{b58} |
| 5937 | Lₐ₃₉₂₅ | L_{b58} | 5938 | Lₐ₃₉₂₇ | L_{b58} |
| 5939 | Lₐ₄₀₃₁ | L_{b58} | 5940 | Lₐ₄₂₃₁ | L_{b58} |
| 5941 | Lₐ₄₂₃₃ | L_{b58} | 5942 | Lₐ₄₂₉₁ | L_{b58} |
| 5943 | Lₐ₄₂₉₃ | L_{b58} | 5944 | Lₐ₄₃₉₇ | L_{b58} |
| 5945 | Lₐ₄₅₉₇ | L_{b58} | 5946 | Lₐ₄₅₉₉ | L_{b58} |
| 5947 | Lₐ₄₆₅₇ | L_{b58} | 5948 | Lₐ₄₆₅₉ | L_{b58} |
| 5949 | Lₐ₅ | L_{b65} | 5950 | Lₐ₂₀₅ | L_{b65} |
| 5951 | Lₐ₂₀₇ | L_{b65} | 5952 | Lₐ₂₆₅ | L_{b65} |
| 5953 | Lₐ₂₆₇ | L_{b65} | 5954 | Lₐ₁₁₀₃ | L_{b65} |
| 5955 | Lₐ₂₉₃₃ | L_{b65} | 5956 | Lₐ₃₁₃₃ | L_{b65} |
| 5957 | Lₐ₃₁₃₅ | L_{b65} | 5958 | Lₐ₃₁₉₃ | L_{b65} |
| 5959 | Lₐ₃₁₉₅ | L_{b65} | 5960 | Lₐ₃₆₆₅ | L_{b65} |
| 5961 | Lₐ₃₈₆₅ | L_{b65} | 5962 | Lₐ₃₈₆₇ | L_{b65} |
| 5963 | Lₐ₃₉₂₅ | L_{b65} | 5964 | Lₐ₃₉₂₇ | L_{b65} |
| 5965 | Lₐ₄₀₃₁ | L_{b65} | 5966 | Lₐ₄₂₃₁ | L_{b65} |
| 5967 | Lₐ₄₂₃₃ | L_{b65} | 5968 | Lₐ₄₂₉₁ | L_{b65} |
| 5969 | Lₐ₄₂₉₃ | L_{b65} | 5970 | Lₐ₄₃₉₇ | L_{b65} |
| 5971 | Lₐ₄₅₉₇ | L_{b65} | 5972 | Lₐ₄₅₉₉ | L_{b65} |
| 5973 | Lₐ₄₆₅₇ | L_{b65} | 5974 | Lₐ₄₆₅₉ | L_{b65} |
| 5975 | Lₐ₅ | L_{b71} | 5976 | Lₐ₂₀₅ | L_{b71} |
| 5977 | Lₐ₂₀₇ | L_{b71} | 5978 | Lₐ₂₆₅ | L_{b71} |
| 5979 | Lₐ₂₆₇ | L_{b71} | 5980 | Lₐ₁₁₀₃ | L_{b71} |
| 5981 | Lₐ₂₉₃₃ | L_{b71} | 5982 | Lₐ₃₁₃₃ | L_{b71} |
| 5983 | Lₐ₃₁₃₅ | L_{b71} | 5984 | Lₐ₃₁₉₃ | L_{b71} |
| 5985 | Lₐ₃₁₉₅ | L_{b71} | 5986 | Lₐ₃₆₆₅ | L_{b71} |
| 5987 | Lₐ₃₈₆₅ | L_{b71} | 5988 | Lₐ₃₈₆₇ | L_{b71} |
| 5989 | Lₐ₃₉₂₅ | L_{b71} | 5990 | Lₐ₃₉₂₇ | L_{b71} |
| 5991 | Lₐ₄₀₃₁ | L_{b71} | 5992 | Lₐ₄₂₃₁ | L_{b71} |
| 5993 | Lₐ₄₂₃₃ | L_{b71} | 5994 | Lₐ₄₂₉₁ | L_{b71} |
| 5995 | Lₐ₄₂₉₃ | L_{b71} | 5996 | Lₐ₄₃₉₇ | L_{b71} |
| 5997 | Lₐ₄₅₉₇ | L_{b71} | 5998 | Lₐ₄₅₉₉ | L_{b71} |
| 5999 | Lₐ₄₆₅₇ | L_{b71} | 6000 | Lₐ₄₆₅₉ | L_{b71} |
| 6001 | Lₐ₅ | L_{b72} | 6002 | Lₐ₂₀₅ | L_{b72} |
| 6003 | Lₐ₂₀₇ | L_{b72} | 6004 | Lₐ₂₆₅ | L_{b72} |
| 6005 | Lₐ₂₆₇ | L_{b72} | 6006 | Lₐ₁₁₀₃ | L_{b72} |
| 6007 | Lₐ₂₉₃₃ | L_{b72} | 6008 | Lₐ₃₁₃₃ | L_{b72} |
| 6009 | Lₐ₃₁₃₅ | L_{b72} | 6010 | Lₐ₃₁₉₃ | L_{b72} |
| 6011 | Lₐ₃₁₉₅ | L_{b72} | 6012 | Lₐ₃₆₆₅ | L_{b72} |
| 6013 | Lₐ₃₈₆₅ | L_{b72} | 6014 | Lₐ₃₈₆₇ | L_{b72} |
| 6015 | Lₐ₃₉₂₅ | L_{b72} | 6016 | Lₐ₃₉₂₇ | L_{b72} |
| 6017 | Lₐ₄₀₃₁ | L_{b72} | 6018 | Lₐ₄₂₃₁ | L_{b72} |
| 6019 | Lₐ₄₂₃₃ | L_{b72} | 6020 | Lₐ₄₂₉₁ | L_{b72} |
| 6021 | Lₐ₄₂₉₃ | L_{b72} | 6022 | Lₐ₄₃₉₇ | L_{b72} |
| 6023 | Lₐ₄₅₉₇ | L_{b72} | 6024 | Lₐ₄₅₉₉ | L_{b72} |
| 6025 | Lₐ₄₆₅₇ | L_{b72} | 6026 | Lₐ₄₆₅₉ | L_{b72} |
| 6027 | Lₐ₅ | L_{b74} | 6028 | Lₐ₂₀₅ | L_{b74} |
| 6029 | Lₐ₂₀₇ | L_{b74} | 6030 | Lₐ₂₆₅ | L_{b74} |
| 6031 | Lₐ₂₆₇ | L_{b74} | 6032 | Lₐ₁₁₀₃ | L_{b74} |
| 6033 | Lₐ₂₉₃₃ | L_{b74} | 6034 | Lₐ₃₁₃₃ | L_{b74} |
| 6035 | Lₐ₃₁₃₅ | L_{b74} | 6036 | Lₐ₃₁₉₃ | L_{b74} |
| 6037 | Lₐ₃₁₉₅ | L_{b74} | 6038 | Lₐ₃₆₆₅ | L_{b74} |
| 6039 | Lₐ₃₈₆₅ | L_{b74} | 6040 | Lₐ₃₈₆₇ | L_{b74} |
| 6041 | Lₐ₃₉₂₅ | L_{b74} | 6042 | Lₐ₃₉₂₇ | L_{b74} |
| 6043 | Lₐ₄₀₃₁ | L_{b74} | 6044 | Lₐ₄₂₃₁ | L_{b74} |
| 6045 | Lₐ₄₂₃₃ | L_{b74} | 6046 | Lₐ₄₂₉₁ | L_{b74} |
| 6047 | Lₐ₄₂₉₃ | L_{b74} | 6048 | Lₐ₄₃₉₇ | L_{b74} |
| 6049 | Lₐ₄₅₉₇ | L_{b74} | 6050 | Lₐ₄₅₉₉ | L_{b74} |
| 6051 | Lₐ₄₆₅₇ | L_{b74} | 6052 | Lₐ₄₆₅₉ | L_{b74} |
| 6053 | Lₐ₅ | L_{b75} | 6054 | Lₐ₂₀₅ | L_{b75} |
| 6055 | Lₐ₂₀₇ | L_{b75} | 6056 | Lₐ₂₆₅ | L_{b75} |
| 6057 | Lₐ₂₆₇ | L_{b75} | 6058 | Lₐ₁₁₀₃ | L_{b75} |
| 6059 | Lₐ₂₉₃₃ | L_{b75} | 6060 | Lₐ₃₁₃₃ | L_{b75} |
| 6061 | Lₐ₃₁₃₅ | L_{b75} | 6062 | Lₐ₃₁₉₃ | L_{b75} |
| 6063 | Lₐ₃₁₉₅ | L_{b75} | 6064 | Lₐ₃₆₆₅ | L_{b75} |
| 6065 | Lₐ₃₈₆₅ | L_{b75} | 6066 | Lₐ₃₈₆₇ | L_{b75} |
| 6067 | Lₐ₃₉₂₅ | L_{b75} | 6068 | Lₐ₃₉₂₇ | L_{b75} |
| 6069 | Lₐ₄₀₃₁ | L_{b75} | 6070 | Lₐ₄₂₃₁ | L_{b75} |
| 6071 | Lₐ₄₂₃₃ | L_{b75} | 6072 | Lₐ₄₂₉₁ | L_{b75} |
| 6073 | Lₐ₄₂₉₃ | L_{b75} | 6074 | Lₐ₄₃₉₇ | L_{b75} |
| 6075 | Lₐ₄₅₉₇ | L_{b75} | 6076 | Lₐ₄₅₉₉ | L_{b75} |
| 6077 | Lₐ₄₆₅₇ | L_{b75} | 6078 | Lₐ₄₆₅₉ | L_{b75} |
| 6079 | Lₐ₅ | L_{b76} | 6080 | Lₐ₂₀₅ | L_{b76} |
| 6081 | Lₐ₂₀₇ | L_{b76} | 6082 | Lₐ₂₆₅ | L_{b76} |
| 6083 | Lₐ₂₆₇ | L_{b76} | 6084 | Lₐ₁₁₀₃ | L_{b76} |
| 6085 | Lₐ₂₉₃₃ | L_{b76} | 6086 | Lₐ₃₁₃₃ | L_{b76} |
| 6087 | Lₐ₃₁₃₅ | L_{b76} | 6088 | Lₐ₃₁₉₃ | L_{b76} |
| 6089 | Lₐ₃₁₉₅ | L_{b76} | 6090 | Lₐ₃₆₆₅ | L_{b76} |
| 6091 | Lₐ₃₈₆₅ | L_{b76} | 6092 | Lₐ₃₈₆₇ | L_{b76} |
| 6093 | Lₐ₃₉₂₅ | L_{b76} | 6094 | Lₐ₃₉₂₇ | L_{b76} |
| 6095 | Lₐ₄₀₃₁ | L_{b76} | 6096 | Lₐ₄₂₃₁ | L_{b76} |
| 6097 | Lₐ₄₂₃₃ | L_{b76} | 6098 | Lₐ₄₂₉₁ | L_{b76} |
| 6099 | Lₐ₄₂₉₃ | L_{b76} | 6100 | Lₐ₄₃₉₇ | L_{b76} |
| 6101 | Lₐ₄₅₉₇ | L_{b76} | 6102 | Lₐ₄₅₉₉ | L_{b76} |
| 6103 | Lₐ₄₆₅₇ | L_{b76} | 6104 | Lₐ₄₆₅₉ | L_{b76} |
| 6105 | Lₐ₅ | L_{b78} | 6106 | Lₐ₂₀₅ | L_{b78} |
| 6107 | Lₐ₂₀₇ | L_{b78} | 6108 | Lₐ₂₆₅ | L_{b78} |
| 6109 | Lₐ₂₆₇ | L_{b78} | 6110 | Lₐ₁₁₀₃ | L_{b78} |
| 6111 | Lₐ₂₉₃₃ | L_{b78} | 6112 | Lₐ₃₁₃₃ | L_{b78} |
| 6113 | Lₐ₃₁₃₅ | L_{b78} | 6114 | Lₐ₃₁₉₃ | L_{b78} |
| 6115 | Lₐ₃₁₉₅ | L_{b78} | 6116 | Lₐ₃₆₆₅ | L_{b78} |
| 6117 | Lₐ₃₈₆₅ | L_{b78} | 6118 | Lₐ₃₈₆₇ | L_{b78} |
| 6119 | Lₐ₃₉₂₅ | L_{b78} | 6120 | Lₐ₃₉₂₇ | L_{b78} |
| 6121 | Lₐ₄₀₃₁ | L_{b78} | 6122 | Lₐ₄₂₃₁ | L_{b78} |
| 6123 | Lₐ₄₂₃₃ | L_{b78} | 6124 | Lₐ₄₂₉₁ | L_{b78} |
| 6125 | Lₐ₄₂₉₃ | L_{b78} | 6126 | Lₐ₄₃₉₇ | L_{b78} |
| 6127 | Lₐ₄₅₉₇ | L_{b78} | 6128 | Lₐ₄₅₉₉ | L_{b78} |
| 6129 | Lₐ₄₆₅₇ | L_{b78} | 6130 | Lₐ₄₆₅₉ | L_{b78} |
| 6131 | Lₐ₅ | L_{b95} | 6132 | Lₐ₂₀₅ | L_{b95} |
| 6133 | Lₐ₂₀₇ | L_{b95} | 6134 | Lₐ₂₆₅ | L_{b95} |
| 6135 | Lₐ₂₆₇ | L_{b95} | 6136 | Lₐ₁₁₀₃ | L_{b95} |
| 6137 | Lₐ₂₉₃₃ | L_{b95} | 6138 | Lₐ₃₁₃₃ | L_{b95} |
| 6139 | Lₐ₃₁₃₅ | L_{b95} | 6140 | Lₐ₃₁₉₃ | L_{b95} |
| 6141 | Lₐ₃₁₉₅ | L_{b95} | 6142 | Lₐ₃₆₆₅ | L_{b95} |
| 6143 | Lₐ₃₈₆₅ | L_{b95} | 6144 | Lₐ₃₈₆₇ | L_{b95} |
| 6145 | Lₐ₃₉₂₅ | L_{b95} | 6146 | Lₐ₃₉₂₇ | L_{b95} |
| 6147 | Lₐ₄₀₃₁ | L_{b95} | 6148 | Lₐ₄₂₃₁ | L_{b95} |
| 6149 | Lₐ₄₂₃₃ | L_{b95} | 6150 | Lₐ₄₂₉₁ | L_{b95} |
| 6151 | Lₐ₄₂₉₃ | L_{b95} | 6152 | Lₐ₄₃₉₇ | L_{b95} |
| 6153 | Lₐ₄₅₉₇ | L_{b95} | 6154 | Lₐ₄₅₉₉ | L_{b95} |
| 6155 | Lₐ₄₆₅₇ | L_{b95} | 6156 | Lₐ₄₆₅₉ | L_{b95} |
| 6157 | Lₐ₅ | L_{b102} | 6158 | Lₐ₂₀₅ | L_{b102} |
| 6159 | Lₐ₂₀₇ | L_{b102} | 6160 | Lₐ₂₆₅ | L_{b102} |
| 6161 | Lₐ₂₆₇ | L_{b102} | 6162 | Lₐ₁₁₀₃ | L_{b102} |
| 6163 | Lₐ₂₉₃₃ | L_{b102} | 6164 | Lₐ₃₁₃₃ | L_{b102} |
| 6165 | Lₐ₃₁₃₅ | L_{b102} | 6166 | Lₐ₃₁₉₃ | L_{b102} |
| 6167 | Lₐ₃₁₉₅ | L_{b102} | 6168 | Lₐ₃₆₆₅ | L_{b102} |
| 6169 | Lₐ₃₈₆₅ | L_{b102} | 6170 | Lₐ₃₈₆₇ | L_{b102} |
| 6171 | Lₐ₃₉₂₅ | L_{b102} | 6172 | Lₐ₃₉₂₇ | L_{b102} |
| 6173 | Lₐ₄₀₃₁ | L_{b102} | 6174 | Lₐ₄₂₃₁ | L_{b102} |
| 6175 | Lₐ₄₂₃₃ | L_{b102} | 6176 | Lₐ₄₂₉₁ | L_{b102} |
| 6177 | Lₐ₄₂₉₃ | L_{b102} | 6178 | Lₐ₄₃₉₇ | L_{b102} |
| 6179 | Lₐ₄₅₉₇ | L_{b102} | 6180 | Lₐ₄₅₉₉ | L_{b102} |
| 6181 | Lₐ₄₆₅₇ | L_{b102} | 6182 | Lₐ₄₆₅₉ | L_{b102} |
| 6183 | Lₐ₅ | L_{b109} | 6184 | Lₐ₂₀₅ | L_{b109} |
| 6185 | Lₐ₂₀₇ | L_{b109} | 6186 | Lₐ₂₆₅ | L_{b109} |
| 6187 | Lₐ₂₆₇ | L_{b109} | 6188 | Lₐ₁₁₀₃ | L_{b109} |
| 6189 | Lₐ₂₉₃₃ | L_{b109} | 6190 | Lₐ₃₁₃₃ | L_{b109} |
| 6191 | Lₐ₃₁₃₅ | L_{b109} | 6192 | Lₐ₃₁₉₃ | L_{b109} |
| 6193 | Lₐ₃₁₉₅ | L_{b109} | 6194 | Lₐ₃₆₆₅ | L_{b109} |
| 6195 | Lₐ₃₈₆₅ | L_{b109} | 6196 | Lₐ₃₈₆₇ | L_{b109} |
| 6197 | Lₐ₃₉₂₅ | L_{b109} | 6198 | Lₐ₃₉₂₇ | L_{b109} |
| 6199 | Lₐ₄₀₃₁ | L_{b109} | 6200 | Lₐ₄₂₃₁ | L_{b109} |
| 6201 | Lₐ₄₂₃₃ | L_{b109} | 6202 | Lₐ₄₂₉₁ | L_{b109} |
| 6203 | Lₐ₄₂₉₃ | L_{b109} | 6204 | Lₐ₄₃₉₇ | L_{b109} |
| 6205 | Lₐ₄₅₉₇ | L_{b109} | 6206 | Lₐ₄₅₉₉ | L_{b109} |
| 6207 | Lₐ₄₆₅₇ | L_{b109} | 6208 | Lₐ₄₆₅₉ | L_{b109} |
| 6209 | Lₐ₅ | L_{b110} | 6210 | Lₐ₂₀₅ | L_{b110} |
| 6211 | Lₐ₂₀₇ | L_{b110} | 6212 | Lₐ₂₆₅ | L_{b110} |
| 6213 | Lₐ₂₆₇ | L_{b110} | 6214 | Lₐ₁₁₀₃ | L_{b110} |
| 6215 | Lₐ₂₉₃₃ | L_{b110} | 6216 | Lₐ₃₁₃₃ | L_{b110} |
| 6217 | Lₐ₃₁₃₅ | L_{b110} | 6218 | Lₐ₃₁₉₃ | L_{b110} |
| 6219 | Lₐ₃₁₉₅ | L_{b110} | 6220 | Lₐ₃₆₆₅ | L_{b110} |
| 6221 | Lₐ₃₈₆₅ | L_{b110} | 6222 | Lₐ₃₈₆₇ | L_{b110} |
| 6223 | Lₐ₃₉₂₅ | L_{b110} | 6224 | Lₐ₃₉₂₇ | L_{b110} |
| 6225 | Lₐ₄₀₃₁ | L_{b110} | 6226 | Lₐ₄₂₃₁ | L_{b110} |
| 6227 | Lₐ₄₂₃₃ | L_{b110} | 6228 | Lₐ₄₂₉₁ | L_{b110} |
| 6229 | Lₐ₄₂₉₃ | L_{b110} | 6230 | Lₐ₄₃₉₇ | L_{b110} |
| 6231 | Lₐ₄₅₉₇ | L_{b110} | 6232 | Lₐ₄₅₉₉ | L_{b110} |
| 6233 | Lₐ₄₆₅₇ | L_{b110} | 6234 | Lₐ₄₆₅₉ | L_{b110} |
| 6235 | Lₐ₅ | L_{b114} | 6236 | Lₐ₂₀₅ | L_{b114} |
| 6237 | Lₐ₂₀₇ | L_{b114} | 6238 | Lₐ₂₆₅ | L_{b114} |
| 6239 | Lₐ₂₆₇ | L_{b114} | 6240 | Lₐ₁₁₀₃ | L_{b114} |
| 6241 | Lₐ₂₉₃₃ | L_{b114} | 6242 | Lₐ₃₁₃₃ | L_{b114} |
| 6243 | Lₐ₃₁₃₅ | L_{b114} | 6244 | Lₐ₃₁₉₃ | L_{b114} |
| 6245 | Lₐ₃₁₉₅ | L_{b114} | 6246 | Lₐ₃₆₆₅ | L_{b114} |
| 6247 | Lₐ₃₈₆₅ | L_{b114} | 6248 | Lₐ₃₈₆₇ | L_{b114} |
| 6249 | Lₐ₃₉₂₅ | L_{b114} | 6250 | Lₐ₃₉₂₇ | L_{b114} |
| 6251 | Lₐ₄₀₃₁ | L_{b114} | 6252 | Lₐ₄₂₃₁ | L_{b114} |
| 6253 | Lₐ₄₂₃₃ | L_{b114} | 6254 | Lₐ₄₂₉₁ | L_{b114} |
| 6255 | Lₐ₄₂₉₃ | L_{b114} | 6256 | Lₐ₄₃₉₇ | L_{b114} |
| 6257 | Lₐ₄₅₉₇ | L_{b114} | 6258 | Lₐ₄₅₉₉ | L_{b114} |
| 6259 | Lₐ₄₆₅₇ | L_{b114} | 6260 | Lₐ₄₆₅₉ | L_{b114} |
| 6261 | Lₐ₅ | L_{b115} | 6262 | Lₐ₂₀₅ | L_{b115} |
| 6263 | Lₐ₂₀₇ | L_{b115} | 6264 | Lₐ₂₆₅ | L_{b115} |
| 6265 | Lₐ₂₆₇ | L_{b115} | 6266 | Lₐ₁₁₀₃ | L_{b115} |
| 6267 | Lₐ₂₉₃₃ | L_{b115} | 6268 | Lₐ₃₁₃₃ | L_{b115} |
| 6269 | Lₐ₃₁₃₅ | L_{b115} | 6270 | Lₐ₃₁₉₃ | L_{b115} |
| 6271 | Lₐ₃₁₉₅ | L_{b115} | 6272 | Lₐ₃₆₆₅ | L_{b115} |
| 6273 | Lₐ₃₈₆₅ | L_{b115} | 6274 | Lₐ₃₈₆₇ | L_{b115} |
| 6275 | Lₐ₃₉₂₅ | L_{b115} | 6276 | Lₐ₃₉₂₇ | L_{b115} |
| 6277 | Lₐ₄₀₃₁ | L_{b115} | 6278 | Lₐ₄₂₃₁ | L_{b115} |
| 6279 | Lₐ₄₂₃₃ | L_{b115} | 6280 | Lₐ₄₂₉₁ | L_{b115} |
| 6281 | Lₐ₄₂₉₃ | L_{b115} | 6282 | Lₐ₄₃₉₇ | L_{b115} |
| 6283 | Lₐ₄₅₉₇ | L_{b115} | 6284 | Lₐ₄₅₉₉ | L_{b115} |
| 6285 | Lₐ₄₆₅₇ | L_{b115} | 6286 | Lₐ₄₆₅₉ | L_{b115} |
| 6287 | Lₐ₅ | L_{b116} | 6288 | Lₐ₂₀₅ | L_{b116} |
| 6289 | Lₐ₂₀₇ | L_{b116} | 6290 | Lₐ₂₆₅ | L_{b116} |
| 6291 | Lₐ₂₆₇ | L_{b116} | 6292 | Lₐ₁₁₀₃ | L_{b116} |
| 6293 | Lₐ₂₉₃₃ | L_{b116} | 6294 | Lₐ₃₁₃₃ | L_{b116} |
| 6295 | Lₐ₃₁₃₅ | L_{b116} | 6296 | Lₐ₃₁₉₃ | L_{b116} |
| 6297 | Lₐ₃₁₉₅ | L_{b116} | 6298 | Lₐ₃₆₆₅ | L_{b116} |
| 6299 | Lₐ₃₈₆₅ | L_{b116} | 6300 | Lₐ₃₈₆₇ | L_{b116} |
| 6301 | Lₐ₃₉₂₅ | L_{b116} | 6302 | Lₐ₃₉₂₇ | L_{b116} |
| 6303 | Lₐ₄₀₃₁ | L_{b116} | 6304 | Lₐ₄₂₃₁ | L_{b116} |
| 6305 | Lₐ₄₂₃₃ | L_{b116} | 6306 | Lₐ₄₂₉₁ | L_{b116} |
| 6307 | Lₐ₄₂₉₃ | L_{b116} | 6308 | Lₐ₄₃₉₇ | L_{b116} |
| 6309 | Lₐ₄₅₉₇ | L_{b116} | 6310 | Lₐ₄₅₉₉ | L_{b116} |
| 6311 | Lₐ₄₆₅₇ | L_{b116} | 6312 | Lₐ₄₆₅₉ | L_{b116} |
| 6313 | Lₐ₅ | L_{b117} | 6314 | Lₐ₂₀₅ | L_{b117} |
| 6315 | Lₐ₂₀₇ | L_{b117} | 6316 | Lₐ₂₆₅ | L_{b117} |
| 6317 | Lₐ₂₆₇ | L_{b117} | 6318 | Lₐ₁₁₀₃ | L_{b117} |
| 6319 | Lₐ₂₉₃₃ | L_{b117} | 6320 | Lₐ₃₁₃₃ | L_{b117} |
| 6321 | Lₐ₃₁₃₅ | L_{b117} | 6322 | Lₐ₃₁₉₃ | L_{b117} |
| 6323 | Lₐ₃₁₉₅ | L_{b117} | 6324 | Lₐ₃₆₆₅ | L_{b117} |
| 6325 | Lₐ₃₈₆₅ | L_{b117} | 6326 | Lₐ₃₈₆₇ | L_{b117} |
| 6327 | Lₐ₃₉₂₅ | L_{b117} | 6328 | Lₐ₃₉₂₇ | L_{b117} |
| 6329 | Lₐ₄₀₃₁ | L_{b117} | 6330 | Lₐ₄₂₃₁ | L_{b117} |
| 6331 | Lₐ₄₂₃₃ | L_{b117} | 6332 | Lₐ₄₂₉₁ | L_{b117} |
| 6333 | Lₐ₄₂₉₃ | L_{b117} | 6334 | Lₐ₄₃₉₇ | L_{b117} |
| 6335 | Lₐ₄₅₉₇ | L_{b117} | 6336 | Lₐ₄₅₉₉ | L_{b117} |
| 6337 | Lₐ₄₆₅₇ | L_{b117} | 6338 | Lₐ₄₆₅₉ | L_{b117} |
| 6339 | Lₐ₅ | L_{b118} | 6340 | Lₐ₂₀₅ | L_{b118} |
| 6341 | Lₐ₂₀₇ | L_{b118} | 6342 | Lₐ₂₆₅ | L_{b118} |
| 6343 | Lₐ₂₆₇ | L_{b118} | 6344 | Lₐ₁₁₀₃ | L_{b118} |
| 6345 | Lₐ₂₉₃₃ | L_{b118} | 6346 | Lₐ₃₁₃₃ | L_{b118} |
| 6347 | Lₐ₃₁₃₅ | L_{b118} | 6348 | Lₐ₃₁₉₃ | L_{b118} |
| 6349 | Lₐ₃₁₉₅ | L_{b118} | 6350 | Lₐ₃₆₆₅ | L_{b118} |
| 6351 | Lₐ₃₈₆₅ | L_{b118} | 6352 | Lₐ₃₈₆₇ | L_{b118} |
| 6353 | Lₐ₃₉₂₅ | L_{b118} | 6354 | Lₐ₃₉₂₇ | L_{b118} |
| 6355 | Lₐ₄₀₃₁ | L_{b118} | 6356 | Lₐ₄₂₃₁ | L_{b118} |
| 6357 | Lₐ₄₂₃₃ | L_{b118} | 6358 | Lₐ₄₂₉₁ | L_{b118} |
| 6359 | Lₐ₄₂₉₃ | L_{b118} | 6360 | Lₐ₄₃₉₇ | L_{b118} |
| 6361 | Lₐ₄₅₉₇ | L_{b118} | 6362 | Lₐ₄₅₉₉ | L_{b118} |
| 6363 | Lₐ₄₆₅₇ | L_{b118} | 6364 | Lₐ₄₆₅₉ | L_{b118} |
| 6365 | Lₐ₅ | L_{b119} | 6366 | Lₐ₂₀₅ | L_{b119} |
| 6367 | Lₐ₂₀₇ | L_{b119} | 6368 | Lₐ₂₆₅ | L_{b119} |
| 6369 | Lₐ₂₆₇ | L_{b119} | 6370 | Lₐ₁₁₀₃ | L_{b119} |
| 6371 | Lₐ₂₉₃₃ | L_{b119} | 6372 | Lₐ₃₁₃₃ | L_{b119} |
| 6373 | Lₐ₃₁₃₅ | L_{b119} | 6374 | Lₐ₃₁₉₃ | L_{b119} |
| 6375 | Lₐ₃₁₉₅ | L_{b119} | 6376 | Lₐ₃₆₆₅ | L_{b119} |
| 6377 | Lₐ₃₈₆₅ | L_{b119} | 6378 | Lₐ₃₈₆₇ | L_{b119} |
| 6379 | Lₐ₃₉₂₅ | L_{b119} | 6380 | Lₐ₃₉₂₇ | L_{b119} |
| 6381 | Lₐ₄₀₃₁ | L_{b119} | 6382 | Lₐ₄₂₃₁ | L_{b119} |
| 6383 | Lₐ₄₂₃₃ | L_{b119} | 6384 | Lₐ₄₂₉₁ | L_{b119} |
| 6385 | Lₐ₄₂₉₃ | L_{b119} | 6386 | Lₐ₄₃₉₇ | L_{b119} |
| 6387 | Lₐ₄₅₉₇ | L_{b119} | 6388 | Lₐ₄₅₉₉ | L_{b119} |
| 6389 | Lₐ₄₆₅₇ | L_{b119} | 6390 | Lₐ₄₆₅₉ | L_{b119} |
| 6391 | Lₐ₅ | L_{b121} | 6392 | Lₐ₂₀₅ | L_{b121} |
| 6393 | Lₐ₂₀₇ | L_{b121} | 6394 | Lₐ₂₆₅ | L_{b121} |
| 6395 | Lₐ₂₆₇ | L_{b121} | 6396 | Lₐ₁₁₀₃ | L_{b121} |
| 6397 | Lₐ₂₉₃₃ | L_{b121} | 6398 | Lₐ₃₁₃₃ | L_{b121} |
| 6399 | Lₐ₃₁₃₅ | L_{b121} | 6400 | Lₐ₃₁₉₃ | L_{b121} |
| 6401 | Lₐ₃₁₉₅ | L_{b121} | 6402 | Lₐ₃₆₆₅ | L_{b121} |
| 6403 | Lₐ₃₈₆₅ | L_{b121} | 6404 | Lₐ₃₈₆₇ | L_{b121} |
| 6405 | Lₐ₃₉₂₅ | L_{b121} | 6406 | Lₐ₃₉₂₇ | L_{b121} |
| 6407 | Lₐ₄₀₃₁ | L_{b121} | 6408 | Lₐ₄₂₃₁ | L_{b121} |
| 6409 | Lₐ₄₂₃₃ | L_{b121} | 6410 | Lₐ₄₂₉₁ | L_{b121} |
| 6411 | Lₐ₄₂₉₃ | L_{b121} | 6412 | Lₐ₄₃₉₇ | L_{b121} |
| 6413 | Lₐ₄₅₉₇ | L_{b121} | 6414 | Lₐ₄₅₉₉ | L_{b121} |
| 6415 | Lₐ₄₆₅₇ | L_{b121} | 6416 | Lₐ₄₆₅₉ | L_{b121} |
| 6417 | Lₐ₅ | L_{b122} | 6418 | Lₐ₂₀₅ | L_{b122} |
| 6419 | Lₐ₂₀₇ | L_{b122} | 6420 | Lₐ₂₆₅ | L_{b122} |
| 6421 | Lₐ₂₆₇ | L_{b122} | 6422 | Lₐ₁₁₀₃ | L_{b122} |
| 6423 | Lₐ₂₉₃₃ | L_{b122} | 6424 | Lₐ₃₁₃₃ | L_{b122} |
| 6425 | Lₐ₃₁₃₅ | L_{b122} | 6426 | Lₐ₃₁₉₃ | L_{b122} |
| 6427 | Lₐ₃₁₉₅ | L_{b122} | 6428 | Lₐ₃₆₆₅ | L_{b122} |
| 6429 | Lₐ₃₈₆₅ | L_{b122} | 6430 | Lₐ₃₈₆₇ | L_{b122} |
| 6431 | Lₐ₃₉₂₅ | L_{b122} | 6432 | Lₐ₃₉₂₇ | L_{b122} |
| 6433 | Lₐ₄₀₃₁ | L_{b122} | 6434 | Lₐ₄₂₃₁ | L_{b122} |
| 6435 | Lₐ₄₂₃₃ | L_{b122} | 6436 | Lₐ₄₂₉₁ | L_{b122} |
| 6437 | Lₐ₄₂₉₃ | L_{b122} | 6438 | Lₐ₄₃₉₇ | L_{b122} |
| 6439 | Lₐ₄₅₉₇ | L_{b122} | 6440 | Lₐ₄₅₉₉ | L_{b122} |
| 6441 | Lₐ₄₆₅₇ | L_{b122} | 6442 | Lₐ₄₆₅₉ | L_{b122} |
| 6443 | Lₐ₅ | L_{b123} | 6444 | Lₐ₂₀₅ | L_{b123} |
| 6445 | Lₐ₂₀₇ | L_{b123} | 6446 | Lₐ₂₆₅ | L_{b123} |
| 6447 | Lₐ₂₆₇ | L_{b123} | 6448 | Lₐ₁₁₀₃ | L_{b123} |
| 6449 | Lₐ₂₉₃₃ | L_{b123} | 6450 | Lₐ₃₁₃₃ | L_{b123} |
| 6451 | Lₐ₃₁₃₅ | L_{b123} | 6452 | Lₐ₃₁₉₃ | L_{b123} |
| 6453 | Lₐ₃₁₉₅ | L_{b123} | 6454 | Lₐ₃₆₆₅ | L_{b123} |
| 6455 | Lₐ₃₈₆₅ | L_{b123} | 6456 | Lₐ₃₈₆₇ | L_{b123} |
| 6457 | Lₐ₃₉₂₅ | L_{b123} | 6458 | Lₐ₃₉₂₇ | L_{b123} |
| 6459 | Lₐ₄₀₃₁ | L_{b123} | 6460 | Lₐ₄₂₃₁ | L_{b123} |
| 6461 | Lₐ₄₂₃₃ | L_{b123} | 6462 | Lₐ₄₂₉₁ | L_{b123} |
| 6463 | Lₐ₄₂₉₃ | L_{b123} | 6464 | Lₐ₄₃₉₇ | L_{b123} |
| 6465 | Lₐ₄₅₉₇ | L_{b123} | 6466 | Lₐ₄₅₉₉ | L_{b123} |
| 6467 | Lₐ₄₆₅₇ | L_{b123} | 6468 | Lₐ₄₆₅₉ | L_{b123} |
| 6469 | Lₐ₅ | L_{b129} | 6470 | Lₐ₂₀₅ | L_{b129} |
| 6471 | Lₐ₂₀₇ | L_{b129} | 6472 | Lₐ₂₆₅ | L_{b129} |
| 6473 | Lₐ₂₆₇ | L_{b129} | 6474 | Lₐ₁₁₀₃ | L_{b129} |
| 6475 | Lₐ₂₉₃₃ | L_{b129} | 6476 | Lₐ₃₁₃₃ | L_{b129} |
| 6477 | Lₐ₃₁₃₅ | L_{b129} | 6478 | Lₐ₃₁₉₃ | L_{b129} |
| 6479 | Lₐ₃₁₉₅ | L_{b129} | 6480 | Lₐ₃₆₆₅ | L_{b129} |
| 6481 | Lₐ₃₈₆₅ | L_{b129} | 6482 | Lₐ₃₈₆₇ | L_{b129} |
| 6483 | Lₐ₃₉₂₅ | L_{b129} | 6484 | Lₐ₃₉₂₇ | L_{b129} |
| 6485 | Lₐ₄₀₃₁ | L_{b129} | 6486 | Lₐ₄₂₃₁ | L_{b129} |
| 6487 | Lₐ₄₂₃₃ | L_{b129} | 6488 | Lₐ₄₂₉₁ | L_{b129} |
| 6489 | Lₐ₄₂₉₃ | L_{b129} | 6490 | Lₐ₄₃₉₇ | L_{b129} |
| 6491 | Lₐ₄₅₉₇ | L_{b129} | 6492 | Lₐ₄₅₉₉ | L_{b129} |
| 6493 | Lₐ₄₆₅₇ | L_{b129} | 6494 | Lₐ₄₆₅₉ | L_{b129} |
| 6495 | Lₐ₅ | L_{b130} | 6496 | Lₐ₂₀₅ | L_{b130} |
| 6497 | Lₐ₂₀₇ | L_{b130} | 6498 | Lₐ₂₆₅ | L_{b130} |
| 6499 | Lₐ₂₆₇ | L_{b130} | 6500 | Lₐ₁₁₀₃ | L_{b130} |
| 6501 | Lₐ₂₉₃₃ | L_{b130} | 6502 | Lₐ₃₁₃₃ | L_{b130} |
| 6503 | Lₐ₃₁₃₅ | L_{b130} | 6504 | Lₐ₃₁₉₃ | L_{b130} |
| 6505 | Lₐ₃₁₉₅ | L_{b130} | 6506 | Lₐ₃₆₆₅ | L_{b130} |
| 6507 | Lₐ₃₈₆₅ | L_{b130} | 6508 | Lₐ₃₈₆₇ | L_{b130} |
| 6509 | Lₐ₃₉₂₅ | L_{b130} | 6510 | Lₐ₃₉₂₇ | L_{b130} |
| 6511 | Lₐ₄₀₃₁ | L_{b130} | 6512 | Lₐ₄₂₃₁ | L_{b130} |
| 6513 | Lₐ₄₂₃₃ | L_{b130} | 6514 | Lₐ₄₂₉₁ | L_{b130} |
| 6515 | Lₐ₄₂₉₃ | L_{b130} | 6516 | Lₐ₄₃₉₇ | L_{b130} |
| 6517 | Lₐ₄₅₉₇ | L_{b130} | 6518 | Lₐ₄₅₉₉ | L_{b130} |
| 6519 | Lₐ₄₆₅₇ | L_{b130} | 6520 | Lₐ₄₆₅₉ | L_{b130} |
| 6521 | Lₐ₅ | L_{b131} | 6522 | Lₐ₂₀₅ | L_{b131} |
| 6523 | Lₐ₂₀₇ | L_{b131} | 6524 | Lₐ₂₆₅ | L_{b131} |
| 6525 | Lₐ₂₆₇ | L_{b131} | 6526 | Lₐ₁₁₀₃ | L_{b131} |
| 6527 | Lₐ₂₉₃₃ | L_{b131} | 6528 | Lₐ₃₁₃₃ | L_{b131} |
| 6529 | Lₐ₃₁₃₅ | L_{b131} | 6530 | Lₐ₃₁₉₃ | L_{b131} |
| 6531 | Lₐ₃₁₉₅ | L_{b131} | 6532 | Lₐ₃₆₆₅ | L_{b131} |
| 6533 | Lₐ₃₈₆₅ | L_{b131} | 6534 | Lₐ₃₈₆₇ | L_{b131} |
| 6535 | Lₐ₃₉₂₅ | L_{b131} | 6536 | Lₐ₃₉₂₇ | L_{b131} |
| 6537 | Lₐ₄₀₃₁ | L_{b131} | 6538 | Lₐ₄₂₃₁ | L_{b131} |
| 6539 | Lₐ₄₂₃₃ | L_{b131} | 6540 | Lₐ₄₂₉₁ | L_{b131} |
| 6541 | Lₐ₄₂₉₃ | L_{b131} | 6542 | Lₐ₄₃₉₇ | L_{b131} |
| 6543 | Lₐ₄₅₉₇ | L_{b131} | 6544 | Lₐ₄₅₉₉ | L_{b131} |
| 6545 | Lₐ₄₆₅₇ | L_{b131} | 6546 | Lₐ₄₆₅₉ | L_{b131} |
| 6547 | Lₐ₅ | L_{b134} | 6548 | Lₐ₂₀₅ | L_{b134} |
| 6549 | Lₐ₂₀₇ | L_{b134} | 6550 | Lₐ₂₆₅ | L_{b134} |
| 6551 | Lₐ₂₆₇ | L_{b134} | 6552 | Lₐ₁₁₀₃ | L_{b134} |
| 6553 | Lₐ₂₉₃₃ | L_{b134} | 6554 | Lₐ₃₁₃₃ | L_{b134} |
| 6555 | Lₐ₃₁₃₅ | L_{b134} | 6556 | Lₐ₃₁₉₃ | L_{b134} |
| 6557 | Lₐ₃₁₉₅ | L_{b134} | 6558 | Lₐ₃₆₆₅ | L_{b134} |
| 6559 | Lₐ₃₈₆₅ | L_{b134} | 6560 | Lₐ₃₈₆₇ | L_{b134} |
| 6561 | Lₐ₃₉₂₅ | L_{b134} | 6562 | Lₐ₃₉₂₇ | L_{b134} |
| 6563 | Lₐ₄₀₃₁ | L_{b134} | 6564 | Lₐ₄₂₃₁ | L_{b134} |
| 6565 | Lₐ₄₂₃₃ | L_{b134} | 6566 | Lₐ₄₂₉₁ | L_{b134} |
| 6567 | Lₐ₄₂₉₃ | L_{b134} | 6568 | Lₐ₄₃₉₇ | L_{b134} |
| 6569 | Lₐ₄₅₉₇ | L_{b134} | 6570 | Lₐ₄₅₉₉ | L_{b134} |
| 6571 | Lₐ₄₆₅₇ | L_{b134} | 6572 | Lₐ₄₆₅₉ | L_{b134} |
| 6573 | Lₐ₅ | L_{b148} | 6574 | Lₐ₂₀₅ | L_{b148} |
| 6575 | Lₐ₂₀₇ | L_{b148} | 6576 | Lₐ₂₆₅ | L_{b148} |
| 6577 | Lₐ₂₆₇ | L_{b148} | 6578 | Lₐ₁₁₀₃ | L_{b148} |
| 6579 | Lₐ₂₉₃₃ | L_{b148} | 6580 | Lₐ₃₁₃₃ | L_{b148} |
| 6581 | Lₐ₃₁₃₅ | L_{b148} | 6582 | Lₐ₃₁₉₃ | L_{b148} |
| 6583 | Lₐ₃₁₉₅ | L_{b148} | 6584 | Lₐ₃₆₆₅ | L_{b148} |
| 6585 | Lₐ₃₈₆₅ | L_{b148} | 6586 | Lₐ₃₈₆₇ | L_{b148} |
| 6587 | Lₐ₃₉₂₅ | L_{b148} | 6588 | Lₐ₃₉₂₇ | L_{b148} |
| 6589 | Lₐ₄₀₃₁ | L_{b148} | 6590 | Lₐ₄₂₃₁ | L_{b148} |
| 6591 | Lₐ₄₂₃₃ | L_{b148} | 6592 | Lₐ₄₂₉₁ | L_{b148} |
| 6593 | Lₐ₄₂₉₃ | L_{b148} | 6594 | Lₐ₄₃₉₇ | L_{b148} |
| 6595 | Lₐ₄₅₉₇ | L_{b148} | 6596 | Lₐ₄₅₉₉ | L_{b148} |
| 6597 | Lₐ₄₆₅₇ | L_{b148} | 6598 | Lₐ₄₆₅₉ | L_{b148} |
| 6599 | Lₐ₅ | L_{b149} | 6600 | Lₐ₂₀₅ | L_{b149} |
| 6601 | Lₐ₂₀₇ | L_{b149} | 6602 | Lₐ₂₆₅ | L_{b149} |
| 6603 | Lₐ₂₆₇ | L_{b149} | 6604 | Lₐ₁₁₀₃ | L_{b149} |
| 6605 | Lₐ₂₉₃₃ | L_{b149} | 6606 | Lₐ₃₁₃₃ | L_{b149} |
| 6607 | Lₐ₃₁₃₅ | L_{b149} | 6608 | Lₐ₃₁₉₃ | L_{b149} |
| 6609 | Lₐ₃₁₉₅ | L_{b149} | 6610 | Lₐ₃₆₆₅ | L_{b149} |
| 6611 | Lₐ₃₈₆₅ | L_{b149} | 6612 | Lₐ₃₈₆₇ | L_{b149} |
| 6613 | Lₐ₃₉₂₅ | L_{b149} | 6614 | Lₐ₃₉₂₇ | L_{b149} |
| 6615 | Lₐ₄₀₃₁ | L_{b149} | 6616 | Lₐ₄₂₃₁ | L_{b149} |
| 6617 | Lₐ₄₂₃₃ | L_{b149} | 6618 | Lₐ₄₂₉₁ | L_{b149} |
| 6619 | Lₐ₄₂₉₃ | L_{b149} | 6620 | Lₐ₄₃₉₇ | L_{b149} |
| 6621 | Lₐ₄₅₉₇ | L_{b149} | 6622 | Lₐ₄₅₉₉ | L_{b149} |
| 6623 | Lₐ₄₆₅₇ | L_{b149} | 6624 | Lₐ₄₆₅₉ | L_{b149} |
| 6625 | Lₐ₅ | L_{b150} | 6626 | Lₐ₂₀₅ | L_{b150} |
| 6627 | Lₐ₂₀₇ | L_{b150} | 6628 | Lₐ₂₆₅ | L_{b150} |
| 6629 | Lₐ₂₆₇ | L_{b150} | 6630 | Lₐ₁₁₀₃ | L_{b150} |
| 6631 | Lₐ₂₉₃₃ | L_{b150} | 6632 | Lₐ₃₁₃₃ | L_{b150} |
| 6633 | Lₐ₃₁₃₅ | L_{b150} | 6634 | Lₐ₃₁₉₃ | L_{b150} |
| 6635 | Lₐ₃₁₉₅ | L_{b150} | 6636 | Lₐ₃₆₆₅ | L_{b150} |
| 6637 | Lₐ₃₈₆₅ | L_{b150} | 6638 | Lₐ₃₈₆₇ | L_{b150} |
| 6639 | Lₐ₃₉₂₅ | L_{b150} | 6640 | Lₐ₃₉₂₇ | L_{b150} |
| 6641 | Lₐ₄₀₃₁ | L_{b150} | 6642 | Lₐ₄₂₃₁ | L_{b150} |
| 6643 | Lₐ₄₂₃₃ | L_{b150} | 6644 | Lₐ₄₂₉₁ | L_{b150} |
| 6645 | Lₐ₄₂₉₃ | L_{b150} | 6646 | Lₐ₄₃₉₇ | L_{b150} |
| 6647 | Lₐ₄₅₉₇ | L_{b150} | 6648 | Lₐ₄₅₉₉ | L_{b150} |
| 6649 | Lₐ₄₆₅₇ | L_{b150} | 6650 | Lₐ₄₆₅₉ | L_{b150} |
| 6651 | Lₐ₅ | L_{b151} | 6652 | Lₐ₂₀₅ | L_{b151} |
| 6653 | Lₐ₂₀₇ | L_{b151} | 6654 | Lₐ₂₆₅ | L_{b151} |
| 6655 | Lₐ₂₆₇ | L_{b151} | 6656 | Lₐ₁₁₀₃ | L_{b151} |
| 6657 | Lₐ₂₉₃₃ | L_{b151} | 6658 | Lₐ₃₁₃₃ | L_{b151} |
| 6659 | Lₐ₃₁₃₅ | L_{b151} | 6660 | Lₐ₃₁₉₃ | L_{b151} |
| 6661 | Lₐ₃₁₉₅ | L_{b151} | 6662 | Lₐ₃₆₆₅ | L_{b151} |
| 6663 | Lₐ₃₈₆₅ | L_{b151} | 6664 | Lₐ₃₈₆₇ | L_{b151} |
| 6665 | Lₐ₃₉₂₅ | L_{b151} | 6666 | Lₐ₃₉₂₇ | L_{b151} |
| 6667 | Lₐ₄₀₃₁ | L_{b151} | 6668 | Lₐ₄₂₃₁ | L_{b151} |
| 6669 | Lₐ₄₂₃₃ | L_{b151} | 6670 | Lₐ₄₂₉₁ | L_{b151} |
| 6671 | Lₐ₄₂₉₃ | L_{b151} | 6672 | Lₐ₄₃₉₇ | L_{b151} |
| 6673 | Lₐ₄₅₉₇ | L_{b151} | 6674 | Lₐ₄₅₉₉ | L_{b151} |
| 6675 | Lₐ₄₆₅₇ | L_{b151} | 6676 | Lₐ₄₆₅₉ | L_{b151} |
| 6677 | Lₐ₅ | L_{b152} | 6678 | Lₐ₂₀₅ | L_{b152} |
| 6679 | Lₐ₂₀₇ | L_{b152} | 6680 | Lₐ₂₆₅ | L_{b152} |
| 6681 | Lₐ₂₆₇ | L_{b152} | 6682 | Lₐ₁₁₀₃ | L_{b152} |
| 6683 | Lₐ₂₉₃₃ | L_{b152} | 6684 | Lₐ₃₁₃₃ | L_{b152} |
| 6685 | Lₐ₃₁₃₅ | L_{b152} | 6686 | Lₐ₃₁₉₃ | L_{b152} |
| 6687 | Lₐ₃₁₉₅ | L_{b152} | 6688 | Lₐ₃₆₆₅ | L_{b152} |
| 6689 | Lₐ₃₈₆₅ | L_{b152} | 6690 | Lₐ₃₈₆₇ | L_{b152} |
| 6691 | Lₐ₃₉₂₅ | L_{b152} | 6692 | Lₐ₃₉₂₇ | L_{b152} |
| 6693 | Lₐ₄₀₃₁ | L_{b152} | 6694 | Lₐ₄₂₃₁ | L_{b152} |
| 6695 | Lₐ₄₂₃₃ | L_{b152} | 6696 | Lₐ₄₂₉₁ | L_{b152} |
| 6697 | Lₐ₄₂₉₃ | L_{b152} | 6698 | Lₐ₄₃₉₇ | L_{b152} |
| 6699 | Lₐ₄₅₉₇ | L_{b152} | 6700 | Lₐ₄₅₉₉ | L_{b152} |
| 6701 | Lₐ₄₆₅₇ | L_{b152} | 6702 | Lₐ₄₆₅₉ | L_{b152} |
| 6703 | Lₐ₅ | L_{b153} | 6704 | Lₐ₂₀₅ | L_{b153} |
| 6705 | Lₐ₂₀₇ | L_{b153} | 6706 | Lₐ₂₆₅ | L_{b153} |
| 6707 | Lₐ₂₆₇ | L_{b153} | 6708 | Lₐ₁₁₀₃ | L_{b153} |
| 6709 | Lₐ₂₉₃₃ | L_{b153} | 6710 | Lₐ₃₁₃₃ | L_{b153} |
| 6711 | Lₐ₃₁₃₅ | L_{b153} | 6712 | Lₐ₃₁₉₃ | L_{b153} |
| 6713 | Lₐ₃₁₉₅ | L_{b153} | 6714 | Lₐ₃₆₆₅ | L_{b153} |
| 6715 | Lₐ₃₈₆₅ | L_{b153} | 6716 | Lₐ₃₈₆₇ | L_{b153} |
| 6717 | Lₐ₃₉₂₅ | L_{b153} | 6718 | Lₐ₃₉₂₇ | L_{b153} |
| 6719 | Lₐ₄₀₃₁ | L_{b153} | 6720 | Lₐ₄₂₃₁ | L_{b153} |
| 6721 | Lₐ₄₂₃₃ | L_{b153} | 6722 | Lₐ₄₂₉₁ | L_{b153} |
| 6723 | Lₐ₄₂₉₃ | L_{b153} | 6724 | Lₐ₄₃₉₇ | L_{b153} |
| 6725 | Lₐ₄₅₉₇ | L_{b153} | 6726 | Lₐ₄₅₉₉ | L_{b153} |
| 6727 | Lₐ₄₆₅₇ | L_{b153} | 6728 | Lₐ₄₆₅₉ | L_{b153} |

wherein optionally, hydrogen in Metal Complex 1 to Metal Complex 6728 can be partially or fully substituted with deuterium.

19. An organic electroluminescent device, comprising:
an anode,
a cathode, and
an organic layer disposed between the anode and the cathode, wherein at least one layer of the organic layer comprises the metal complex according to claim 1.

20. The organic electroluminescent device according to claim 19, wherein the organic layer comprising the metal complex is a light-emitting layer.

21. The organic electroluminescent device according to claim 20, wherein the light-emitting layer further comprises a first host compound or further comprises a first host compound and a second host compound; and
preferably, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

22. The organic electroluminescent device according to claim 21, wherein the metal complex is doped in the first host compound and the second host compound, and a weight of the metal complex accounts for 1% to 30% of a total weight of the light-emitting layer; and
preferably, the metal complex is doped in the first host compound and the second host compound, and the weight of the metal complex accounts for 3% to 13% of the total weight of the light-emitting layer.

23. A compound composition, comprising the metal complex according to claim 1.
